(19) United States
(12) Patent Application Publication
(10) Pub. No.: US 2026/0161081 A1
(43) Pub. Date: Jun. 11, 2026

(54) PATTERNING PROCESS

(71) Applicant: SHIN-ETSU CHEMICAL CO., LTD., Tokyo (JP)

(72) Inventors: Masaki OHASHI, Joetsu-shi (JP); Shun Kikuchi, Joetsu-shi (JP); Kousuke Ohyama, Joetsu-shi (JP); Satoshi Kusama, Joetsu-shi (JP); Ryo Nishikawa, Joetsu-shi (JP)

(73) Assignee: SHIN-ETSU CHEMICAL CO., LTD., Tokyo (JP)

(21) Appl. No.: 19/408,659

(22) Filed: Dec. 4, 2025

(30) Foreign Application Priority Data
Dec. 11, 2024 (JP) 2024-216321

(51) Int. Cl. G03F 7/039; G03F 7/00; G03F 7/004; G03F 7/11

(52) U.S. Cl. CPC G03F 7/0397; G03F 7/0042; G03F 7/11; G03F 7/70033

(57) ABSTRACT

The present invention is a patterning process including the steps of: (i) forming a resist pattern on a support by using a resist film obtained from a resist composition containing a hypervalent iodine compound, a carboxy-group-containing compound, and a solvent; (ii) forming a pattern-reversal film on the support having the formed resist pattern by applying a material containing an organotitanium compound and a solvent; and (iii) removing the resist pattern by etching to form a reverse pattern. This can provide a patterning process including: forming a resist pattern by using a non-chemically amplified resist composition excellent in sensitivity and limiting resolution; and further reversing the pattern by using an organotitanium-compound-containing material having high etching resistance.

### TECHNICAL FIELD

The present invention relates to a patterning process.

### BACKGROUND ART

While a higher integration density, higher operating speed and lower power consumption of LSIs are demanded to comply with the expanding IoT market, the effort to reduce the pattern rule is in rapid progress. In particular, logic devices drive forward the miniaturization technology. As the advanced miniaturization technology, devices of 10-nm node are manufactured in a mass scale by the double, triple, or quadro-patterning version of the immersion ArF lithography. Furthermore, the experimental mass-scale manufacture of 7-nm node devices by the next-generation extreme ultraviolet ray (EUV) lithography of wavelength 13.5 nm has started.

As miniaturization advances, image blurs due to acid diffusion are regarded as a problem (Non Patent Document 1). In order to ensure resolution for fine patterns with a post-45 nm processed size, it is suggested that not only the enhancement of dissolution contrast, which has been proposed previously, but also the controlling of acid diffusion is important (Non Patent Document 2). In chemically amplified resist compositions, however, the sensitivity and the contrast are enhanced by acid diffusion. Accordingly, an attempt to minimize acid diffusion by lowering the temperature of post-exposure baking (PEB) and shortening the PEB time lowers the sensitivity and contrast markedly.

It is effective to control the acid diffusion by adding an acid generator that generates a bulky acid. Accordingly, it has been proposed to copolymerize a polymer with an acid generator in the form of an onium salt having polymerizable olefin. In post-16 nm processed size patterning of resist films, however, it is considered that patterning is impossible with chemically amplified resist compositions in view of the acid diffusion. Accordingly, development of a non-chemically amplified resist composition is desired.

Examples of materials for a non-chemically amplified resist composition include polymethyl methacrylate (PMMA). PMMA is a positive resist material whose solubility in an organic solvent developer increases due to decreased molecular weight caused by scission of the main chain by EUV irradiation.

Hydrogensilsesquioxane (HSQ) is a negative resist material which turns insoluble in an alkaline developer through crosslinking by condensation reaction of silanol generated by EUV irradiation. Calixarene substituted with chlorine also functions as a negative resist material. These negative resist materials have a small molecular size prior to crosslinking and are free from causing blurs due to acid diffusion, and therefore, exhibit smaller edge roughness and very high resolution. Accordingly, the materials have been used as a pattern transfer material to show the resolution limit of the exposure apparatus. These materials, however, are insufficient in sensitivity, and further improvement is required.

The number of photons in EUV exposure being small is a factor that causes difficulties in developing materials for EUV lithography. The energy of EUV is much higher than that of an ArF excimer laser beam, and the number of photons in EUV exposure is 1/14 of that of ArF exposure. Furthermore, the size of the pattern formed by EUV exposure is half of that in ArF exposure or less. Therefore, EUV exposure is easily affected by variation in the number of photons. The variation in the number of photons in a radiation light region of extremely short wavelengths is the physical phenomenon of shot noise, and it is impossible to eliminate the influence of the variation. Therefore, so-called probability theory (stochastics) is attracting attention. The influence of shot noise cannot be eliminated, but there is discussion of how to reduce this influence. Due to the influence of shot noise, not only are critical dimension uniformity (CDU) and line width roughness (LWR) increased, a phenomenon that a hole gets blocked at a probability of one to several millions is observed. If a hole gets blocked, conduction failure occurs and the transistor does not function, and the performance of the entire device is adversely affected. Considering sensitivity in practical terms, resist compositions that mainly contain PMMA or HSQ are greatly affected by stochastics, and cannot achieve the desired resolution performance.

The introduction of an element that greatly absorbs EUV light is attracting attention as a means for reducing the influence of shot noise on the side of the resist. Patent Document 1 proposes a chemically amplified resist composition containing iodine atoms, which greatly absorb EUV light. However, as stated above, a chemically amplified resist composition cannot realize excellent resolution performance in EUV lithography, in which the processed size is to be further miniaturized in the future. Especially in a line-and-space pattern, pattern collapse and the breaking of a line increase remarkably as the pattern size is reduced, and therefore, reducing these leads to the improvement of limiting resolution.

Patent Document 2 proposes a negative resist composition containing a tin compound. This composition mainly contains the element tin, which greatly absorbs EUV light, and therefore, stochastics is improved, and high sensitivity and high resolution can be realized. However, such a so-called metal resist has many problems such as insufficient solubility in a solvent for resists, storage stability, and defects due to residues after etching.

Patent Document 3 proposes a non-chemically amplified resist composition containing an organic polymer and an iodine compound. This composition contains iodine, which greatly absorbs EUV light, and therefore, is excellent in sensitivity and resolution, but is constituted by organic components, and therefore, etching resistance is insufficient.

### CITATION LIST

### Patent Literature

Patent Document 1: JP2018-005224A
Patent Document 2: JP2021-503482A
Patent Document 3: JP2024-092963A

### Non Patent Literature

Non Patent Document 1: SPIE Vol. 5039 p1 (2003)
Non Patent Document 2: SPIE Vol. 6520 p65203L-1 (2007)

### SUMMARY OF INVENTION

### Technical Problem

The present invention has been made in view of the above-described circumstances, and an object thereof is to provide a patterning process including: forming a resist pattern by using a non-chemically amplified resist composition excellent in sensitivity and limiting resolution; and further reversing the pattern by using an organotitanium-compound-containing material having high etching resistance.

### Solution to Problem

To achieve the object, the present invention provides a patterning process comprising the steps of:
(i) forming a resist pattern on a support by using a resist film obtained from a resist composition containing a hypervalent iodine compound, a carboxy-group-containing compound, and a solvent;
(ii) forming a pattern-reversal film on the support having the formed resist pattern by applying a material containing an organotitanium compound and a solvent; and
(iii) removing the resist pattern by etching to form a reverse pattern.

According to such a patterning process, it is possible to form a resist pattern by using a non-chemically amplified resist composition excellent in sensitivity and limiting resolution, and further reverse the pattern by using an organotitanium-compound-containing material having high etching resistance.

In the present invention, as the hypervalent iodine compound, at least one compound selected from hypervalent iodine compounds represented by the following general formulae (1) to (10) is preferably used,

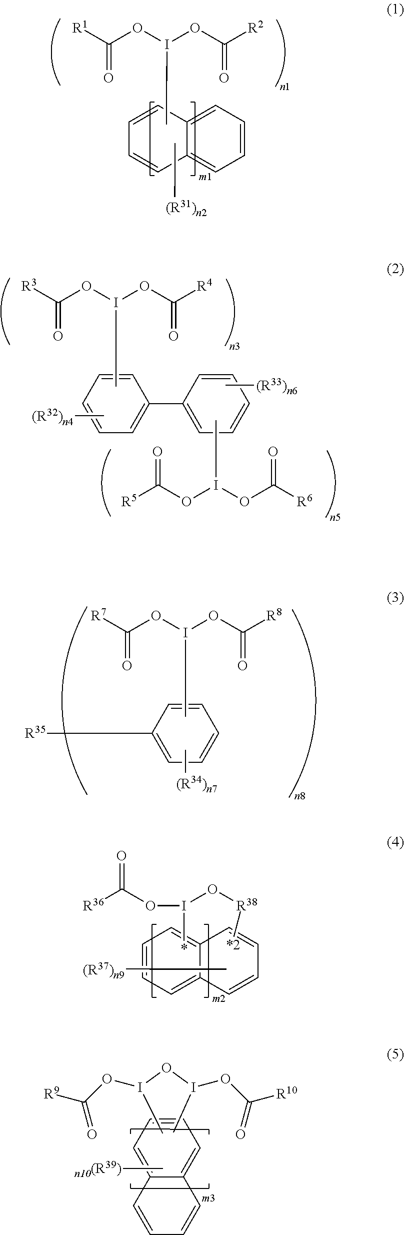

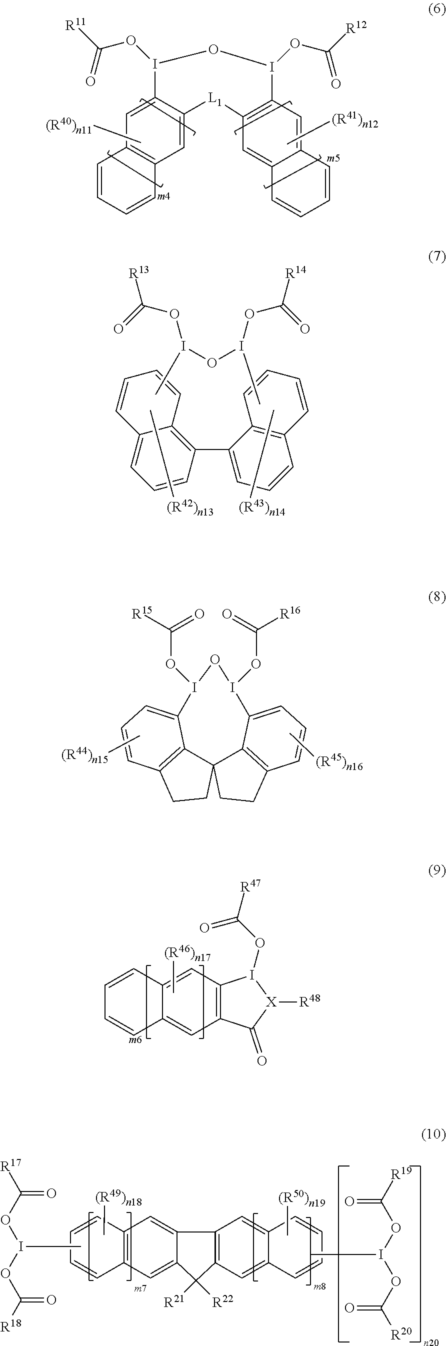

wherein “m1” represents an integer of 0 to 2, when “m1” is 0, “n1” representing an integer of 1 to 3, “n2” representing an integer of 0 to 5, and 1≤n1+n2≤6 being satisfied, when “m1” is 1, “n1” representing an integer of 1 to 3, “n2” representing an integer of 0 to 7, and 1≤n1+n2≤8 being satisfied, and when “m1” is 2, “n1” representing an integer of 1 to 3, “n2” representing an integer of 0 to 9, and 1≤n1+n2≤10 being satisfied;
“n3” represents 1 or 2, “n4” represents an integer of 0 to 4, and 1≤n3+n4≤5 is satisfied, and “n5” represents 1 or 2, “n6” represents an integer of 0 to 4, and 1≤n5+n6≤5 is satisfied;
“n7” represents an integer of 0 to 4, and “n8” represents an integer of 1 to 4;
“m2” represents an integer of 0 to 2, when “m2” is 0, “n9” representing an integer of 0 to 4, when “m2” is 1, “n9” representing an integer of 0 to 6, and when “m2” is 2, “n9” representing an integer of 0 to 8;
“m3” represents an integer of 0 to 2, when “m3” is 0, “n10” representing an integer of 0 to 4, when “m3” is 1, “n10” representing an integer of 0 to 6, and when “m3” is 2, “n10” representing an integer of 0 to 8;
“m4” represents 0 or 1, when “m4” is 0, “n11” representing an integer of 0 to 4 and when “m4” is 1, “n11” representing an integer of 0 to 6;
“m5” represents 0 or 1, when “m5” is 0, “n12” representing an integer of 0 to 4 and when “m5” is 1, “n12” representing an integer of 0 to 6;
“n13” and “n14” each represent an integer of 0 to 6;
“n15” and “n16” each represent an integer of 0 to 3;
“m6” represents an integer of 0 to 2, when “m6” is 0, “n17” representing an integer of 0 to 4, when “m6” is 1, “n17” representing an integer of 0 to 6, and when “m6” is 2, “n17” representing an integer of 0 to 8;
“m7” represents an integer of 0 to 2, when “m7” is 0, “n18” representing an integer of 0 to 3, when “m7” is 1, “n18” representing an integer of 0 to 5, and when “m7” is 2, “n18” representing an integer of 0 to 7;
“m8” represents an integer of 0 to 2, when “m8” is 0, “n19” representing an integer of 0 to 3 and “n20” representing 0 or 1, when “m8” is 1, “n19” representing an integer of 0 to 5 and “n20” representing 0 or 1, and when “m8” is 2, “n19” representing an integer of 0 to 7 and “n20” representing 0 or 1;
R¹ to R²² each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, R¹⁹ and R²⁰, or R²¹ and R²² may be bonded to each other to form a ring together with the carbon atoms bonded thereto and any atoms between the carbon atoms;
R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³²s are identical to or different from each other and the R³²s may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with the carbon atoms of the aromatic ring bonded thereto, when “n10” is 2 or more, the R³⁹s are identical to or different from each other and the R³⁹s may be bonded to each other to form a ring together with the carbon atoms of the aromatic ring bonded thereto, when “n11” is 2 or more, the R⁴⁰s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴²s are identical to or different from each other and the R⁴²s may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with the carbon atoms of the aromatic ring bonded thereto, and when “n19” is 2 or more, the R⁵⁰s are identical to or different from each other and the R⁵⁰s may be bonded to each other to form a ring together with the carbon atoms of the aromatic ring bonded thereto;
R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, wherein part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms;
R³⁶ represents a halogen atom or a hydrocarbyl group having 1 to 10 carbon atoms and optionally containing a heteroatom;
R³⁸ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
L₁ represents absence of a bond, a single bond, —O—, —S—, —NH—, or —CH₂—;
R⁴⁷ represents a halogen atom or a hydrocarbyl group having 1 to 10 carbon atoms and optionally containing a heteroatom;
X represents a nitrogen atom or a sulfur atom, when X is a nitrogen atom, X may have R⁴⁸; and
R⁴⁸ represents a hydrogen atom, a halogen atom, or a hydrocarbyl group or ester each having 1 to 20 carbon atoms and optionally containing a heteroatom.

In the inventive patterning process, it is preferable to use such a hypervalent iodine compound.

In the present invention, as the carboxy-group-containing compound, a carboxy-group-containing polymer including a repeating unit represented by the following general formula (11) or a carboxylic acid compound represented by the following general formula (12) is preferably used,

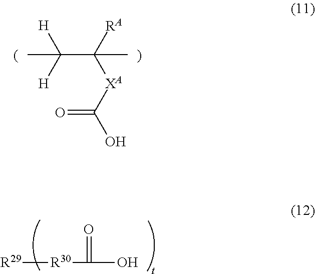

wherein R^{A} represents a hydrogen atom, a halogen atom, a methyl group, or a trifluoromethyl group;
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring, and “*” represents an attachment point to the carbon atom of the main chain;
“t” represents an integer of 1 to 4;
R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, wherein part or all of hydrogen atoms of the t-valent hydrocarbon group or the t-valent heterocyclic group may be substituted with a group containing a heteroatom, and part of —CH₂— of the t-valent hydrocarbon group may be substituted with a group containing a heteroatom; and
R³⁰ represents a single bond or a hydrocarbylene group having 1 to 10 carbon atoms, wherein part or all of hydrogen atoms of the hydrocarbylene group may be substituted with a group containing a heteroatom, part of —CH₂— of the hydrocarbylene group may be substituted with a group containing a heteroatom, and when “t” is 2 to 4, the R³⁰s are identical to or different from each other.

In the inventive patterning process, it is preferable to use such a carboxy-group-containing compound.

In the present invention, a resist underlayer film is preferably formed between the support and the resist film.

In the inventive patterning process, a resist underlayer film can also be formed between the support and the resist film.

In the present invention, as the organotitanium compound, a compound represented by the following general formula (13) is preferably used,

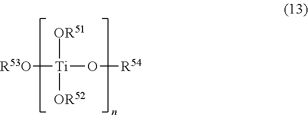

wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

In the inventive patterning process, it is preferable to use such an organotitanium compound.

### Advantageous Effects of Invention

As described above, the inventive patterning process is extremely useful for forming a resist pattern by using a non-chemically amplified resist composition excellent in sensitivity and limiting resolution, achieving both high resolution and etching resistance especially in lithography using an electron beam or EUV, and forming a fine pattern.

### BRIEF DESCRIPTION OF DRAWINGS

FIG. 1 illustrates an example of the inventive patterning process.

### DESCRIPTION OF EMBODIMENTS

As described above, there have been demands for the development of a patterning process including: forming a resist pattern by using a non-chemically amplified resist composition excellent in sensitivity and limiting resolution; and further reversing the pattern by using an organotitanium-compound-containing material having high etching resistance.

To achieve the object, the present inventors have studied earnestly and found out that a pattern excellent in etching resistance can be formed by forming a pattern by using a resist film obtained from a resist composition containing a hypervalent iodine compound, a carboxy-group-containing compound, and a solvent, then applying a material containing an organotitanium compound and a solvent, and then forming a reverse pattern in an etching step, and that this process is extremely effective for precise fine processing. Thus, the present invention has been achieved.

That is, the present invention is a patterning process comprising the steps of:
(i) forming a resist pattern on a support by using a resist film obtained from a resist composition containing a hypervalent iodine compound, a carboxy-group-containing compound, and a solvent;
(ii) forming a pattern-reversal film on the support having the formed resist pattern by applying a material containing an organotitanium compound and a solvent; and
(iii) removing the resist pattern by etching to form a reverse pattern.

Hereinafter, the present invention will be described in detail, but the present invention is not limited thereto.

### [Resist Composition]

The resist composition used in the inventive patterning process contains a hypervalent iodine compound, a carboxy-group-containing compound, and a solvent.

### [Hypervalent Iodine Compound]

As the hypervalent iodine compound, it is preferable to use at least one compound selected from hypervalent iodine compounds represented by the following general formulae (1) to (10).

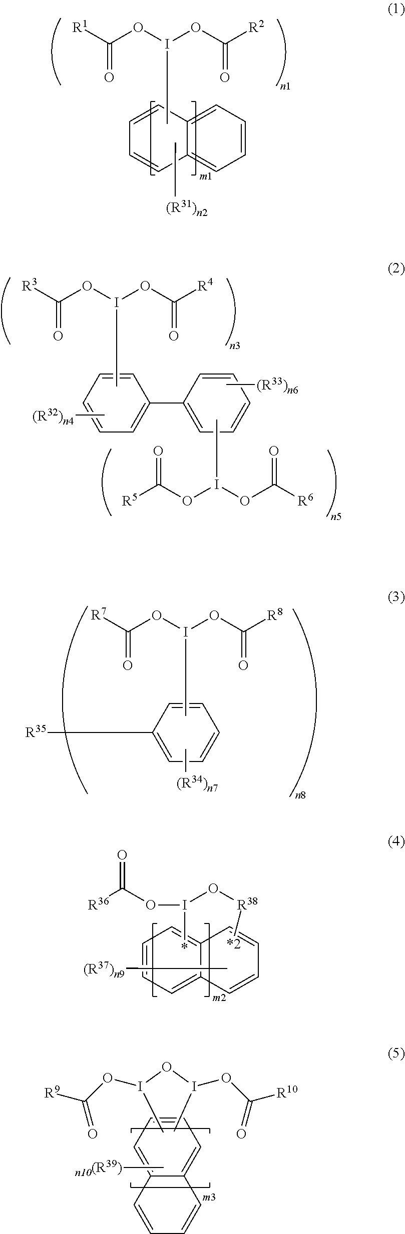

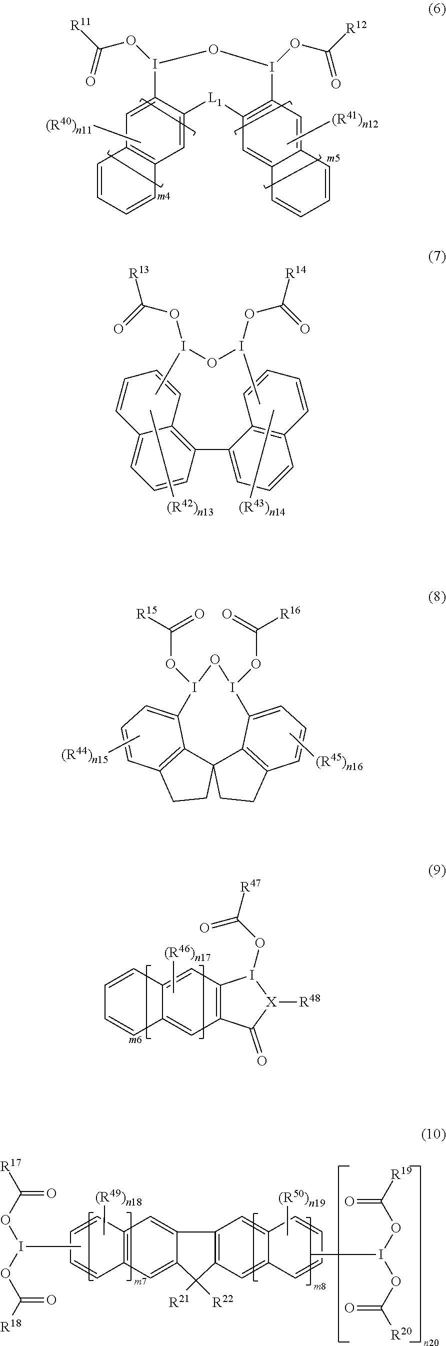

In the formulae, “m1” represents an integer of 0 to 2, when “m1” is 0, “n1” representing an integer of 1 to 3, “n2” representing an integer of 0 to 5, and 1 n1+n2≤6 being satisfied, when “m1” is 1, “n1” representing an integer of 1 to 3, “n2” representing an integer of 0 to 7, and 1≤n1+n2≤8 being satisfied, and when “m1” is 2, “n1” representing an integer of 1 to 3, “n2” representing an integer of 0 to 9, and 1≤n1+n2≤10 being satisfied;
“n3” represents 1 or 2, “n4” represents an integer of 0 to 4, and 1≤n3+n4≤5 is satisfied, and “n5” represents 1 or 2, “n6” represents an integer of 0 to 4, and 1≤n5+n6≤5 is satisfied;
“n7” represents an integer of 0 to 4, and “n8” represents an integer of 1 to 4;
“m2” represents an integer of 0 to 2, when “m2” is 0, “n9” representing an integer of 0 to 4, when “m2” is 1, “n9” representing an integer of 0 to 6, and when “m2” is 2, “n9” representing an integer of 0 to 8;
“m3” represents an integer of 0 to 2, when “m3” is 0, “n10” representing an integer of 0 to 4, when “m3” is 1, “n10” representing an integer of 0 to 6, and when “m3” is 2, “n10” representing an integer of 0 to 8;
“m4” represents 0 or 1, when “m4” is 0, “n11” representing an integer of 0 to 4 and when “m4” is 1, “n11” representing an integer of 0 to 6;
“m5” represents 0 or 1, when “m5” is 0, “n12” representing an integer of 0 to 4 and when “m5” is 1, “n12” representing an integer of 0 to 6;
“n13” and “n14” each represent an integer of 0 to 6;
“n15” and “n16” each represent an integer of 0 to 3;
“m6” represents an integer of 0 to 2, when “m6” is 0, “n17” representing an integer of 0 to 4, when “m6” is 1, “n17” representing an integer of 0 to 6, and when “m6” is 2, “n17” representing an integer of 0 to 8;
“m7” represents an integer of 0 to 2, when “m7” is 0, “n18” representing an integer of 0 to 3, when “m7” is 1, “n18” representing an integer of 0 to 5, and when “m7” is 2, “n18” representing an integer of 0 to 7;
“m8” represents an integer of 0 to 2, when “m8” is 0, “n19” representing an integer of 0 to 3 and “n20” representing 0 or 1, when “m8” is 1, “n19” representing an integer of 0 to 5 and “n20” representing 0 or 1, and when “m8” is 2, “n19” representing an integer of 0 to 7 and “n20” representing 0 or 1;
R¹ to R²² each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, R¹⁹ and R²⁰, or R²¹ and R²² may be bonded to each other to form a ring together with the carbon atoms bonded thereto and any atoms between the carbon atoms;
R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³²s are identical to or different from each other and the R³²s may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with the carbon atoms of the aromatic ring bonded thereto, when “n10” is 2 or more, the R³⁹s are identical to or different from each other and the R³⁹s may be bonded to each other to form a ring together with the carbon atoms of the aromatic ring bonded thereto, when “n11” is 2 or more, the R⁴⁰s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴²s are identical to or different from each other and the R⁴²s may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with the carbon atoms of the aromatic ring bonded thereto, and when “n19” is 2 or more, the R⁵⁰s are identical to or different from each other and the R⁵⁰s may be bonded to each other to form a ring together with the carbon atoms of the aromatic ring bonded thereto;
R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, where part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms;
R³⁶ represents a halogen atom or a hydrocarbyl group having 1 to 10 carbon atoms and optionally containing a heteroatom;
R³⁸ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
L₁ represents absence of a bond, a single bond, —O—, —S—, —NH—, or —CH₂—;
R⁴⁷ represents a halogen atom or a hydrocarbyl group having 1 to 10 carbon atoms and optionally containing a heteroatom;
X represents a nitrogen atom or a sulfur atom, when X is a nitrogen atom, X may have R⁴⁸; and
R⁴⁸ represents a hydrogen atom, a halogen atom, or a hydrocarbyl group or ester each having 1 to 20 carbon atoms and optionally containing a heteroatom.

In the general formula (1), “m1” represents an integer of 0 to 2, when “m1” is 0, “n1” representing an integer of 1 to 3, “n2” representing an integer of 0 to 5, and 1≤n1+n2≤6 being satisfied, when “m1” is 1, “n1” representing an integer of 1 to 3, “n2” representing an integer of 0 to 7, and 1≤n1+n2≤8 being satisfied, and when “m1” is 2, “n1” representing an integer of 1 to 3, “n2” representing an integer of 0 to 9, and 1≤n1+n2≤10 being satisfied.

In the general formula (2), “n3” represents 1 or 2, “n4” represents an integer of 0 to 4, and 1≤n3+n4≤5 is satisfied. “n5” represents 1 or 2, “n6” represents an integer of 0 to 4, and 1≤n5+n6≤5 is satisfied.

In the general formula (3), “n7” represents an integer of 0 to 4, and “n8” represents an integer of 1 to 4.

In the general formula (4), “m2” represents an integer of 0 to 2, when “m2” is 0, “n9” representing an integer of 0 to 4, when “m2” is 1, “n9” representing an integer of 0 to 6, and when “m2” is 2, “n9” representing an integer of 0 to 8.

In the general formula (5), “m3” represents an integer of 0 to 2, when “m3” is 0, “n10” representing an integer of 0 to 4, when “m3” is 1, “n10” representing an integer of 0 to 6, and when “m3” is 2, “n10” representing an integer of 0 to 8.

In the general formula (6), “m4” represents 0 or 1, when “m4” is 0, “n11” representing an integer of 0 to 4 and when “m4” is 1, “n11” representing an integer of 0 to 6. “m5” represents 0 or 1, when “m5” is 0, “n12” representing an integer of 0 to 4 and when “m5” is 1, “n12” representing an integer of 0 to 6.

In the general formula (7), “n13” and “n14” each represent an integer of 0 to 6.

In the general formula (8), “n15” and “n16” each represent an integer of 0 to 3.

In the general formula (9), “m6” represents an integer of 0 to 2, when “m6” is 0, “n17” representing an integer of 0 to 4, when “m6” is 1, “n17” representing an integer of 0 to 6, and when “m6” is 2, “n17” representing an integer of 0 to 8.

In the general formula (10), “m7” represents an integer of 0 to 2, when “m7” is 0, “n18” representing an integer of 0 to 3, when “m7” is 1, “n18” representing an integer of 0 to 5, and when “m7” is 2, “n18” representing an integer of 0 to 7. “m8” represents an integer of 0 to 2, when “m8” is 0, “n19” representing an integer of 0 to 3 and “n20” representing 0 or 1, when “m8” is 1, “n19” representing an integer of 0 to 5 and “n20” representing 0 or 1, and when “m8” is 2, “n19” representing an integer of 0 to 7 and “n20” representing 0 or 1.

In the general formulae (1) to (3), (5) to (8), and (10), R¹ to R²² each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, R¹⁹ and R²⁰, or R²¹ and R²² may be bonded to each other to form a ring together with the carbon atoms bonded thereto and any atoms between the carbon atoms.

Examples of the halogen atom represented by R¹ to R²² include a fluorine atom, a chlorine atom, a bromine atom, and an iodine atom. The hydrocarbyl group represented by R¹ to R²² having 1 to 10 carbon atoms may be saturated or unsaturated, and may be linear, branched, or cyclic. Specific examples thereof include: alkyl groups having 1 to 10 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, and an adamantyl group; alkenyl groups having 2 to 10 carbon atoms, such as a vinyl group and an allyl group; aryl groups having 6 to 10 carbon atoms, such as a phenyl group and a naphthyl group; and groups which are combinations of these groups. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— of the hydrocarbyl group may be substituted with a group containing a heteroatom such as an oxygen atom, a sulfur atom, or a nitrogen atom. The resulting hydrocarbyl group may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. As R¹ to R²², a hydrocarbyl group having 1 to 4 carbon atoms is preferable.

In the general formulae (1) to (10), R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³²s are identical to or different from each other and the R³²s may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with the carbon atoms of the aromatic ring bonded thereto, when “n10” is 2 or more, the R³⁹s are identical to or different from each other and the R³⁹s may be bonded to each other to form a ring together with the carbon atoms of the aromatic ring bonded thereto, when “n11” is 2 or more, the R⁴⁰s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴²s are identical to or different from each other and the R⁴²s may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with the carbon atoms of the aromatic ring bonded thereto, and when “n19” is 2 or more, the R⁵⁰s are identical to or different from each other and the R⁵⁰s may be bonded to each other to form a ring together with the carbon atoms of the aromatic ring bonded thereto.

Examples of the halogen atom represented by R³¹ to R³⁴, R³⁷, R³⁹ to R⁴⁶, R⁴⁹, and R⁵⁰ include a fluorine atom, a chlorine atom, a bromine atom, and an iodine atom. The hydrocarbyl group represented by R³¹ to R³⁴, R³⁷, R³⁹ to R⁴⁶, R⁴⁹, and R⁵⁰ having 1 to 40 carbon atoms may be saturated or unsaturated, and may be linear, branched, or cyclic. Specific examples thereof include: alkyl groups having 1 to 40 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; and aryl groups having 6 to 40 carbon atoms, such as a phenyl group, a naphthyl group, and an anthracenyl group. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— of the hydrocarbyl group may be substituted with a group containing a heteroatom such as an oxygen atom, a sulfur atom, or a nitrogen atom. The resulting hydrocarbyl group may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc.

In the general formula (3), R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, where part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms.

The n8-valent hydrocarbon group represented by R³⁵ may be saturated or unsaturated, and may be linear, branched, or cyclic. The n8-valent hydrocarbon group is a hydrocarbon group from which “n8” hydrogen atoms are removed. Examples of the hydrocarbon include alkanes having 1 to 40 carbon atoms, alkenes having 2 to 40 carbon atoms, alkynes having 2 to 40 carbon atoms, cyclic saturated hydrocarbons having 3 to 40 carbon atoms, cyclic unsaturated hydrocarbons having 3 to 40 carbon atoms, and aromatic hydrocarbons having 6 to 40 carbon atoms.

Specific examples of the alkanes having 1 to 40 carbon atoms include methane, ethane, propane, butane, pentane, hexane, heptane, octane, nonane, decane, and structural isomers thereof.

Specific examples of the alkenes having 2 to 40 carbon atoms include ethylene, propylene, butene, pentene, hexene, heptene, octene, nonene, decene, and structural isomers thereof.

Specific examples of the alkynes having 2 to 40 carbon atoms include acetylene, propyne, butyne, pentyne, hexyne, heptyne, octyne, nonyne, decyne, and structural isomers thereof.

Specific examples of the cyclic saturated hydrocarbons having 3 to 40 carbon atoms include cyclopropane, cyclobutane, cyclohexane, cycloheptane, cyclooctane, adamantane, and norbornane.

Specific examples of the cyclic unsaturated hydrocarbons having 3 to 40 carbon atoms include cyclopropene, cyclobutene, cyclopentene, cyclohexene, cycloheptene, cyclooctene, and norbornene.

Specific examples of the aromatic hydrocarbons having 6 to 40 carbon atoms include benzene, naphthalene, and biphenyl.

The n8-valent heterocyclic group represented by R³⁵ is a group which is obtained by removing “n8” hydrogen atoms from a heterocyclic compound. Examples of the heterocyclic compound include furan, pyridine, pyrazole, and thiazolidine.

Part or all of the hydrogen atoms of the n8-valent hydrocarbon group or the n8-valent heterocyclic group represented by R³⁵ may be substituted with a group containing a heteroatom such as an oxygen atom, a sulfur atom, a nitrogen atom, or a halogen atom. The resulting n8-valent hydrocarbon group or n8-valent heterocyclic group may contain a hydroxy group, a cyano group, a fluorine atom, a chlorine atom, a bromine atom, an iodine atom, etc. Furthermore, part of the —CH₂-constituting the n8-valent hydrocarbon group may be substituted with a group containing a heteroatom such as an oxygen atom, a sulfur atom, or a nitrogen atom. The resulting n8-valent hydrocarbon group may contain a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc.

In the general formula (4), R³⁶ represents a halogen atom or a hydrocarbyl group having 1 to 10 carbon atoms and optionally containing a heteroatom. Specific examples of the halogen atom and hydrocarbyl group represented by R³⁶ respectively include those given as examples of the halogen atom and hydrocarbyl group represented by R¹ to R²².

In the general formula (4), R³⁸ represents a carbonyl group or a hydrocarbylene group having 1 to 10 carbon atoms and optionally containing a heteroatom. The hydrocarbylene group having 1 to 10 carbon atoms may be saturated or unsaturated, and may be linear, branched, or cyclic. Specific examples thereof include: alkylene groups having 1 to 10 carbon atoms, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-2,3-diyl group, a butane-1,4-diyl group, a 2-methylpropane-1,2-diyl group, a pentane-1,5-diyl group, a hexane-1,6-diyl group, a heptane-1,7-diyl group, an octane-1,8-diyl group, a nonane-1,9-diyl group, and a decane-1,10-diyl group; cyclic saturated hydrocarbylene groups having 3 to 10 carbon atoms, such as a cyclopentanediyl group, a cyclohexanediyl group, a norbornanediyl group, an adamantanediyl group, and a tricyclo[5.2.1.0^{2,6}]decanediyl group; alkenylene groups having 2 to 10 carbon atoms, such as a vinylene group and a propynylene group; arylene groups having 6 to 10 carbon atoms, such as a phenylene group, a methylphenylene group, an ethylphenylene group, an n-propylphenylene group, an isopropylphenylene group, an n-butylphenylene group, and a naphthylene group; and groups which are combinations of these groups. Furthermore, part or all of the hydrogen atoms of the hydrocarbylene group may be substituted with a group containing a heteroatom, such as an oxygen atom, a sulfur atom, a nitrogen atom, or a halogen atom, and part of the —CH₂— of the hydrocarbylene group may be substituted with a group containing a heteroatom such as an oxygen atom, a sulfur atom, or a nitrogen atom. The resulting hydrocarbylene group may contain a hydroxy group, a cyano group, a halogenated alkyl group, a halogen atom, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), etc. As R³⁸, a carbonyl group, a hydrocarbylene group having 1 to 4 carbon atoms, or a fluorinated hydrocarbylene group having 1 to 4 carbon atoms is preferable.

In the general formula (4), “*1” and “*2” each represent an attachment point to a carbon atom of the aromatic ring in the formula, provided that “*1” and “*2” are bonded to adjacent carbon atoms of the aromatic ring. As combinations of such “*1”, “*2”, and “m2”, the seven cases shown below are possible.

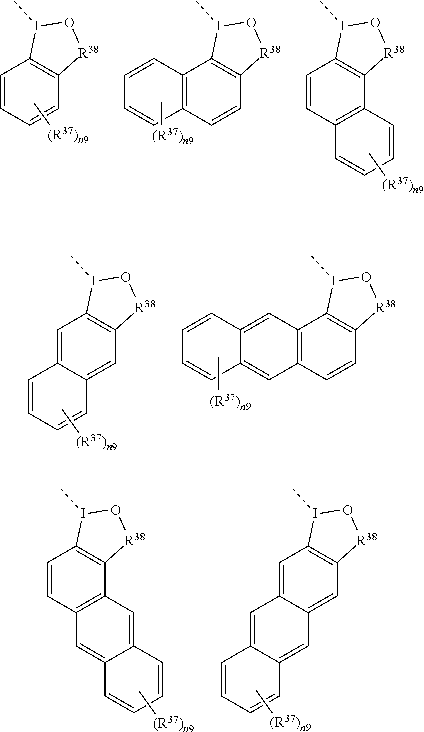

In the formulae, “n9”, R³⁷, and R³⁸ are as defined above. A broken line represents an attachment point to R³⁶—C(═O)—O—.

In the general formula (6), L₁ represents absence of a bond, a single bond, —O—, —S—, —NH—, or —CH₂—.

In the general formula (9), R⁴⁷ represents a halogen atom or a hydrocarbyl group having 1 to 10 carbon atoms and optionally containing a heteroatom. Specific examples of the halogen atom and hydrocarbyl group represented by R⁴⁷ respectively include those given as examples of the halogen atom and hydrocarbyl group represented by R¹ to R²².

In the general formula (9), X represents a nitrogen atom or a sulfur atom, and when X is a nitrogen atom, X may have R⁴⁸. R⁴⁸ represents a hydrogen atom, a halogen atom, or a hydrocarbyl group or ester each having 1 to 20 carbon atoms and optionally containing a heteroatom. Specific examples of the halogen atom and hydrocarbyl group represented by R⁴⁸ respectively include those given as examples of the halogen atom and hydrocarbyl group represented by R¹ to R²². Specific examples of the ester represented by R⁴⁸ include those having an ester bond among the examples given as examples of the hydrocarbyl group represented by R¹ to R²².

Specific examples of the hypervalent iodine compound represented by the general formula (1) include the following, but are not limited thereto.

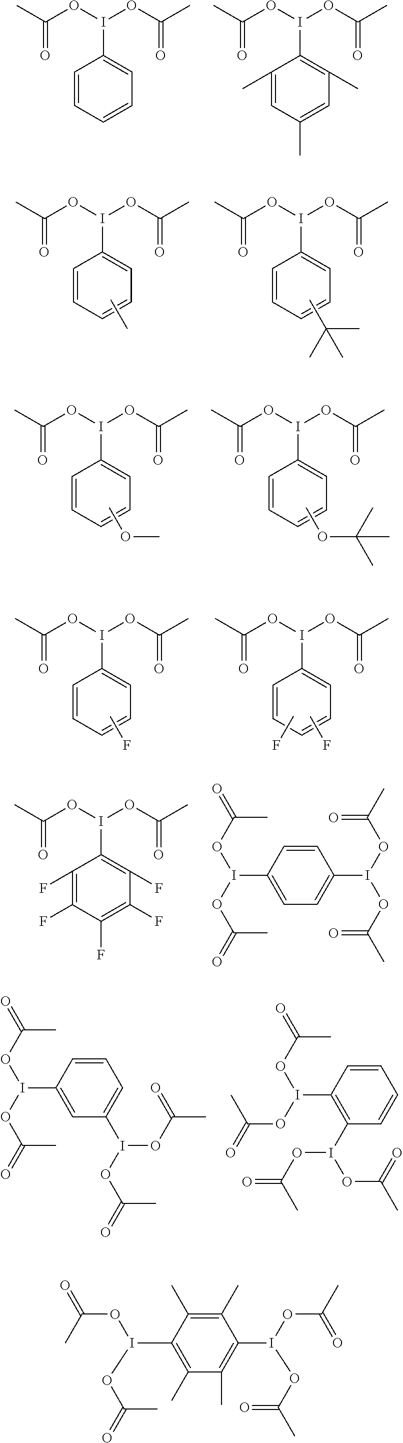

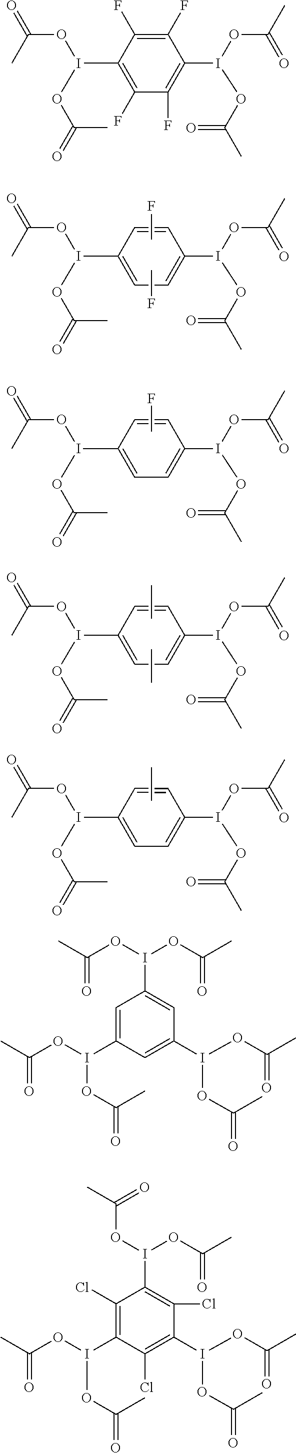

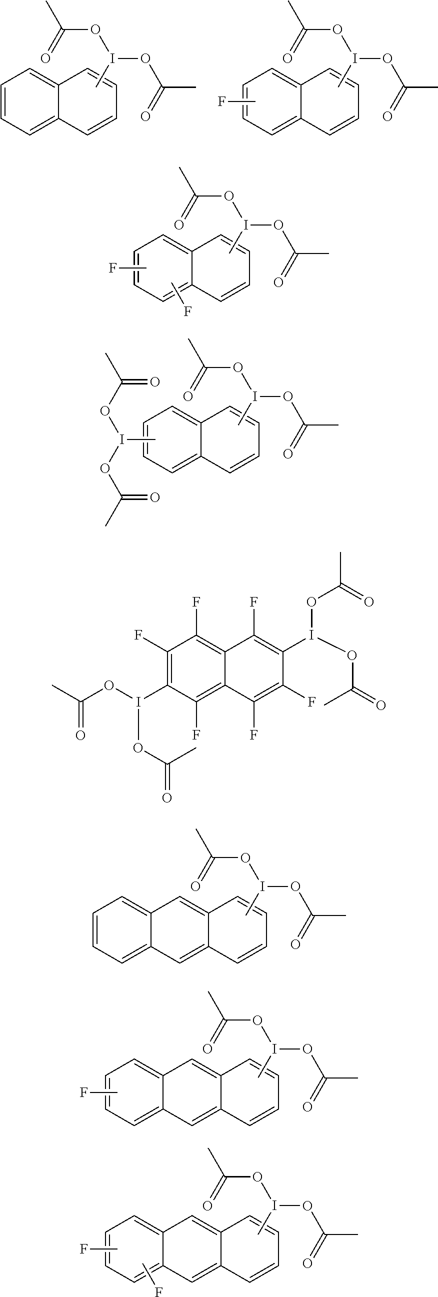

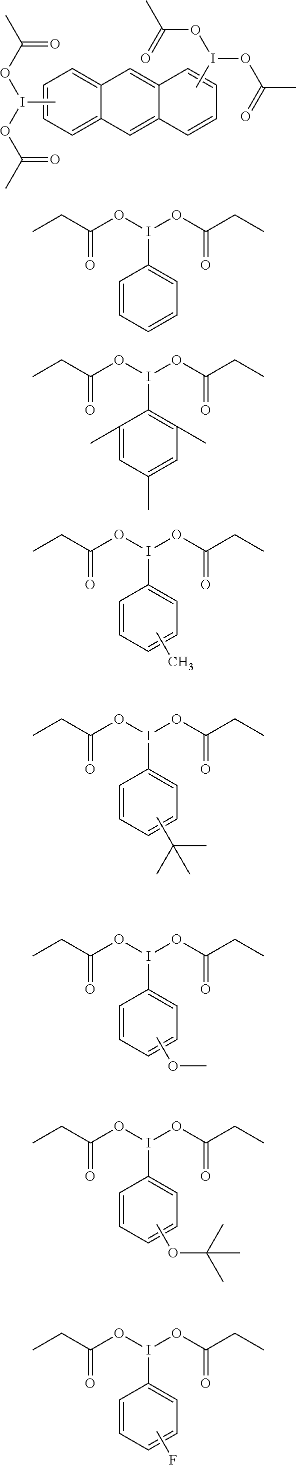

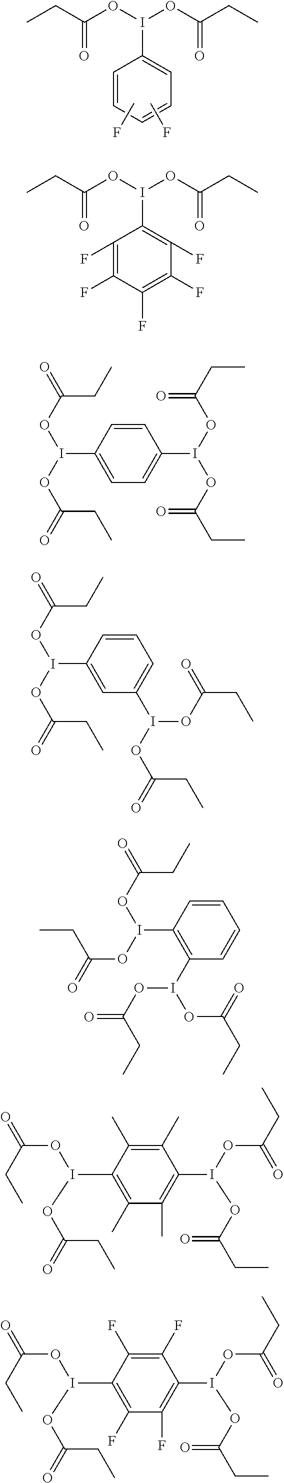

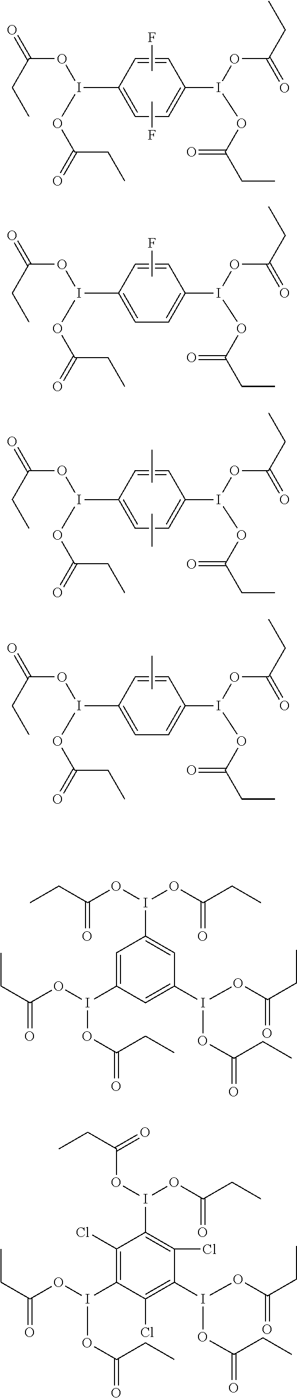

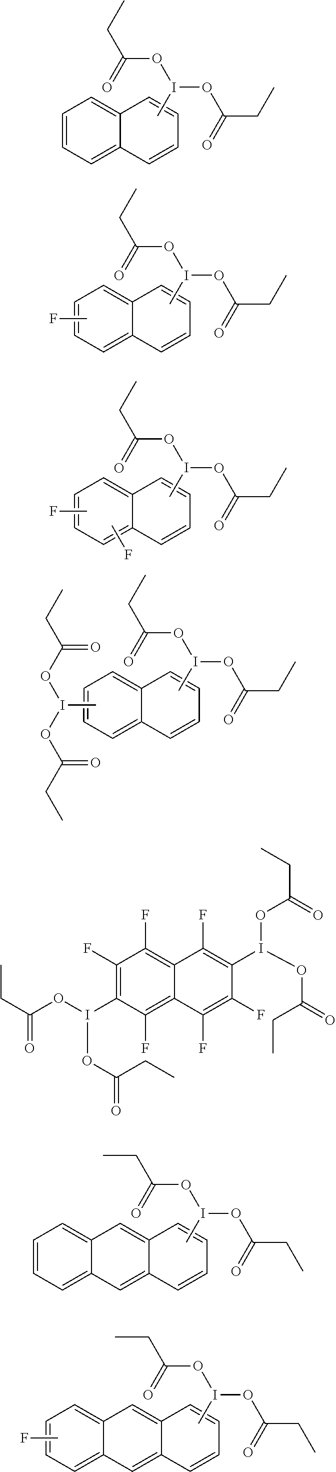

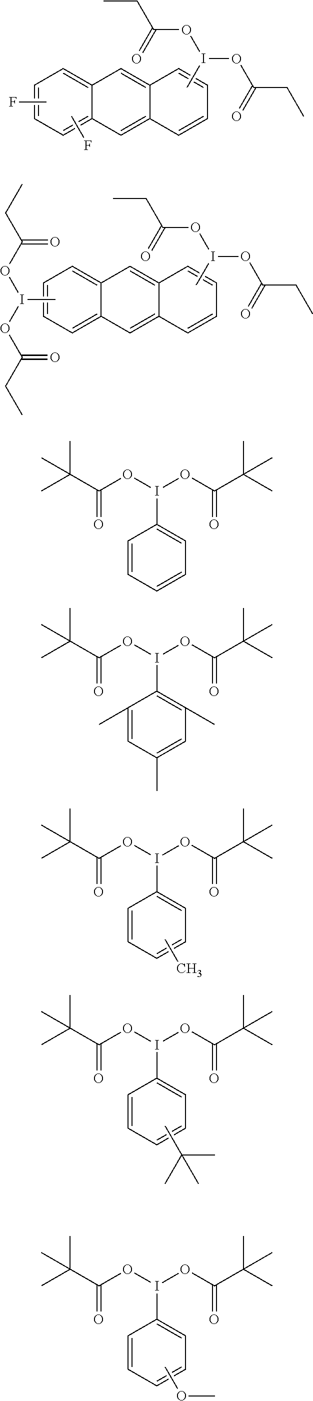

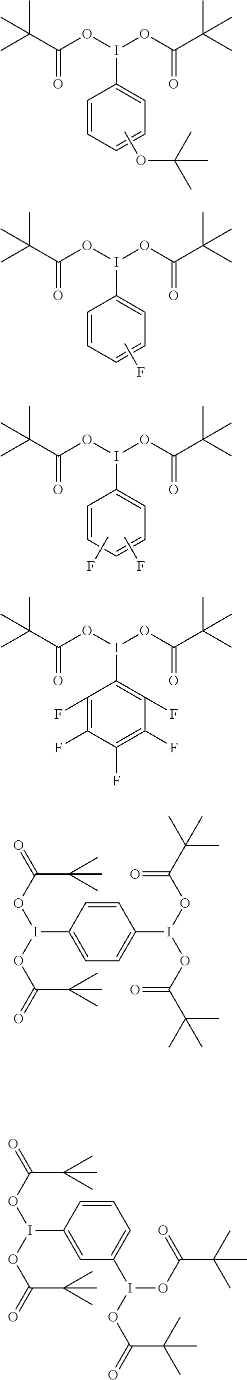

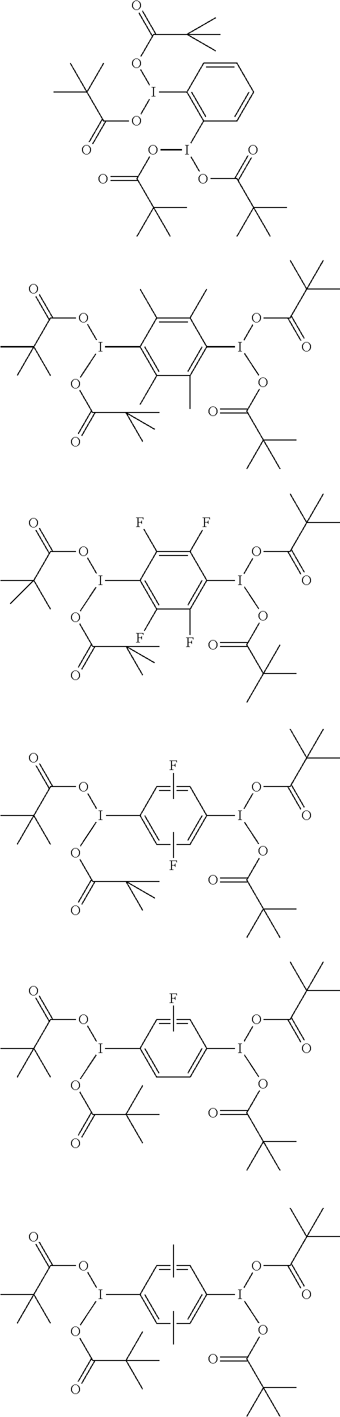

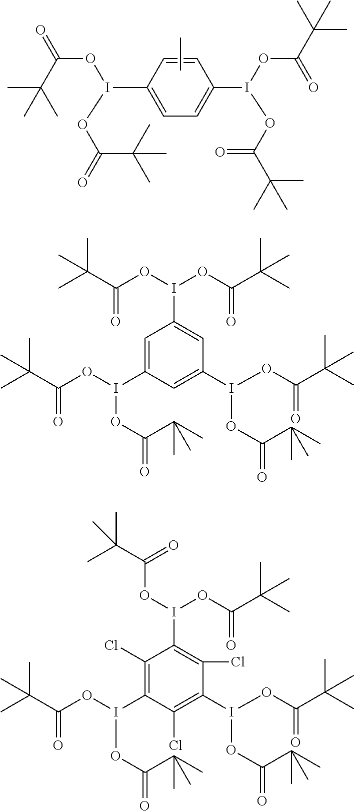

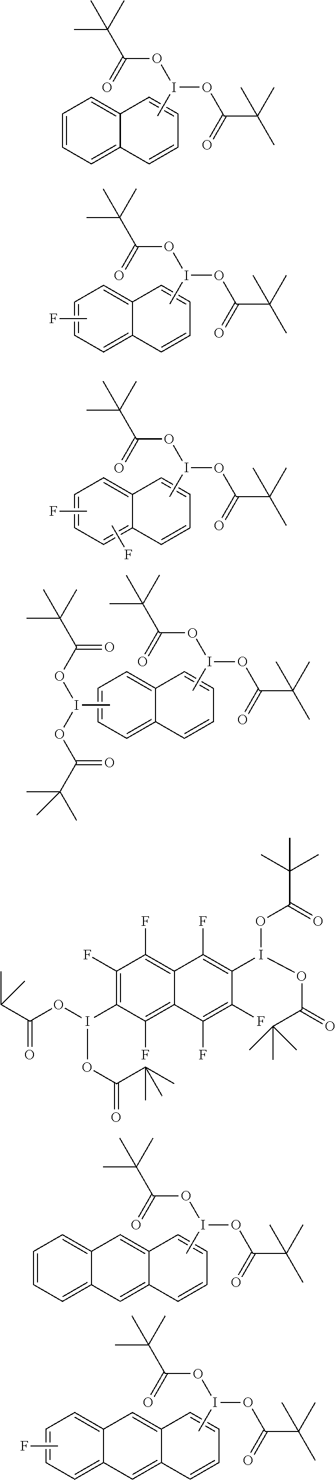

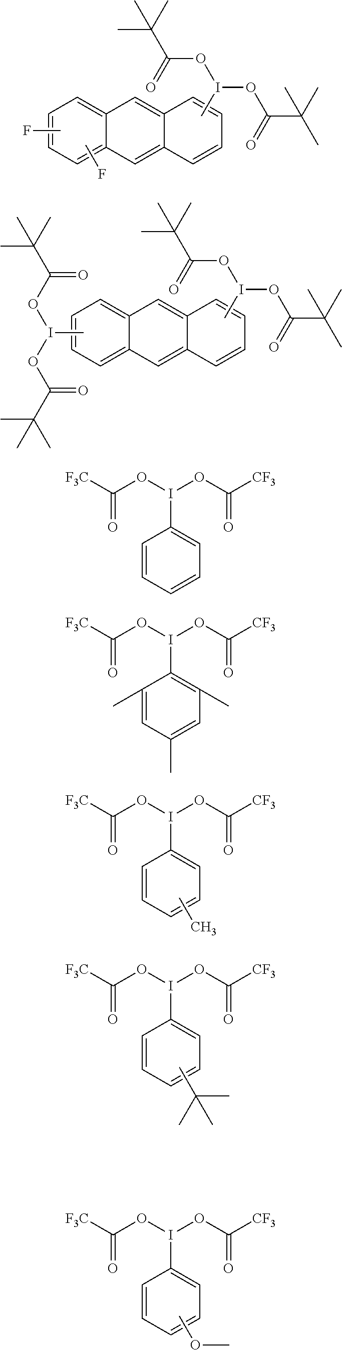

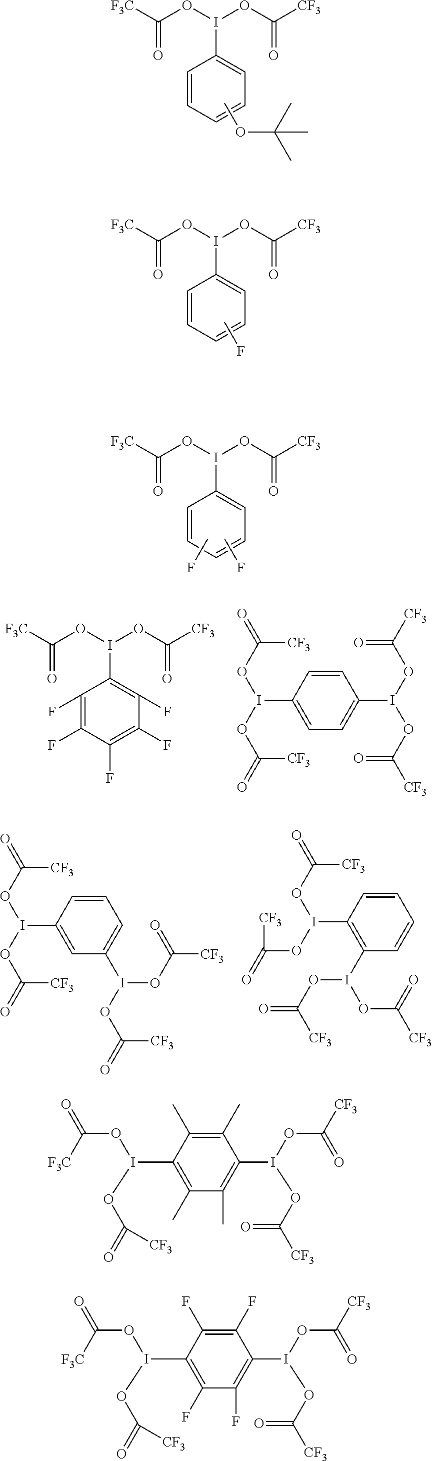

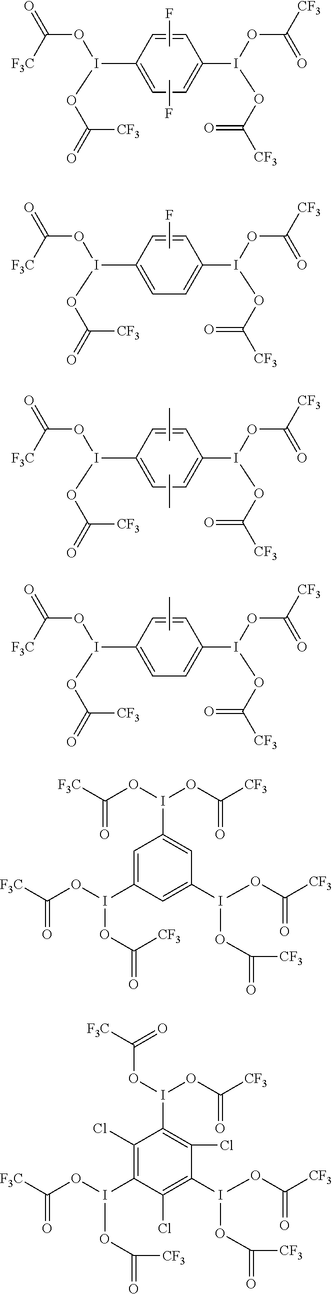

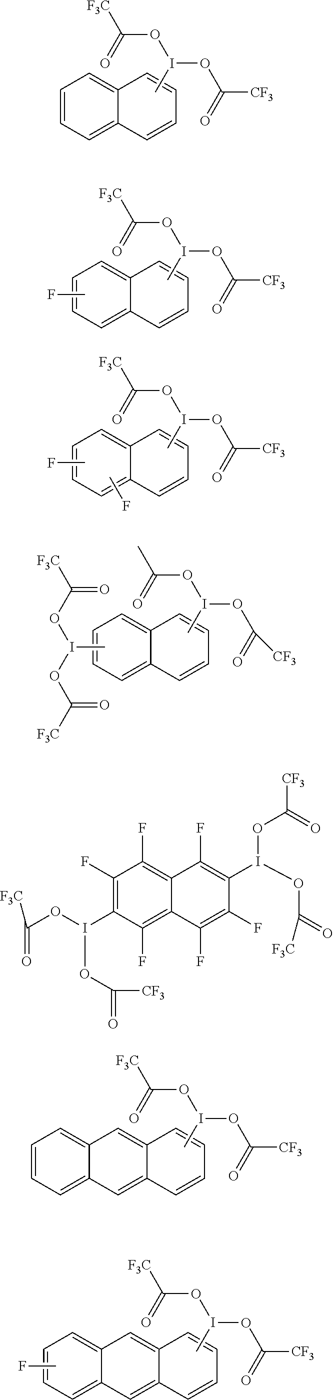

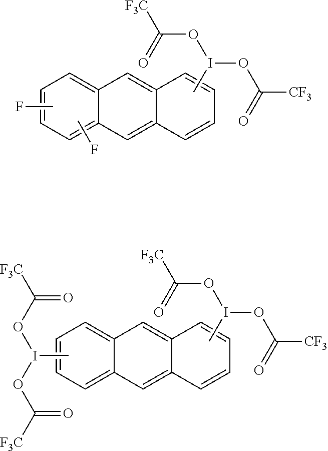

Specific examples of the hypervalent iodine compound represented by the general formula (2) include the following, but are not limited thereto.

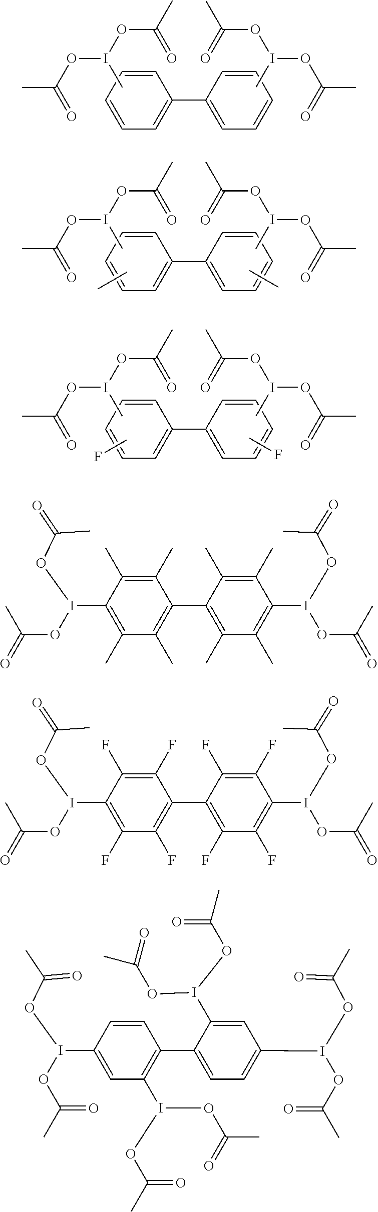

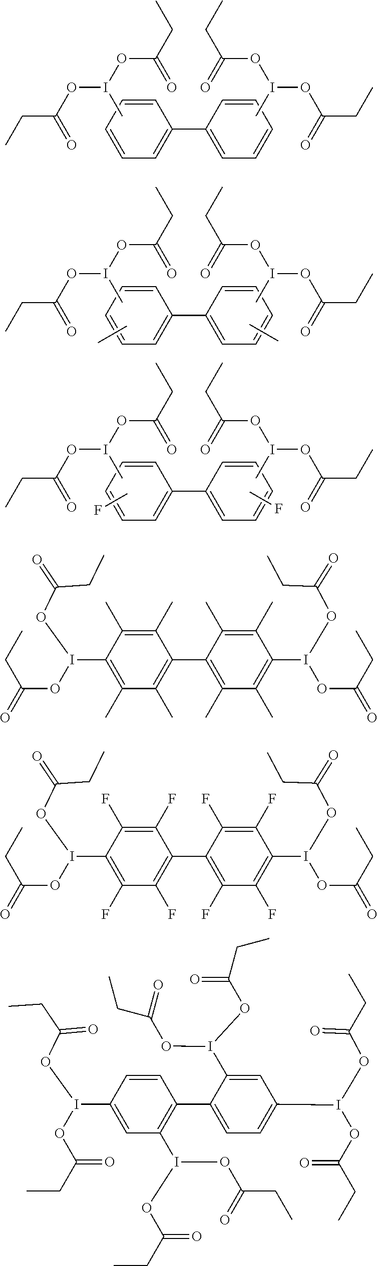

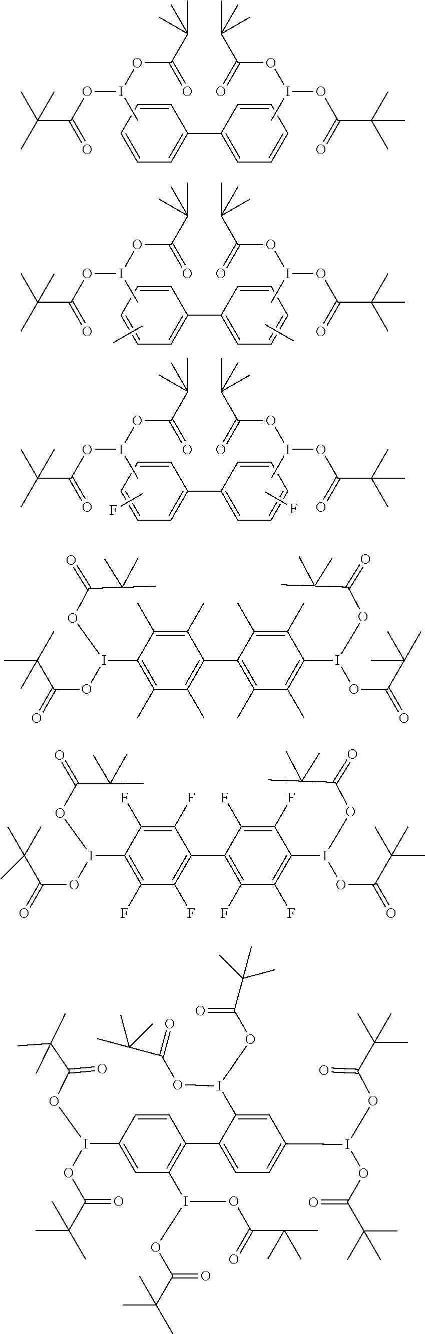

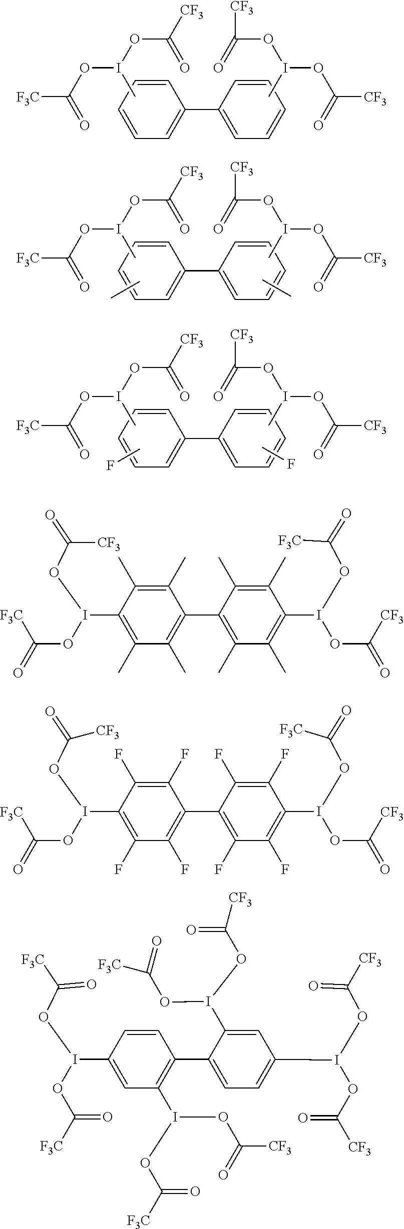

Specific examples of the hypervalent iodine compound represented by the general formula (3) include the following, but are not limited thereto.

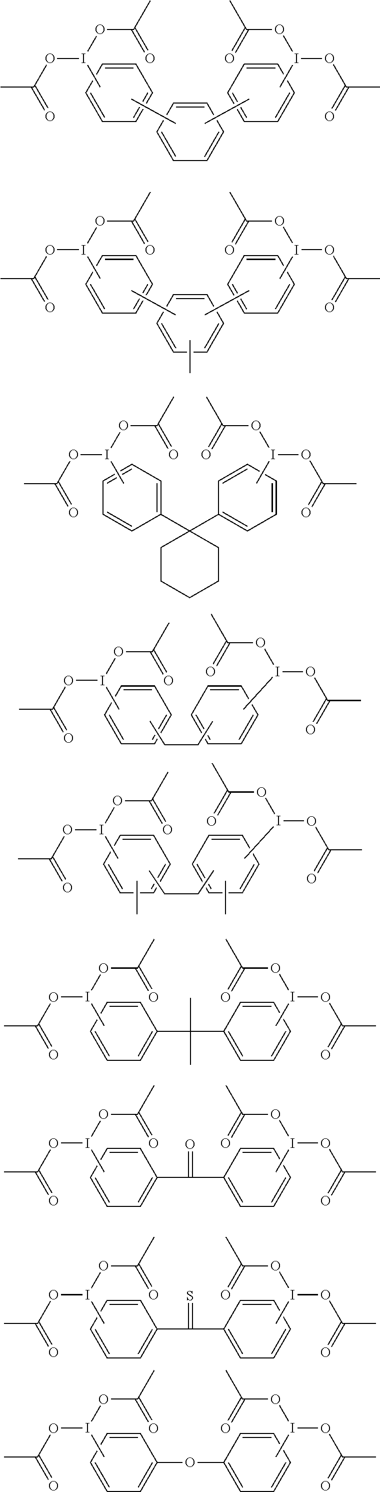

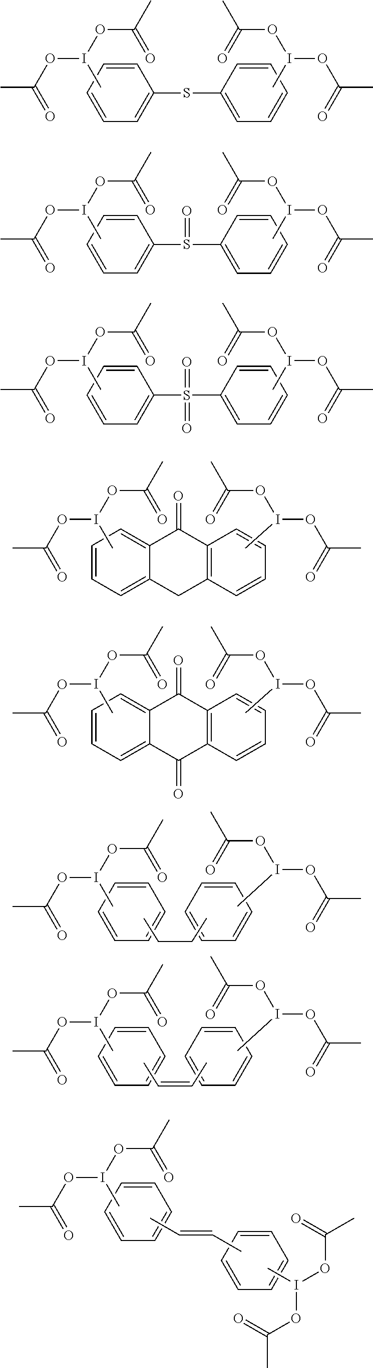

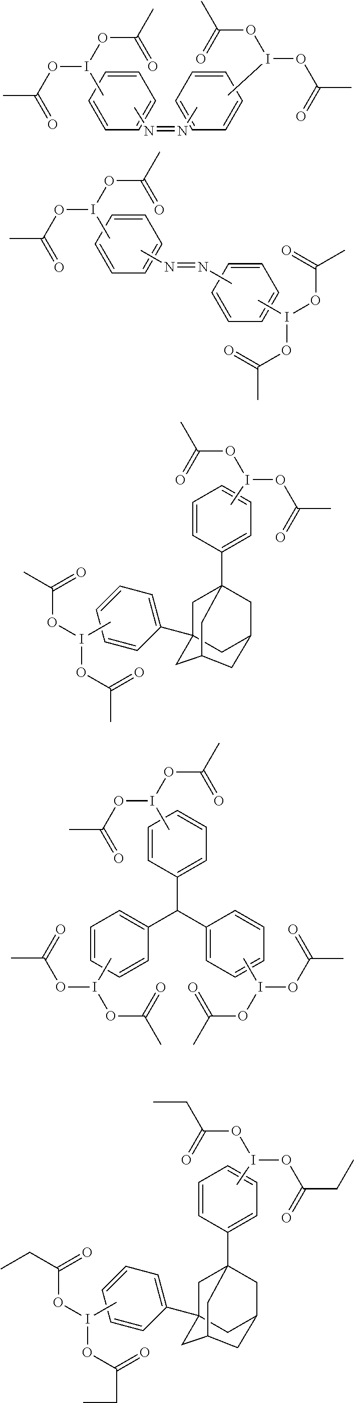

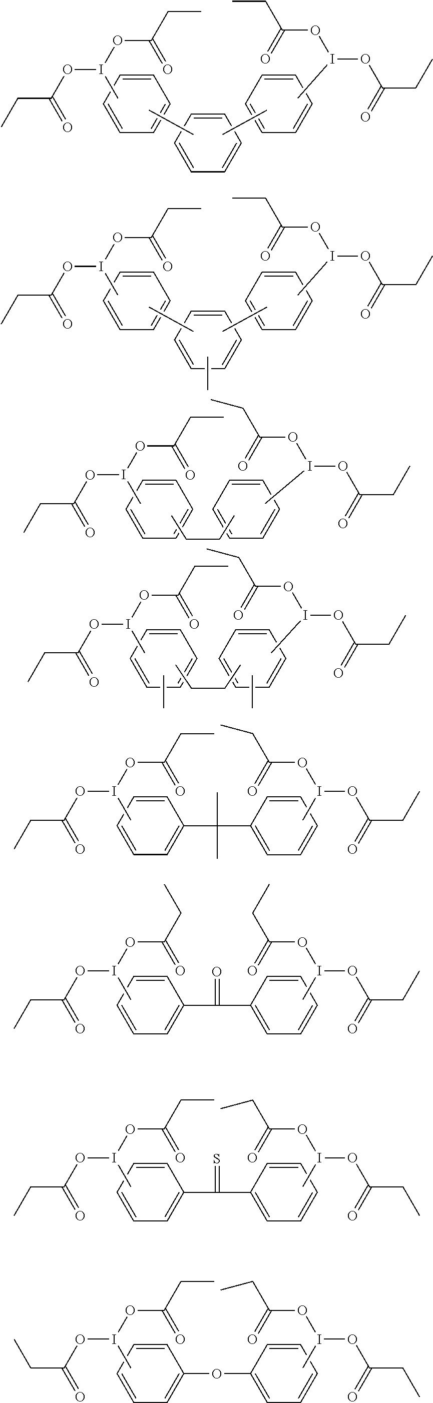

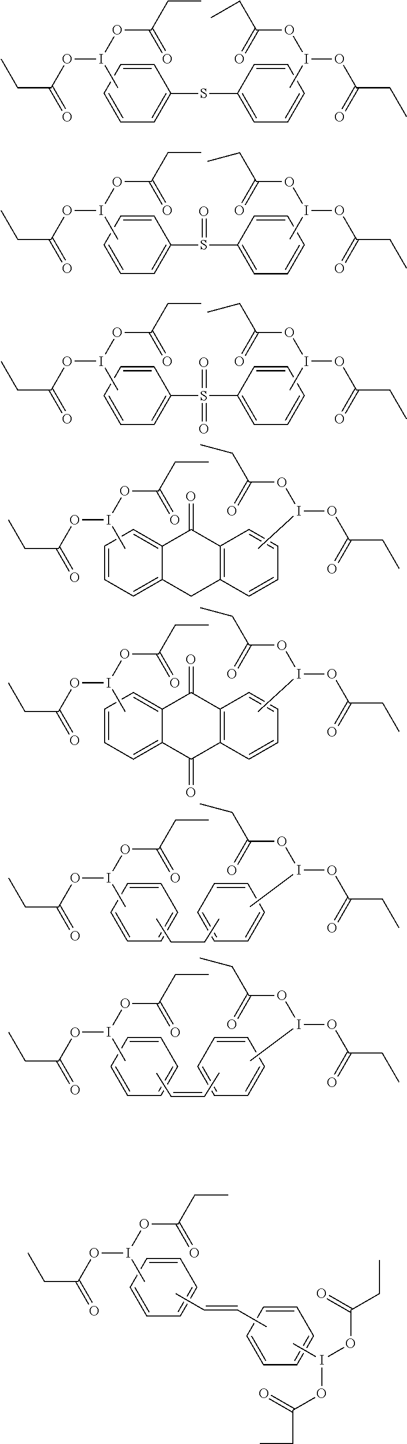

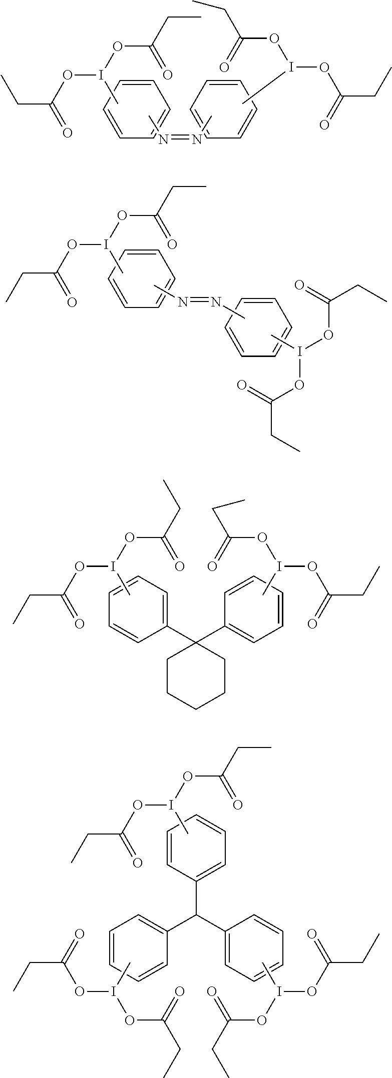

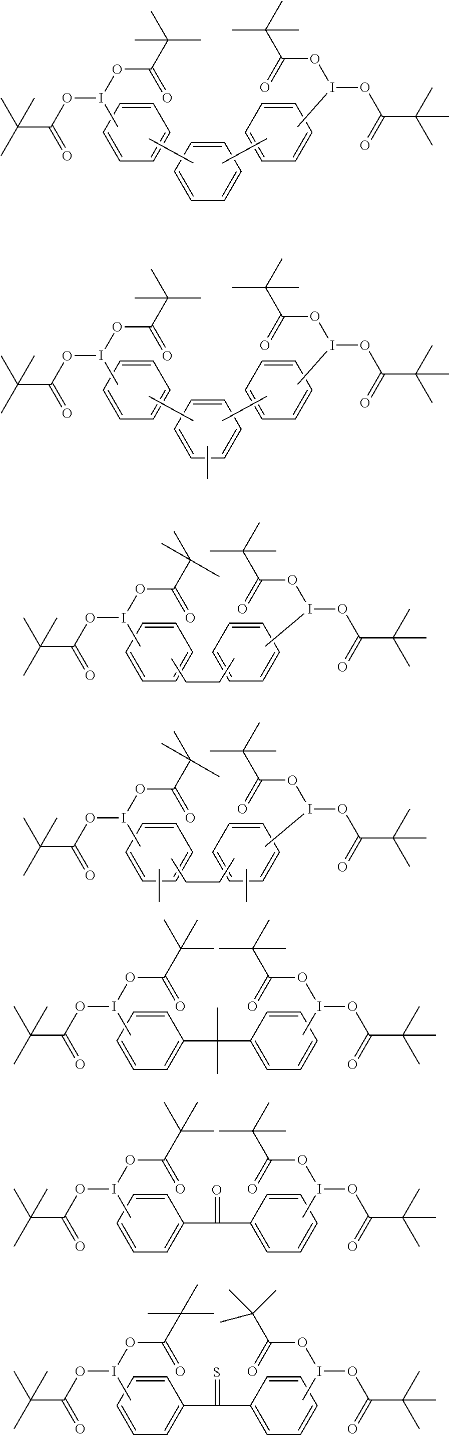

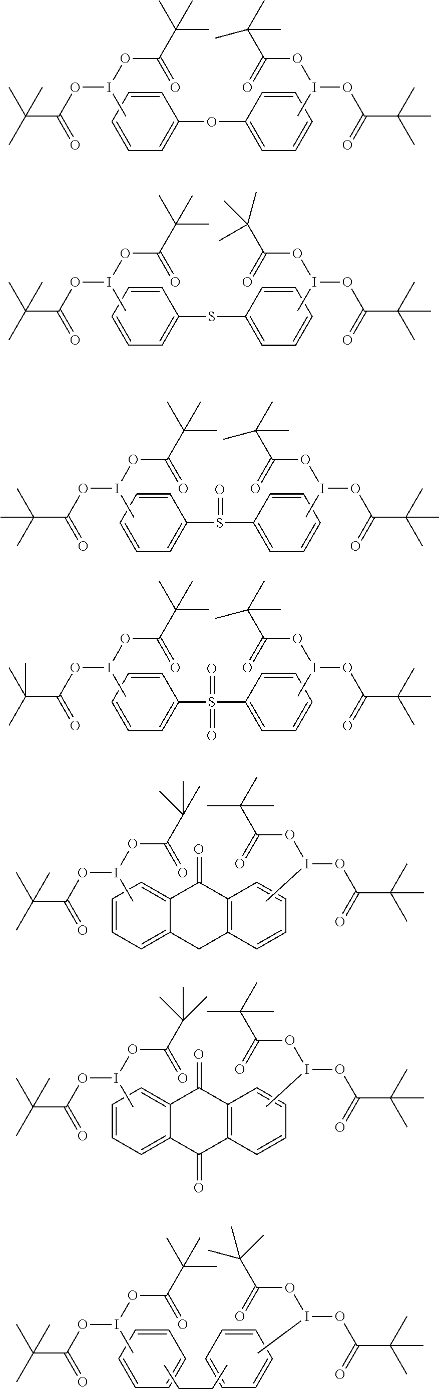

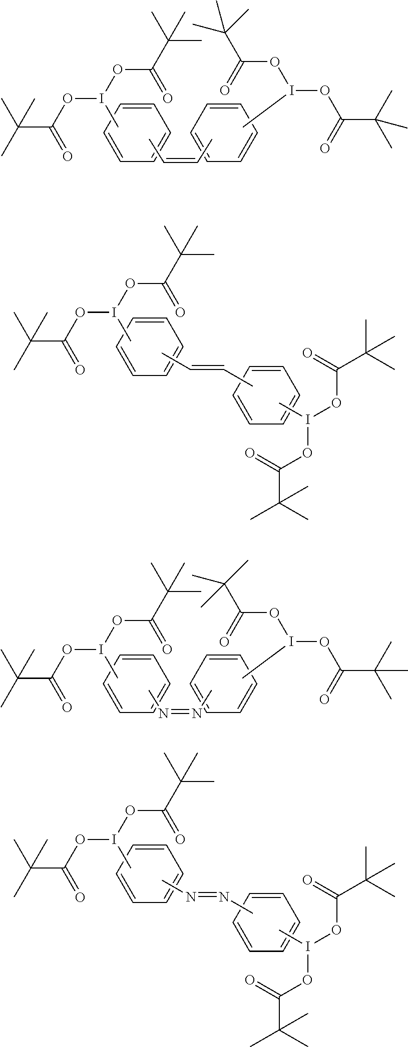

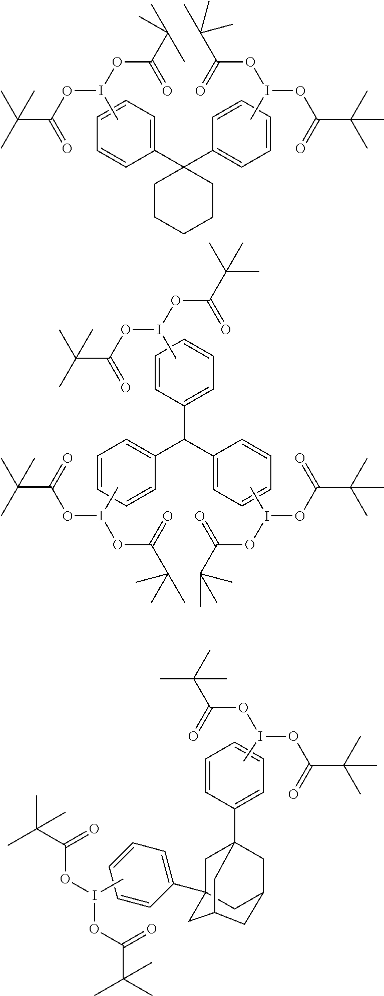

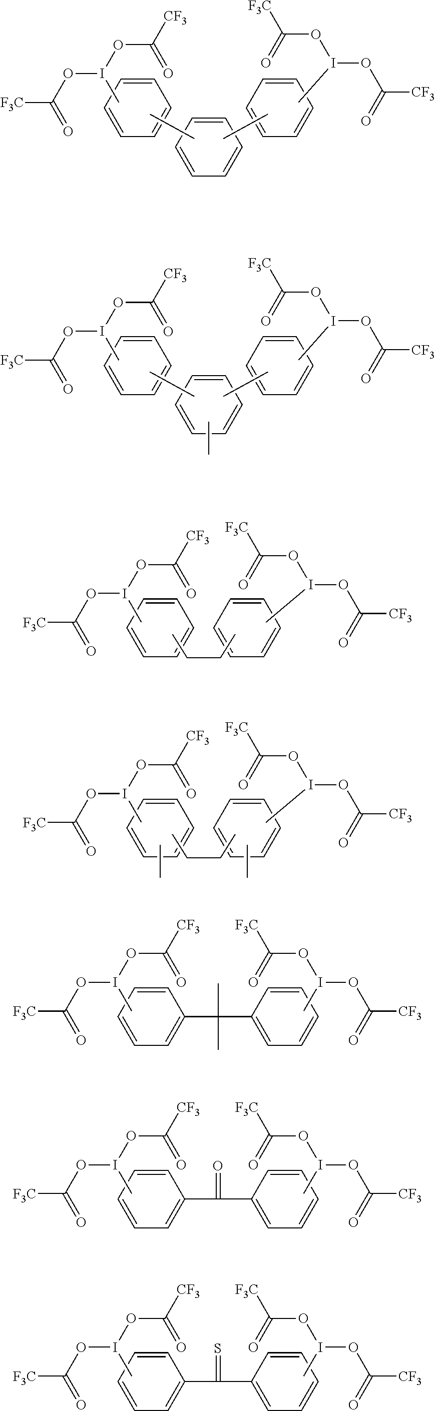

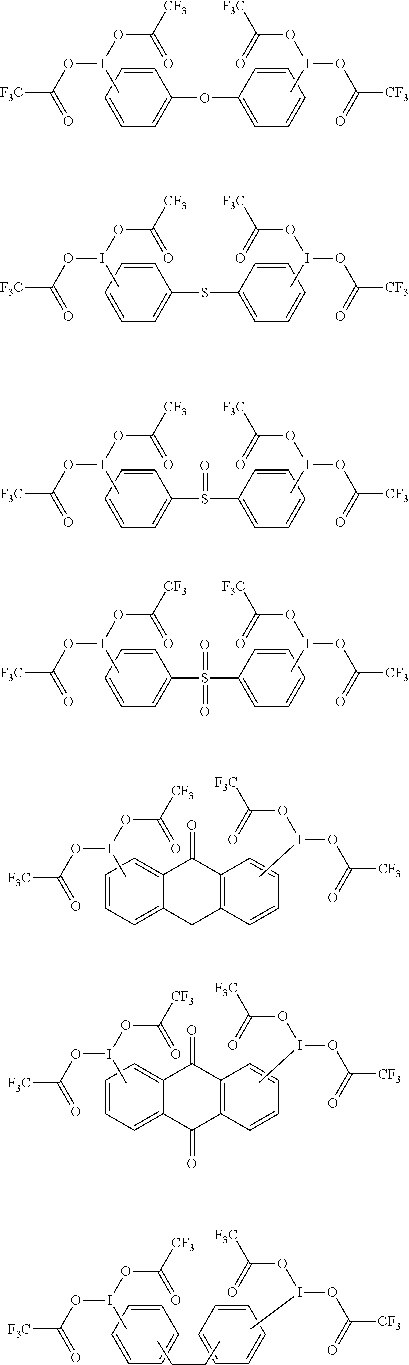

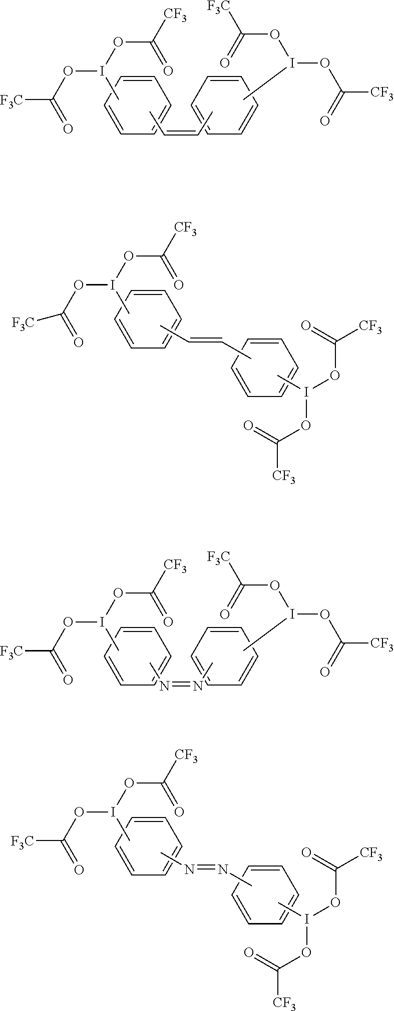

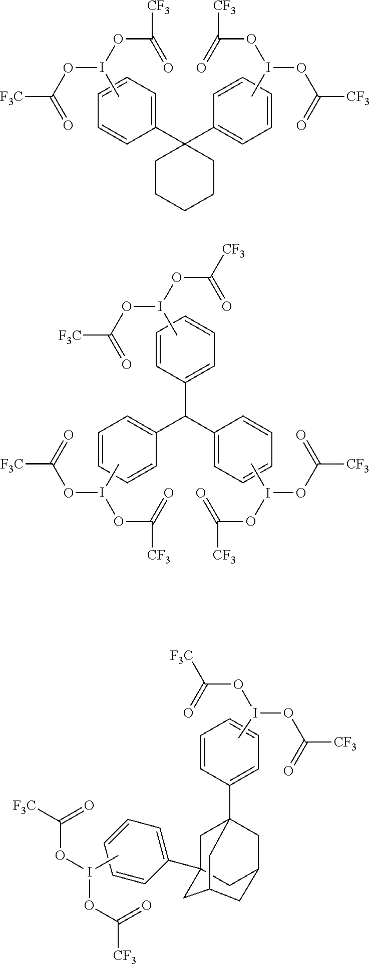

Specific examples of the hypervalent iodine compound represented by the general formula (4) include the following, but are not limited thereto. Note that, in the following formulae, Me represents a methyl group.

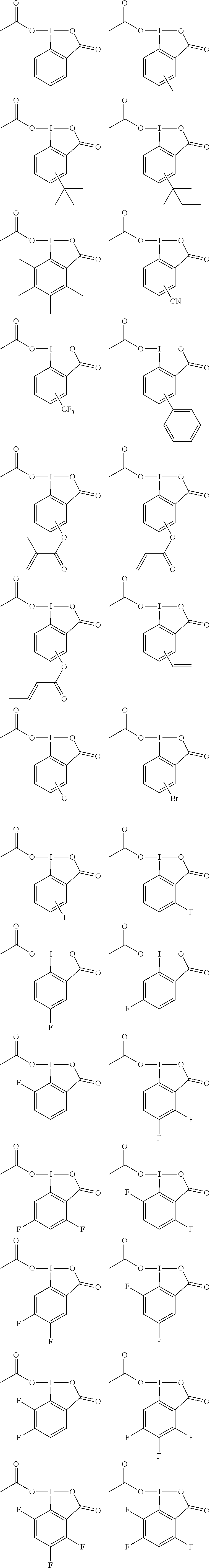

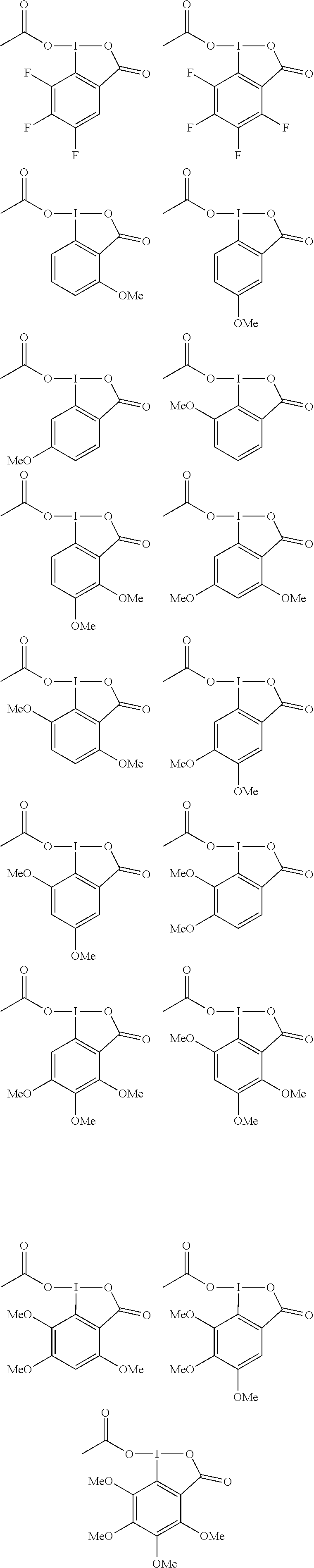

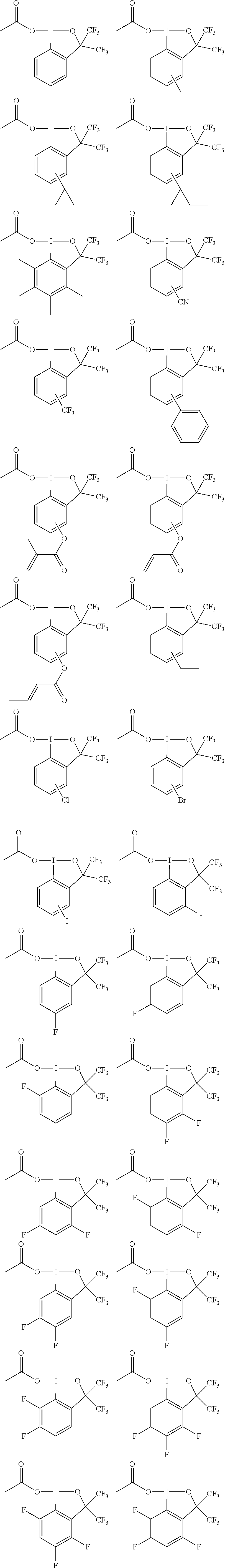

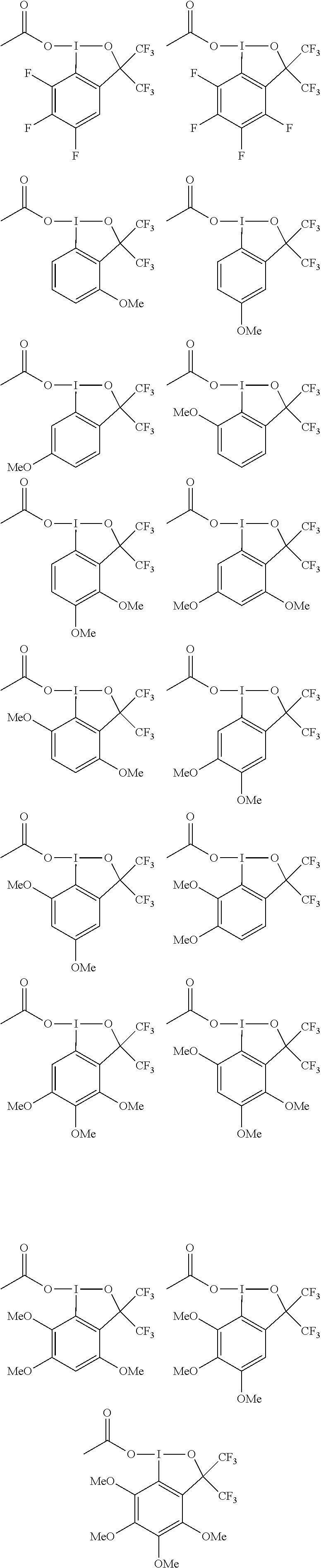

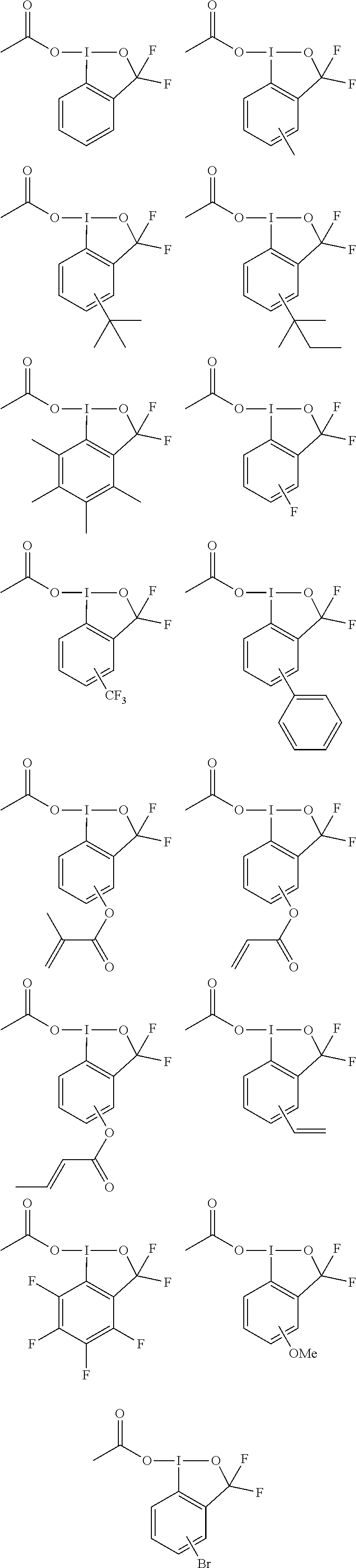

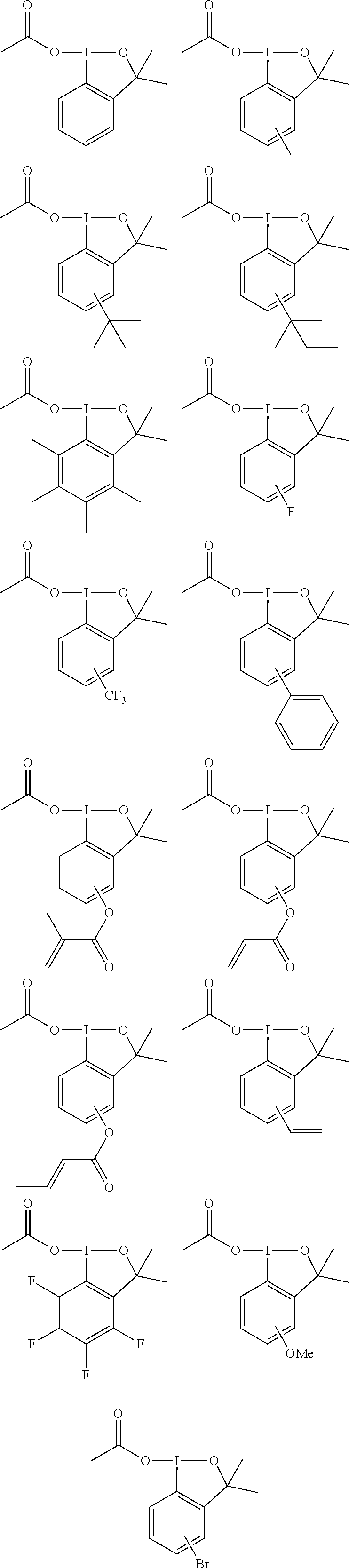

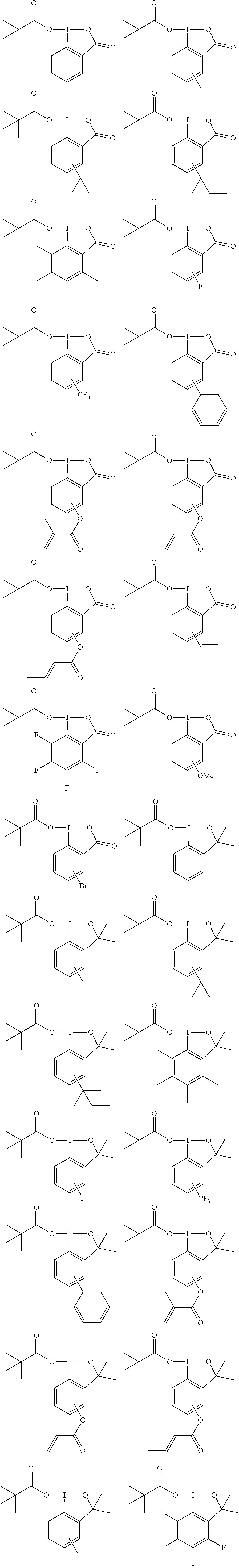

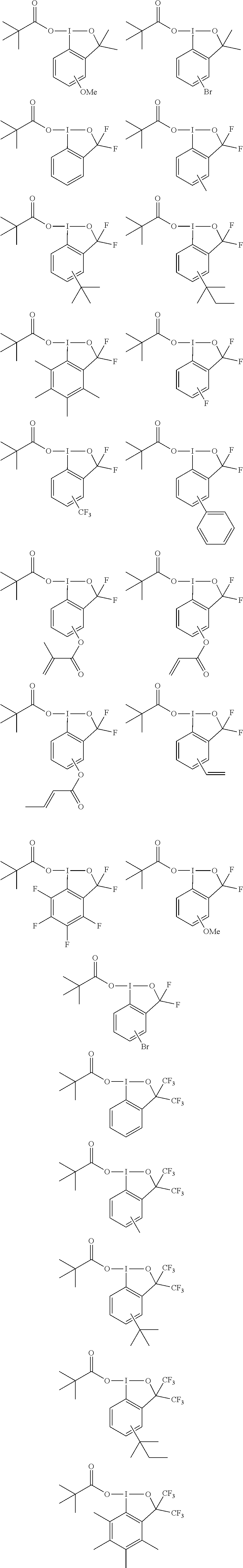

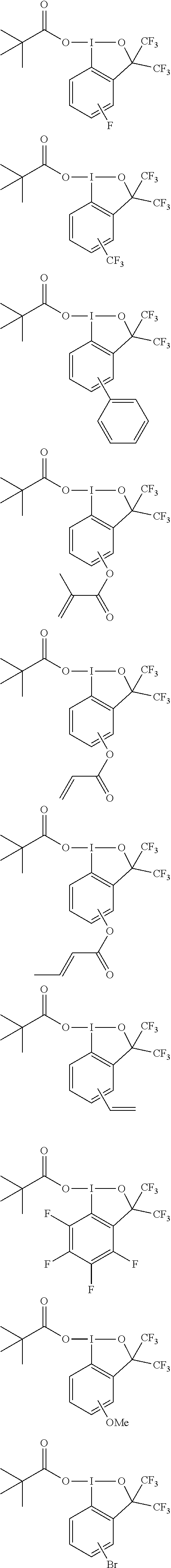

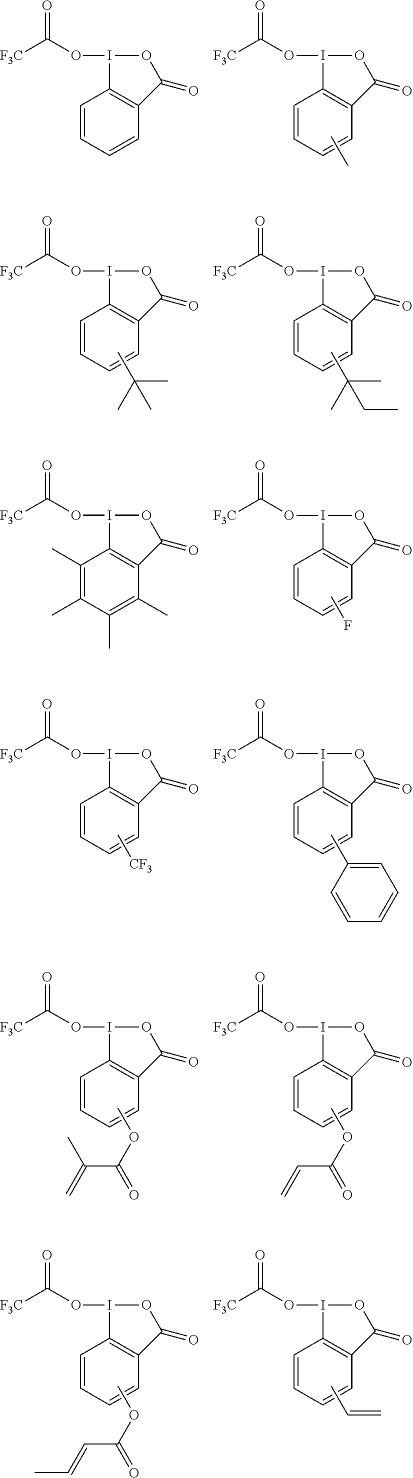

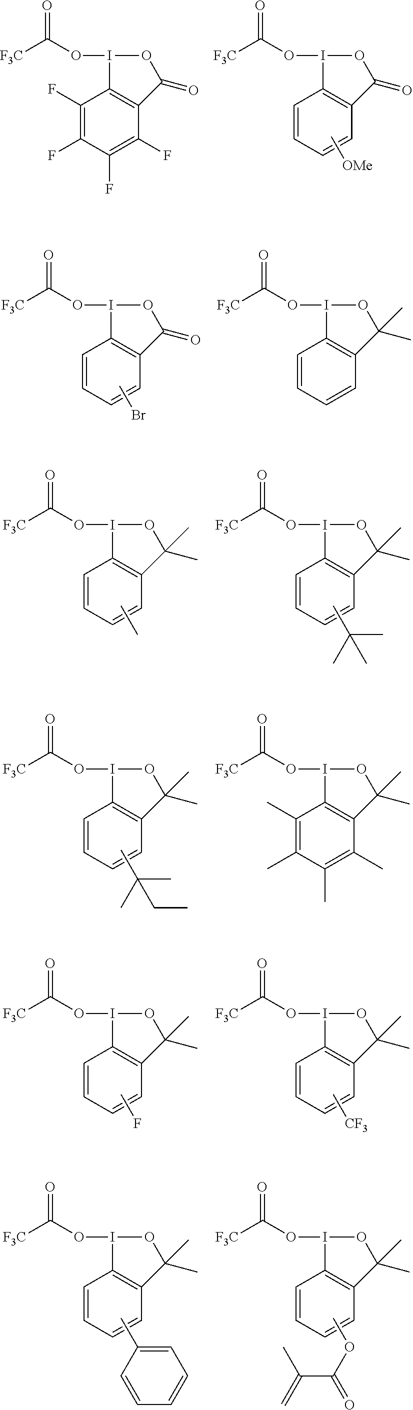

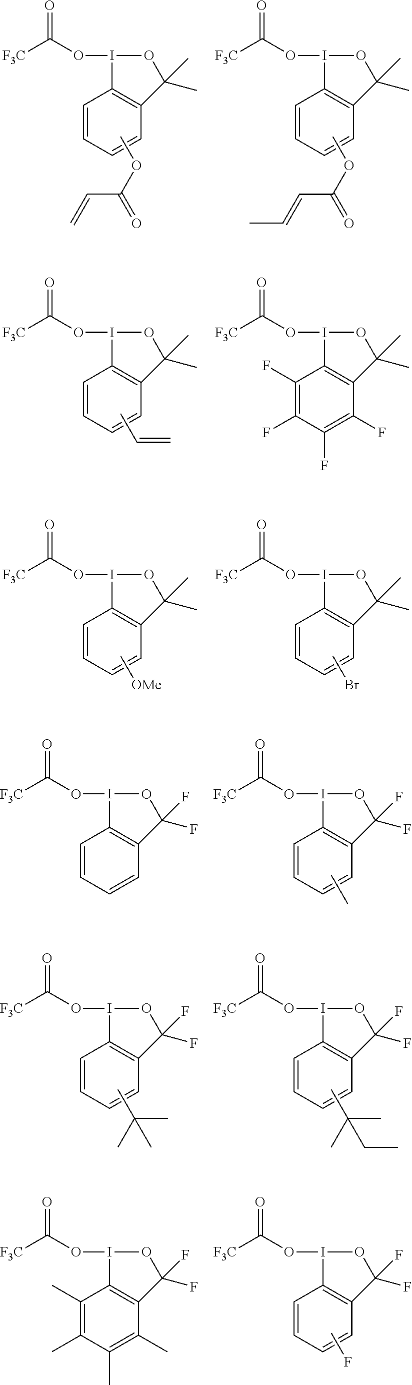

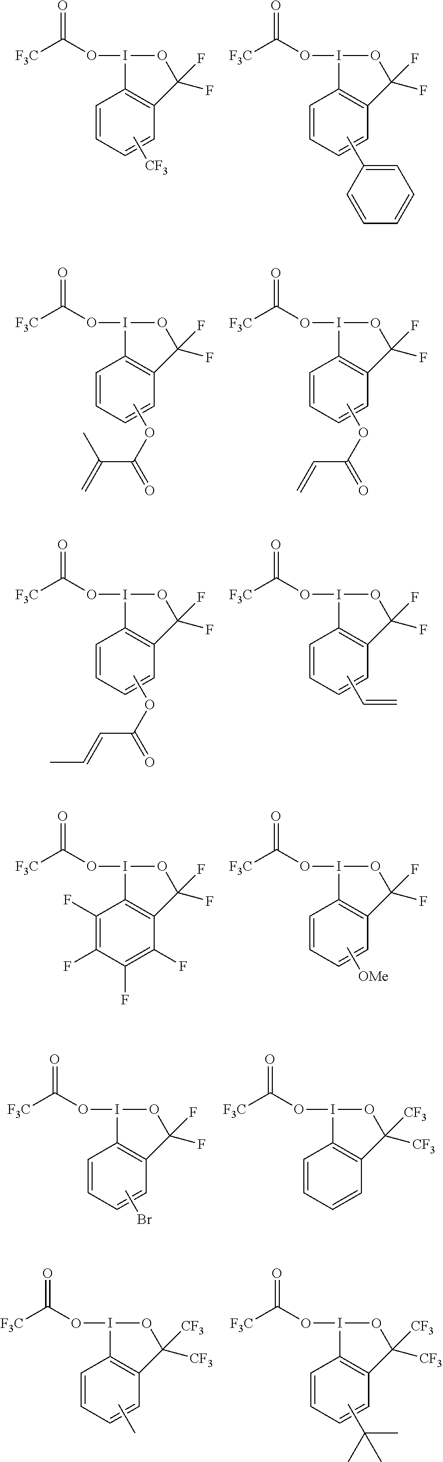

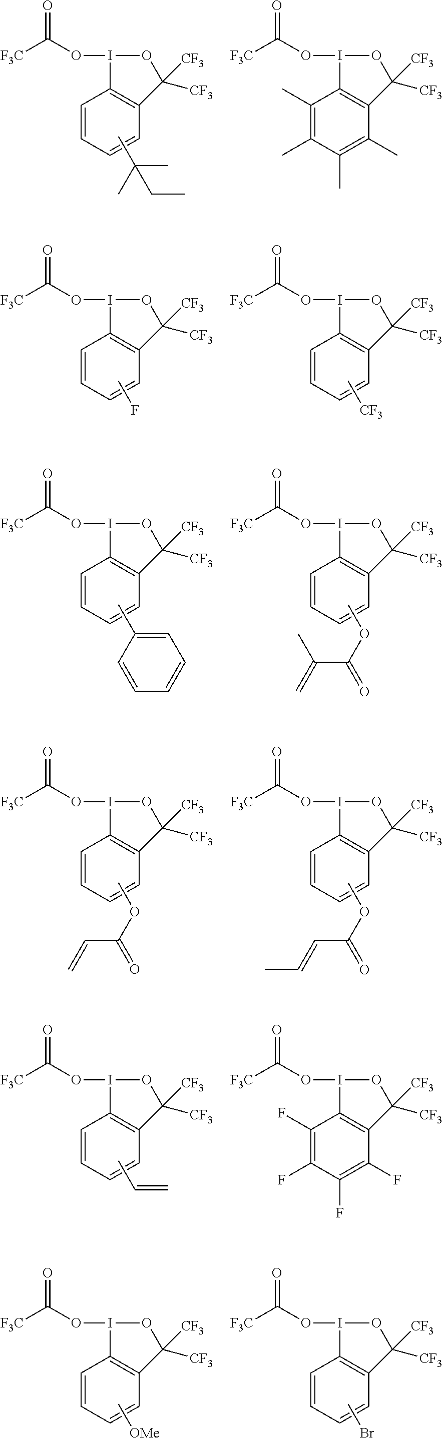

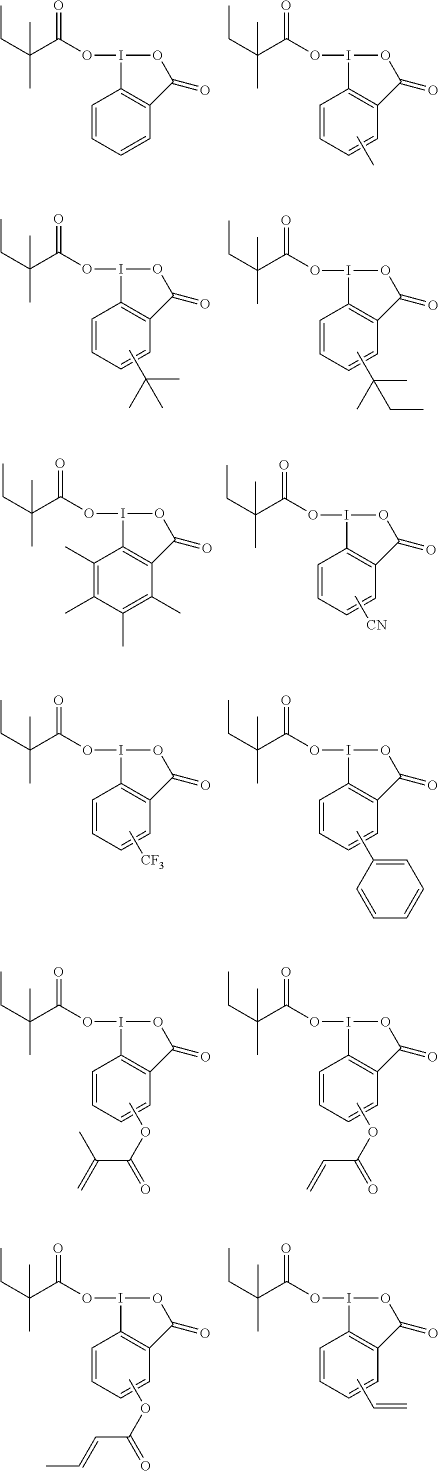

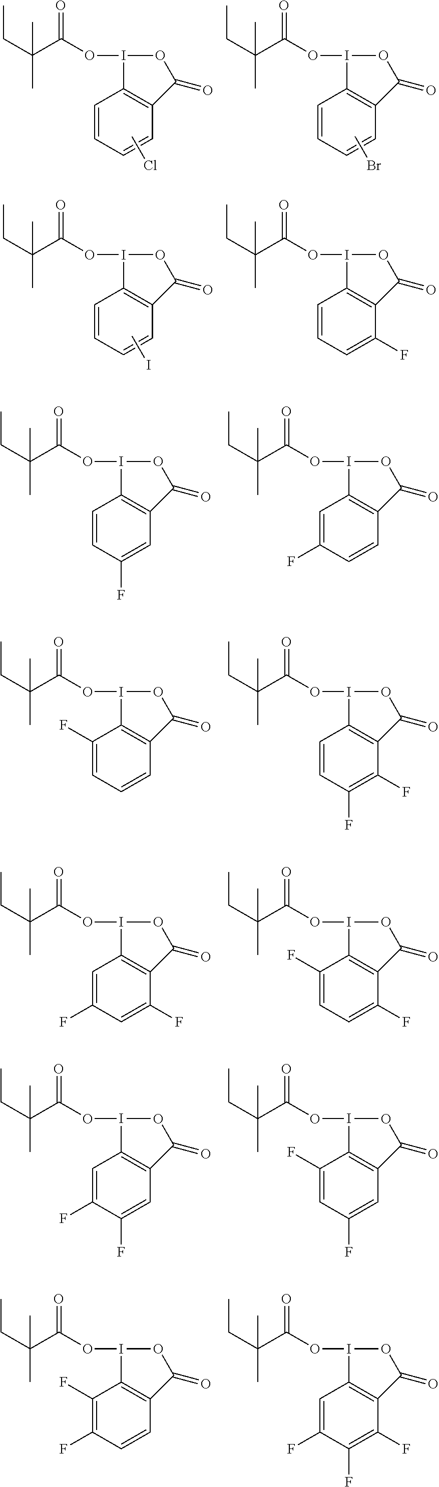

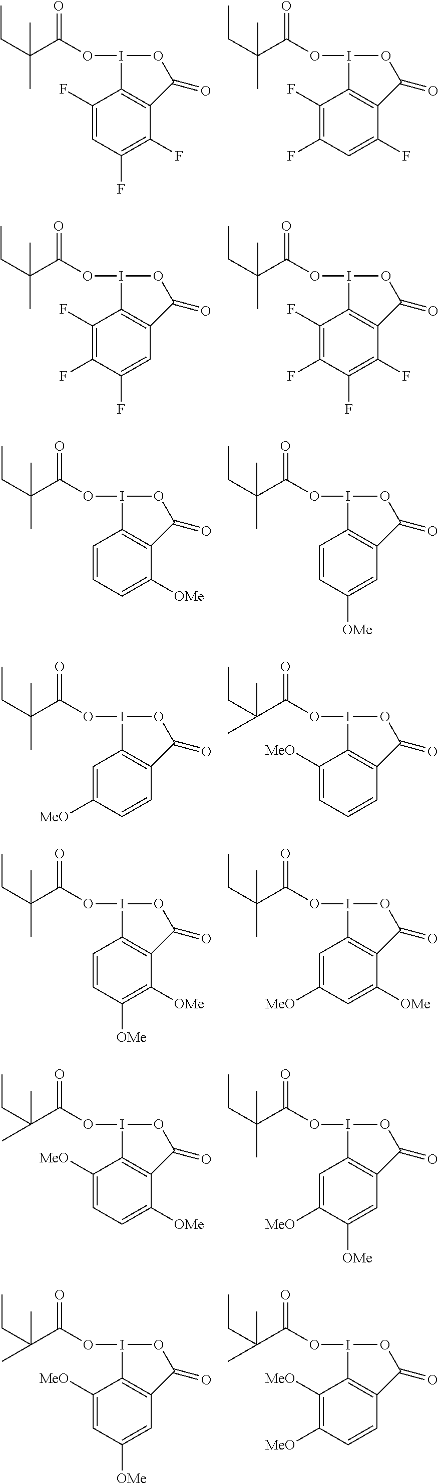

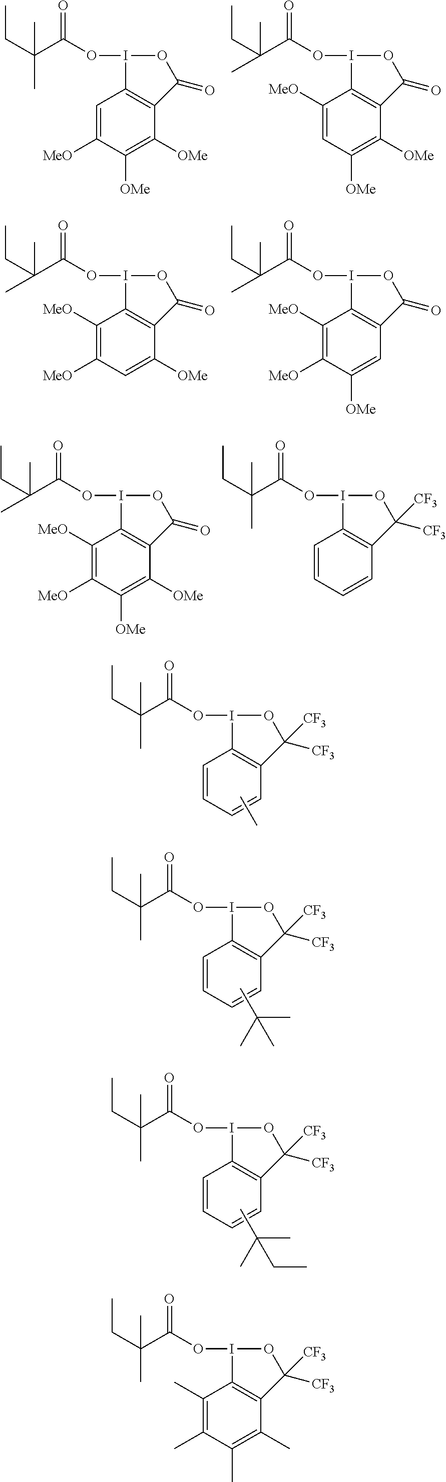

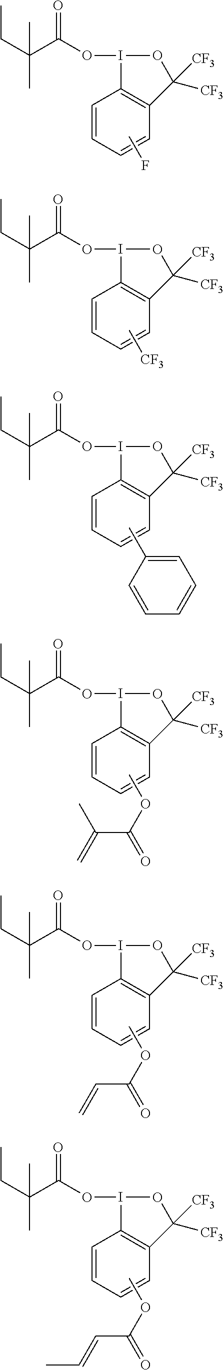

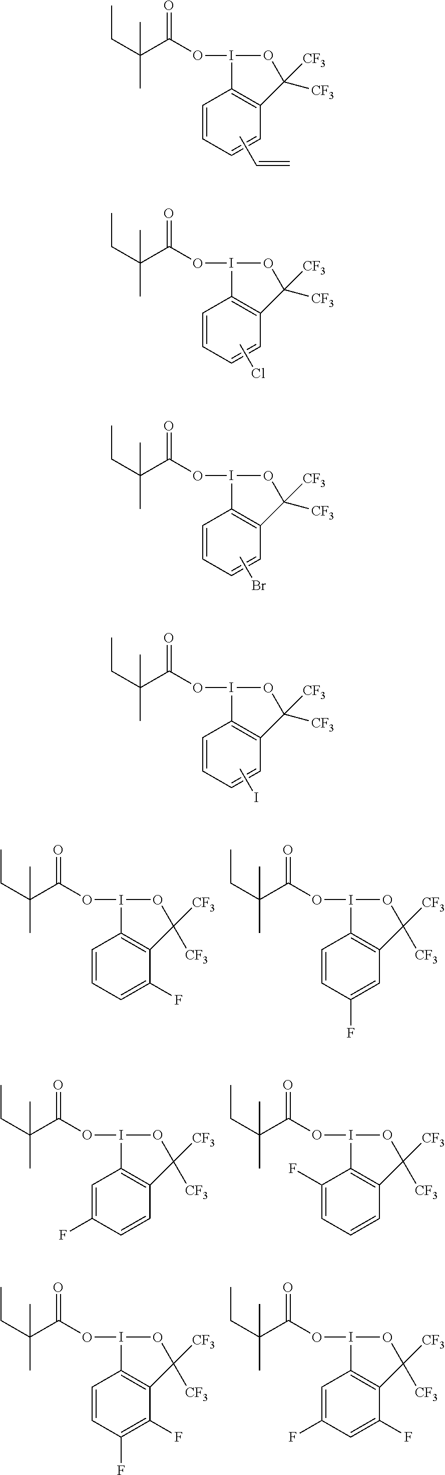

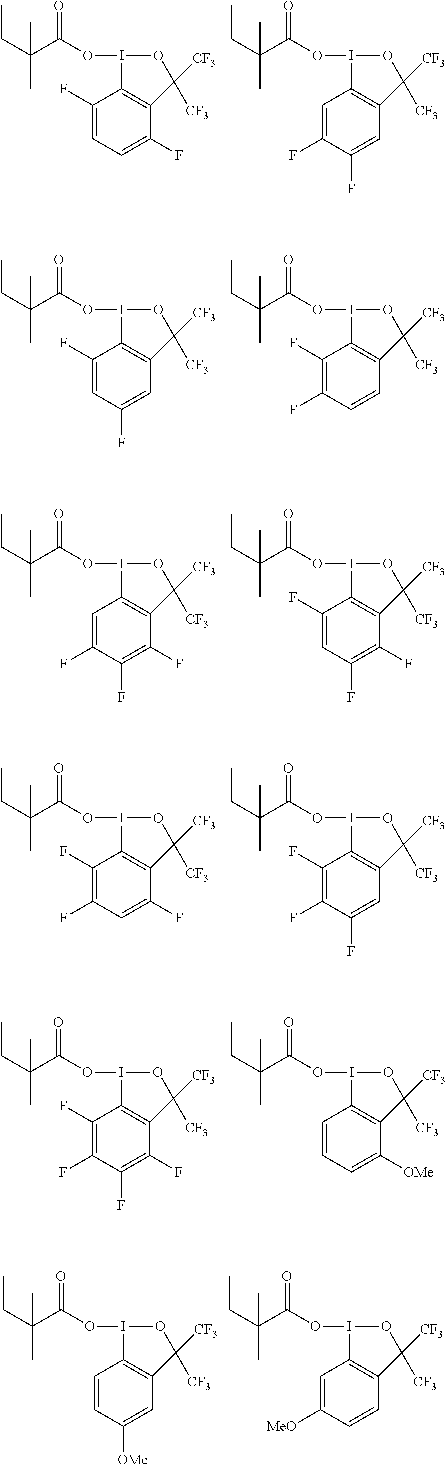

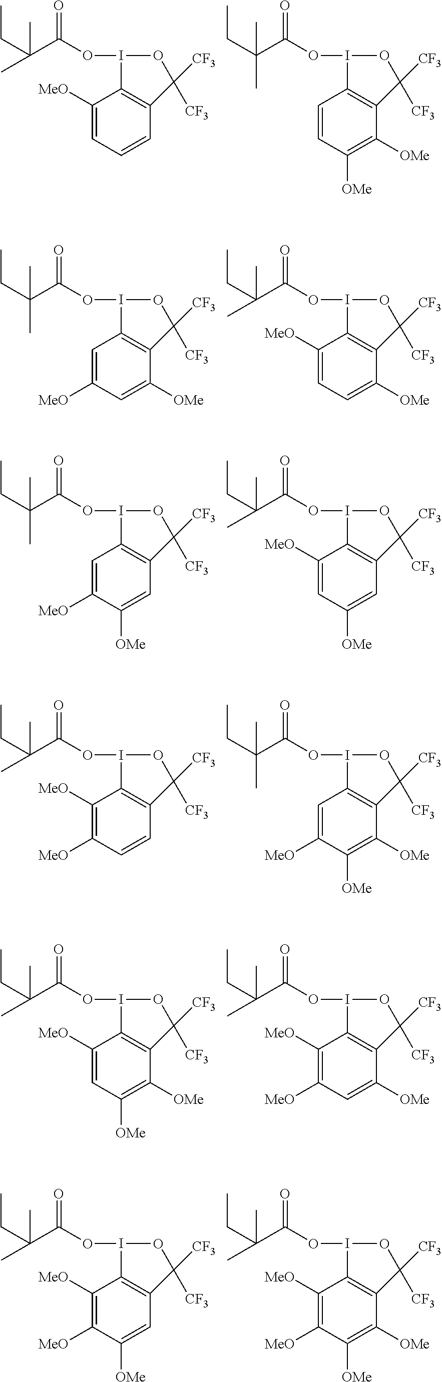

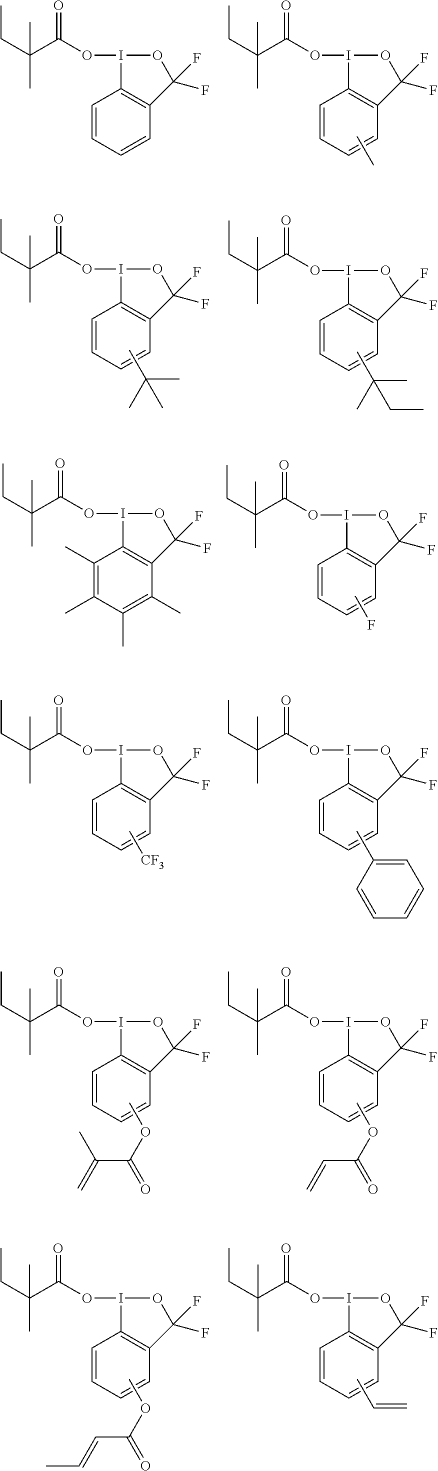

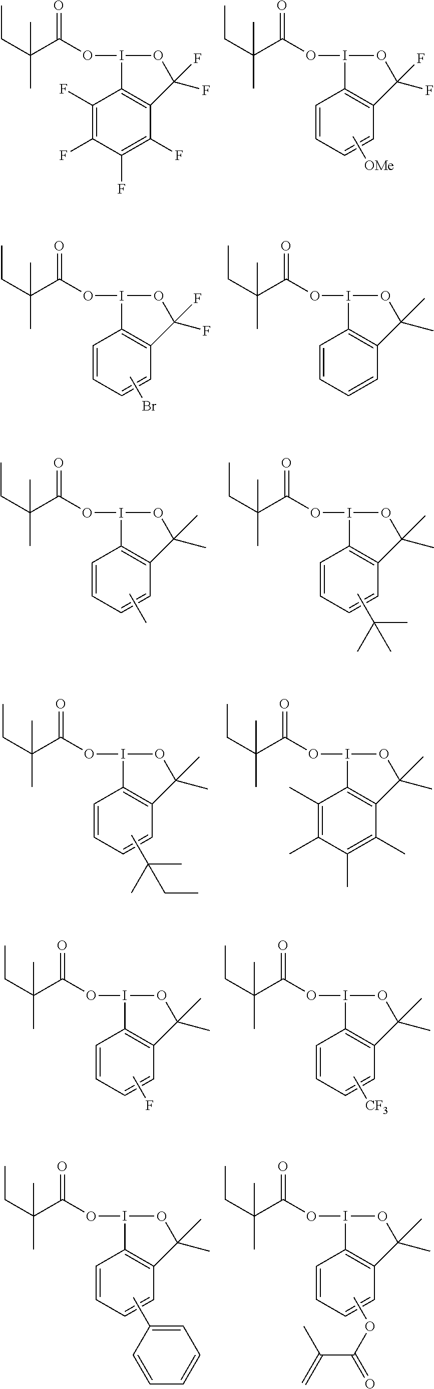

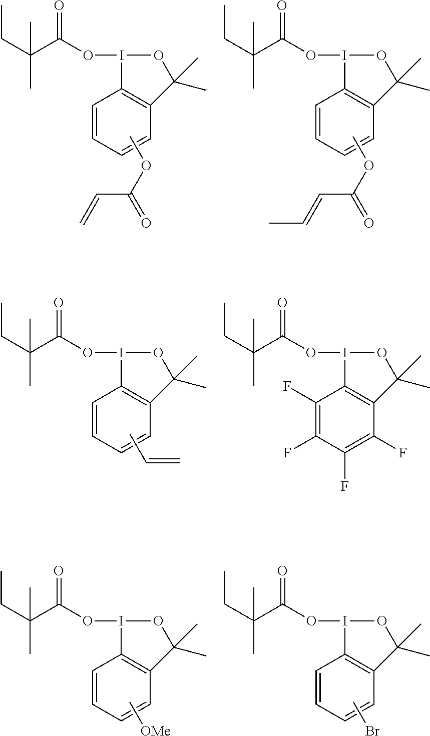

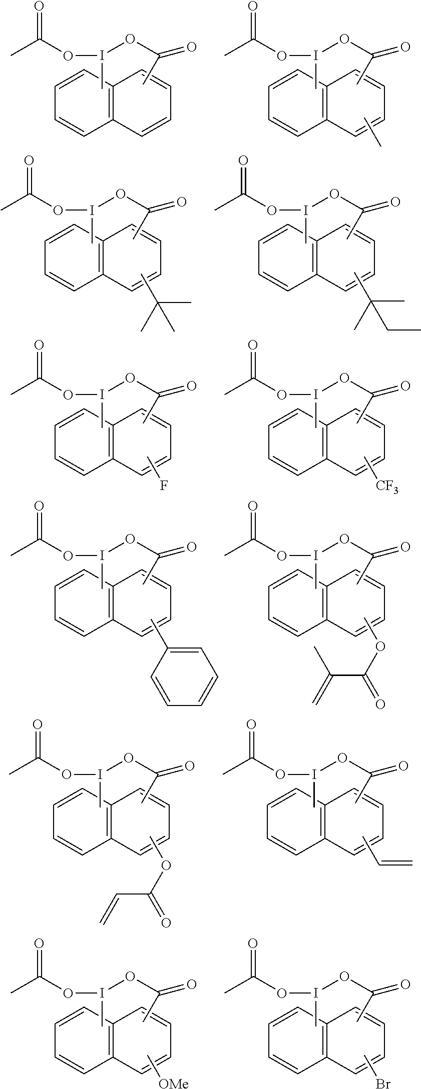

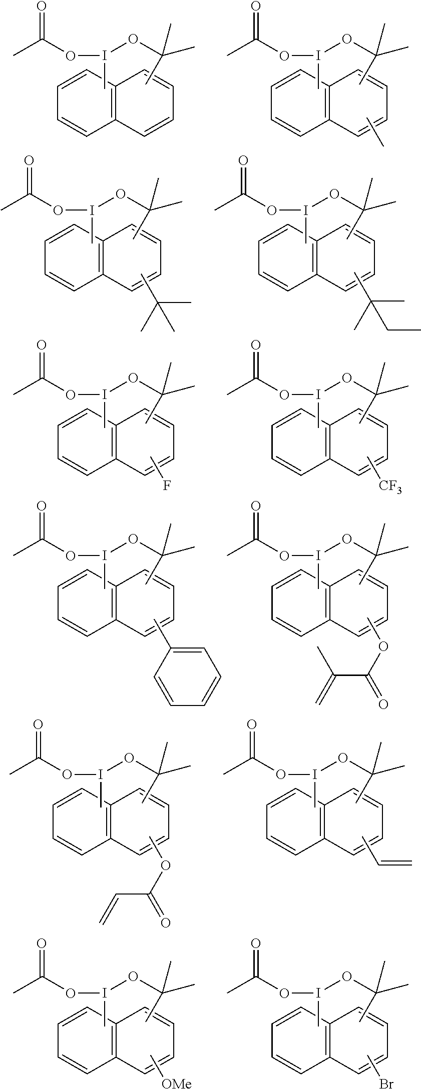

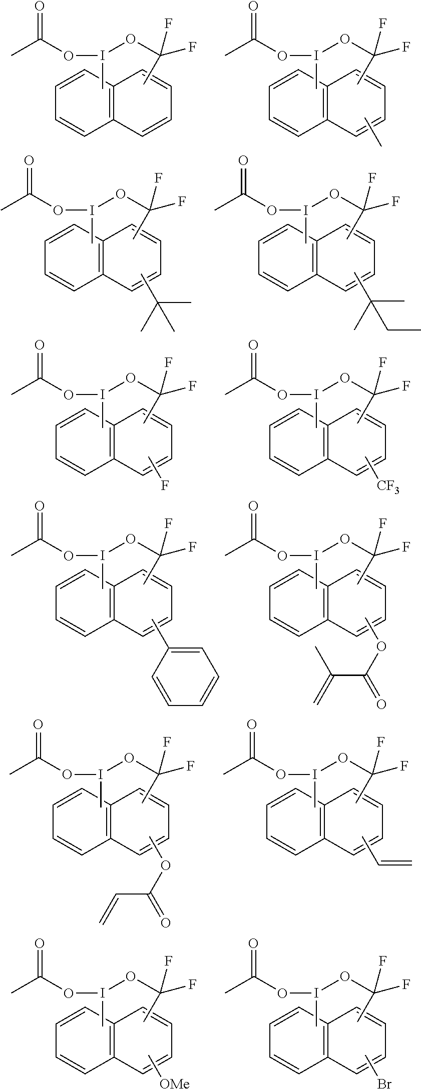

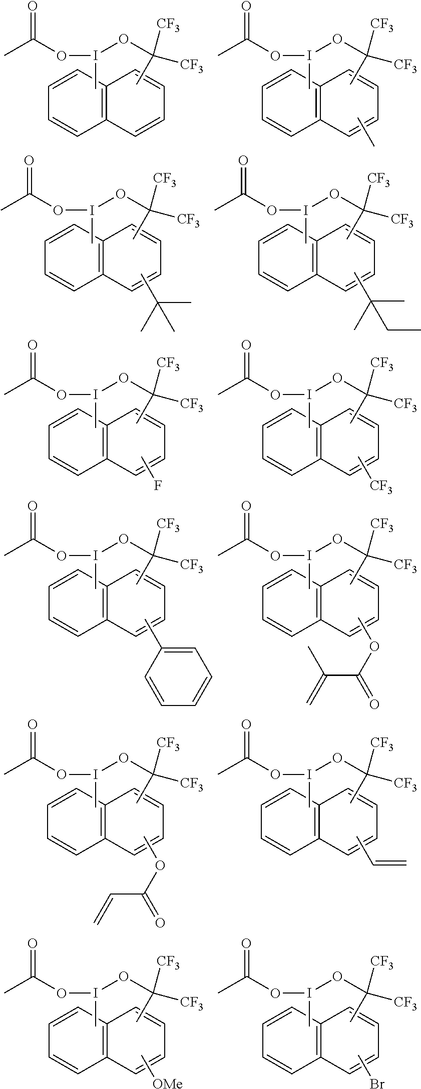

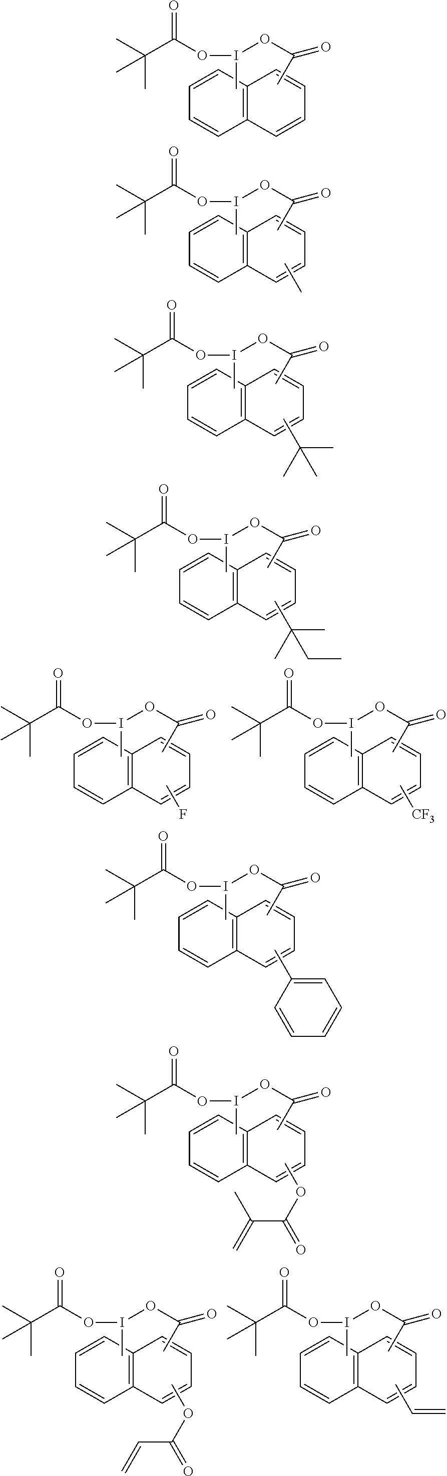

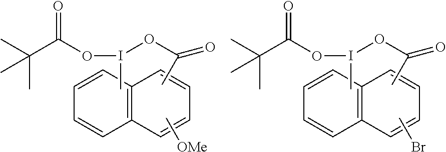

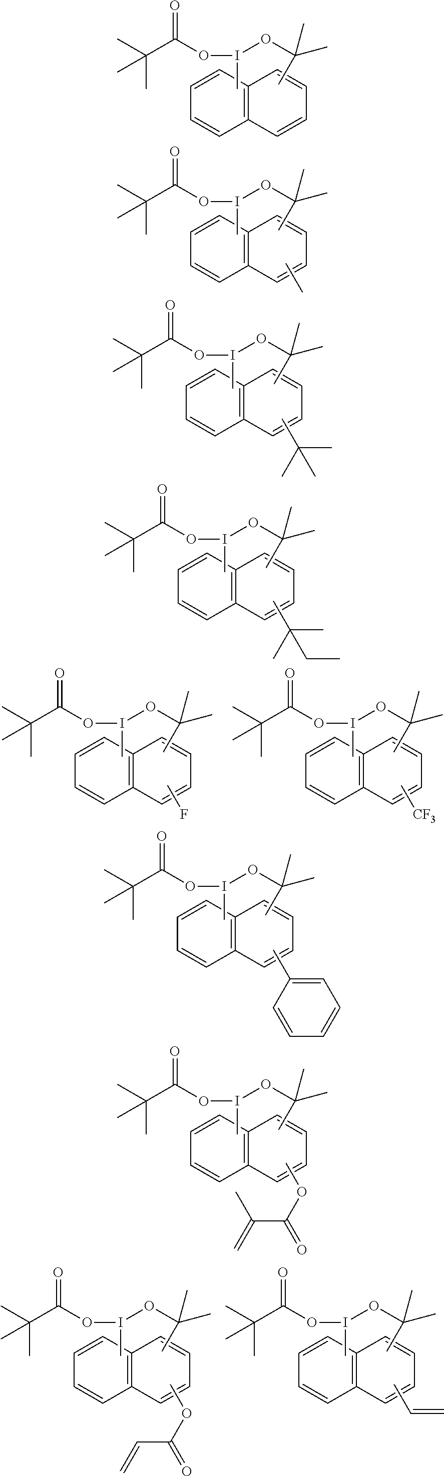

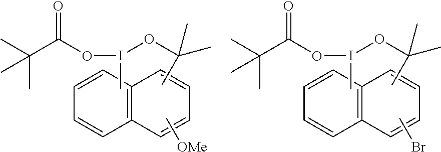

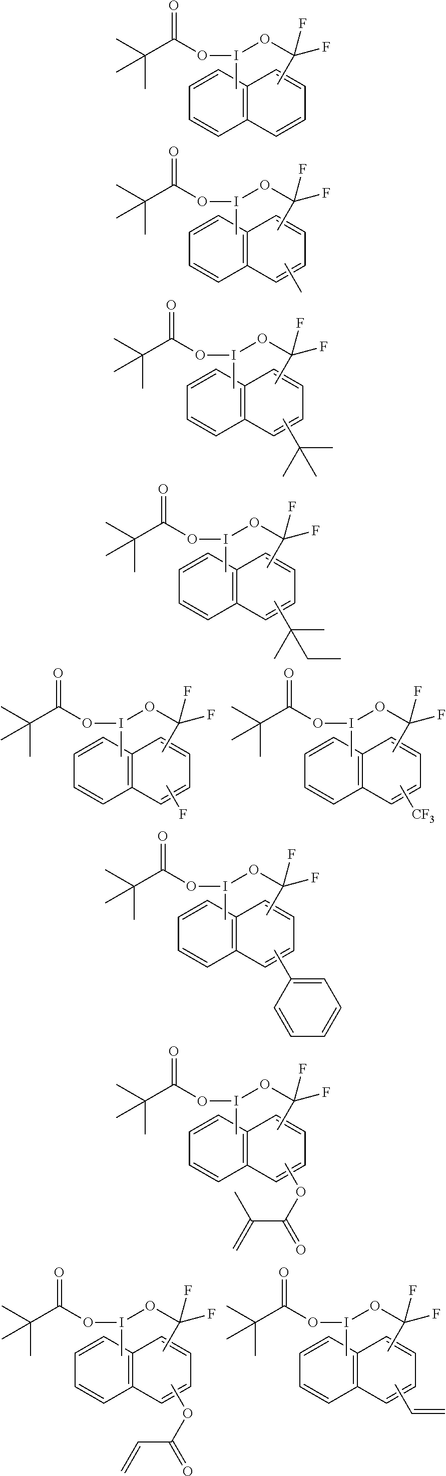

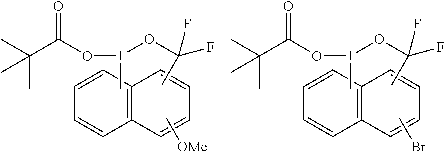

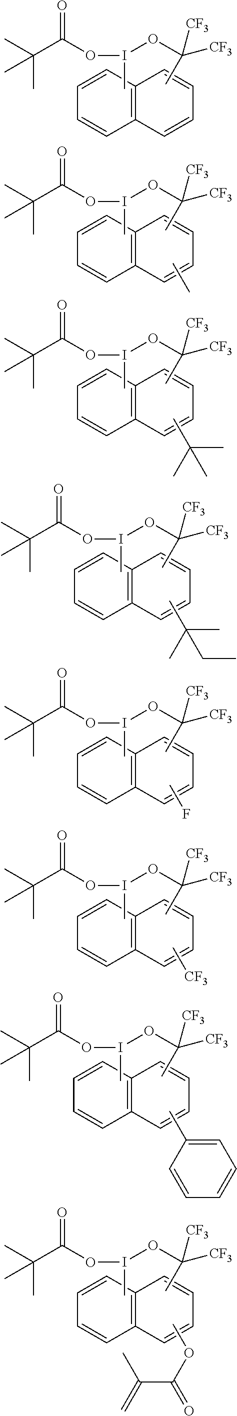

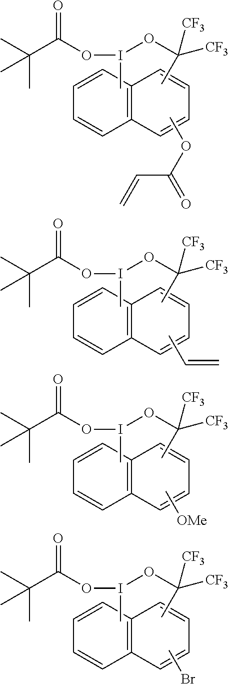

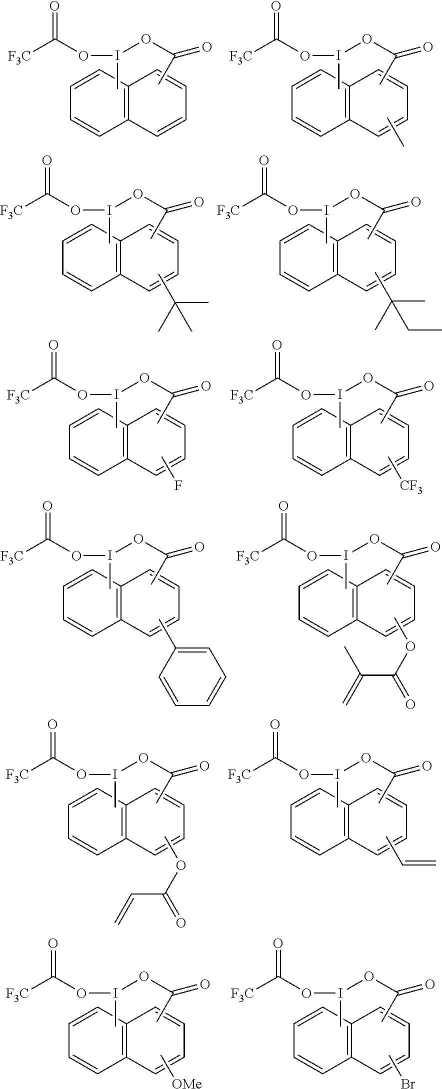

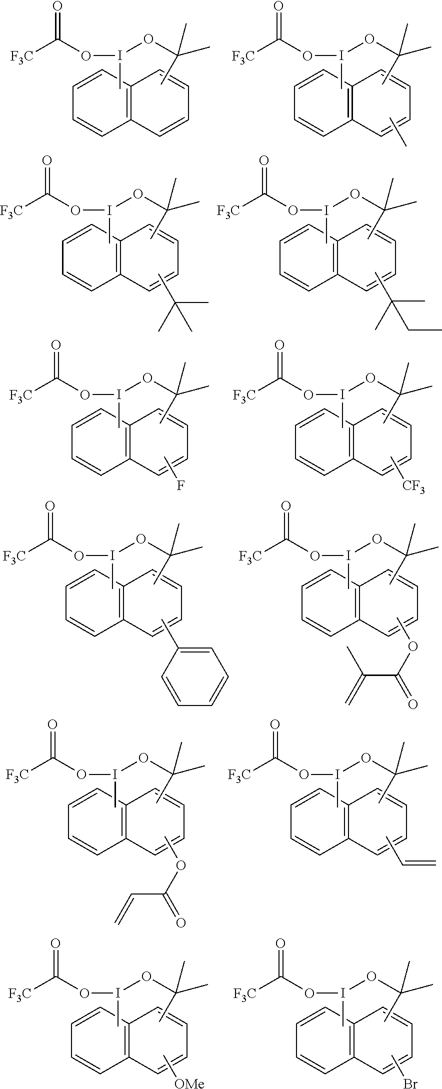

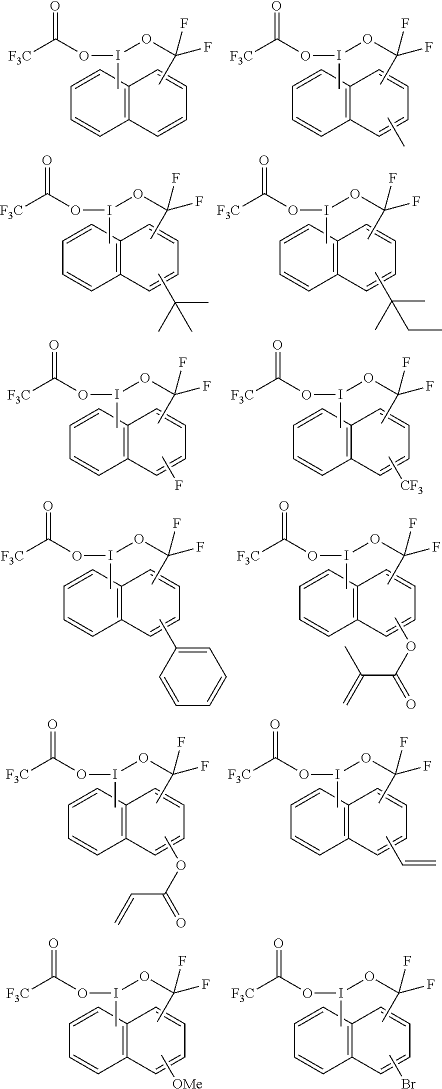

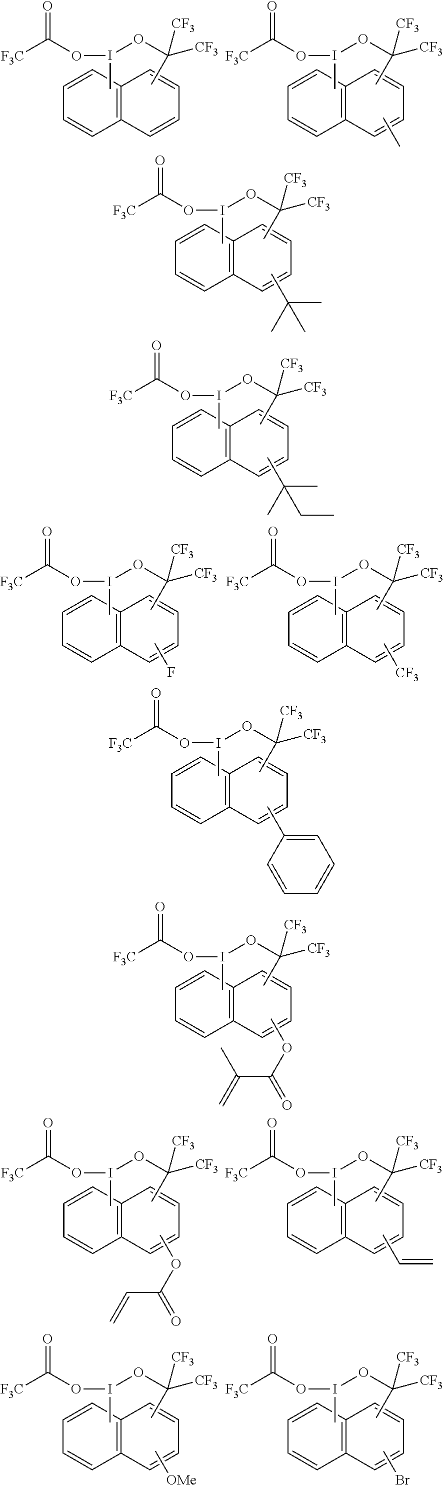

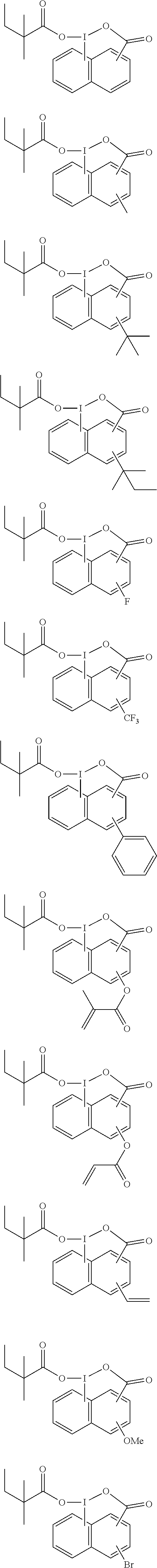

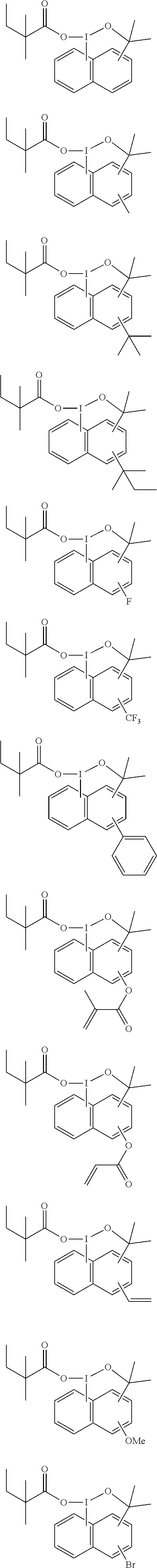

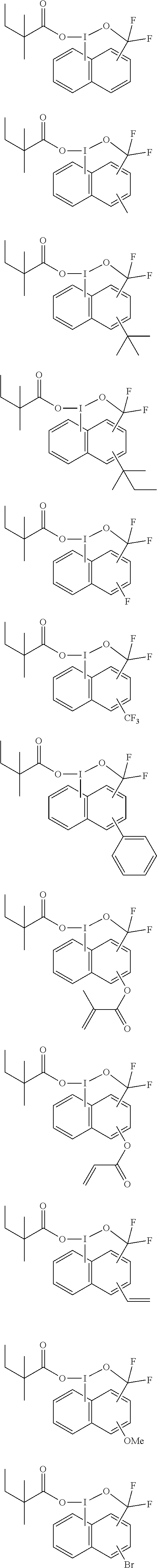

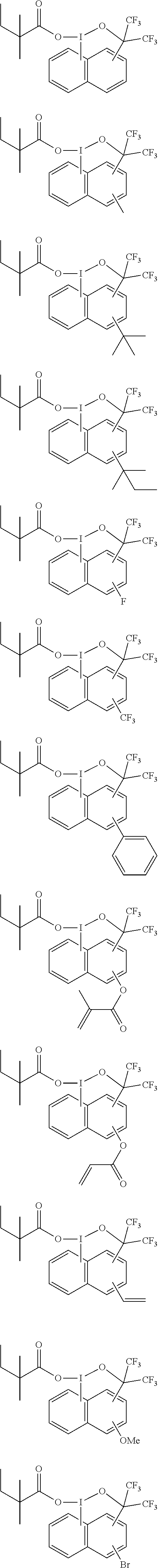

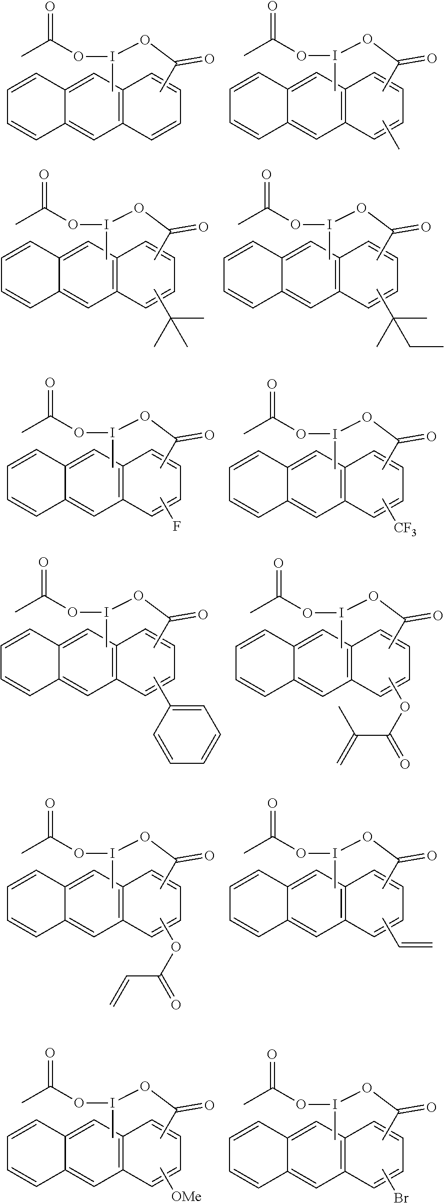

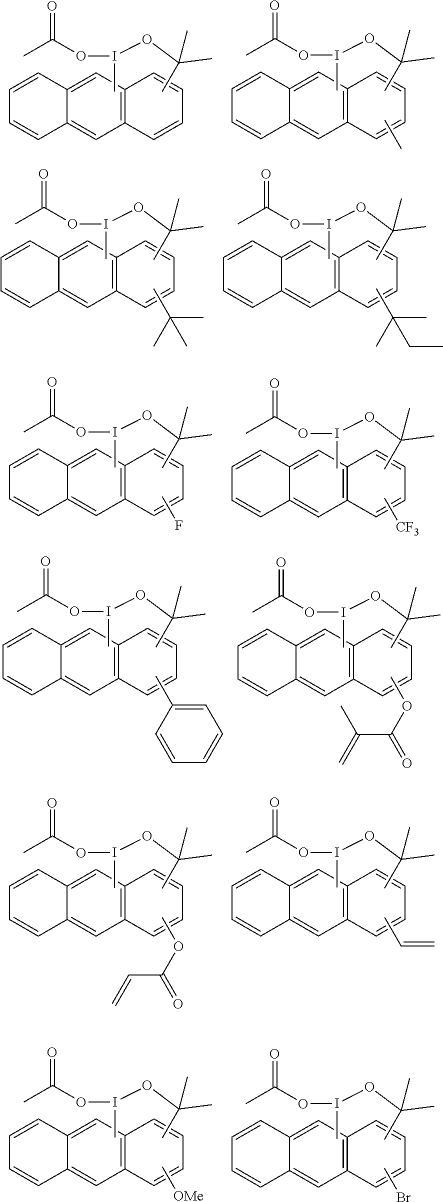

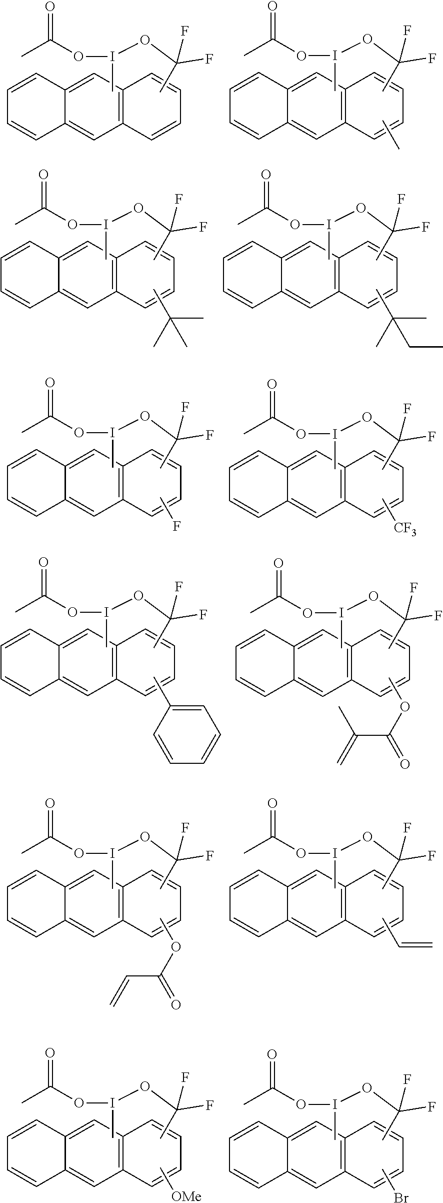

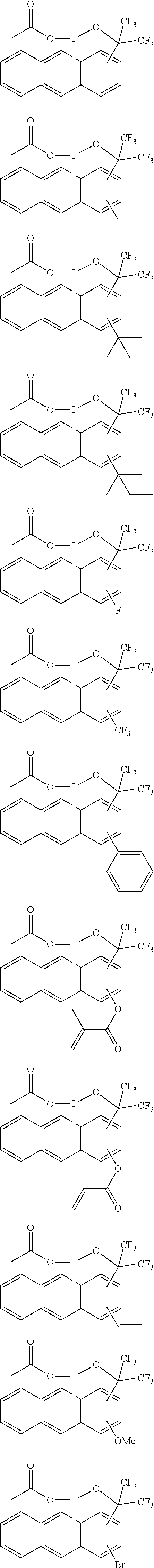

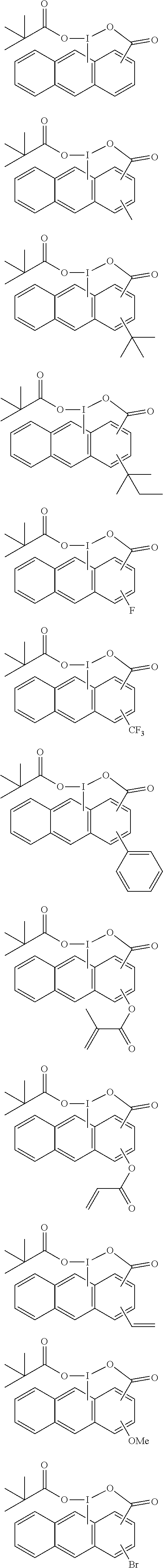

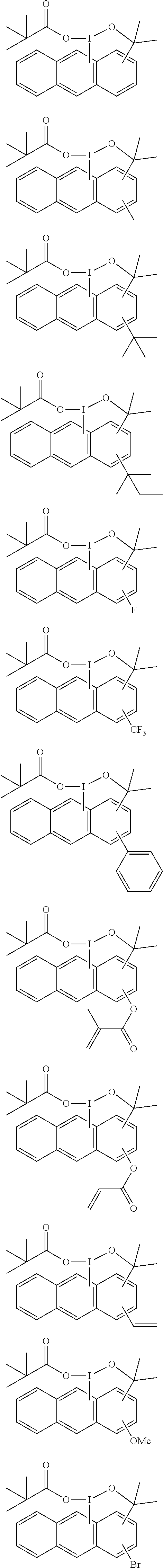

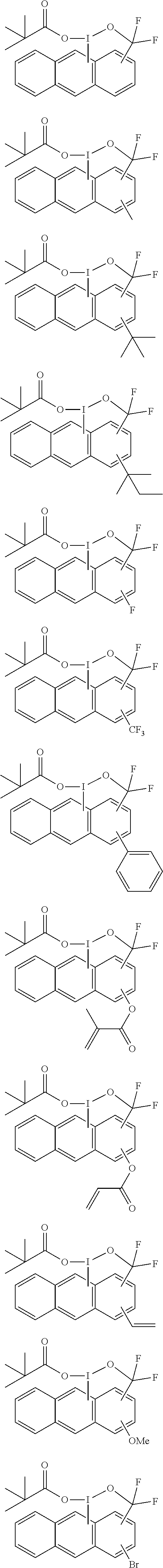

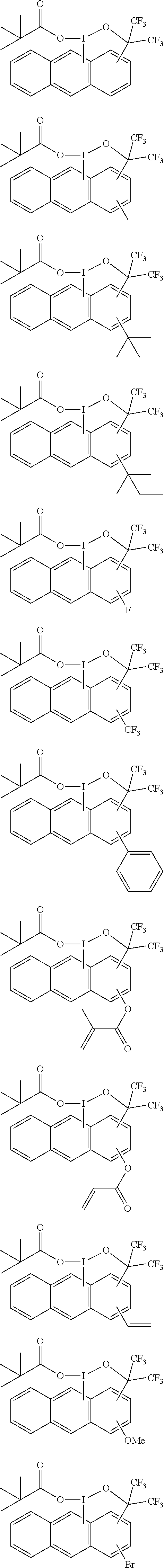

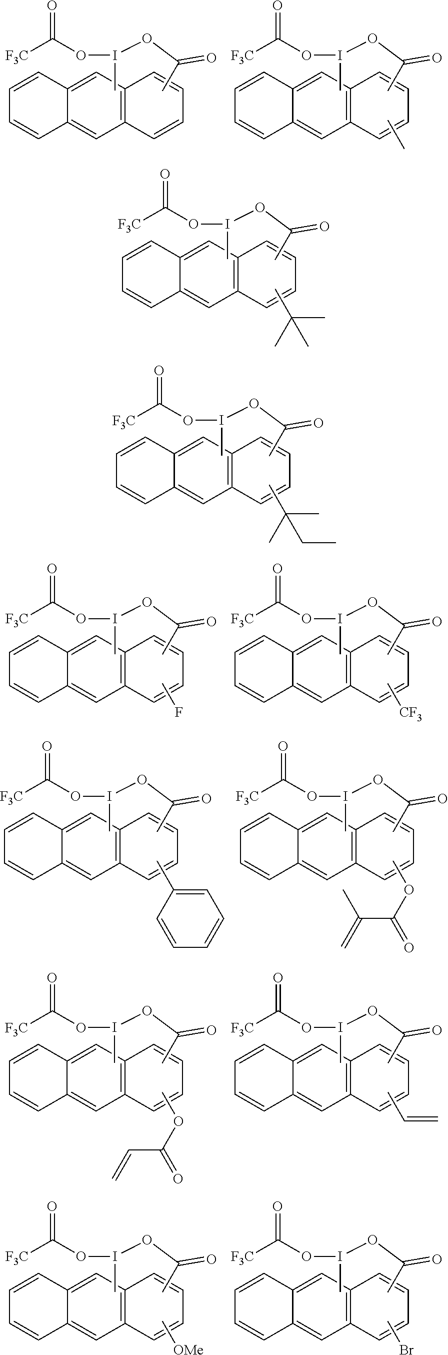

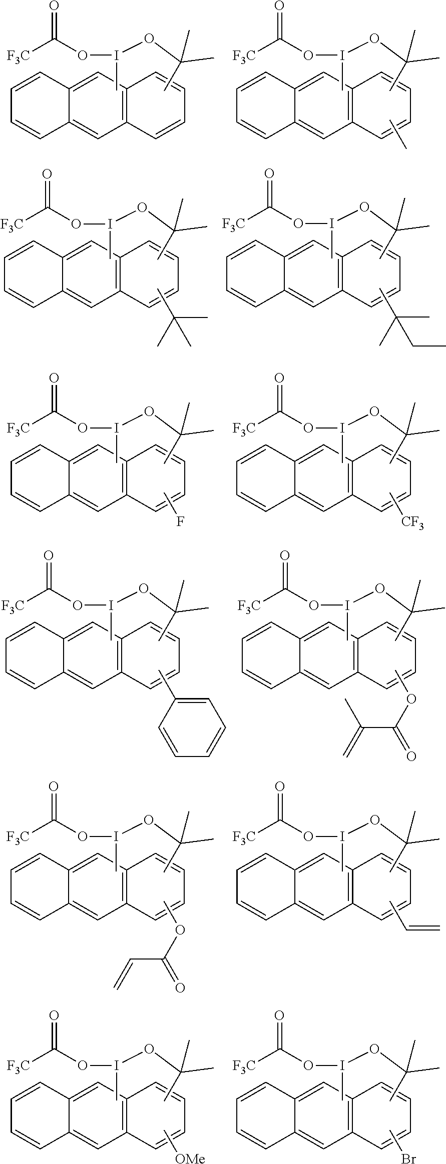

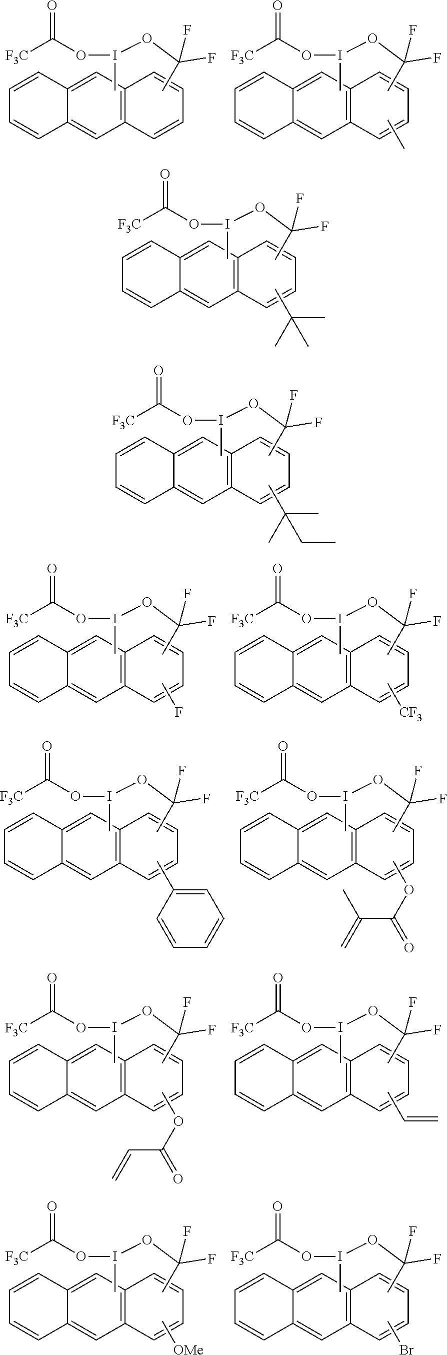

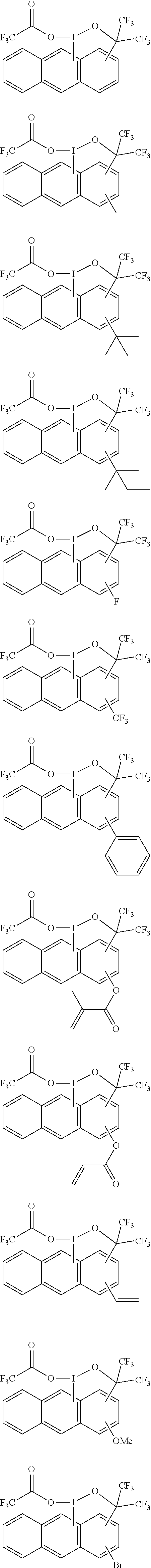

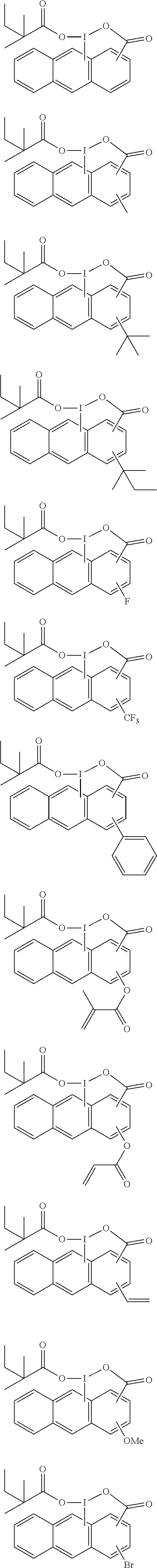

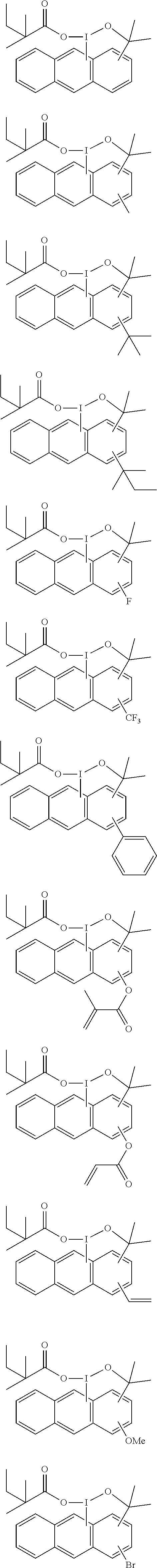

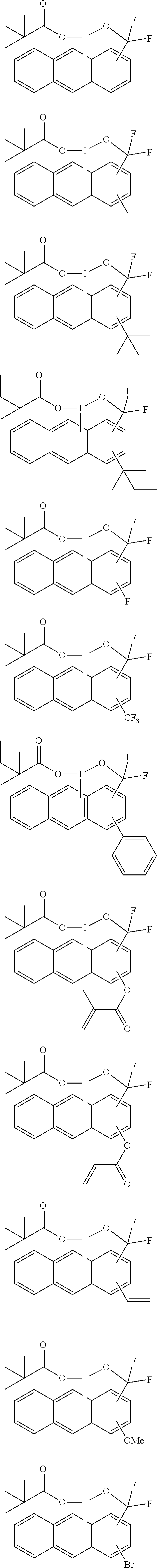

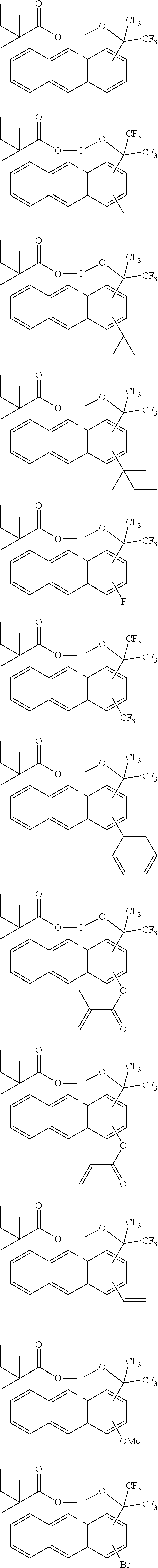

Specific examples of the hypervalent iodine compound represented by the general formula (5) include the following, but are not limited thereto.

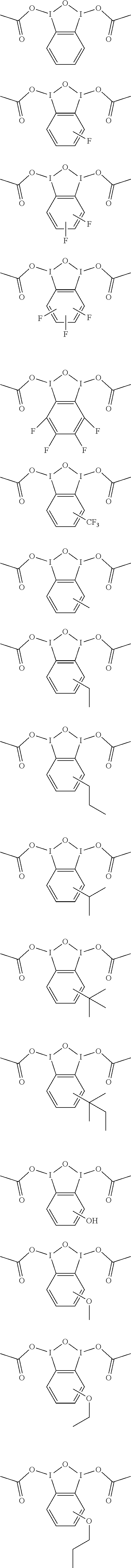

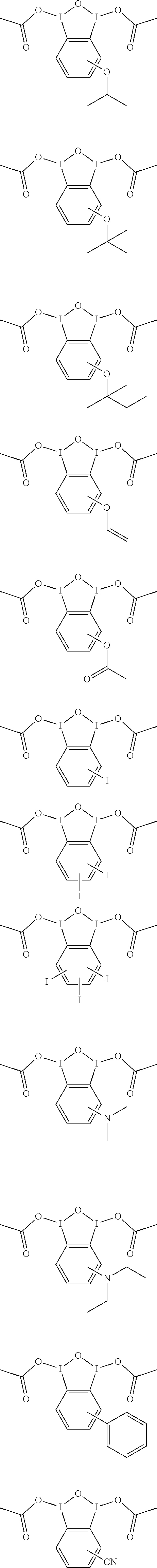

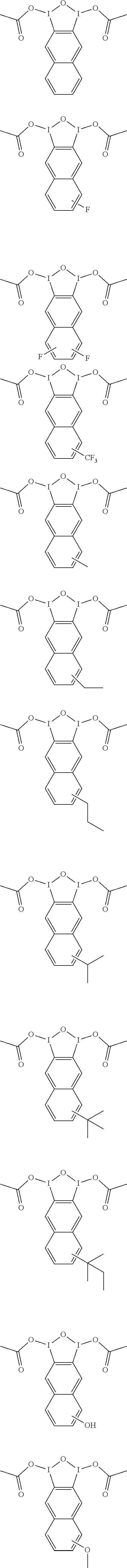

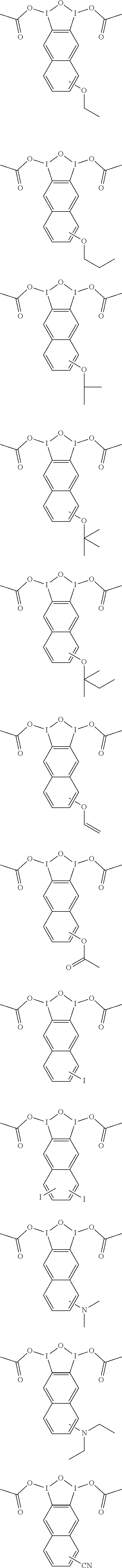

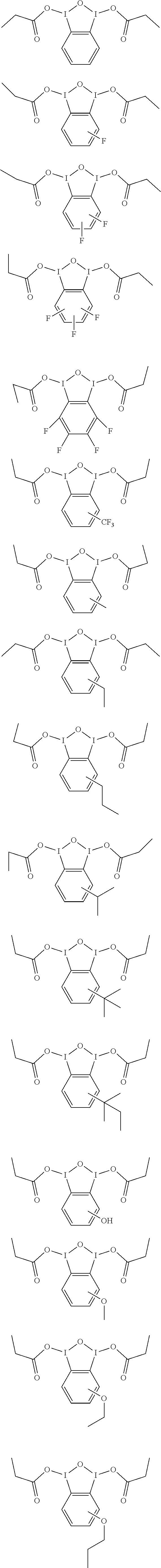

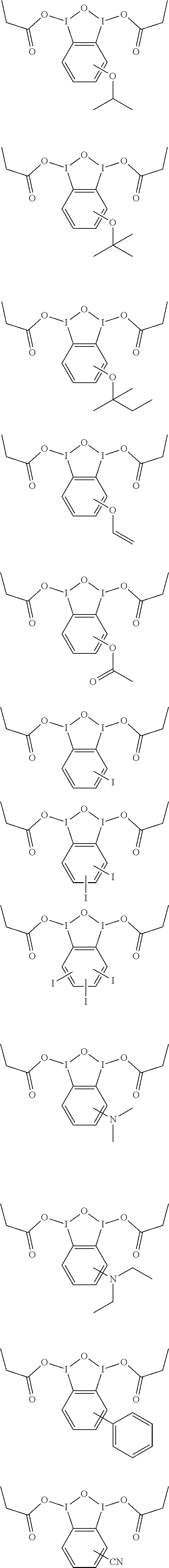

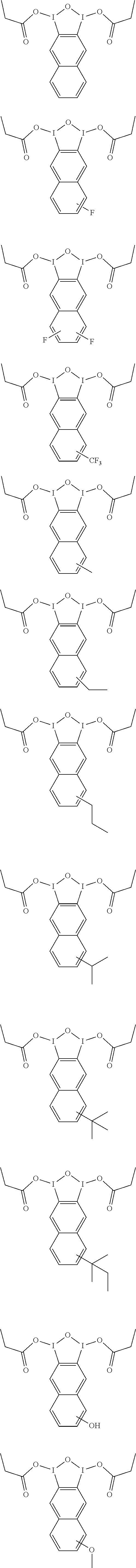

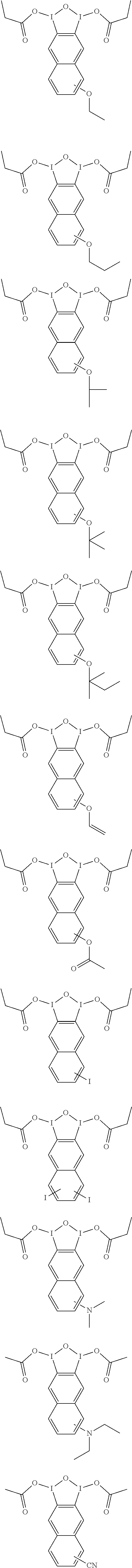

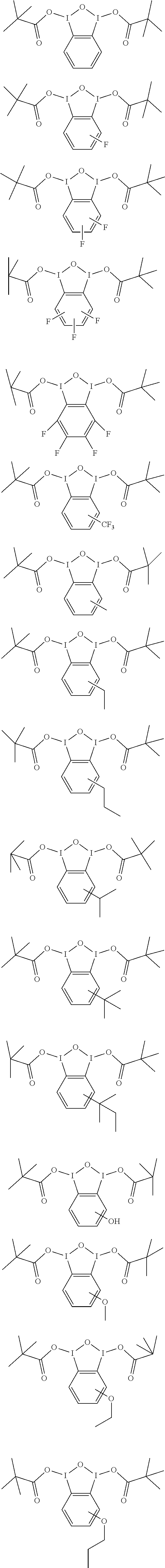

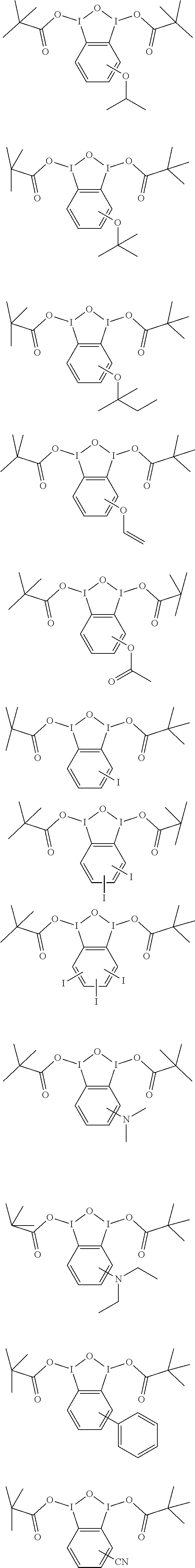

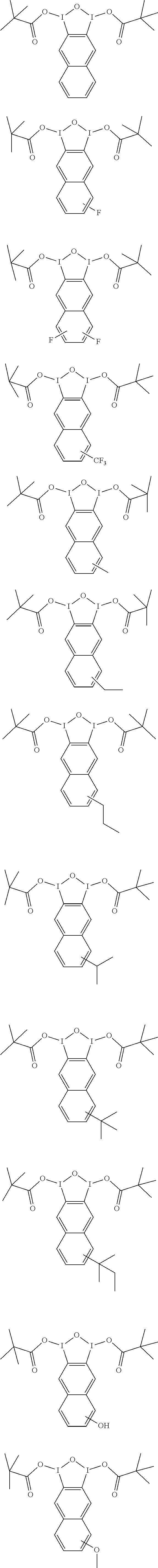

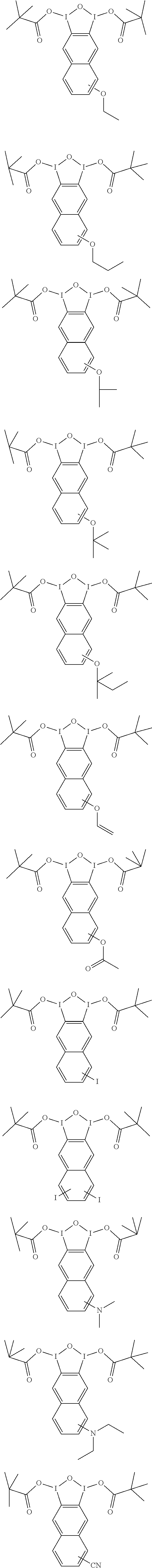

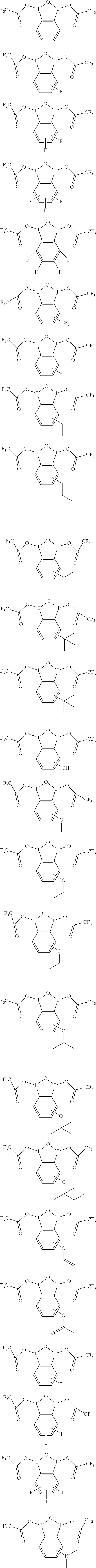

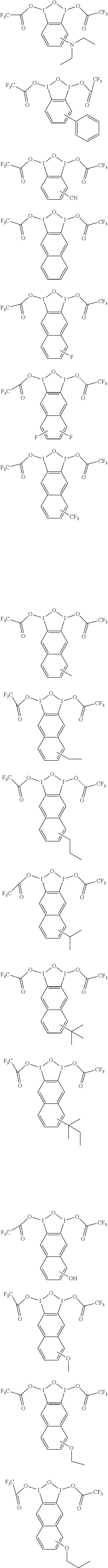

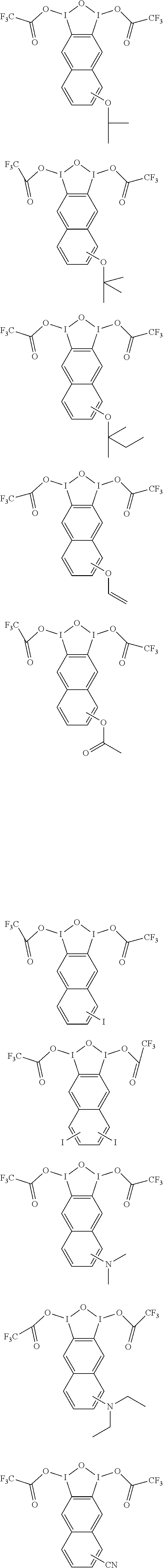

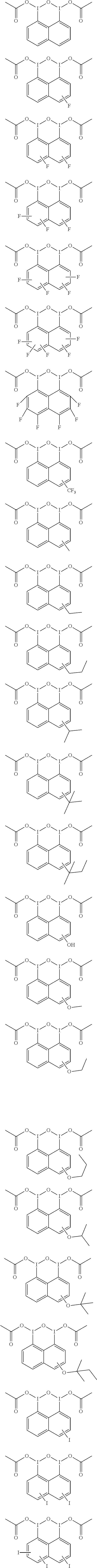

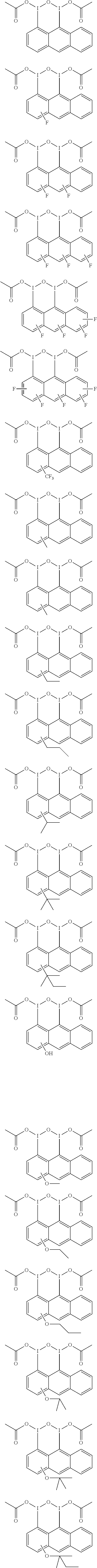

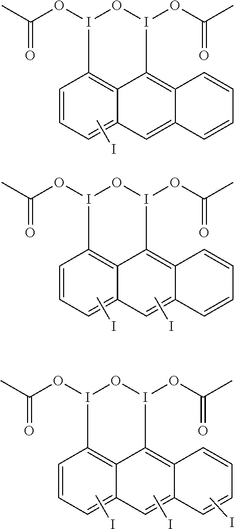

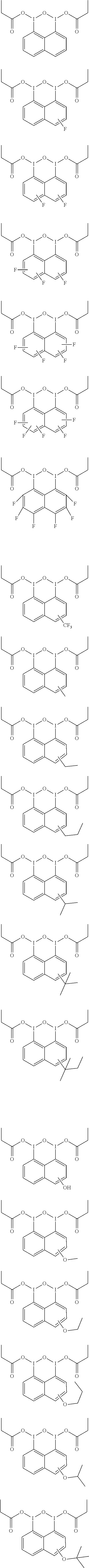

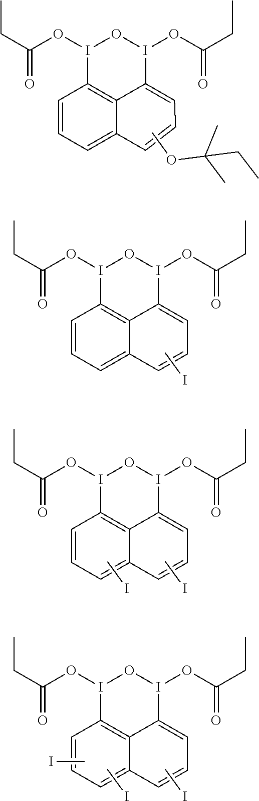

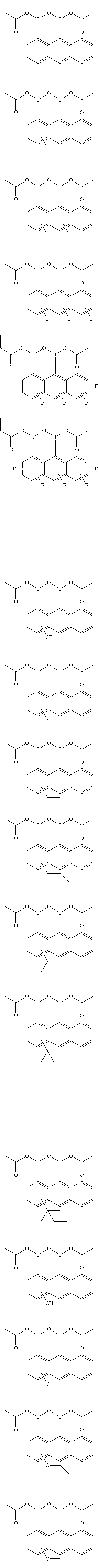

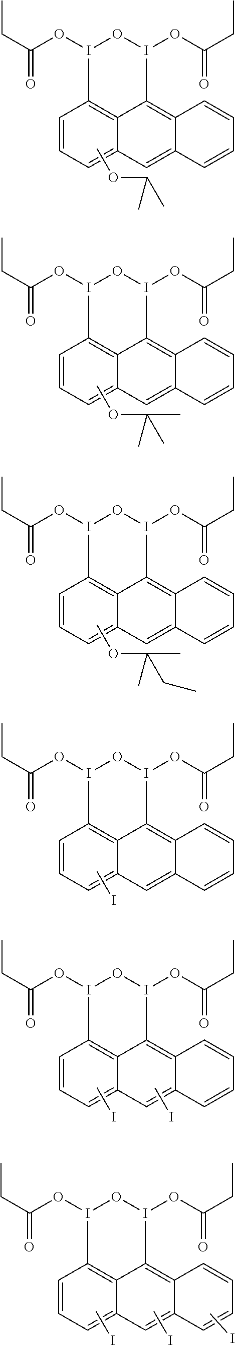

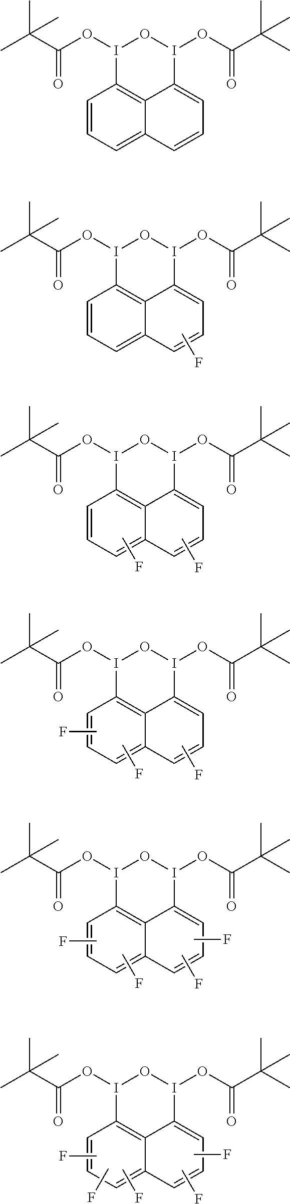

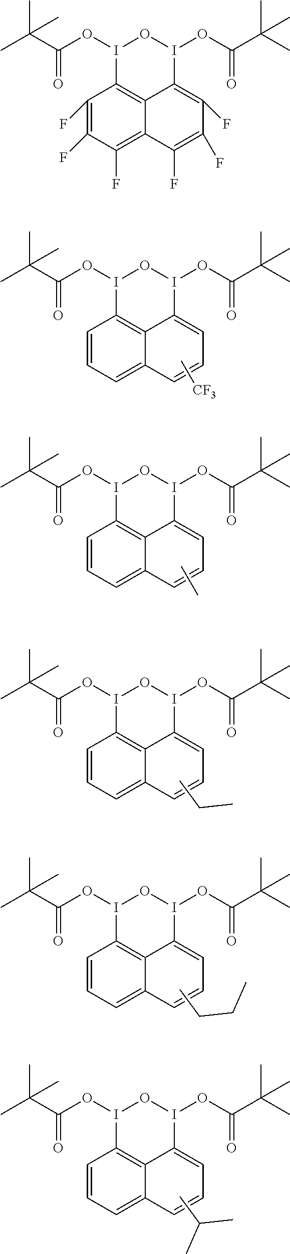

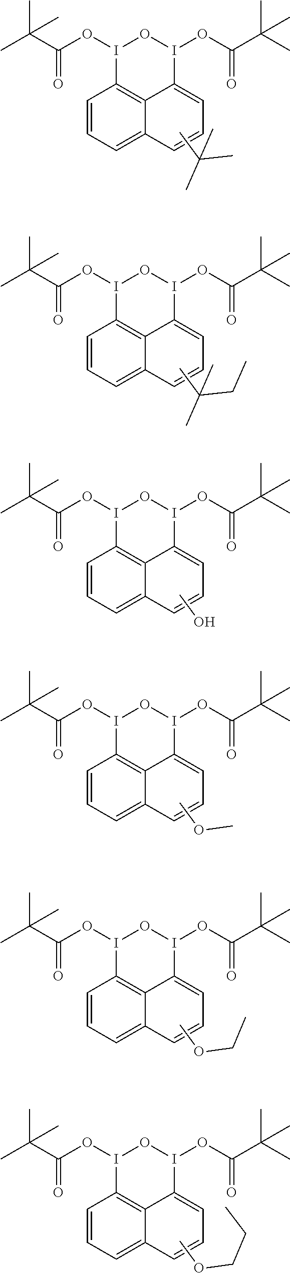

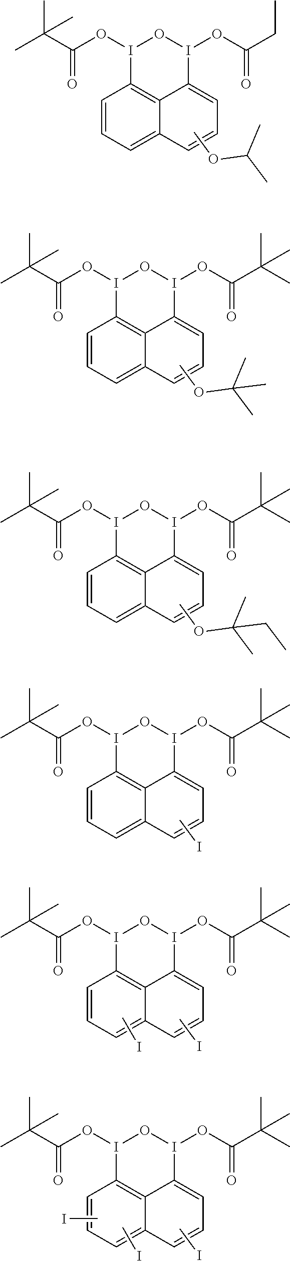

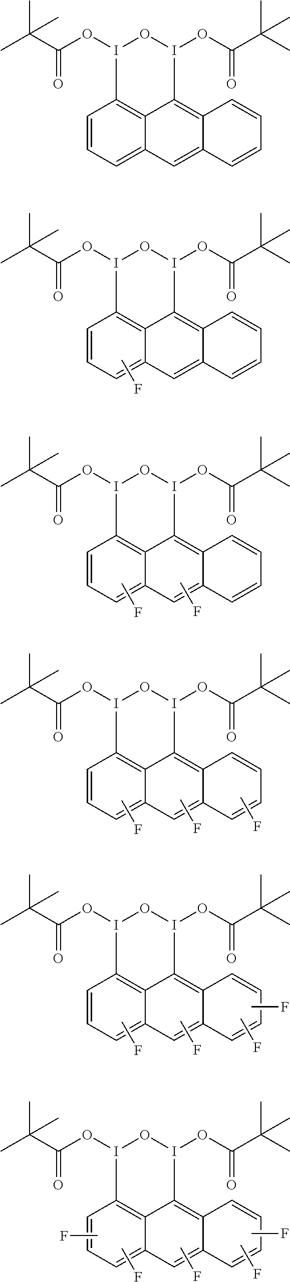

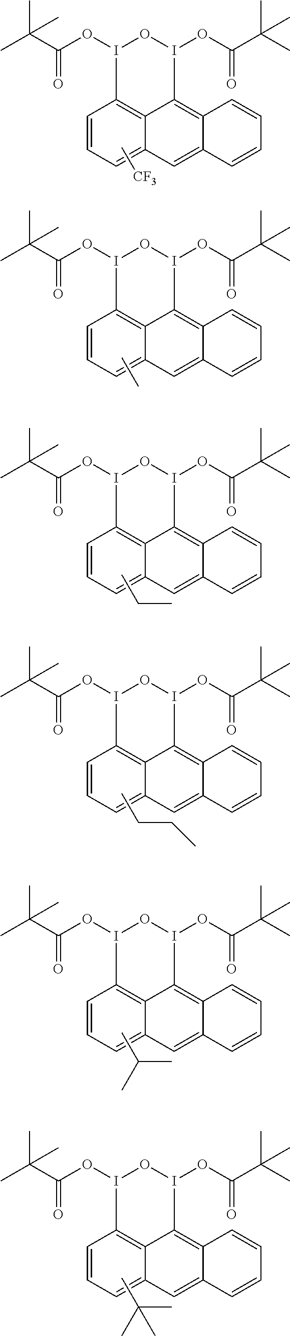

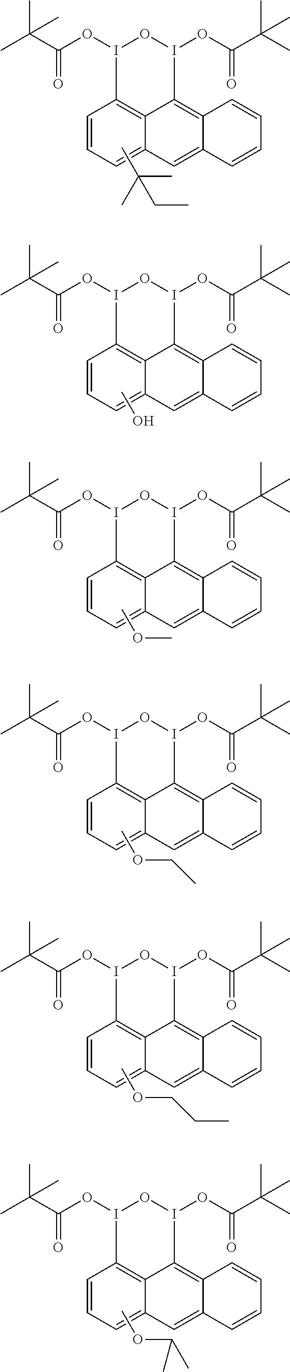

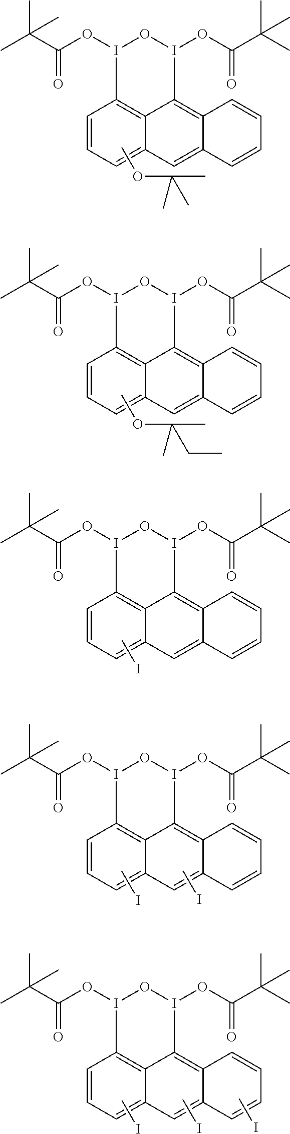

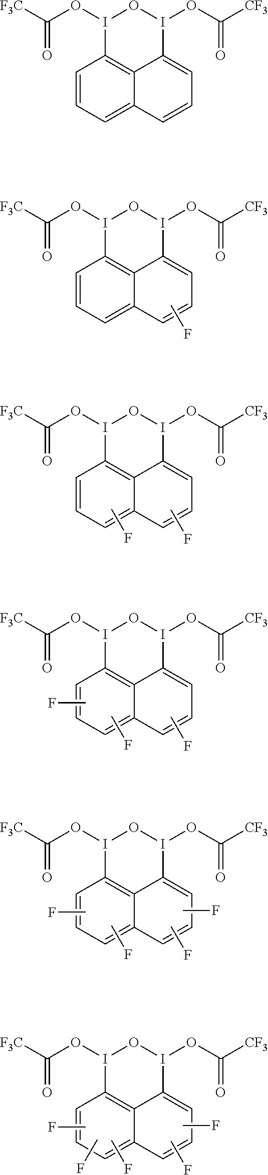

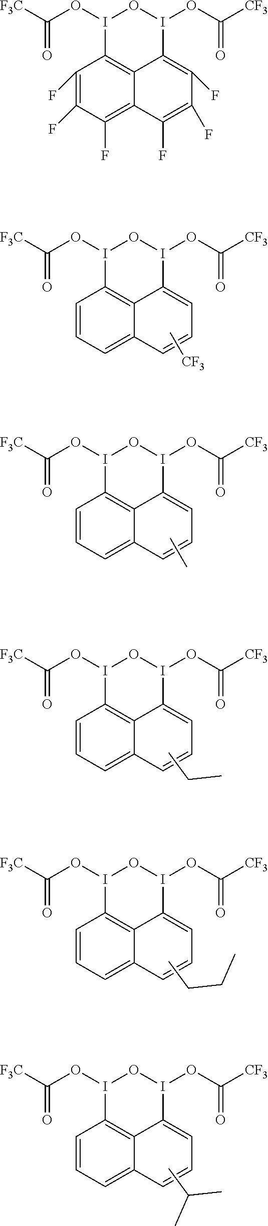

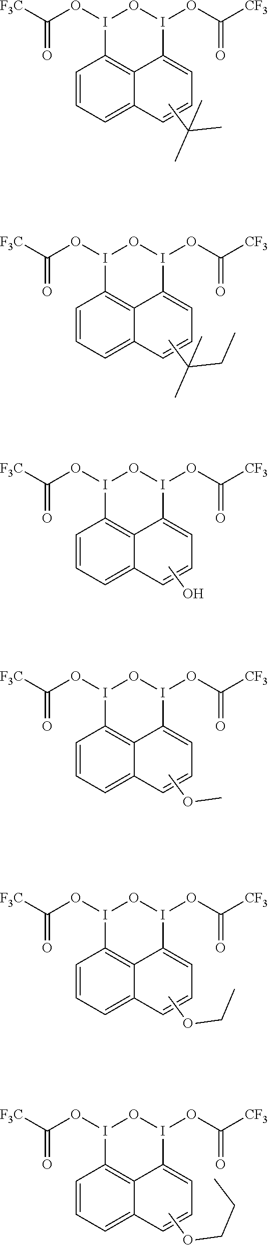

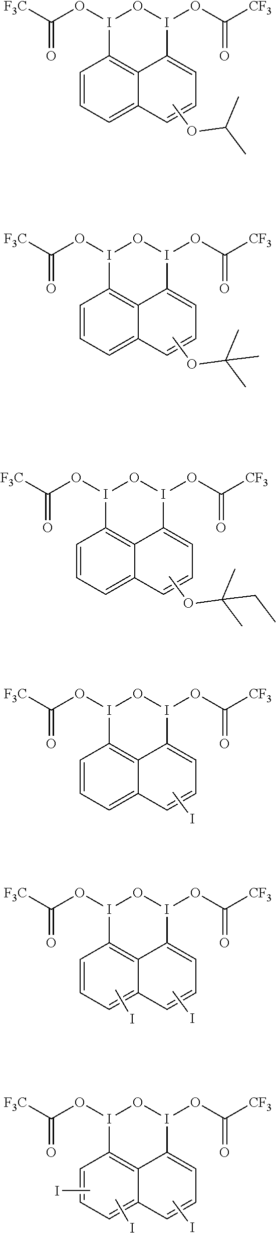

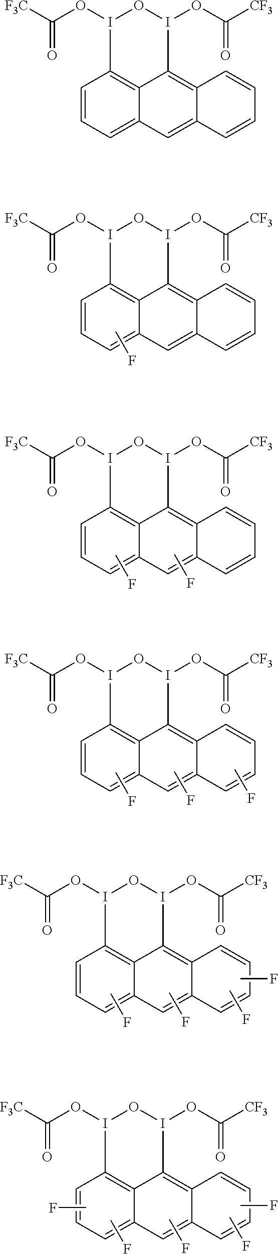

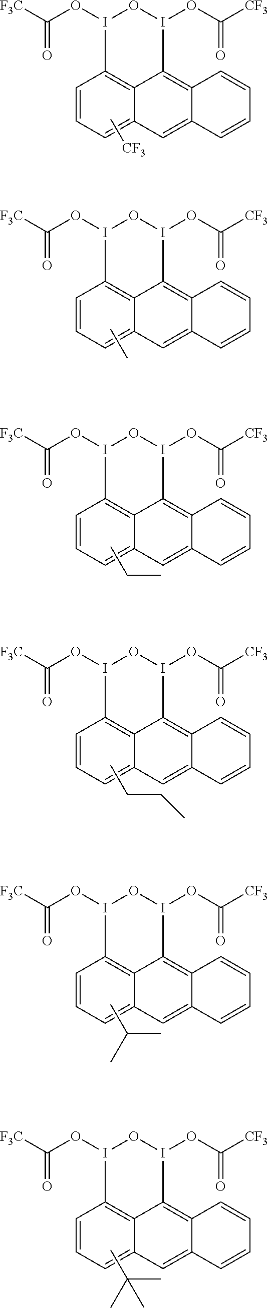

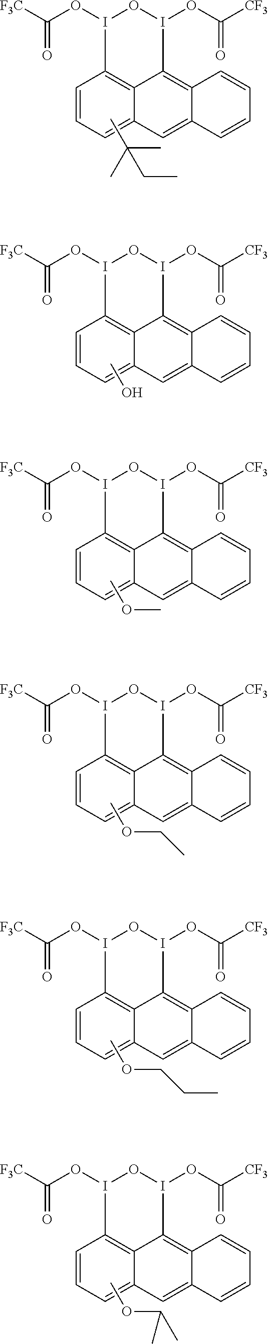

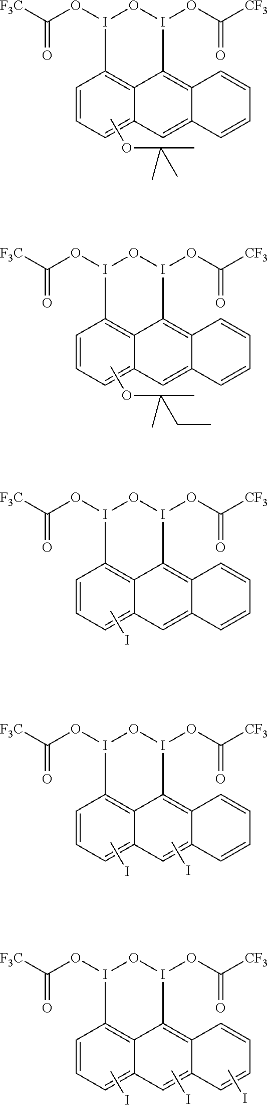

Specific examples of the hypervalent iodine compound represented by the general formula (6) include the following, but are not limited thereto. Note that, in the following formulae, L₁ is as defined above.

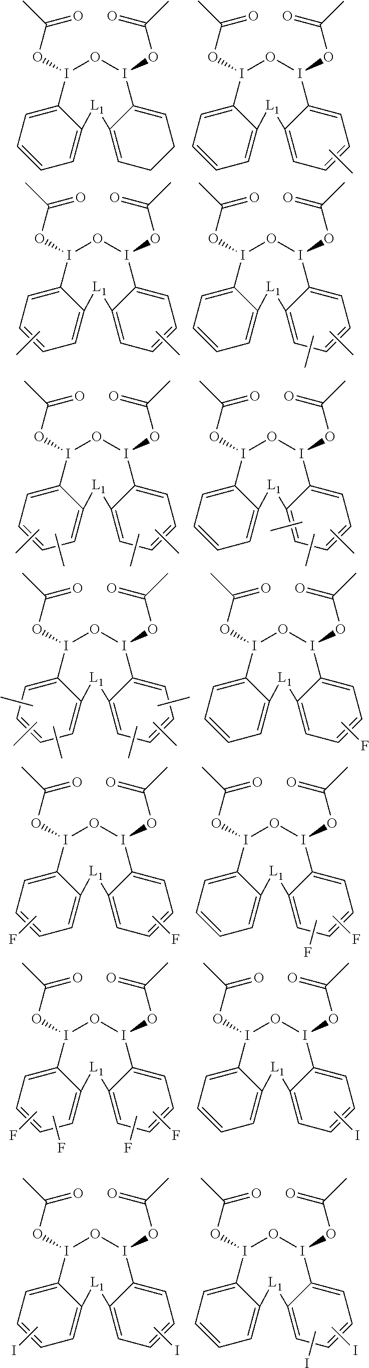

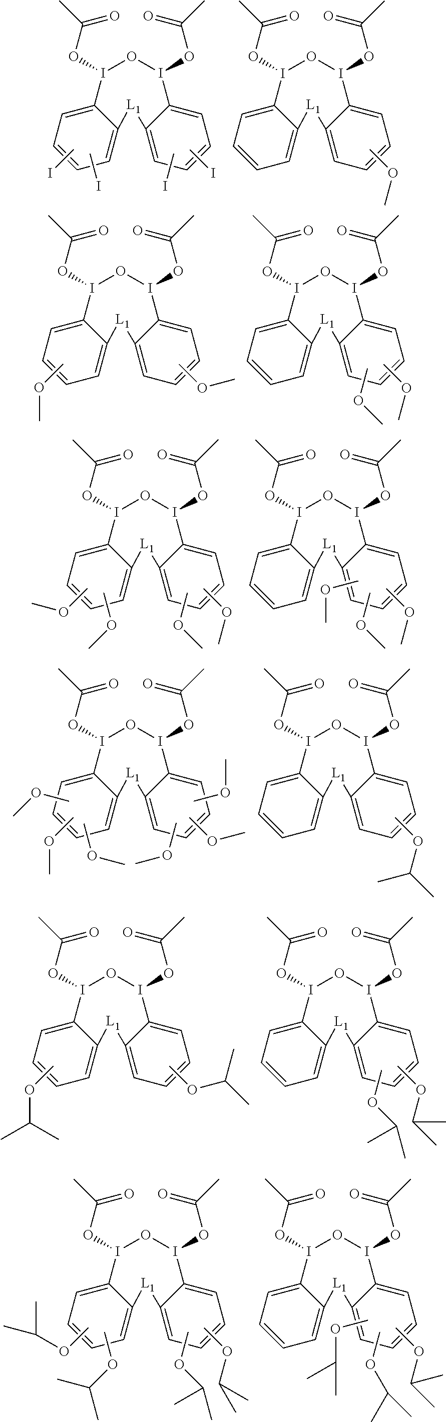

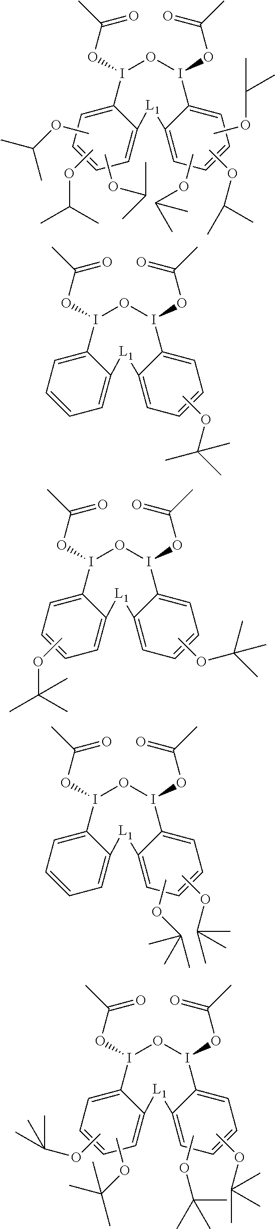

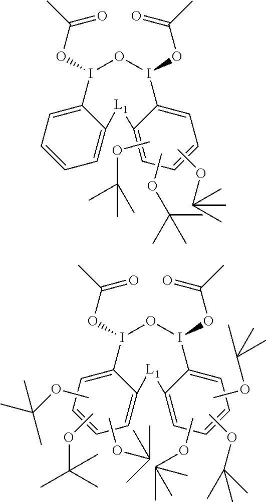

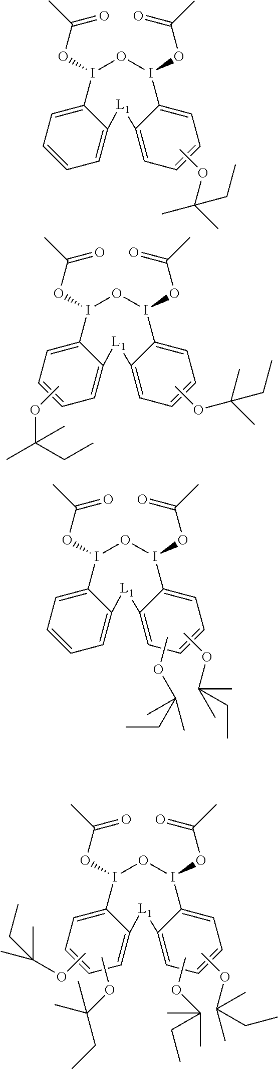

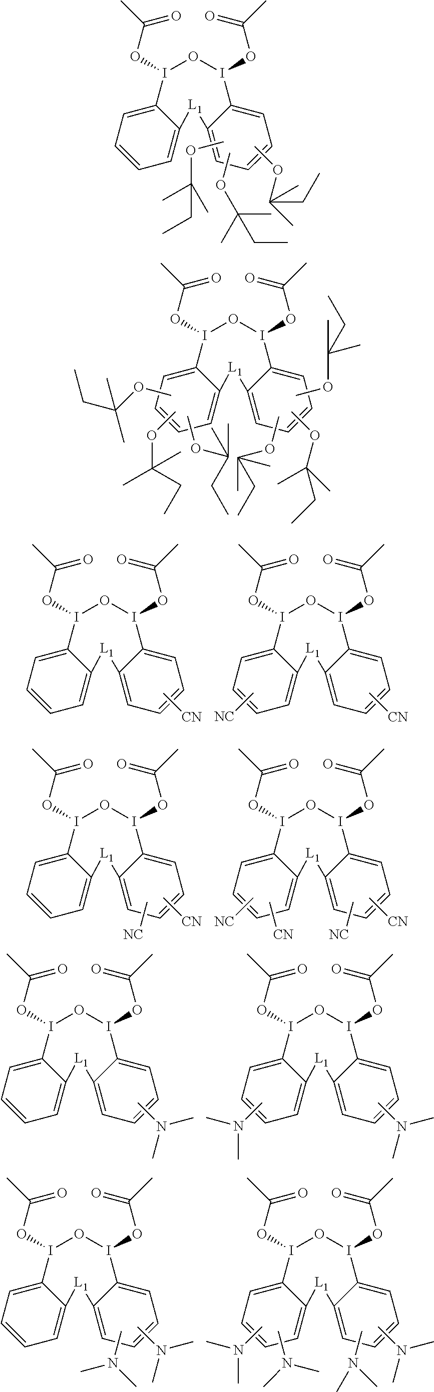

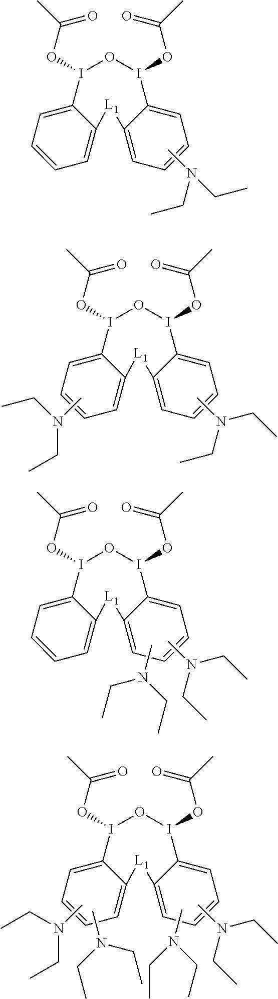

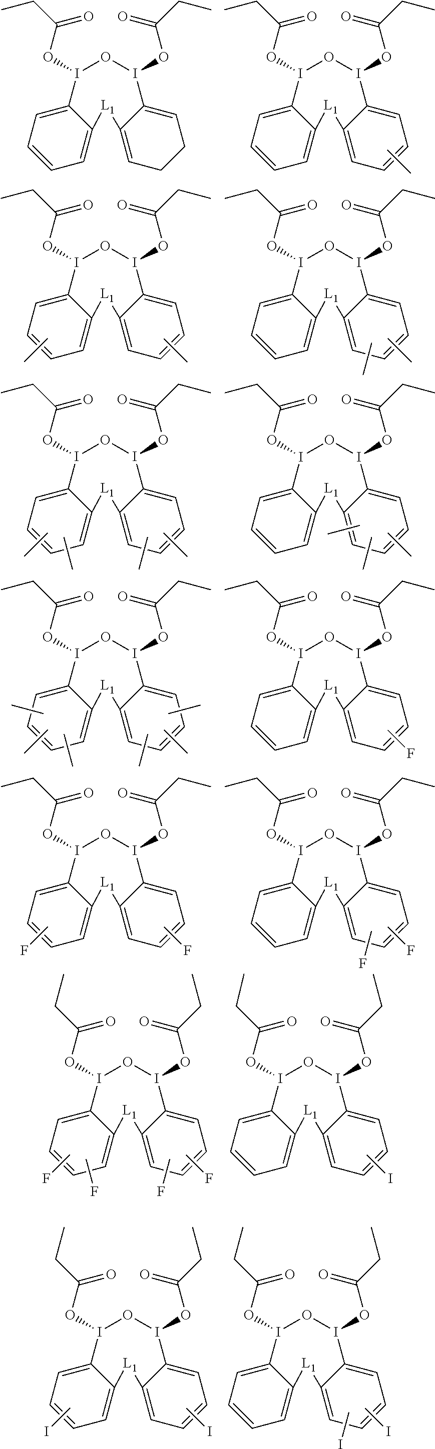

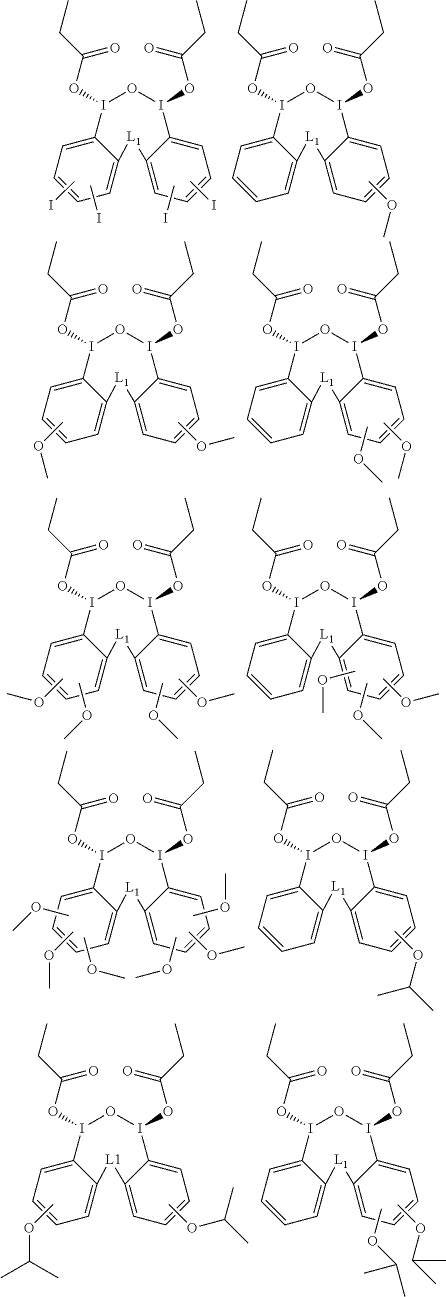

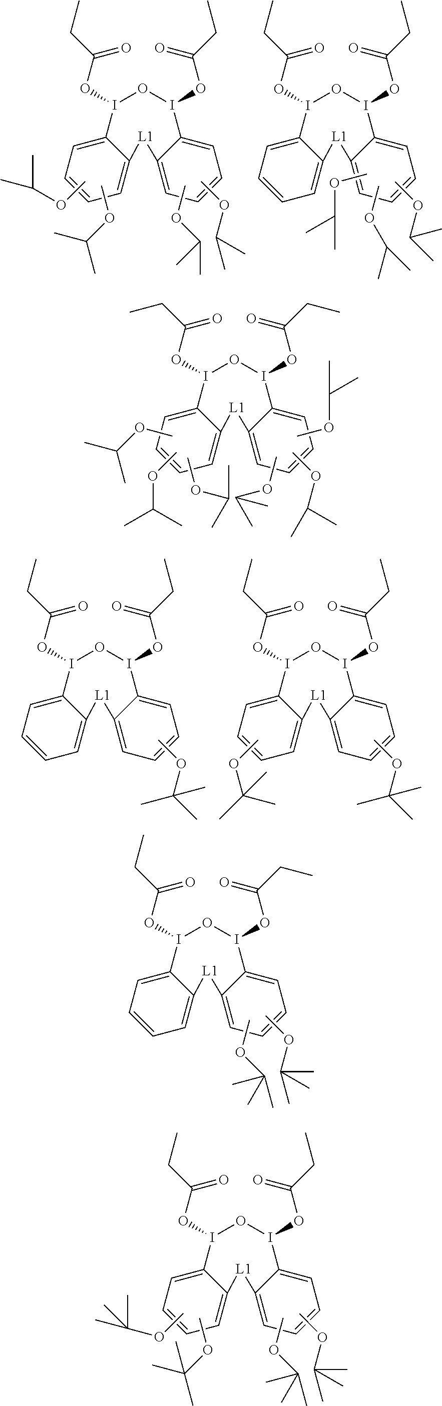

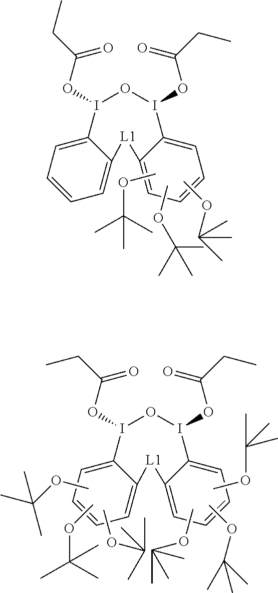

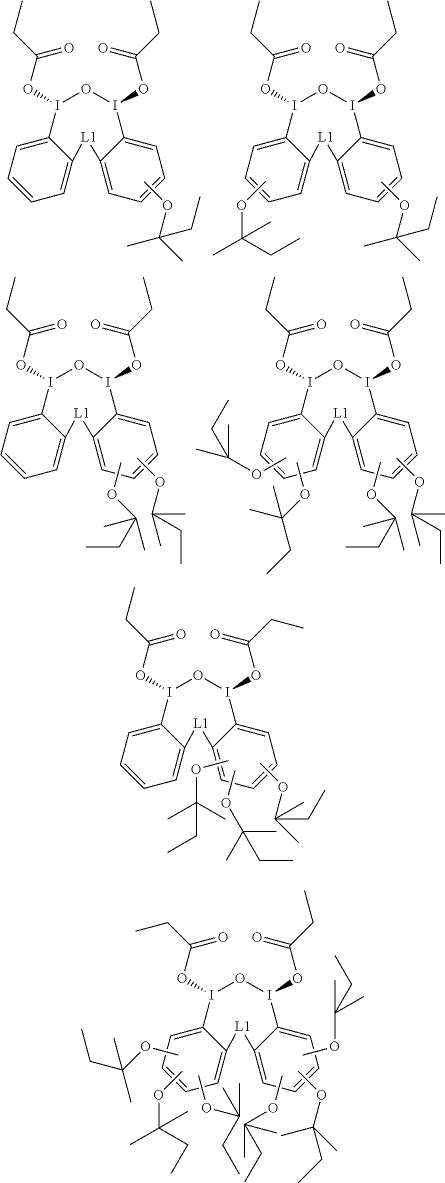

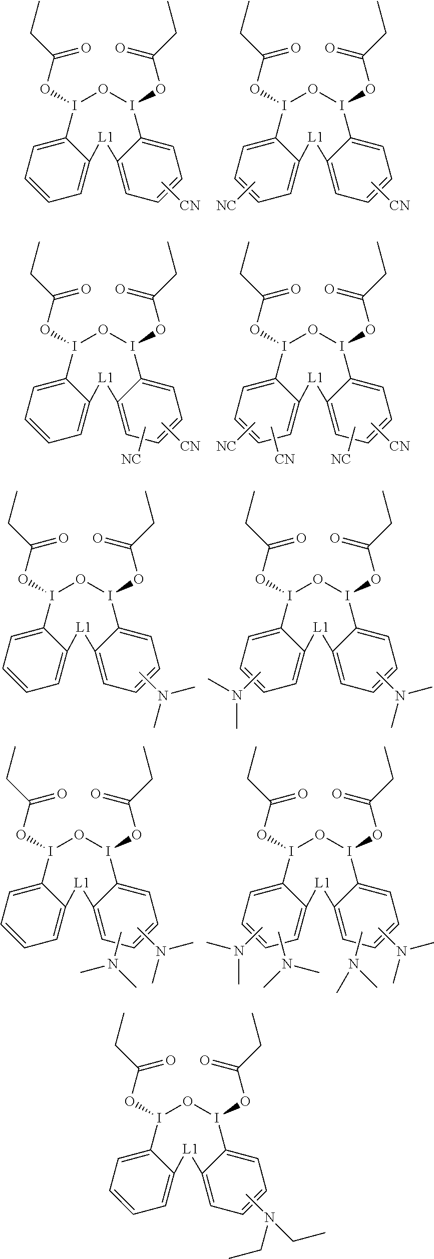

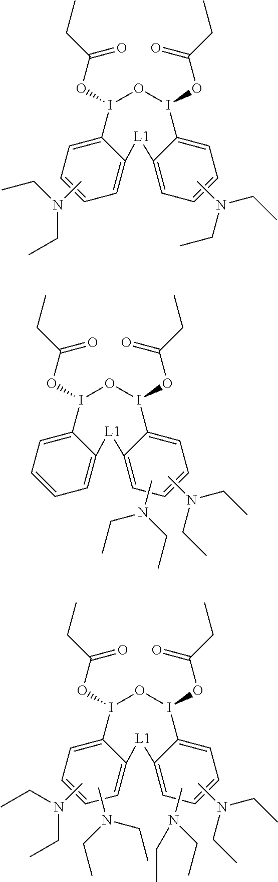

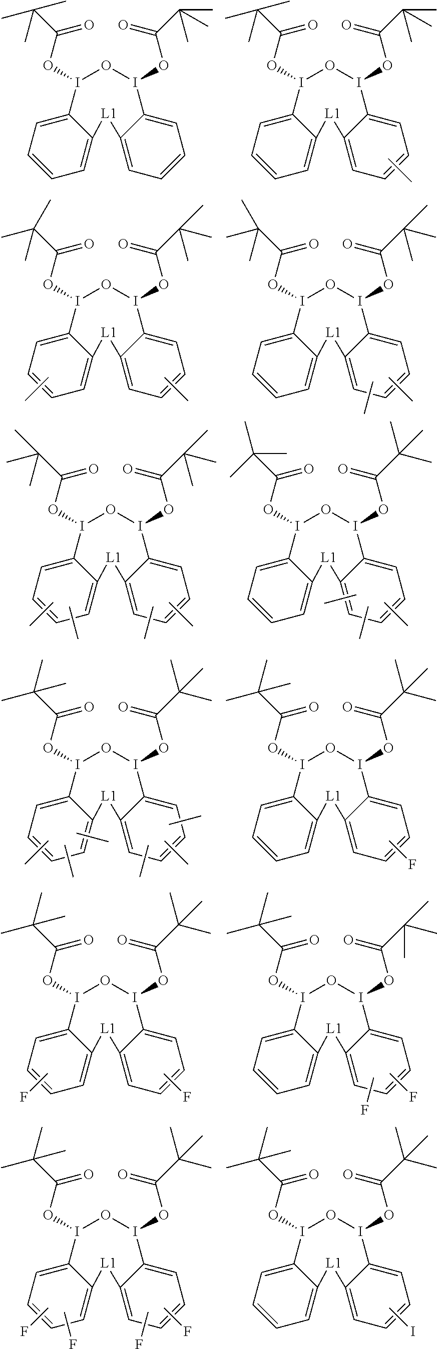

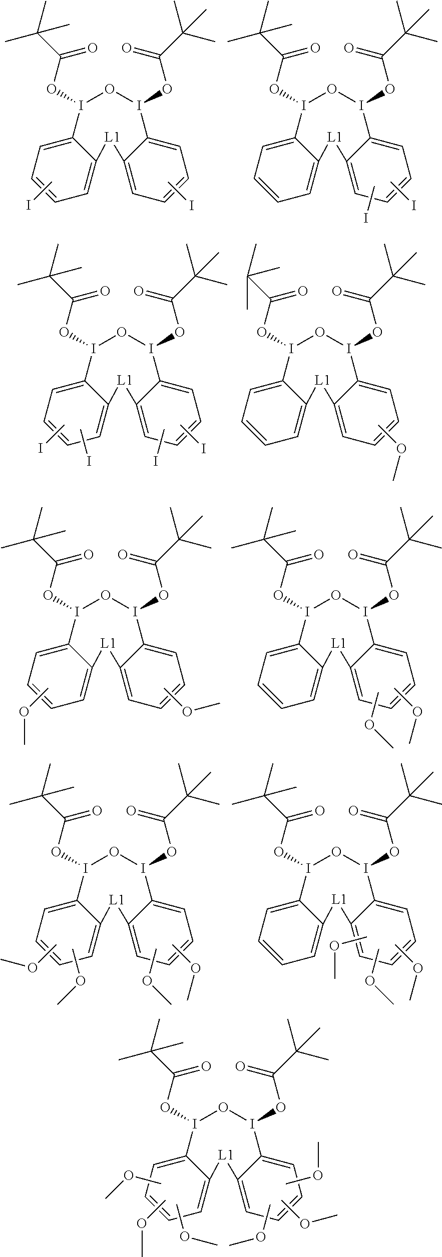

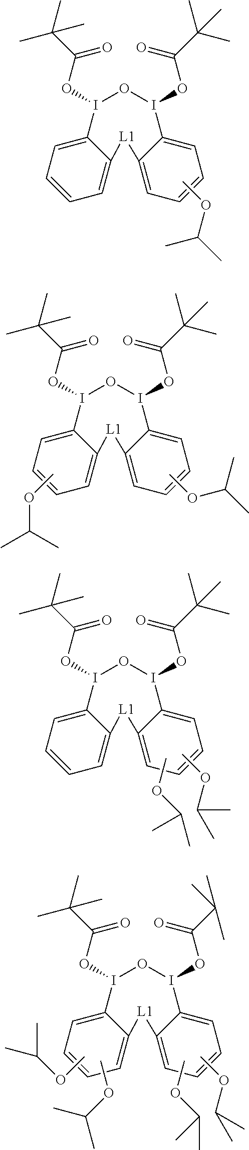

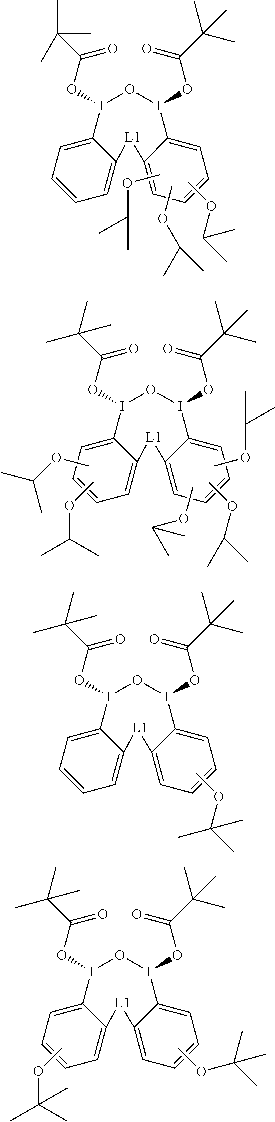

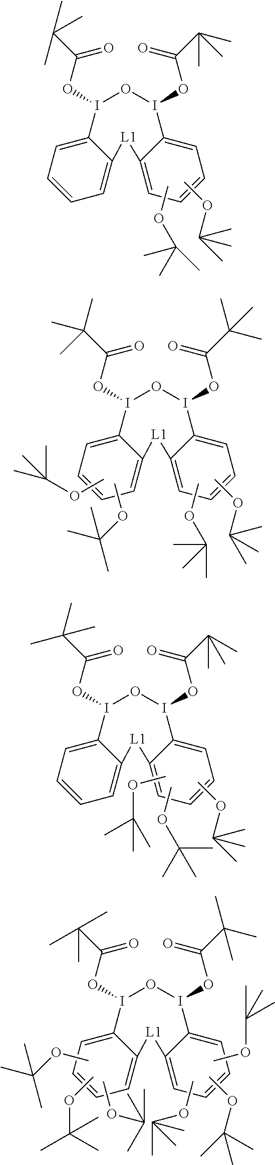

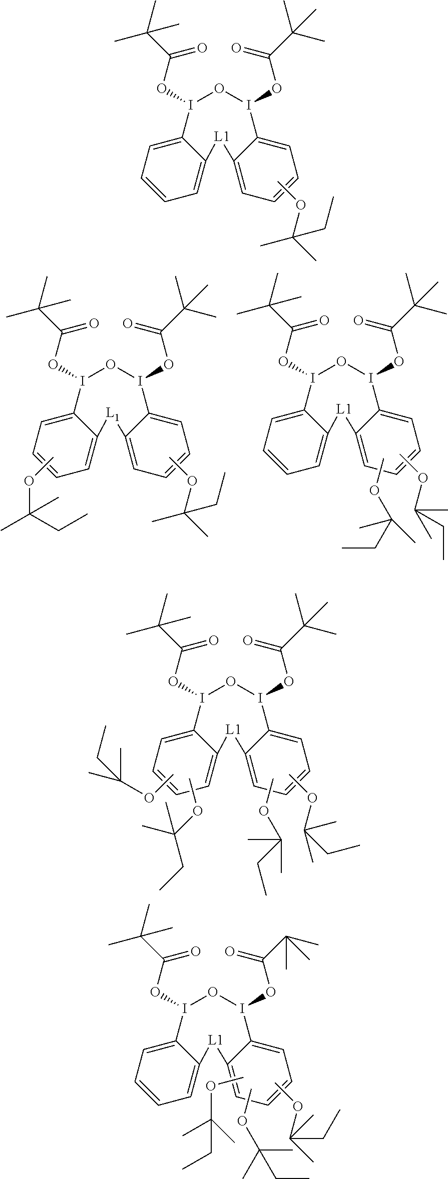

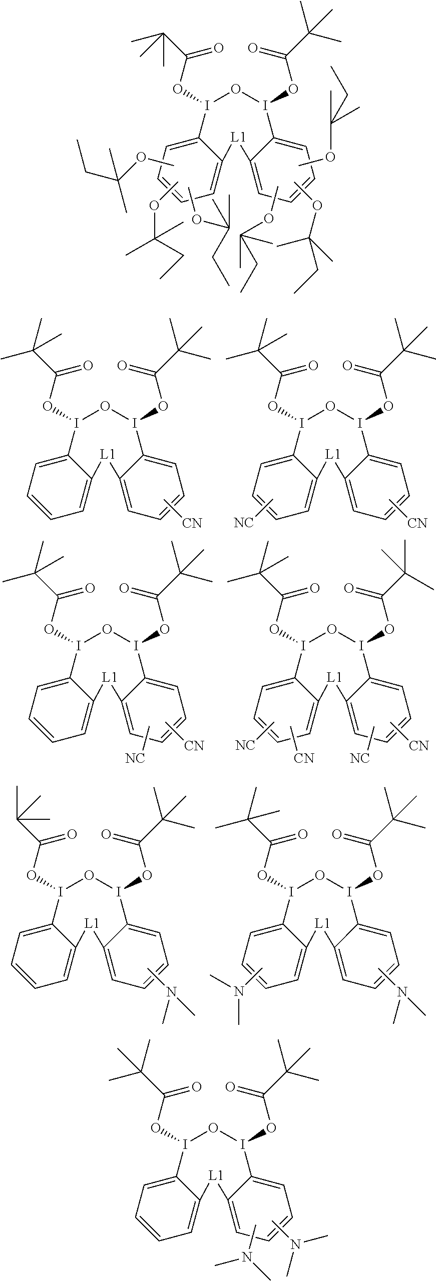

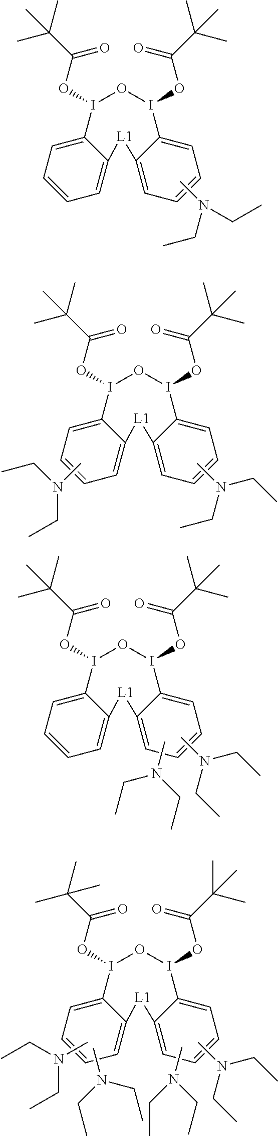

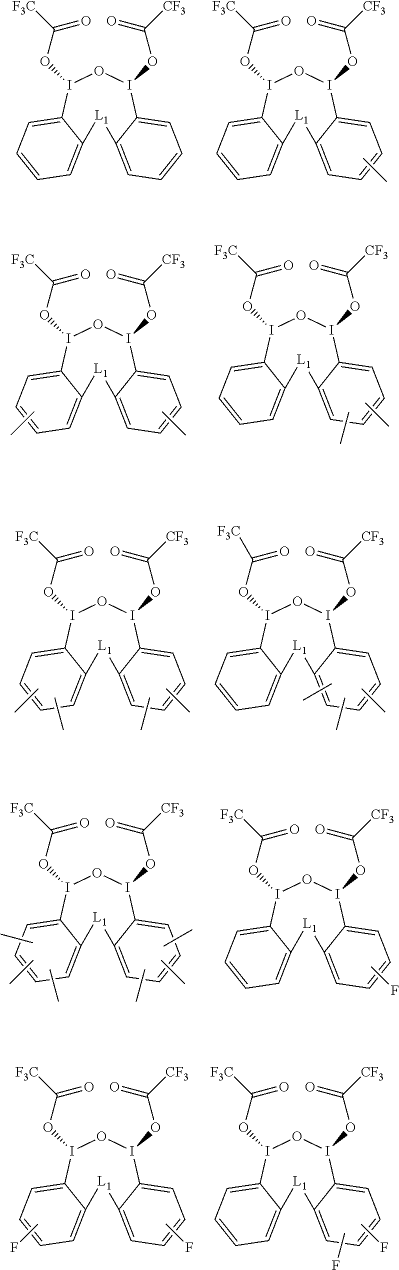

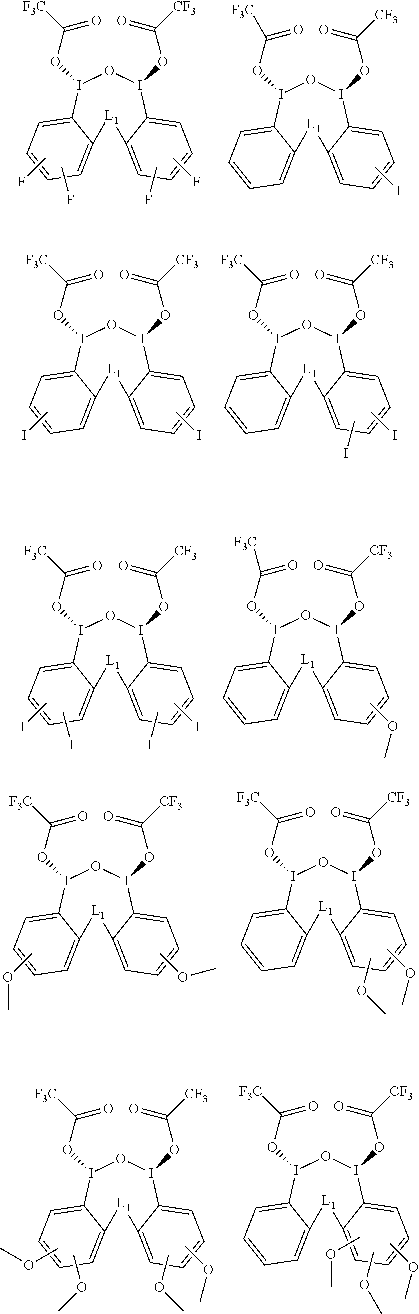

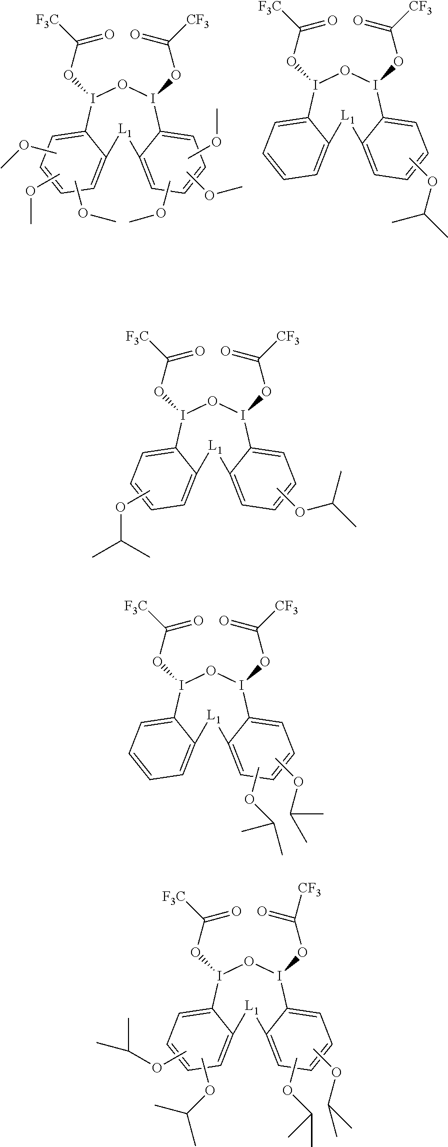

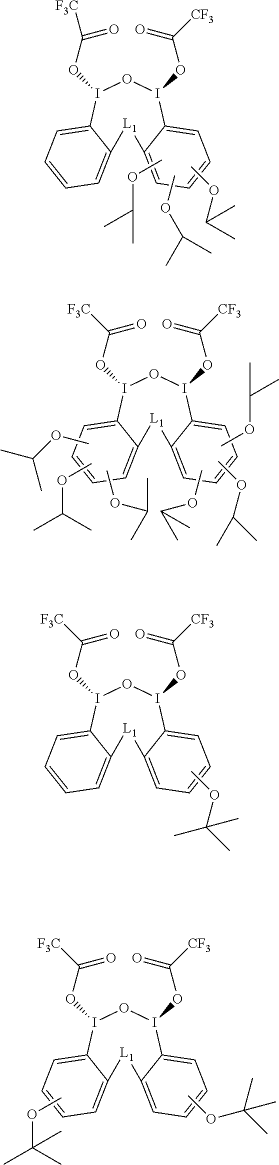

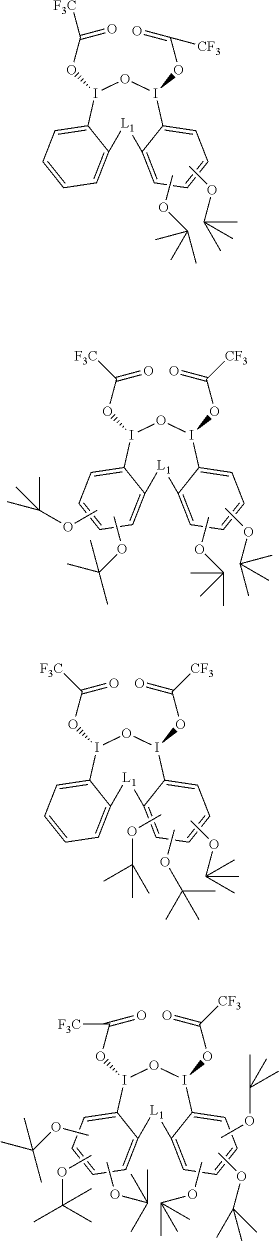

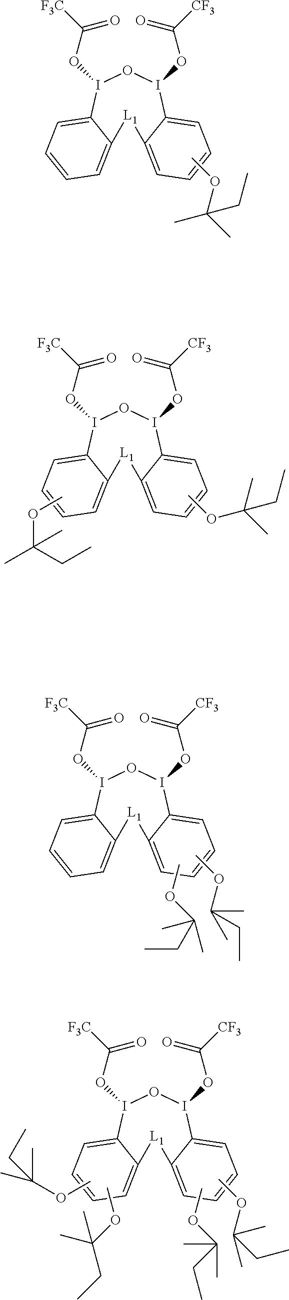

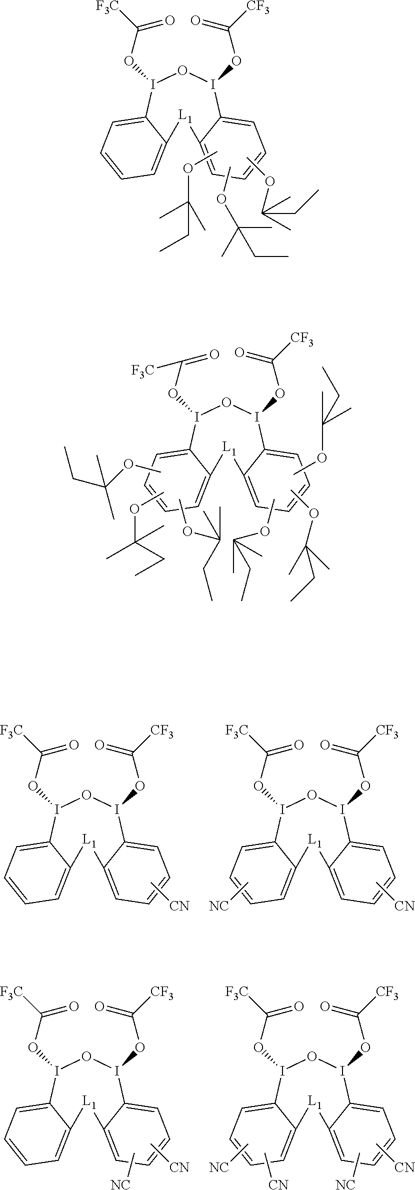

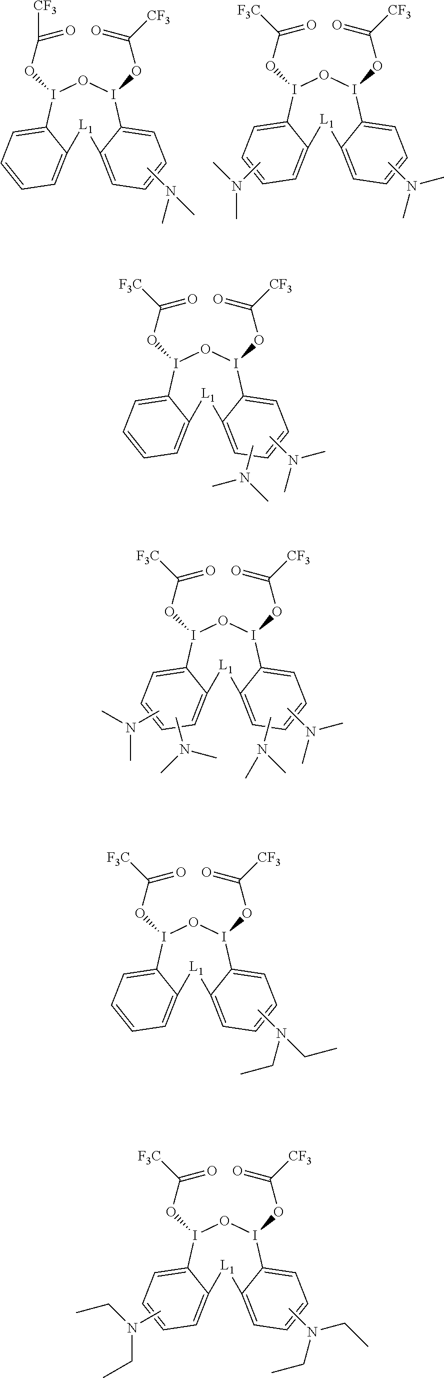

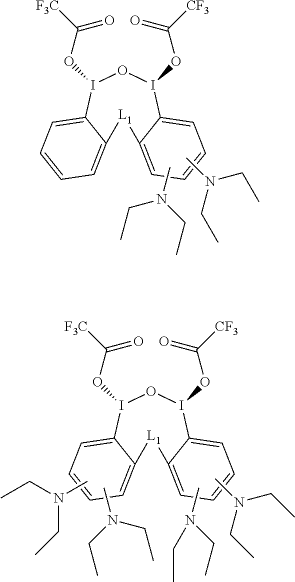

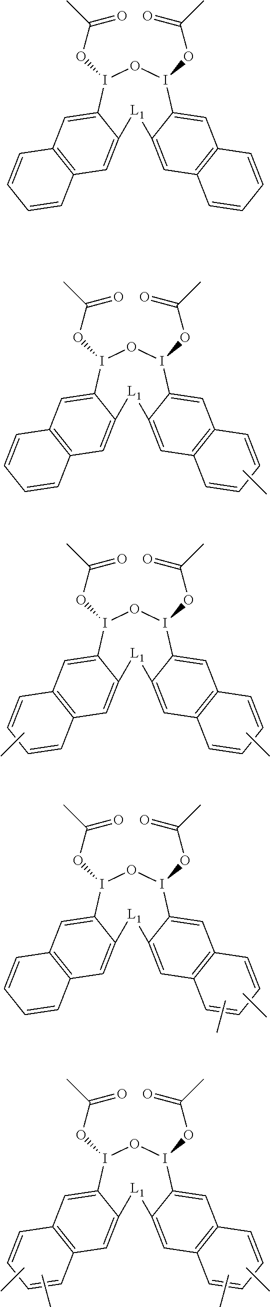

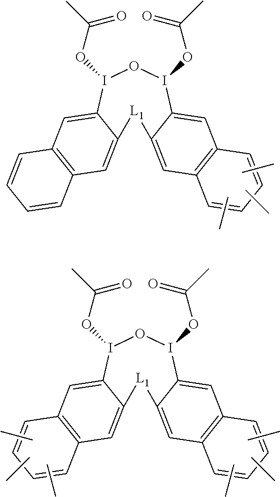

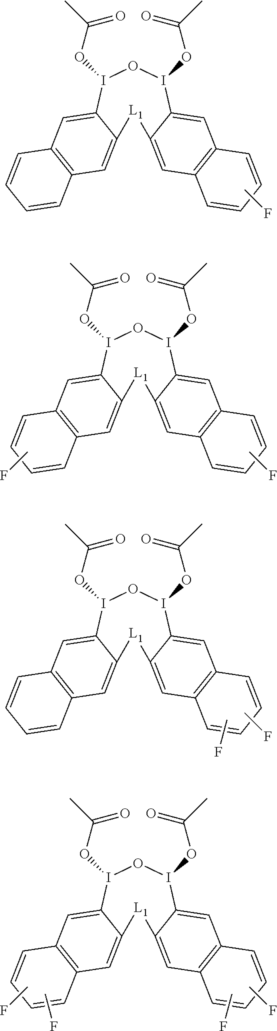

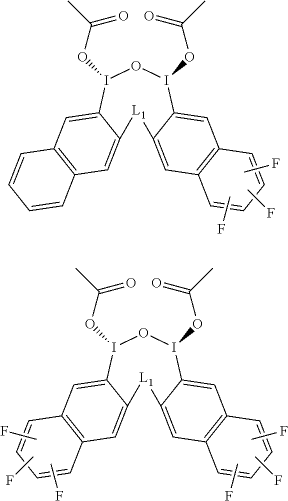

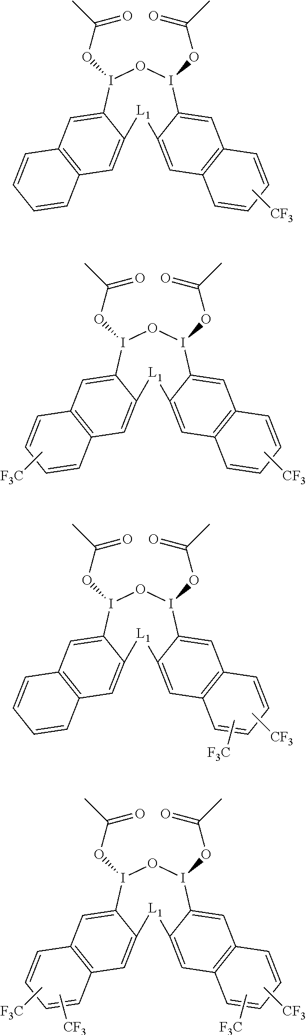

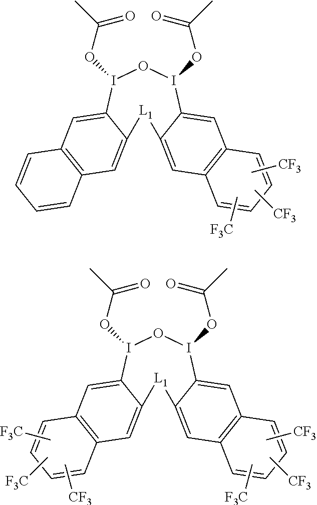

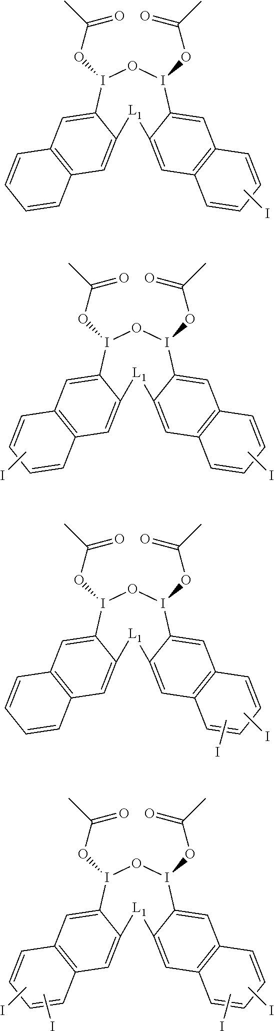

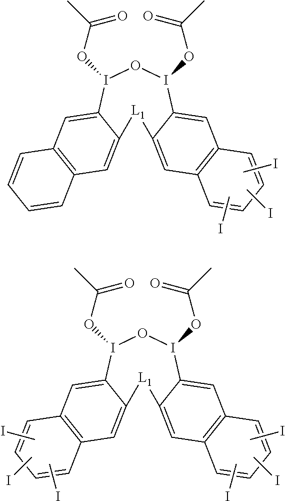

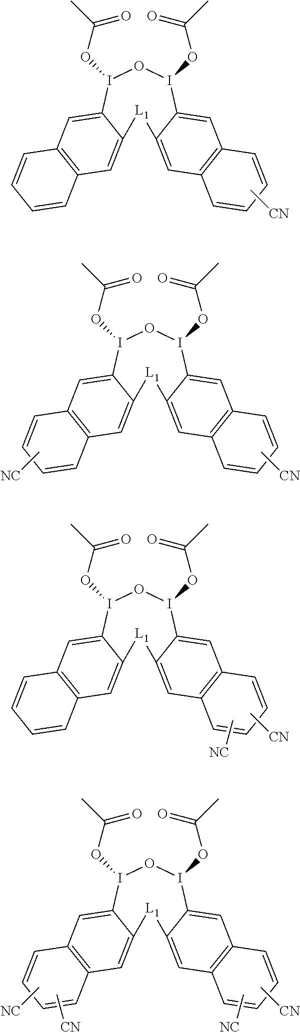

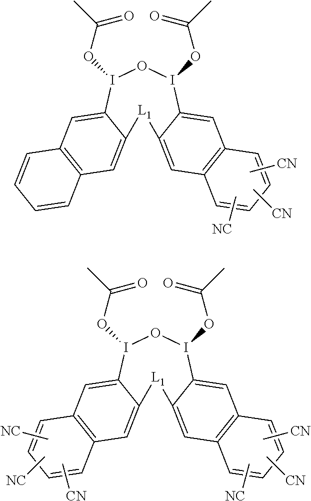

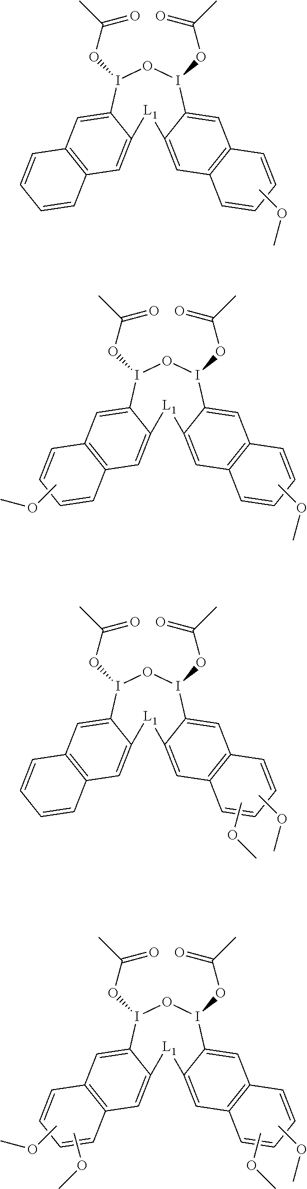

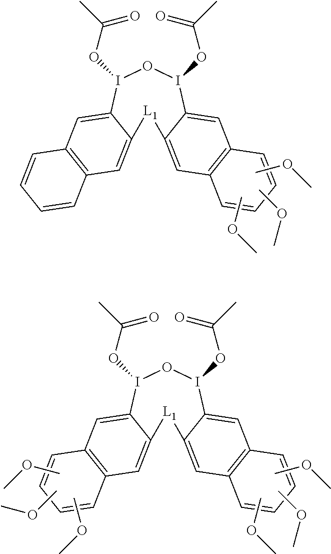

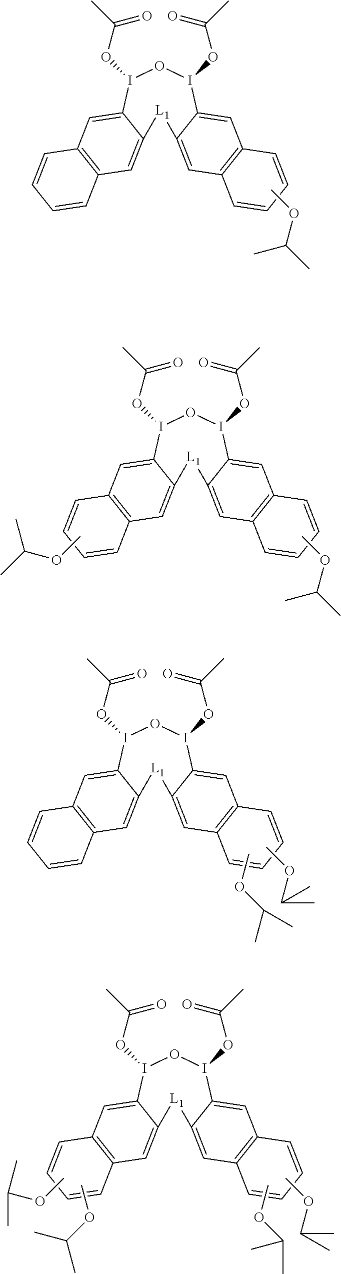

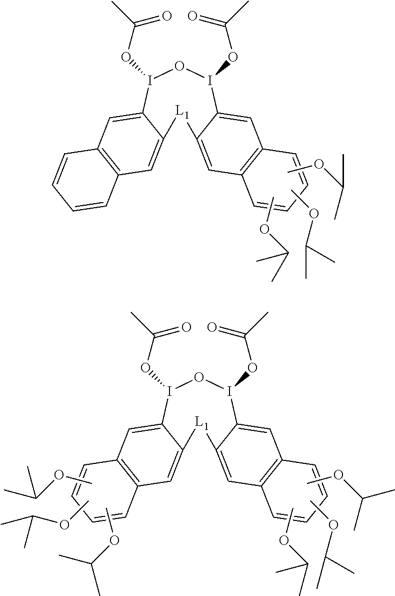

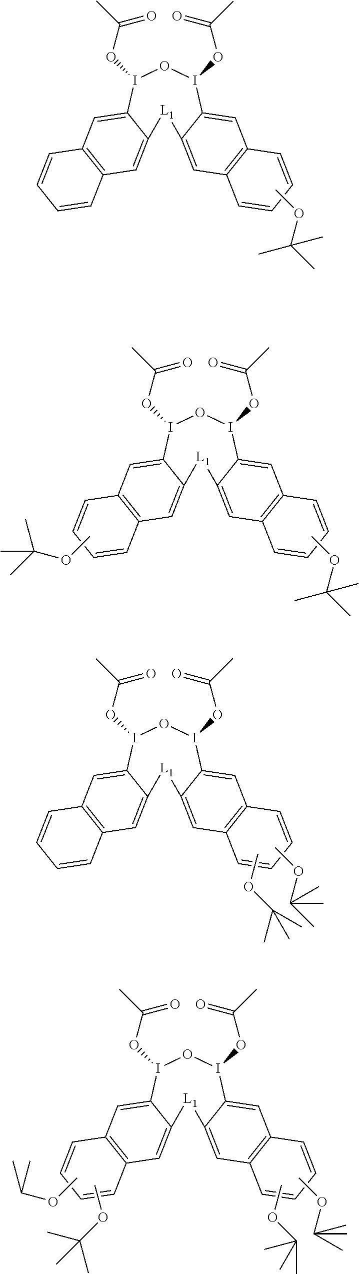

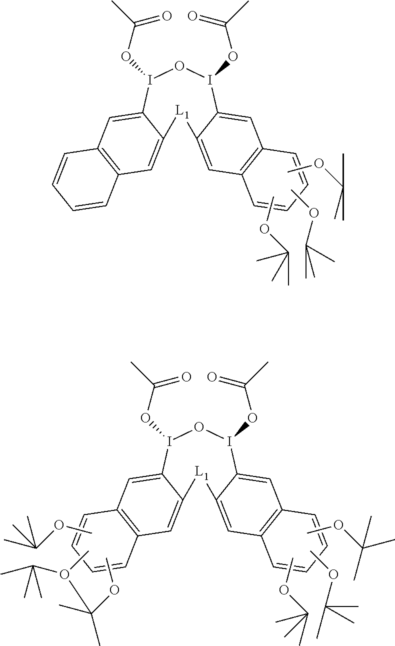

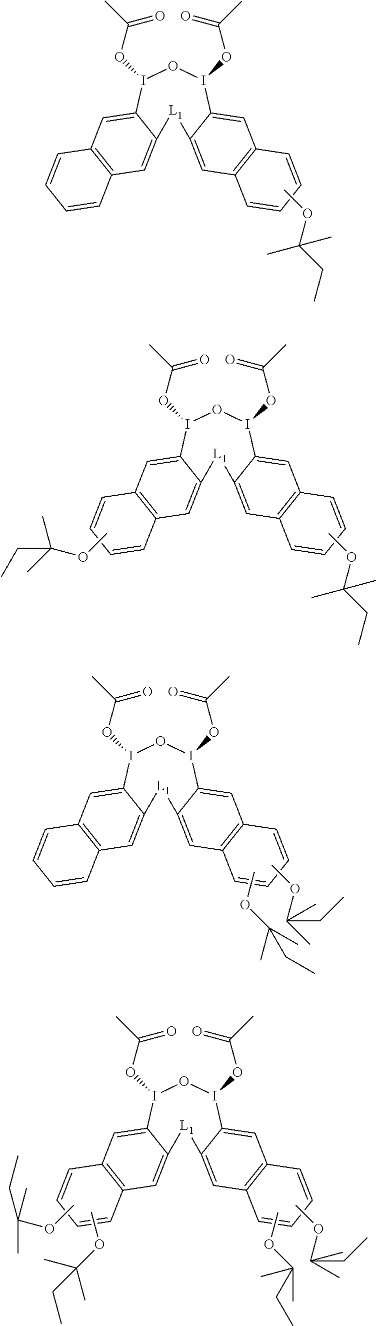

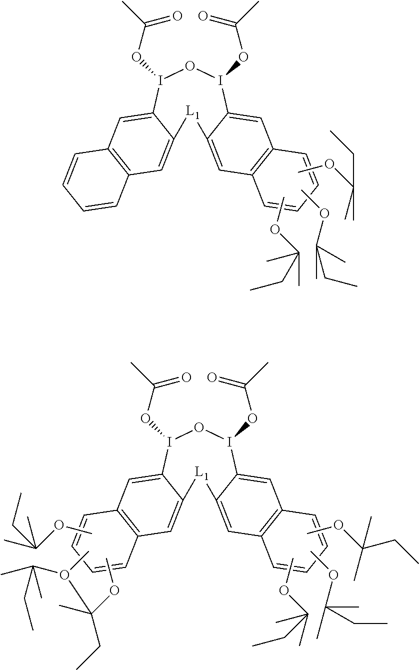

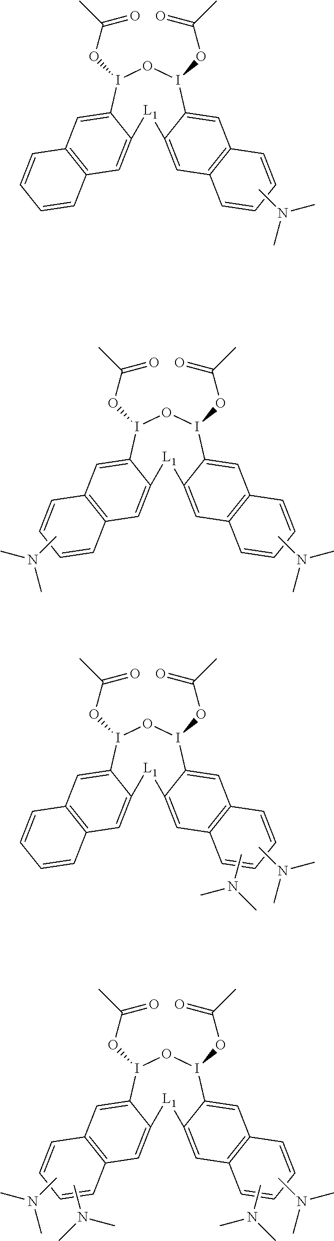

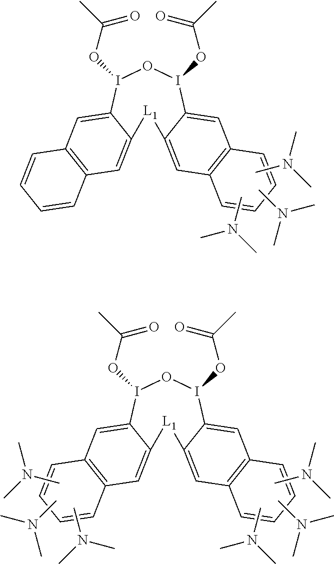

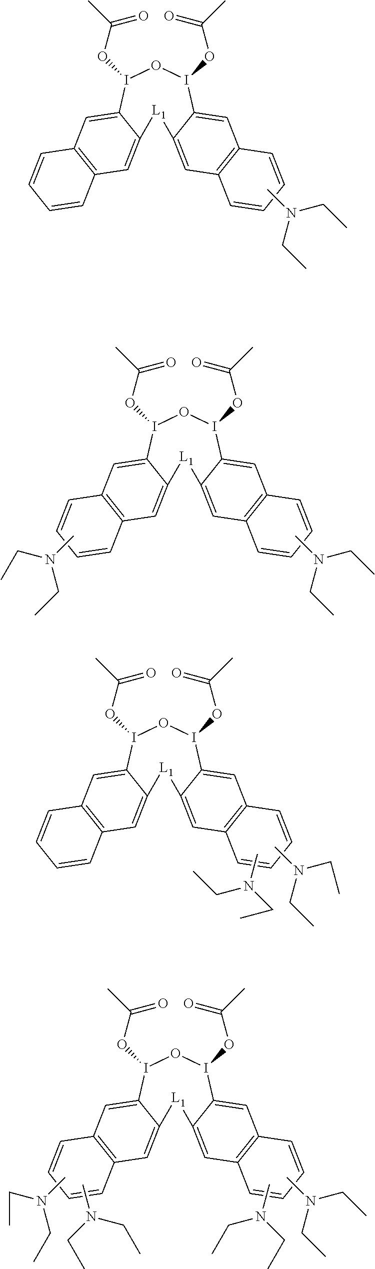

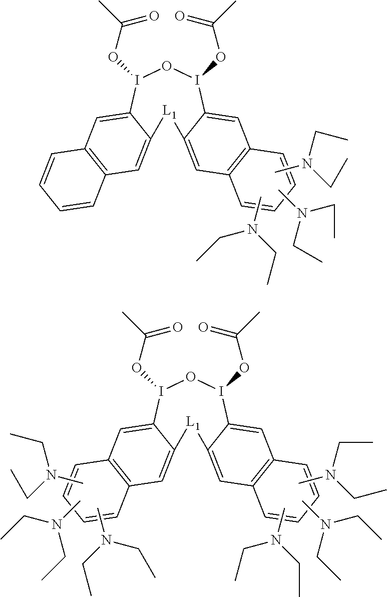

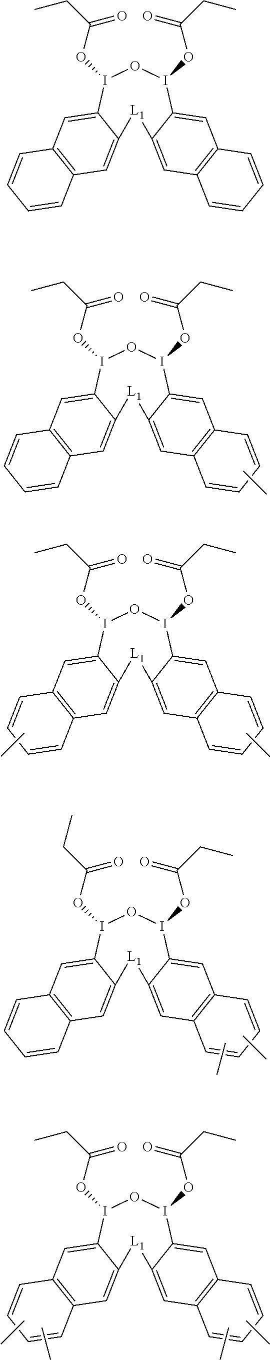

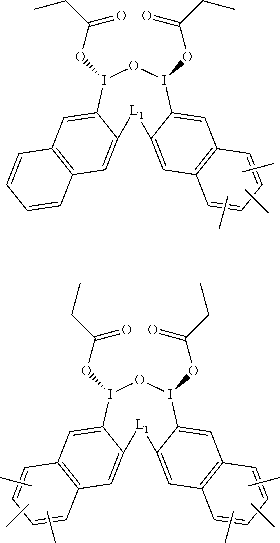

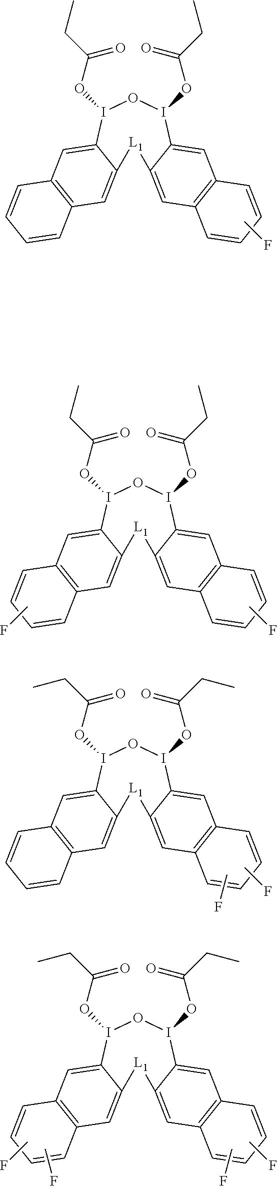

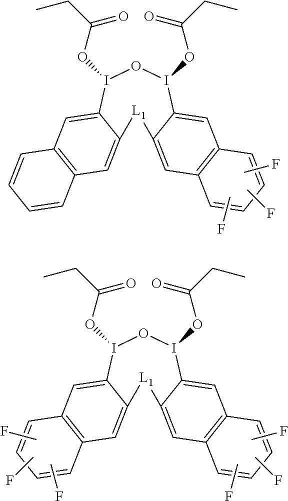

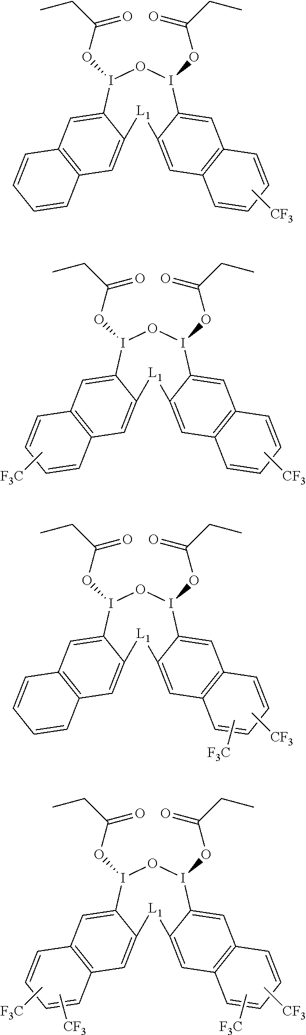

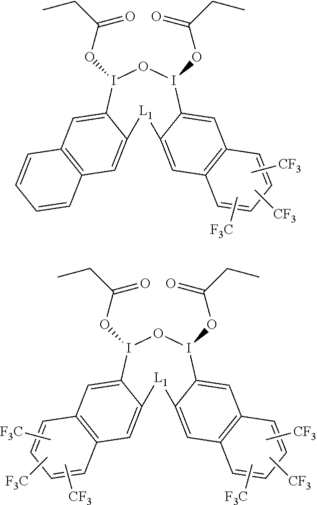

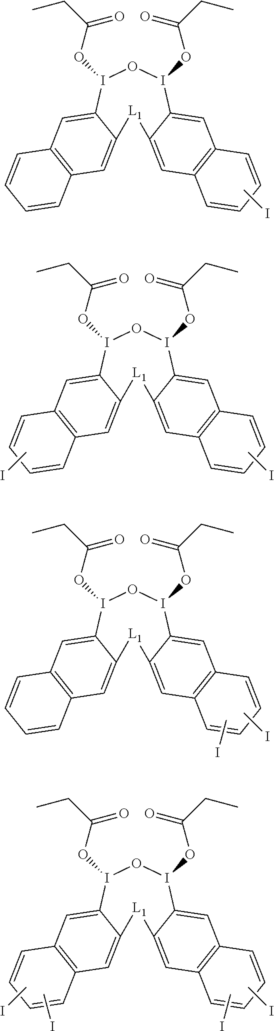

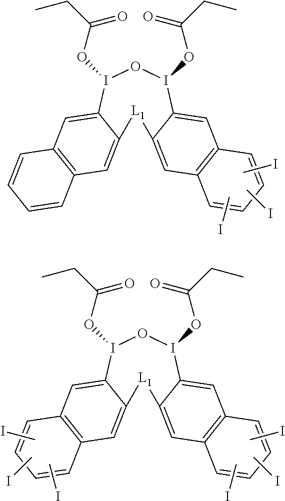

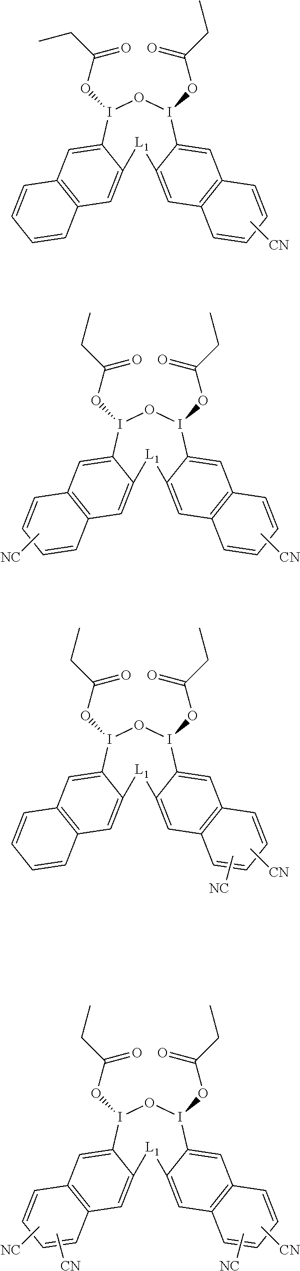

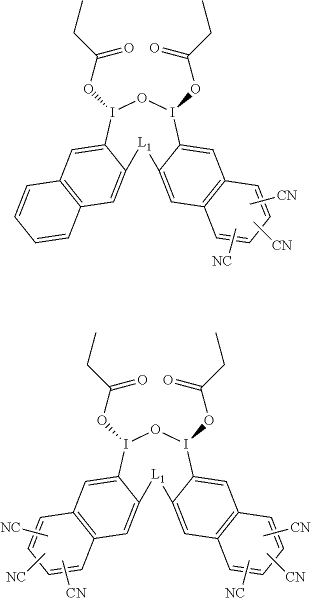

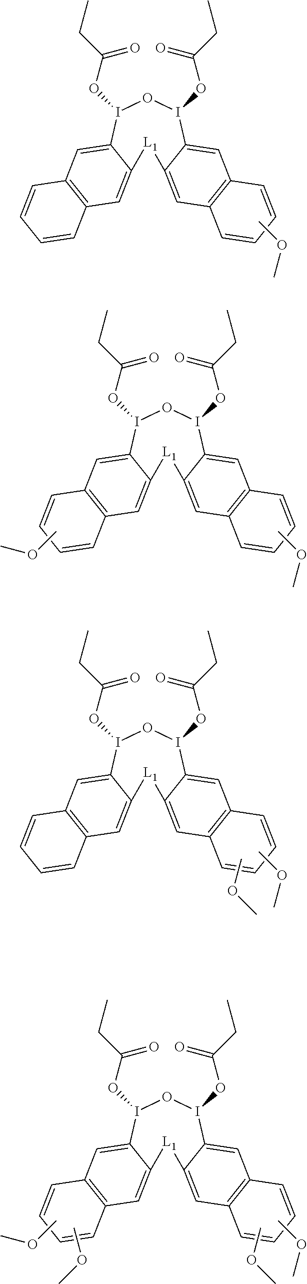

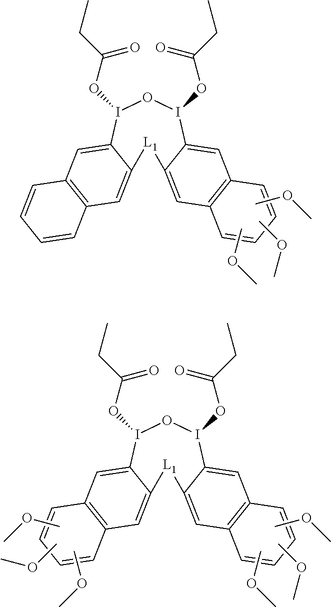

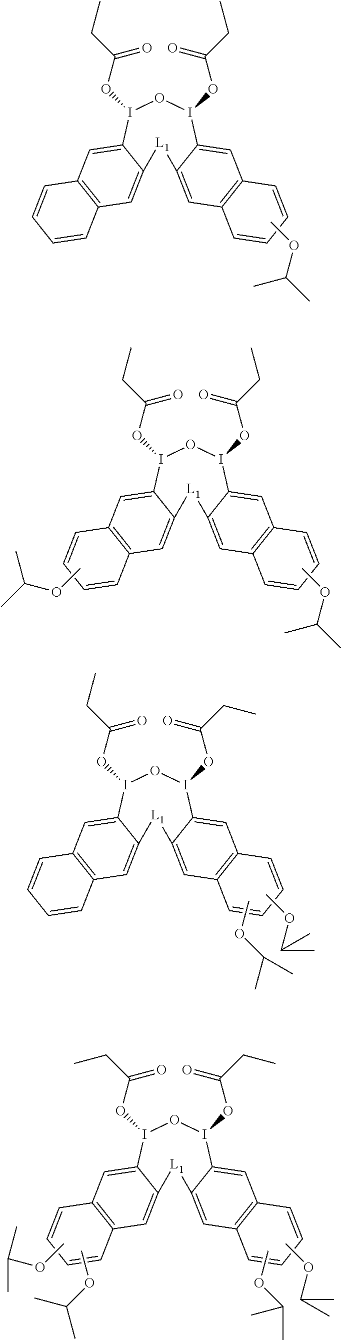

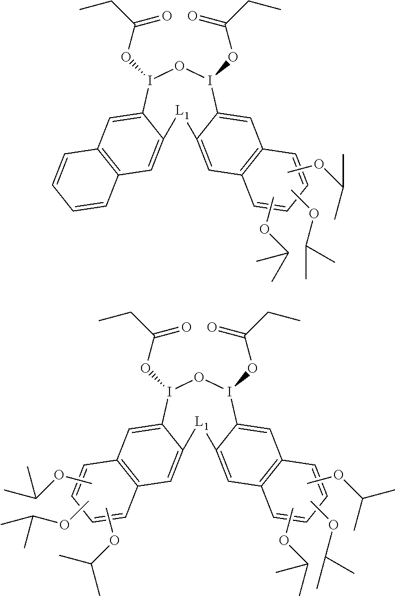

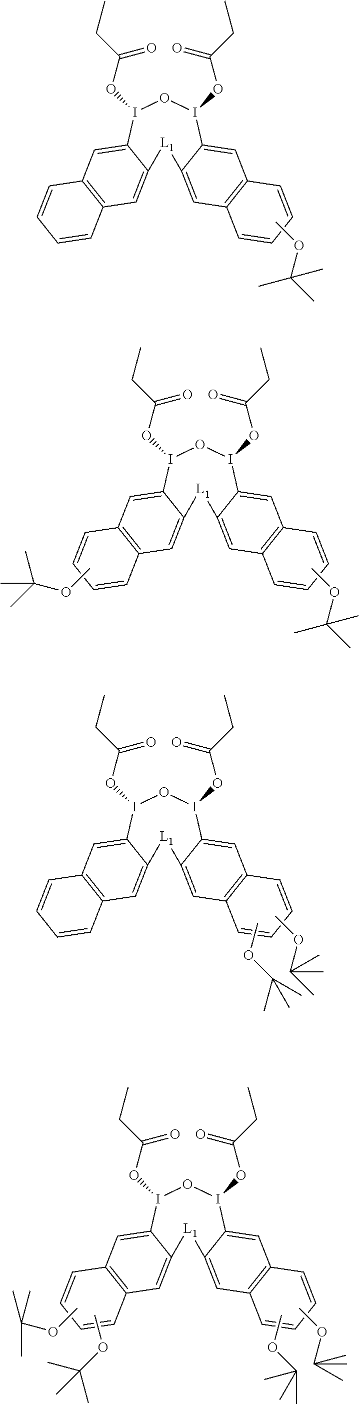

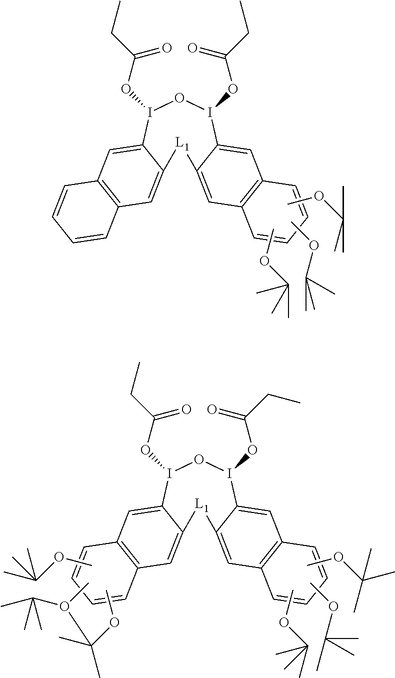

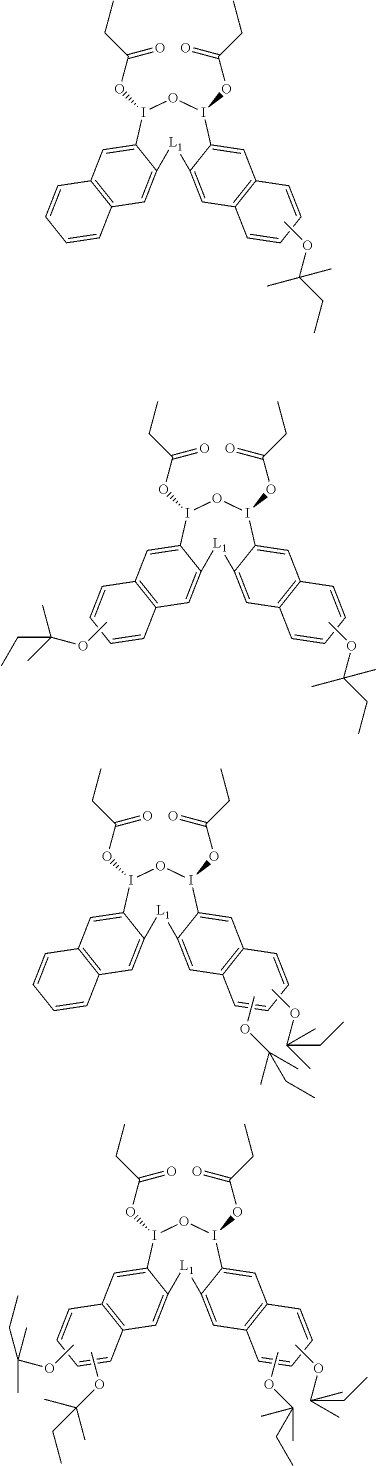

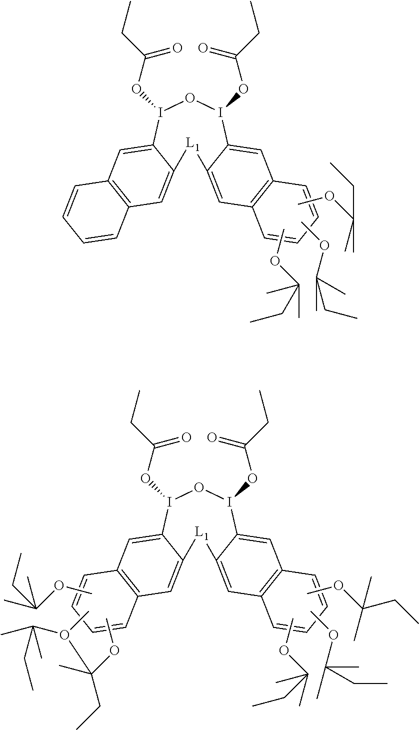

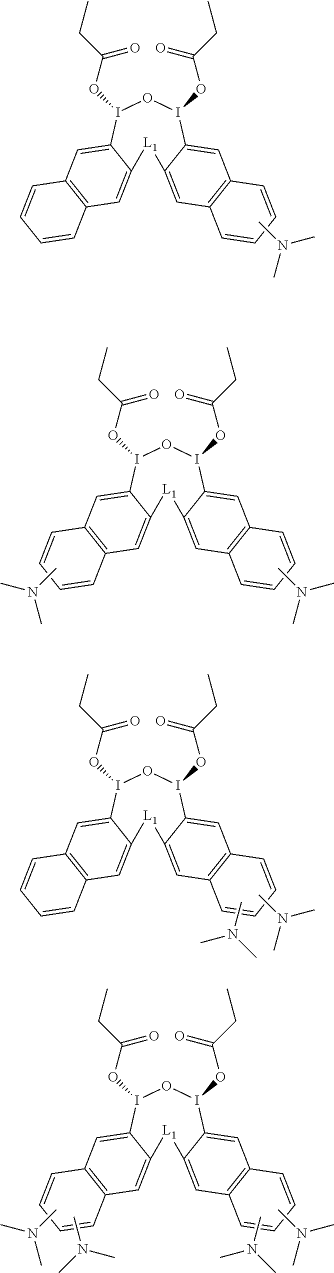

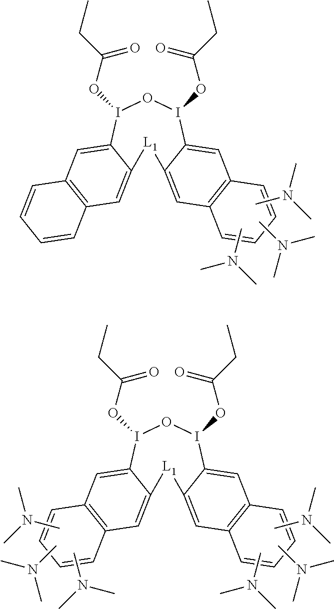

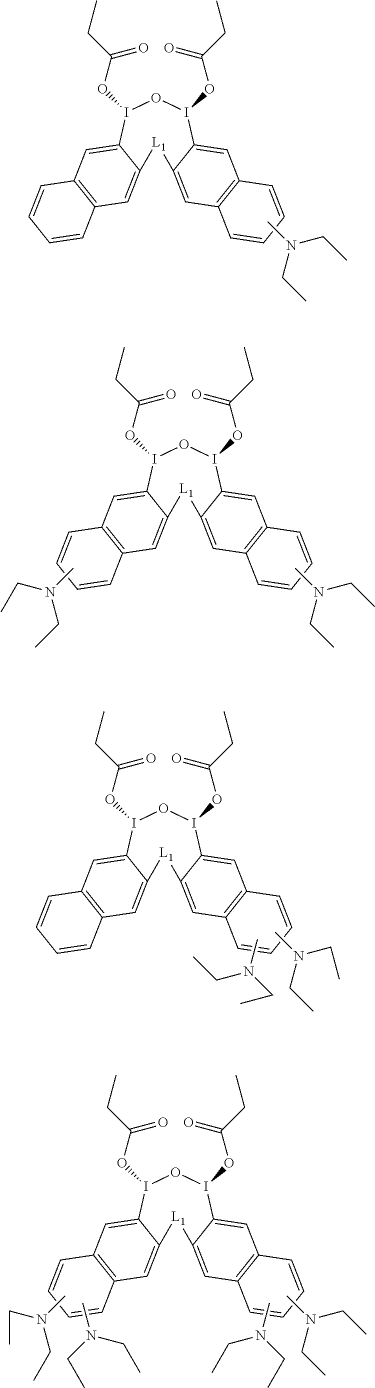

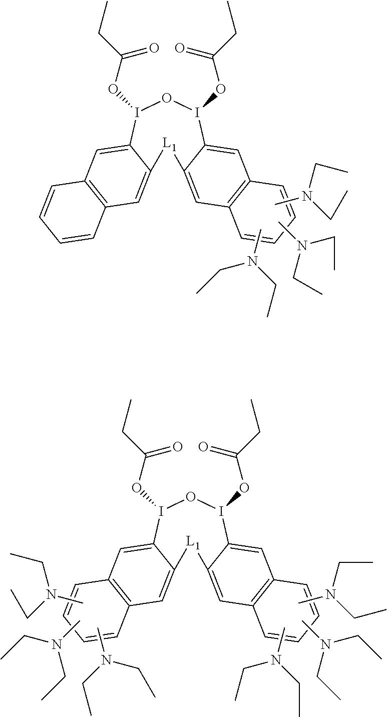

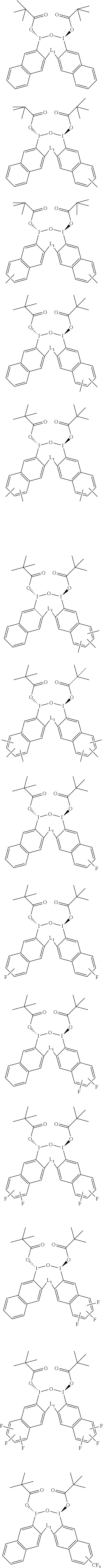

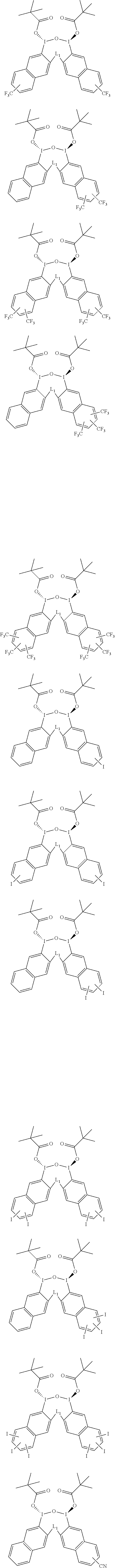

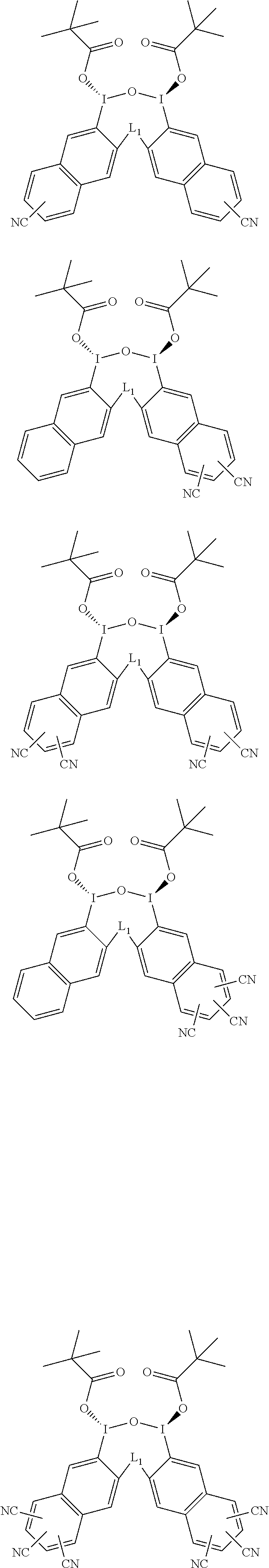

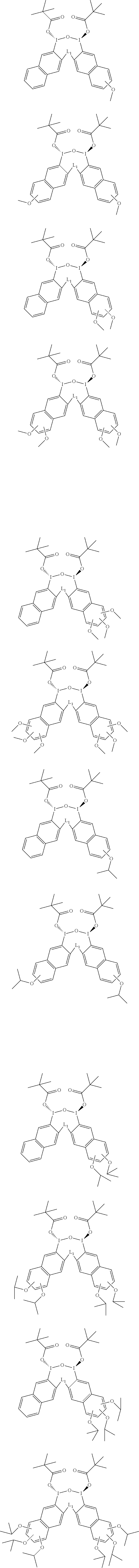

[chemical structure]

[chemical structure]

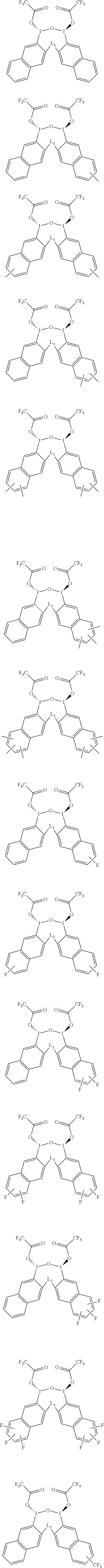

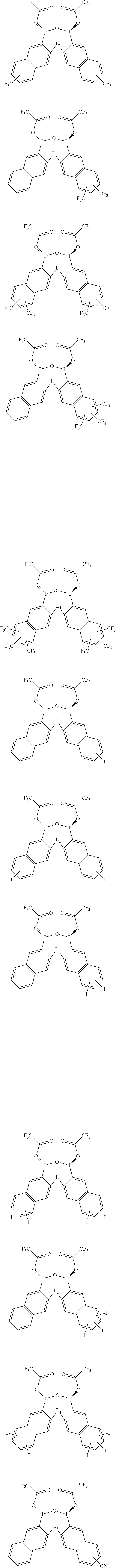

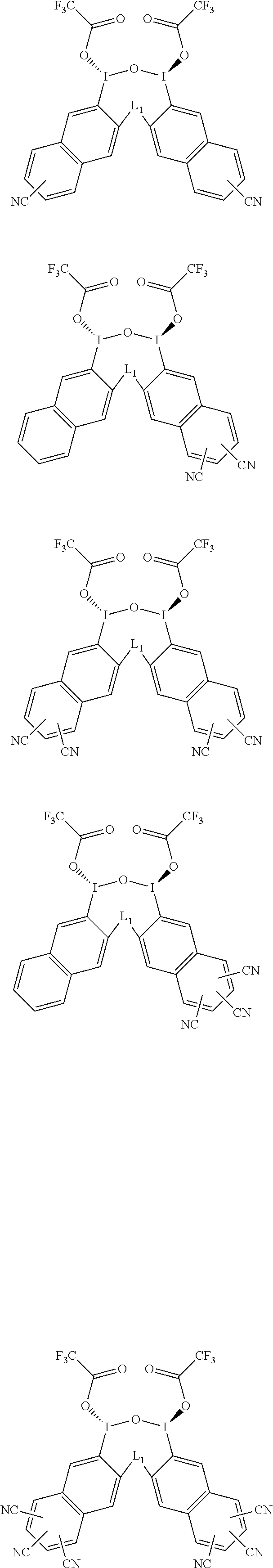

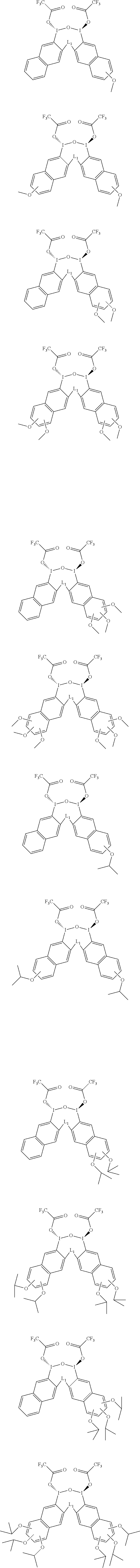

[chemical structure]

[chemical structure]

Specific examples of the hypervalent iodine compound represented by the general formula (7) include the following, but are not limited thereto.

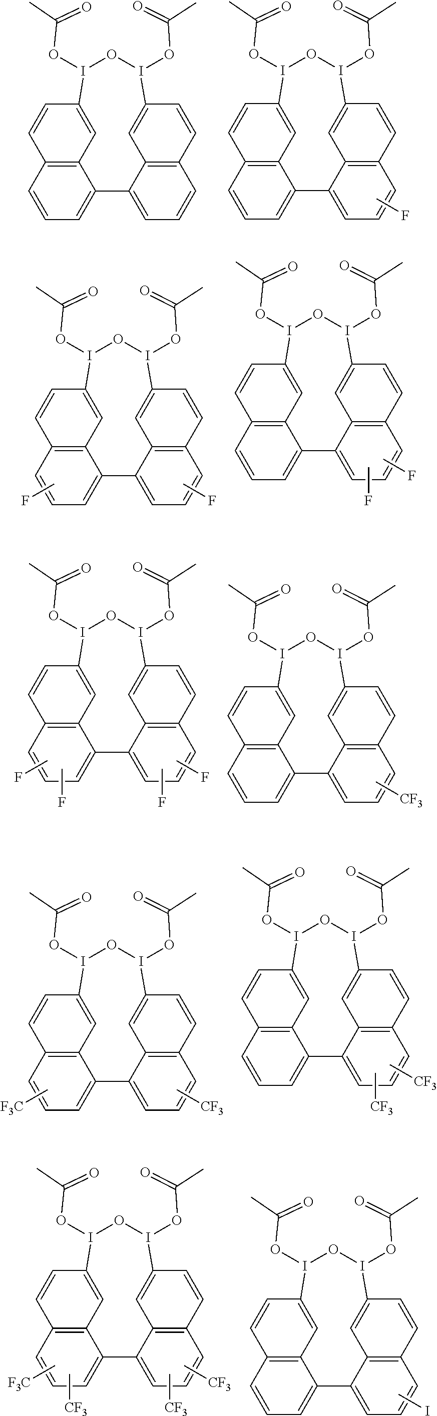

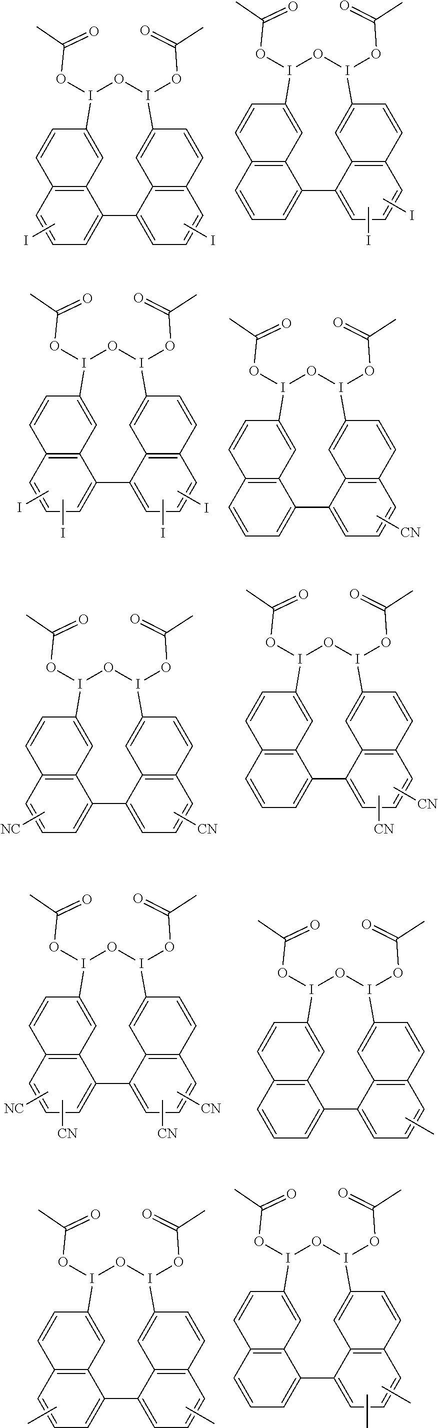

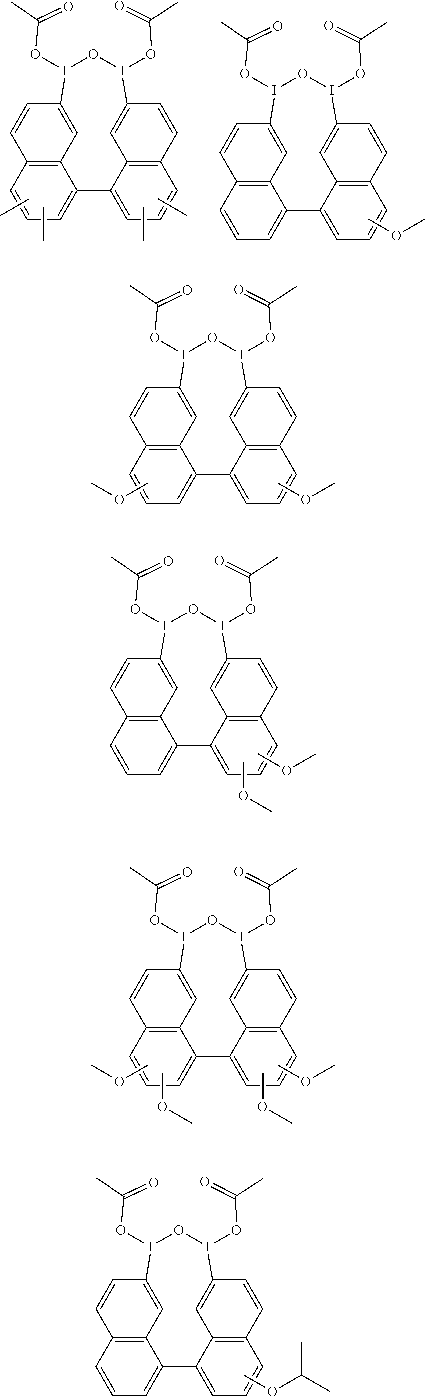

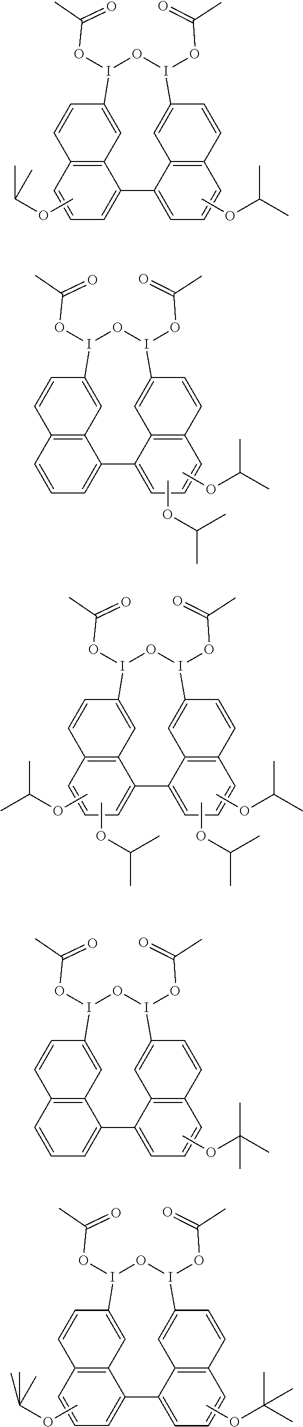

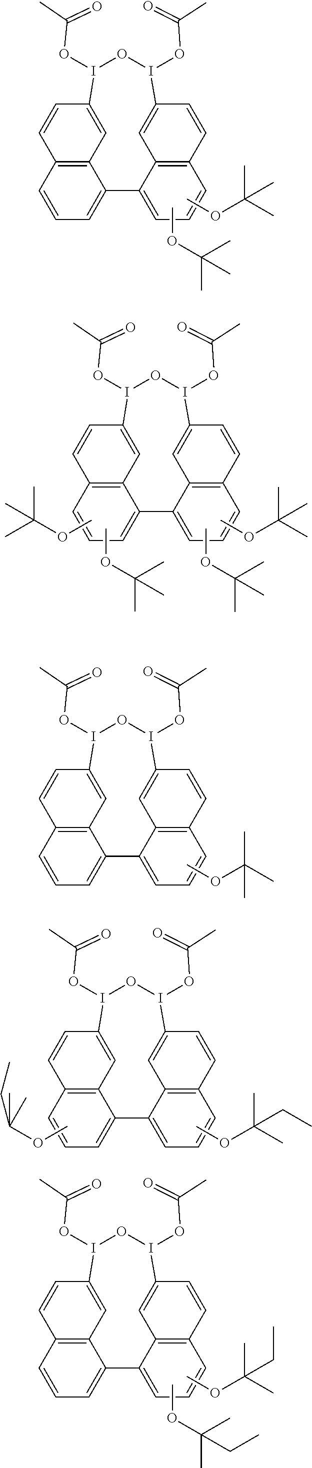

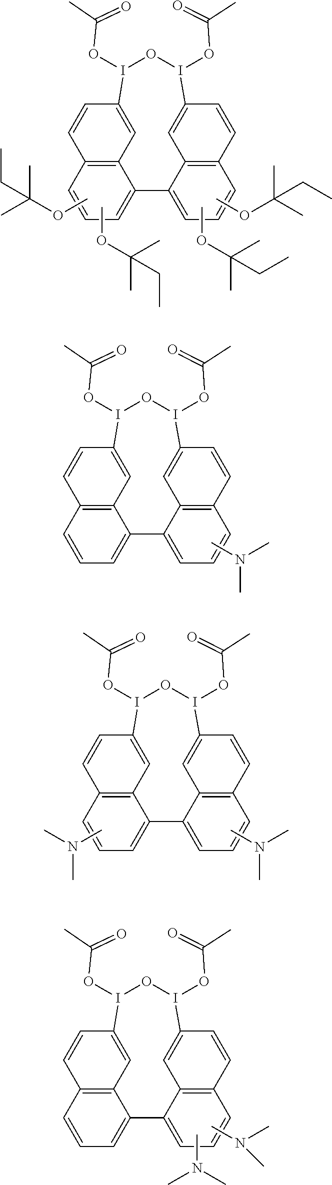

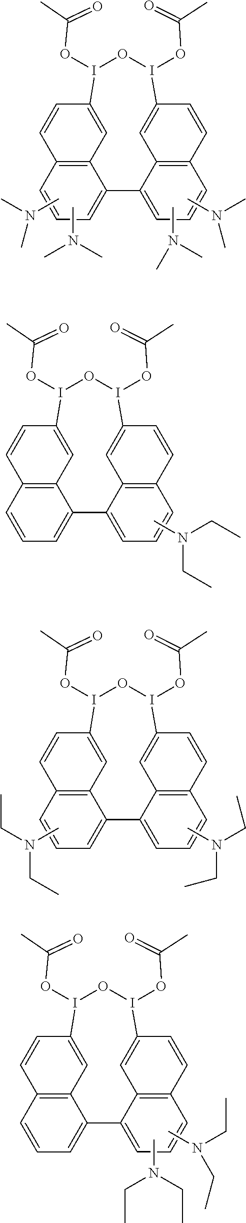

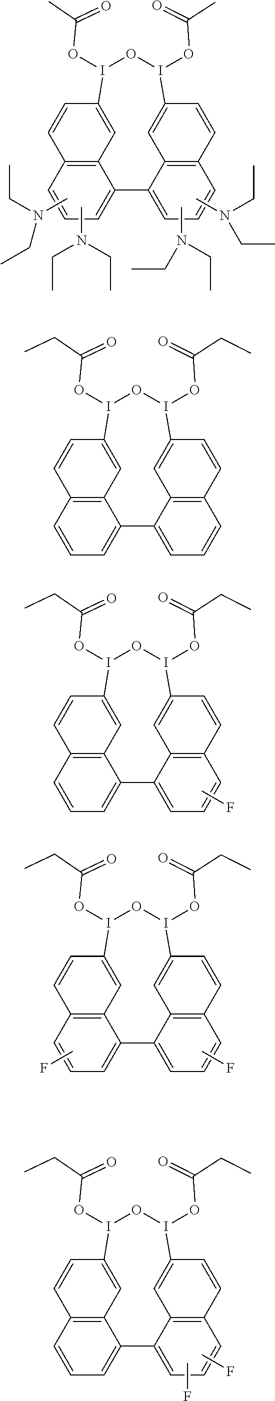

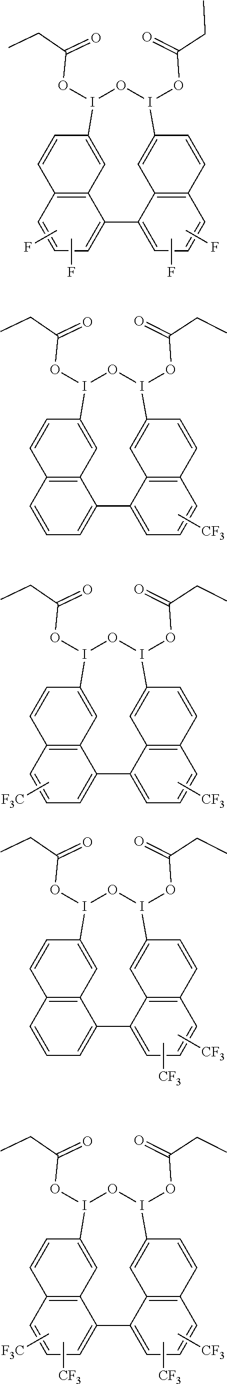

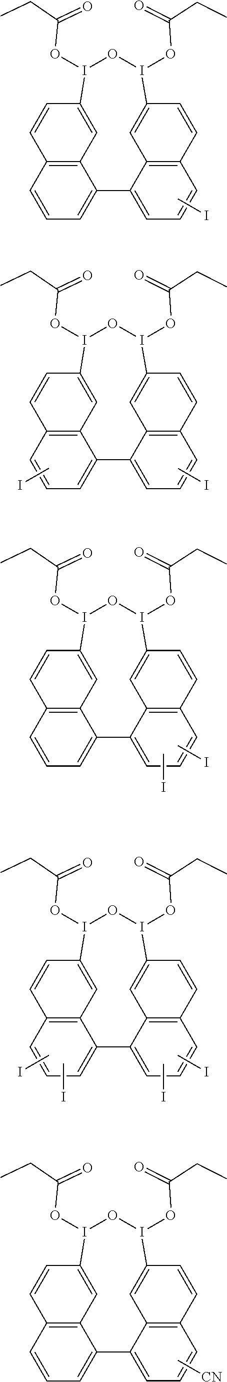

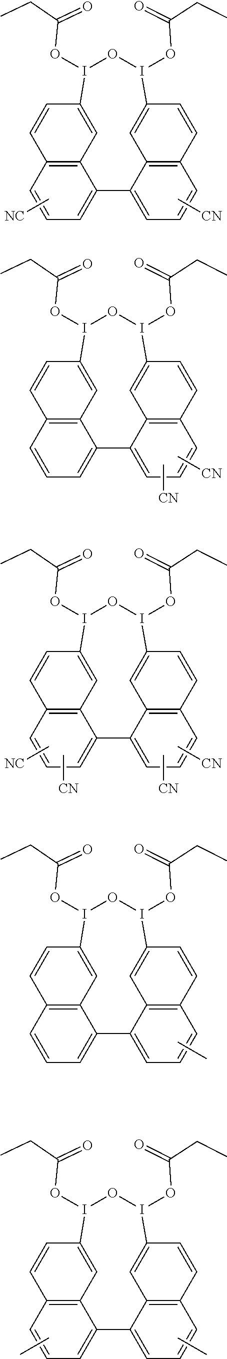

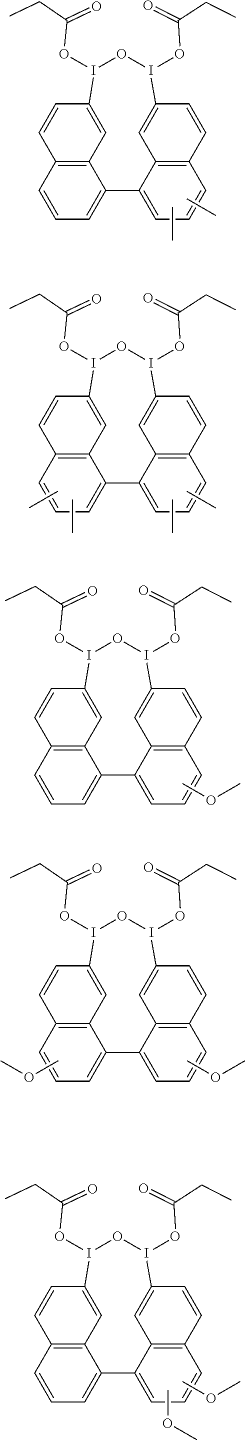

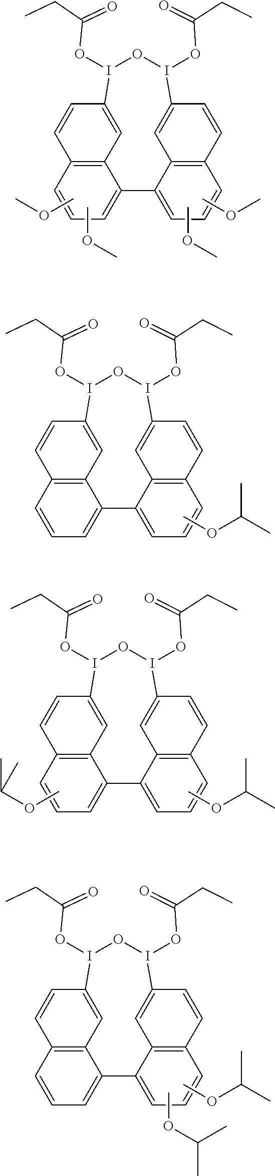

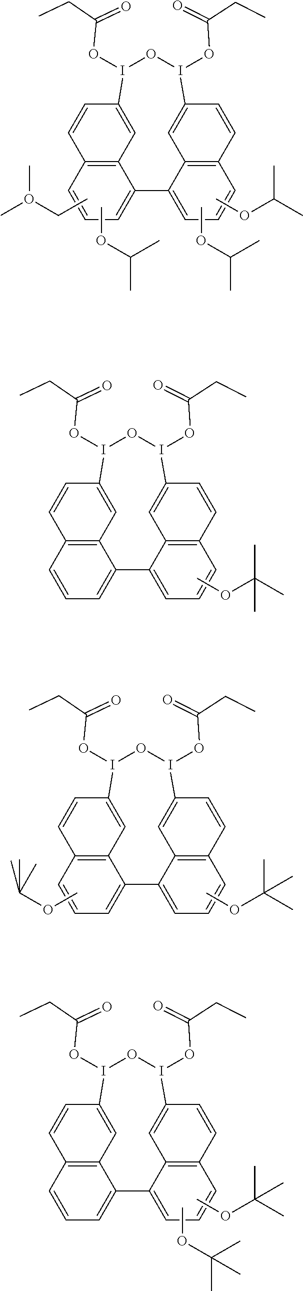

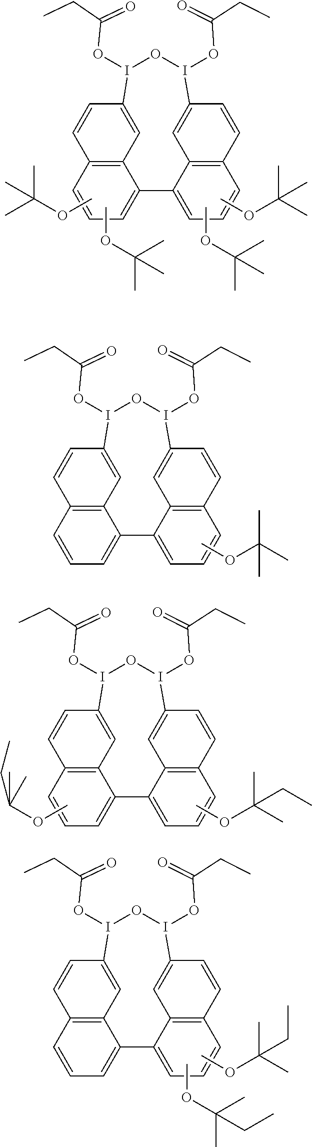

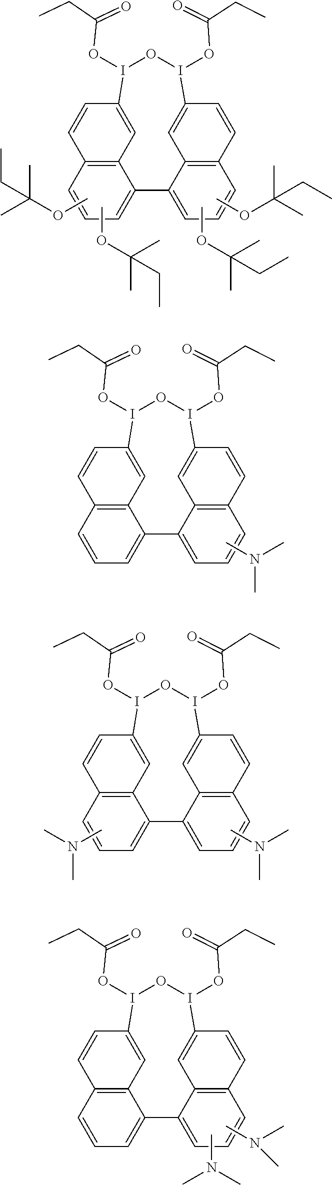

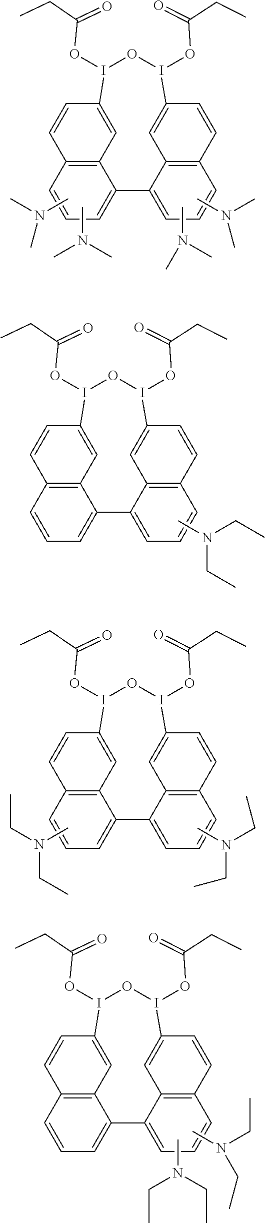

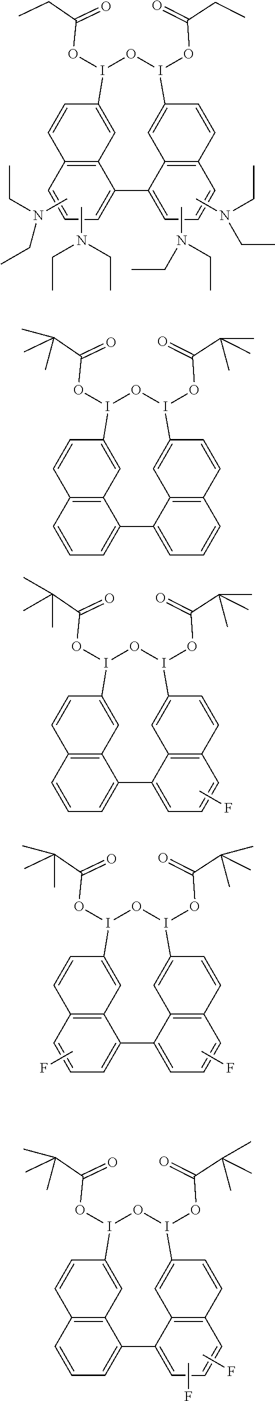

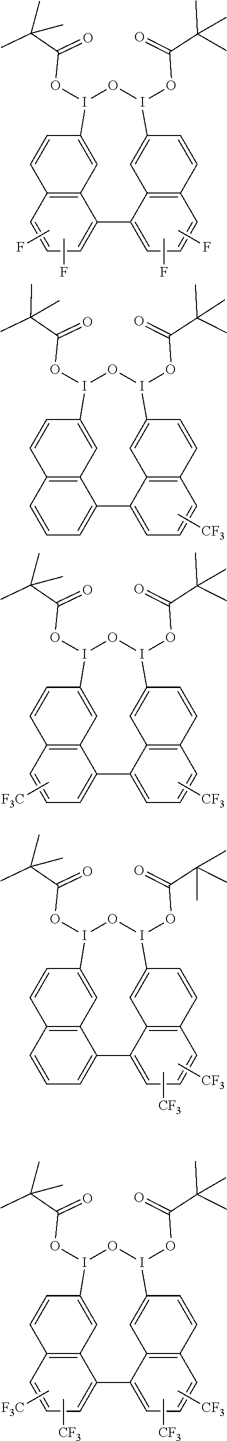

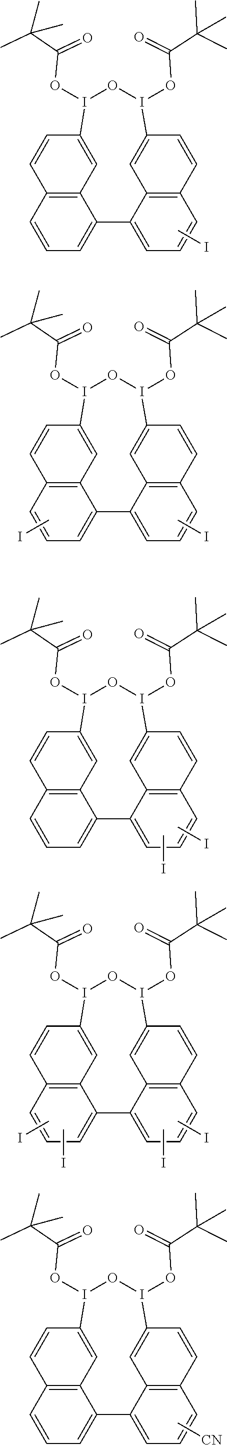

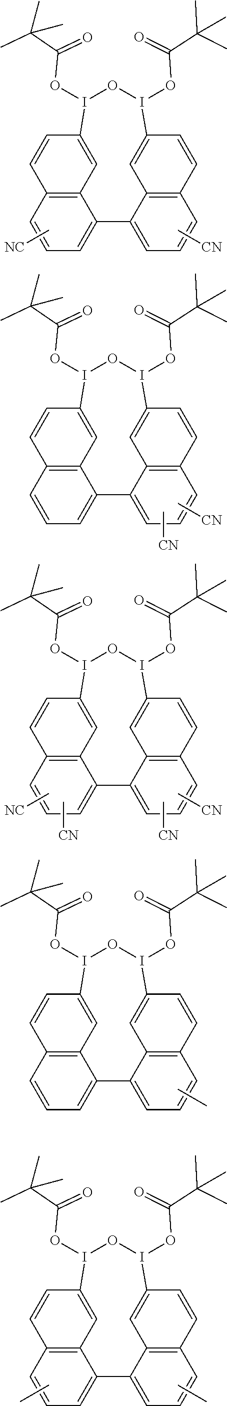

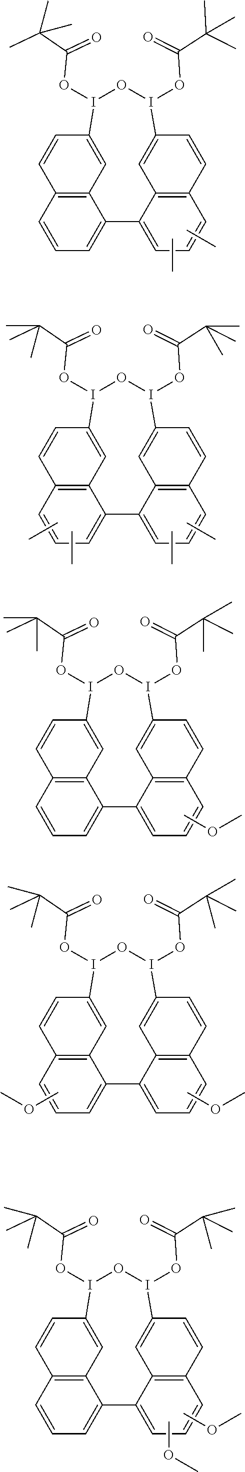

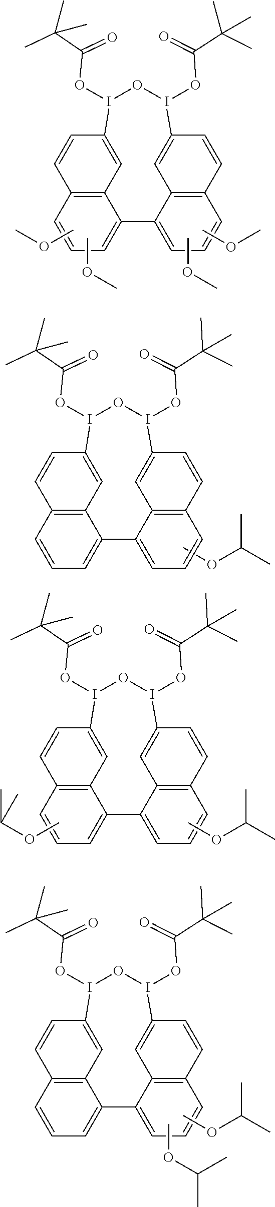

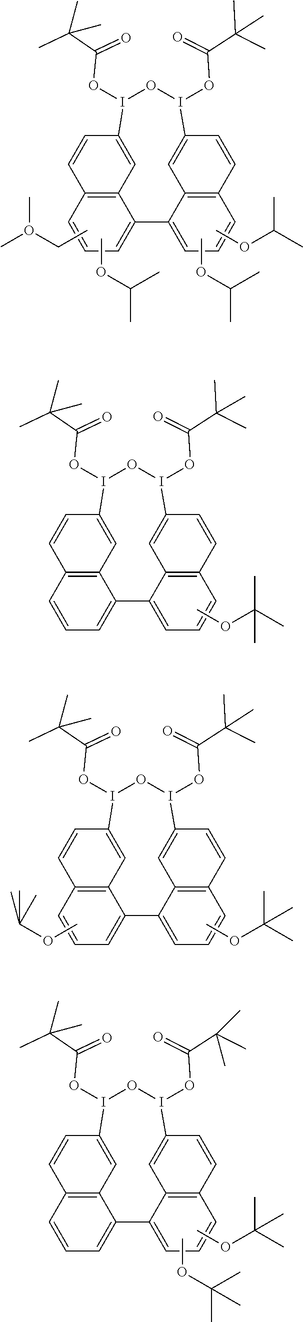

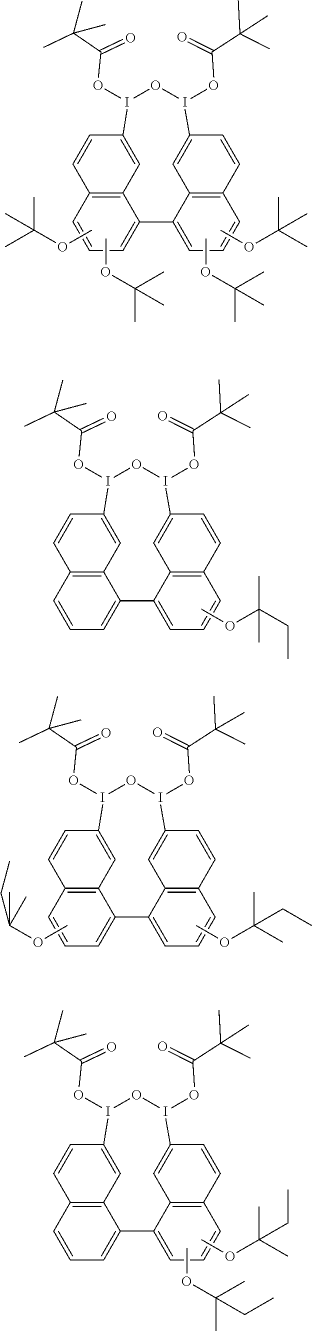

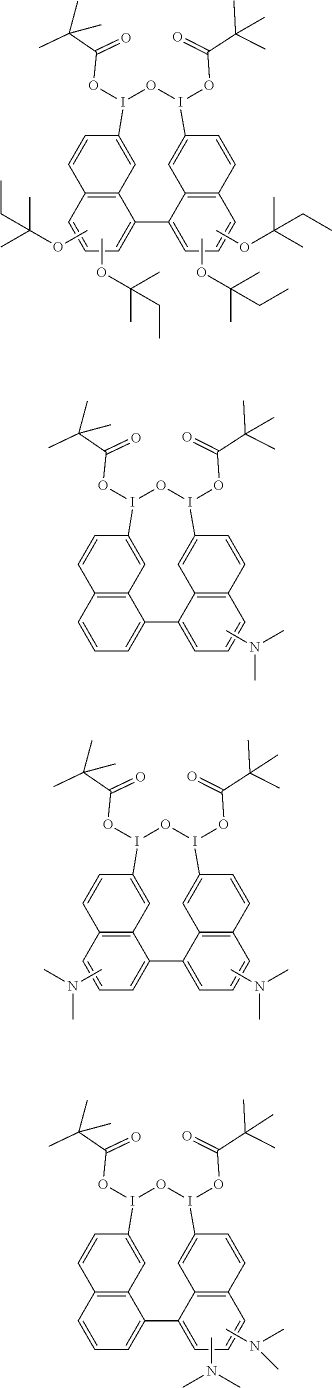

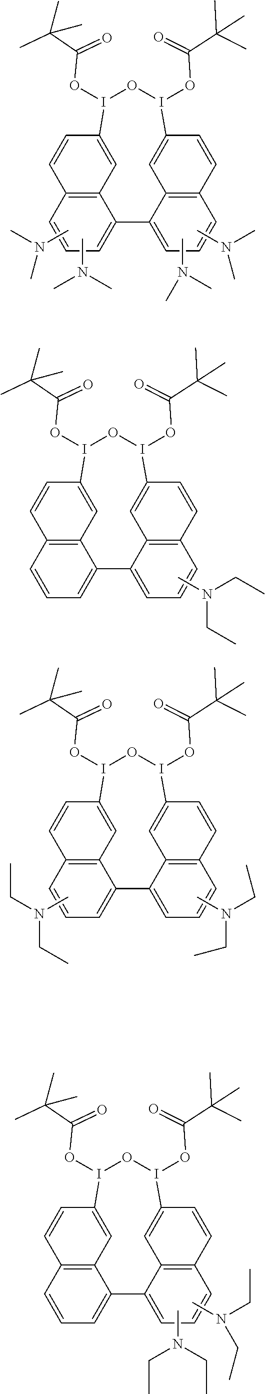

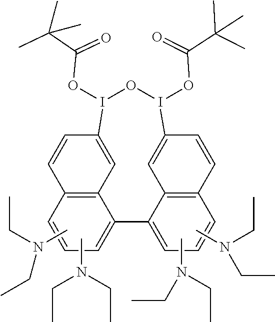

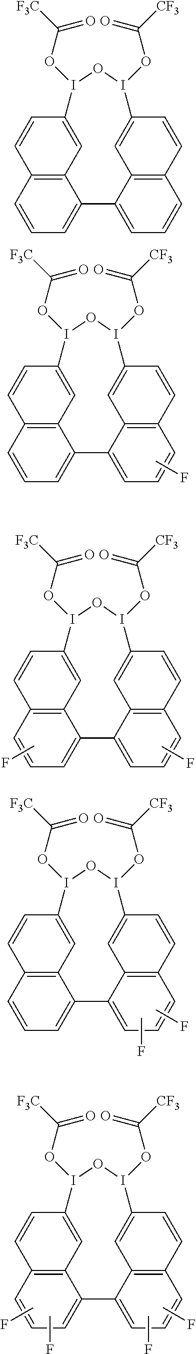

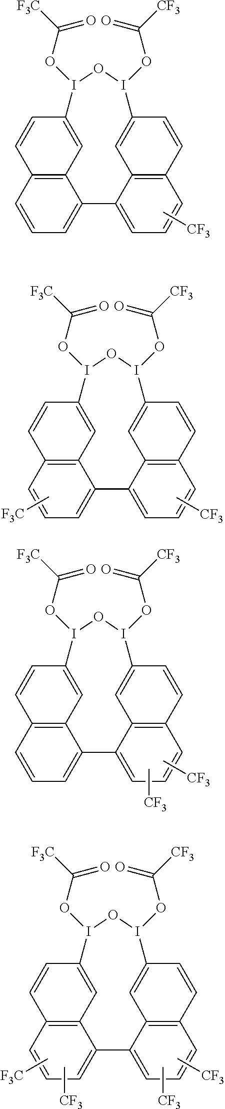

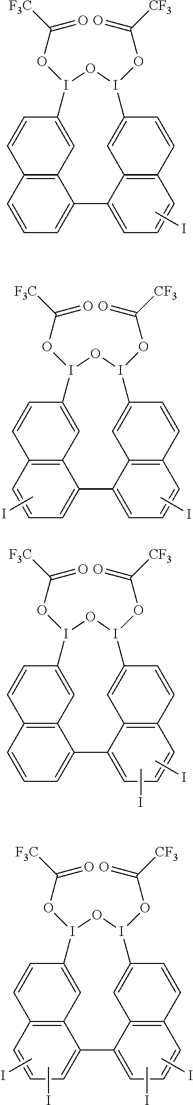

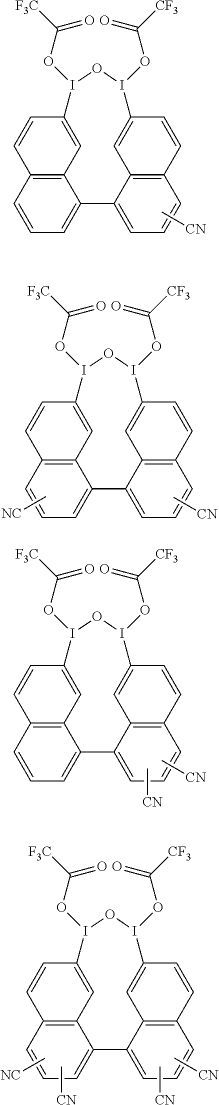

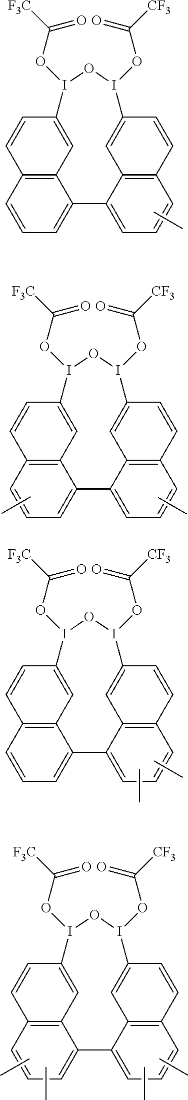

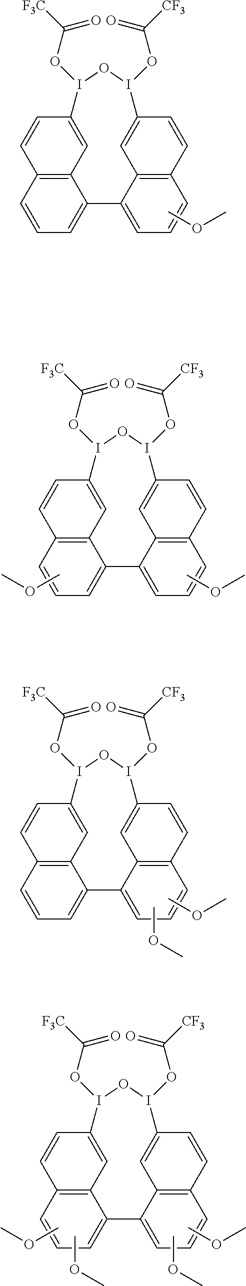

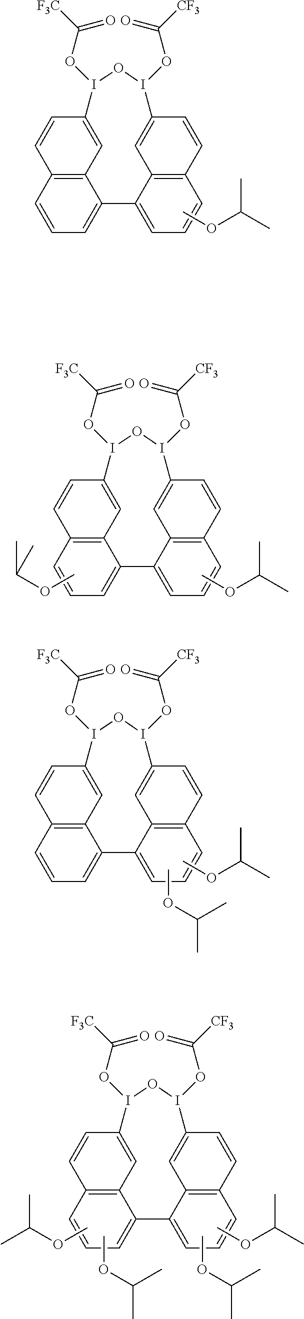

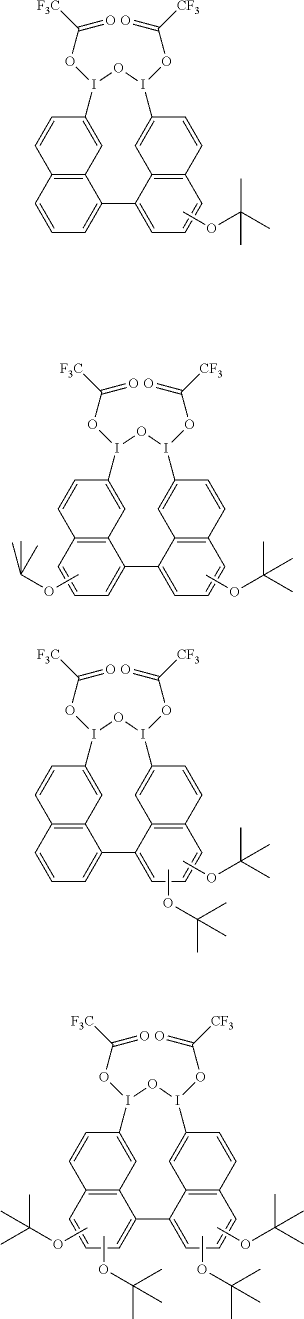

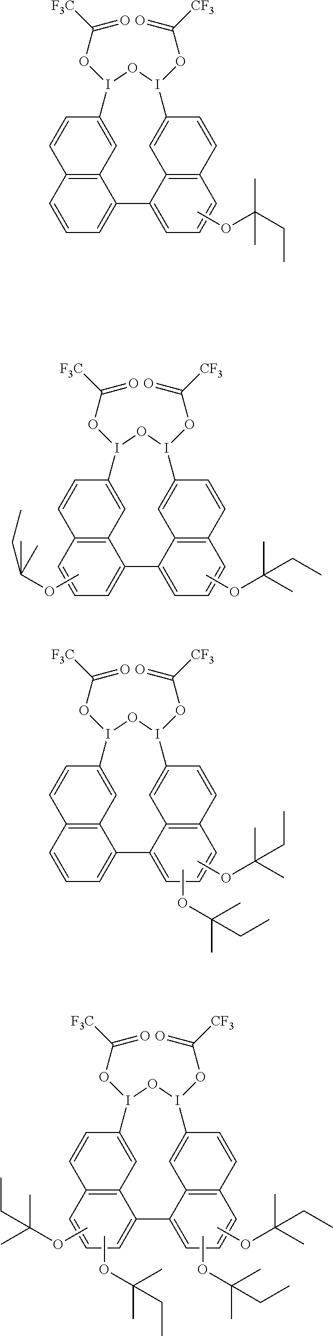

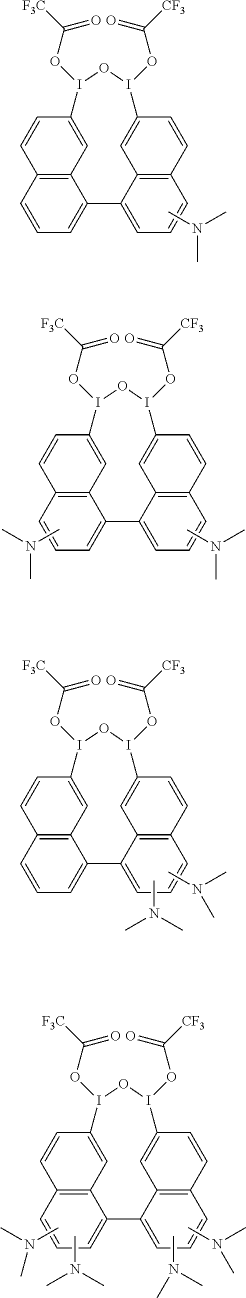

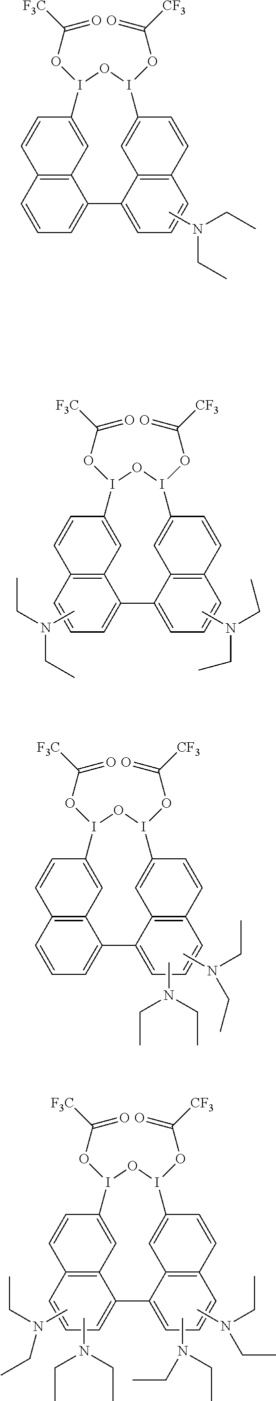

Specific examples of the hypervalent iodine compound represented by the general formula (8) include the following, but are not limited thereto.

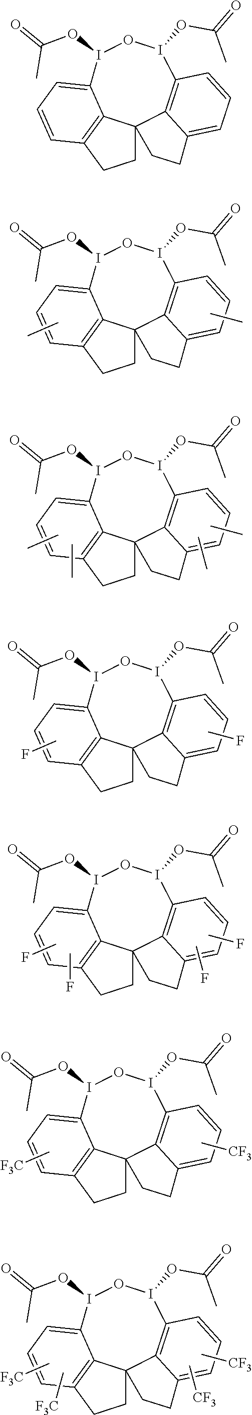

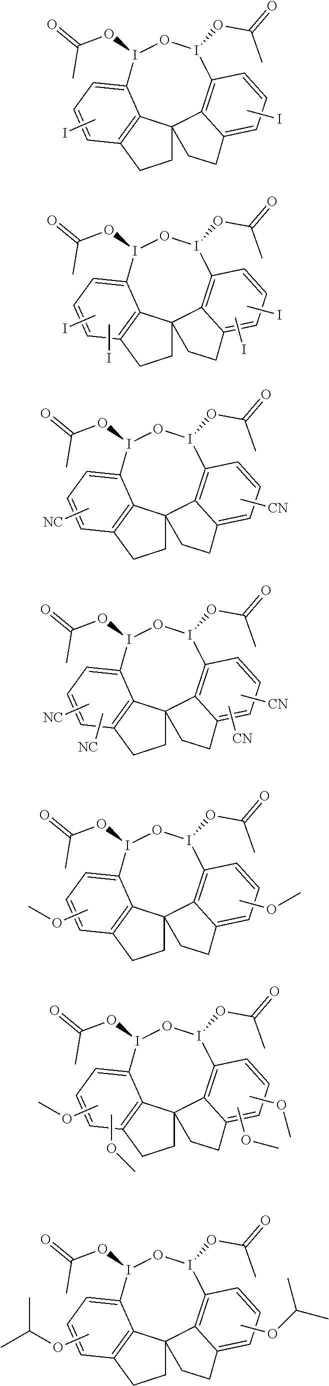

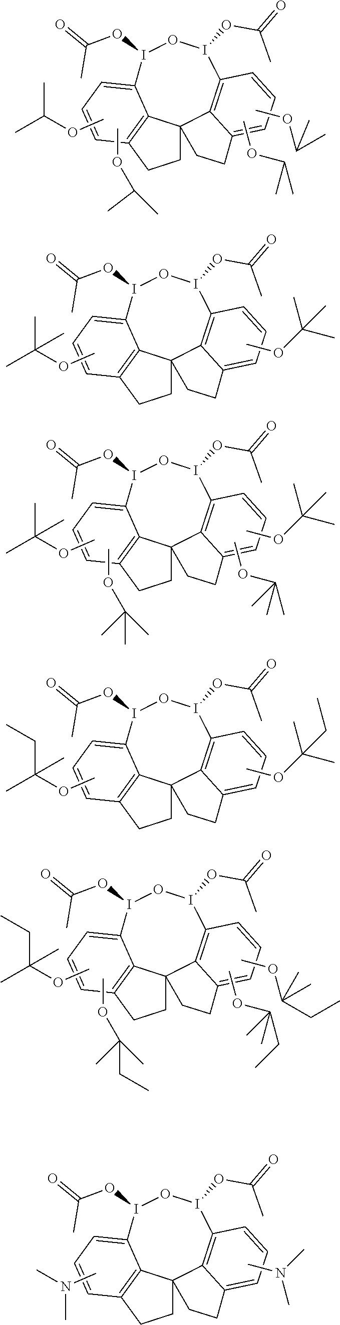

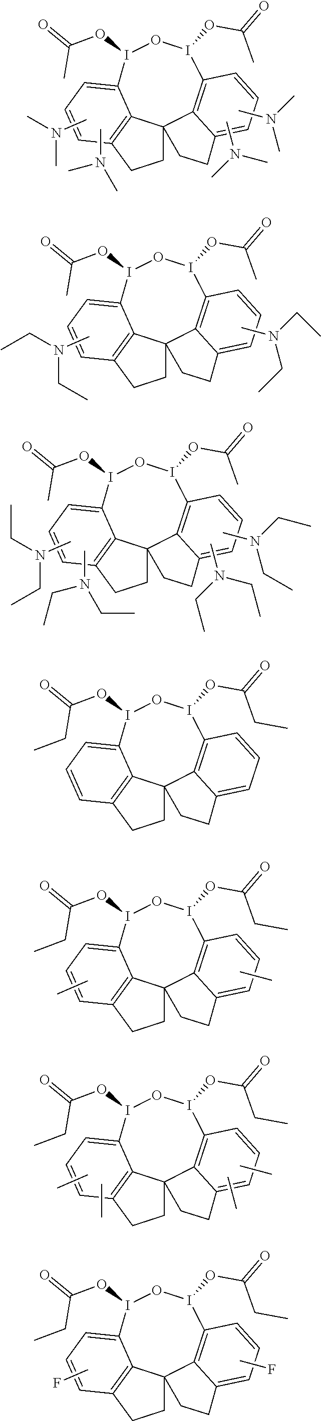

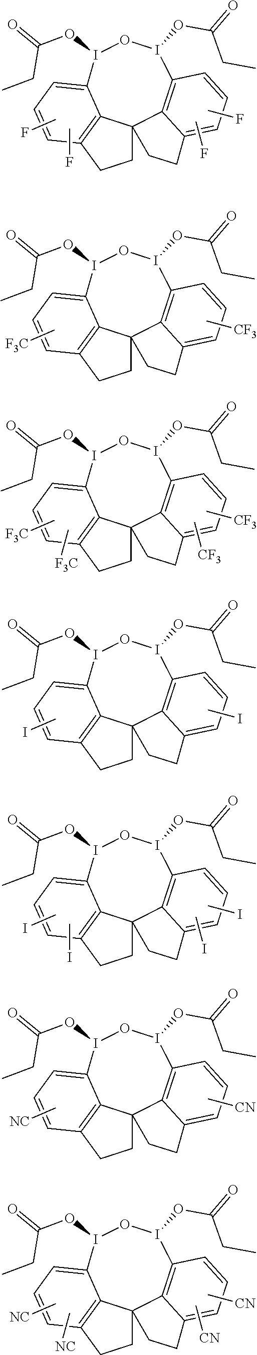

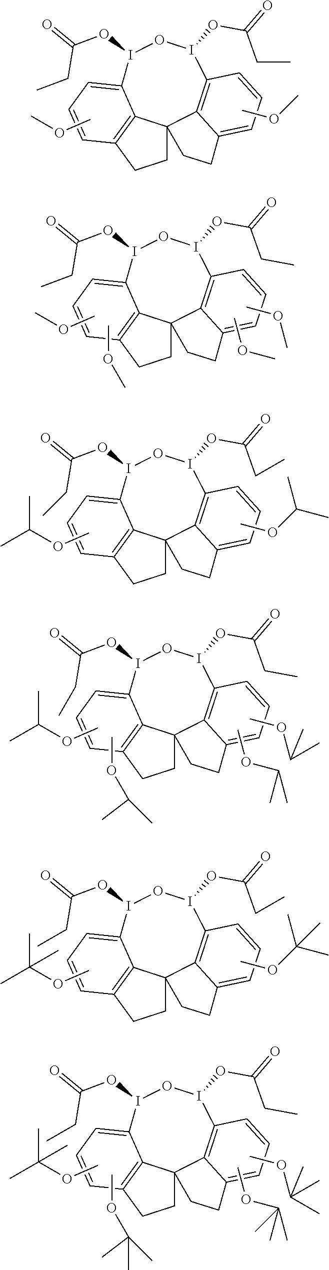

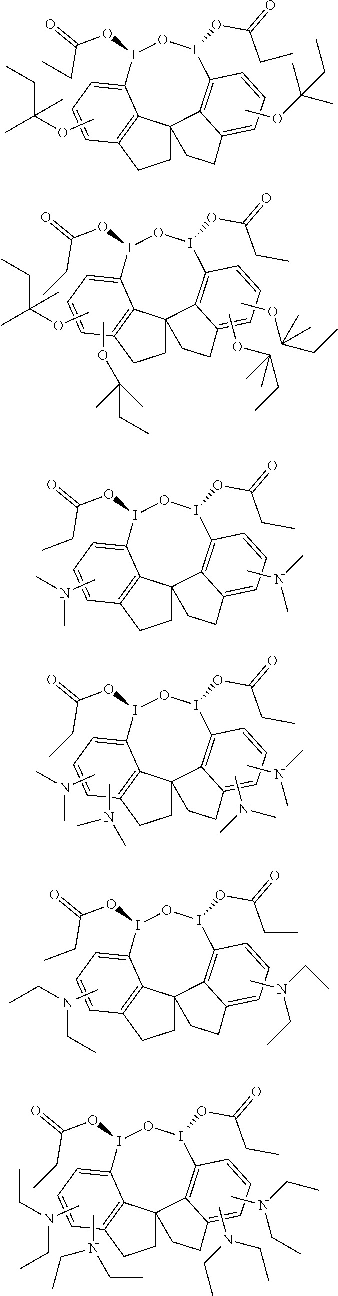

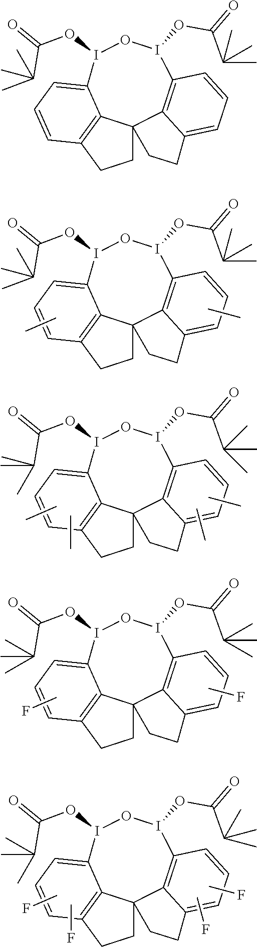

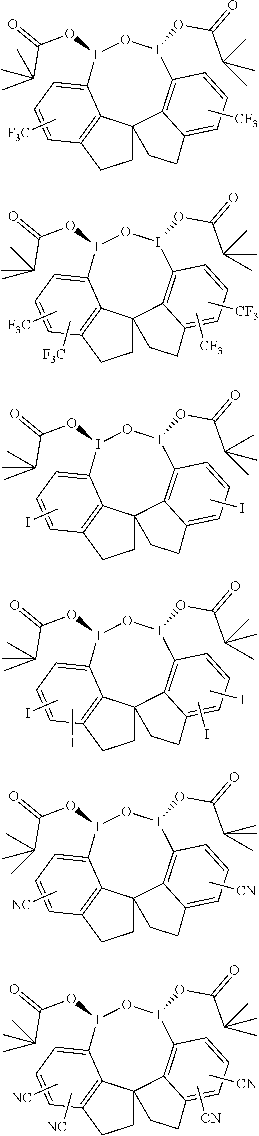

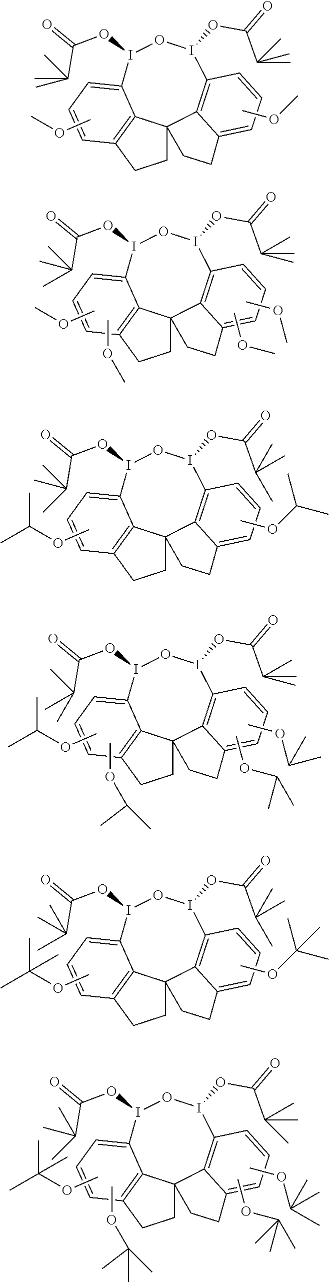

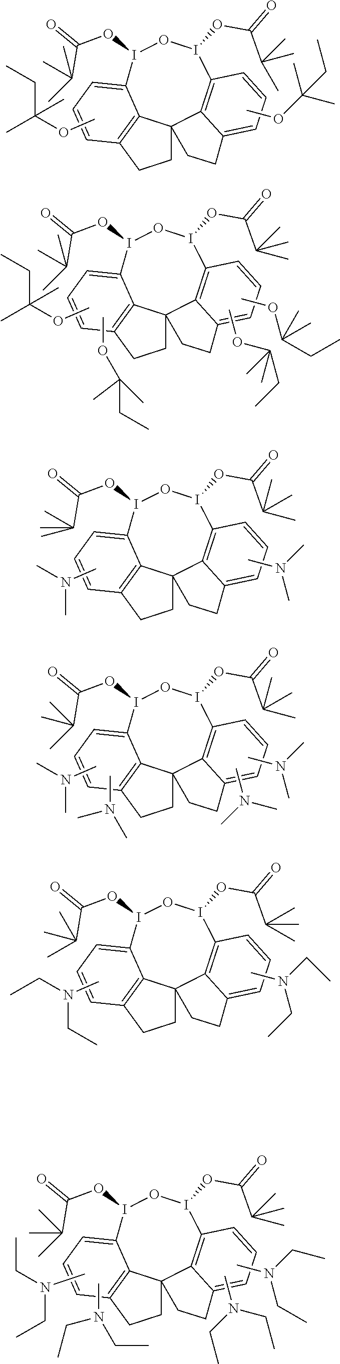

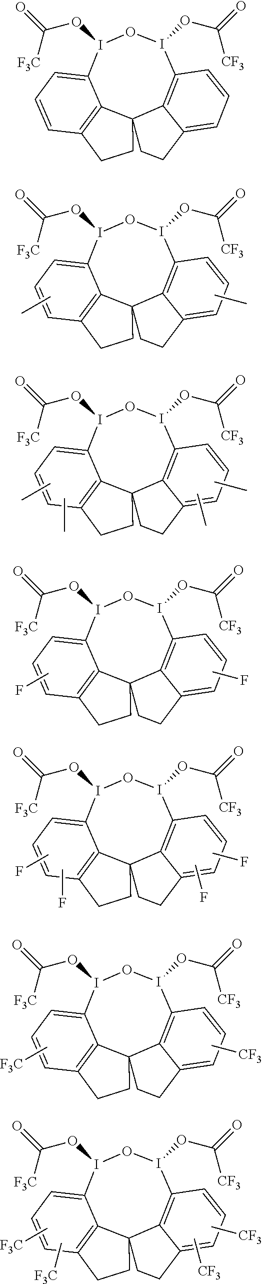

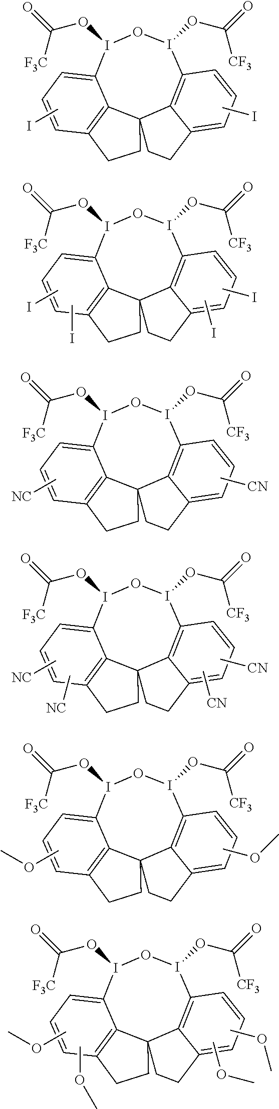

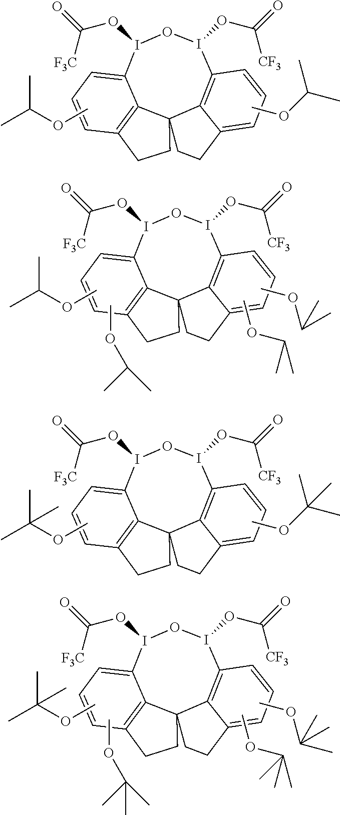

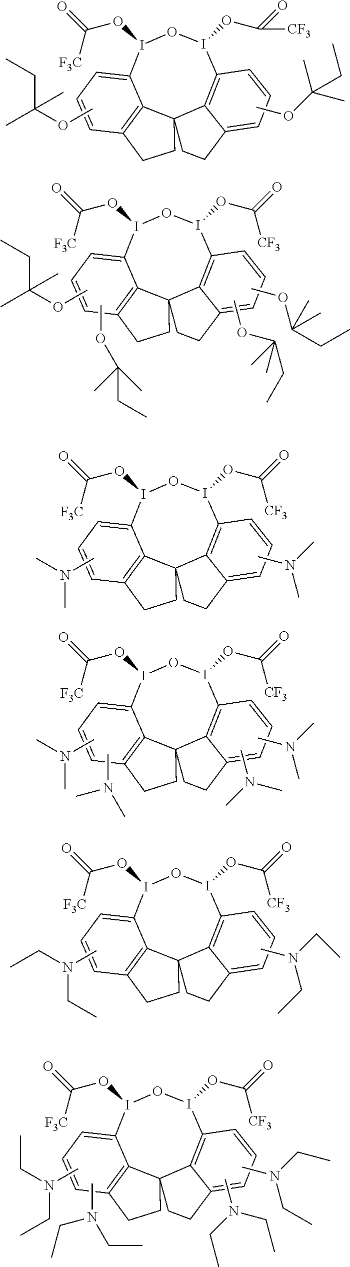

Specific examples of the hypervalent iodine compound represented by the general formula (9) include the following, but are not limited thereto. Note that, in the following formulae, Me represents a methyl group.

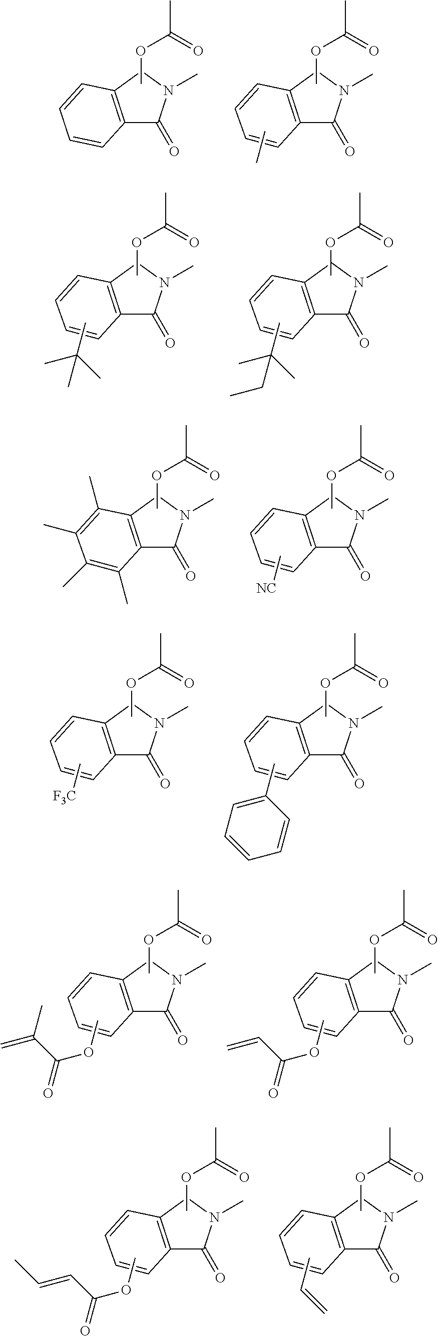

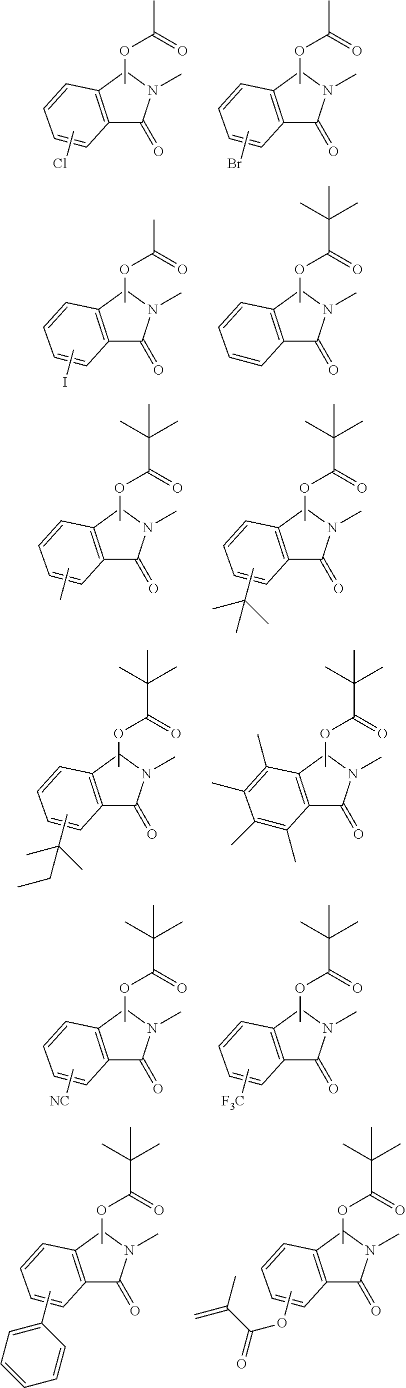

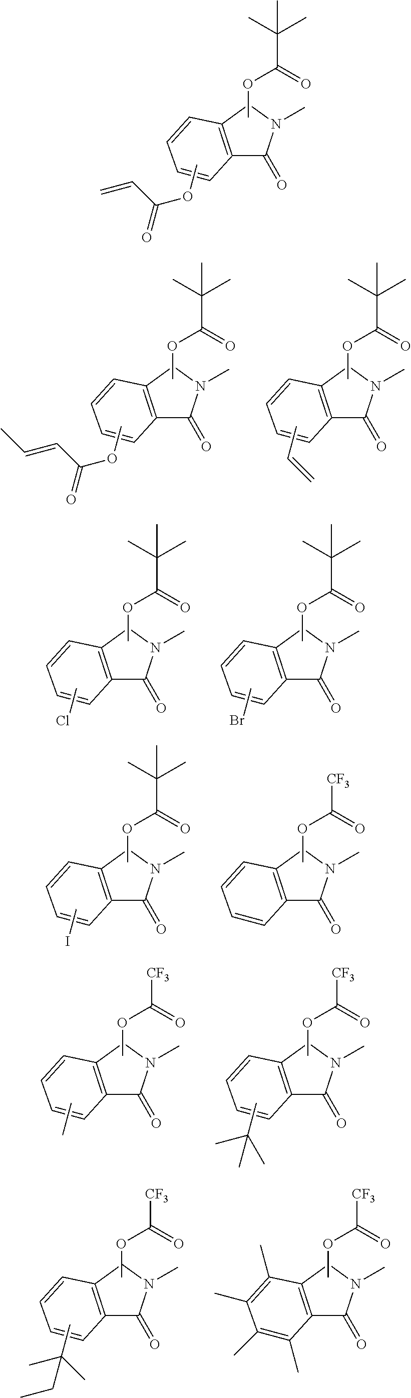

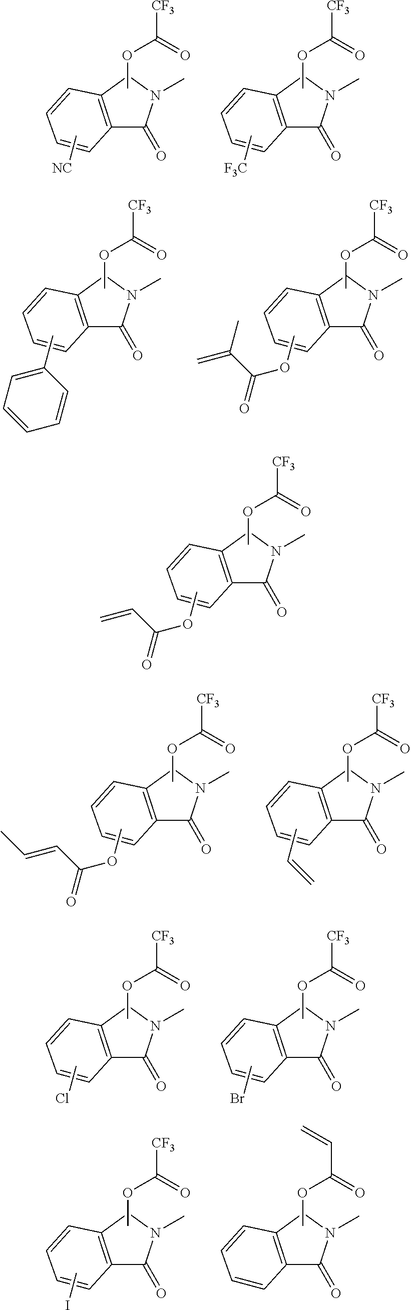

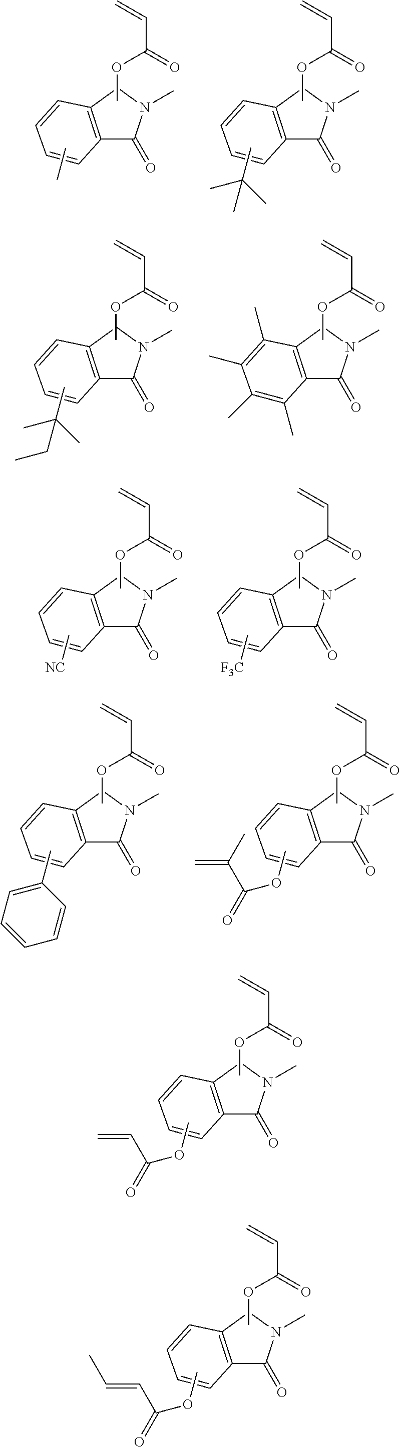

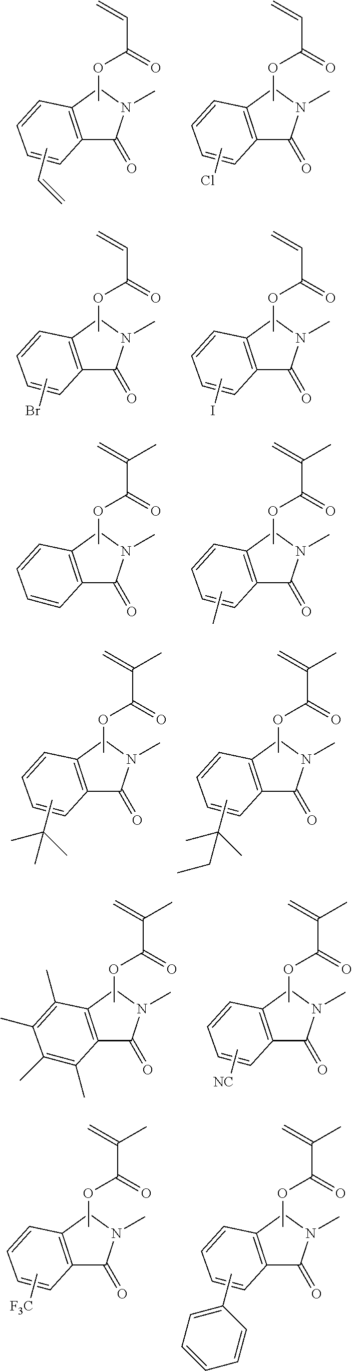

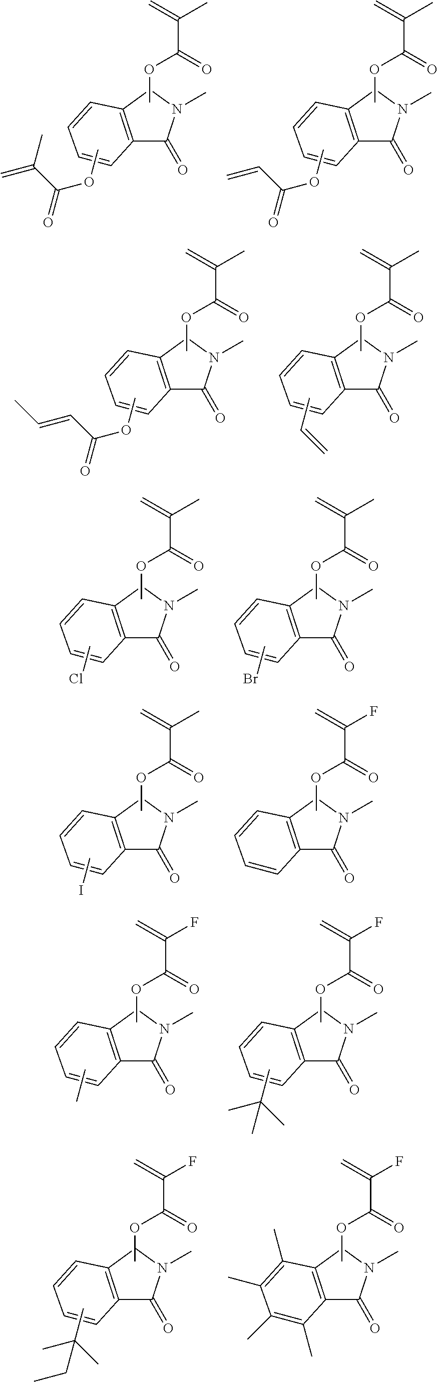

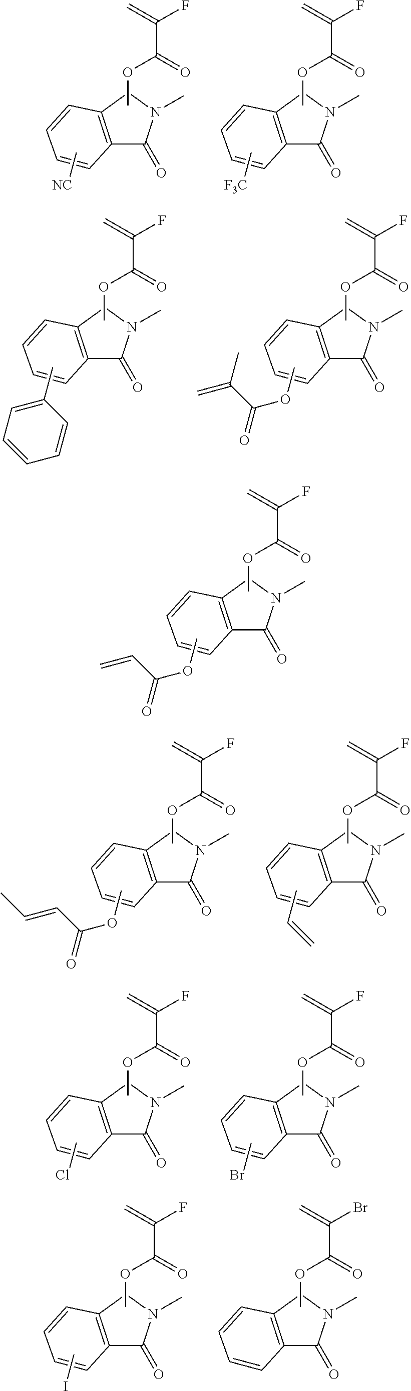

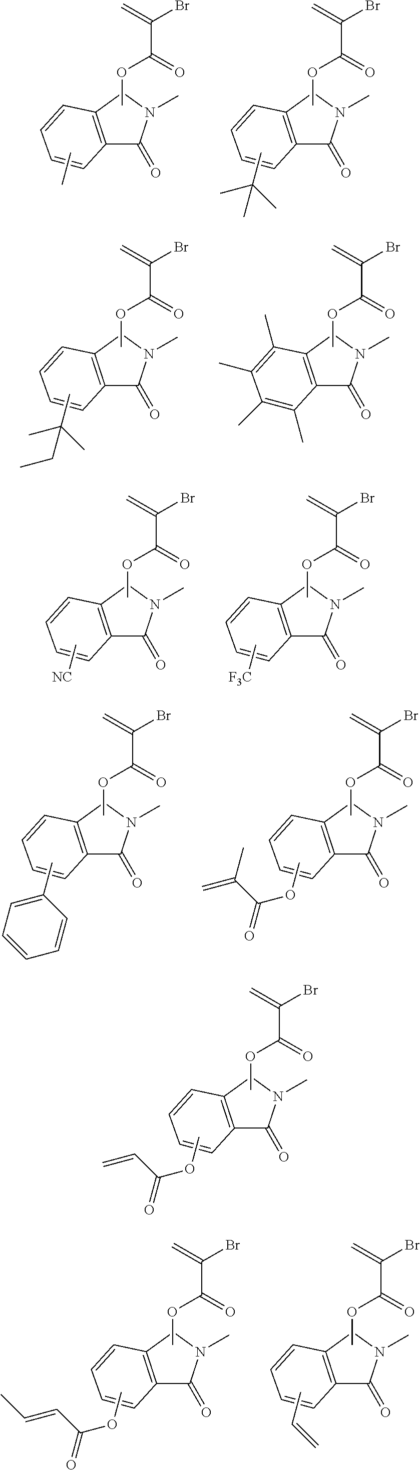

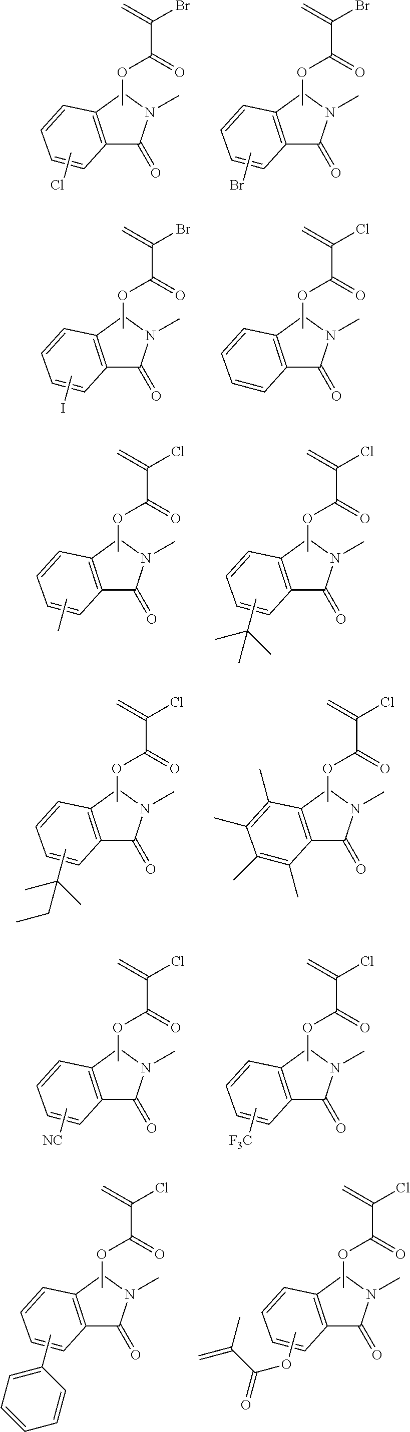

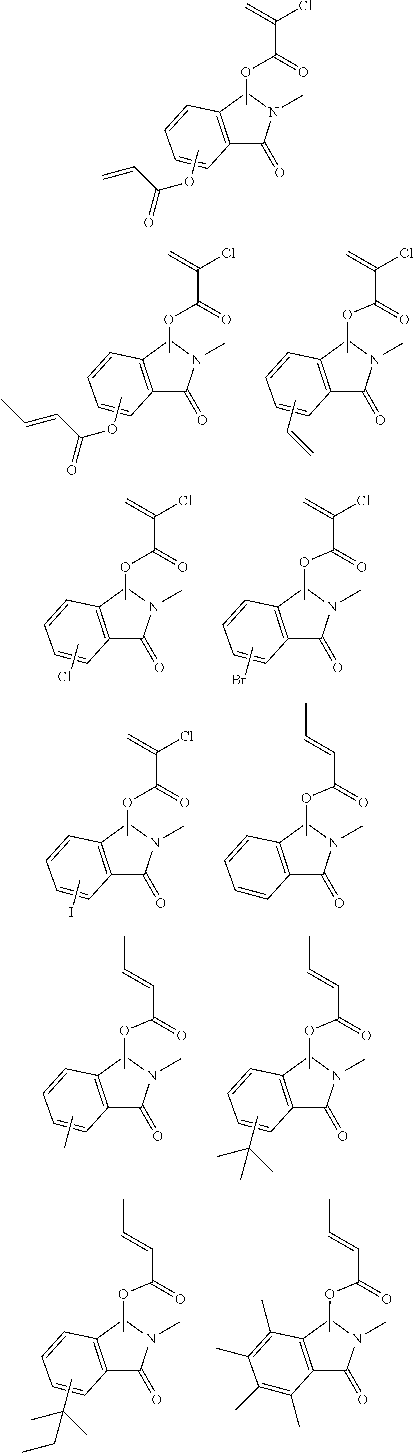

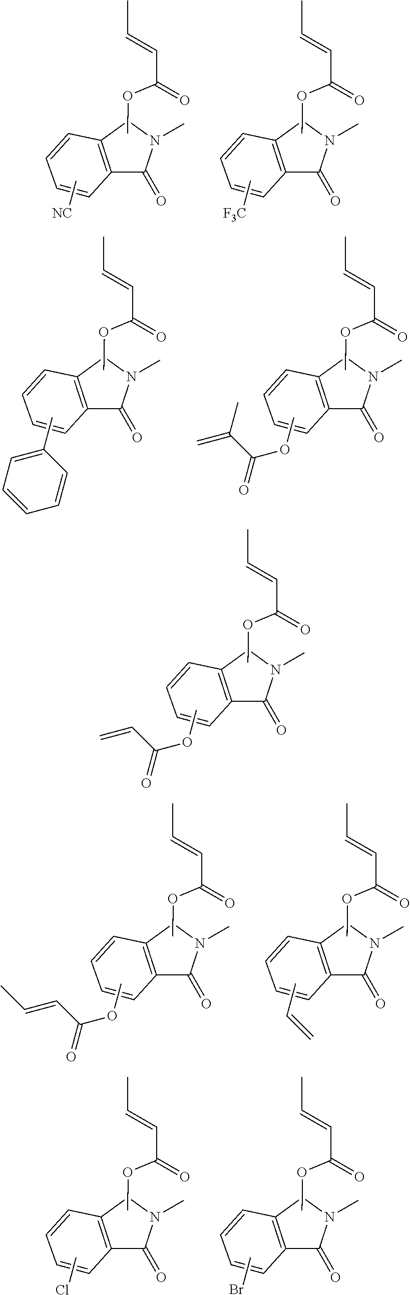

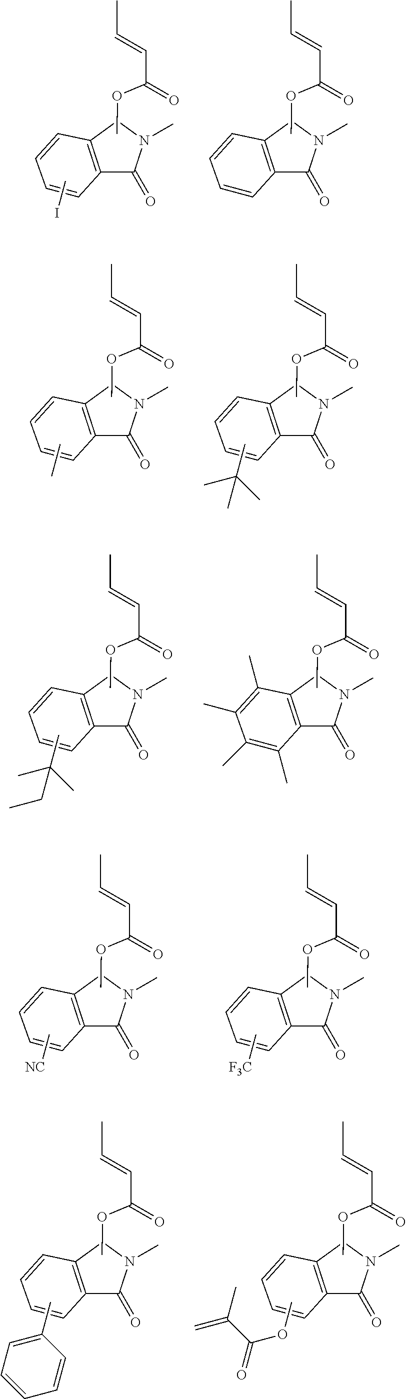

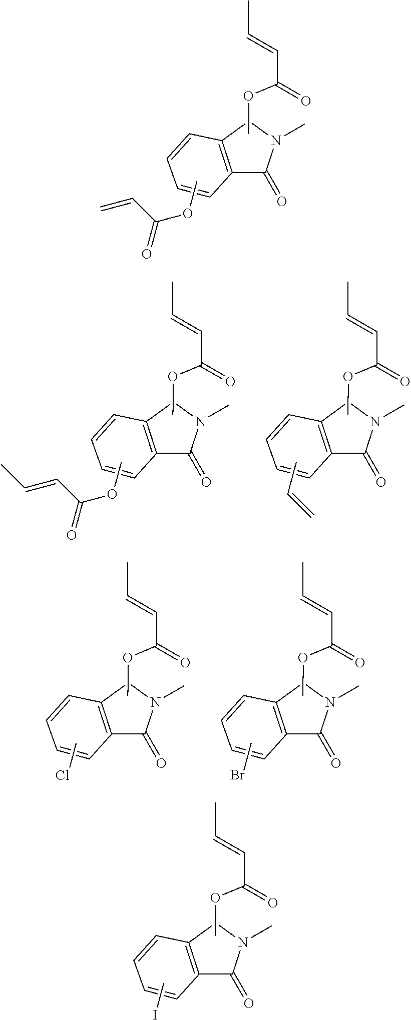

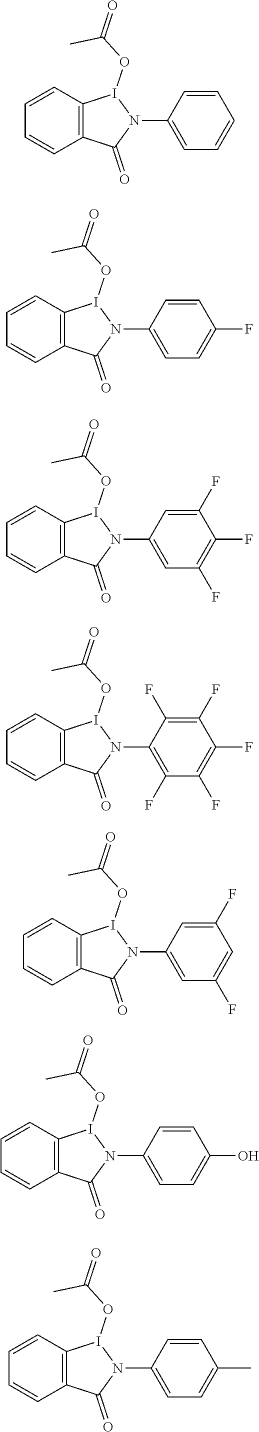

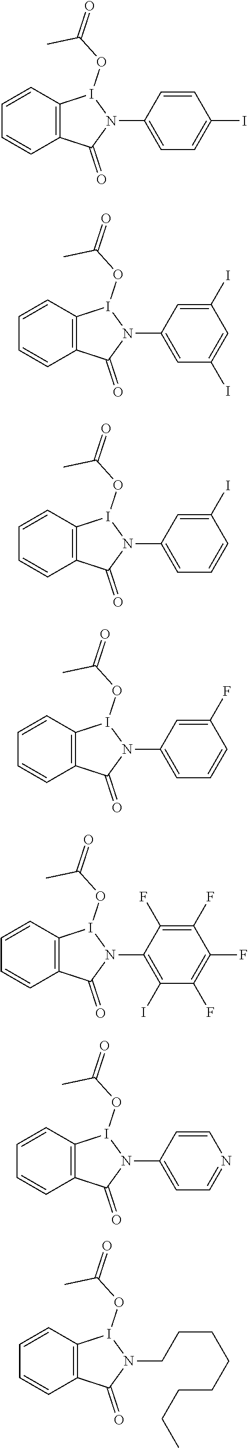

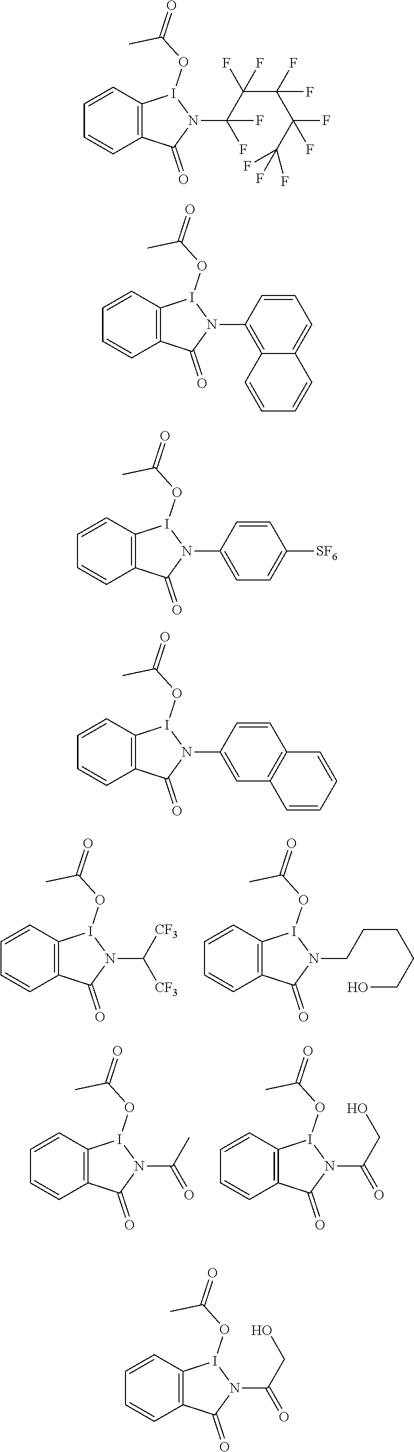

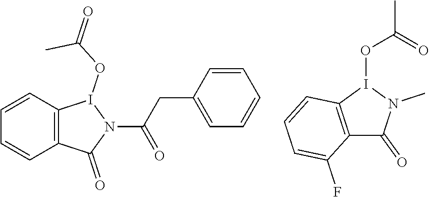

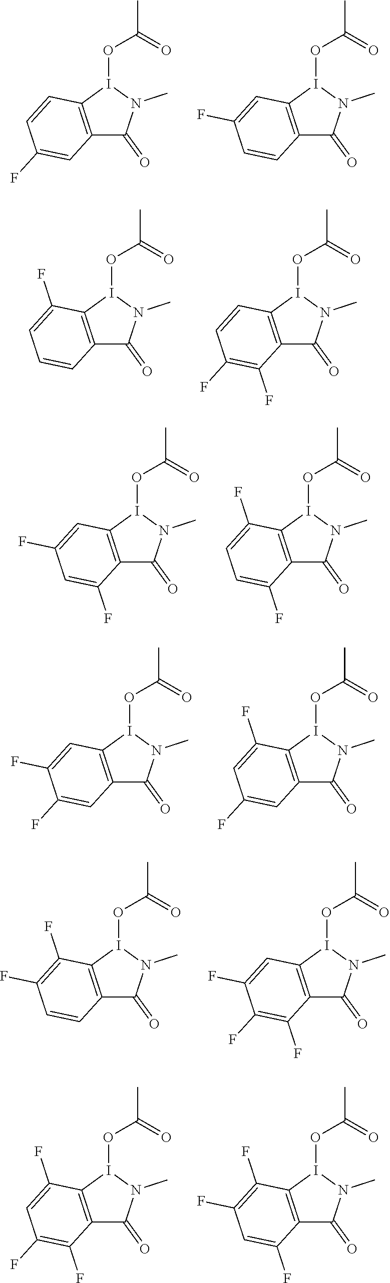

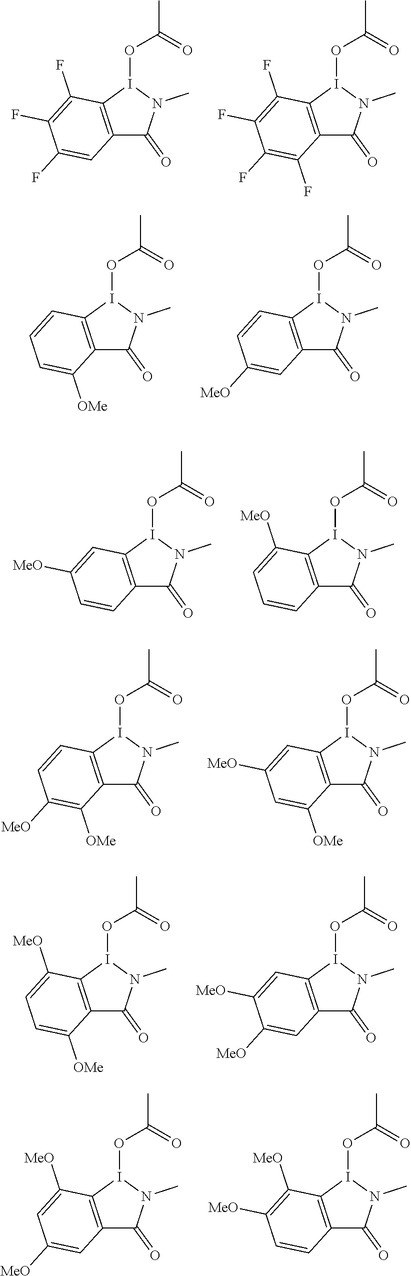

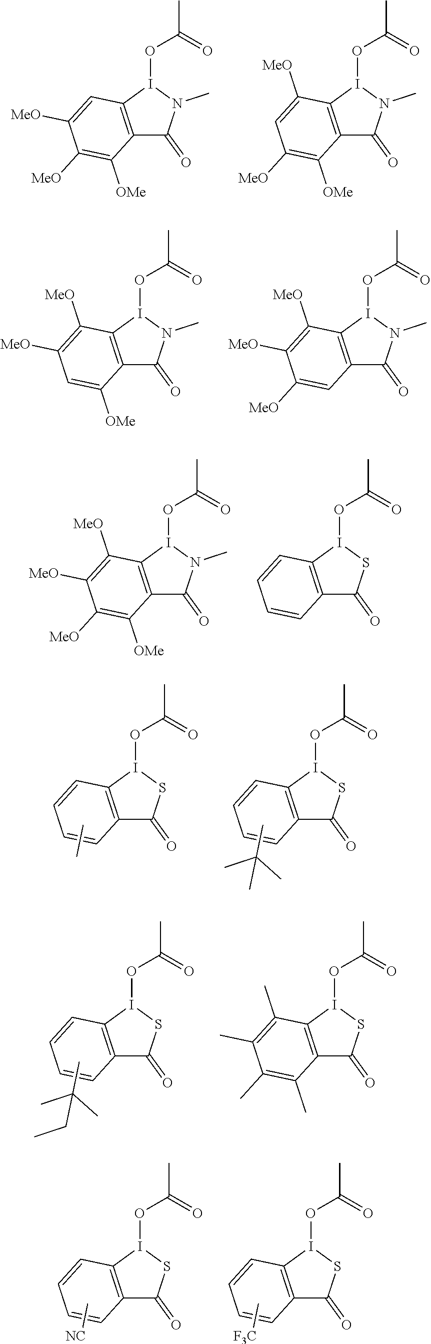

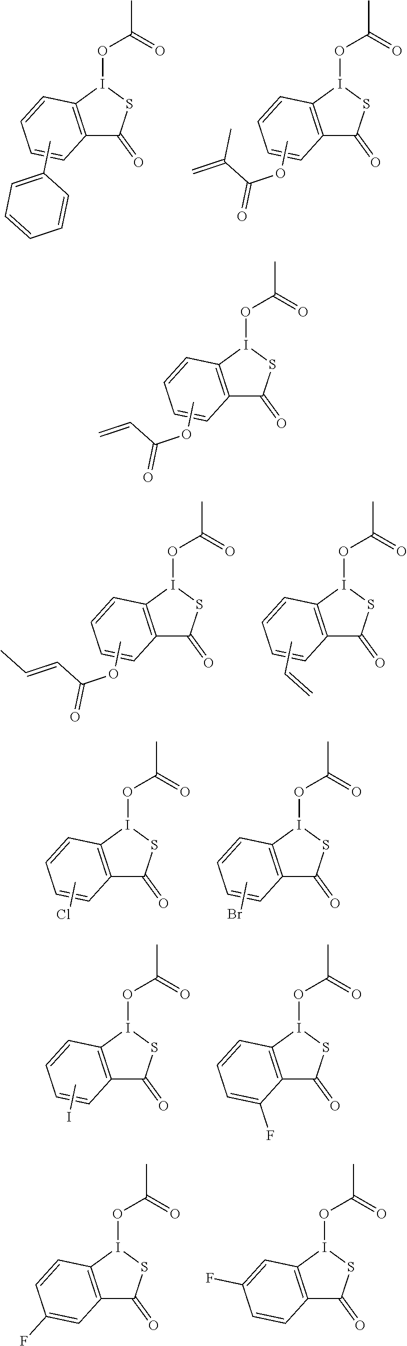

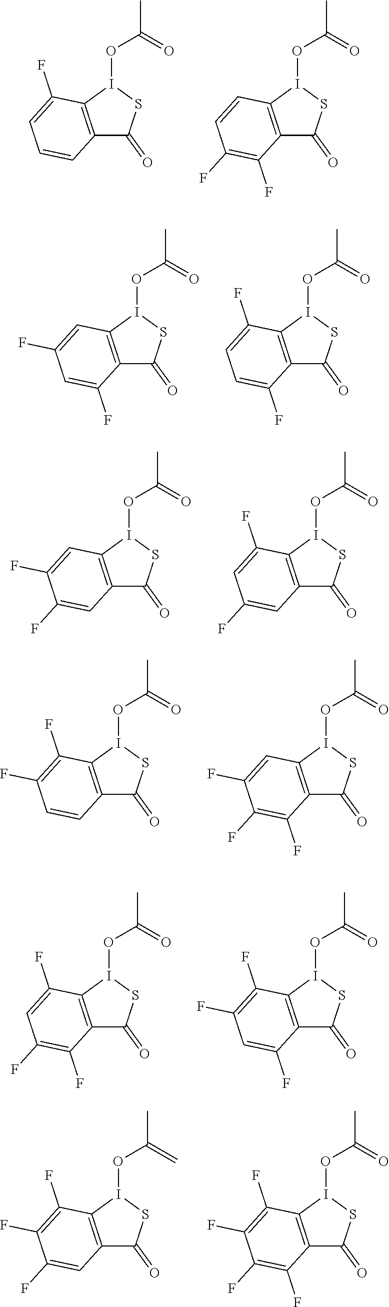

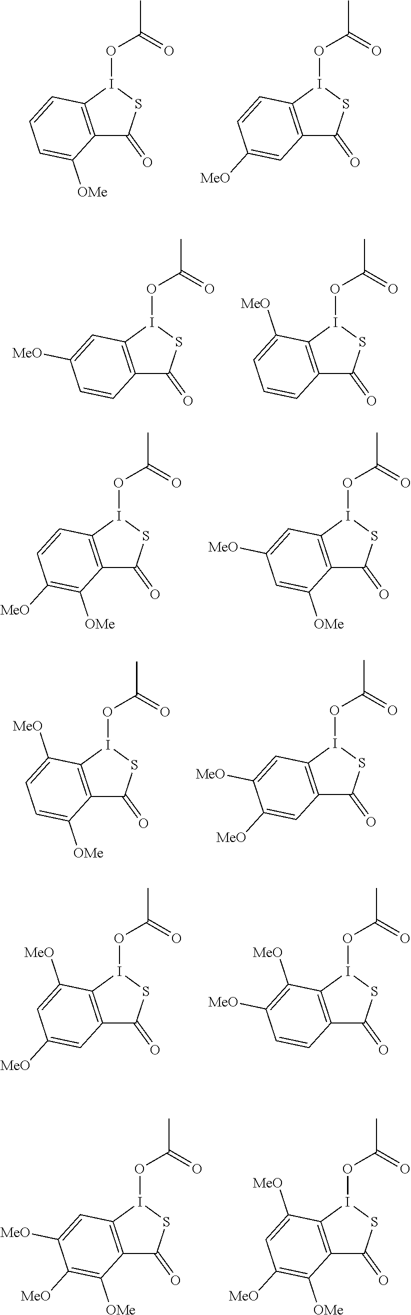

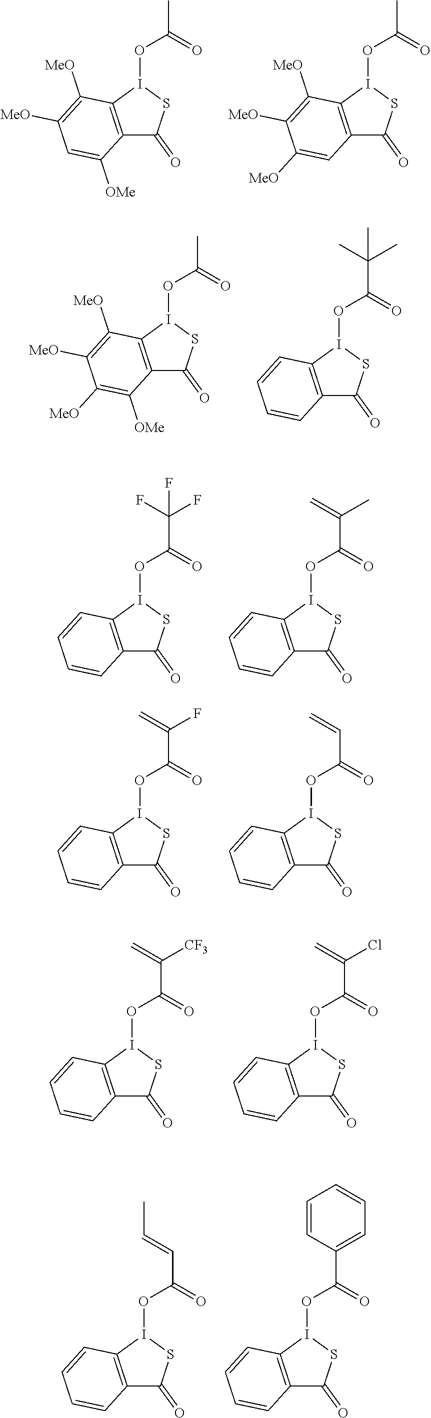

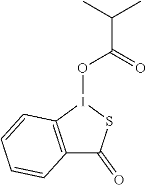

Specific examples of the hypervalent iodine compound represented by the general formula (10) include the following, but are not limited thereto.

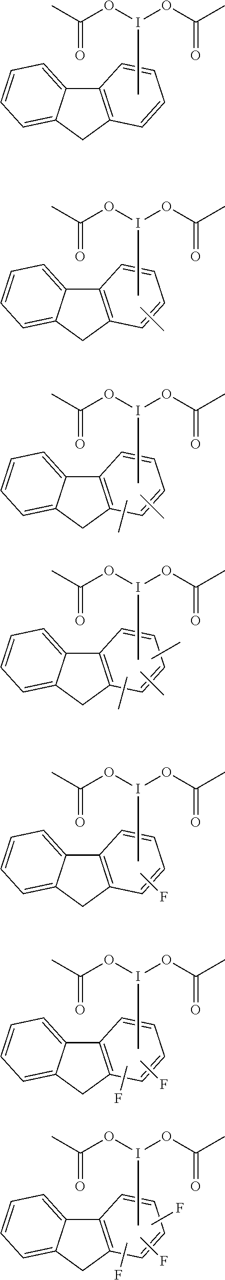

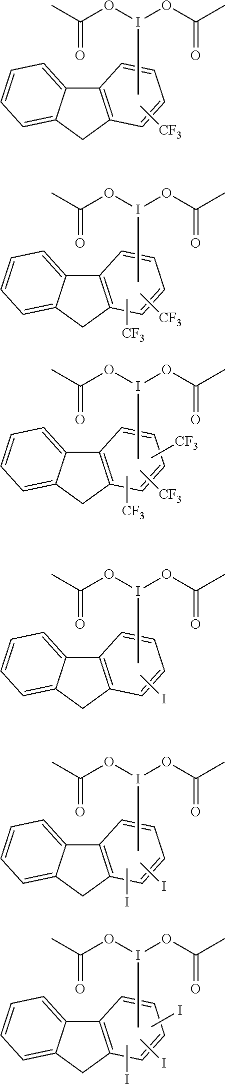

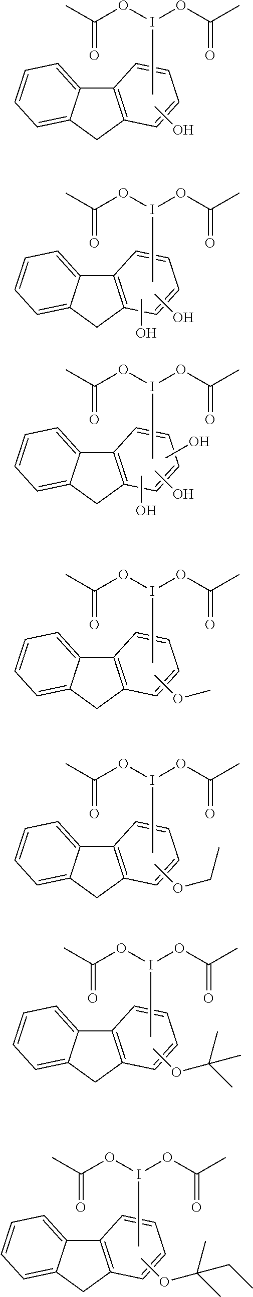

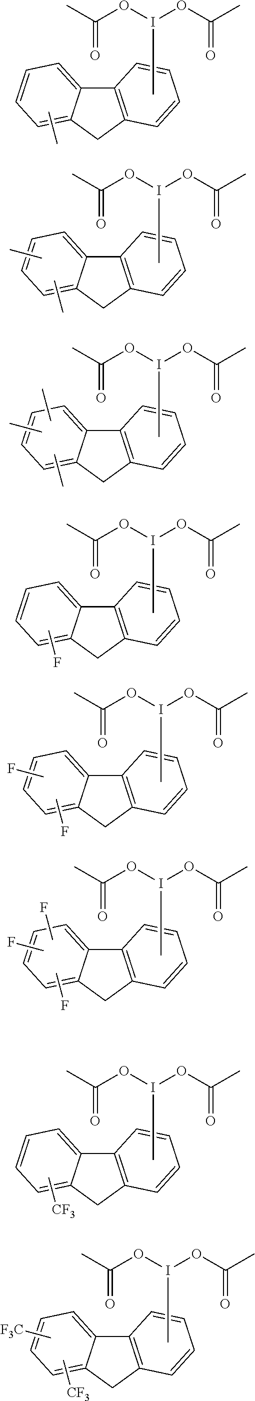

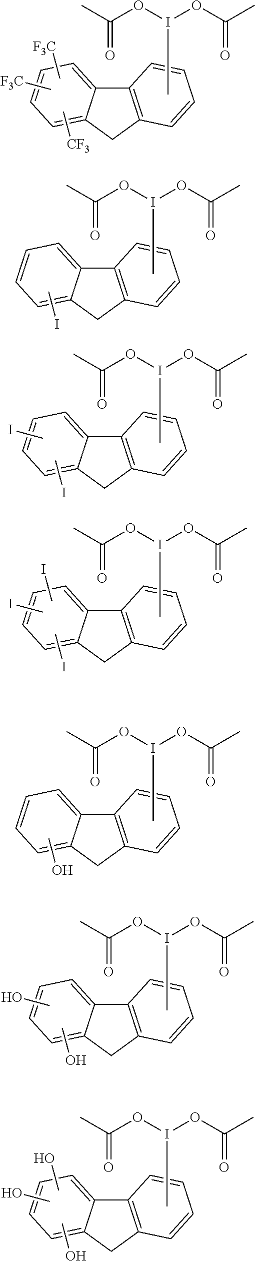

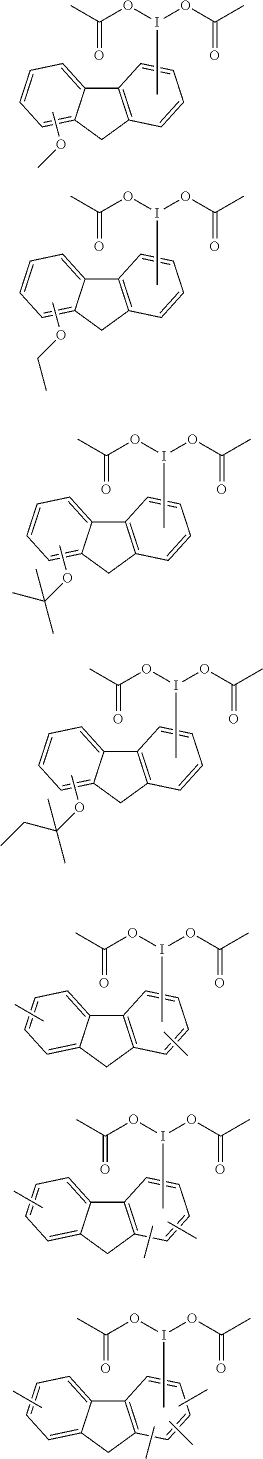

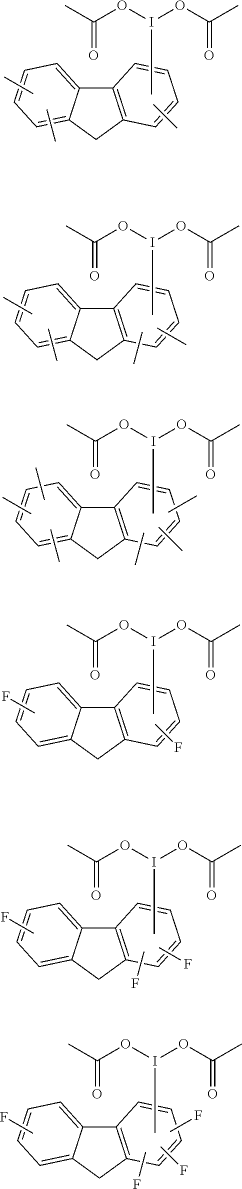

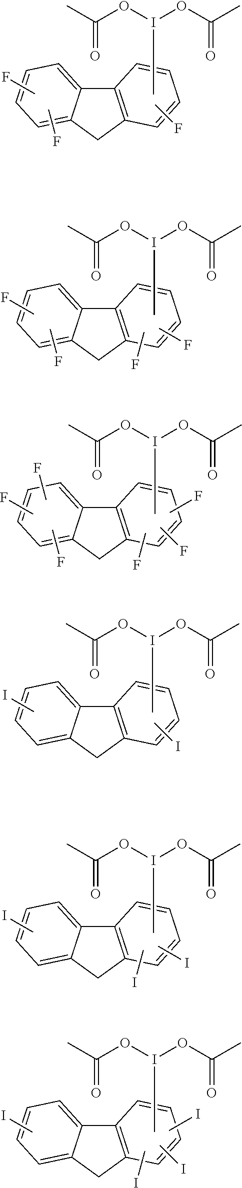

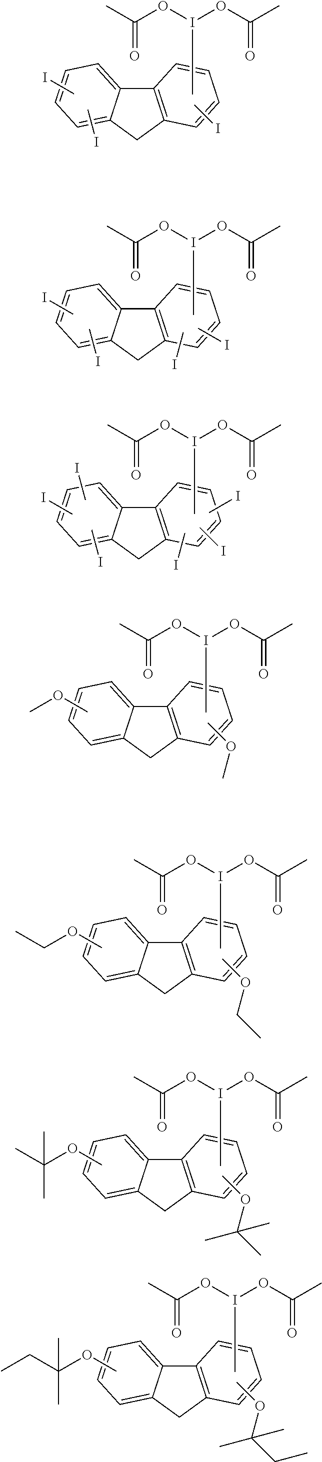

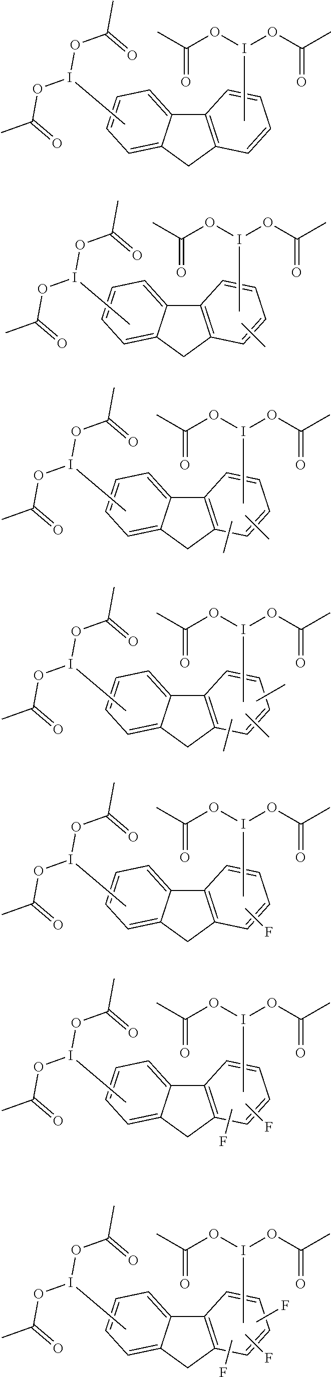

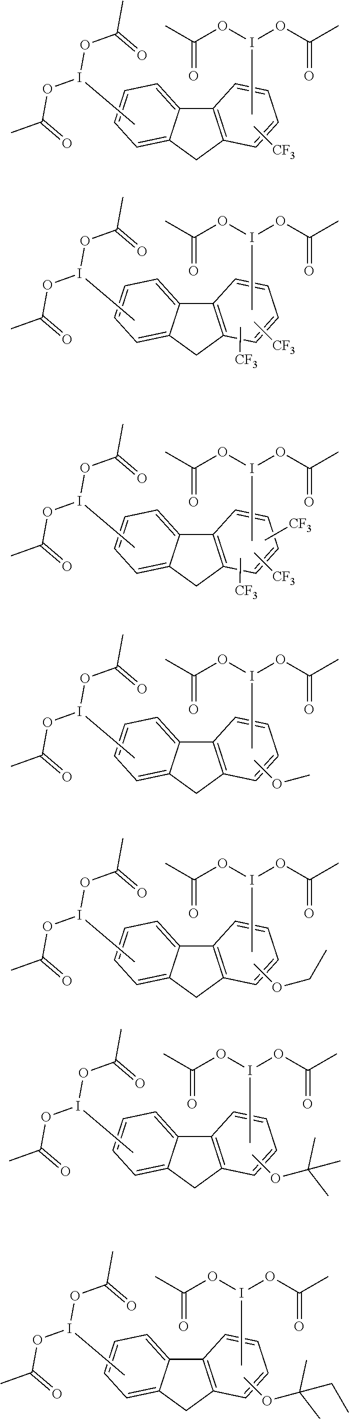

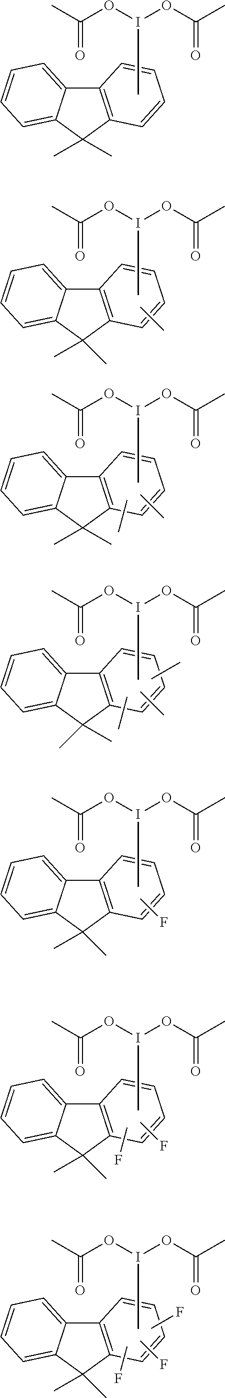

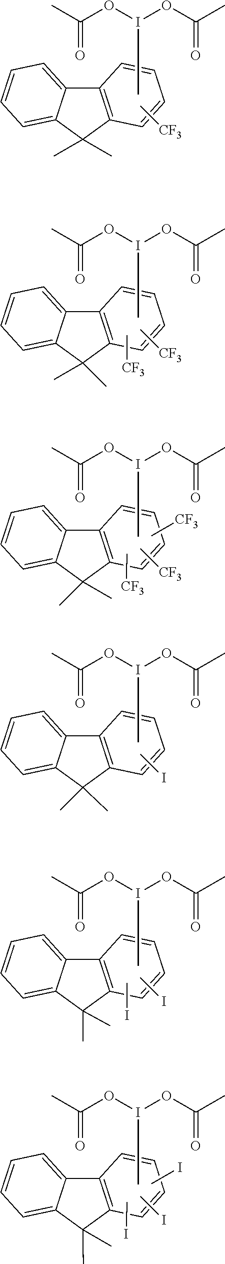

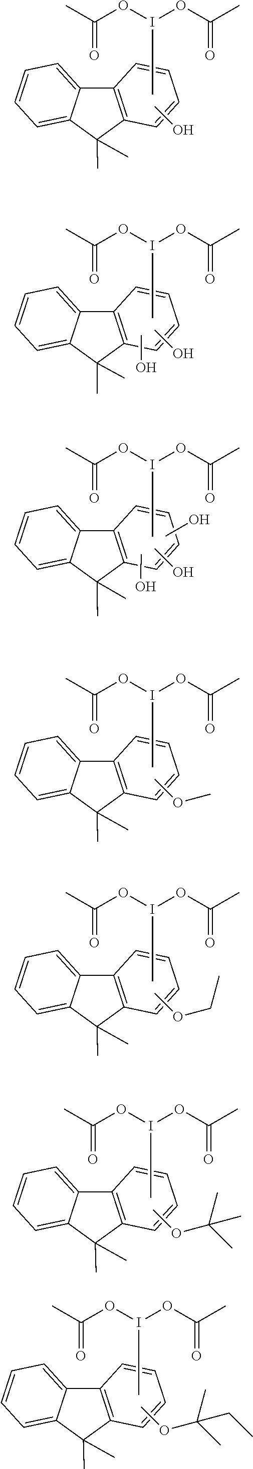

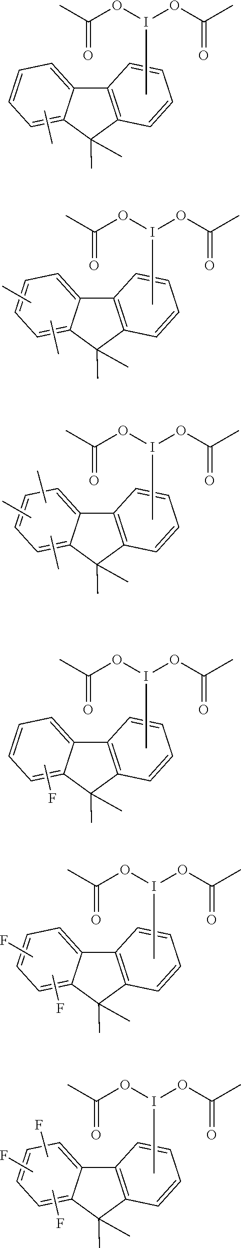

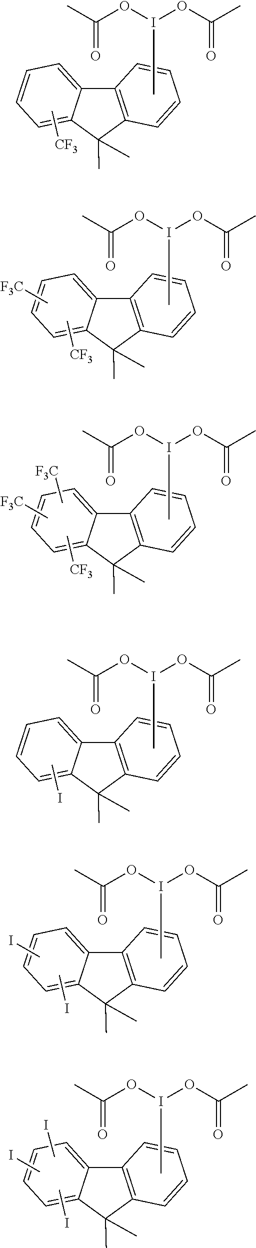

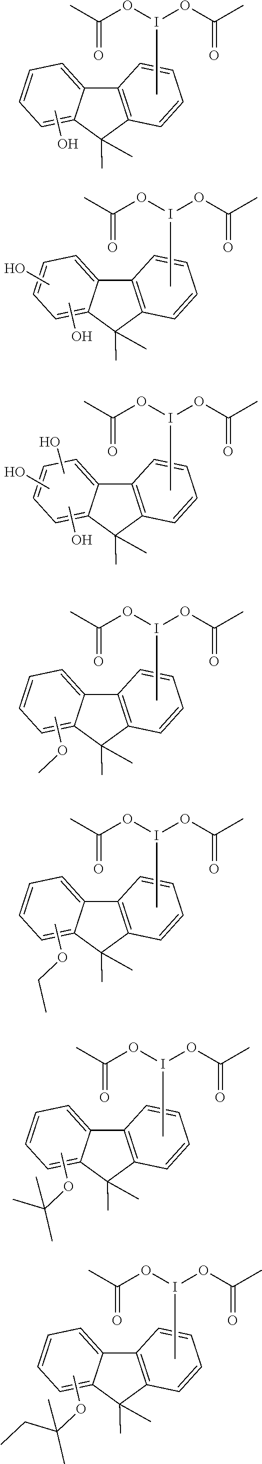

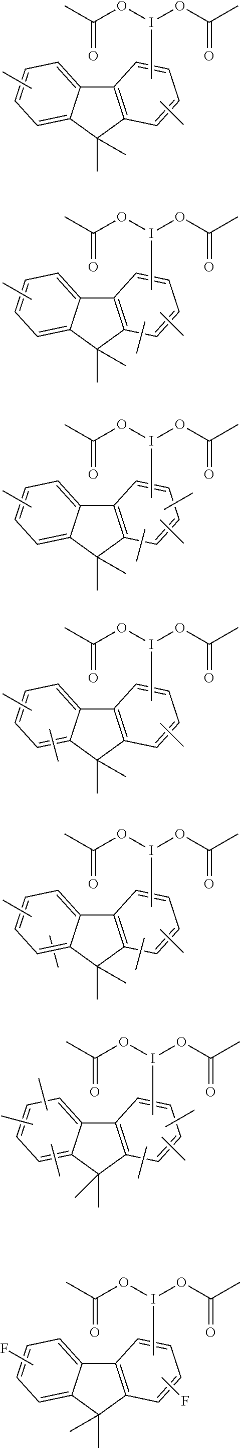

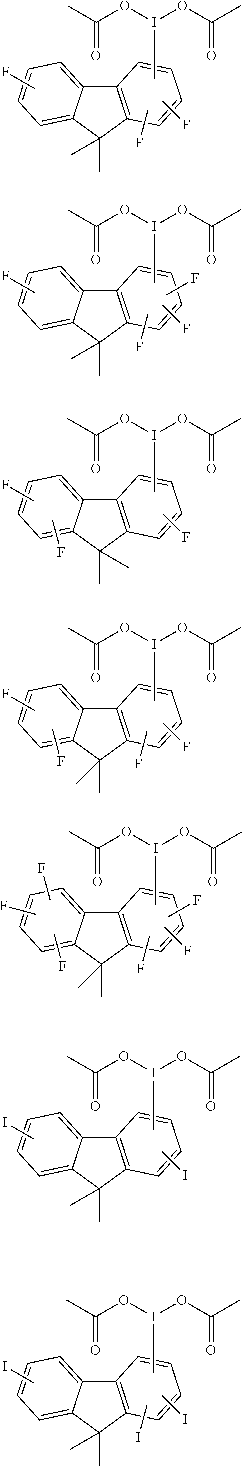

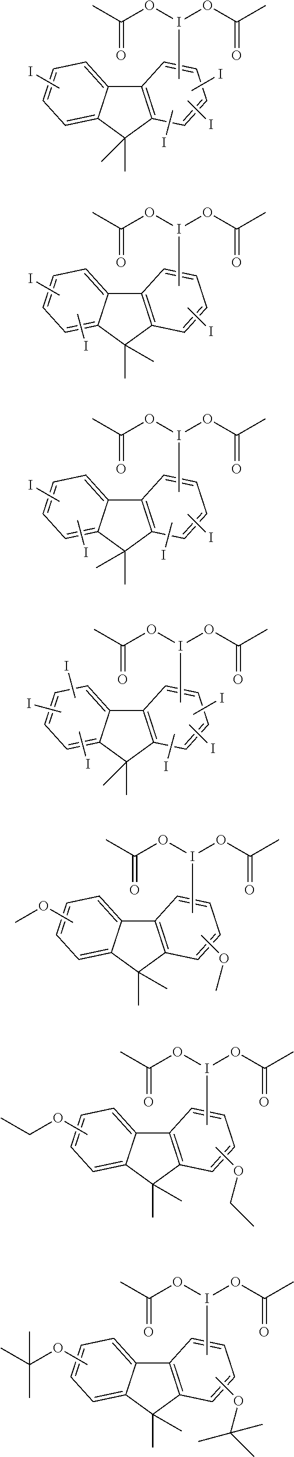

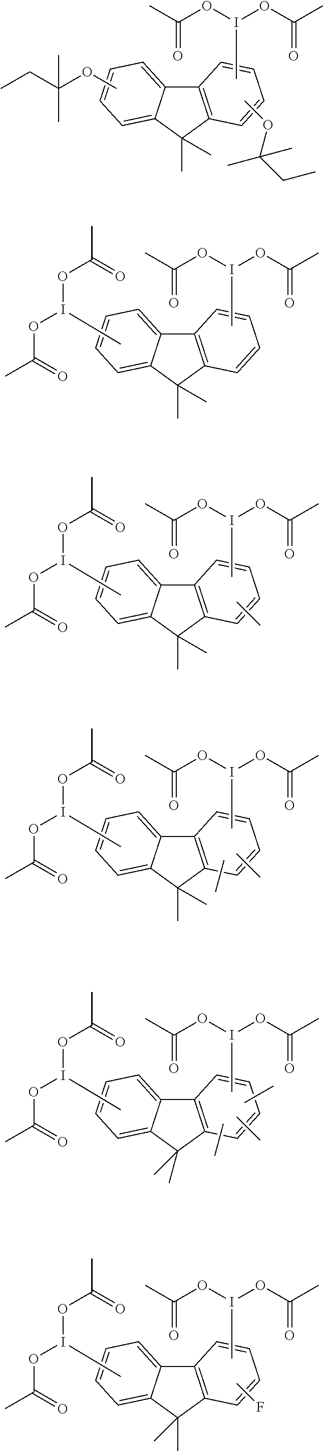

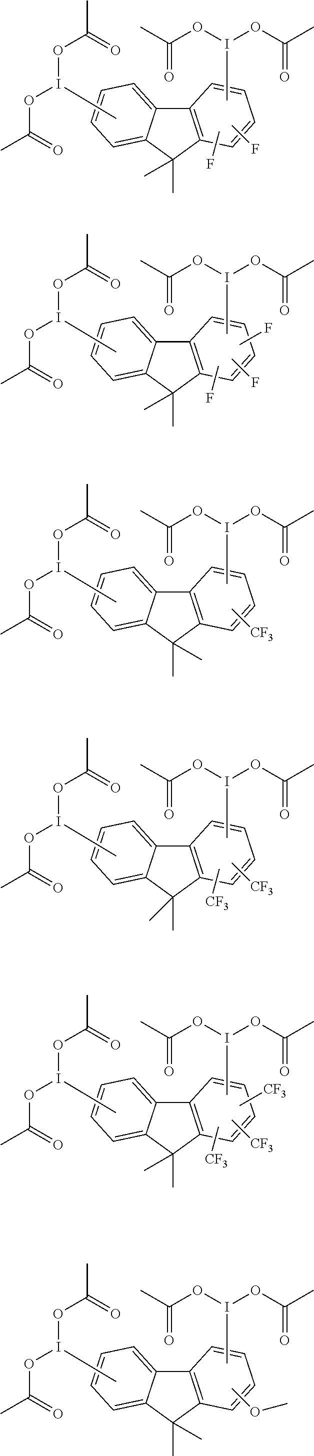

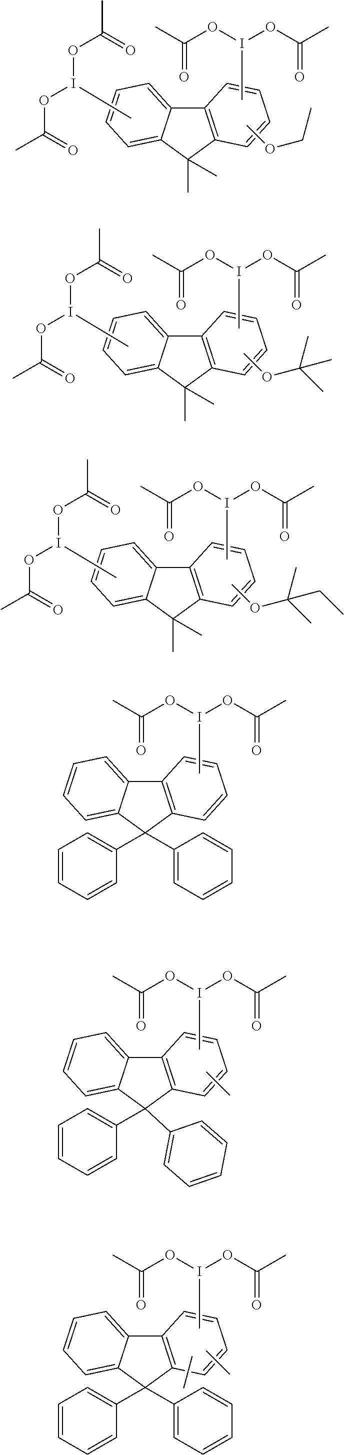

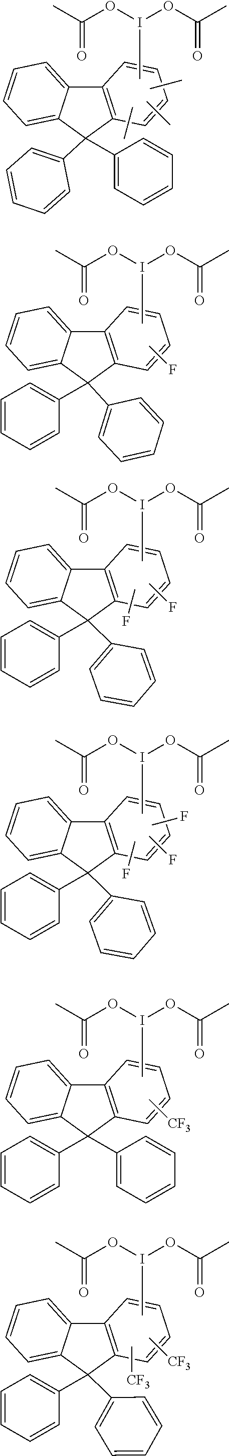

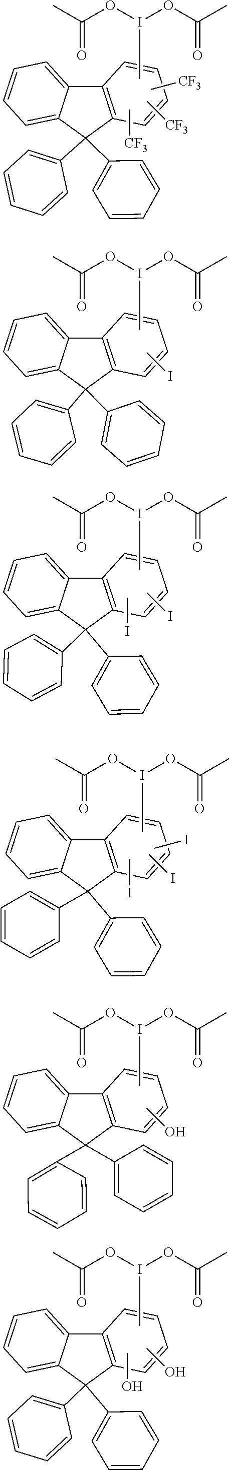

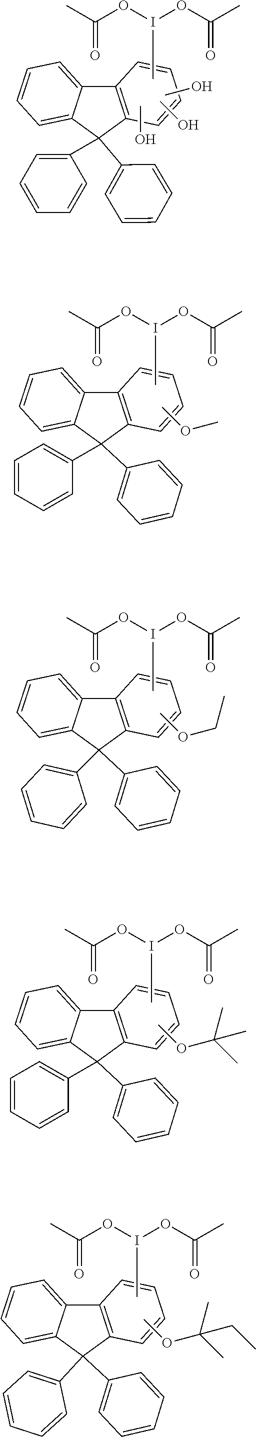

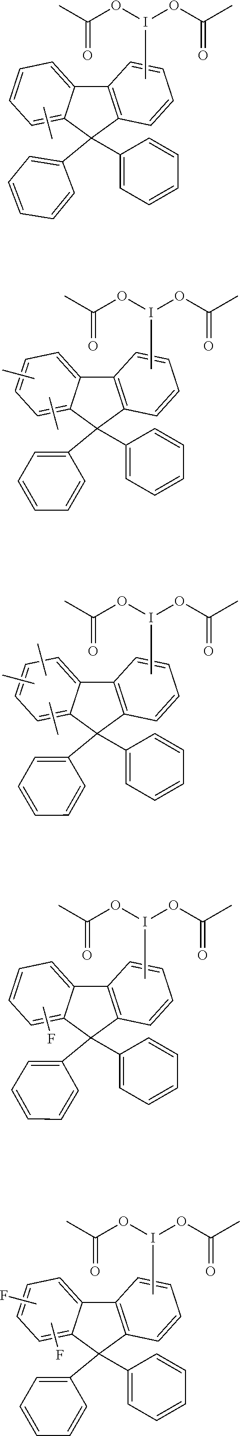

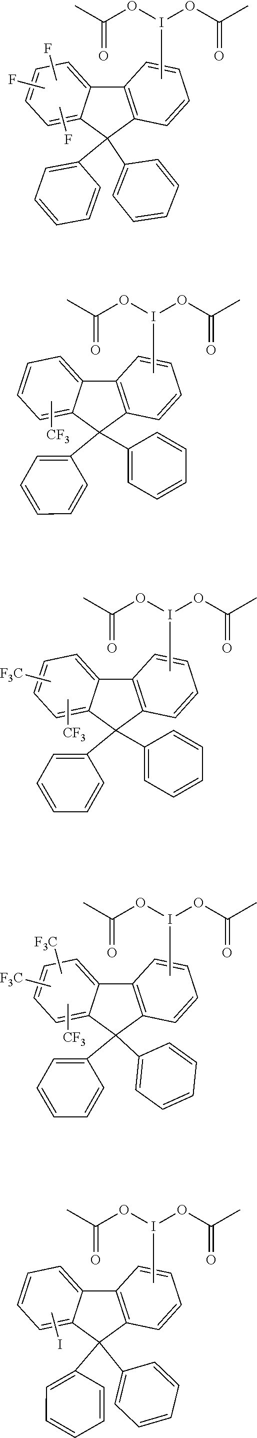

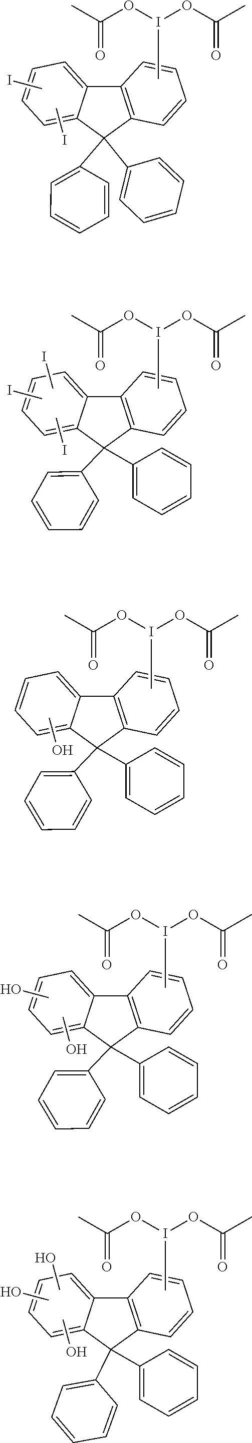

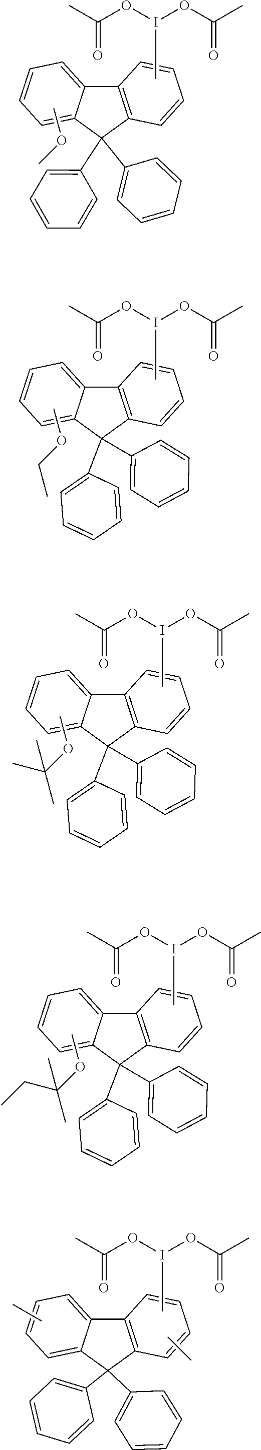

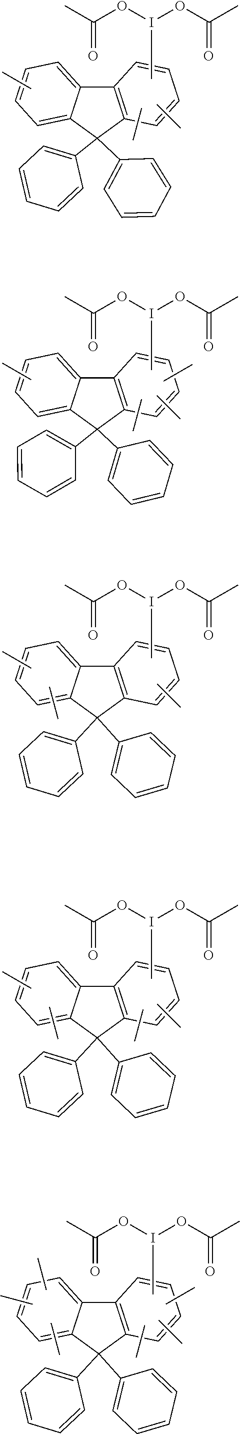

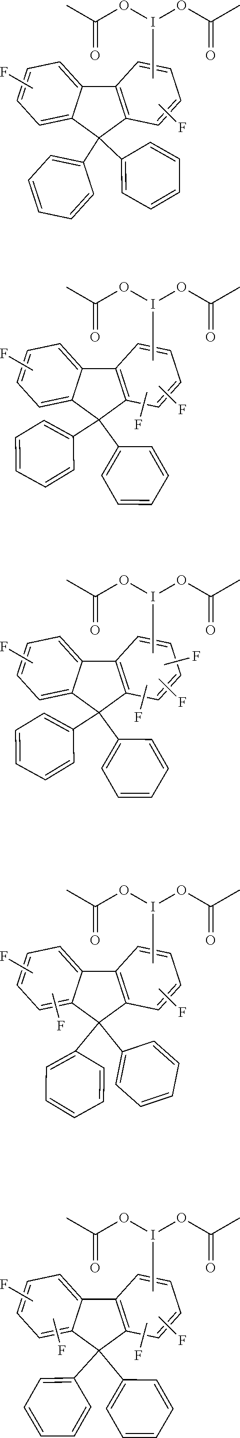

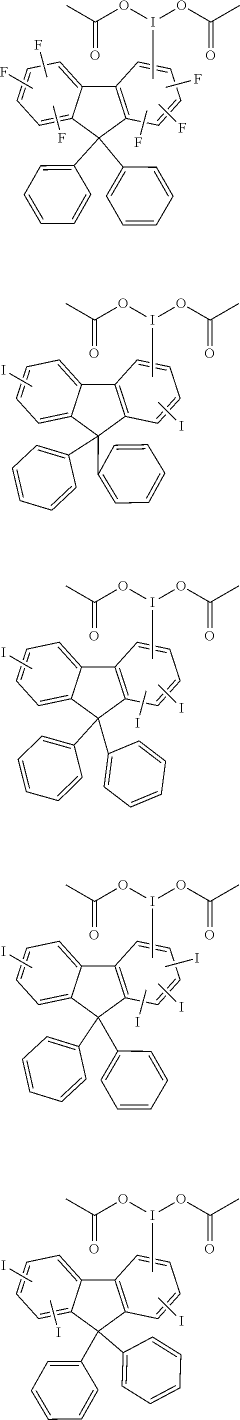

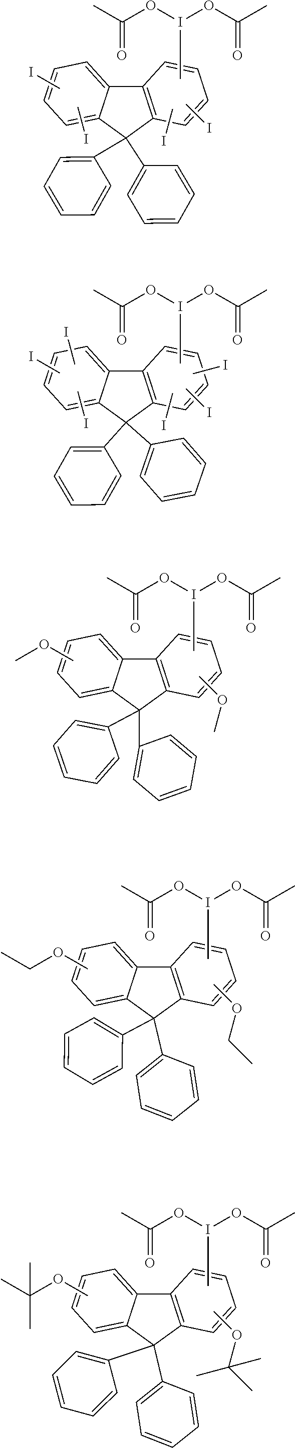

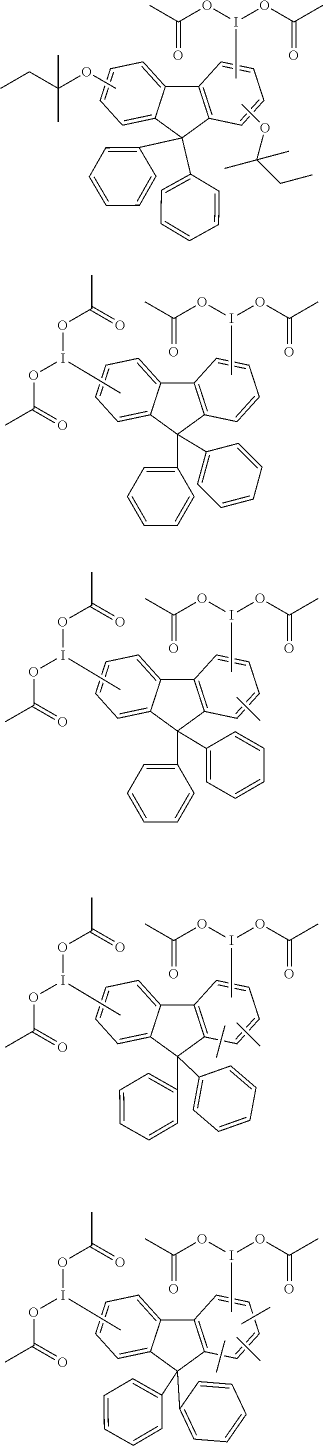

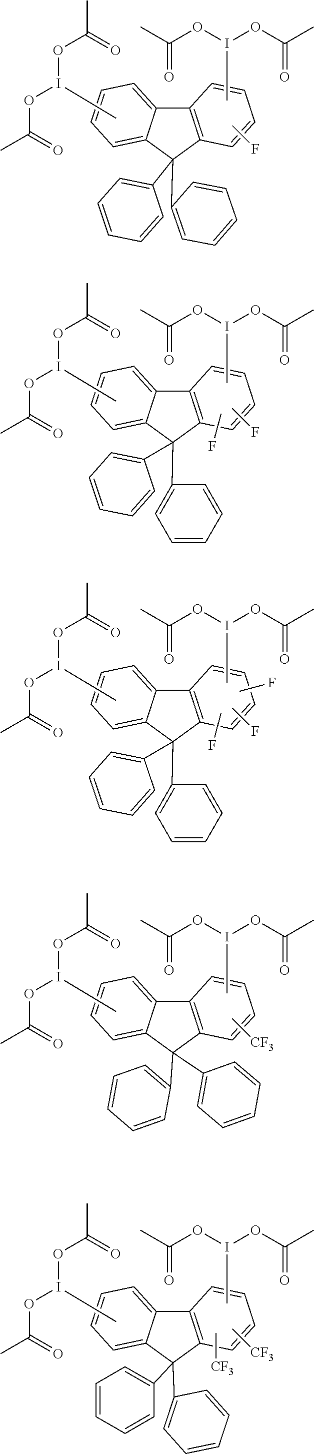

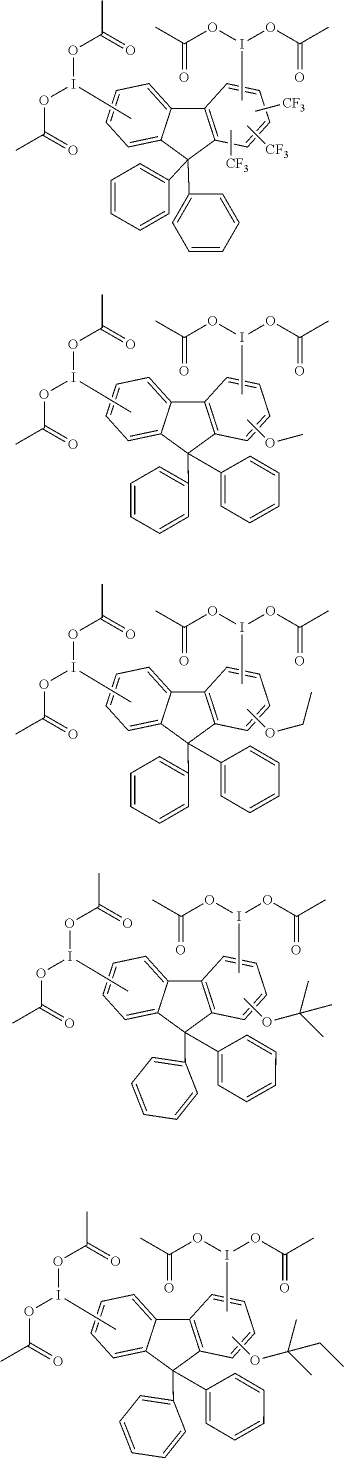

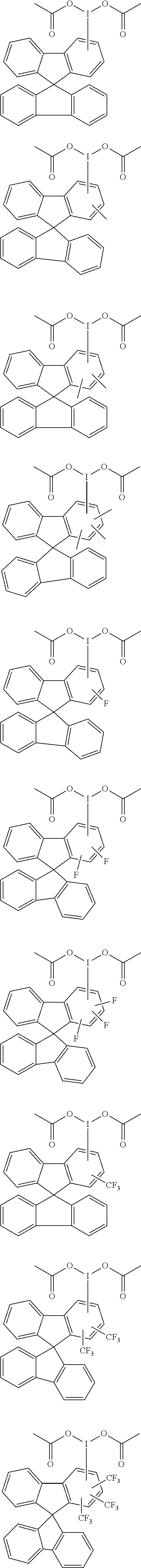

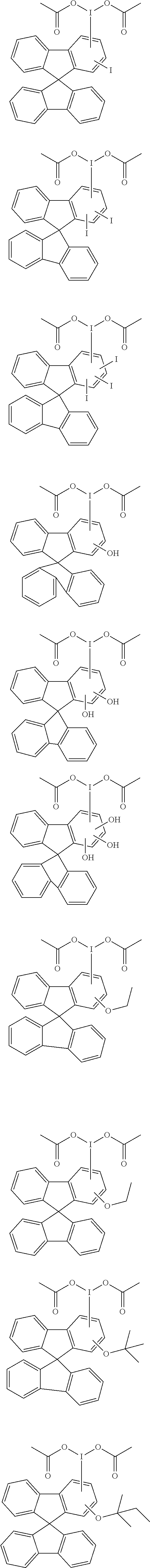

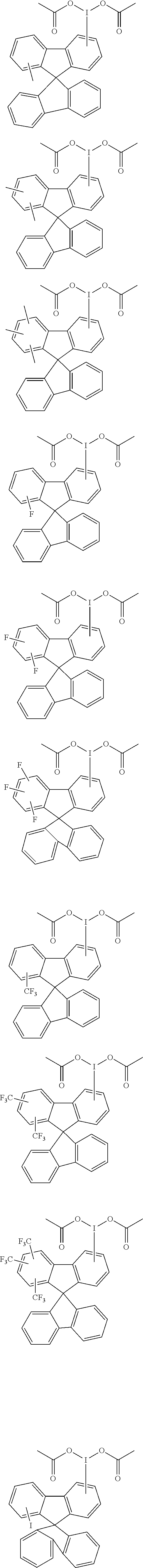

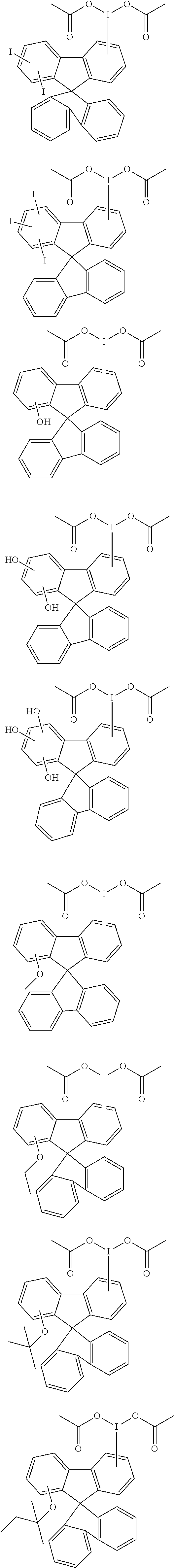

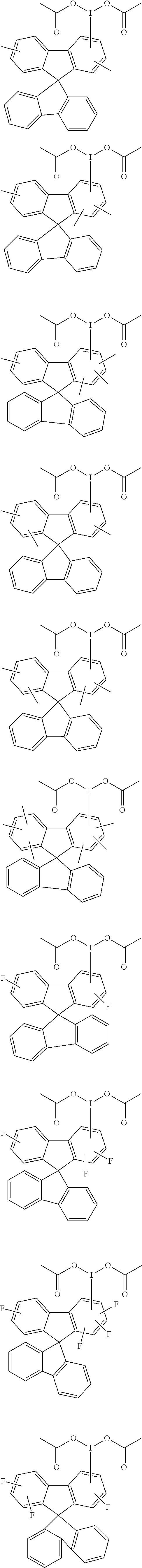

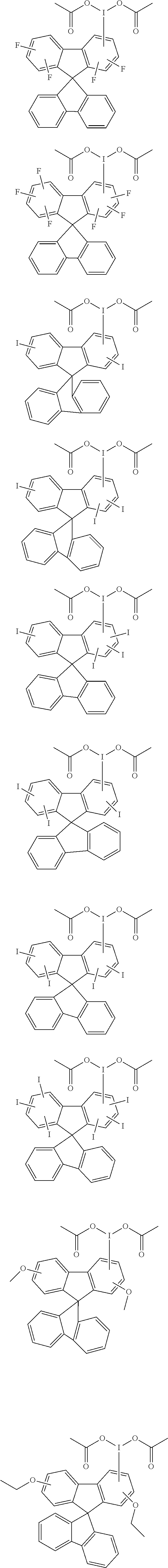

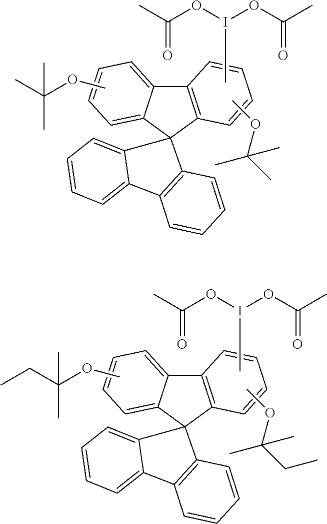

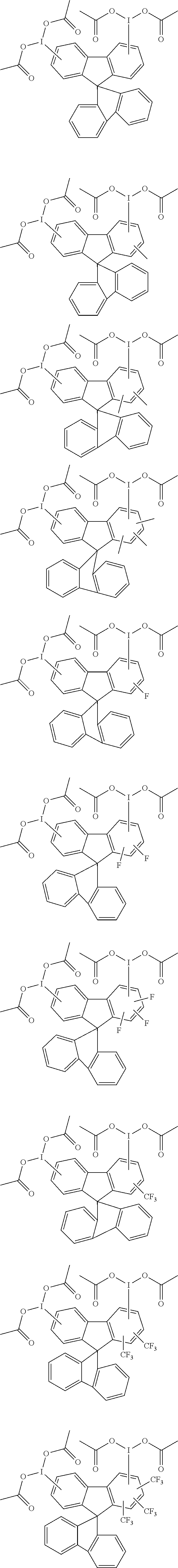

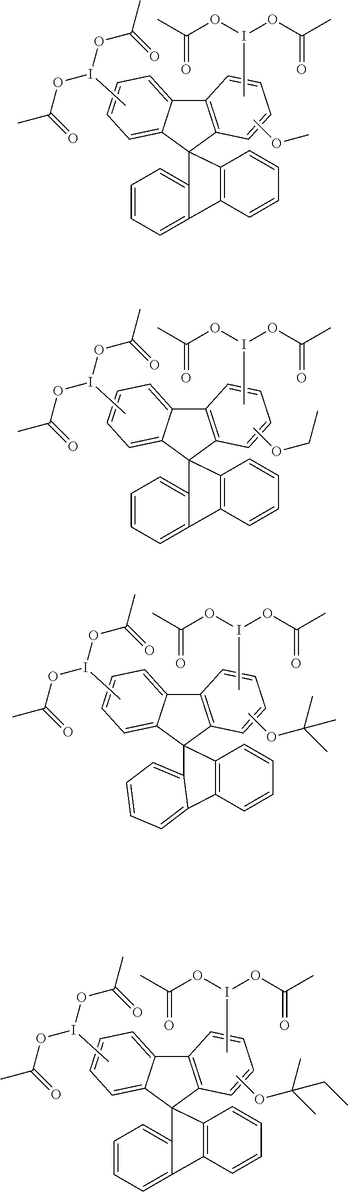

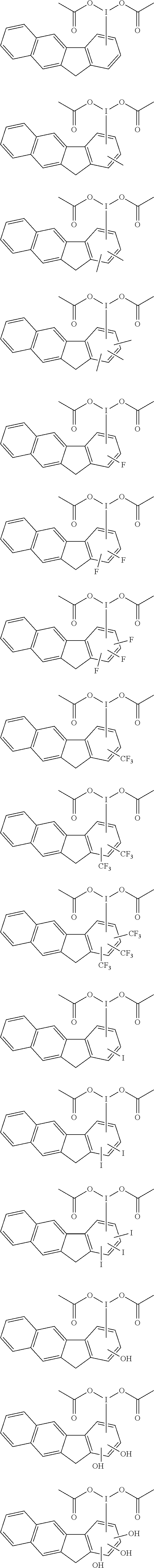

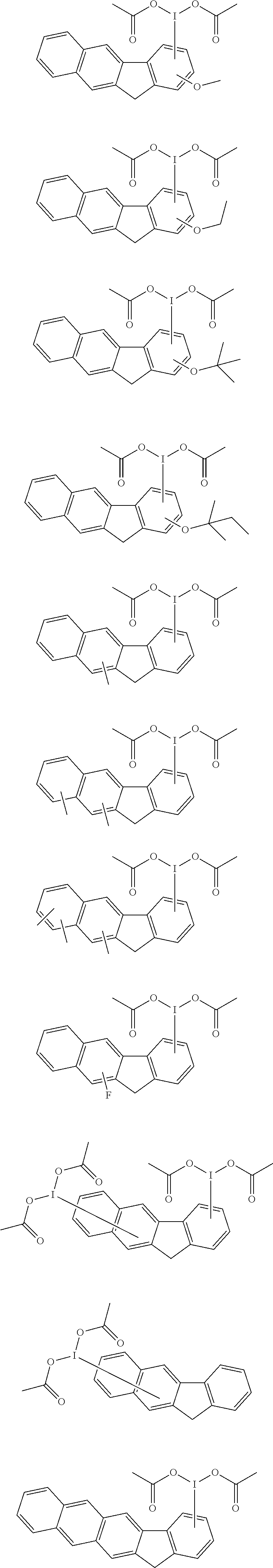

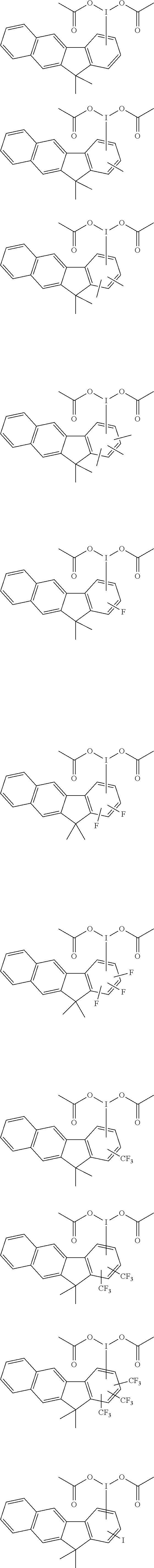

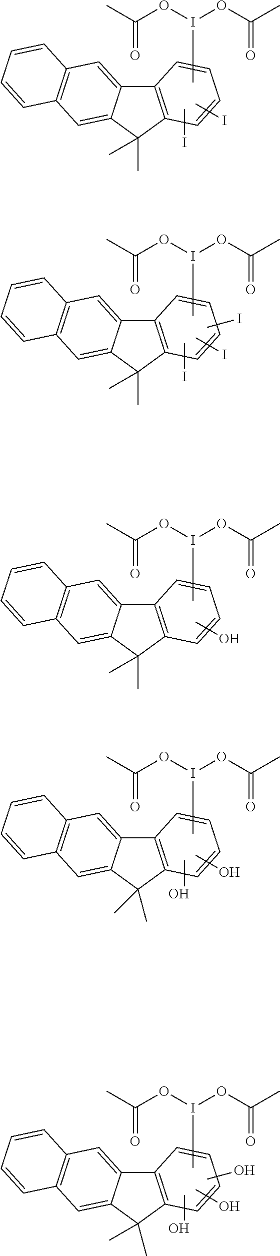

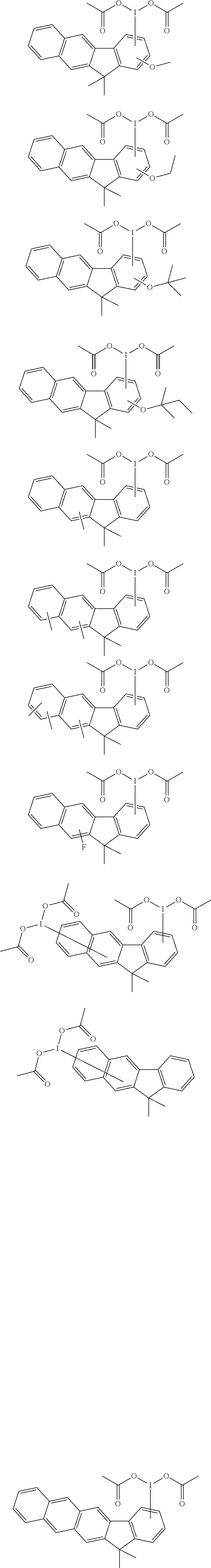

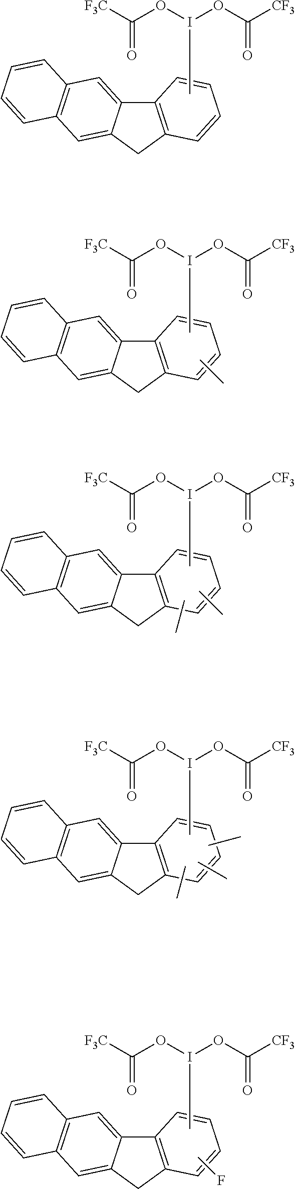

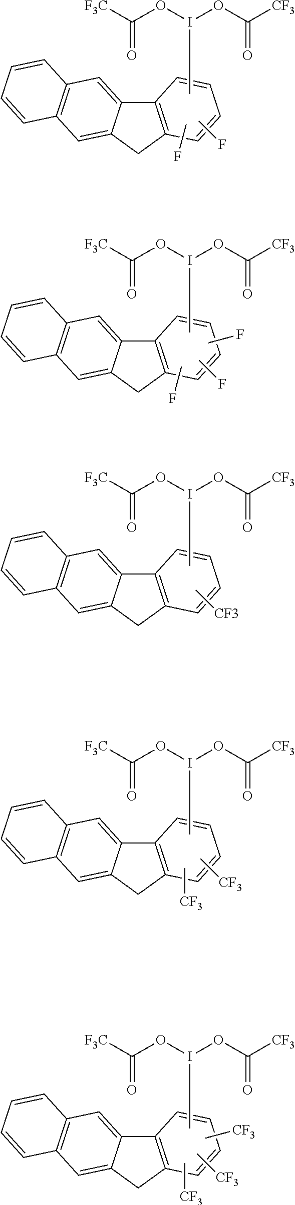

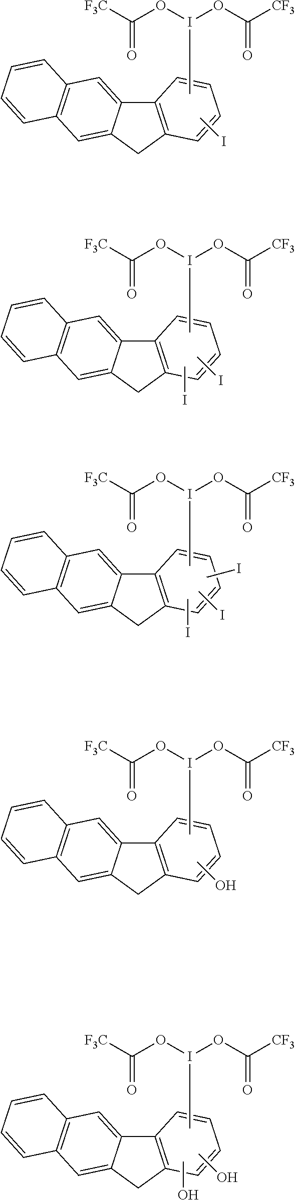

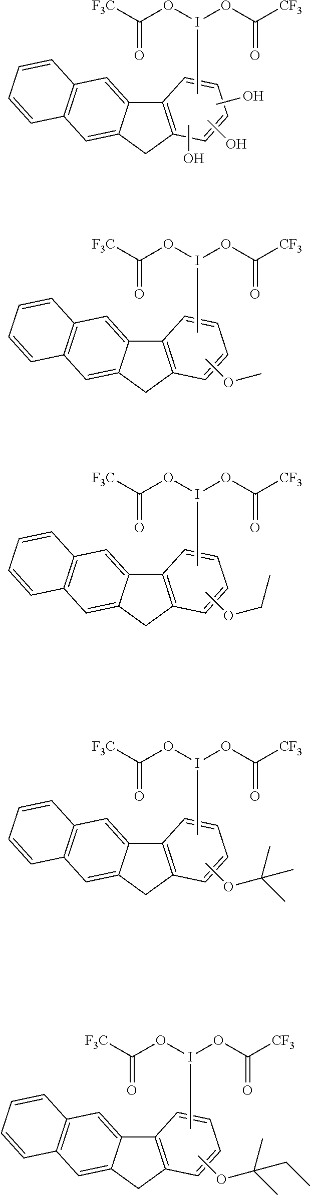

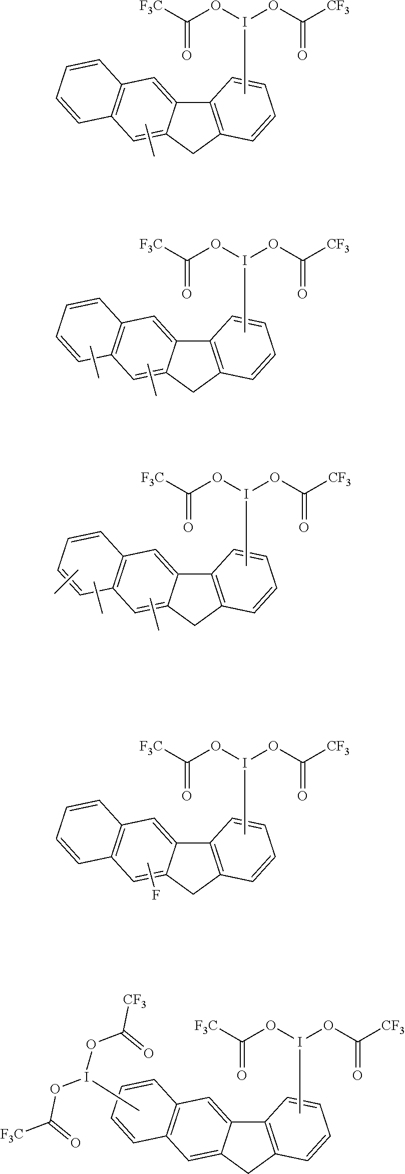

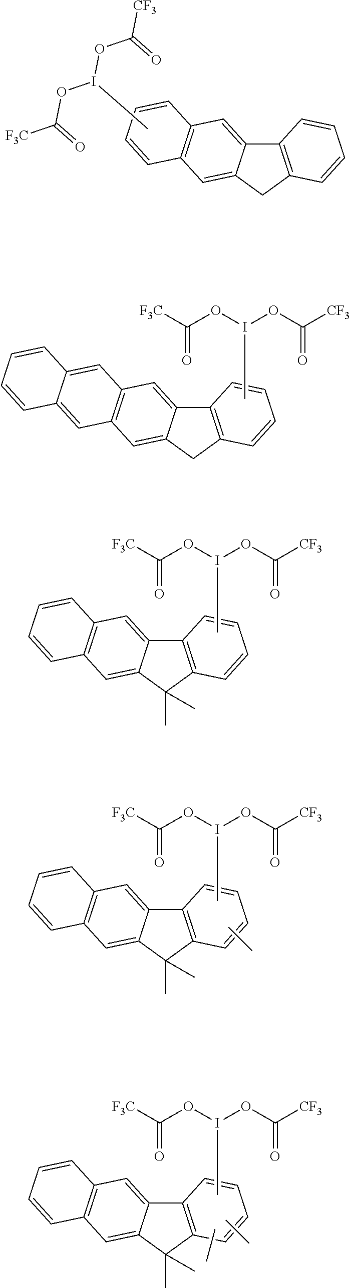

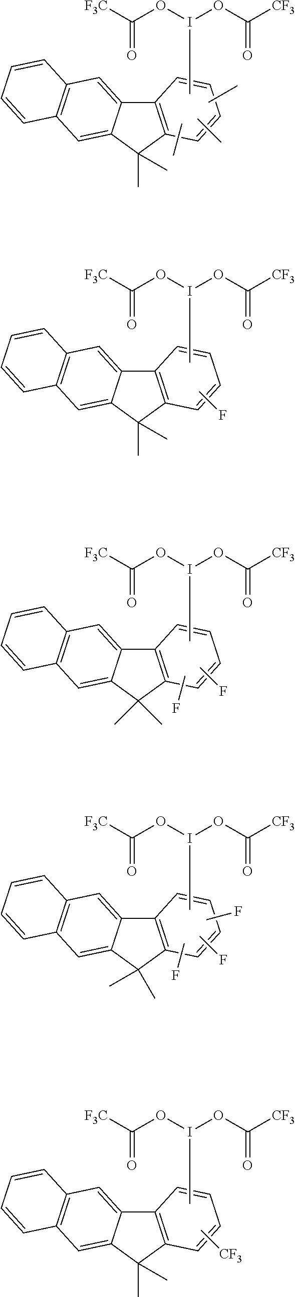

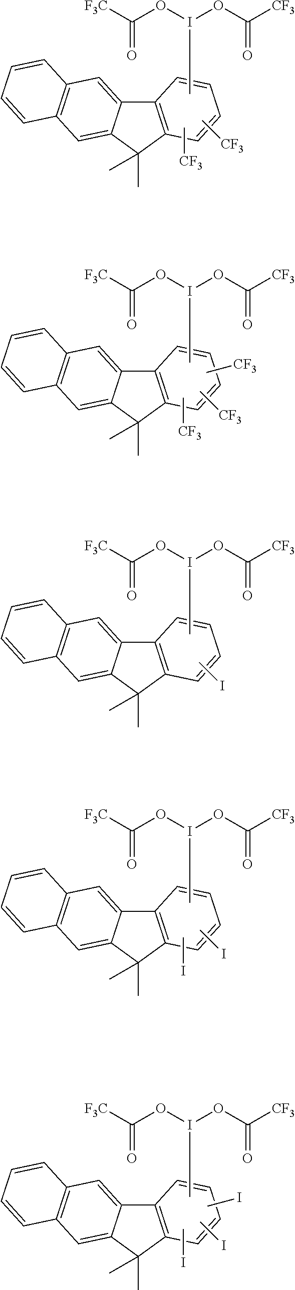

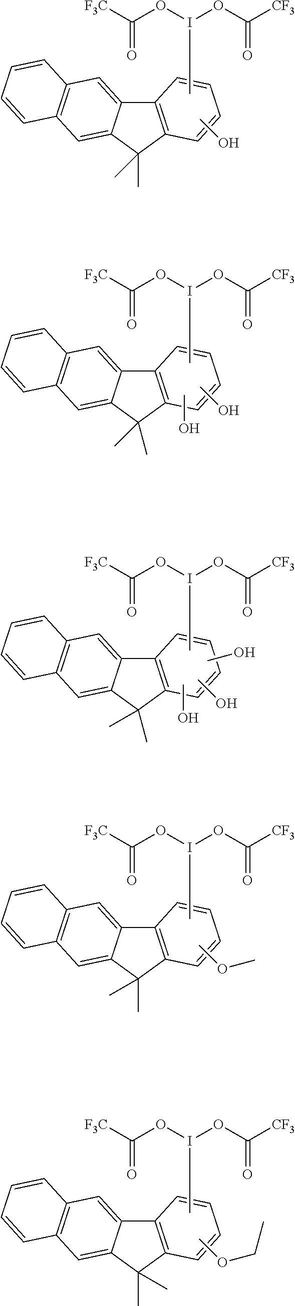

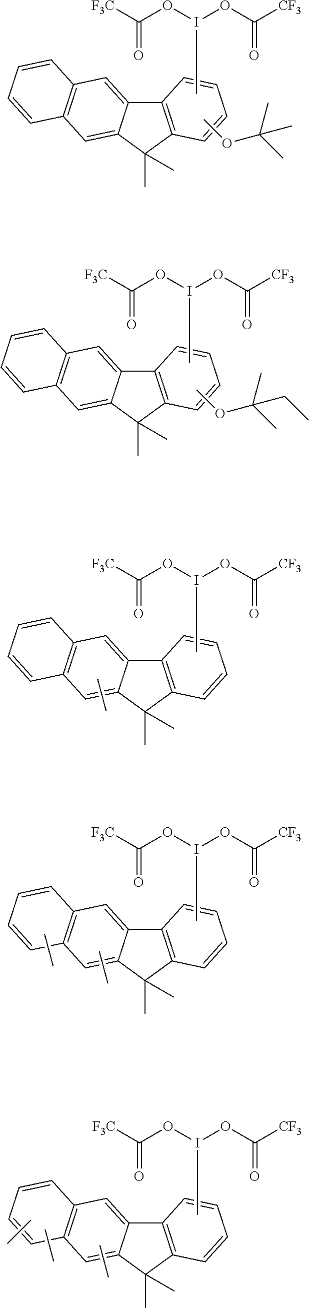

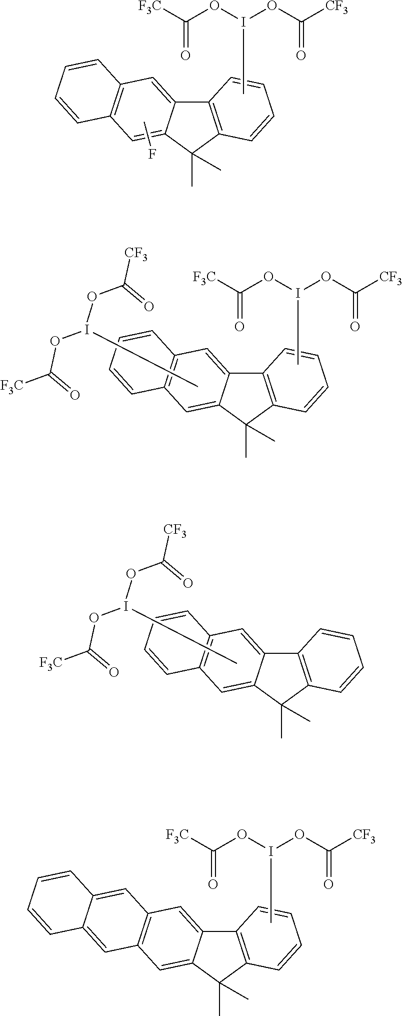

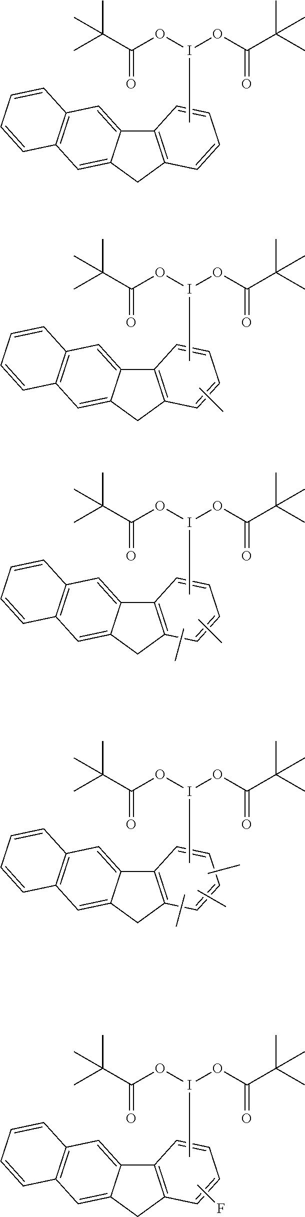

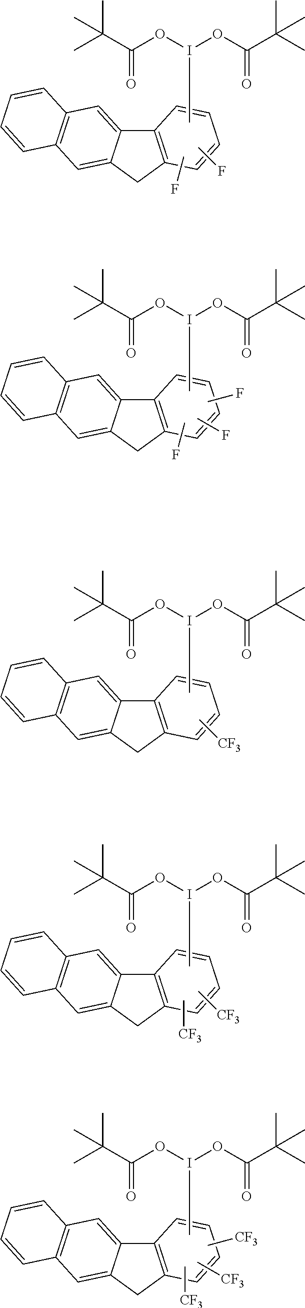

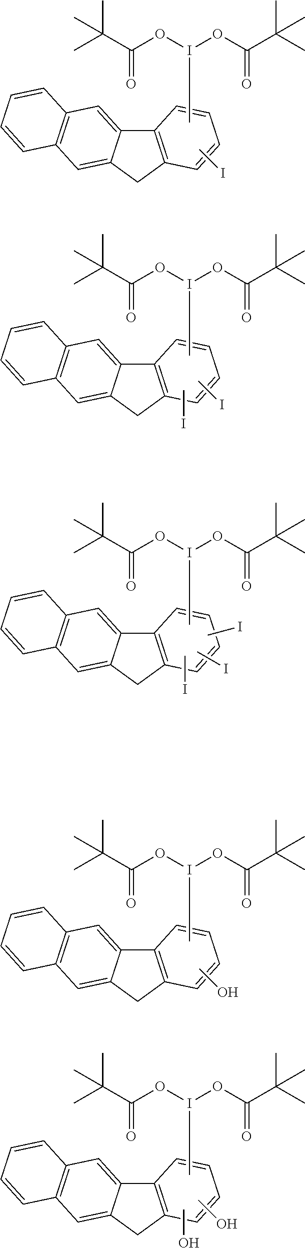

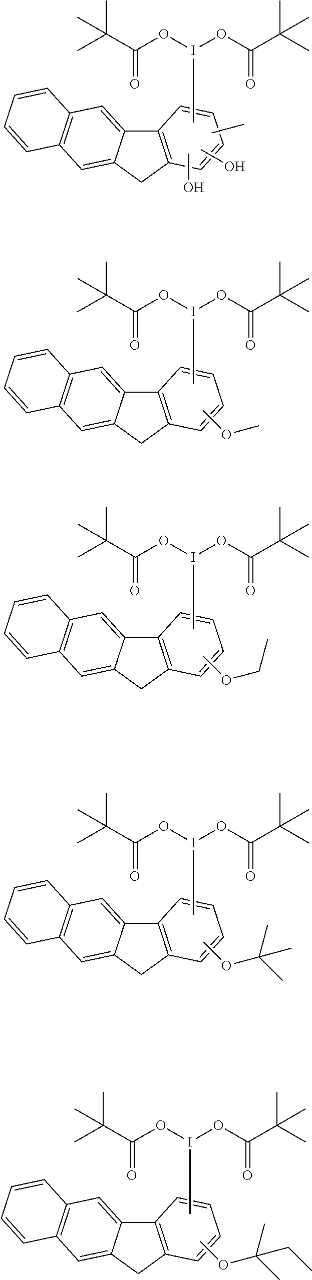

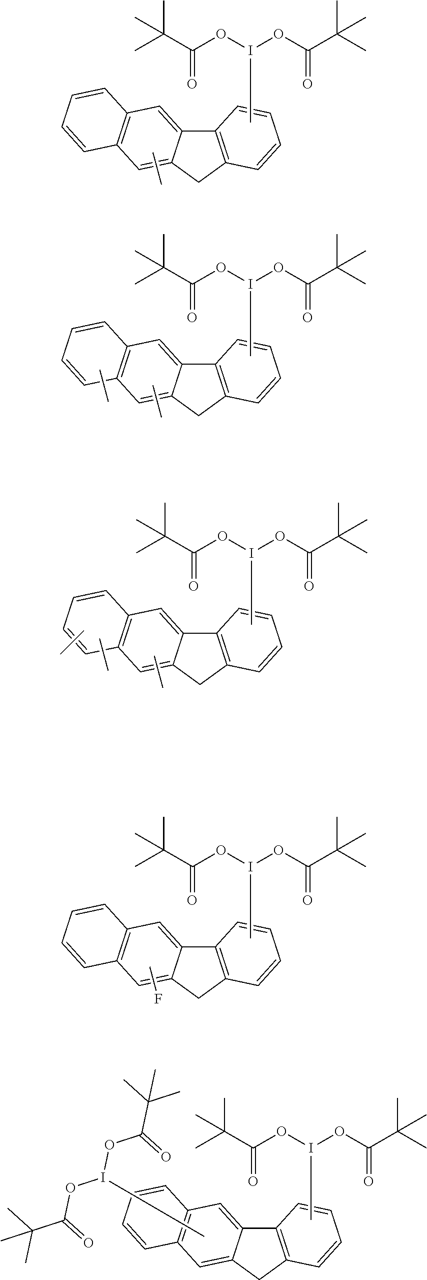

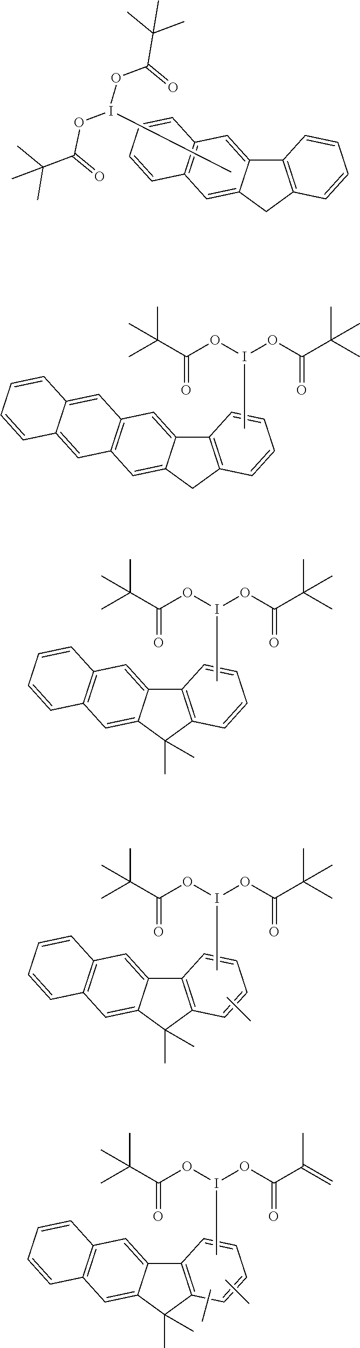

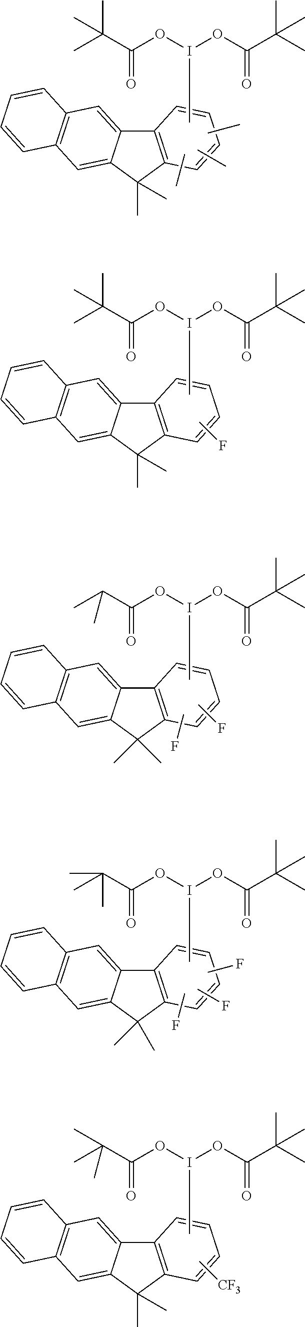

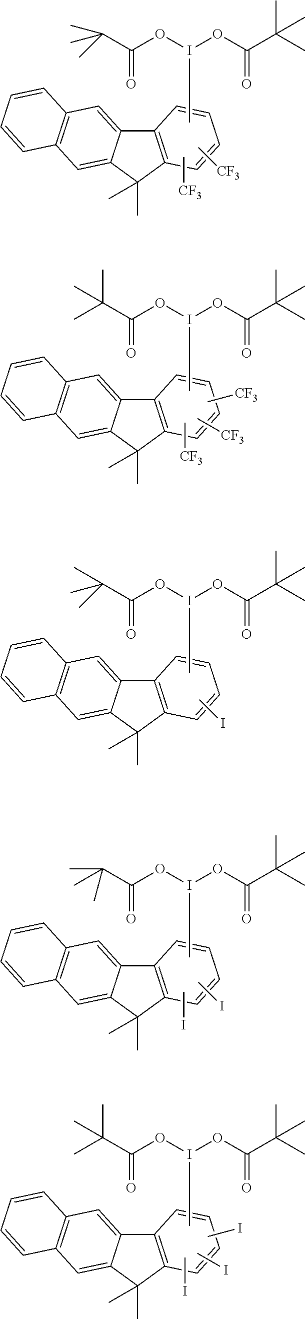

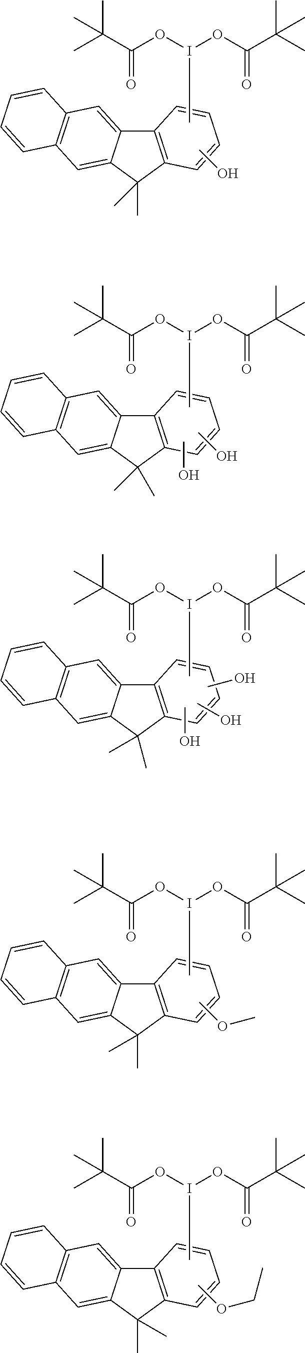

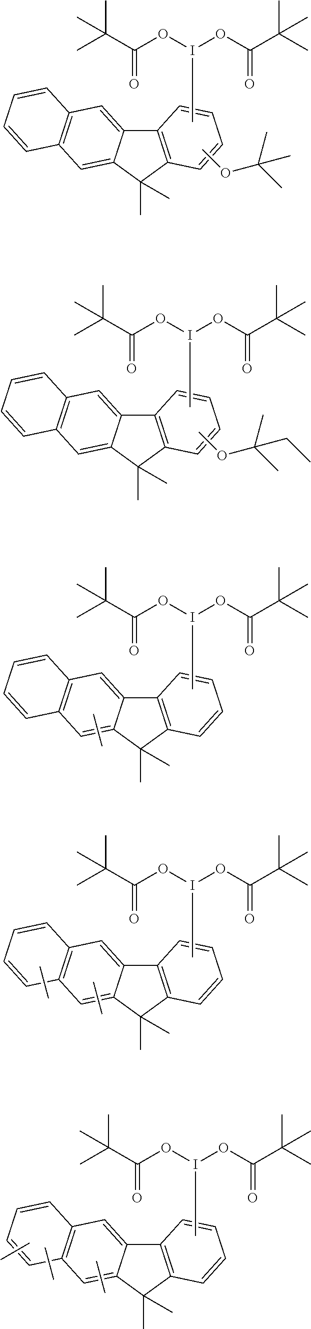

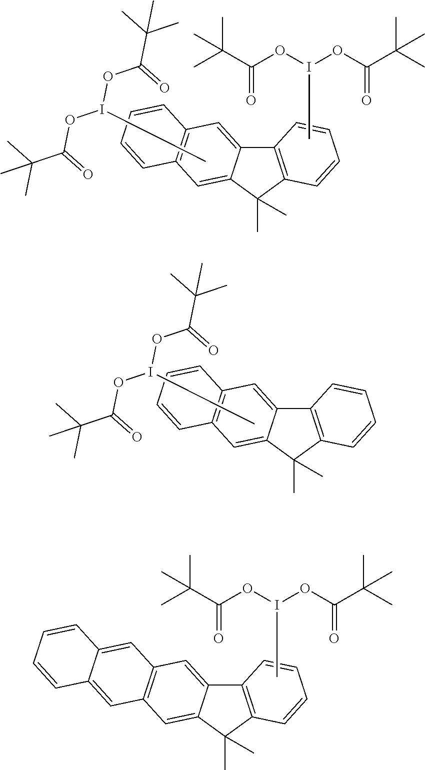

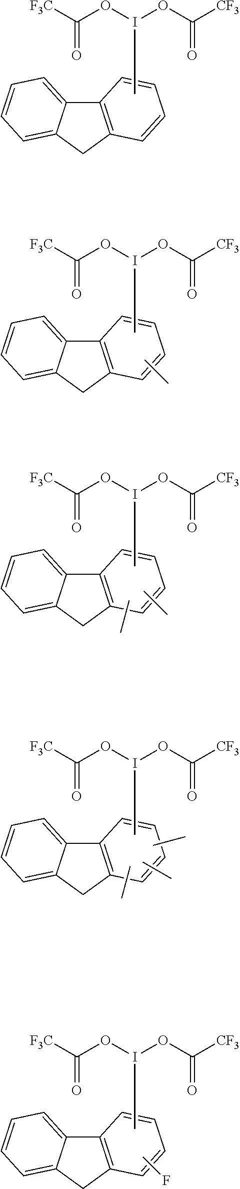

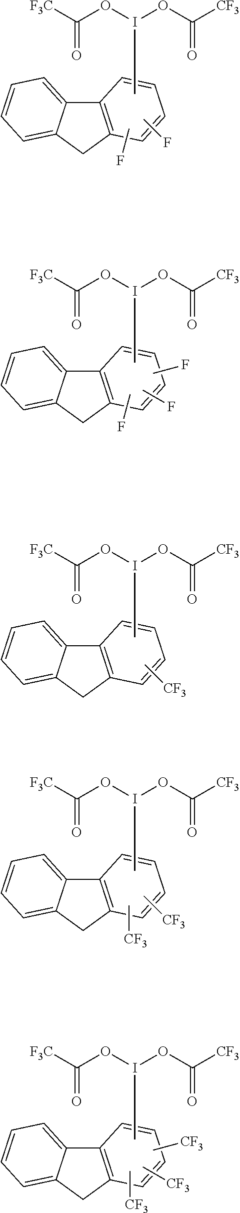

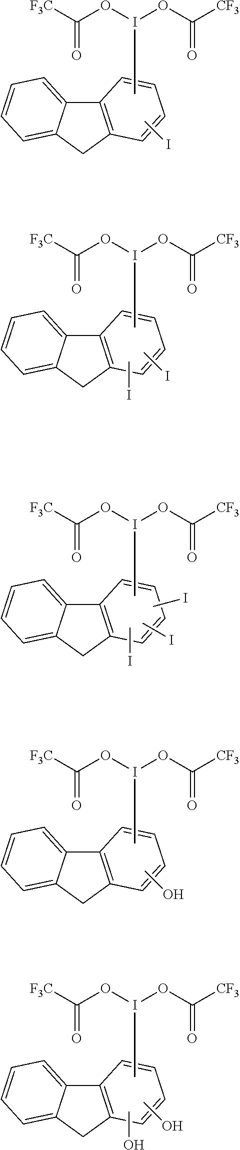

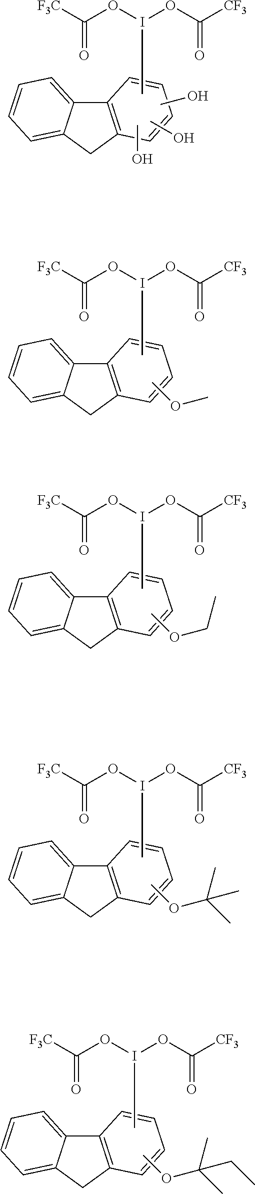

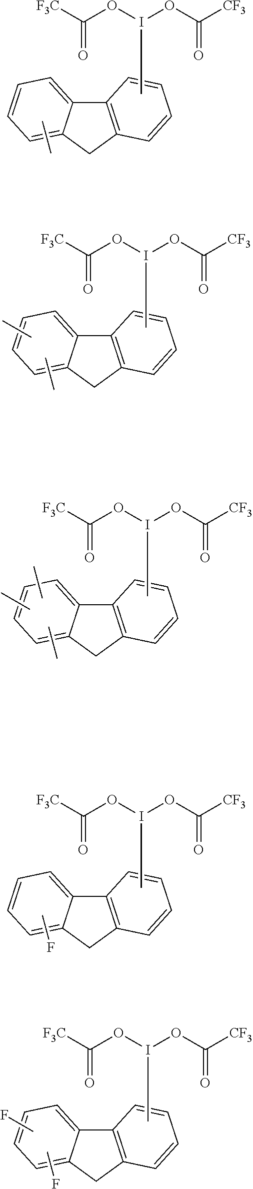

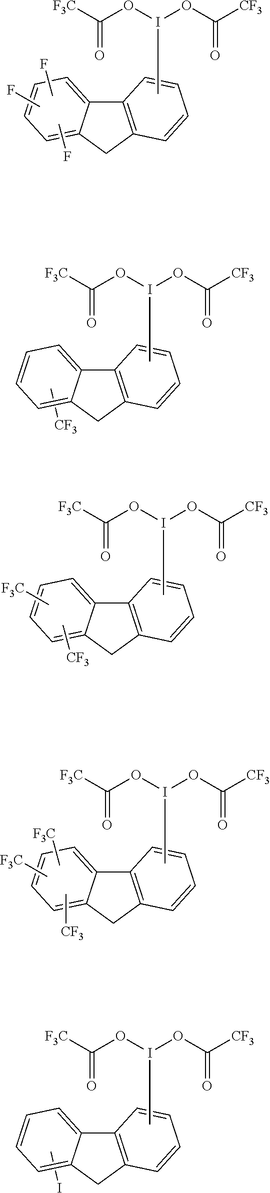

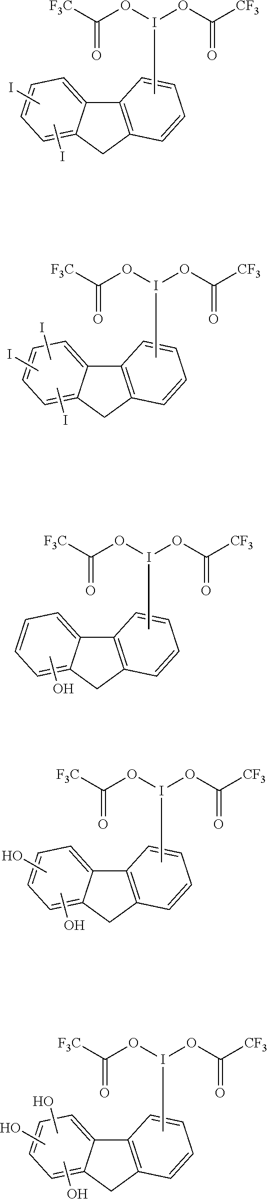

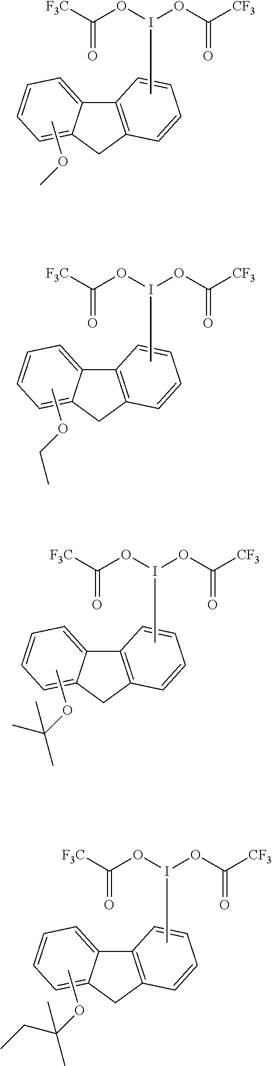

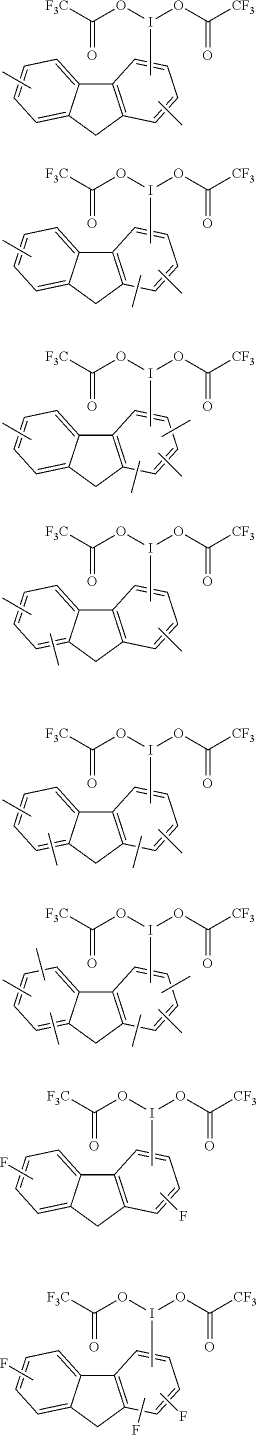

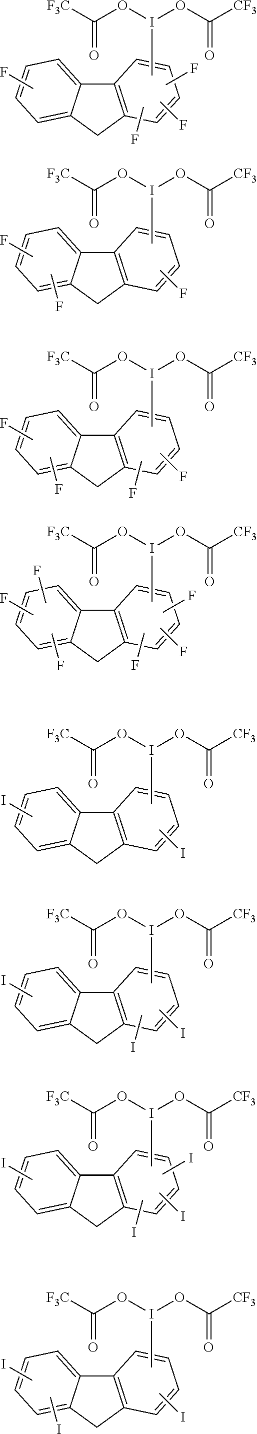

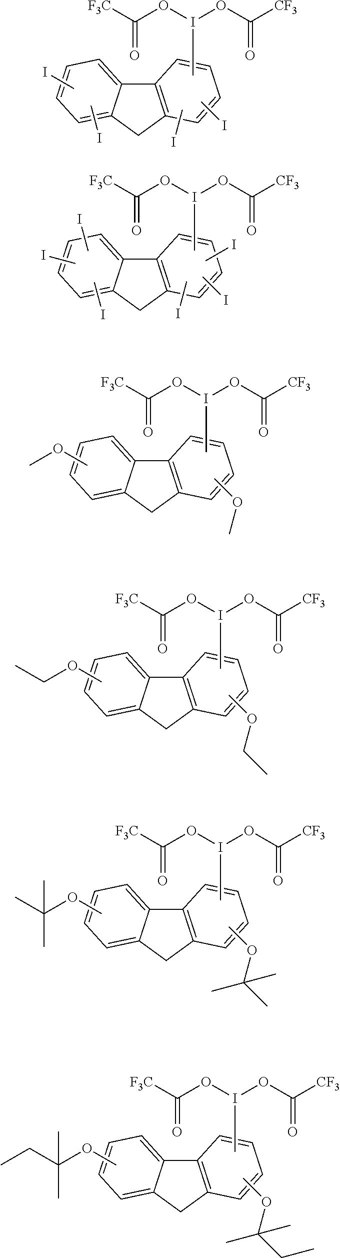

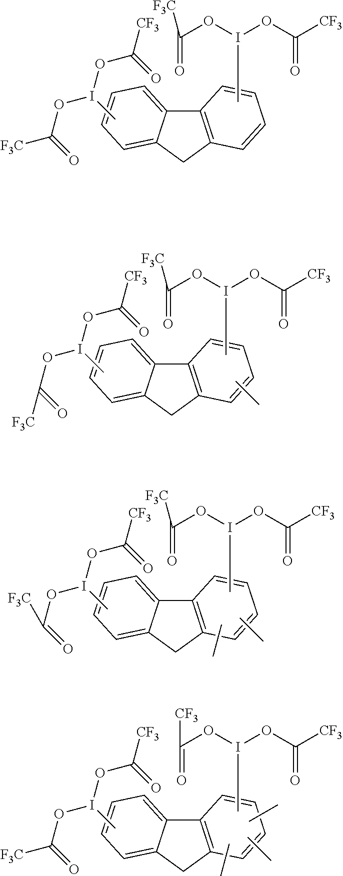

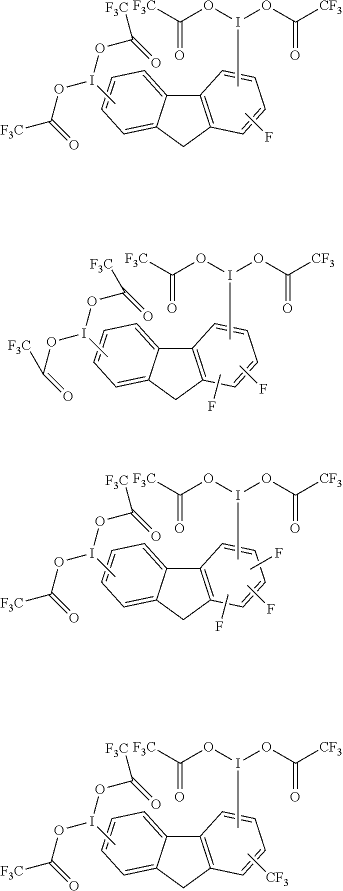

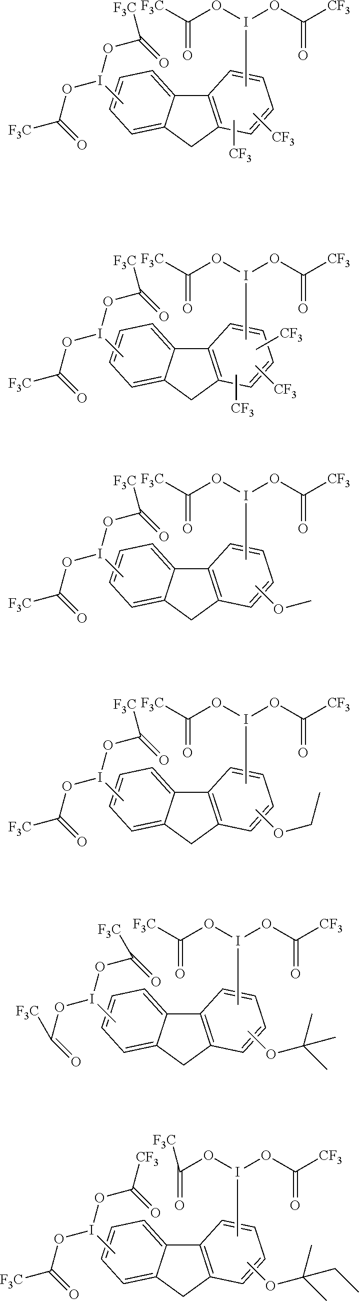

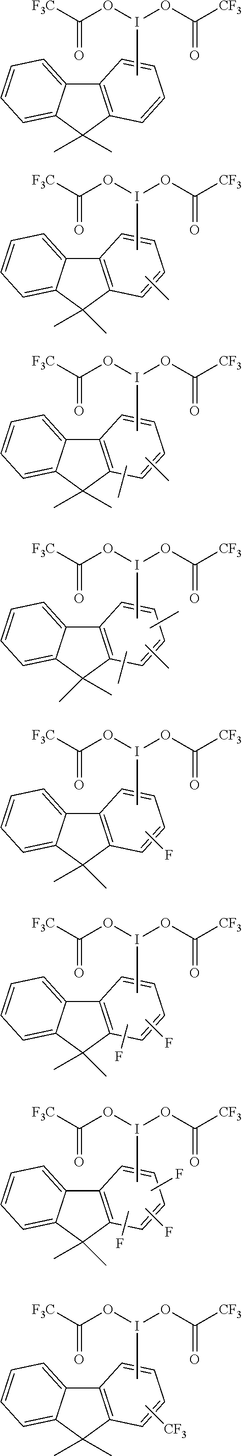

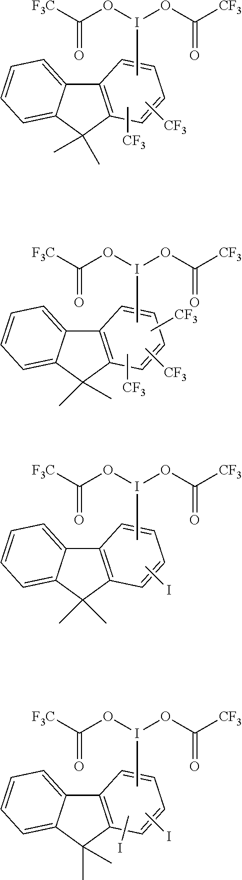

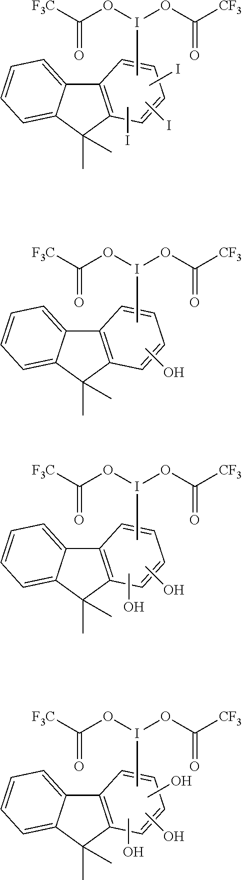

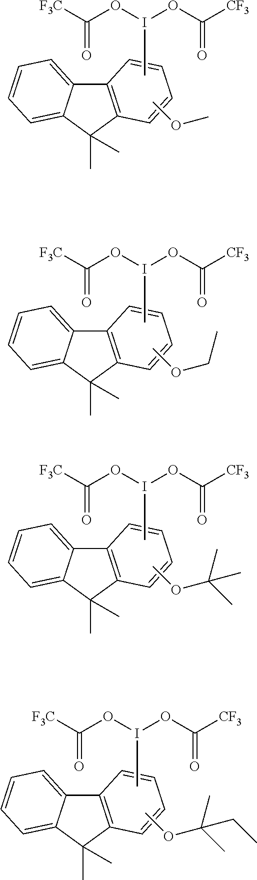

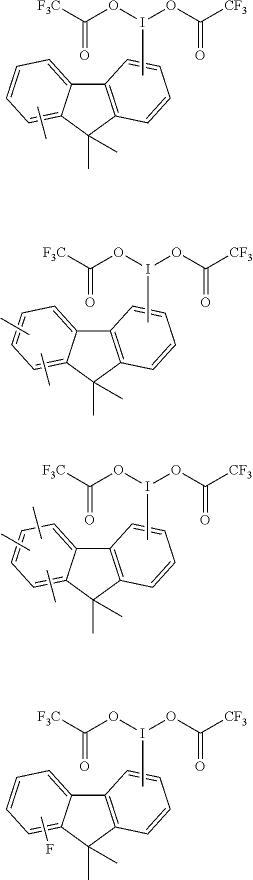

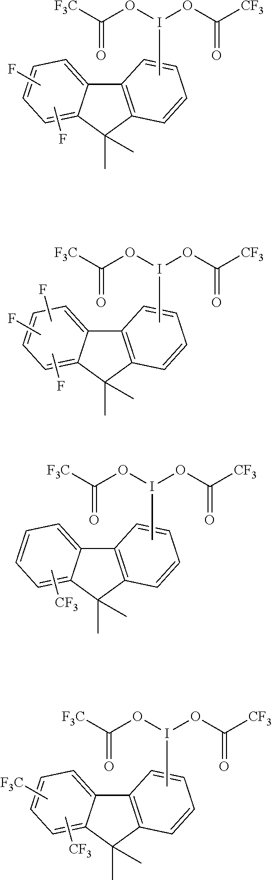

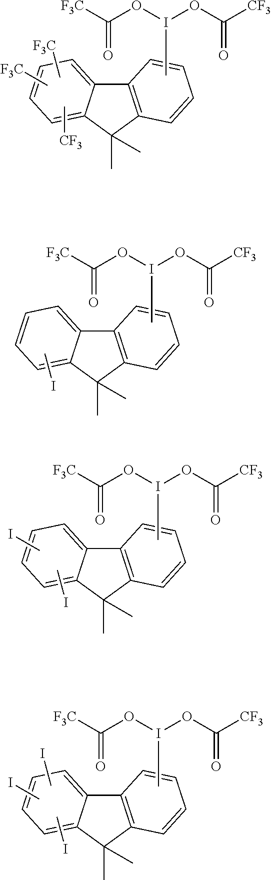

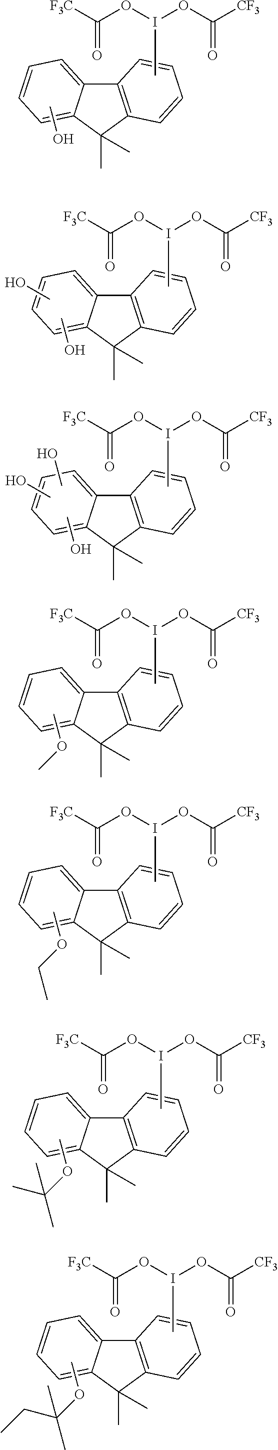

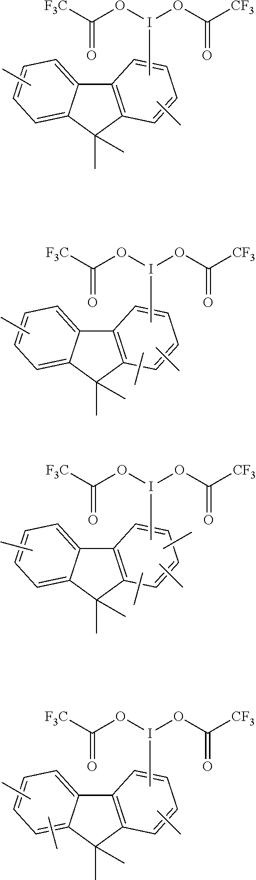

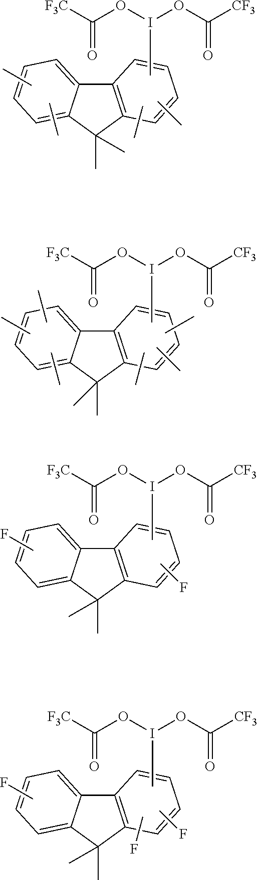

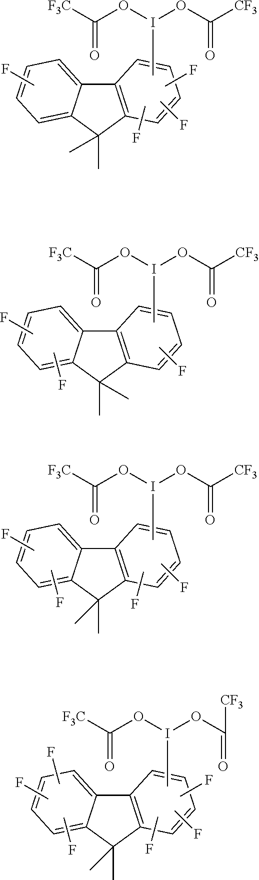

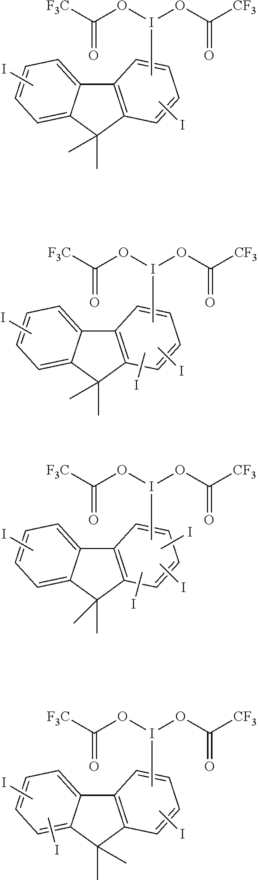

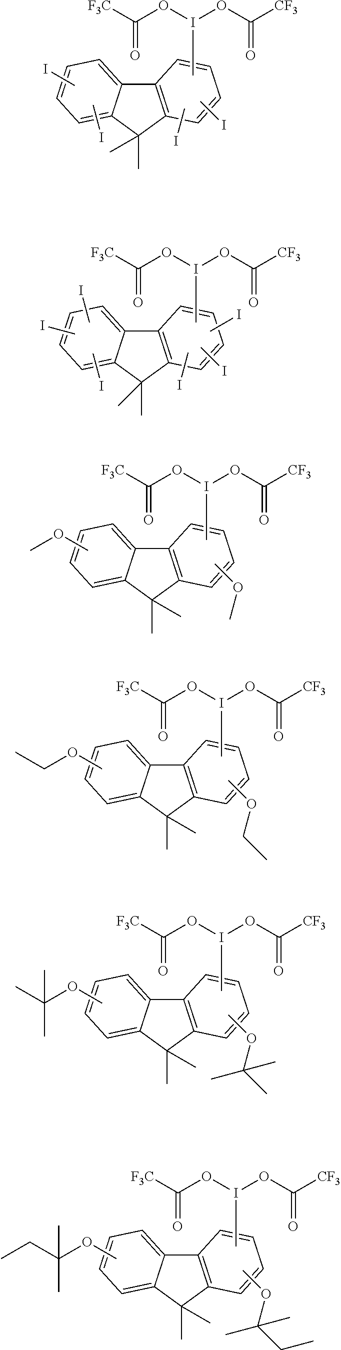

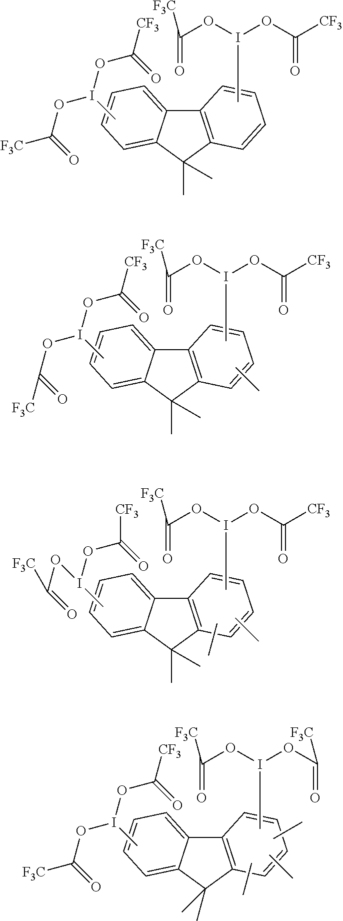

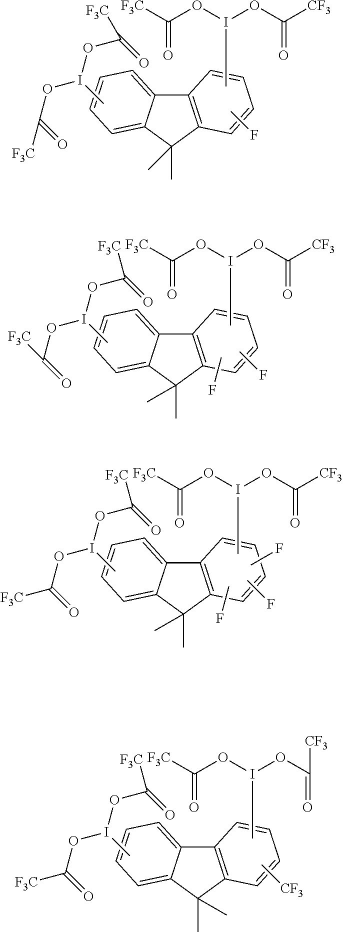

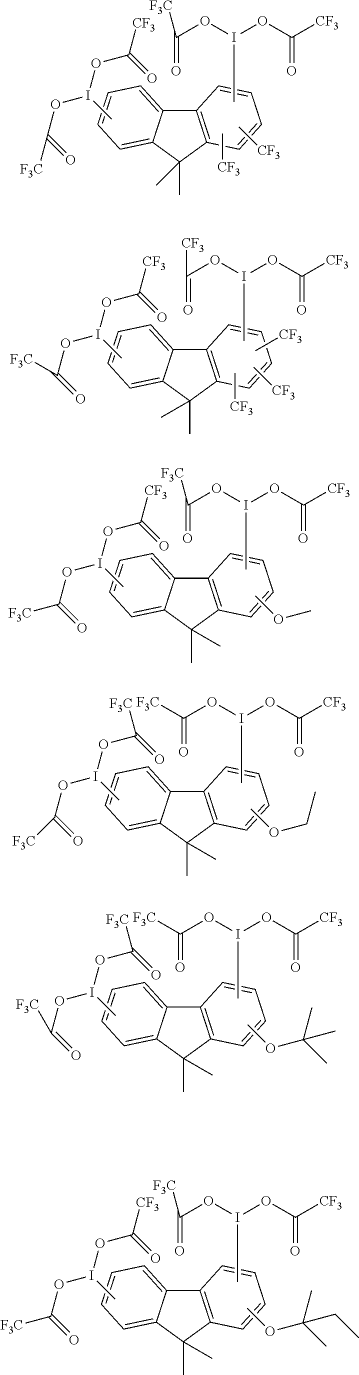

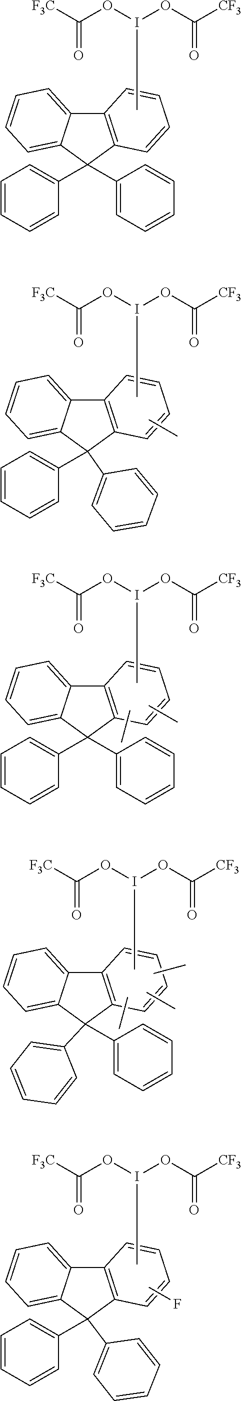

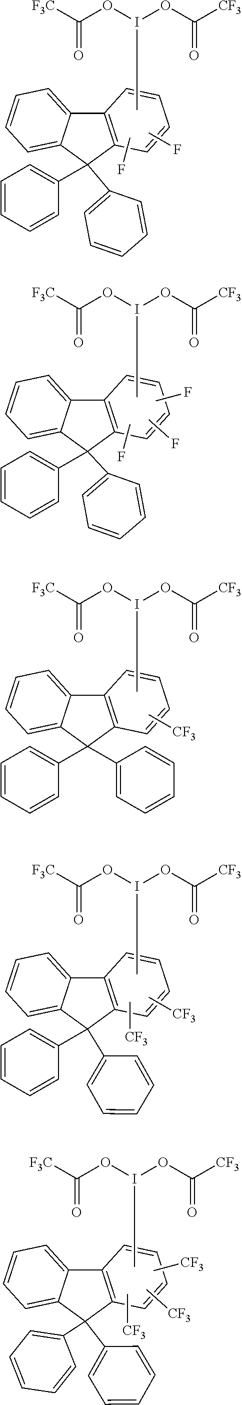

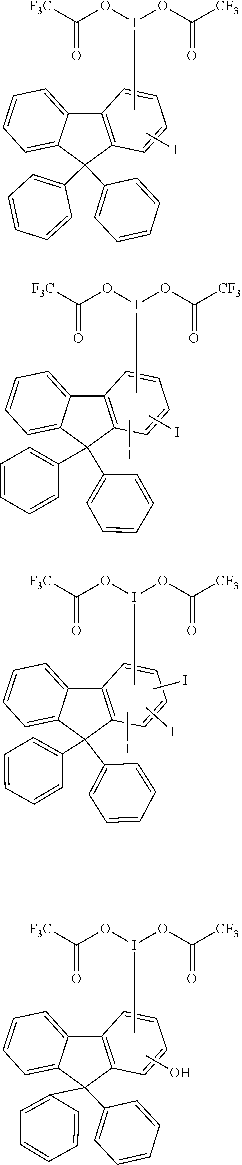

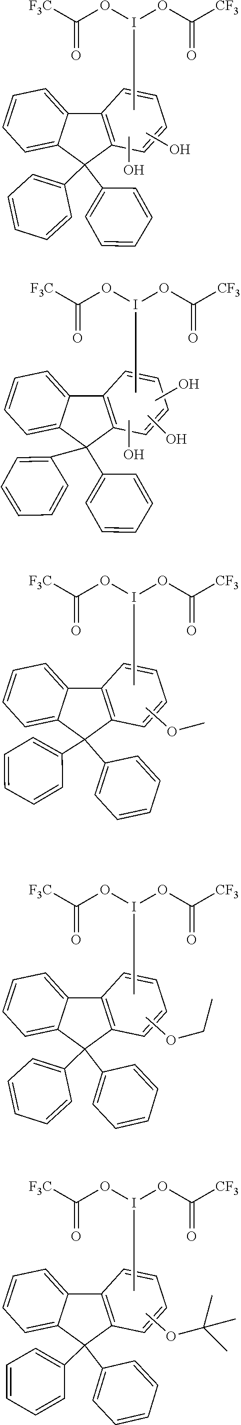

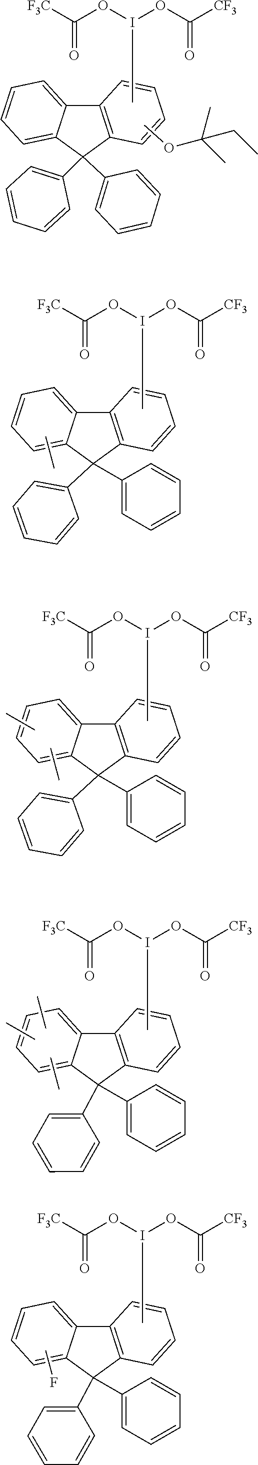

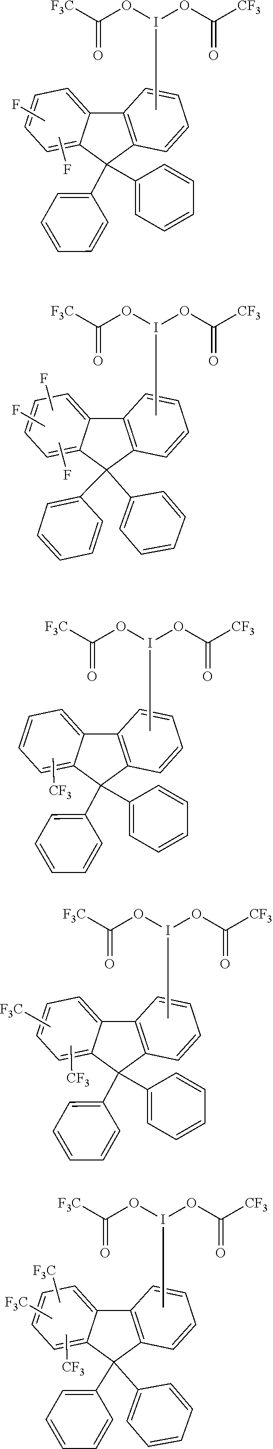

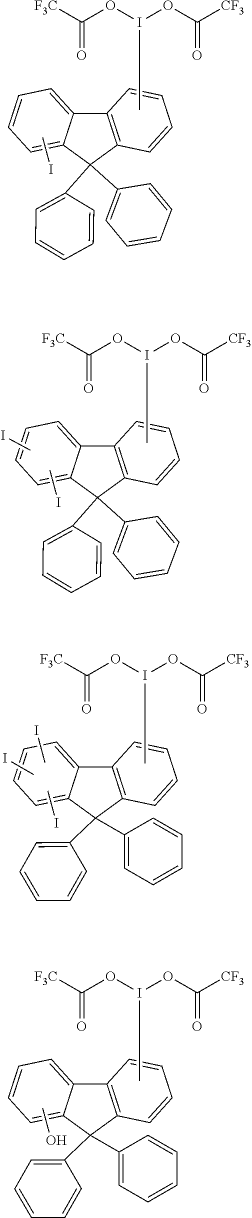

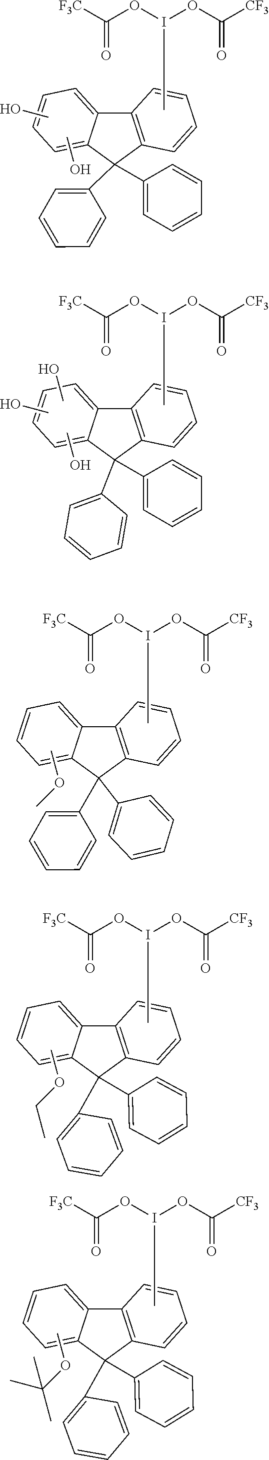

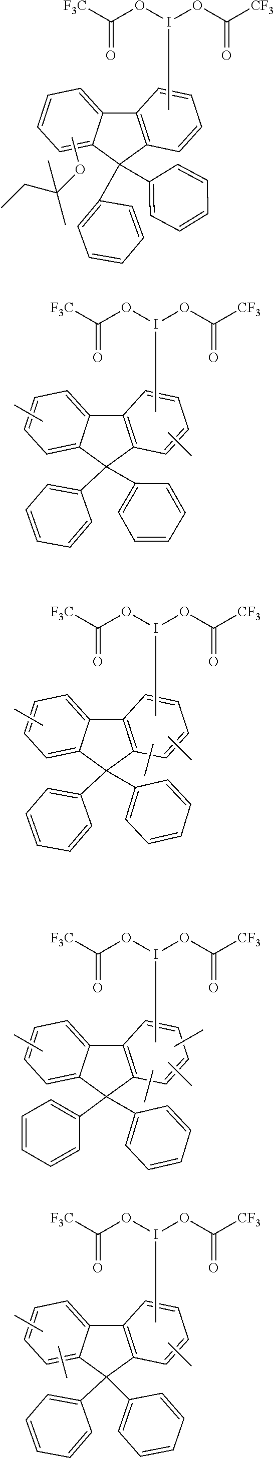

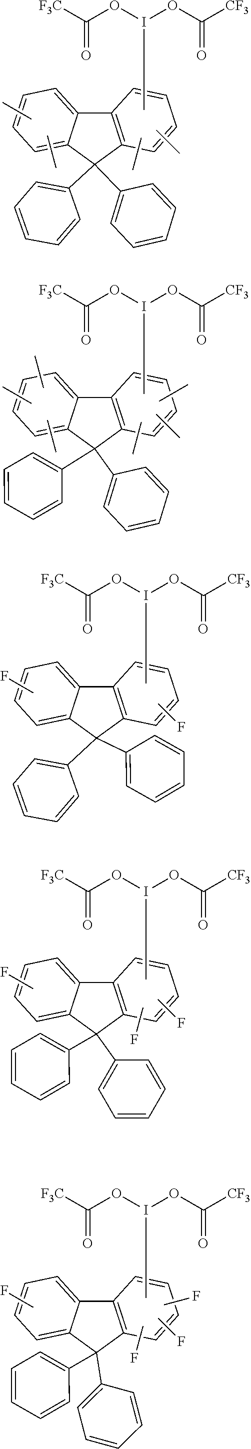

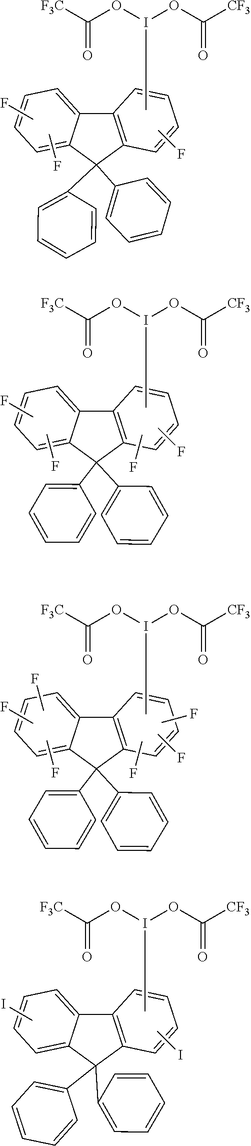

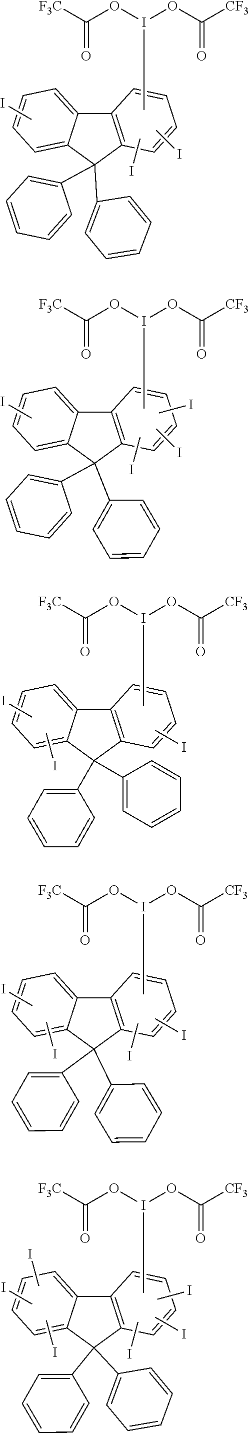

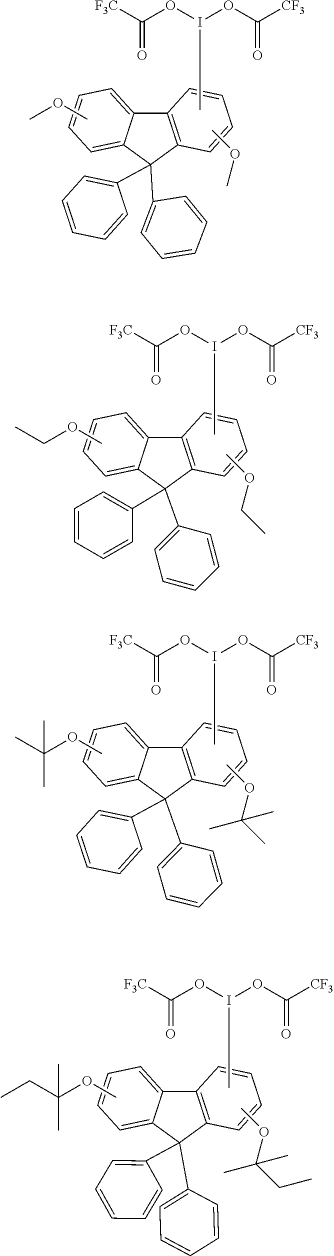

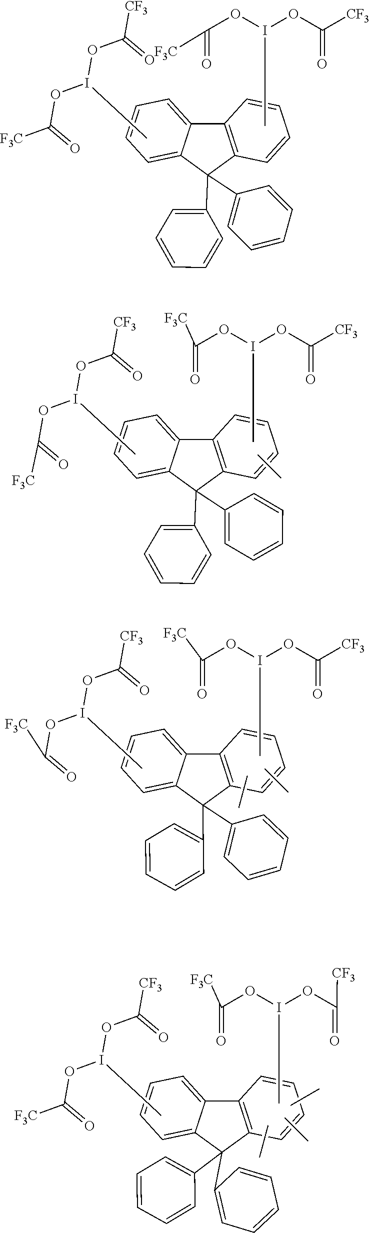

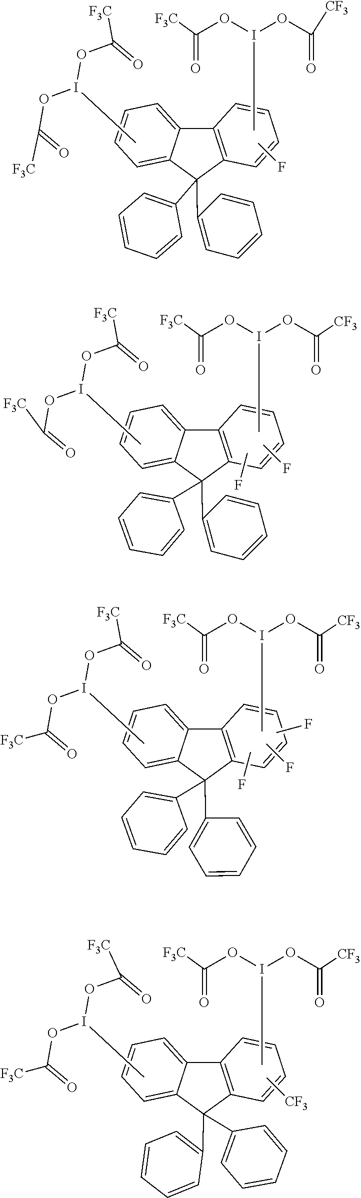

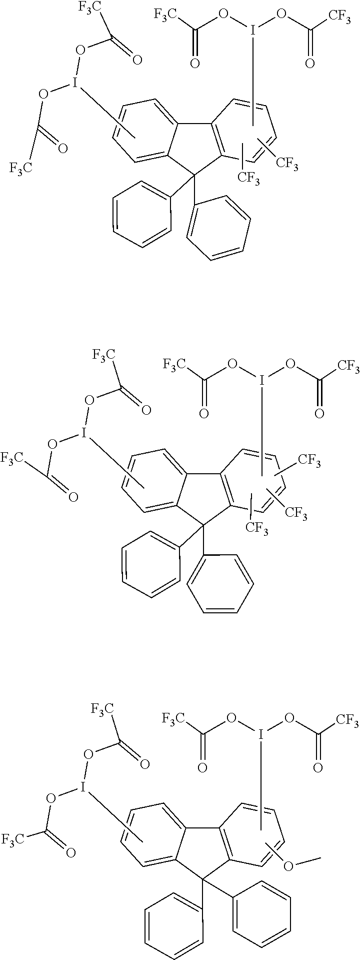

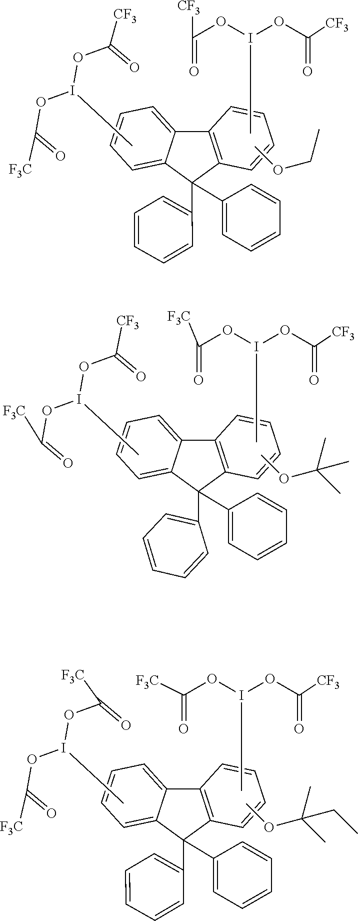

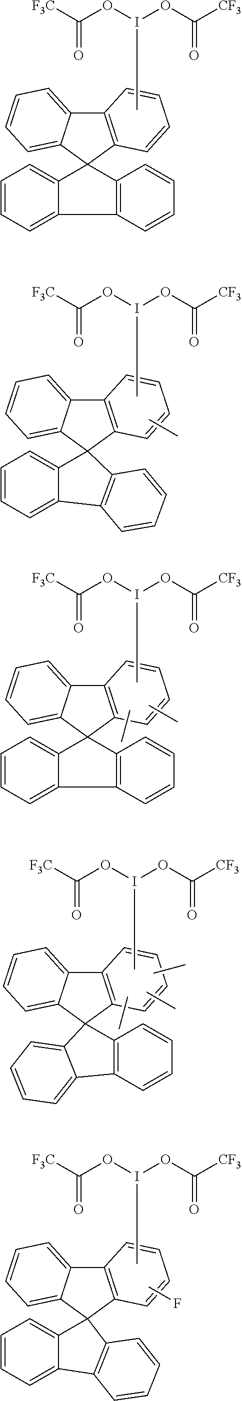

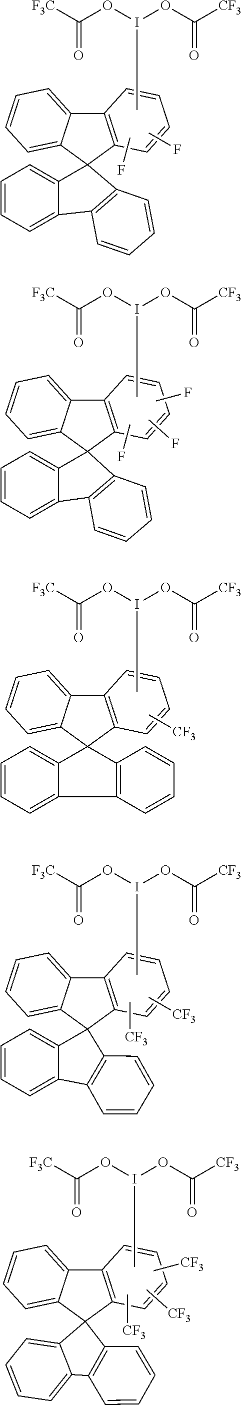

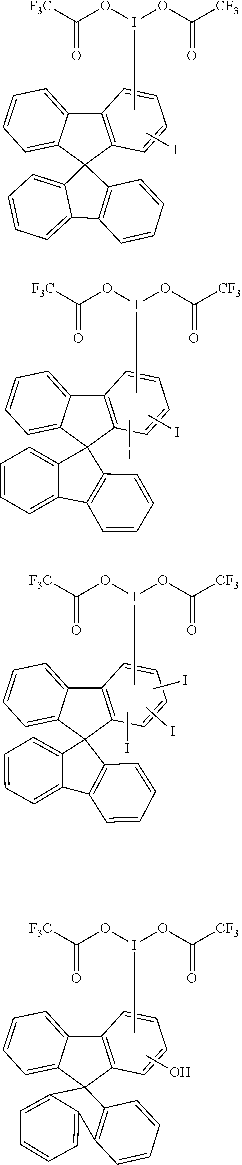

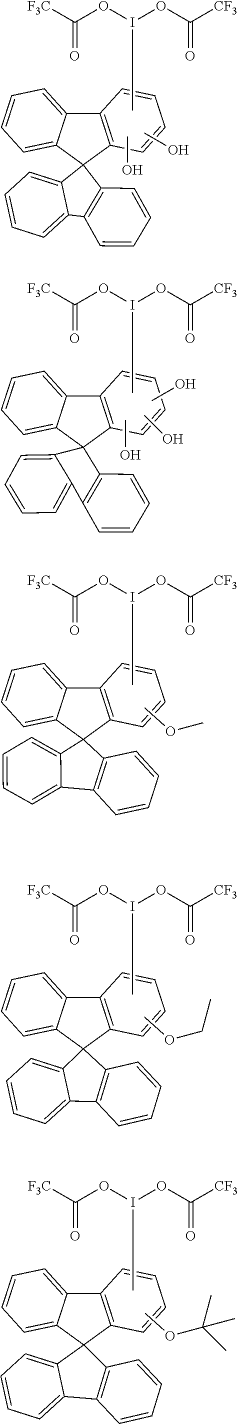

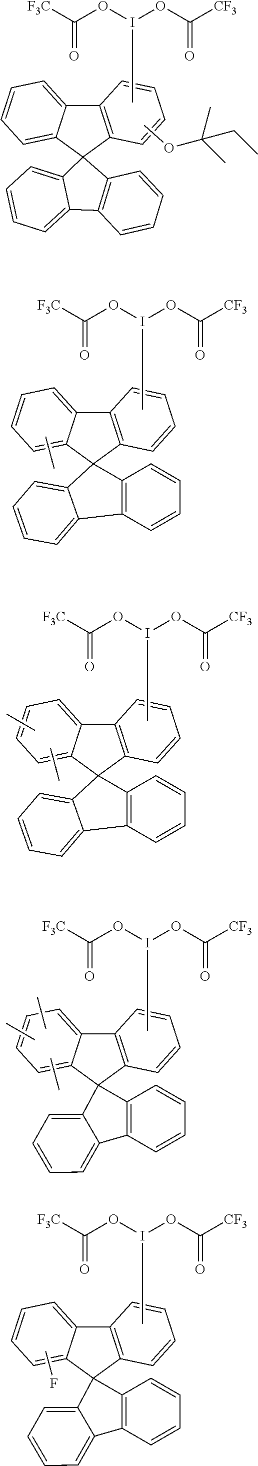

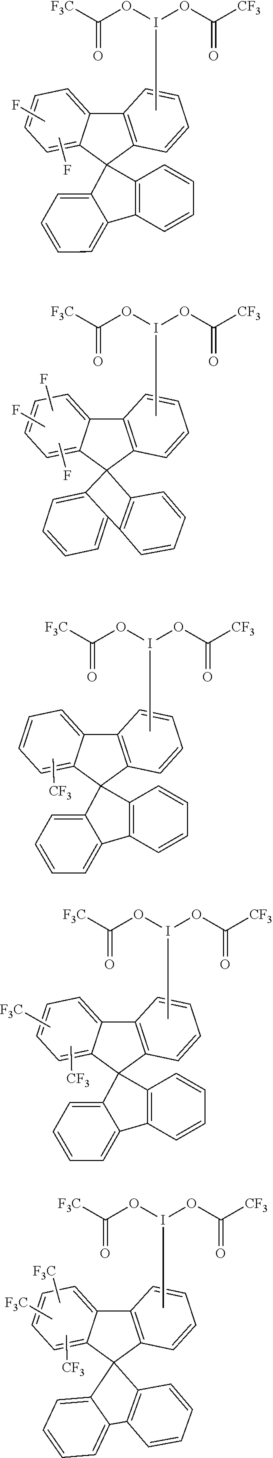

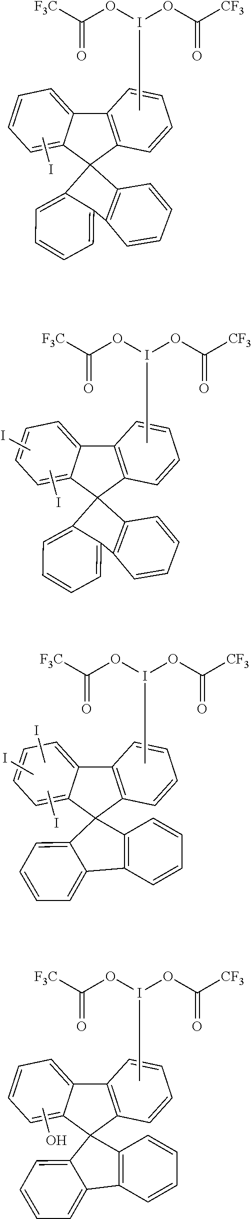

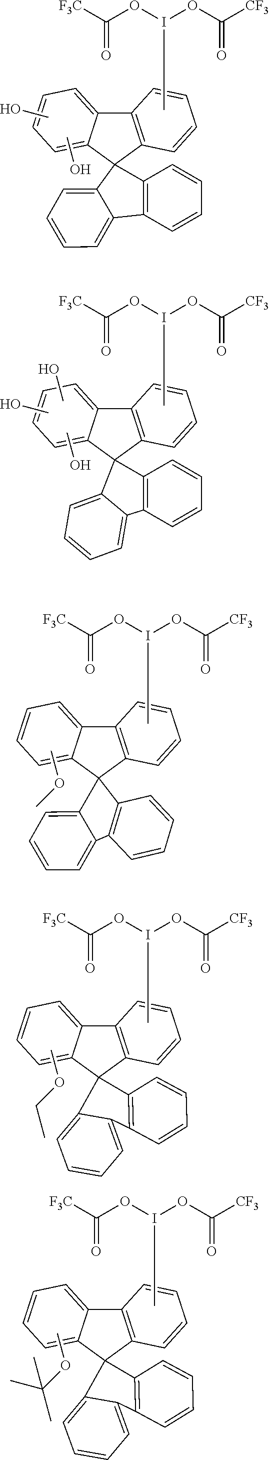

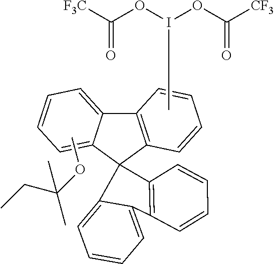

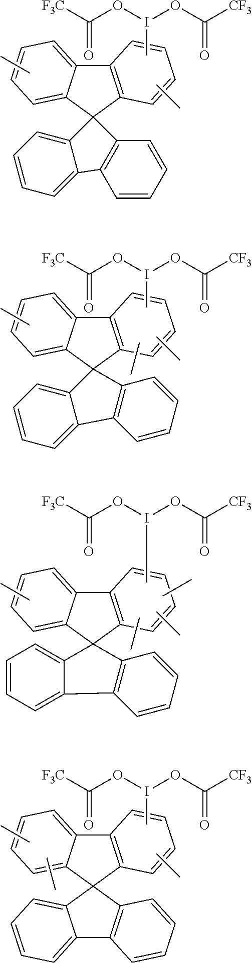

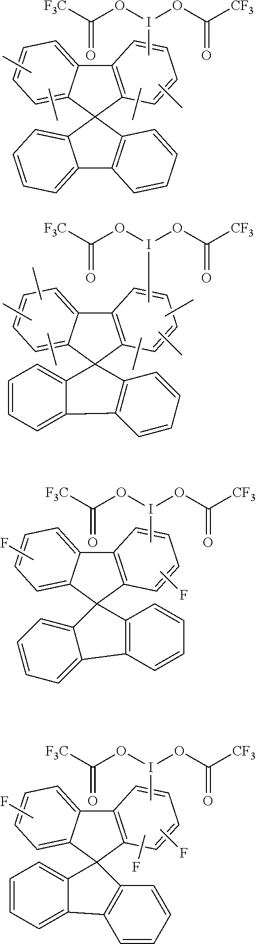

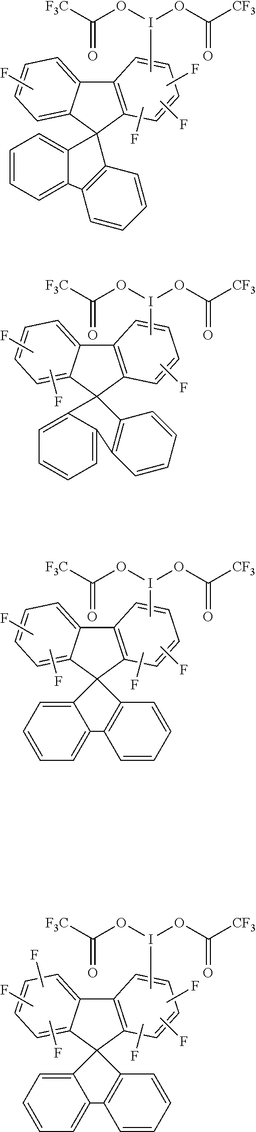

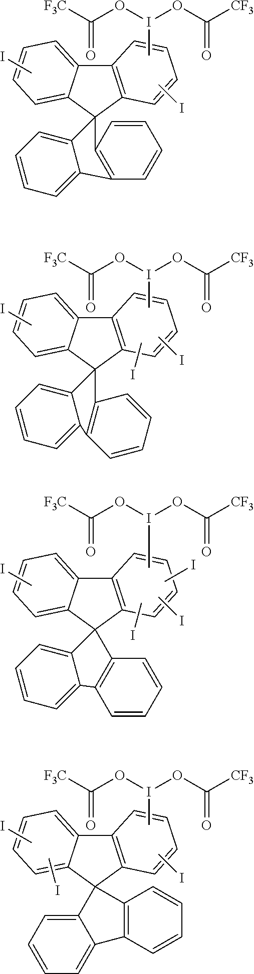

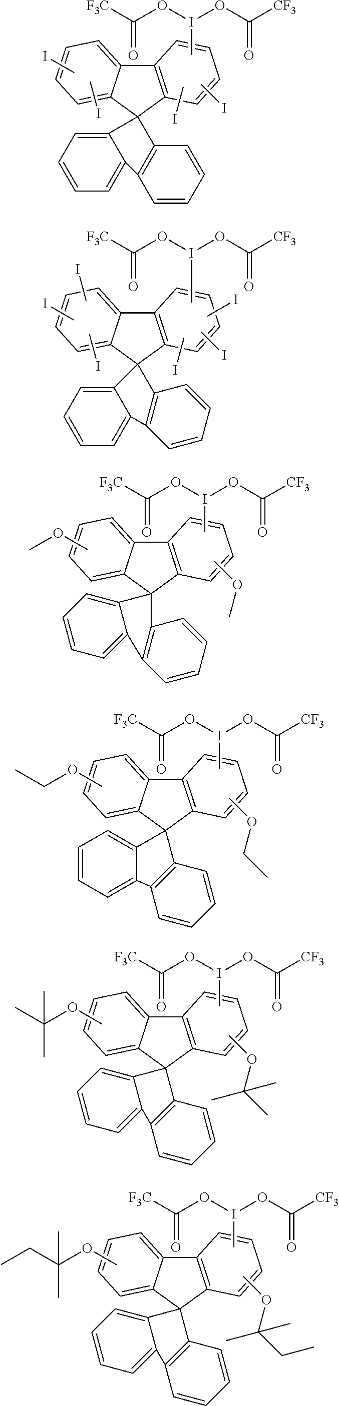

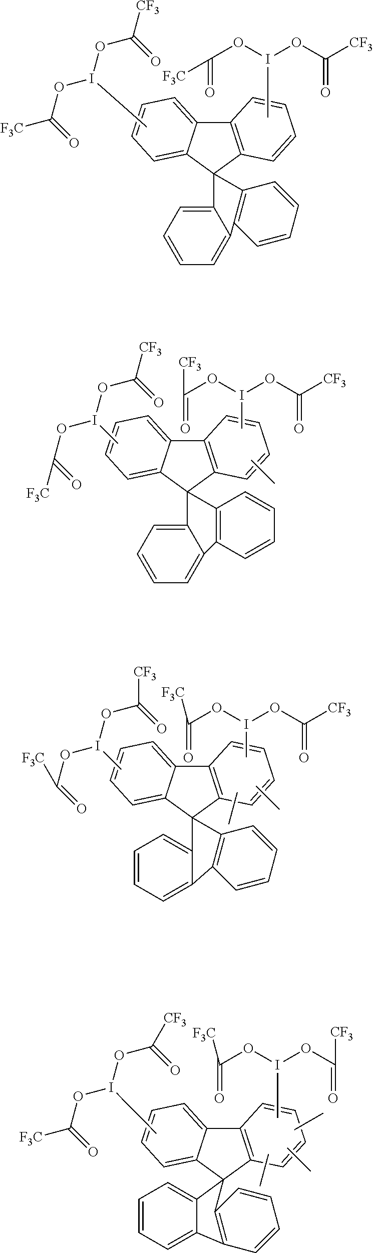

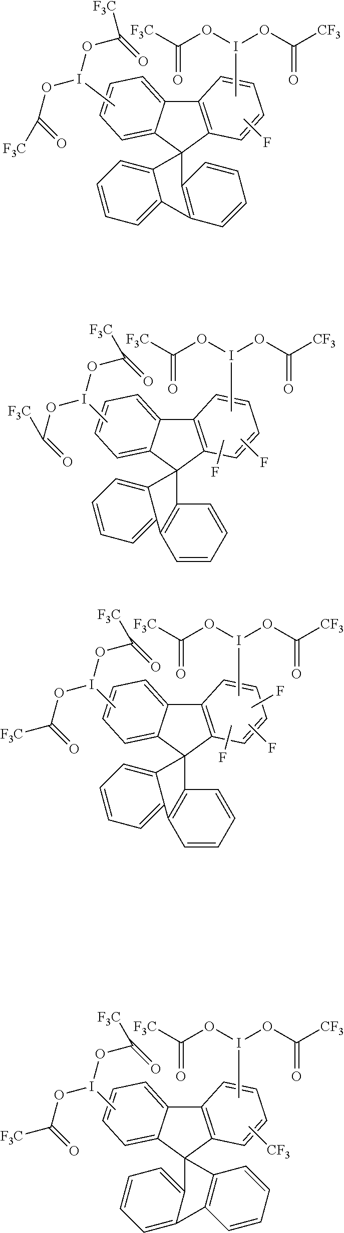

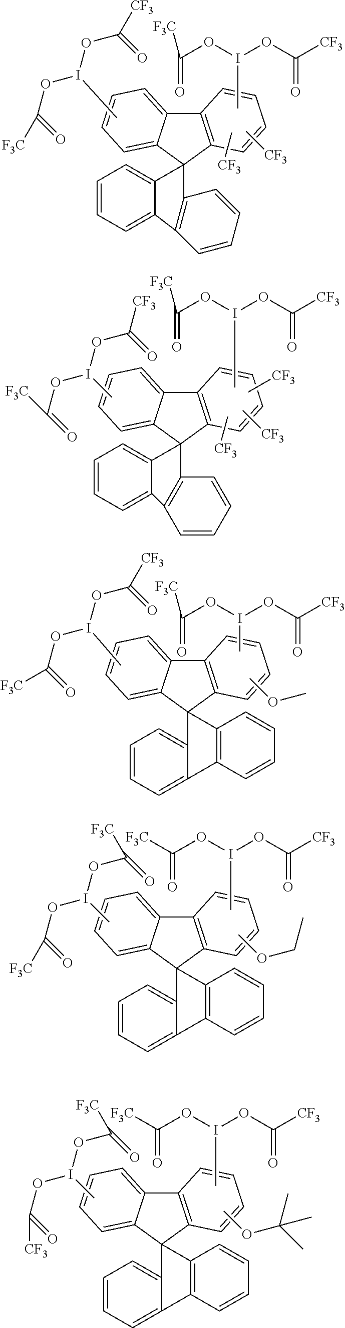

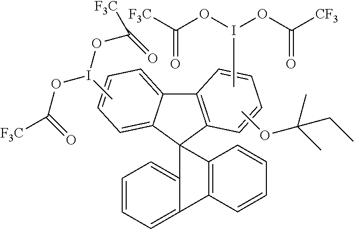

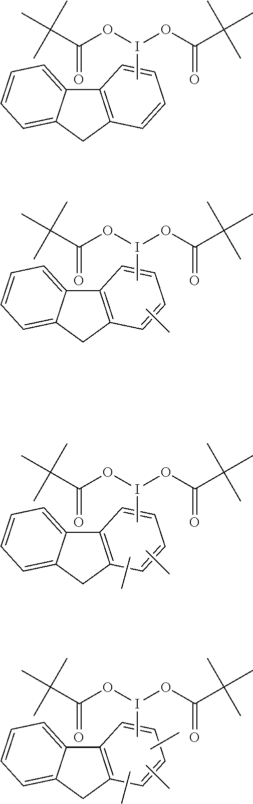

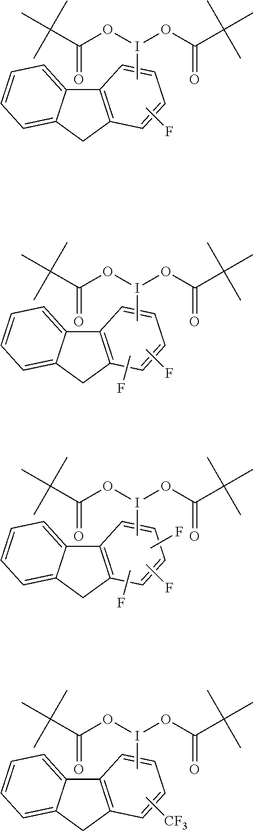

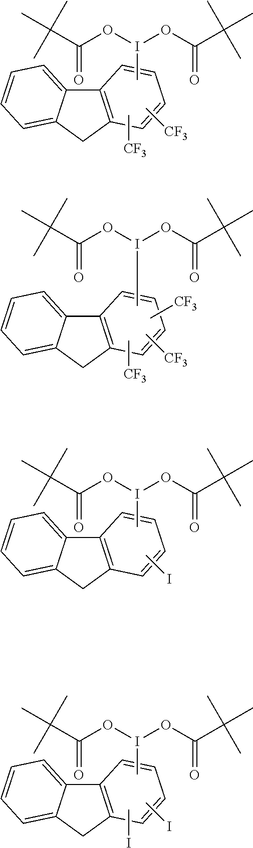

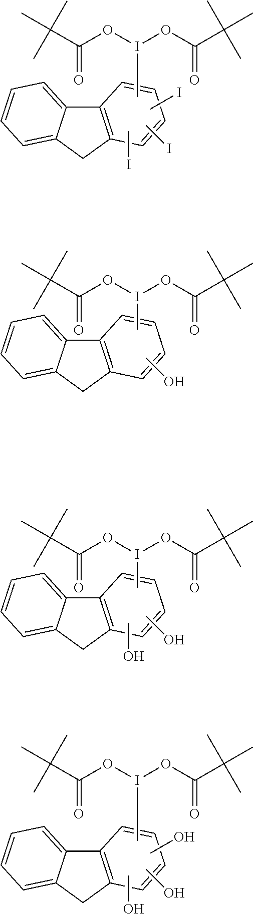

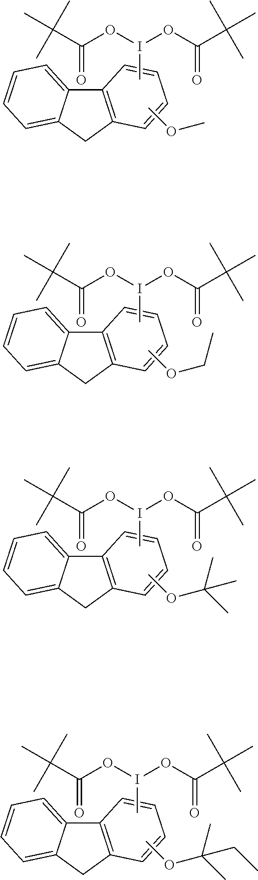

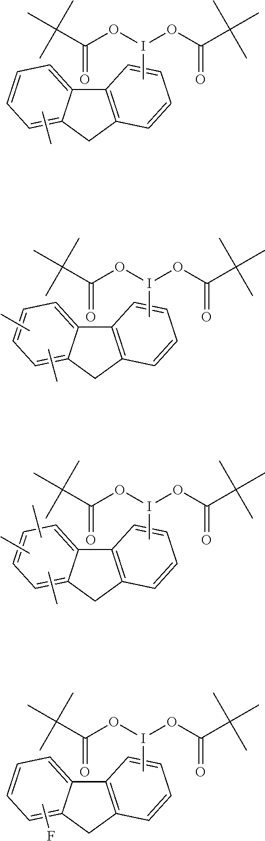

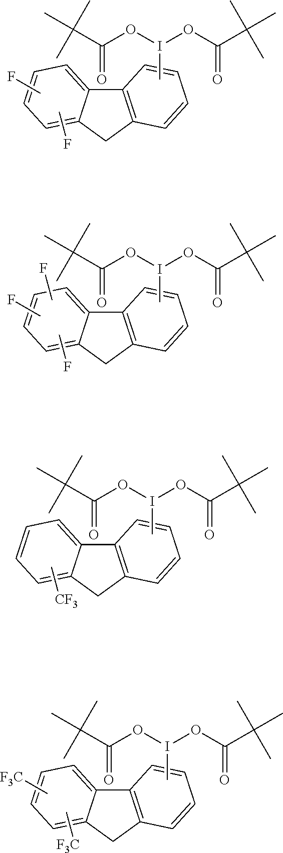

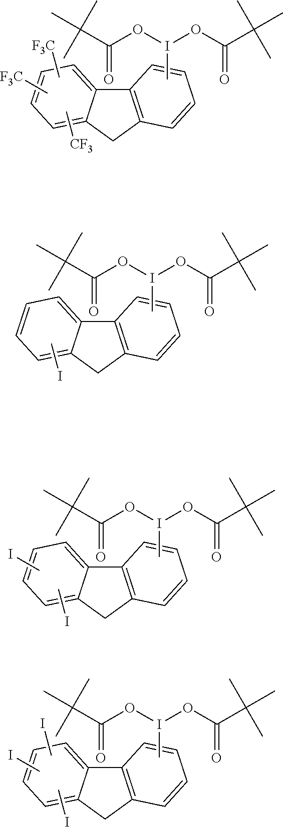

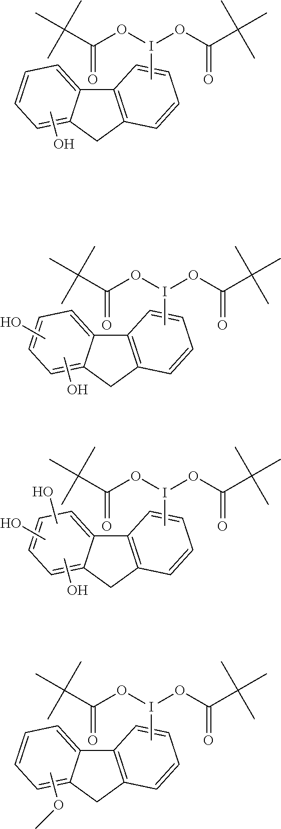

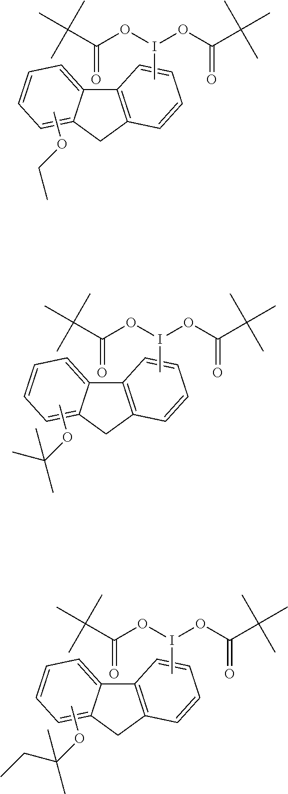

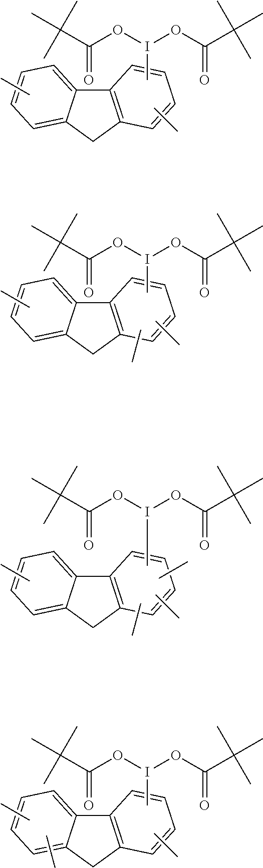

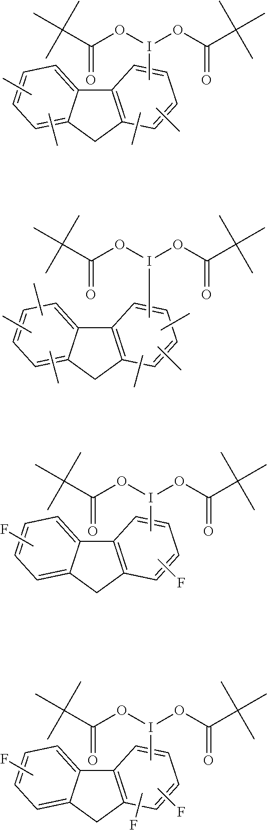

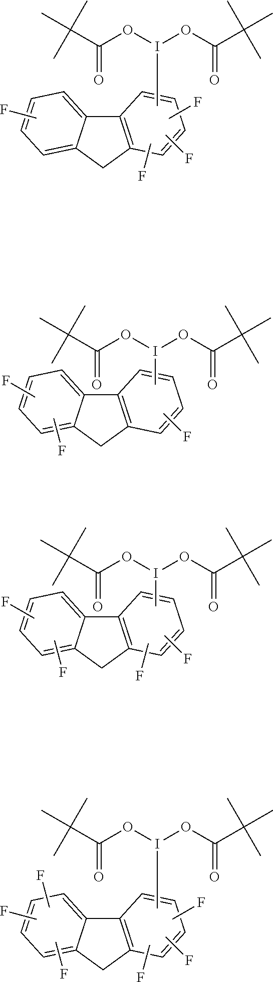

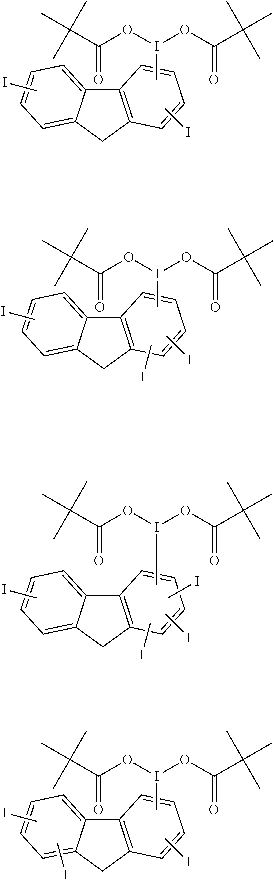

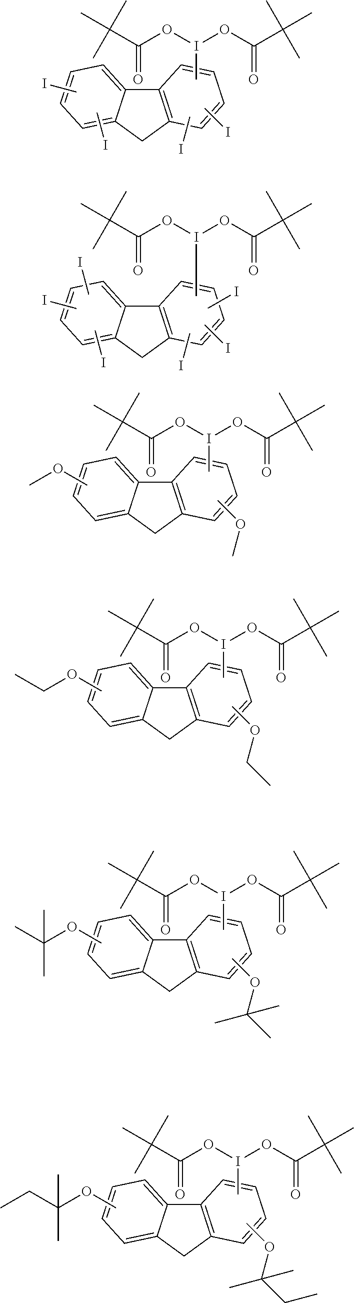

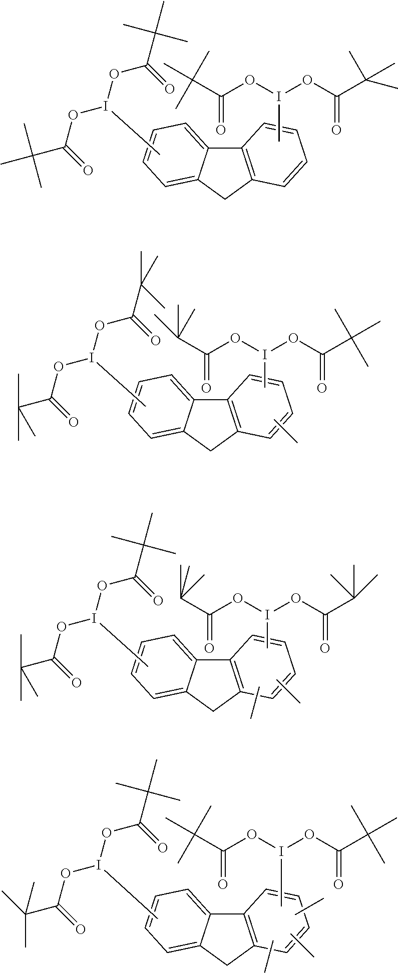

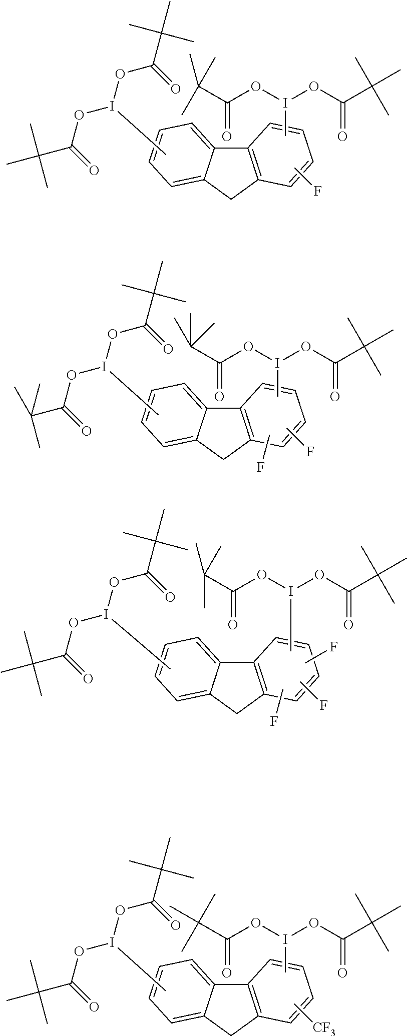

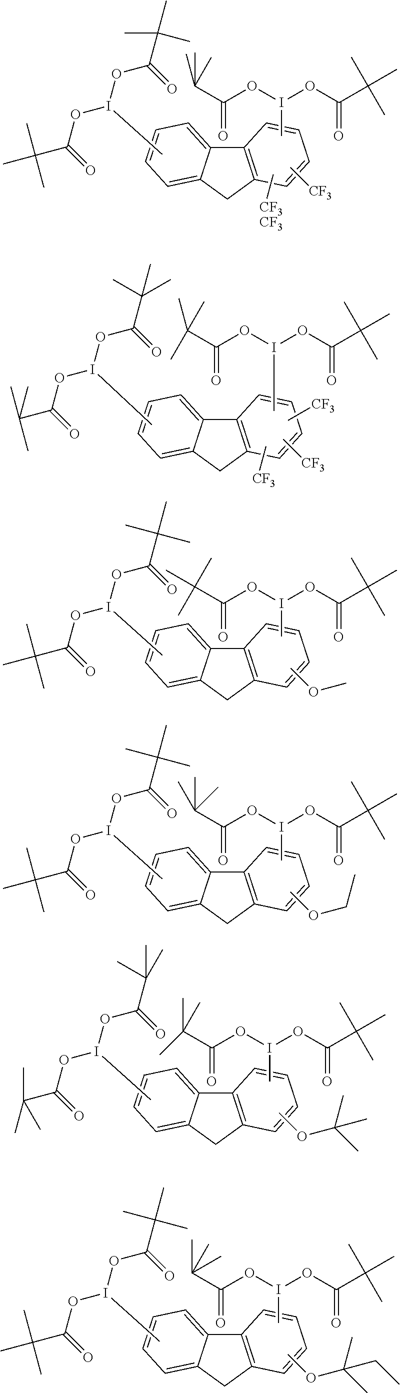

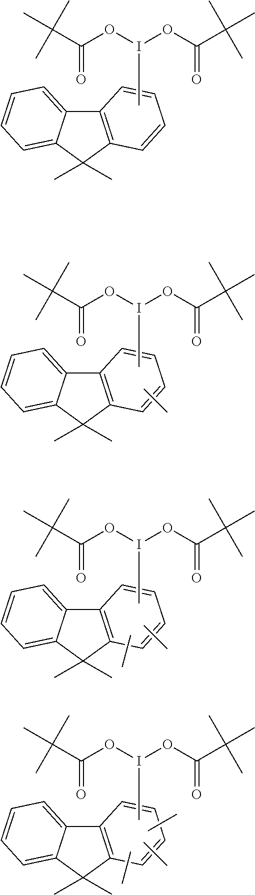

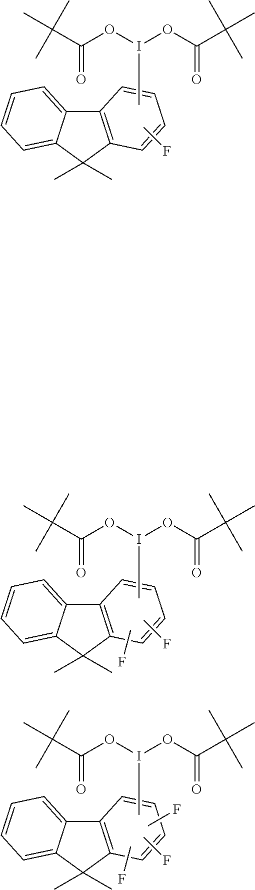

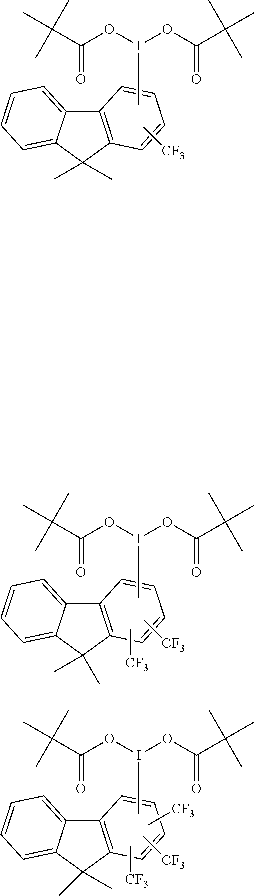

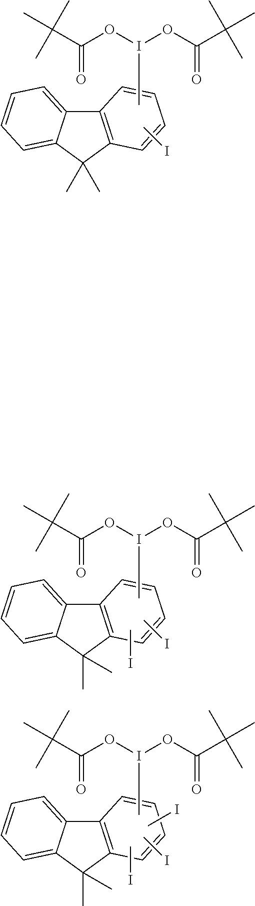

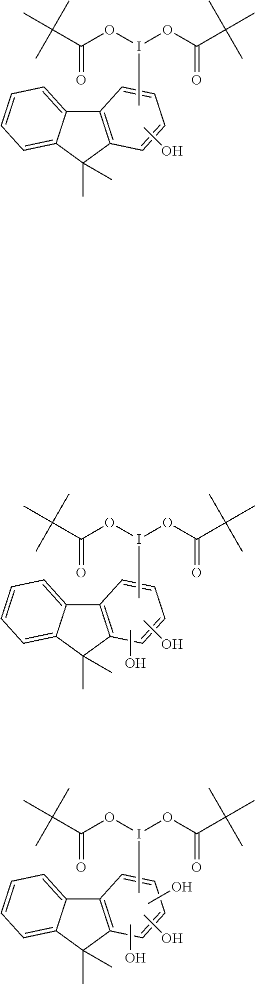

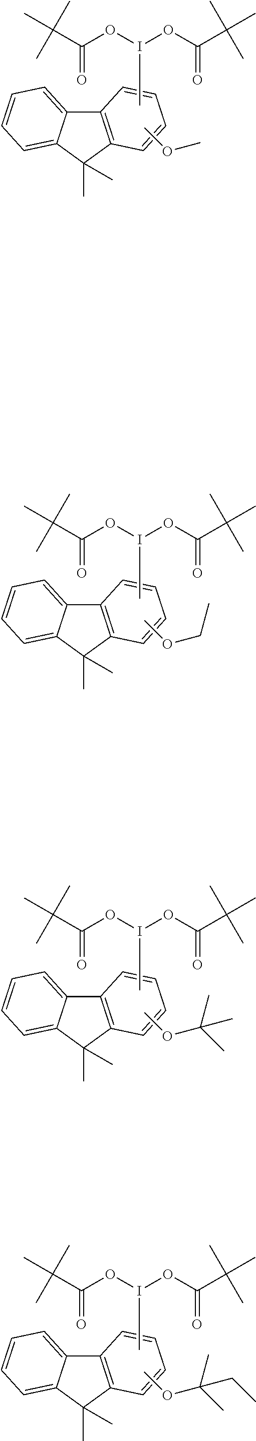

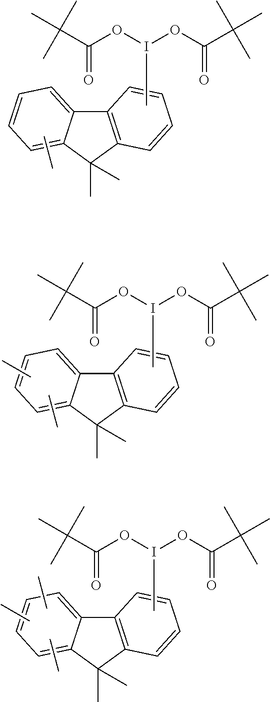

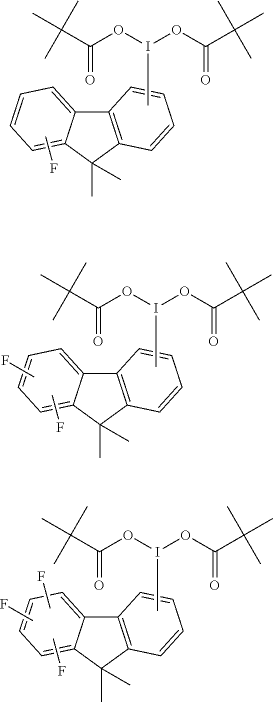

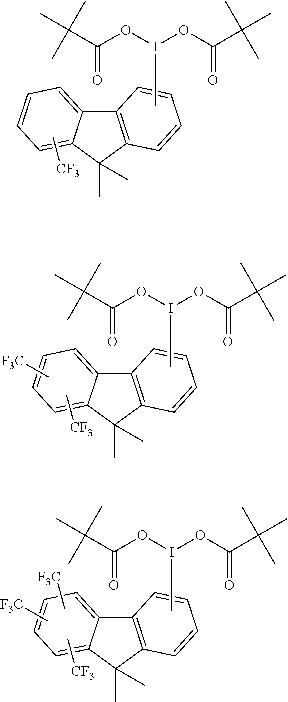

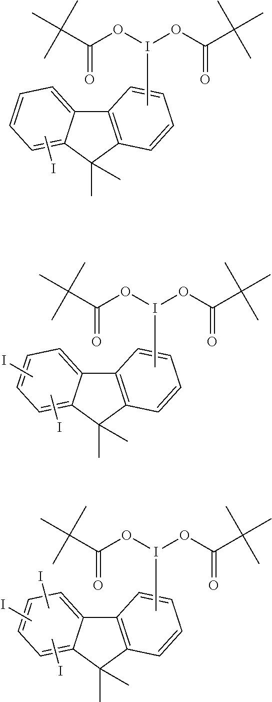

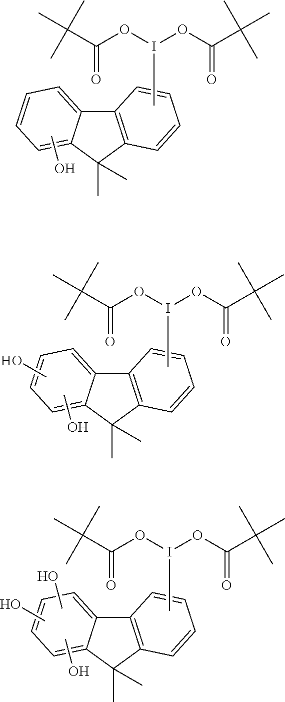

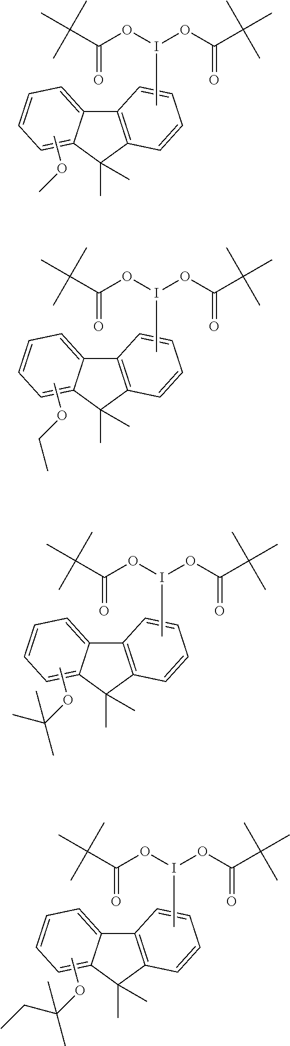

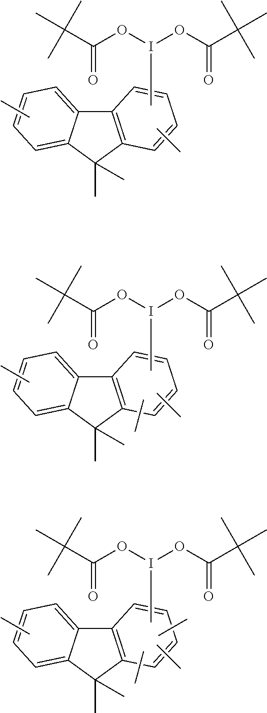

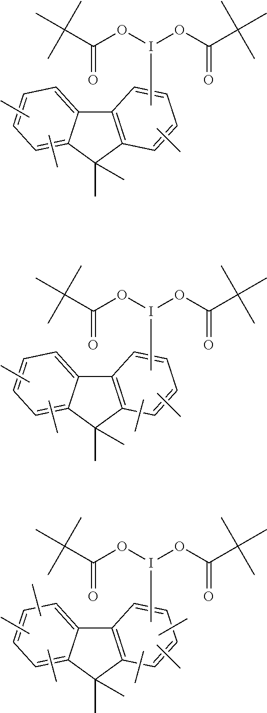

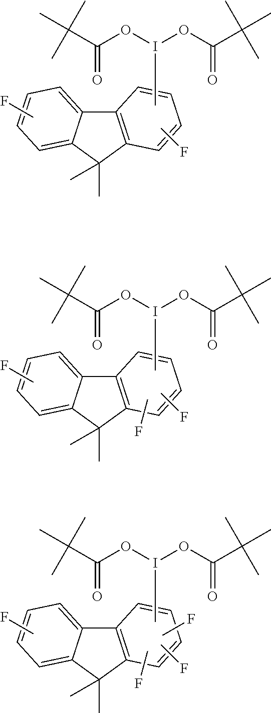

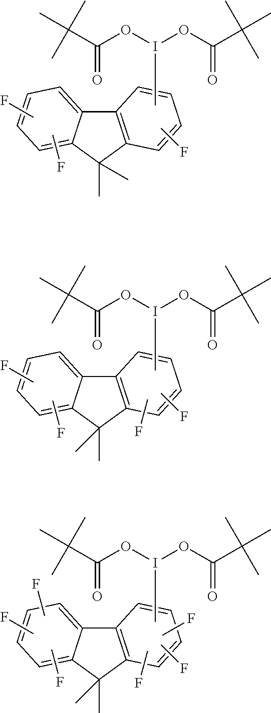

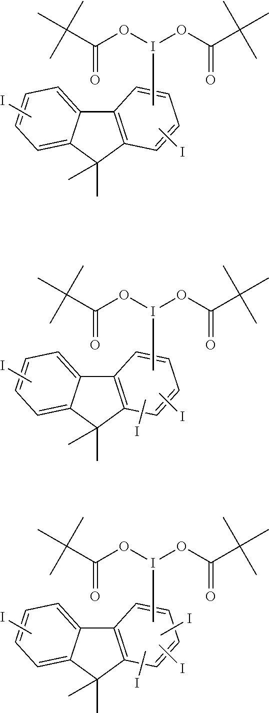

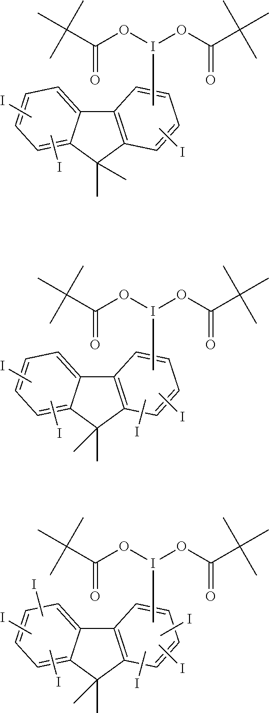

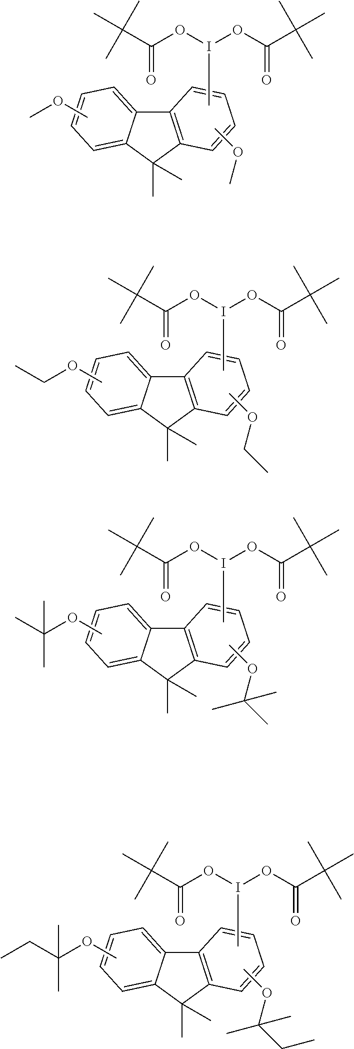

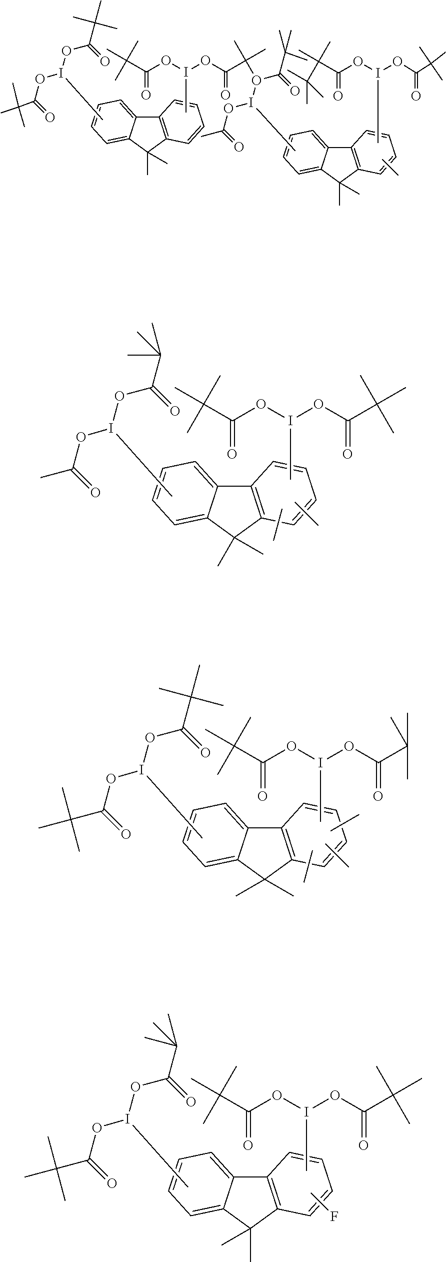

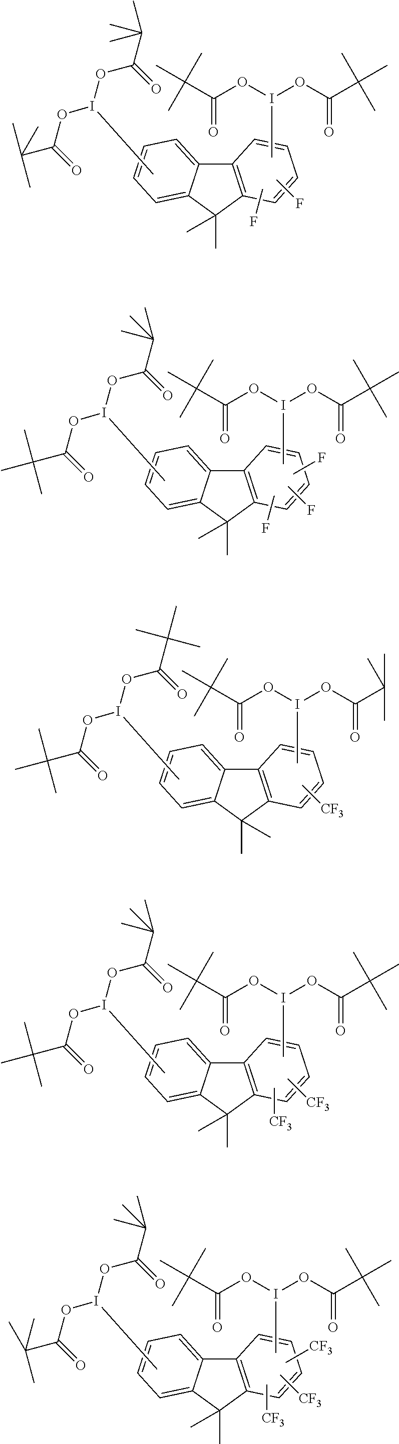

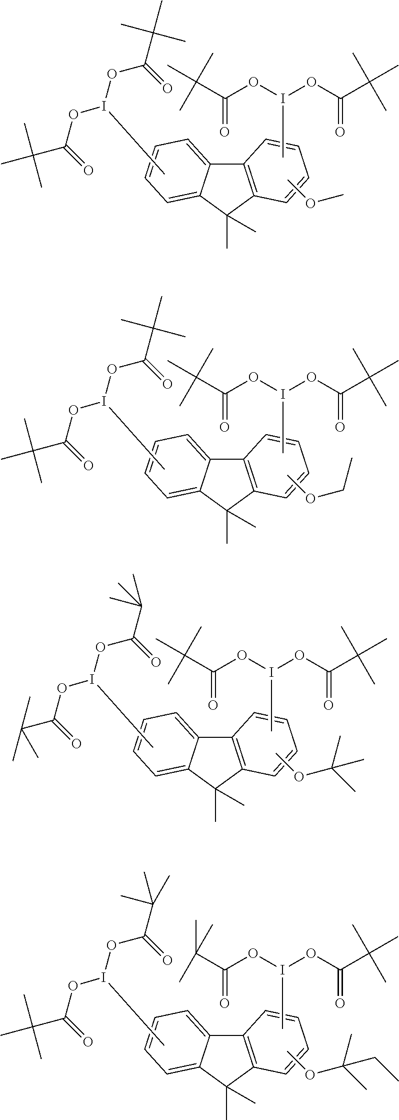

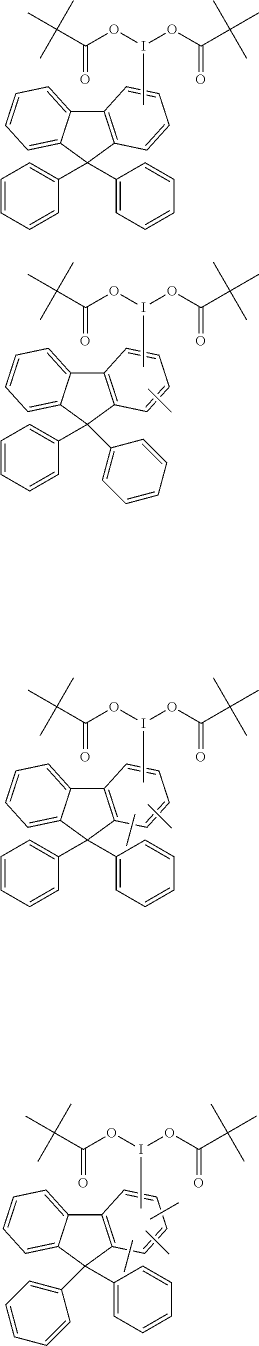

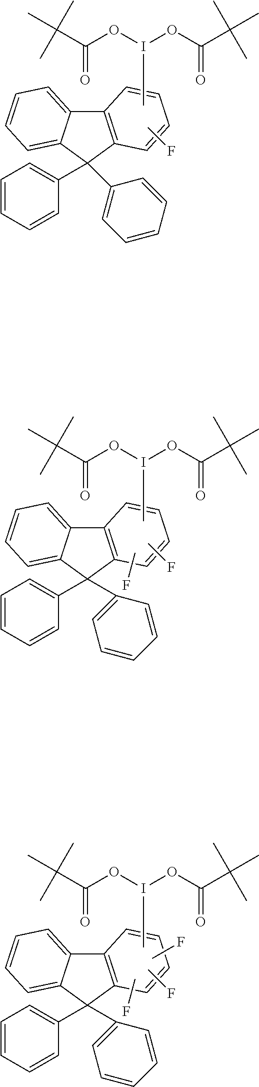

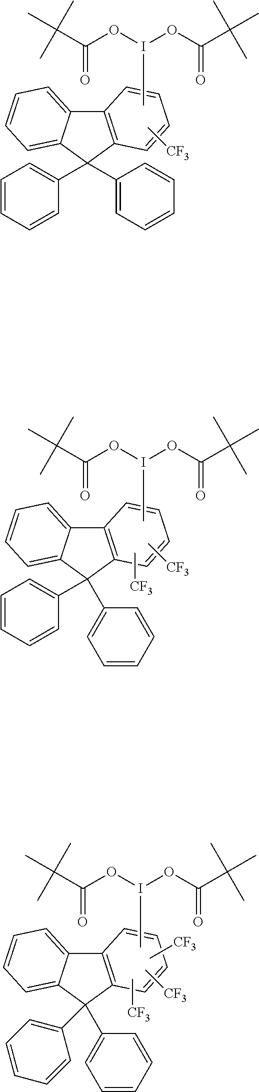

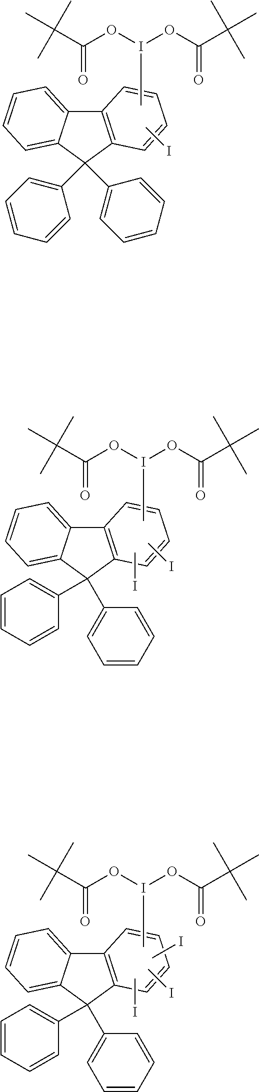

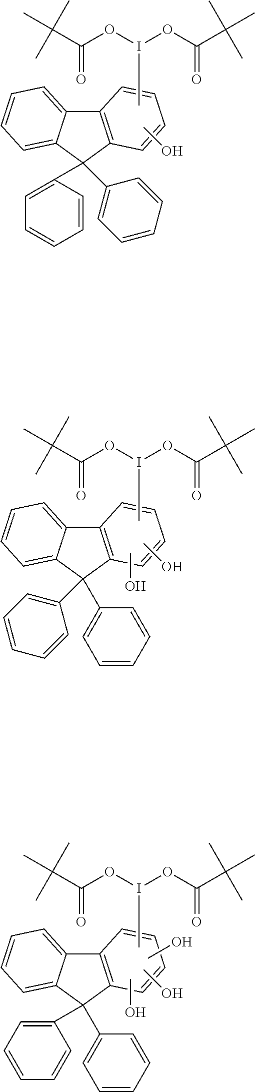

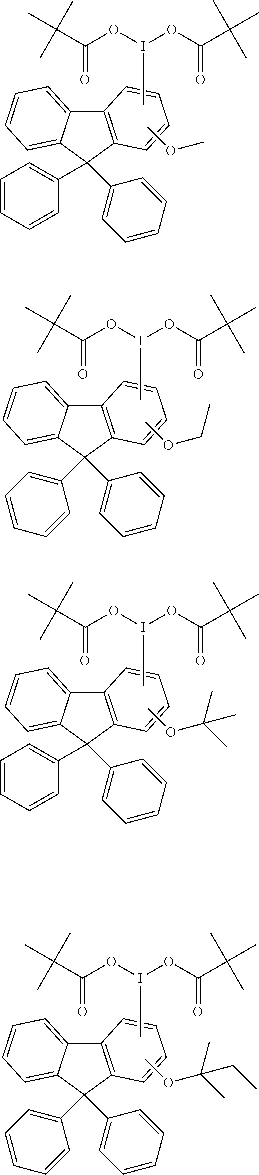

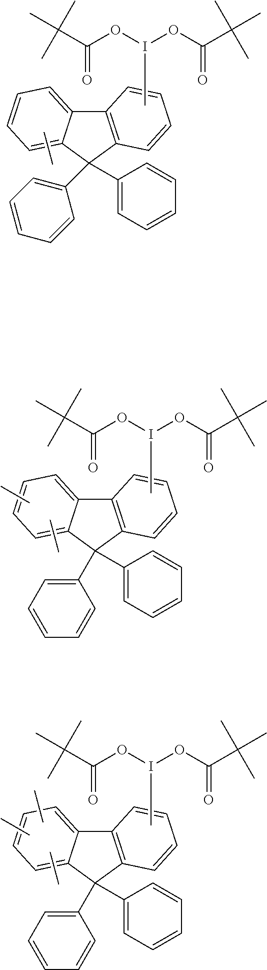

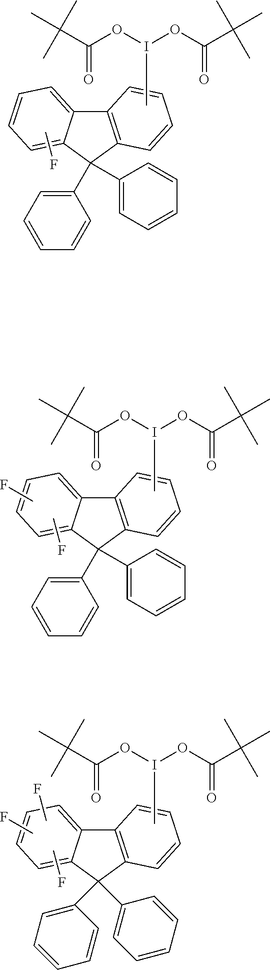

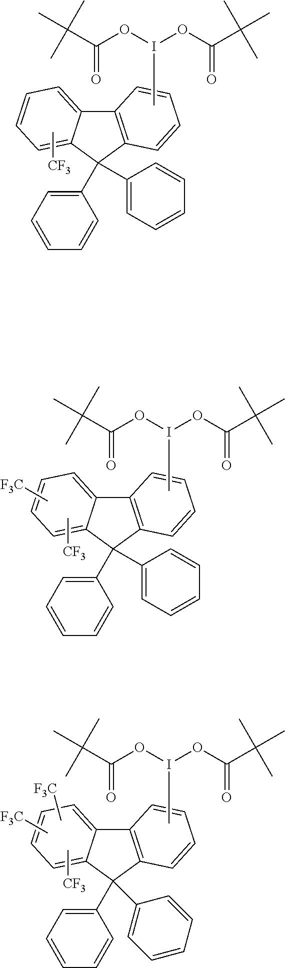

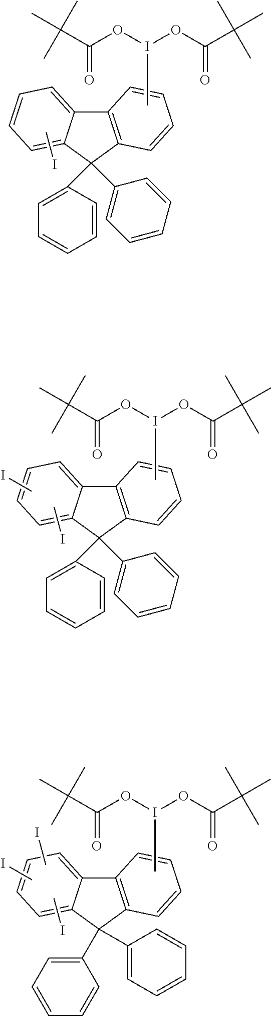

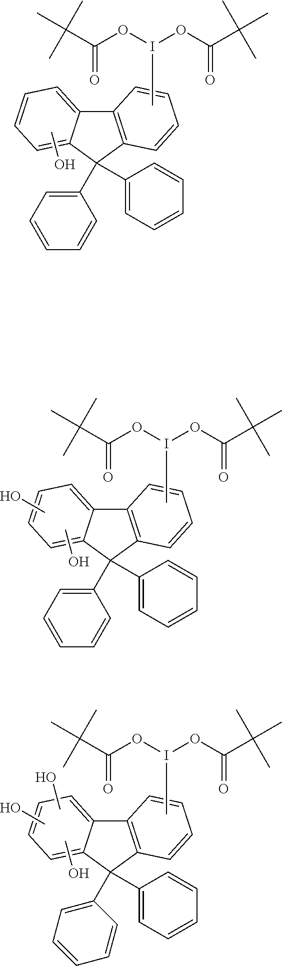

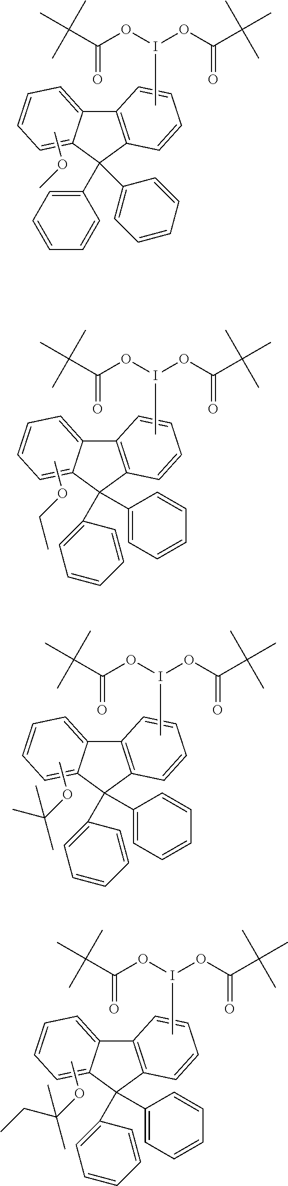

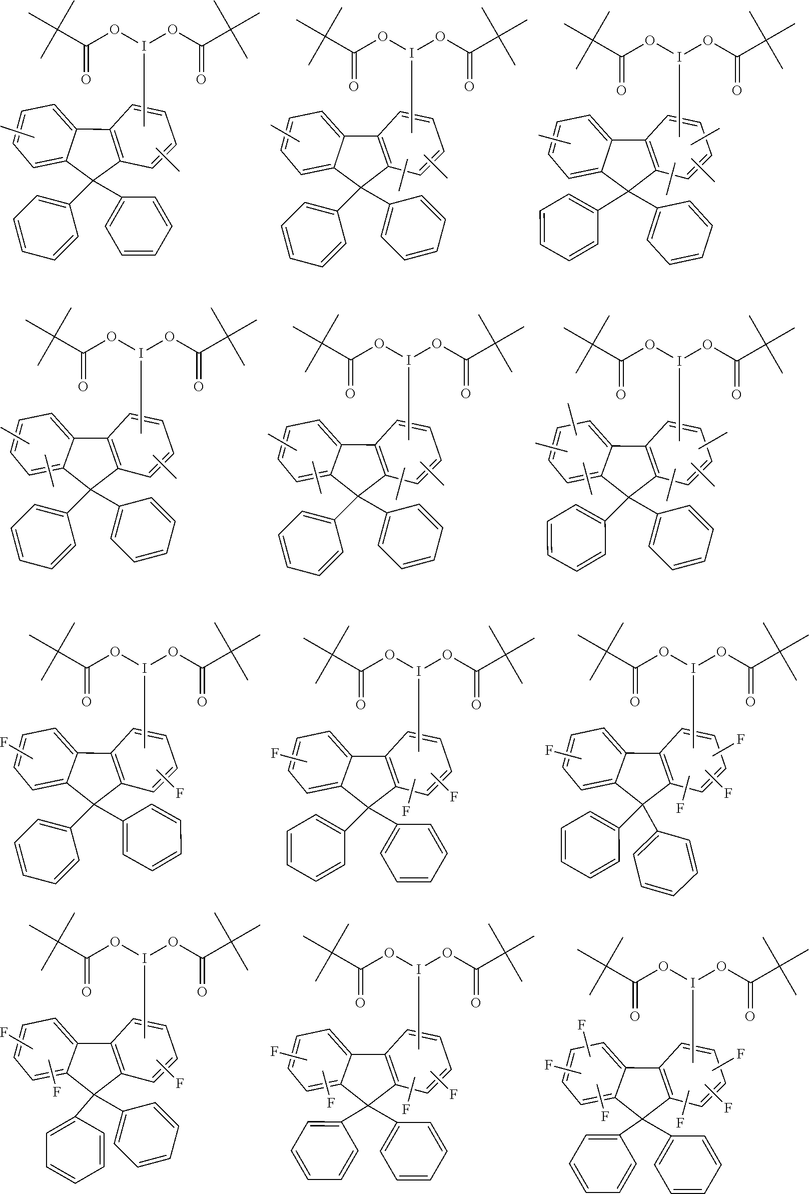

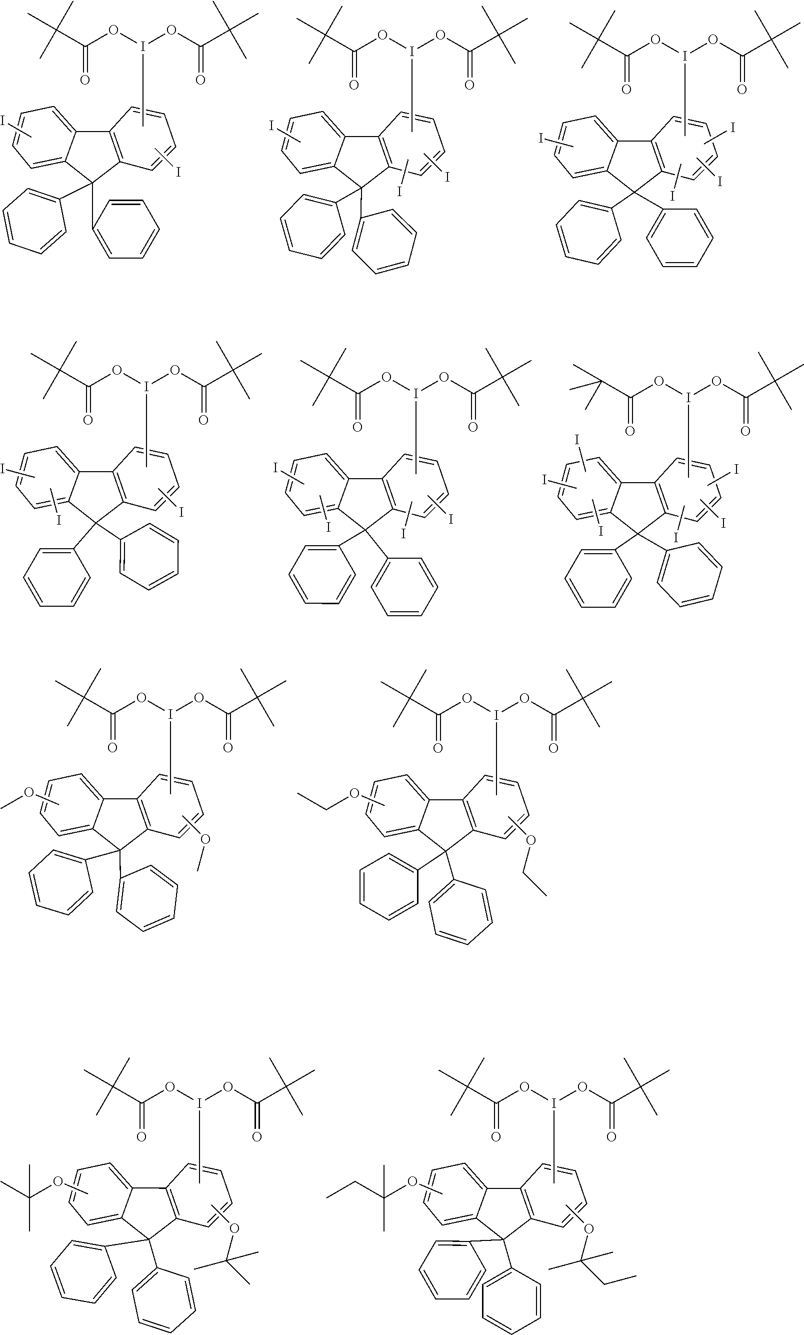

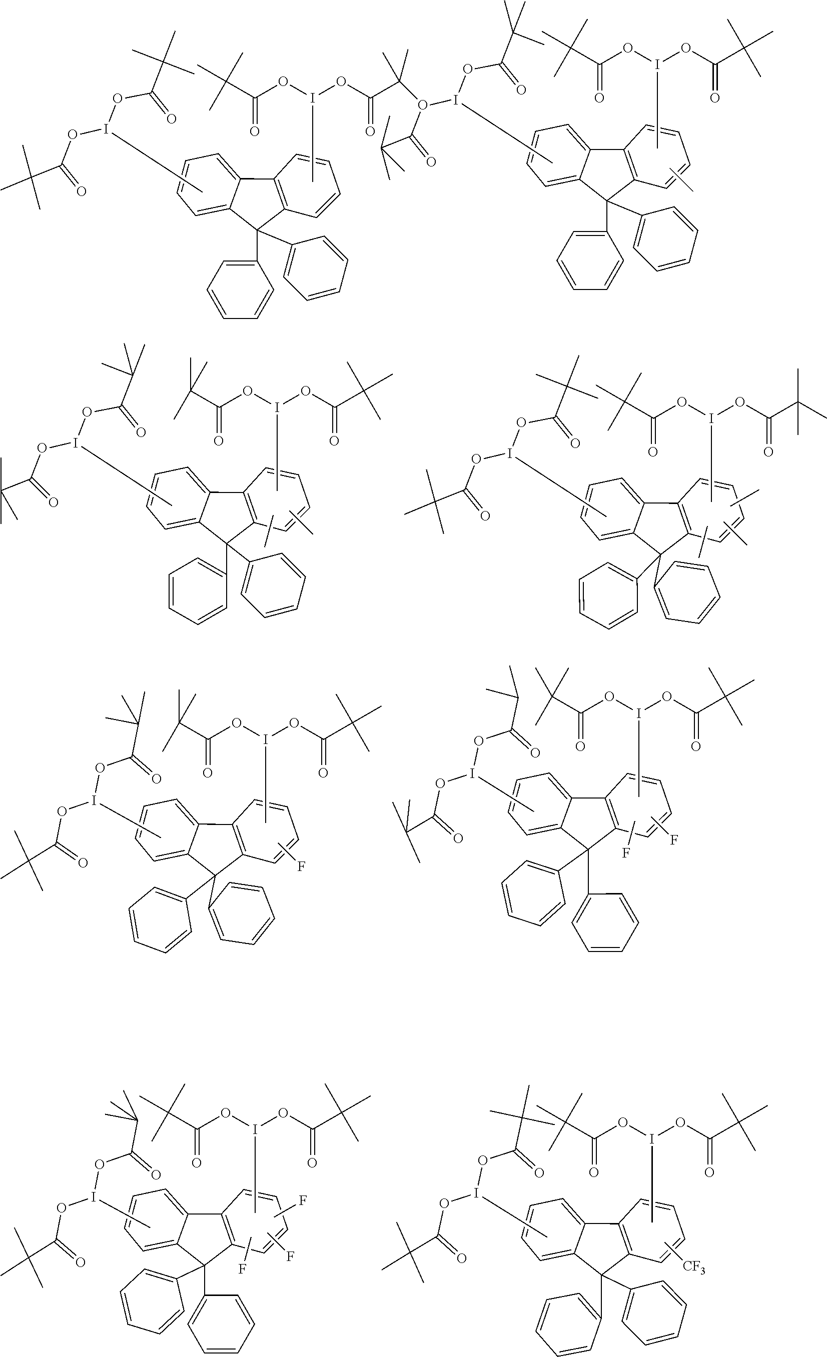

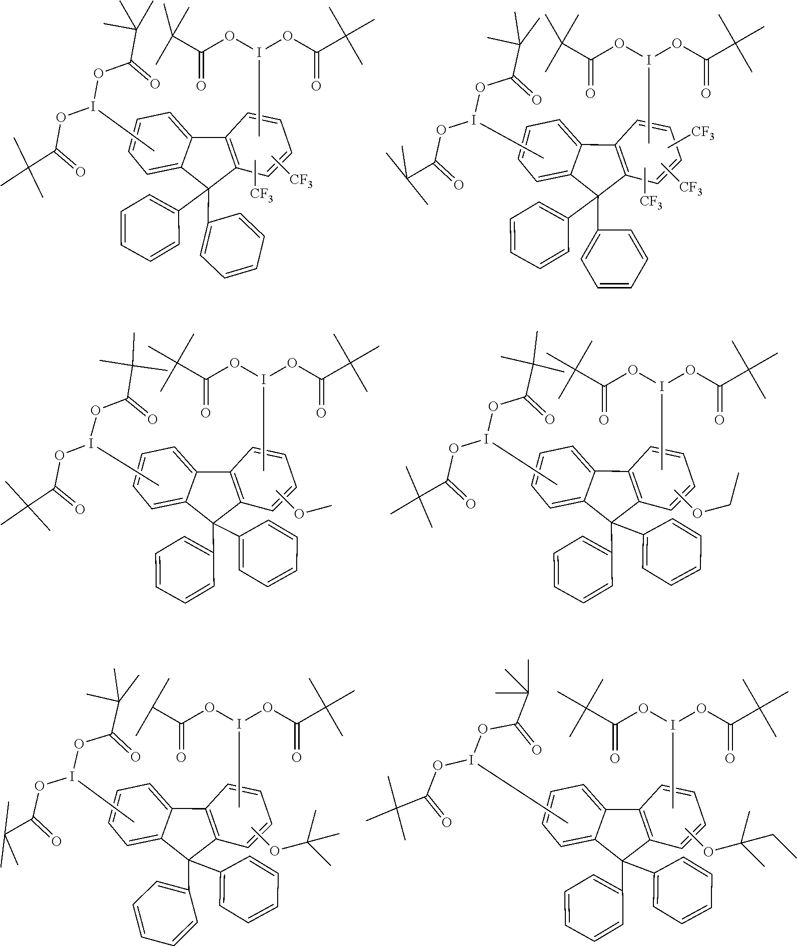

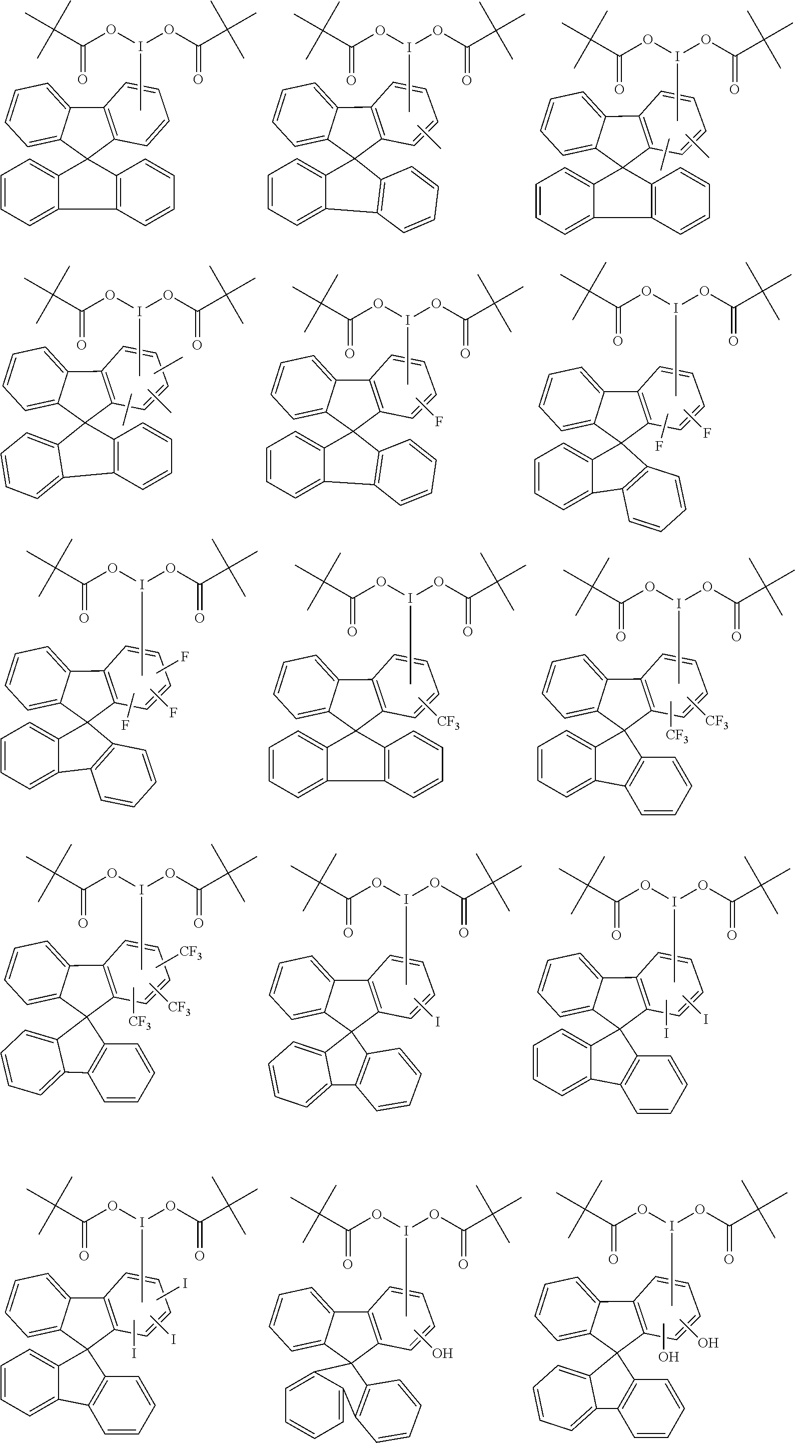

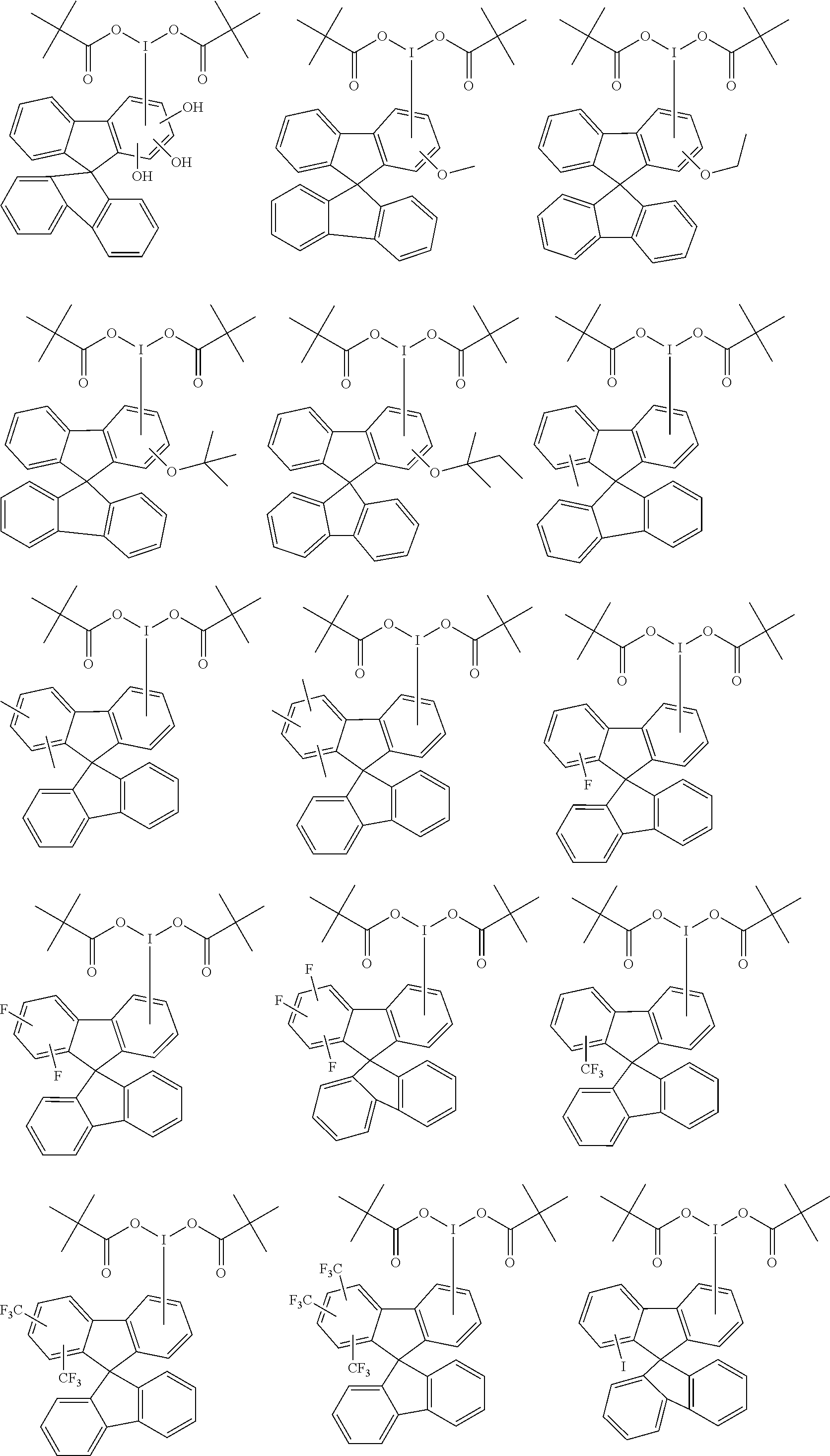

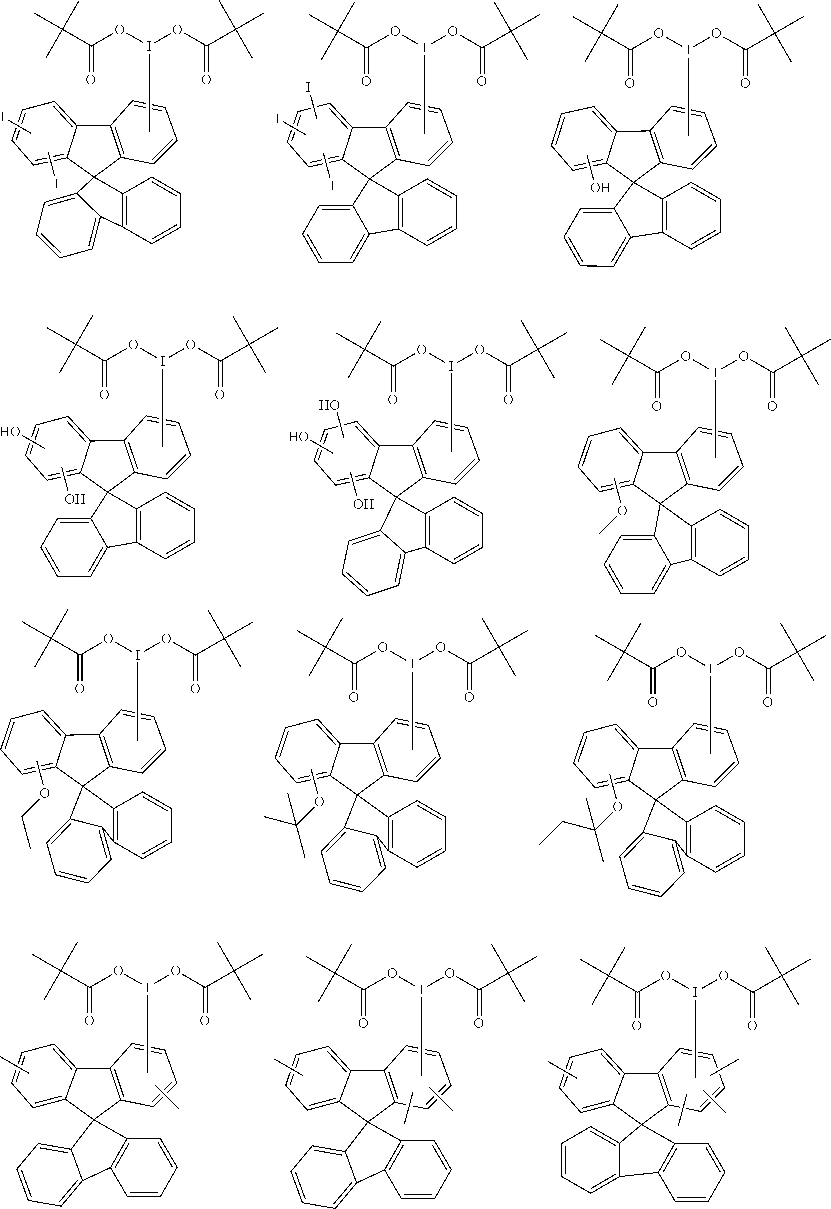

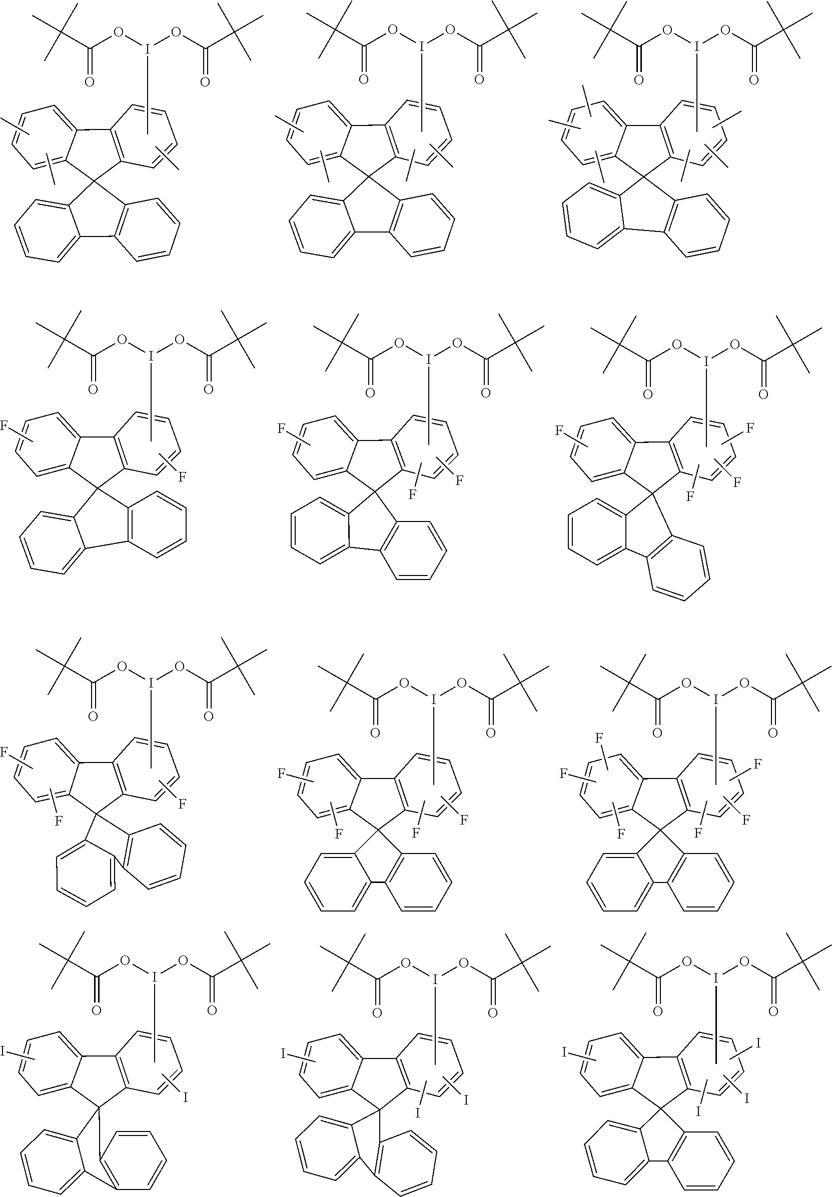

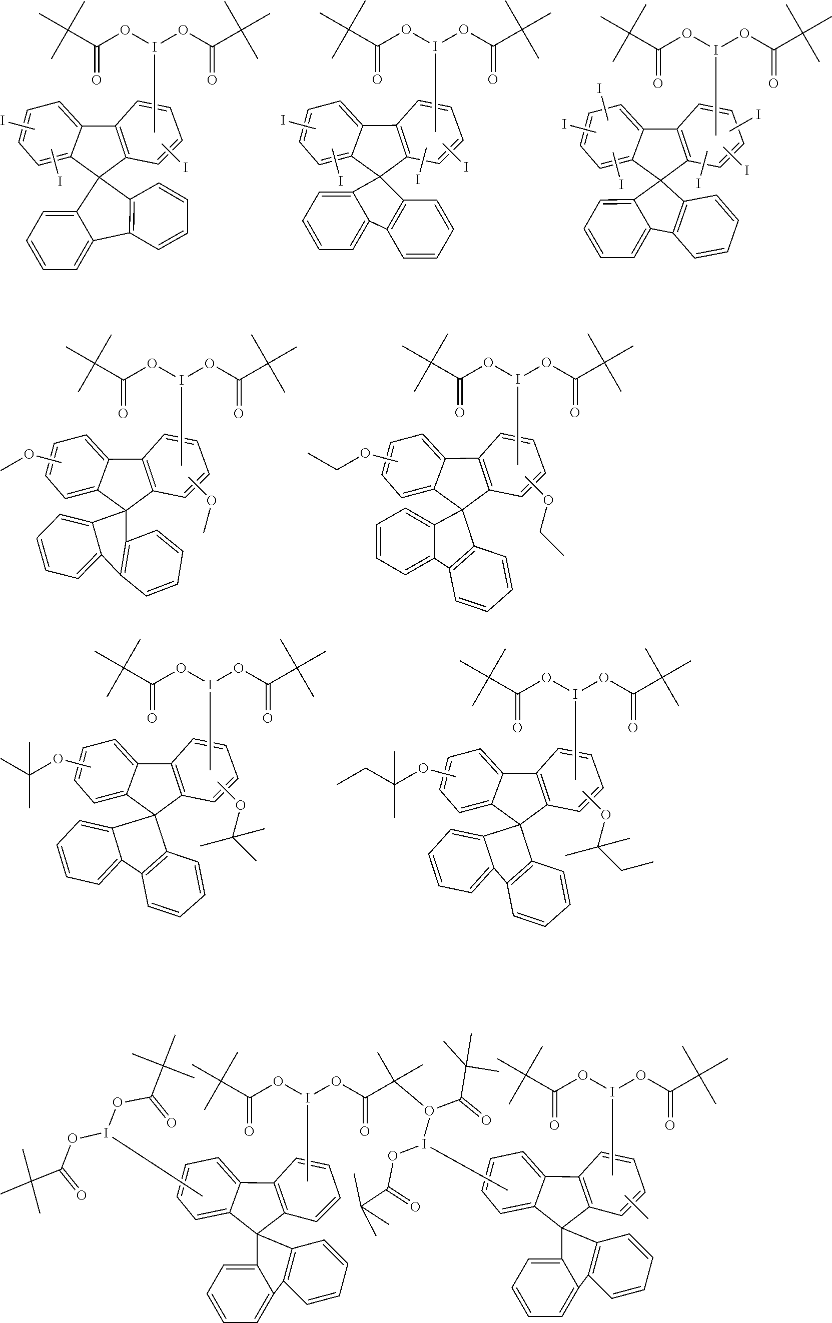

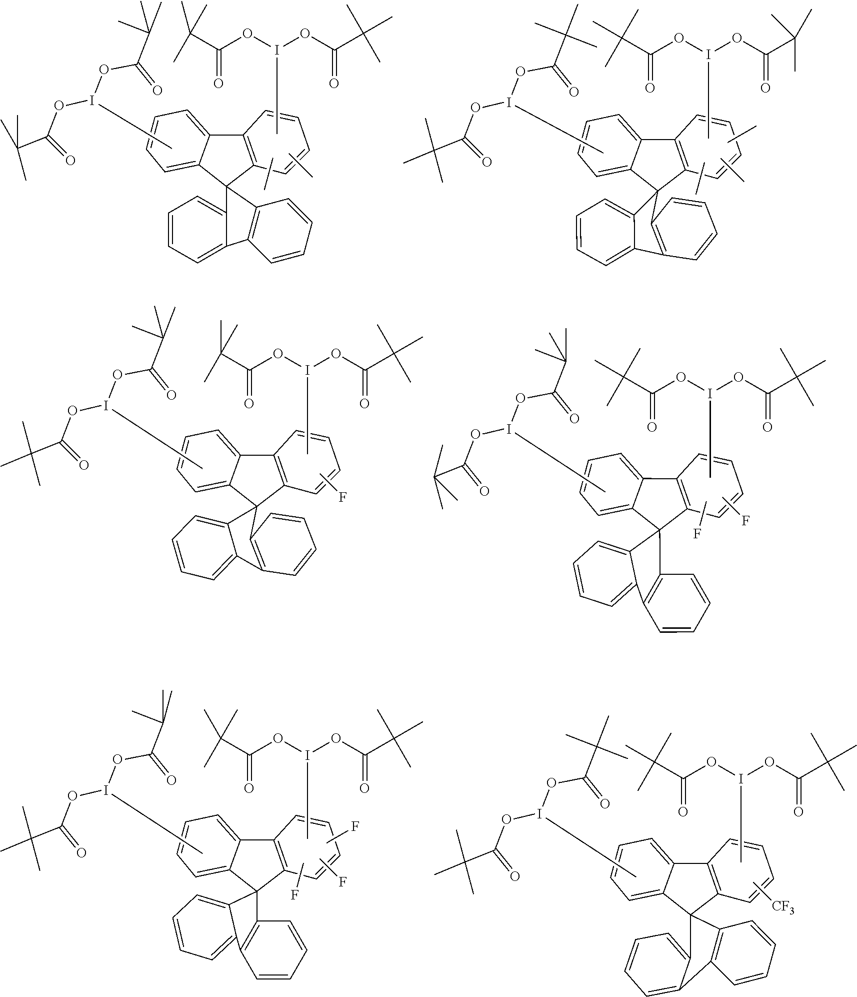

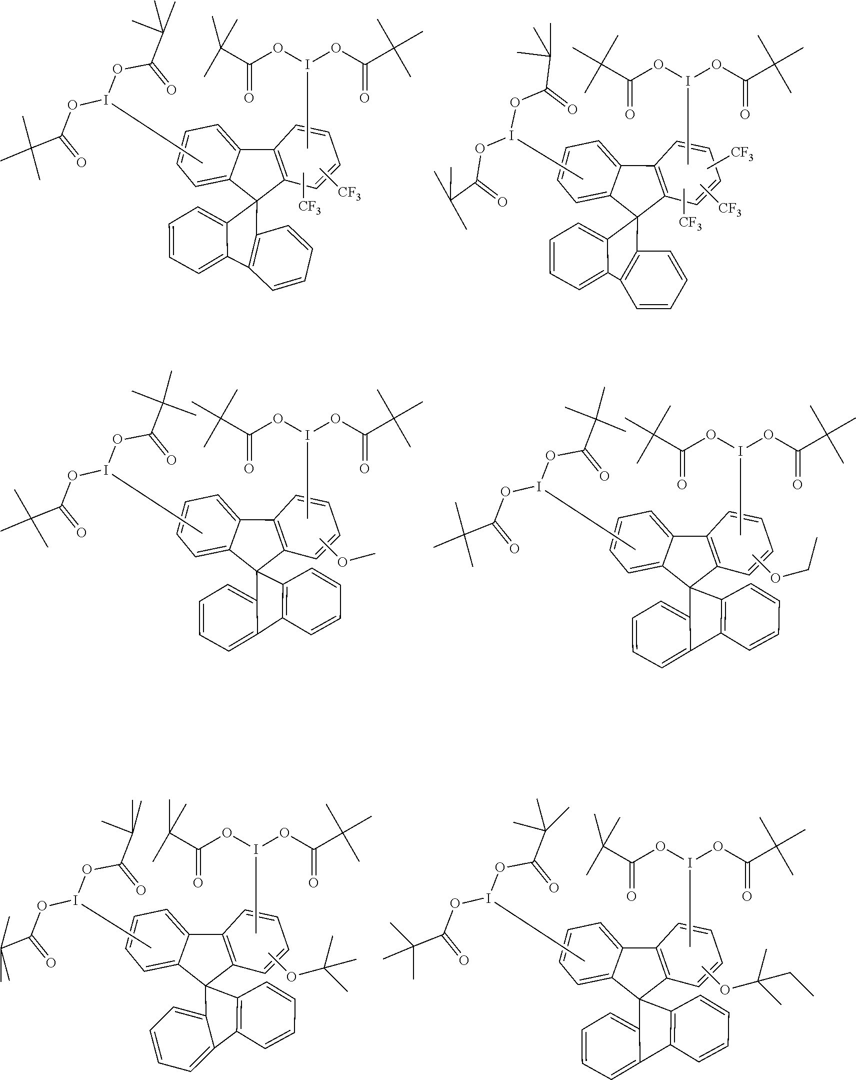

### [Carboxy-Group-Containing Compound]

As the carboxy-group-containing compound, a carboxy-group-containing polymer including a repeating unit represented by the following general formula (11) or a carboxylic acid compound represented by the following general formula (12) is preferably used.

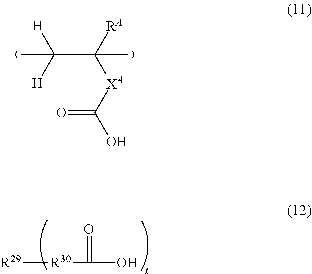

In the formulae, R^{A} represents a hydrogen atom, a halogen atom, a methyl group, or a trifluoromethyl group;
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring, and “*” represents an attachment point to the carbon atom of the main chain;
“t” represents an integer of 1 to 4;
R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, where part or all of hydrogen atoms of the t-valent hydrocarbon group or the t-valent heterocyclic group may be substituted with a group containing a heteroatom, and part of —CH₂— of the t-valent hydrocarbon group may be substituted with a group containing a heteroatom; and
R³⁰ represents a single bond or a hydrocarbylene group having 1 to 10 carbon atoms, where part or all of hydrogen atoms of the hydrocarbylene group may be substituted with a group containing a heteroatom, part of —CH₂— of the hydrocarbylene group may be substituted with a group containing a heteroatom, and when “t” is 2 to 4, the R³⁰s are identical to or different from each other.

In the general formula (11), R^{A} represents a hydrogen atom, a halogen atom, a methyl group, or a trifluoromethyl group. X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring, and “*” represents an attachment point to the carbon atom of the main chain.

In the general formula (12), “t” represents an integer of 1 to 4.

In the general formula (12), R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, where part or all of hydrogen atoms of the t-valent hydrocarbon group or the t-valent heterocyclic group may be substituted with a group containing a heteroatom, and part of —CH₂— of the t-valent hydrocarbon group may be substituted with a group containing a heteroatom.

In the general formula (12), R³⁰ represents a single bond or a hydrocarbylene group having 1 to 10 carbon atoms, where part or all of hydrogen atoms of the hydrocarbylene group may be substituted with a group containing a heteroatom, part of —CH₂— of the hydrocarbylene group may be substituted with a group containing a heteroatom, and when “t” is 2 to 4, the R³⁰s are identical to or different from each other.

The t-valent hydrocarbon group represented by R²⁹ may be saturated or unsaturated, and may be linear, branched, or cyclic. The t-valent hydrocarbon group is a hydrocarbon from which “t” hydrogen atoms are removed. Examples of the hydrocarbon include alkanes having 1 to 40 carbon atoms, alkenes having 2 to 40 carbon atoms, alkynes having 2 to 40 carbon atoms, cyclic saturated hydrocarbons having 3 to 40 carbon atoms, cyclic unsaturated hydrocarbons having 3 to 40 carbon atoms, and aromatic hydrocarbons having 6 to 40 carbon atoms.

Examples of the alkanes having 1 to 40 carbon atoms include methane, ethane, propane, butane, pentane, hexane, heptane, octane, nonane, decane, and structural isomers thereof.

Examples of the alkenes having 2 to 40 carbon atoms include ethylene, propylene, butene, pentene, hexene, heptene, octene, nonene, decene, and structural isomers thereof.

Examples of the alkynes having 2 to 40 carbon atoms include acetylene, propyne, butyne, pentyne, hexyne, heptyne, octyne, nonyne, decyne, and structural isomers thereof.

Examples of the cyclic saturated hydrocarbons having 3 to 40 carbon atoms include cyclopropane, cyclobutane, cyclohexane, cycloheptane, cyclooctane, adamantane, and norbornane.

Examples of the cyclic unsaturated hydrocarbons having 3 to 40 carbon atoms include cyclopropene, cyclobutene, cyclopentene, cyclohexene, cycloheptene, cyclooctene, and norbornene.

Examples of the aromatic hydrocarbons having 6 to 40 carbon atoms include benzene, naphthalene, and biphenyl.

The t-valent heterocyclic group represented by R²⁹ is a group which is obtained by removing “t” hydrogen atoms from a heterocyclic compound. Examples of the heterocyclic compound include furan, pyridine, pyrazole, and thiazolidine.

Part or all of the hydrogen atoms of the t-valent hydrocarbon group or the t-valent heterocyclic group may be substituted with a group containing a heteroatom such as an oxygen atom, a sulfur atom, a nitrogen atom, or a halogen atom. The resulting t-valent hydrocarbon group or t-valent heterocyclic group may contain a hydroxy group, a cyano group, a fluorine atom, a chlorine atom, a bromine atom, an iodine atom, etc. Furthermore, part of the —CH₂— constituting the t-valent hydrocarbon group may be substituted with a group containing a heteroatom such as an oxygen atom, a sulfur atom, or a nitrogen atom. The resulting t-valent hydrocarbon group may contain a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc.

The hydrocarbylene group represented by R³⁰ may be saturated or unsaturated, and may be linear, branched, or cyclic. Specific examples thereof include: alkanediyl groups having 1 to 20 carbon atoms, such as a methanediyl group, an ethane-1,1-diyl group, an ethane-1,2-diyl group, a propane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, and a dodecane-1,12-diyl group; cyclic saturated hydrocarbylene groups having 3 to 20 carbon atoms, such as a cyclopentanediyl group, a cyclohexanediyl group, a norbornanediyl group, and an adamantanediyl group; unsaturated aliphatic hydrocarbylene groups having 2 to 20 carbon atoms, such as a vinylene group and a propene-1,3-diyl group; arylene groups having 6 to 20 carbon atoms, such as a phenylene group and a naphthylene group; and groups which are combinations of these groups. Furthermore, part or all of the hydrogen atoms of the hydrocarbylene group may be substituted with a group containing a heteroatom, such as an oxygen atom, a sulfur atom, a nitrogen atom, or a halogen atom, and part of the —CH₂— constituting the hydrocarbylene group may be substituted with a group containing a heteroatom such as an oxygen atom, a sulfur atom, or a nitrogen atom. The resulting hydrocarbylene group may contain a hydroxy group, a cyano group, a fluorine atom, a chlorine atom, a bromine atom, an iodine atom, a carbonyl group, an ether bond, a thioether bond, an ester bond, a sulfonic acid ester bond, a carbonate bond, a carbamate bond, a lactone ring, a sultone ring, a carboxylic anhydride, etc.

Among the carboxylic acid compounds represented by the general formula (12), those in which “t” is 2, 3, or 4 are preferable. In this case, it is easier to form a strong, high-molecular-weight resist film when mixed with a hypervalent iodine compound, and such a case is preferable from the viewpoint of etching resistance and developer resistance.

Specific examples of the carboxy-group-containing polymer including the repeating unit represented by the general formula (11) include the following, but are not limited thereto. Note that, in the following formulae, R^{A} is as defined above.

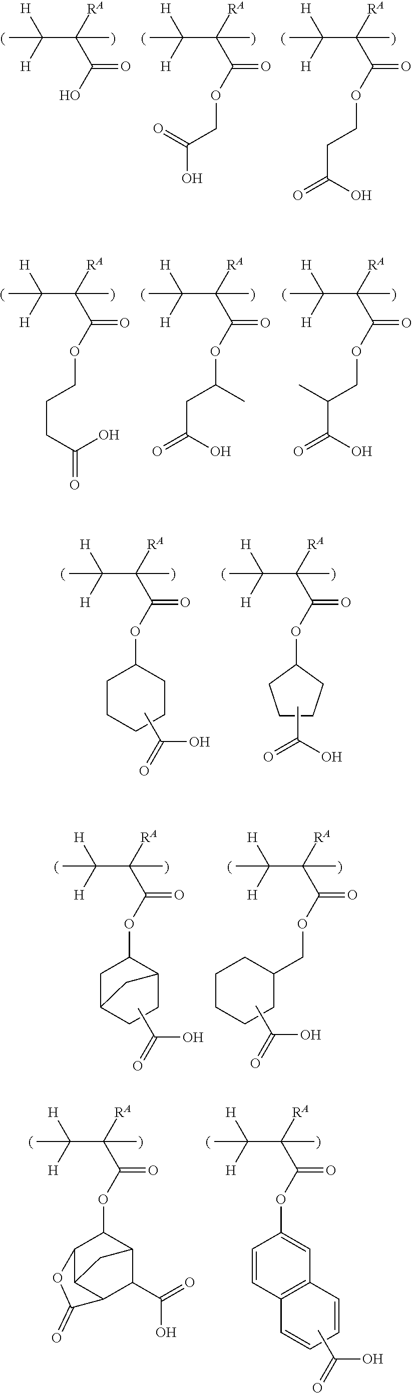

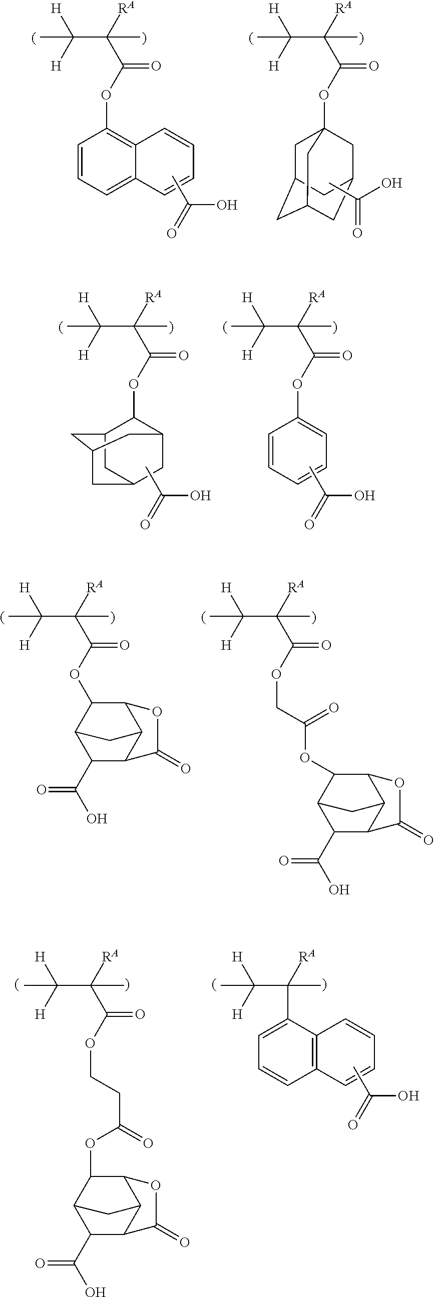

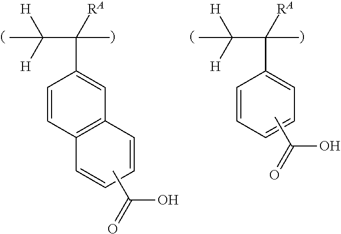

Examples of the carboxylic acid compound represented by the general formula (12) include the following, but are not limited thereto.

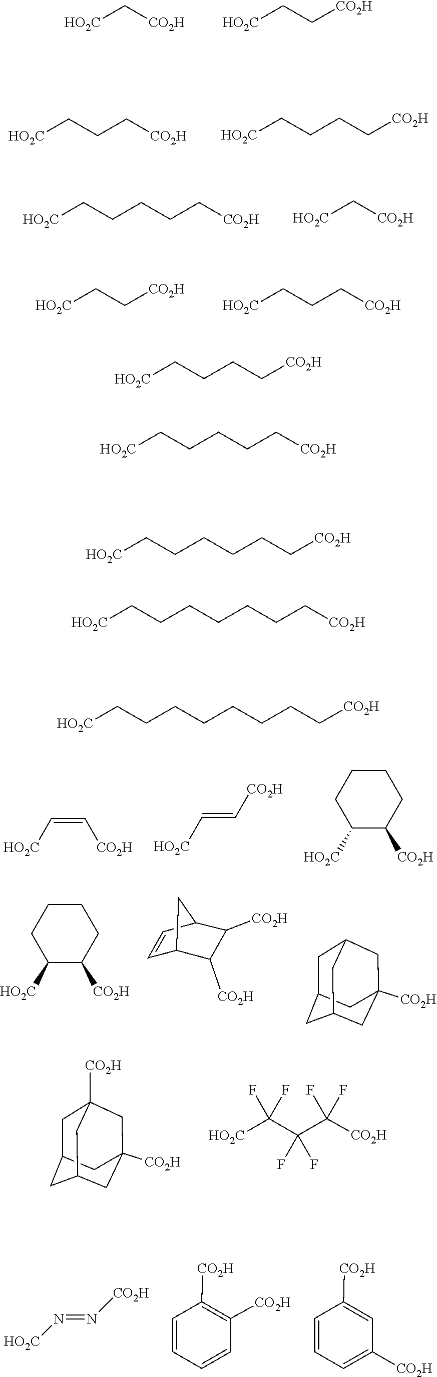

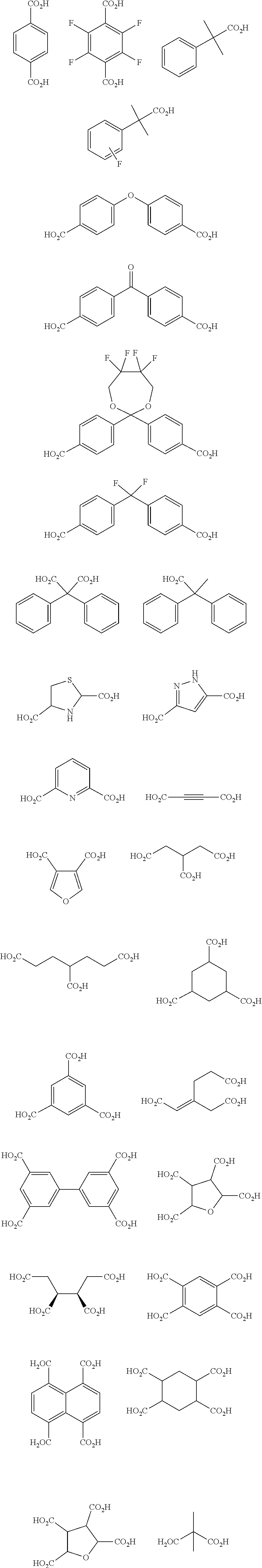

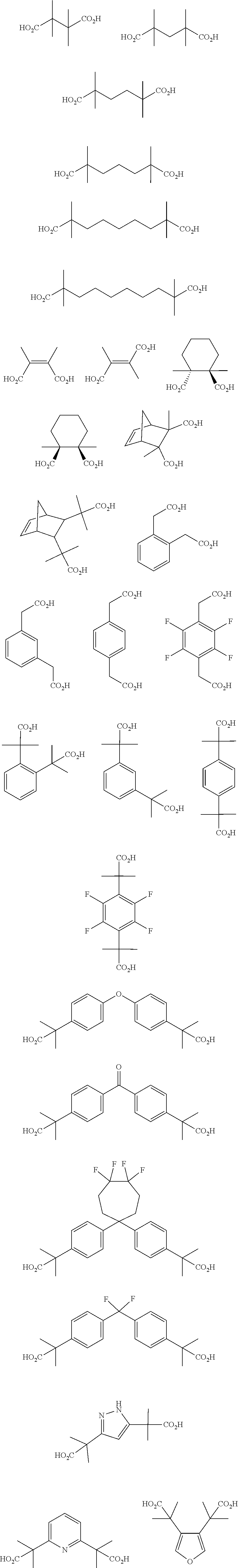

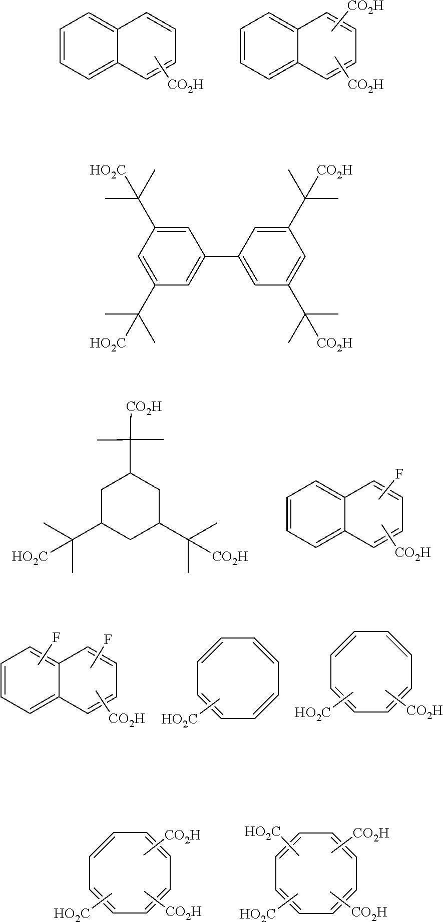

The carboxy-group-containing polymer including the repeating unit represented by the general formula (11) may further include repeating units (hereinafter, also referred to as other repeating units) other than the repeating unit represented by the general formula (11). The other repeating units are not particularly limited, but preferable are those that may enhance the solubility of the polymer, being hardly soluble when having only the repeating unit represented by the general formula (11), in a solvent. As the other repeating units, repeating units having a cyclic structure and repeating units including a styrene skeleton, the units having a rigid skeleton and being expected to have high etching resistance, are preferable.

Specific examples of the other repeating units include the following, but are not limited thereto. Note that, in the following formulae, R^{A} is as defined above and each X^{B} independently represents —CH₂— or —O—.

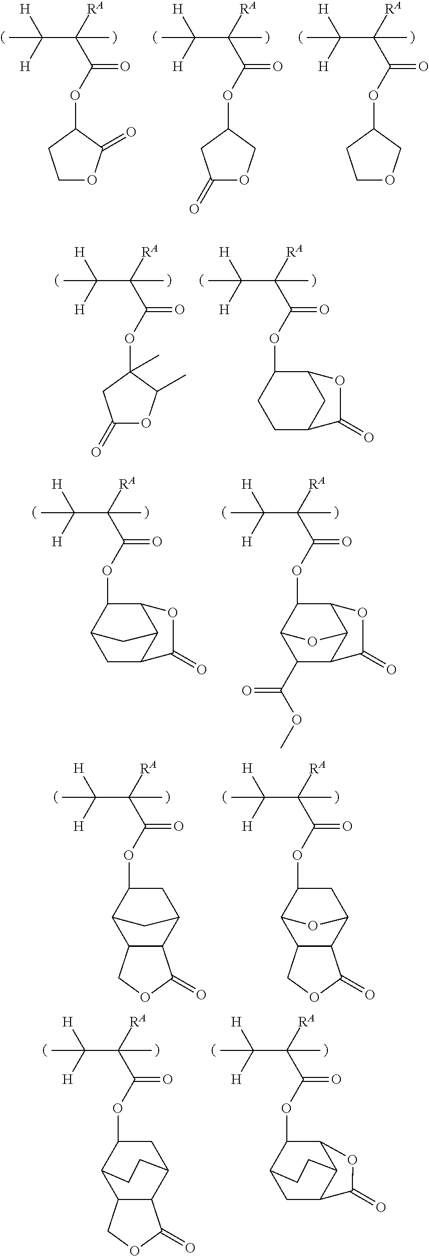

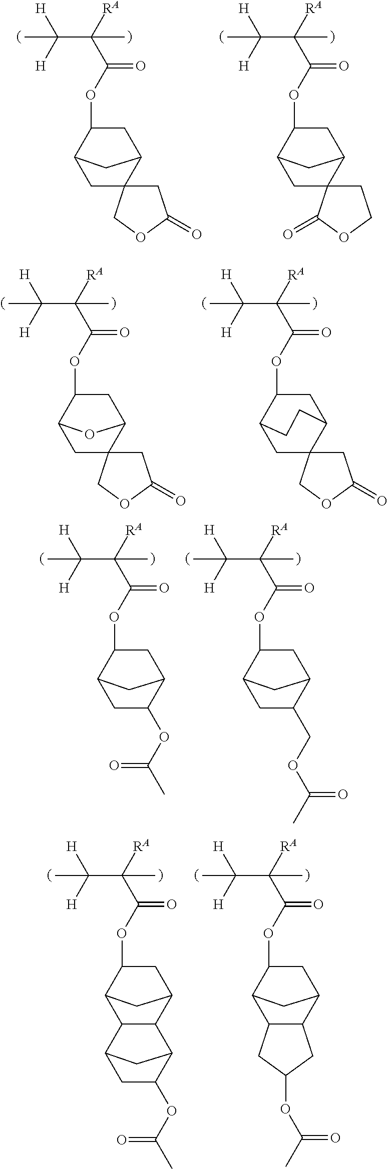

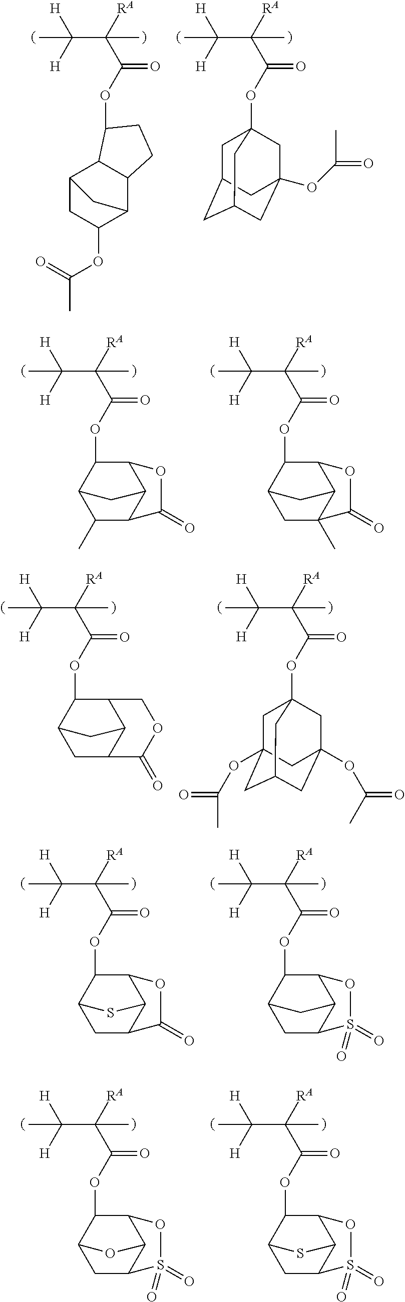

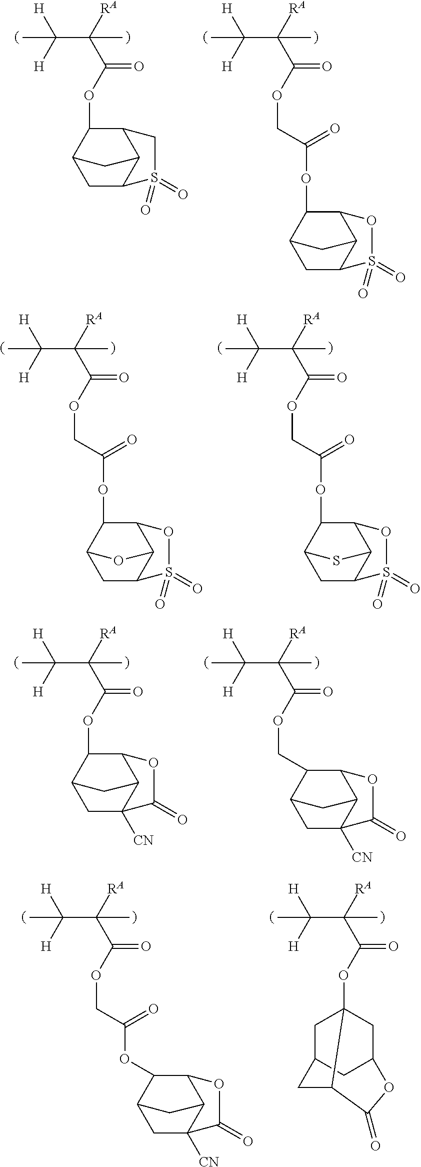

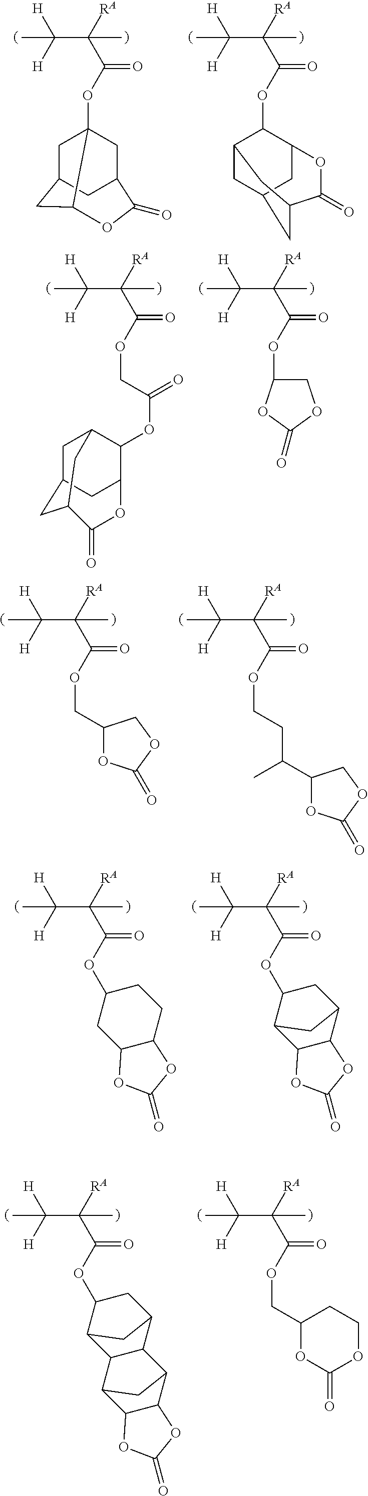

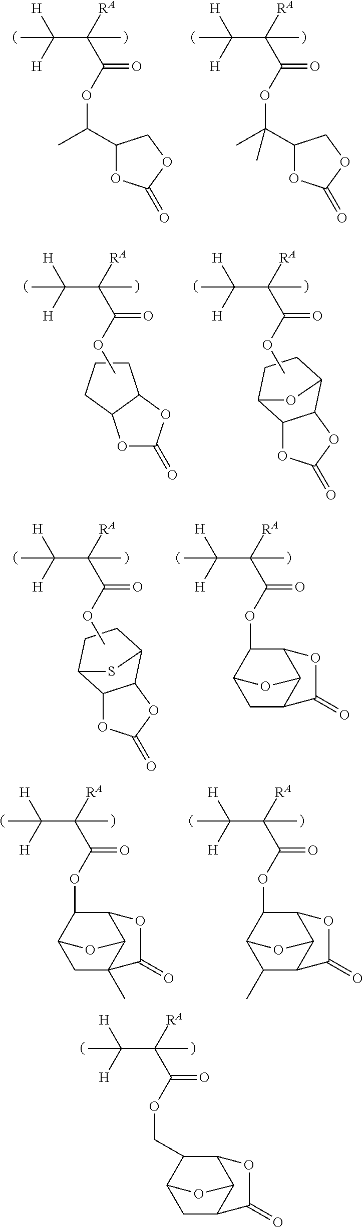

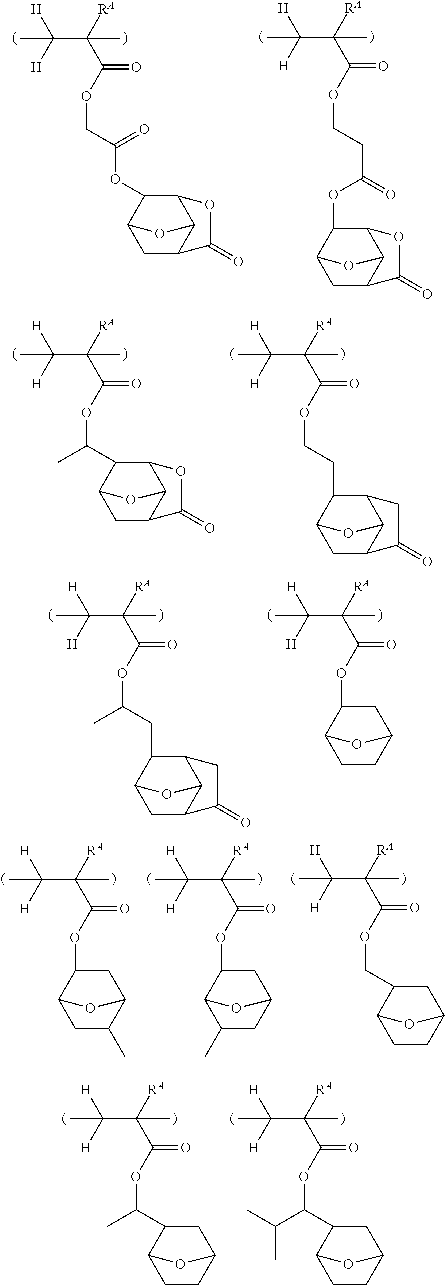

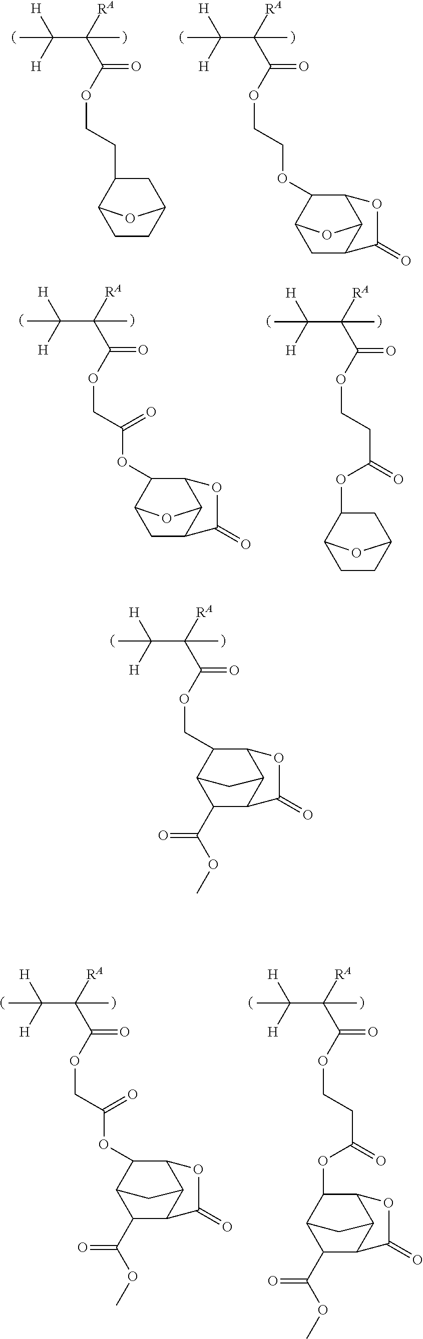

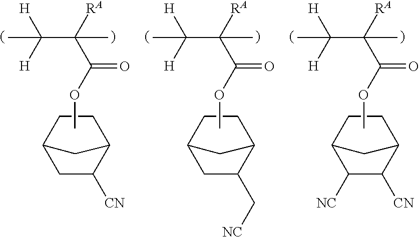

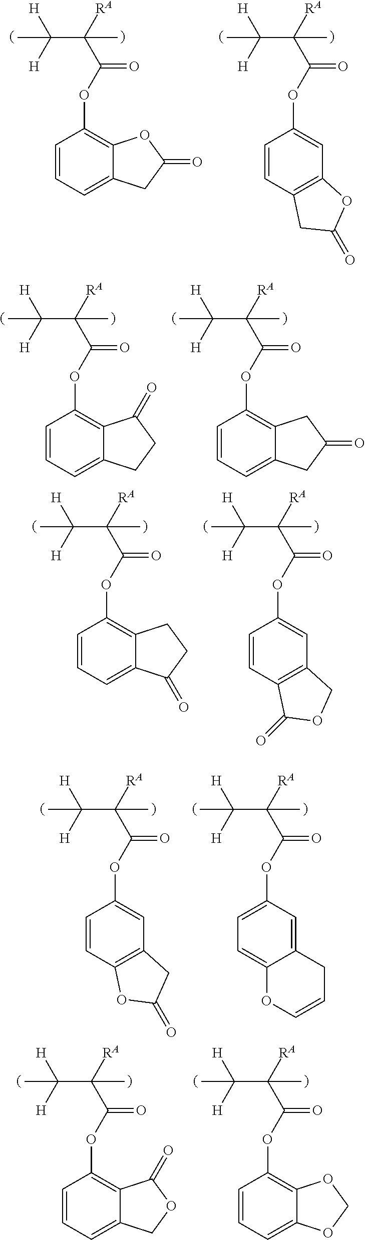

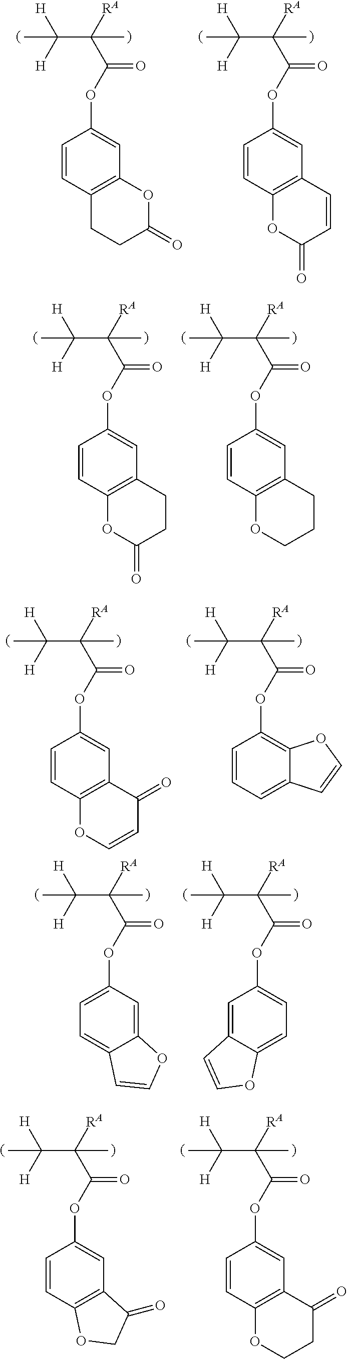

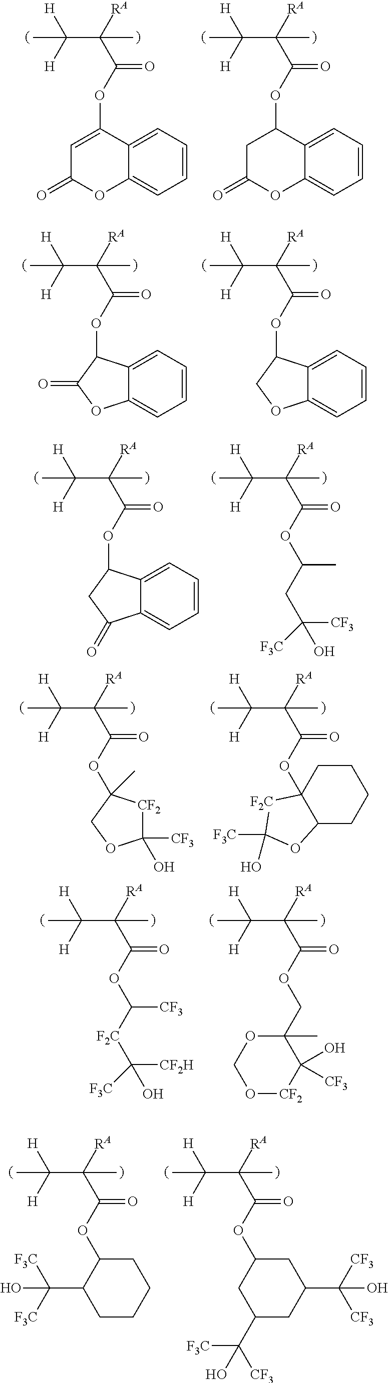

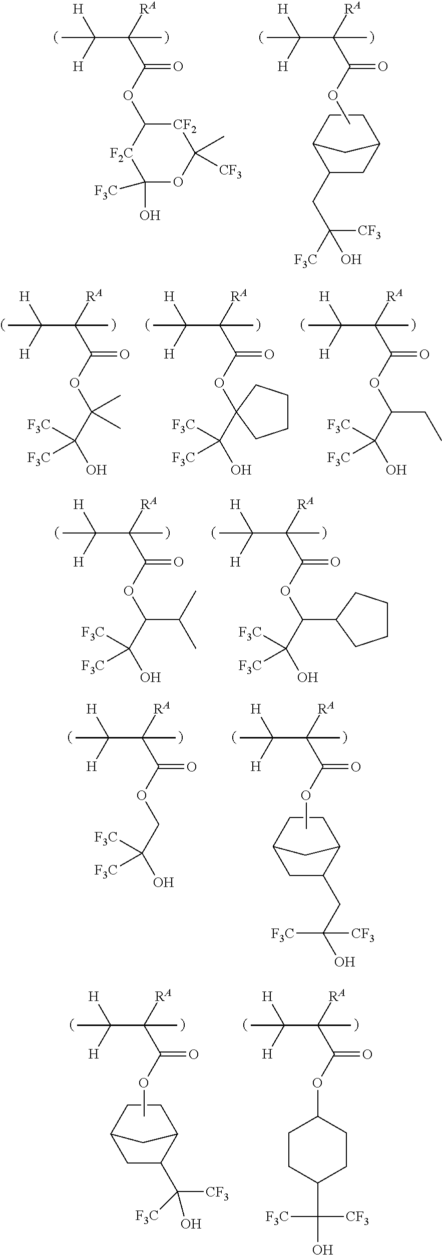

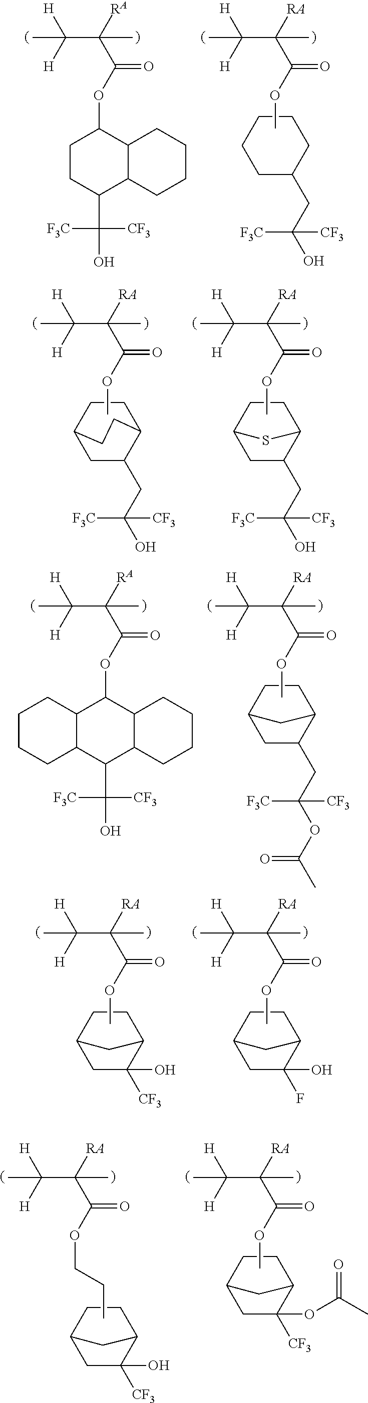

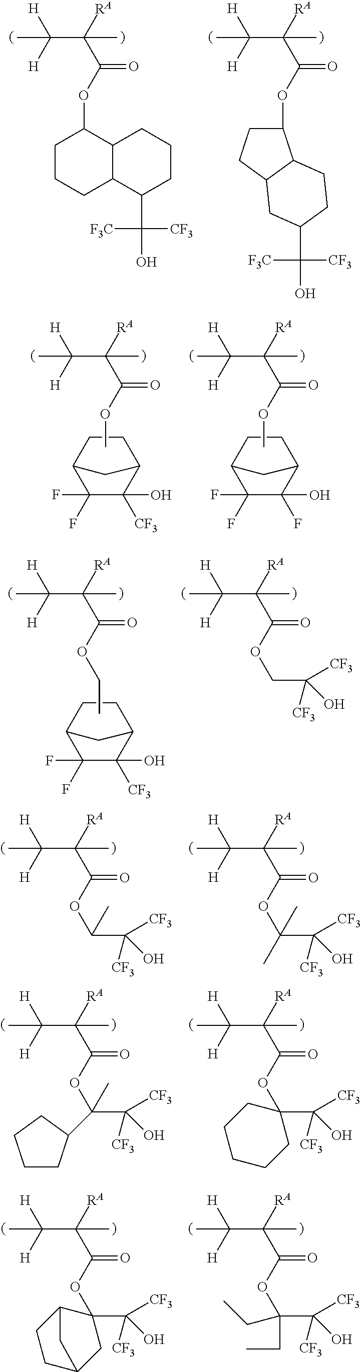

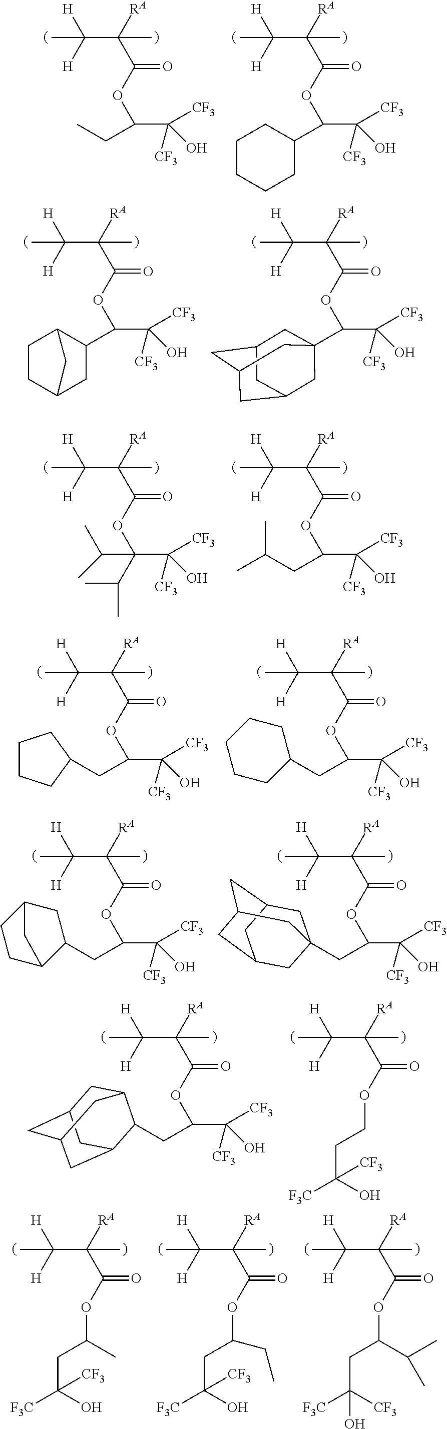

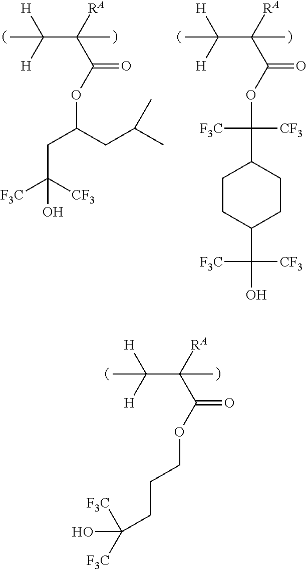

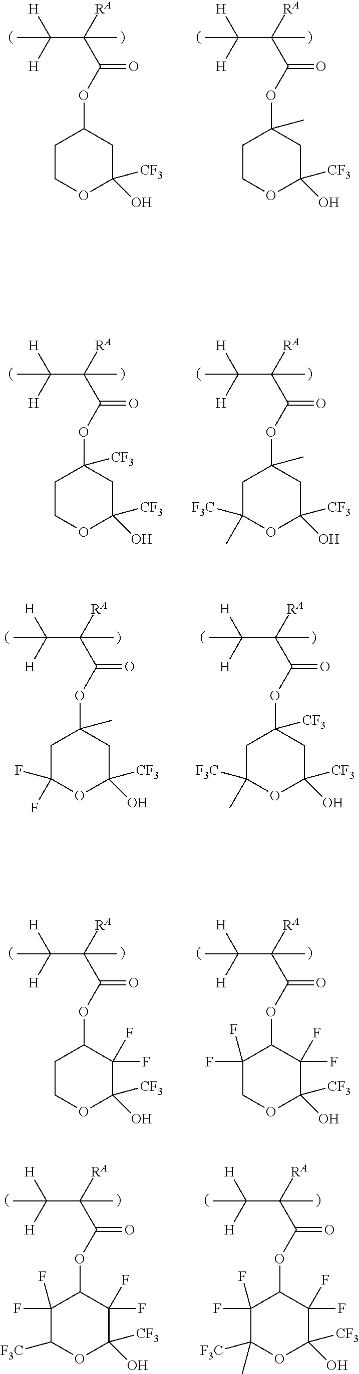

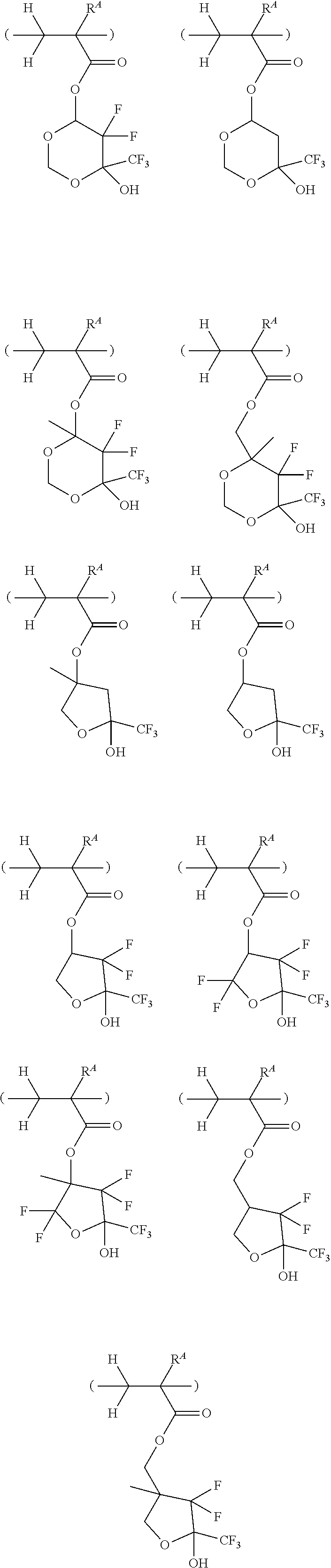

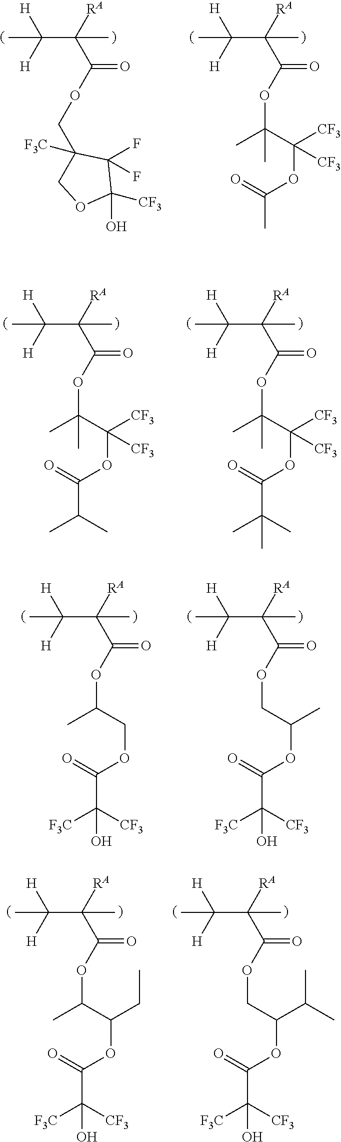

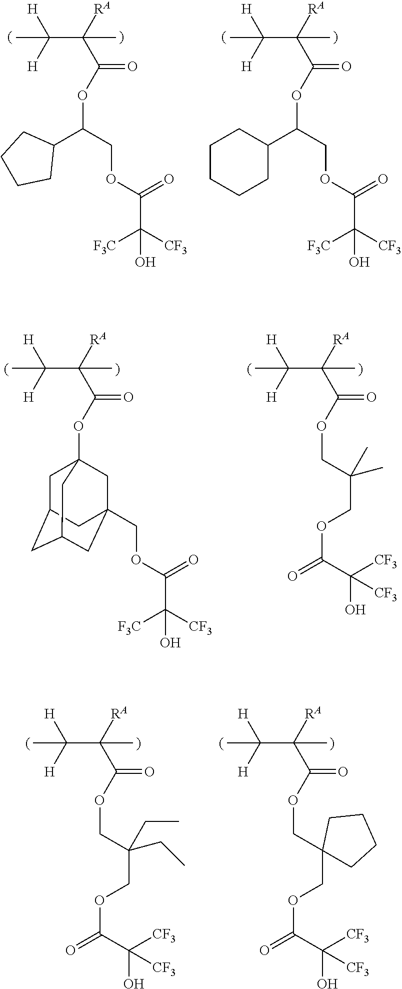

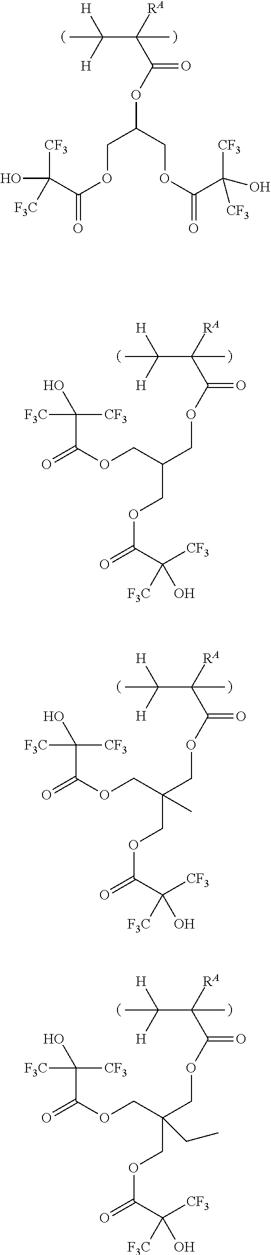

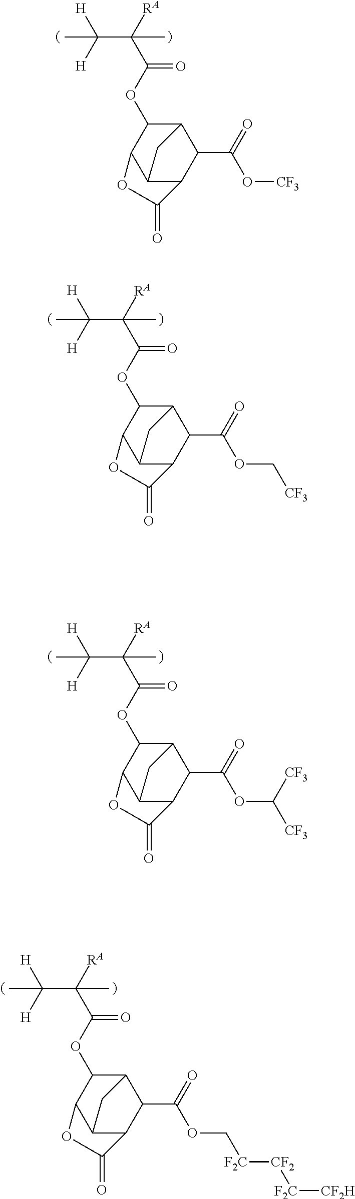

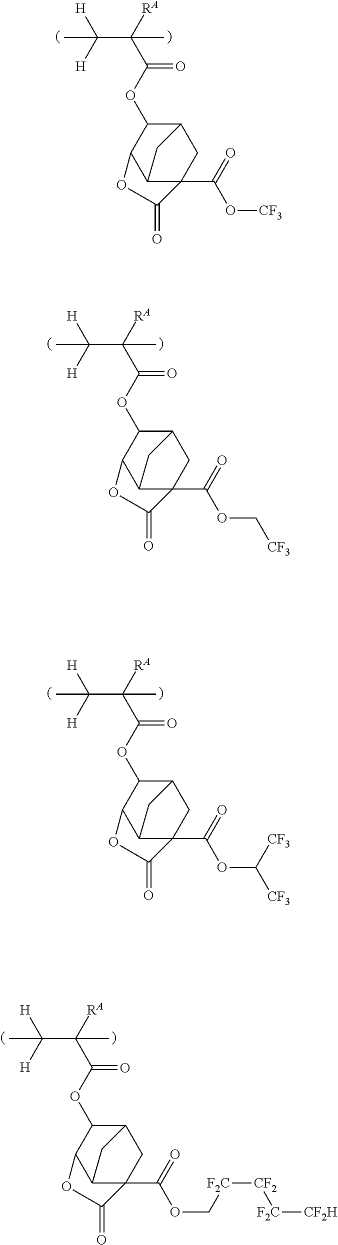

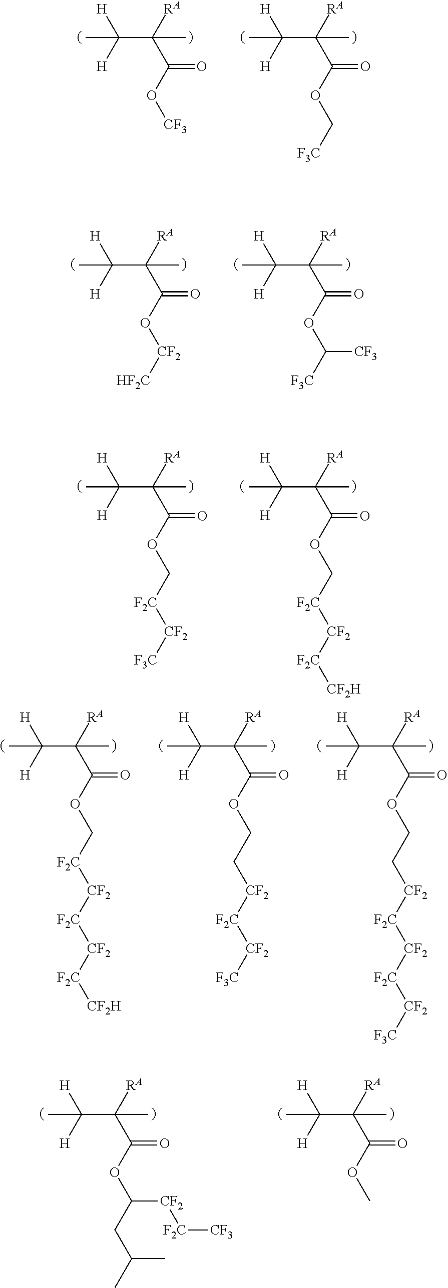

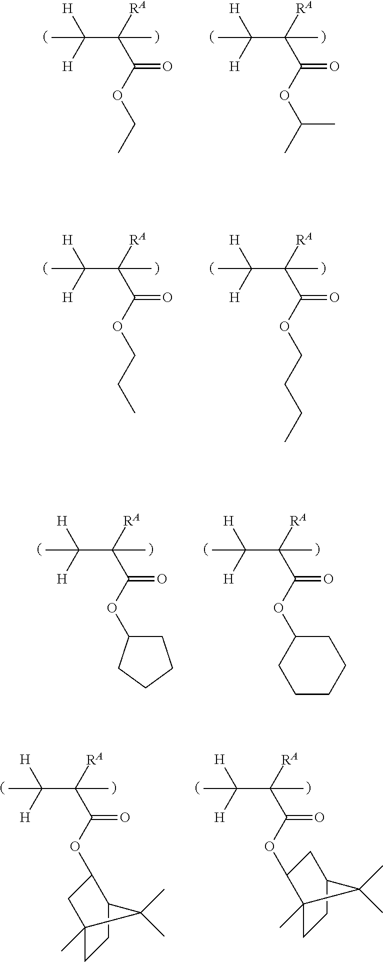

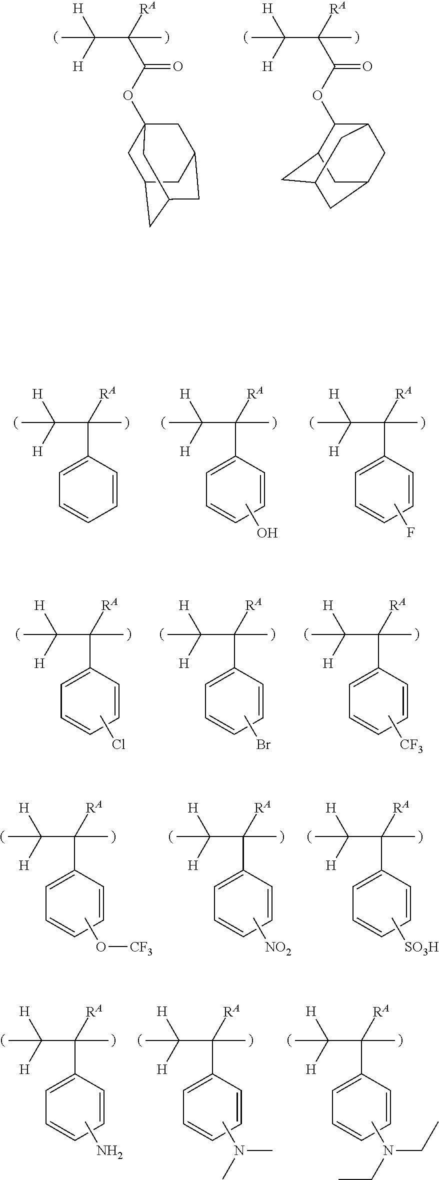

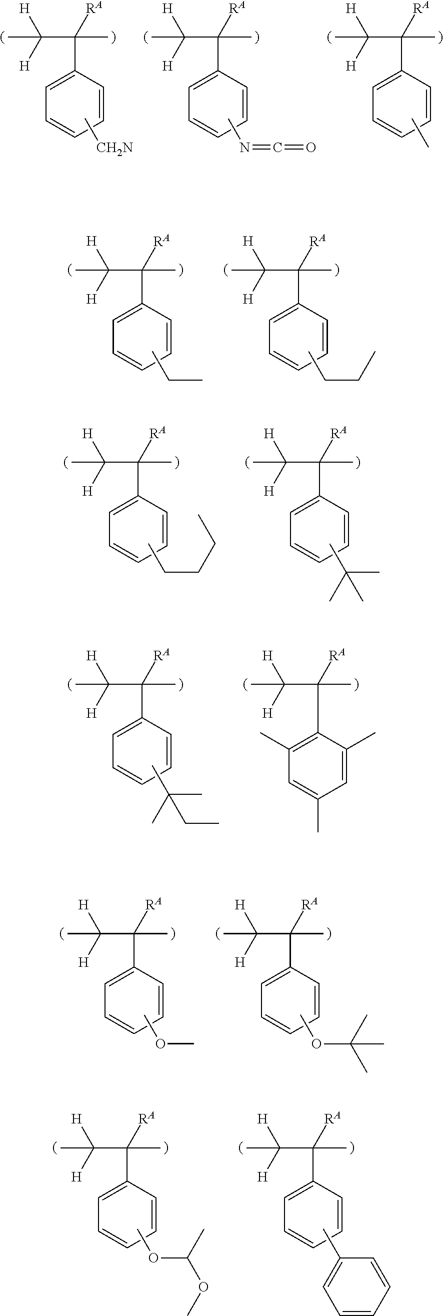

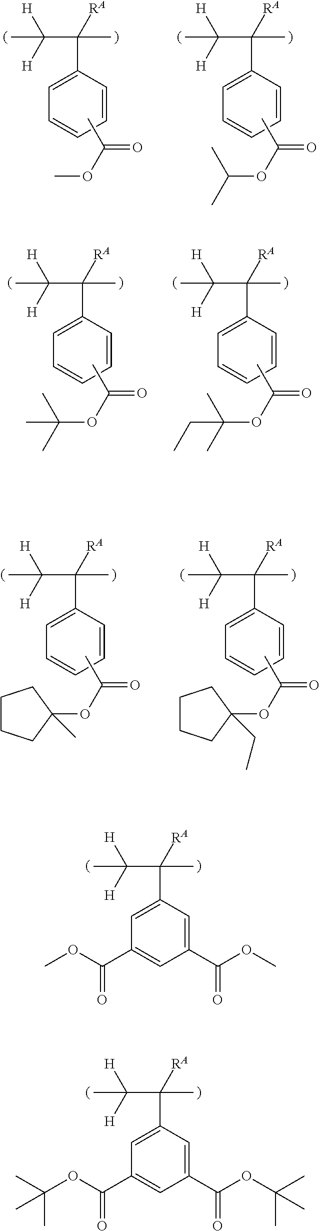

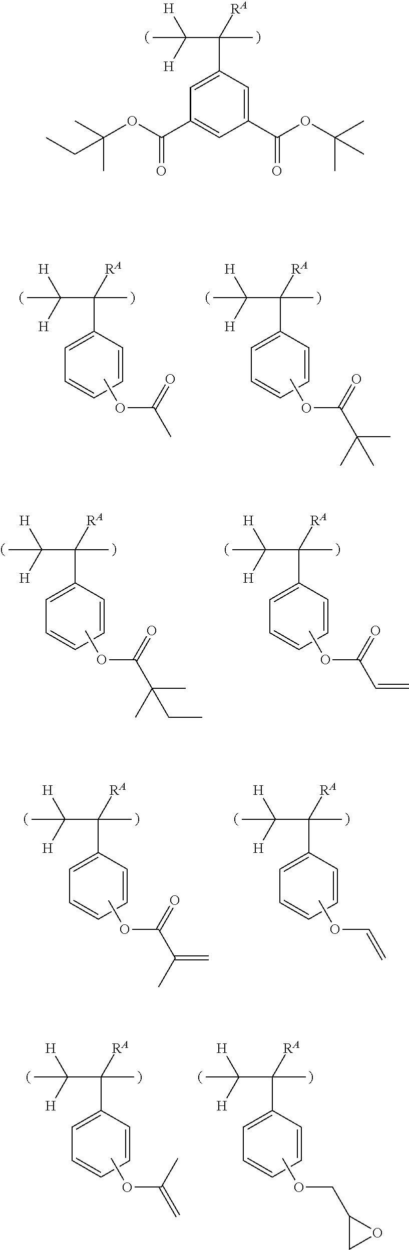

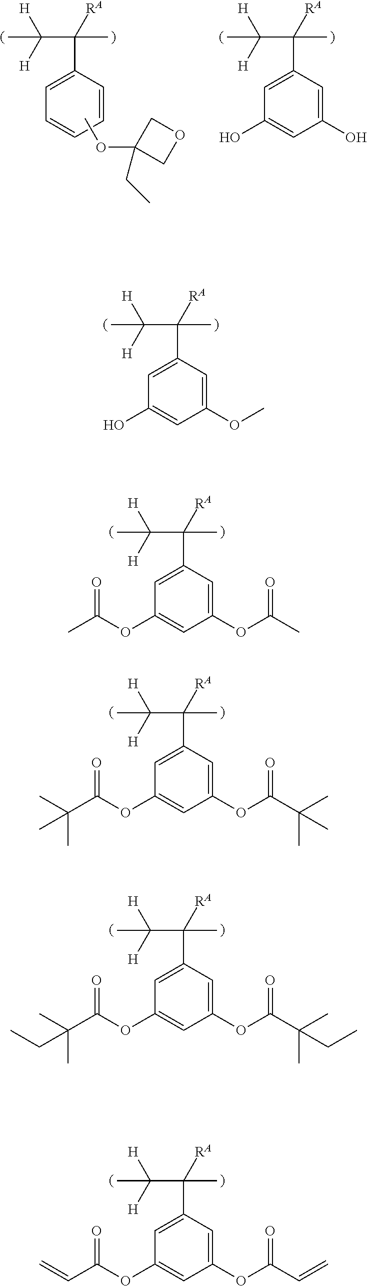

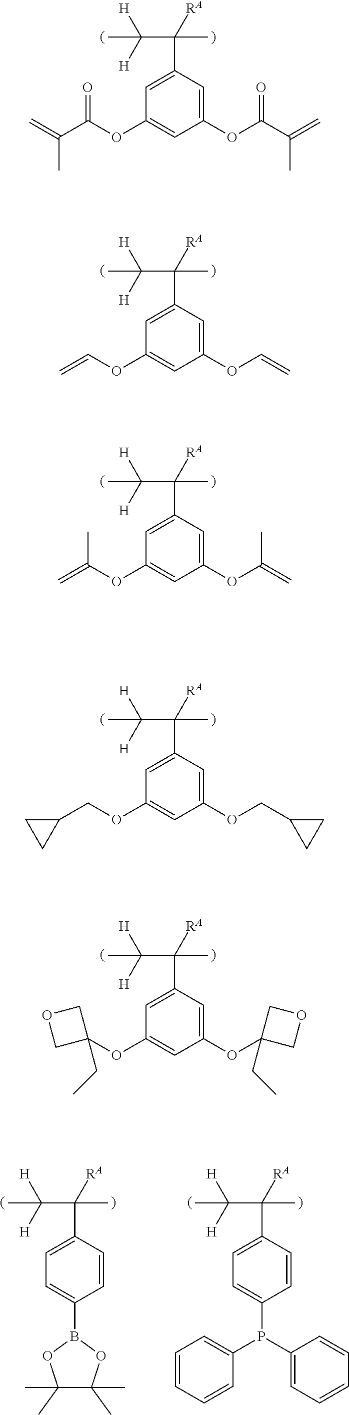

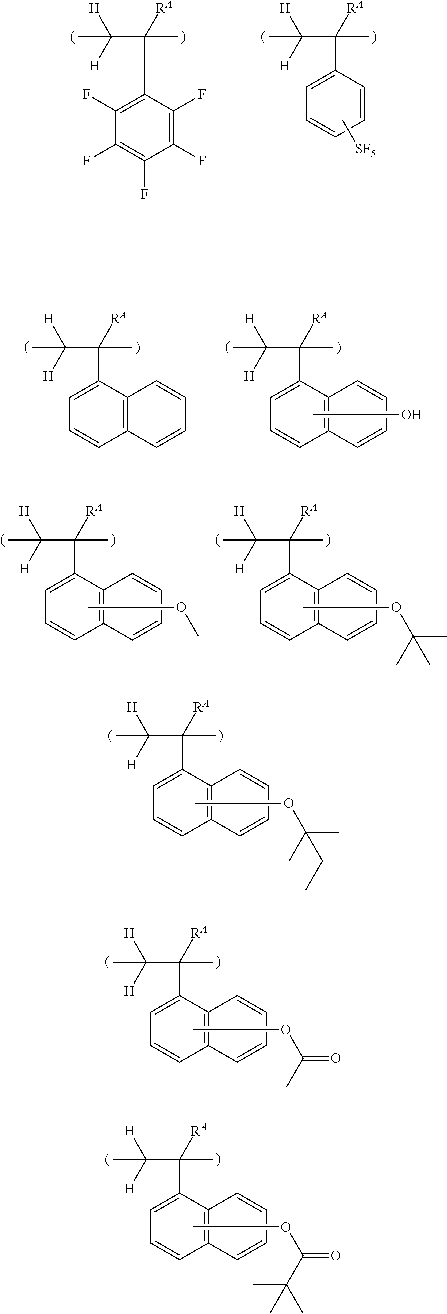

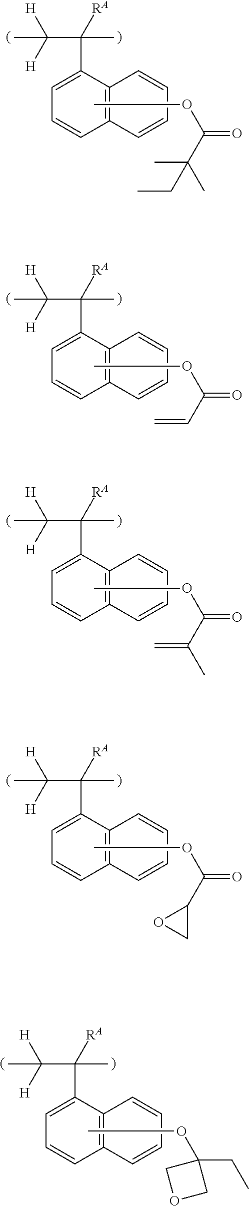

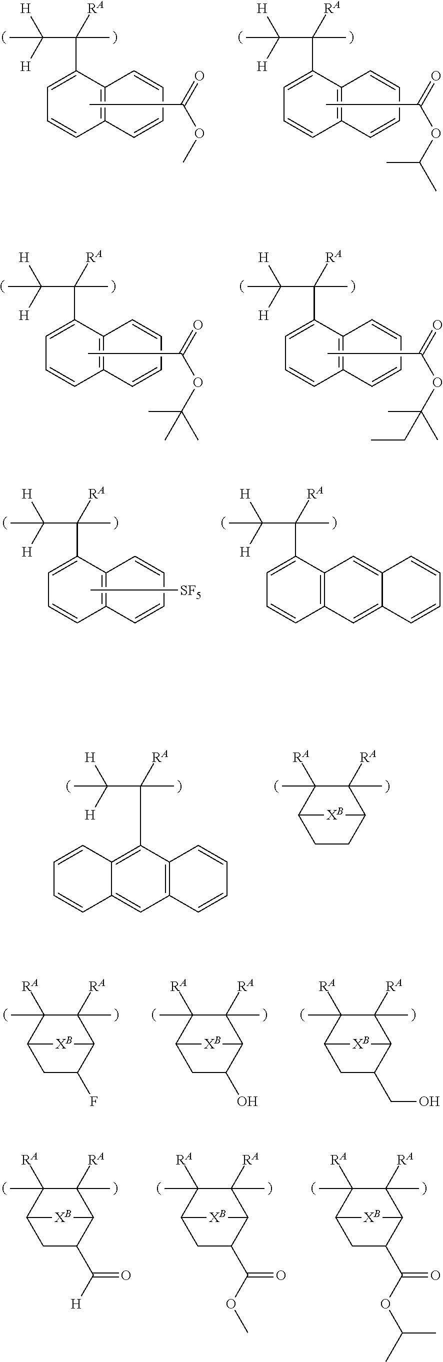

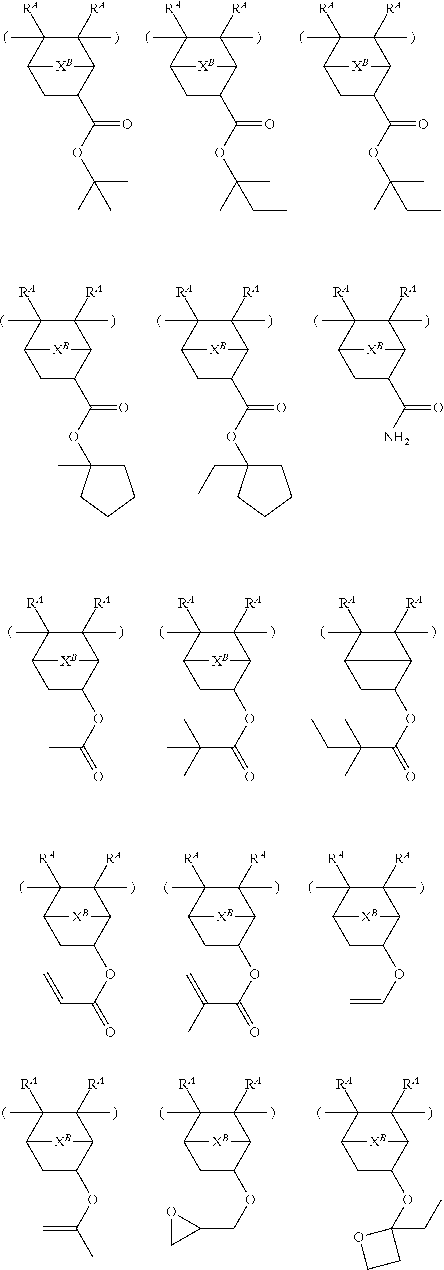

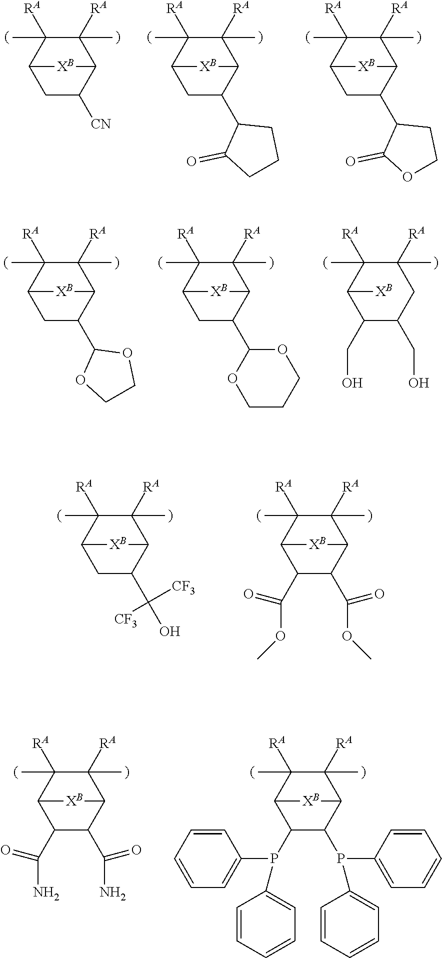

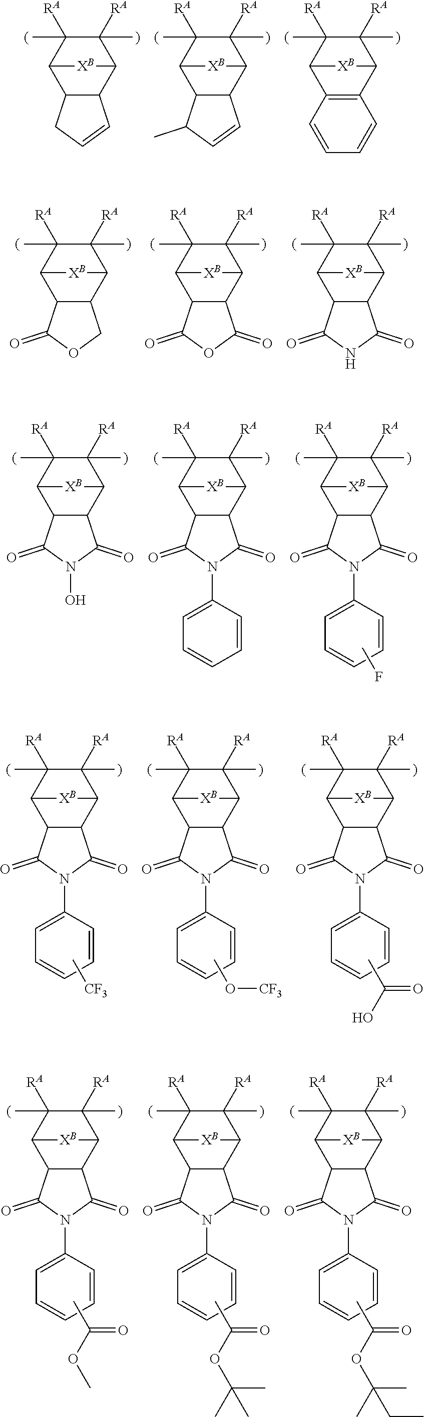

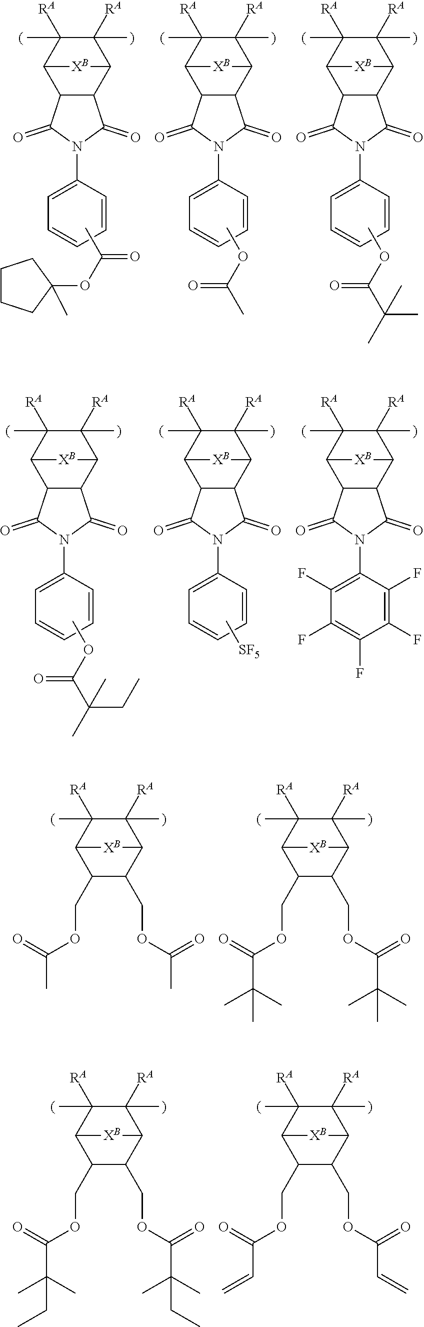

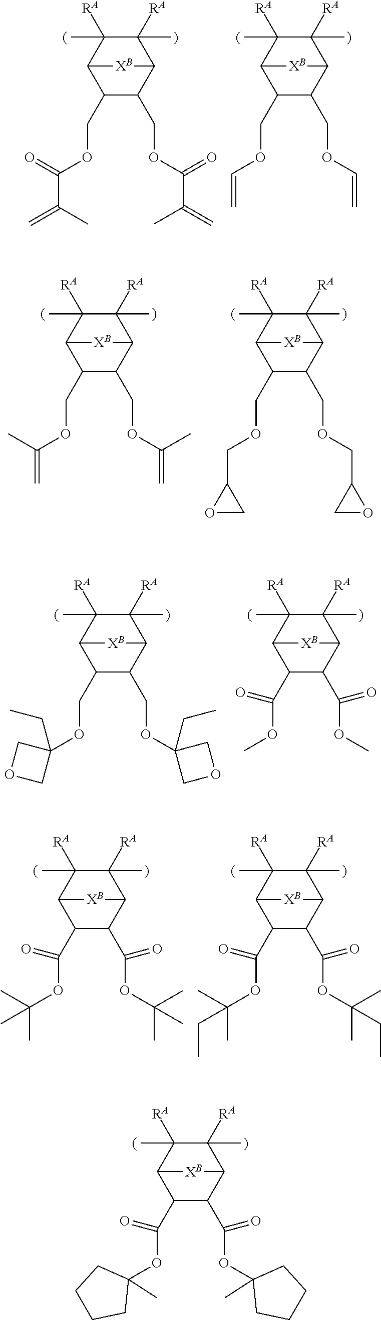

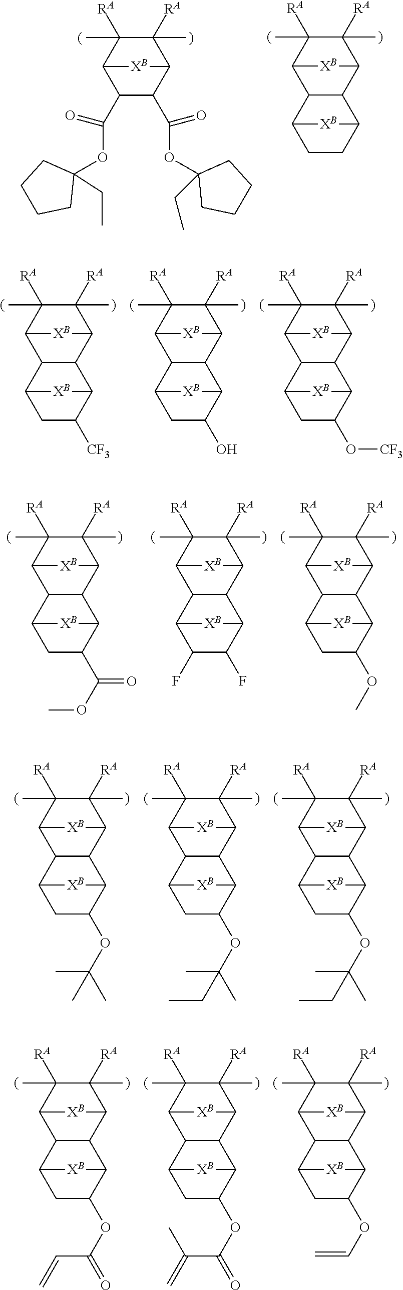

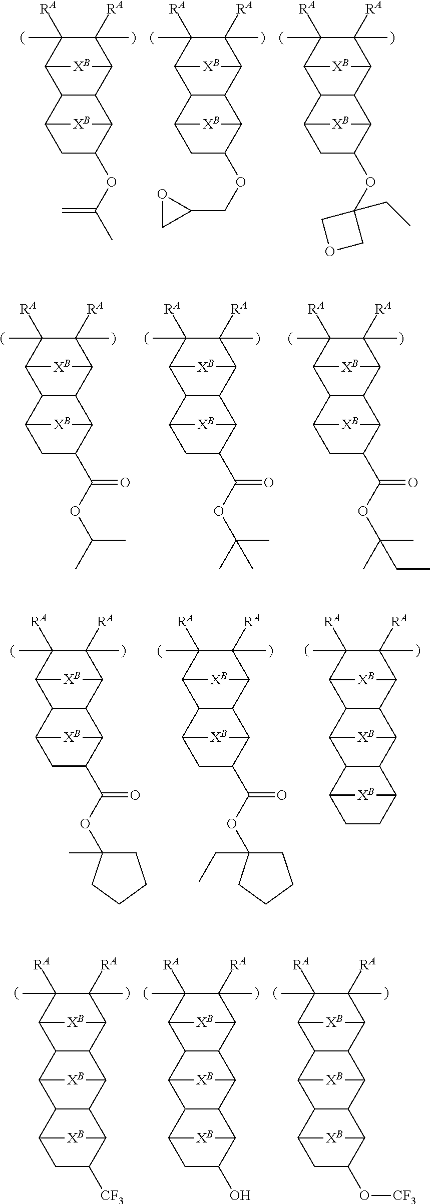

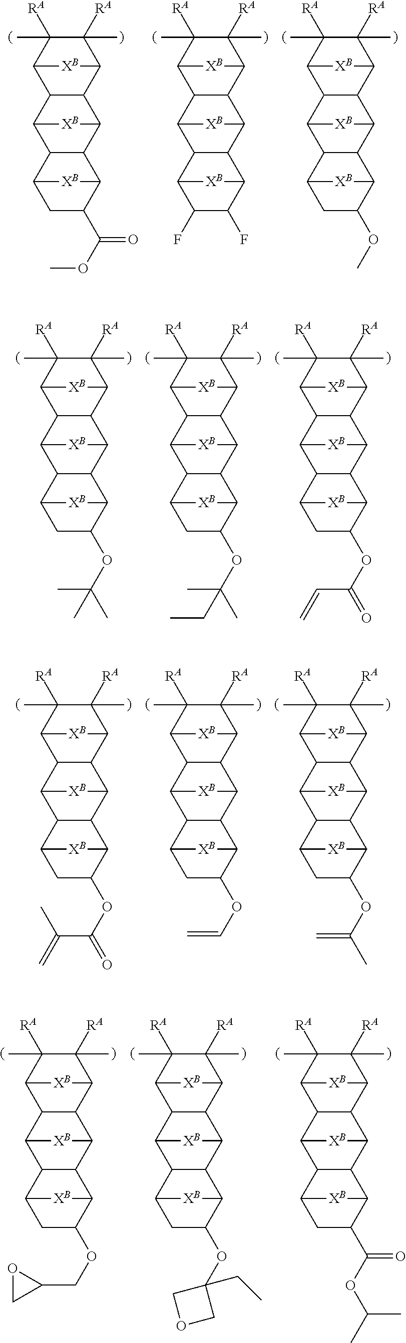

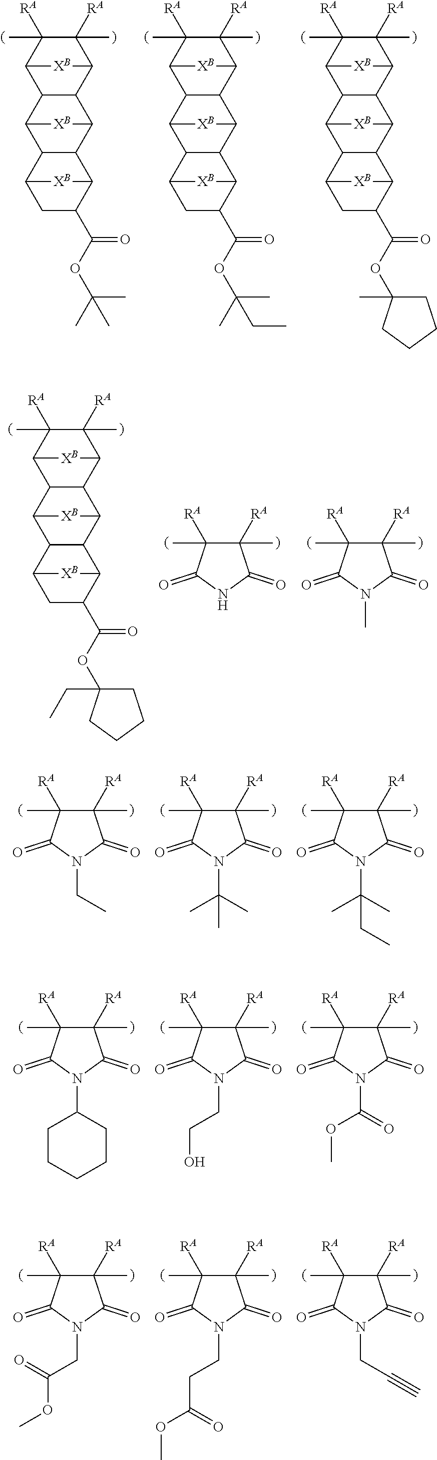

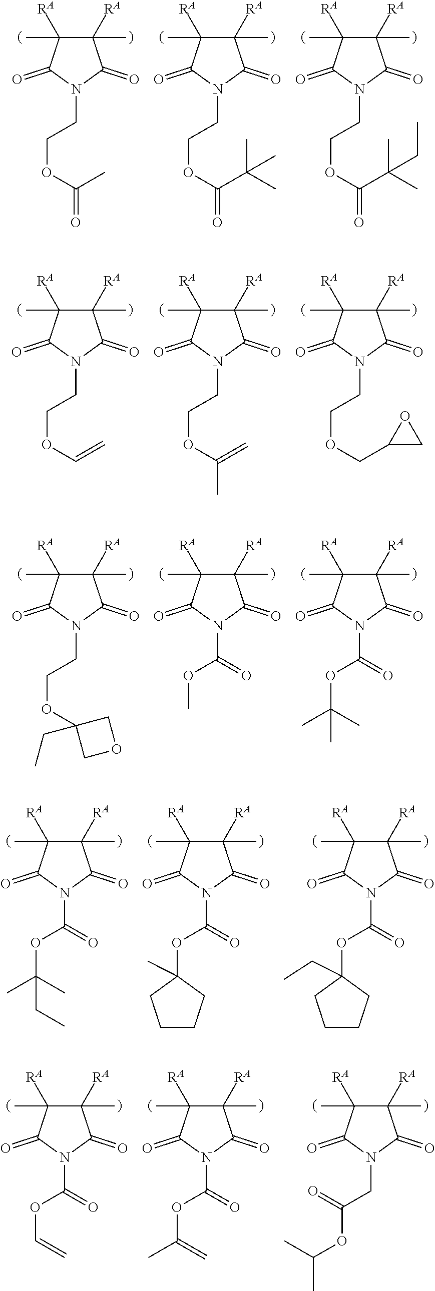

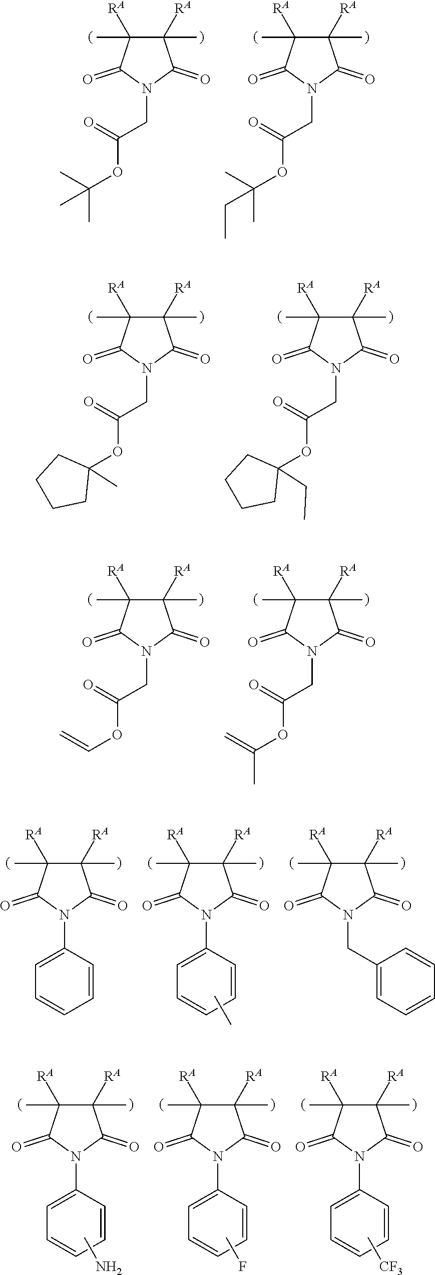

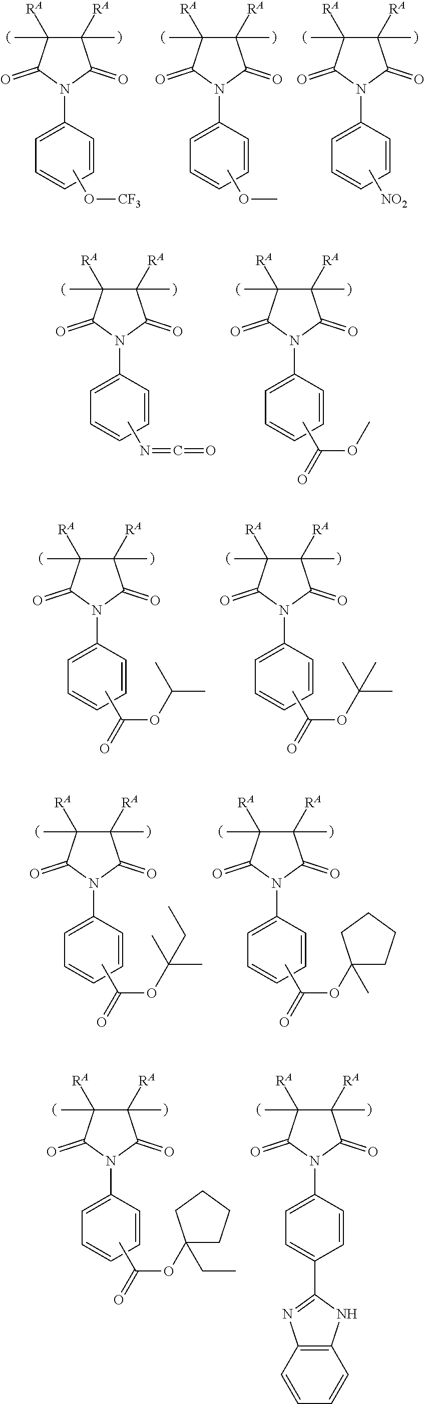

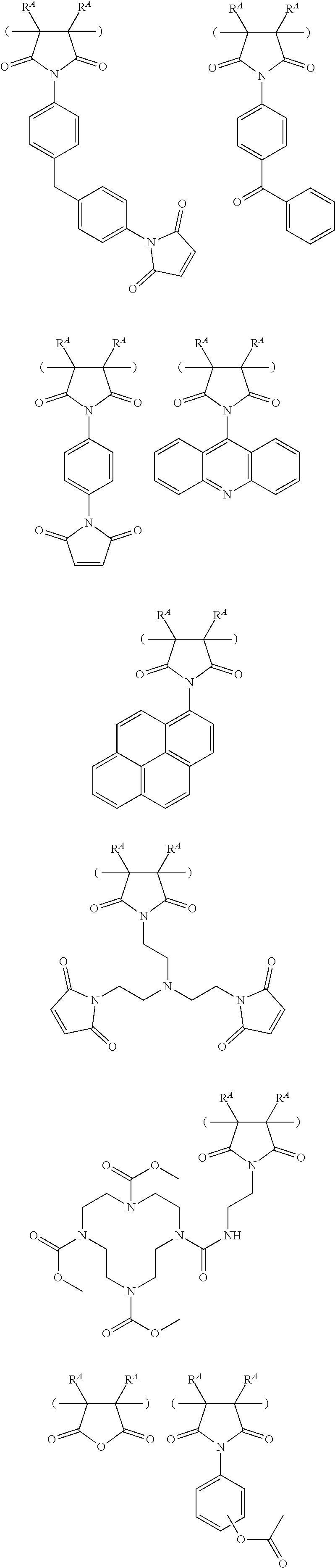

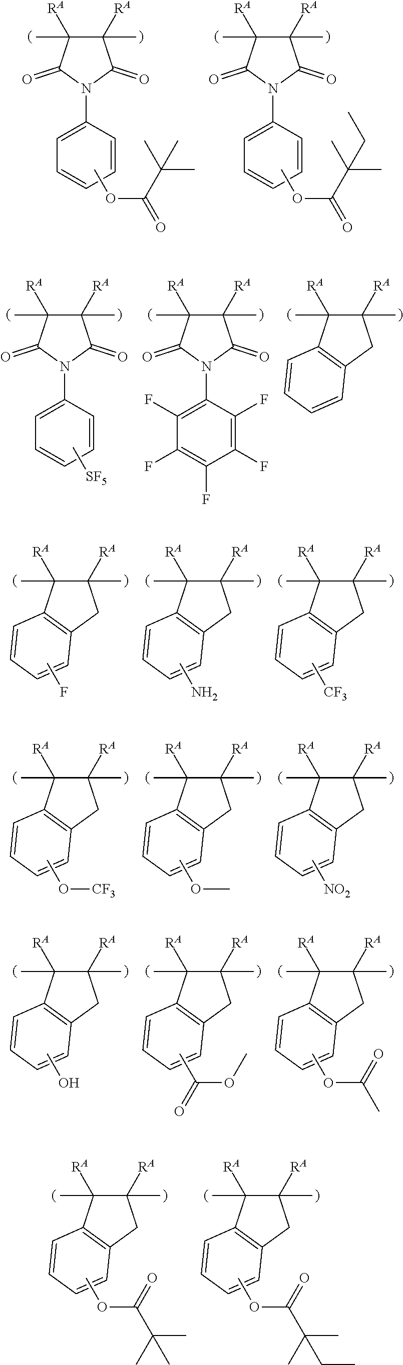

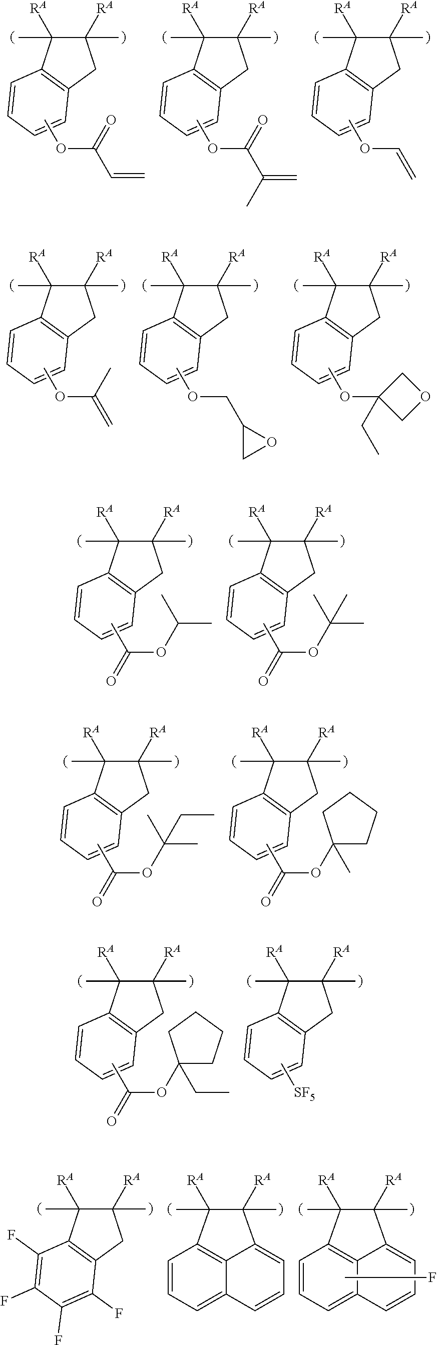

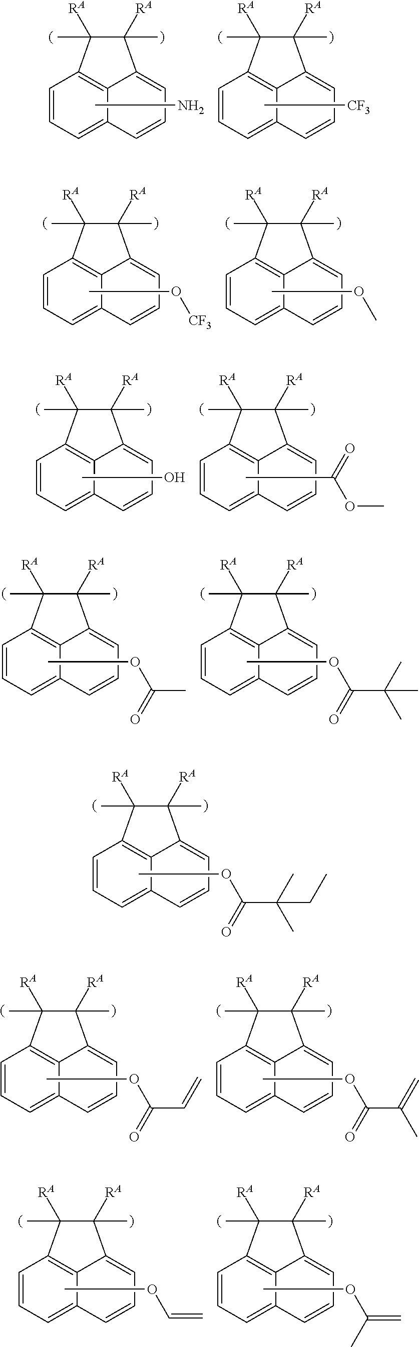

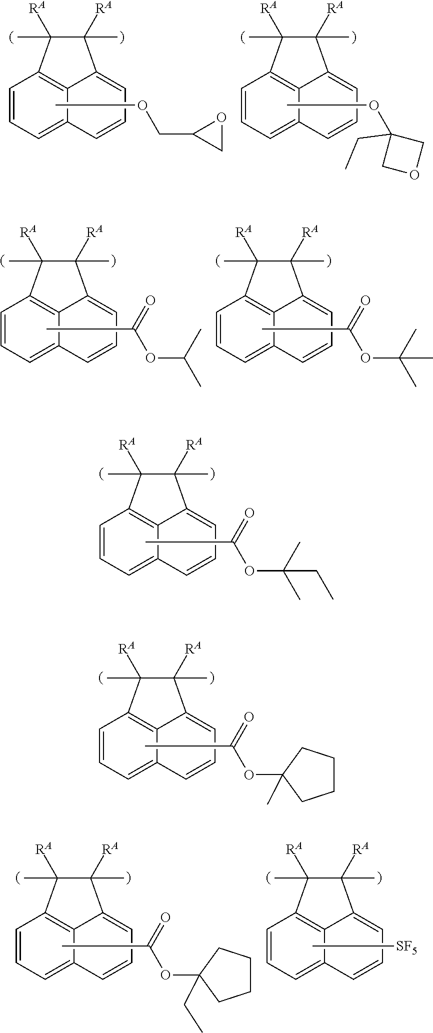

In the above-described resist composition, the content ratio of the hypervalent iodine compound to the carboxy-group-containing compound (when the carboxy-group-containing compound is a carboxy-group-containing polymer, the content ratio of the hypervalent iodine compound to the carboxy-group-containing repeating unit in the polymer) is preferably “hypervalent iodine compound”:“carboxy-group-containing compound”=10:90 to 90:10, more preferably 20:80 to 80:20, and further preferably 30:70 to 70:30 in molar ratio. One kind of the hypervalent iodine compound may be used, or two or more kinds thereof having different composition ratios, Mw, and/or Mw/Mn may be used in combination. One kind of the carboxy-group-containing compound may be used, or two or more kinds thereof having different composition ratios, Mw, and/or Mw/Mn may be used in combination.

In the carboxy-group-containing polymer, the content ratio (molar ratio) of the carboxy-group-containing repeating unit to the other repeating units is preferably “carboxy-group-containing repeating unit”:“other repeating units”=10:90 to 90:10, more preferably 15:85 to 85:15, and further preferably 20:80 to 80:20.

The carboxy-group-containing polymer preferably has a weight-average molecular weight (Mw) of 1,000 to 500,000, more preferably 3,000 to 100,000. Note that, in the present invention, Mw is a value measured in terms of polystyrene by gel permeation chromatography (GPC) using tetrahydrofuran (THF) as an eluent.

Furthermore, when the carboxy-group-containing polymer has a wide molecular weight distribution (Mw/Mn), polymers having a lower molecular weight and higher molecular weight than the Mw are present, and therefore, there are risks of foreign matters appearing on the pattern after the exposure and the degradation of pattern profile. Accordingly, the finer the pattern rule, the stronger the influences of Mw and Mw/Mn. Hence, in order to obtain a resist composition suitably used for finer pattern dimensions, the carboxy-group-containing polymer preferably has a narrow dispersity Mw/Mn of 1.0 to 2.0.

Examples of methods for synthesizing the carboxy-group-containing polymer include a method of subjecting the monomers to give the repeating units described above to heat polymerization in an organic solvent to which a radical polymerization initiator has been added.

Specific examples of the organic solvent to be used in the polymerization reaction include toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Specific examples of the radical polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of the radical polymerization initiator to be added is preferably 0.01 to 25 mol % of the total amount of the monomers to be polymerized. The reaction temperature is preferably 50 to 150° C., more preferably 60 to 100° C. The reaction time is preferably 2 to 24 hours, and from the viewpoint of production efficiency, more preferably 2 to 12 hours.

The radical polymerization initiator may be added to the solution containing the monomer and supplied to the reaction vessel, or a solution of the initiator may be prepared separately from the solution containing the monomer, and each may be supplied to the reaction vessel independently. There is a possibility that the polymerization reaction may progress due to radicals generated from the radical polymerization initiator during waiting time and an ultra-high molecular weight polymer may be generated, and therefore, from the viewpoint of quality control, it is preferable to prepare each of the monomer solution and the initiator solution independently and add the solutions dropwise. Furthermore, to adjust the molecular weight, a known chain transfer agent, such as dodecyl mercaptan and 2-mercaptoethanol may also be used. In this case, the amount of the chain transfer agent to be added is preferably 0.01 to 20 mol % of the total amount of the monomers to be polymerized.

Note that the amount of each monomer in the monomer solution can be, for example, set appropriately to achieve the preferable content ratios of the above-described repeating units.

### [Solvent]

The above-described resist composition contains a solvent. The solvent is not particularly limited as long as the solvent dissolves the hypervalent iodine compound, the carboxy-group-containing compound, and other components described later and allows film formation. As such a solvent, organic solvents are preferable, and specific examples thereof include: ketones, such as cyclohexanone, methyl-2-n-pentyl ketone, and methyl isoamyl ketone; alcohols, such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids, such as formic acid, acetic acid, and propionic acid; lactones, such as γ-butyrolactone; and mixed solvents thereof.

In the resist composition, the amount of the solvent contained is preferably such an amount that the concentration of the solid contents in the resist composition is 0.1 to 20 mass %, more preferably 0.1 to 15 mass %, and further preferably 0.1 to 10 mass %. Note that, in the present invention, solid contents is a general term for the components other than the solvent out of all the components of the resist composition. One kind of the solvent may be used, or two or more kinds thereof may be used in mixture.

The resist composition may further contain a surfactant. As the surfactant, a fluorine-based and/or silicone-based surfactant is preferable. Examples of such a surfactant include surfactants disclosed in paragraph [0276] of US2008/0248425A1. Furthermore, it is also possible to use a surfactant disclosed in paragraph [0280] of US2008/0248425A1, other than the fluorine-based and/or silicone-based surfactants.

When the resist composition contains the surfactant, the contained amount is preferably 0.0001 to 2 mass % of all the solid contents. One kind of the surfactant may be used, or two or more kinds thereof may be used in combination.

The resist composition may further contain a radical scavenger. When a radical scavenger is contained, the photoreaction during photolithography can be controlled, and sensitivity can be adjusted.

Examples of the radical scavenger include hindered phenols, quinones, hindered amines, and thiol compounds. Specifically, examples of the hindered phenols include dibutylhydroxytoluene (BHT) and 2,2′-methylenebis(4-methyl-6-tert-butylphenol). Examples of the quinones include 4-methoxyphenol (methoquinone) and hydroquinone. Examples of the hindered amines include 2,2,6,6-tetramethylpiperidine and 2,2,6,6-tetramethylpiperidine-N-oxy radical. Examples of the thiol compounds include dodecanethiol and hexadecanethiol.

When the resist composition contains the radical scavenger, the contained amount is preferably 0.01 to 10 mass % of all the solid contents. One kind of the radical scavenger may be used, or two or more kinds thereof may be used in combination.

The resist composition may further contain a crosslinking agent. When a crosslinking agent is contained, the crosslinking reaction during photolithography can be promoted, the glass transition temperature of the pattern can be increased, and a pattern that is excellent in the resolution of a thin line can be obtained.

Examples of the crosslinking agent include compounds having a carbon-carbon unsaturated bond as a functional group, such as a vinyl group, a (meth)acrylate group, an allyl group, an alkynyl group, and an aromatic ring. Specifically, examples of compounds having a vinyl group include chain alkenes, branched alkenes, and cyclic alkenes, each optionally having a substituent. Examples of compounds having a (meth)acrylate group include acrylic acid, methacrylic acid, acrylic acid ester, and methacrylic acid ester, each optionally having a substituent. Examples of compounds having an allyl group include allyl alcohol, allyl ether, allyl ester, allyl amide, allylamine, and allyl-group-containing isocyanurates, each optionally having a substituent. Examples of compounds having an alkynyl group include chain alkynes, branched alkynes, cyclic alkynes, alkynyl alcohols, alkynyl ethers, alkynyl esters, alkynyl amides, alkynyl amines, and alkynyl-group-containing isocyanurates, each optionally having a substituent. Examples of compounds having an aromatic ring include arenes, heteroarenes, styrene, stilbene, phenylacetylene, acenaphthylene, and chalcone, each optionally having a substituent. The crosslinking agent may have only one of the functional groups, or may have a plurality of the groups. The number of the functional groups contained in the crosslinking agent is preferably 1 or more and 10 or less, more preferably 2 or more and 8 or less.

When the resist composition contains the crosslinking agent, the contained amount is preferably 0.01 to 50 mass % of all the solid contents. One kind of the crosslinking agent may be used, or two or more kinds thereof may be used in combination.

When the resist composition contains the crosslinking agent, a photo-polymerization initiator may further be contained. The photo-polymerization initiator generates radicals when irradiated with a high-energy beam, and can promote the crosslinking of the crosslinking agent.

Specific examples of the photo-polymerization initiator include: benzophenone derivatives, such as benzophenone, methyl 0-benzoylbenzoate, 4-benzoyl-4′-methyldiphenyl ketone, dibenzyl ketone, and fluorenone; acetophenone derivatives, such as 2,2′-diethoxyacetophenone, 2-hydroxy-2-methylpropiophenone, 2,2-dimethoxy-1,2-diphenylethan-1-one, 1-hydroxycyclohexyl phenyl ketone, 2-methyl-1-[4-(methylthio)phenyl]-2-morpholinopropan-1-one, 2-hydroxy-1-{4-[4-(2-hydroxy-2-methylpropionyl)-benzyl]-phenyl}-2-methylpropan-1-one, and methyl phenylglyoxylate; thioxanthone derivatives, such as thioxanthone, 2-methylthioxanthone, 2-isopropylthioxanthone, 4-isopropylthioxanthone, 2-chlorothioxanthone, and diethylthioxanthone; benzyl derivatives, such as benzyl, benzyldimethyl ketal, and benzyl-β-methoxyethyl acetal; benzoin derivatives, such as benzoin, benzoin methyl ether, and 2-hydroxy-2-methyl-1-phenylpropan-1-one; oxime compounds, such as 1-phenyl-1,2-butanedione-2-(O-methoxycarbonyl)oxime, 1-phenyl-1,2-propanedione-2-(O-methoxycarbonyl)oxime, 1-phenyl-1,2-propanedione-2-(O-ethoxycarbonyl)oxime, 1-phenyl-1,2-propanedione-2-(O-benzoyl)oxime, 1,3-diphenylpropanetrione-2-(O-ethoxycarbonyl)oxime, 1-phenyl-3-ethoxypropantrione-2-(O-benzoyl)oxime, 1,2-octanedione-1-[4-(phenylthio)-2-(O-benzoyloxime)], and ethenone-1-[9-ethyl-6-(2-methylbenzoyl)-9H-carbazol-3-yl]-1-(O-acetyloxime); α-hydroxyketone compounds, such as 2-hydroxy-2-methyl-1-phenylpropan-1-one, 1-[4-(2-hydroxyethoxy)phenyl]-2-hydroxy-2-methyl-1-propan-1-one, and 2-hydroxy-1-{4-[4-(2-hydroxy-2-methylpropionyl)-benzyl]phenyl}-2-methylpropane; α-aminoalkylphenone compounds, such as 2-benzyl-2-dimethylamino-1-(4-morpholinophenyl)-butanone-1 and 2-dimethylamino-2-(4-methylbenzyl)-1-(4-morpholin-4-yl-phenyl)butan-1-one; phosphine oxide compounds, such as bis(2,4,6-trimethylbenzoyl)-phenylphosphine oxide, bis(2,6-dimethoxybenzoyl)-2,4,4-trimethyl-pentylphosphine oxide, and 2,4,6-trimethylbenzoyldiphenylphosphine oxide; and titanocene compounds, such as bis(η5-2,4-cyclopentadien-1-yl)-bis(2,6-difluoro-3-(1H-pyrrol-1-yl)-phenyl)titanium.

When the resist composition contains the photo-polymerization initiator, the contained amount is preferably 0.1 to 10 mass %, more preferably 0.1 to 5 mass %, and most preferably 0.1 to 1 mass % of all the solid contents. When the amount is 0.1 mass % or more, a blending effect can be achieved sufficiently.

The resist composition mainly contains a hypervalent iodine compound and a carboxy-group-containing compound as described above, and polymers containing acid-labile groups and photo-acid generators, which are contained in conventional chemically amplified resist compositions, do not need to be contained. However, the resist composition used in the present invention makes it possible to form a positive pattern, where exposed portions become soluble in a developer, or a negative pattern, where exposed portions become insoluble in a developer, especially by exposure to EB or EUV. The mechanism is not completely clear, but the following conjecture can be made, for example.

The hypervalent iodine compound is, for example, a tricoordinate compound having an aryl group and a carboxylate ligand. It can be assumed that when such a tricoordinate iodine compound is mixed with a carboxy-group-containing compound, exchange with the carboxylate ligand occurs as an equilibrium reaction. In this event, if the original carboxylate ligand can be removed by some method, a hypervalent iodine compound having a new ligand is generated. For example, when 1-iodonaphthylene diacetate, which is a hypervalent iodine compound, and a carboxy-group-containing compound are mixed together and the generated acetic acid, having a low boiling point, is removed, ligand exchange is completed. Here, a polymer in which the carboxy-group-containing compound is crosslinked with the hypervalent iodine compound is obtained.

The polymer crosslinked with the hypervalent iodine compound is generated at the time of film formation. This is because such a crosslinked polymer is insoluble in most organic solvents, and therefore, a solution cannot be prepared even if the polymer is synthesized beforehand. This is conjectured to be because the hypervalent iodine compound, originally having low solvent solubility due to high polarization, contains the carboxy-group-containing compound as a ligand, and thus, solubility is even more degraded. Accordingly, in this step, it is desirable to remove the original low-molecular-weight carboxylic acid component at the time of film formation and in the subsequent baking process, thus completing the ligand exchange reaction and also forming a resist film.

The resist film obtained from the resist composition used in the present invention changes in polarity by the hypervalent iodine compound, being the main component of the resist film, being decomposed by light, and a pattern is formed by a development process. The mechanism is not completely clear, but the following conjecture can be made, for example.

The resist composition used in the present invention can be either a positive type or a negative type depending on the choice of components. In the case of a positive type, a polymer in which a hypervalent iodine compound is bonded is contained at the time of film formation. By the polymer being decomposed due to light, a monovalent iodine compound is formed, and at the same time, the bond between the carboxy-group-containing compound and the hypervalent iodine compound is removed, and the molecular weight is reduced. It is conjectured that, as a result, a positive pattern, where exposed portions are removed with an organic solvent, is formed.

On the other hand, in the case of a negative type, a polymer generated at the time of film formation, crosslinked with a hypervalent iodine compound, is contained. By the polymer being decomposed due to light, exchange of cross links or bonds occurs, and increase in molecular weight and polarity conversion occurs. It is conjectured that, as a result, a negative pattern, where unexposed portions are removed with an aqueous alkaline solution, is formed.

From the above-described conjecture, it can be said that the resist composition is a non-chemically amplified resist composition. The resist composition does not require an acid-labile group-containing polymer or a photo-acid generator, unlike conventional chemically amplified resist compositions. Therefore, adverse effects (e. g. image blurs) due to acid diffusion do not occur, and resolution of a fine pattern is possible.

The resist composition is extremely effective, especially in EUV lithography. This results from iodine atoms, which are capable of greatly absorbing EUV light, being contained. That is, shot noise can be reduced, and higher resolution and lower LWR can be achieved.

As an EUV resist composition with which a fine pattern can be formed, reported is a metal resist that mainly contains a compound of tin, which is a metal having a high absorbance of EUV light in the same manner as iodine atoms (e. g. Patent Document 2). However, as described above, such a metal resist has many issues such as insufficient solubility in a solvent, storage stability, and furthermore, the provision of infrastructures accompanying the handling of new metal elements in lithography processes. On the other hand, in the case of the resist composition used in the present invention, conventional lithography processes and track tools can be applied as they are, and there are no problems regarding solubility in a solvent either.

The resist film preferably has a film thickness of 10 to 70 nm, more preferably 20 to 50 nm.

The resist composition may contain a photo-acid generator. By a photo-acid generator being contained in the resist composition used in the present invention, a positive pattern can be formed with higher sensitivity compared to a resist composition containing no photo-acid generator. The mechanism is not completely clear, but the following conjecture can be made, for example.

In the resist composition used in the present invention, by a photo-acid generator being contained, the acid generated from the photo-acid generator in the process of exposing the resist is exchanged with the ligand of the hypervalent iodine compound to form a new ligand, and thus, the bond between the carboxy-group-containing compound and the hypervalent iodine compound is removed. It is conjectured that, therefore, in addition to scission of the I-0 bond caused by light, polarity conversion caused by exchange with a new ligand caused by the acid generated from the photo-acid generator occurs, or decrease in the molecular weight (in a case where the carboxy-group-containing compound is a polymer) occurs, and a positive pattern can be formed with high sensitivity by development with an organic solvent.

From the above conjecture, the resist composition used in the present invention is a non-chemically amplified resist composition that may contain a photo-acid generator, and does not require an acid-labile group-containing polymer, unlike conventional chemically amplified resist compositions. Therefore, the acid generated from the photo-acid generator reacts with the ligand of the hypervalent iodine compound in exposed portions to form a new ligand of the hypervalent iodine. That is, unlike chemically amplified resist compositions, the composition does not have an amplification mechanism, where a reaction with an acid-labile-group occurs and an acid is regenerated, and therefore, adverse effects (e. g. image blurs) due to acid diffusion do not occur and a fine pattern can be resolved.

Specific examples of the photo-acid generator include the following onium salt compounds.

### [Onium Salt Compound]

The onium salt compounds contain, as a cation, a sulfonium cation represented by the following general formula (5-1) or an iodonium cation represented by the following general formula (5-2).

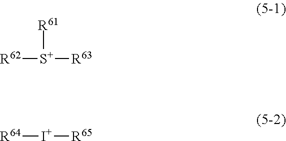

In the general formulae (5-1) and (5-2), R⁶¹ to R⁶⁵ each independently represent a halogen atom or a hydrocarbyl group having 1 to 30 carbon atoms and optionally containing a heteroatom.

Specific examples of the halogen atom represented by R⁶¹ to R⁶⁵ include a fluorine atom, a chlorine atom, a bromine atom, and an iodine atom.

The hydrocarbyl group represented by R⁶¹ to R⁶⁵ having 1 to 30 carbon atoms may be saturated or unsaturated, and may be linear, branched, or cyclic. Specific examples thereof include: alkyl groups having 1 to 30 carbon atoms, such as a methyl group, an ethyl group, an n-propyl group, an isopropyl group, an n-butyl group, an isobutyl group, a sec-butyl group, and a tert-butyl group; cyclic saturated hydrocarbyl groups having 3 to 30 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 30 carbon atoms, such as a vinyl group, an allyl group, a propenyl group, a butenyl group, and a hexenyl group; cyclic unsaturated hydrocarbyl groups having 3 to 30 carbon atoms, such as a cyclohexenyl group; aryl groups having 6 to 30 carbon atoms, such as a phenyl group, a naphthyl group, and a thienyl group; aralkyl groups having 7 to 30 carbon atoms, such as a benzyl group, a 1-phenylethyl group, and a 2-phenylethyl group; groups which are combinations of these groups; etc. Aryl groups are preferable. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— of the hydrocarbyl group may be substituted with a group containing a heteroatom such as an oxygen atom, a sulfur atom, or a nitrogen atom. The resulting hydrocarbyl group may contain a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic anhydride (—C(═O)—O—C(═O)—), a haloalkyl group, etc.

Furthermore, R⁶¹ and R⁶² may be bonded to each other to form a ring together with the sulfur atom bonded thereto. In this case, specific examples of the structure of the ring include those represented by the following formulae.

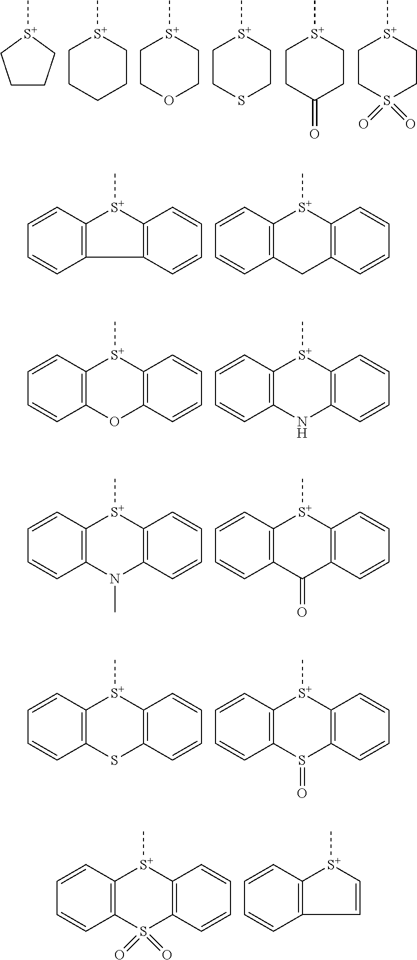

In the formulae, a broken line represents an attachment point to R⁶³.

Specific examples of the sulfonium cation represented by the general formula (5-1) include the following, but are not limited thereto.

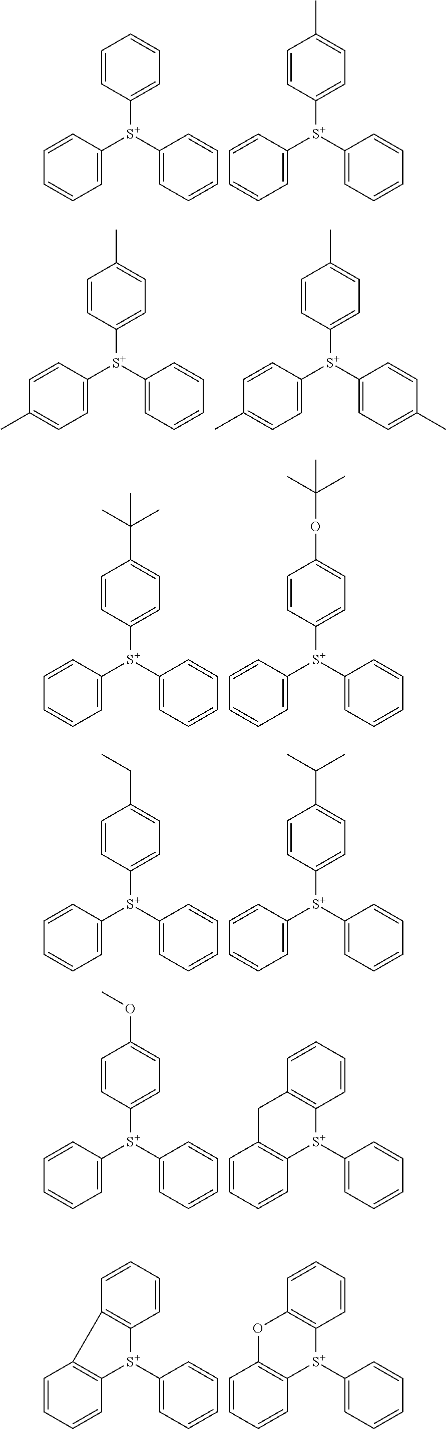

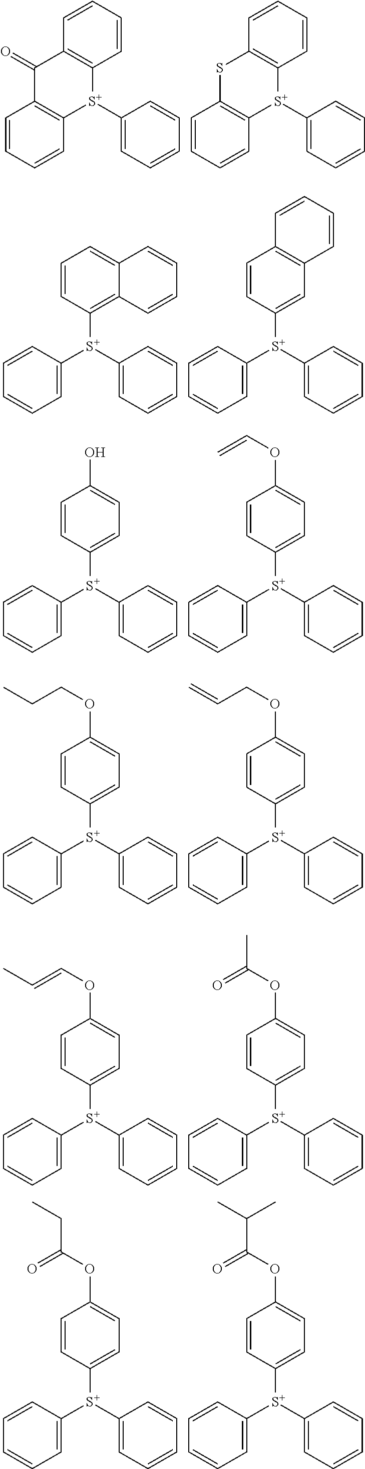

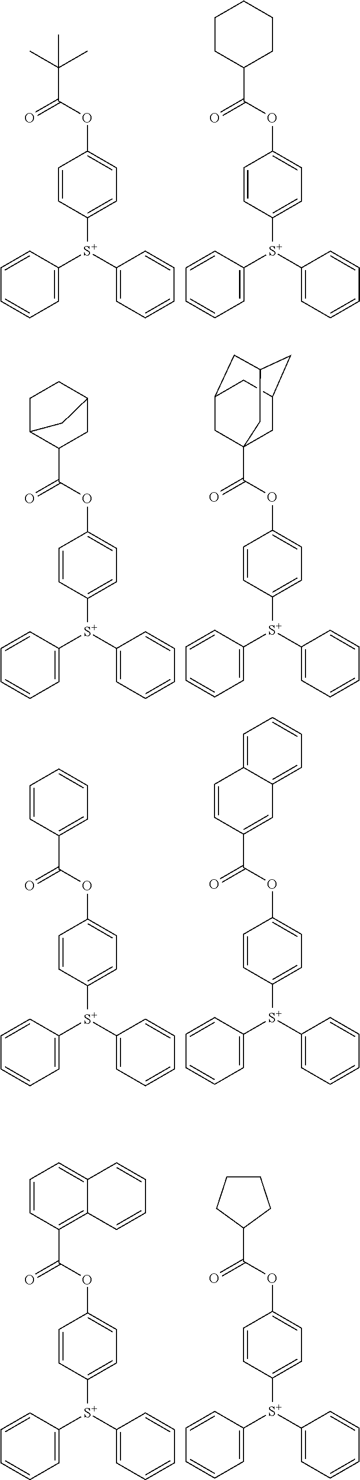

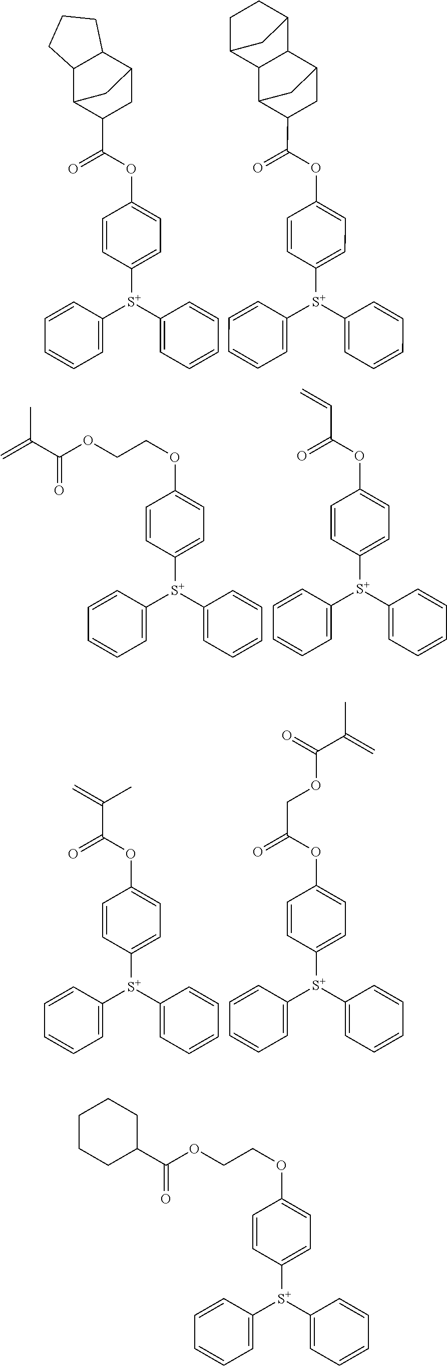

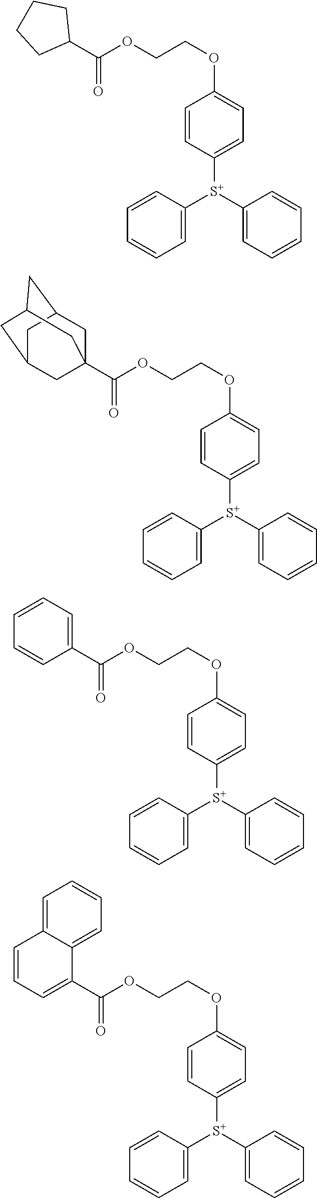

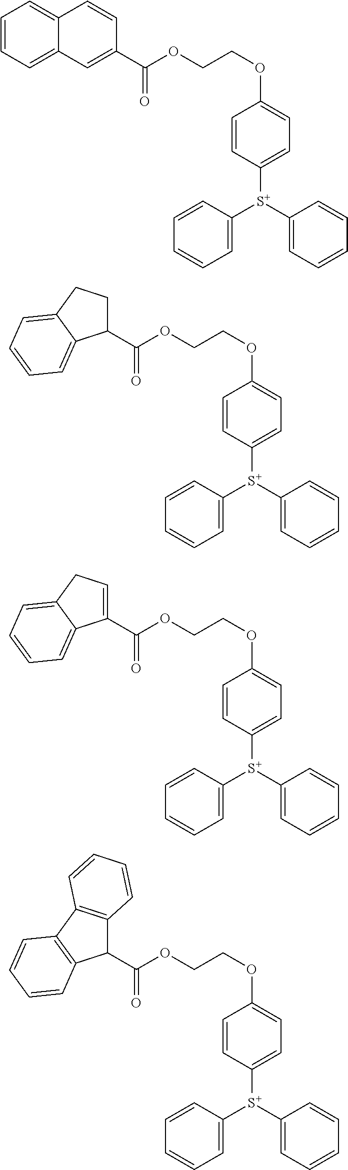

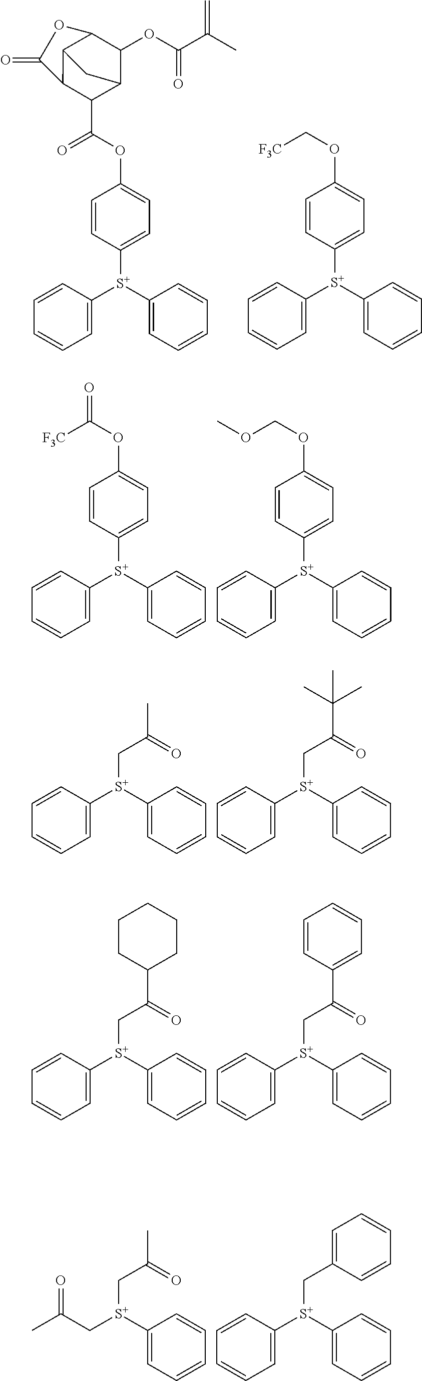

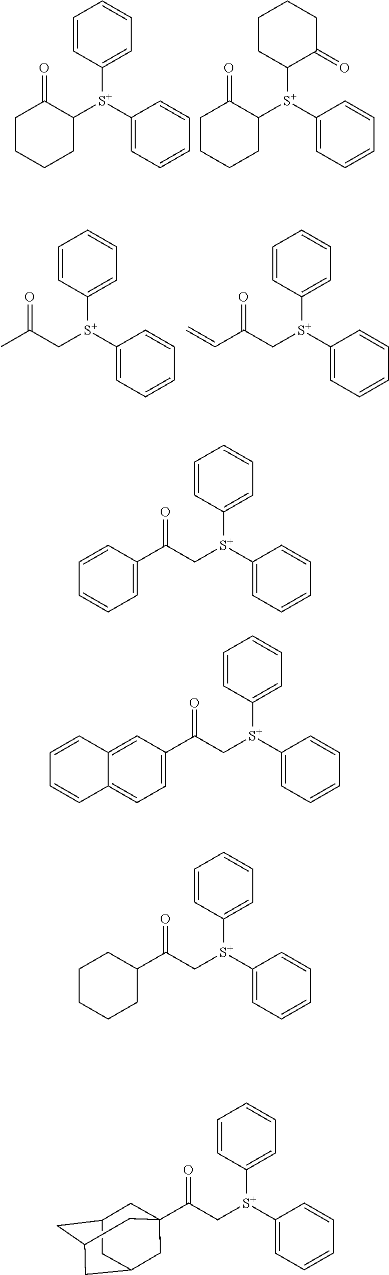

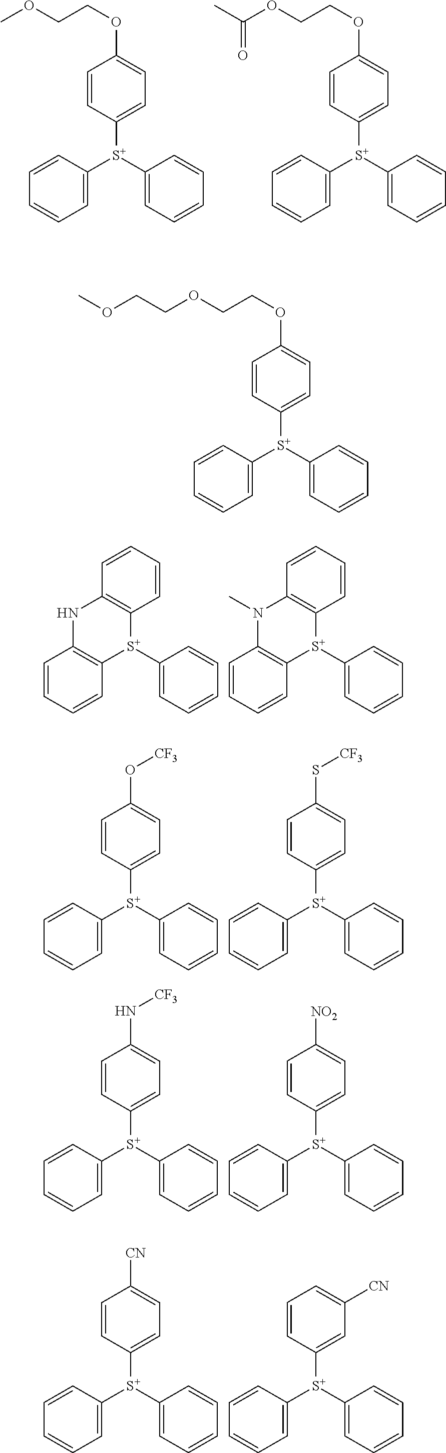

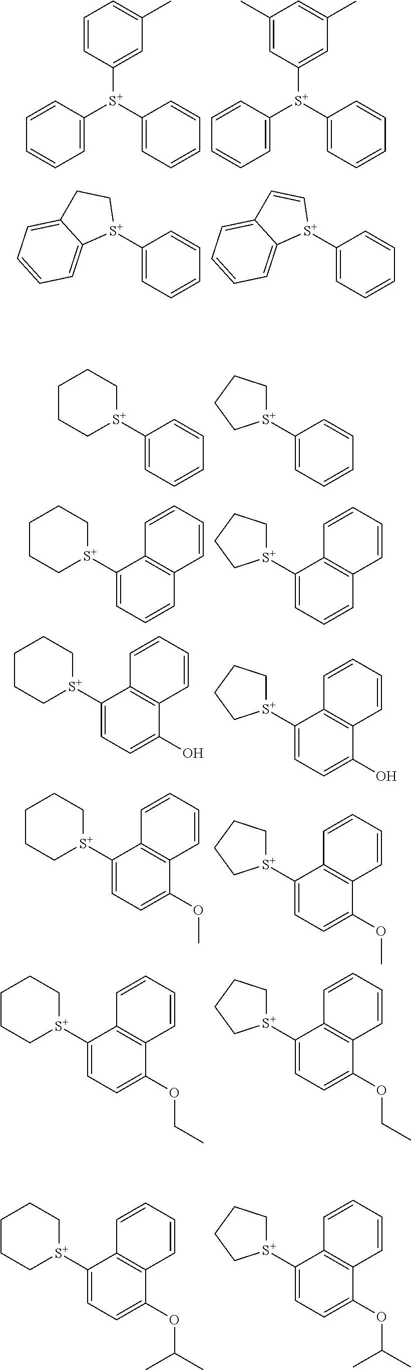

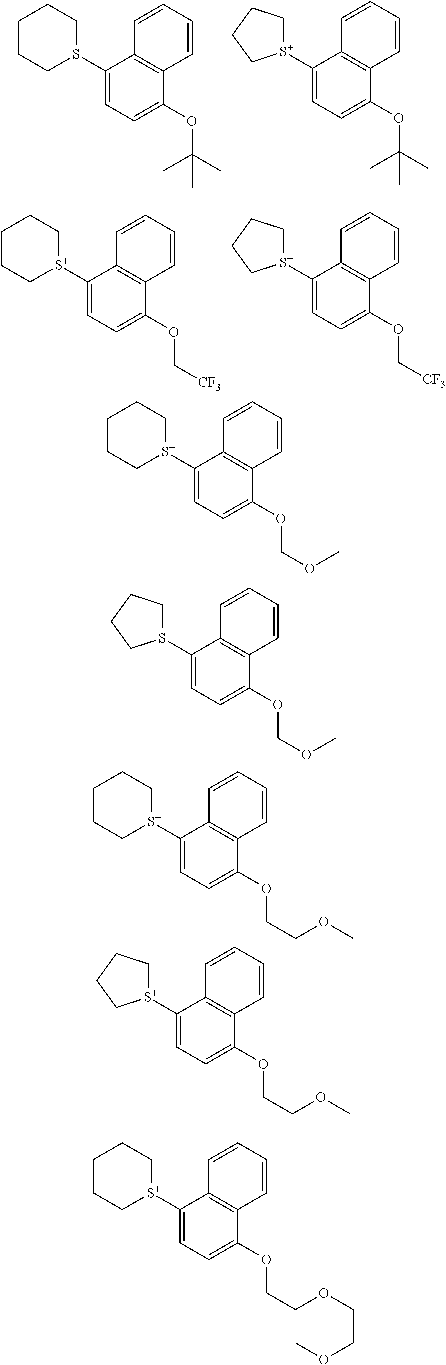

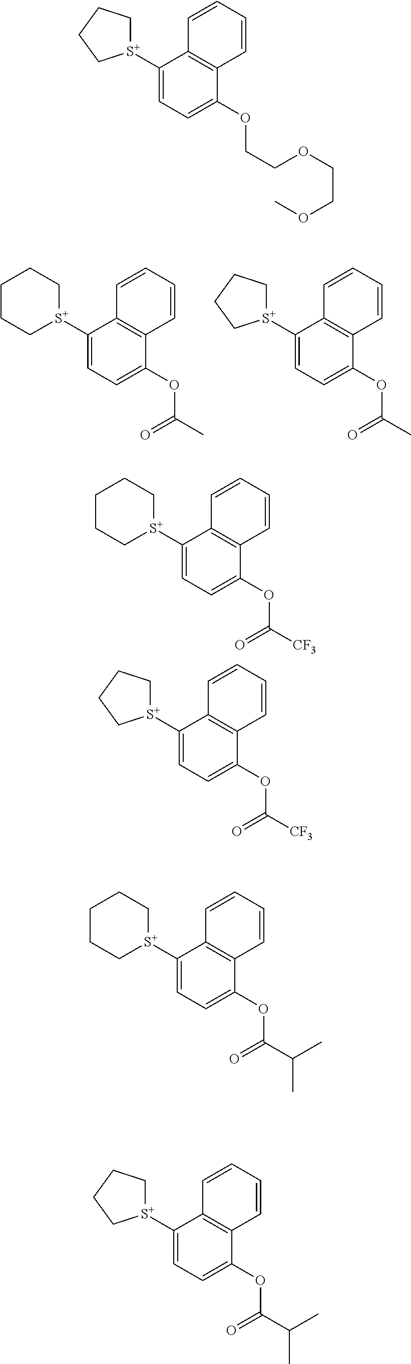

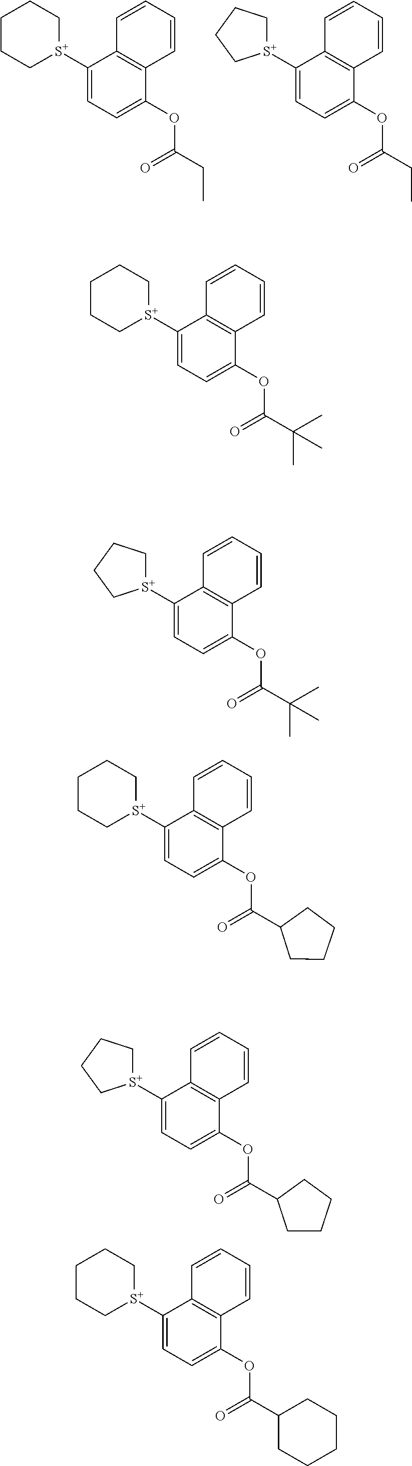

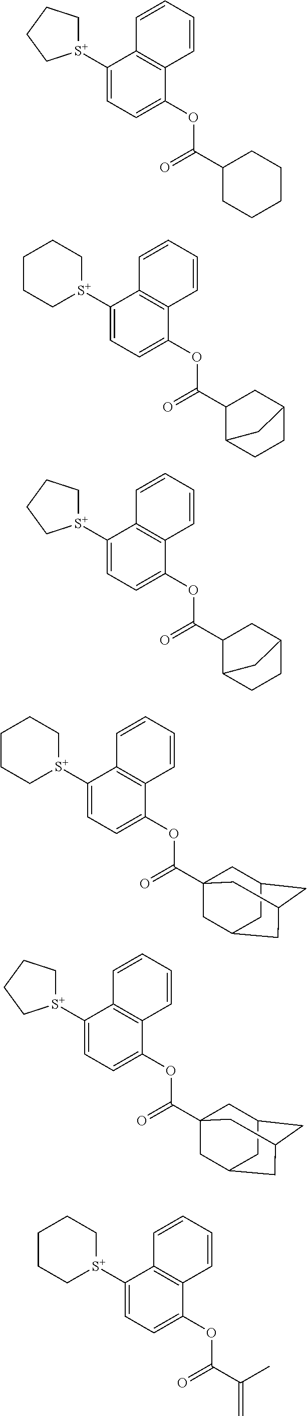

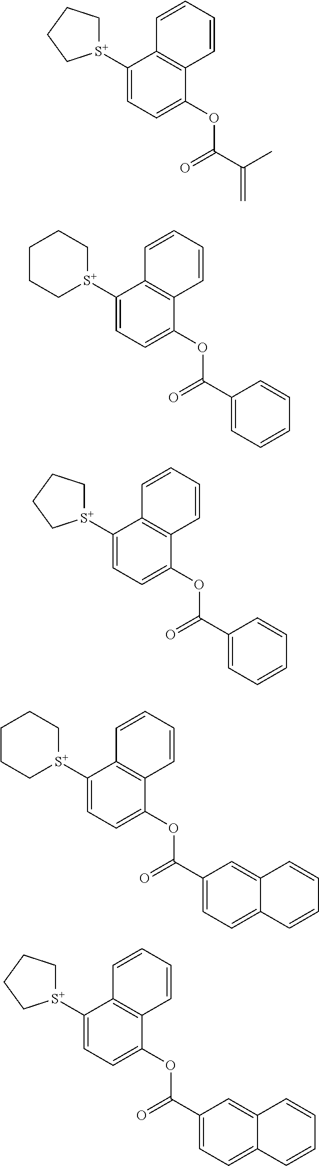

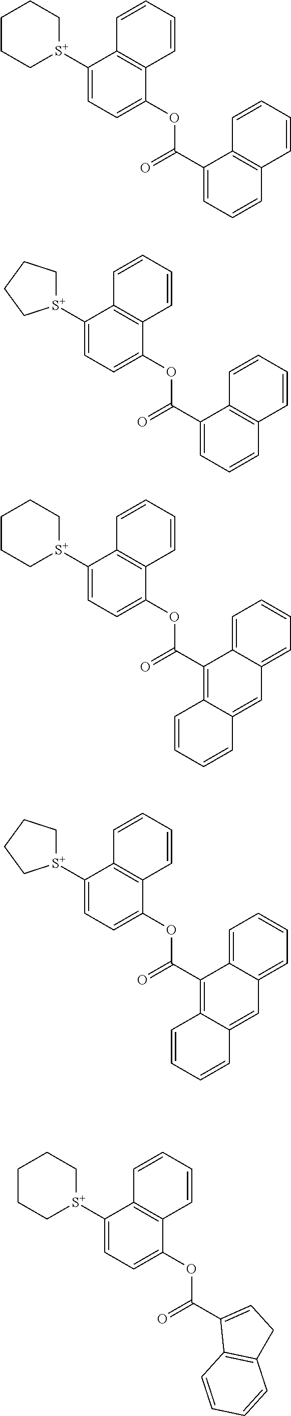

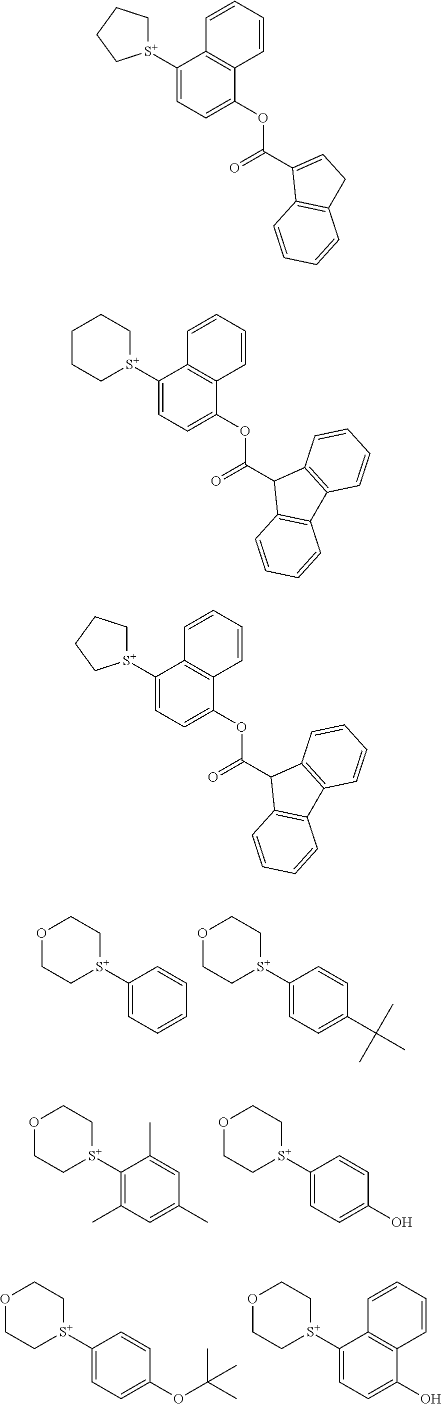

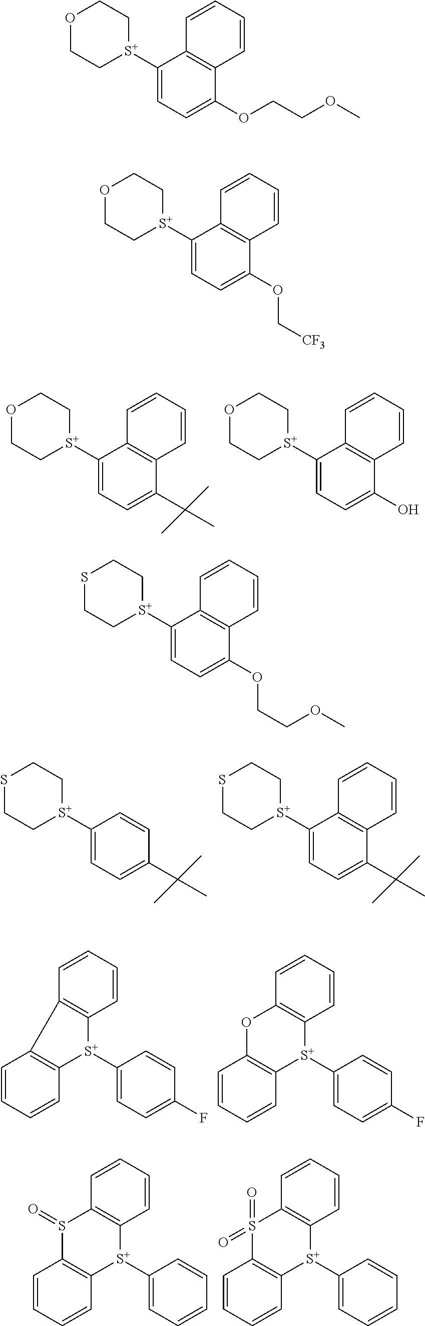

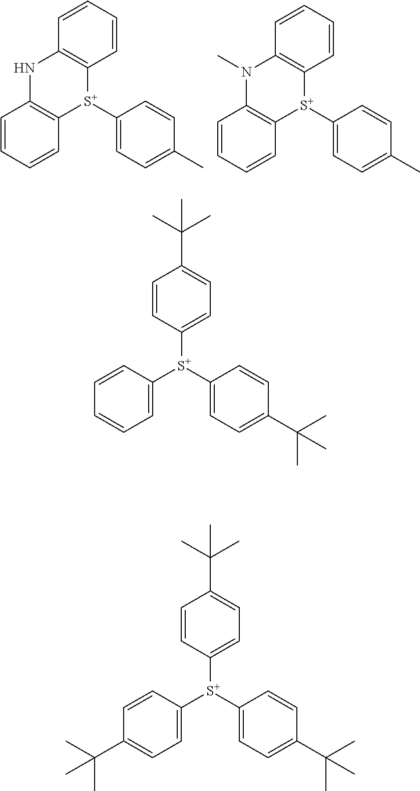

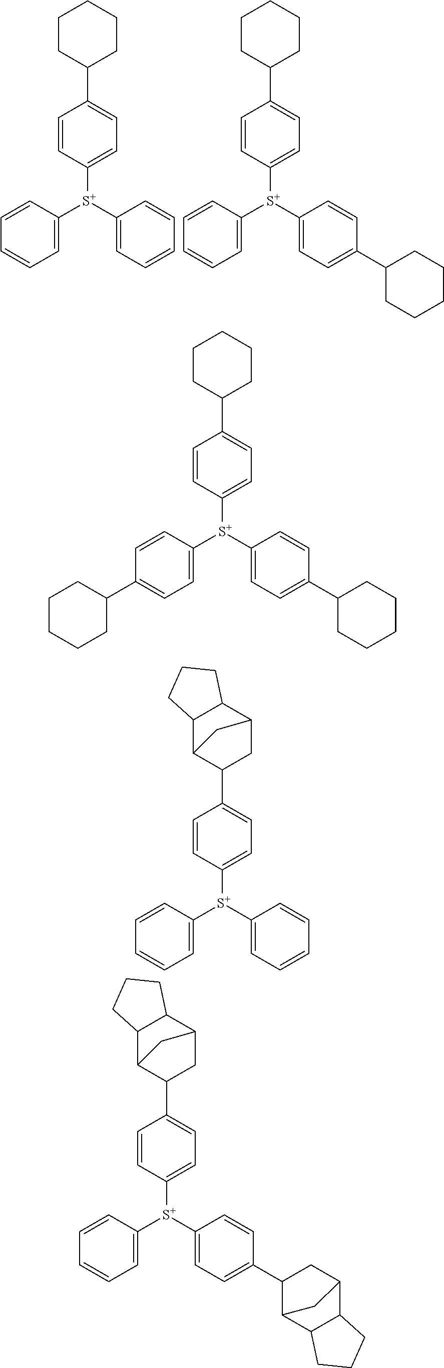

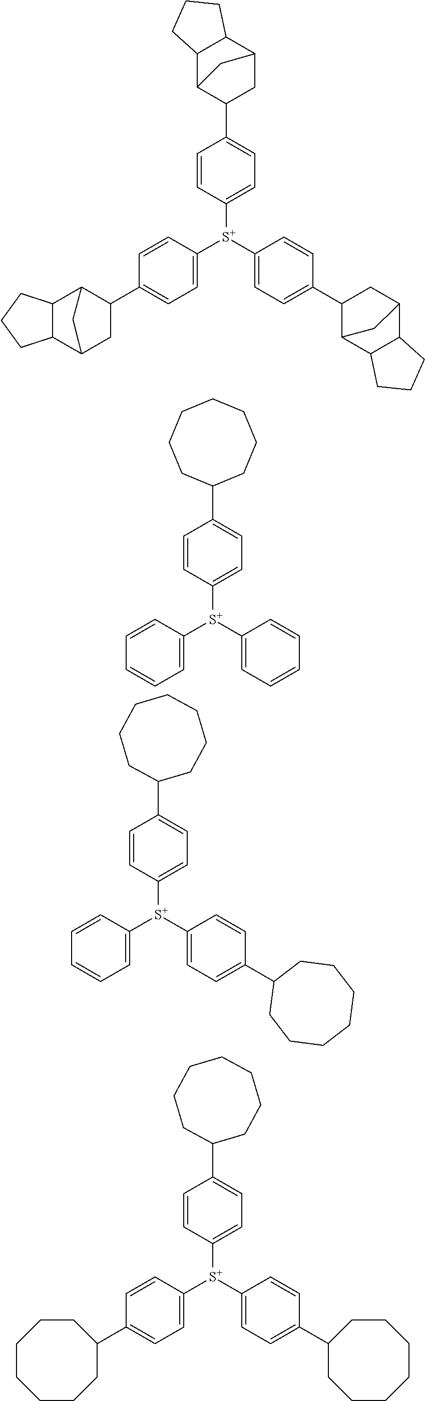

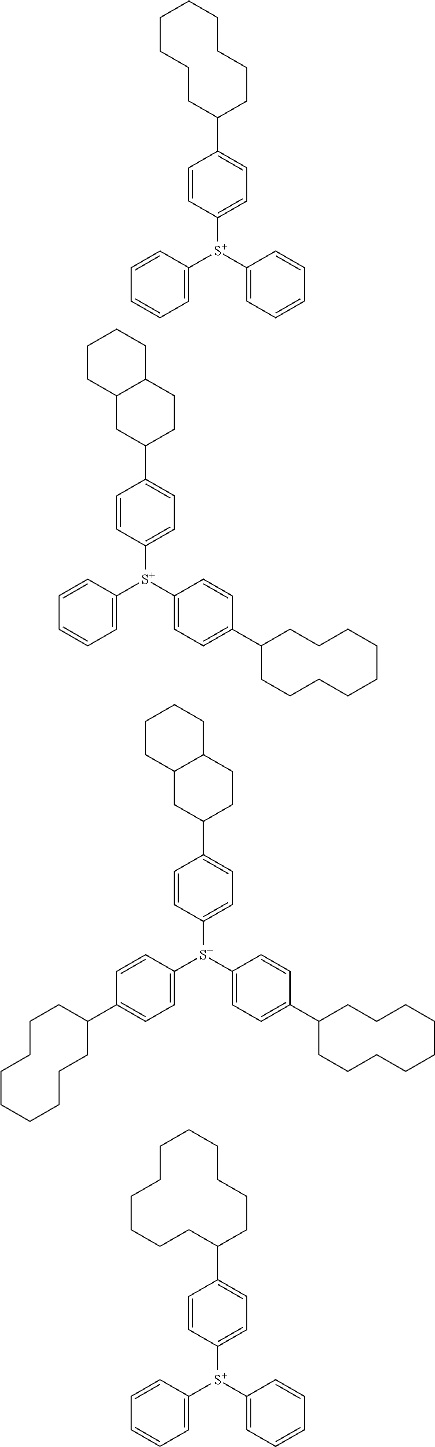

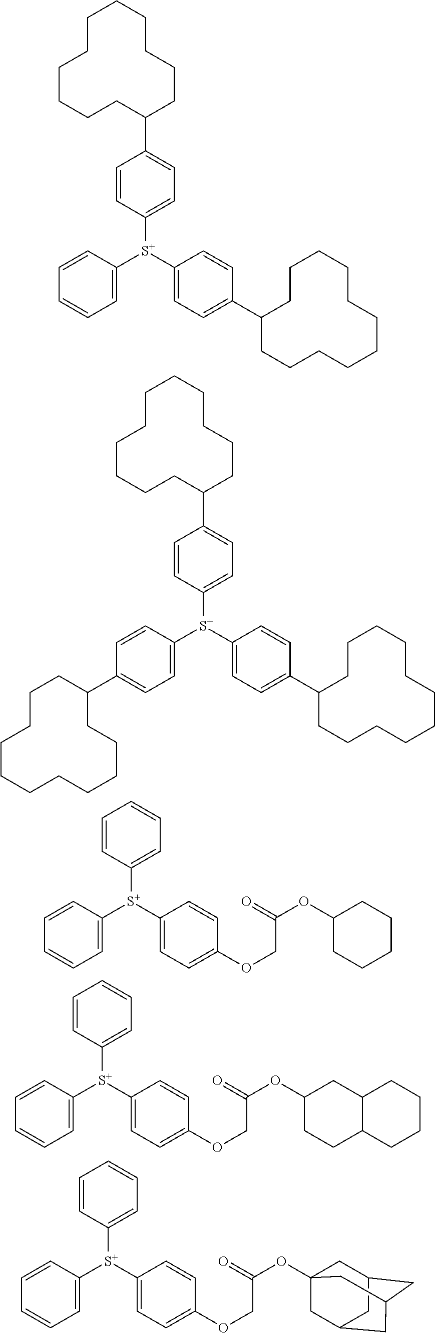

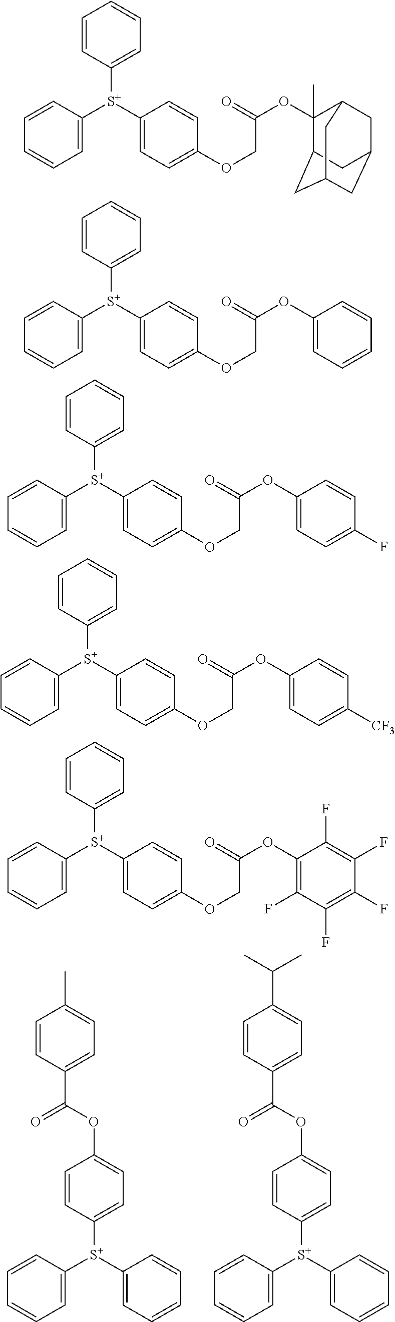

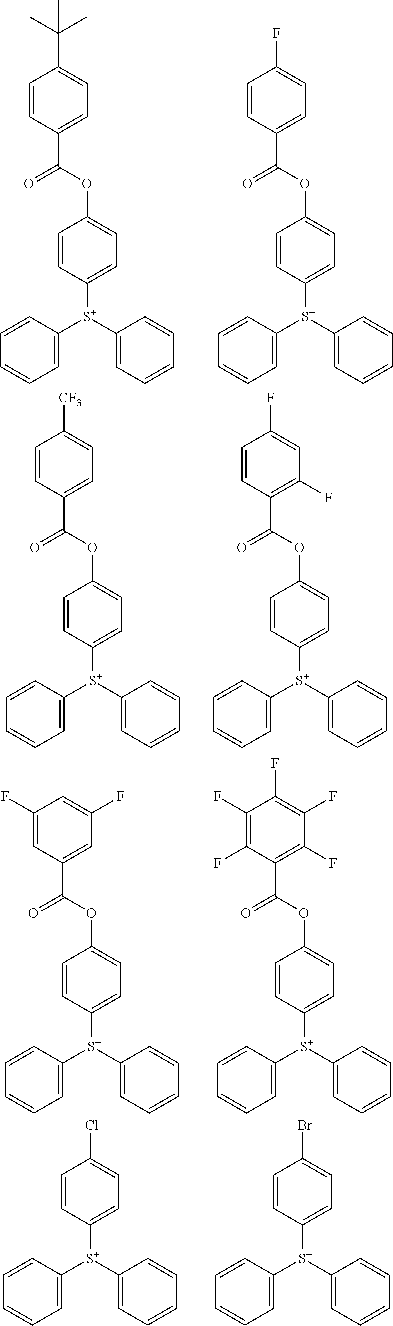

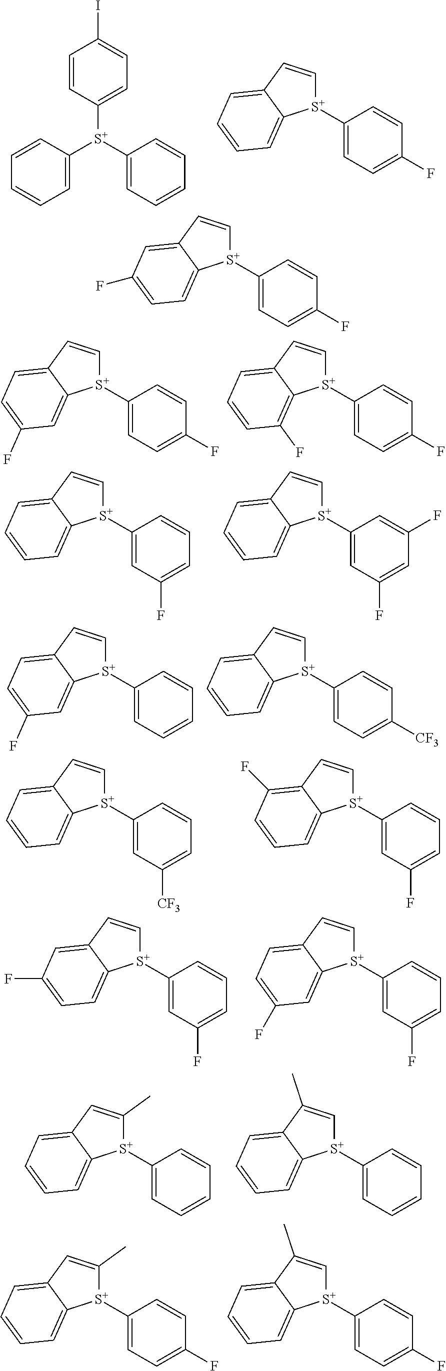

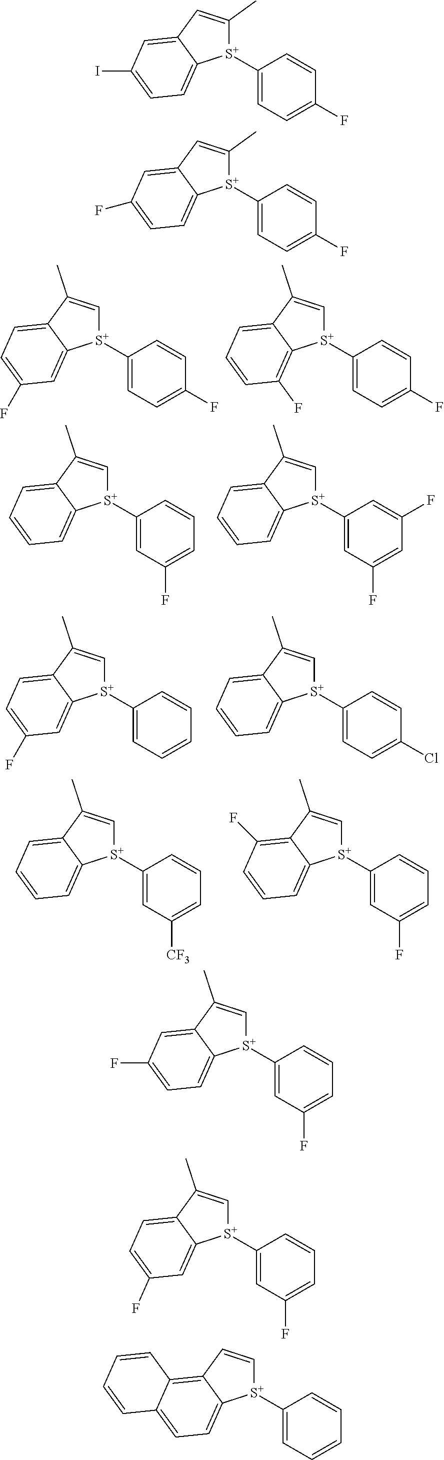

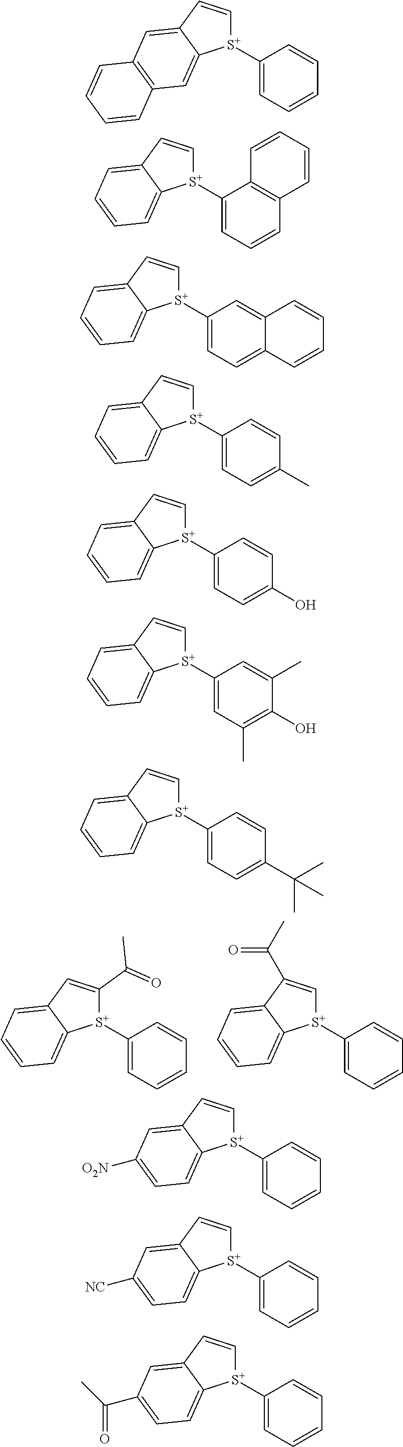

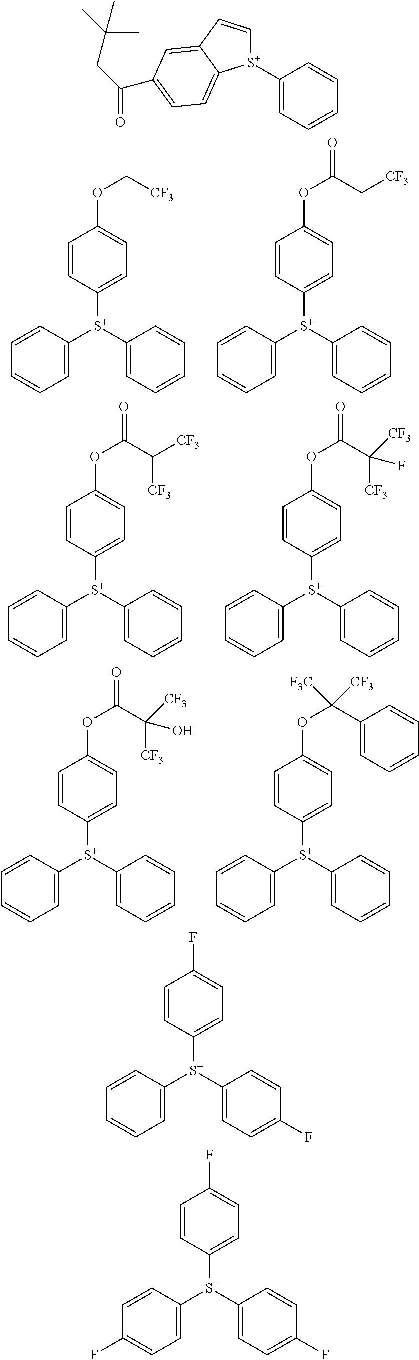

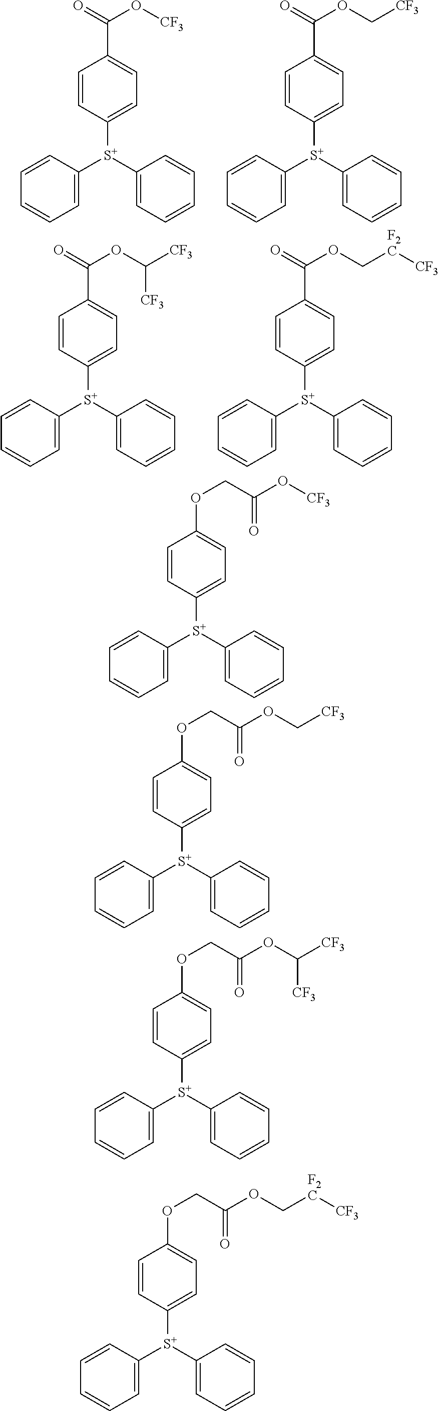

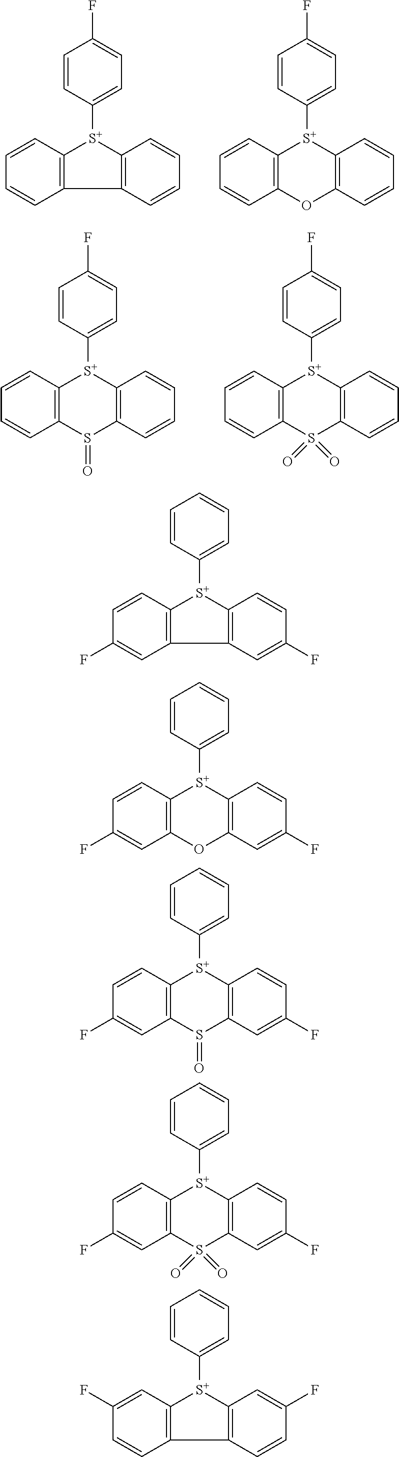

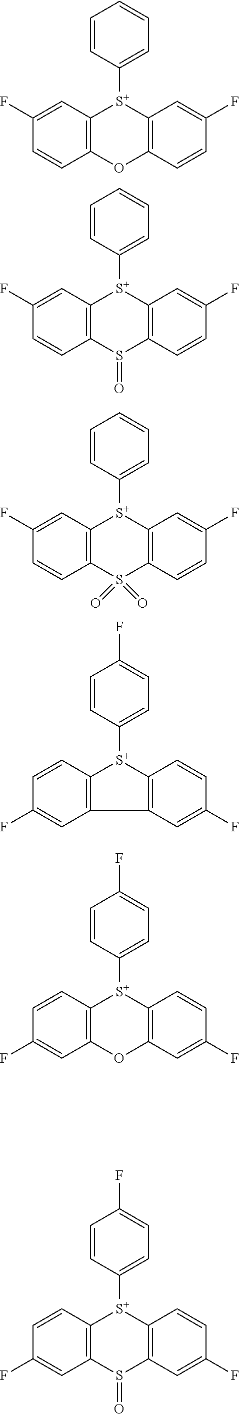

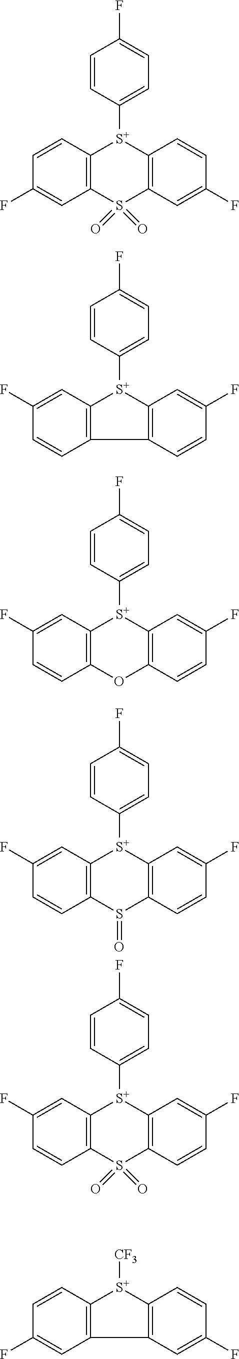

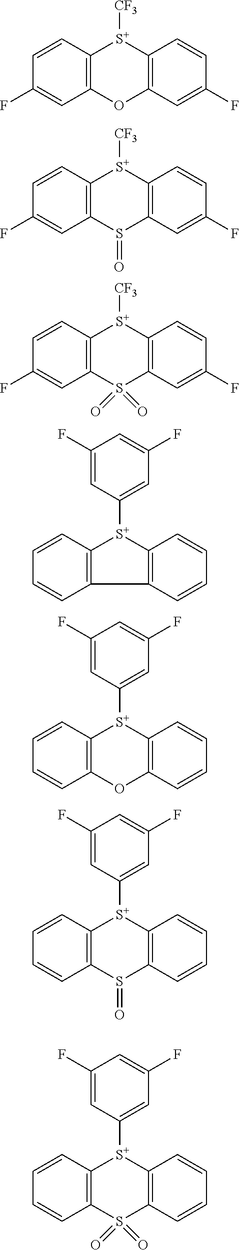

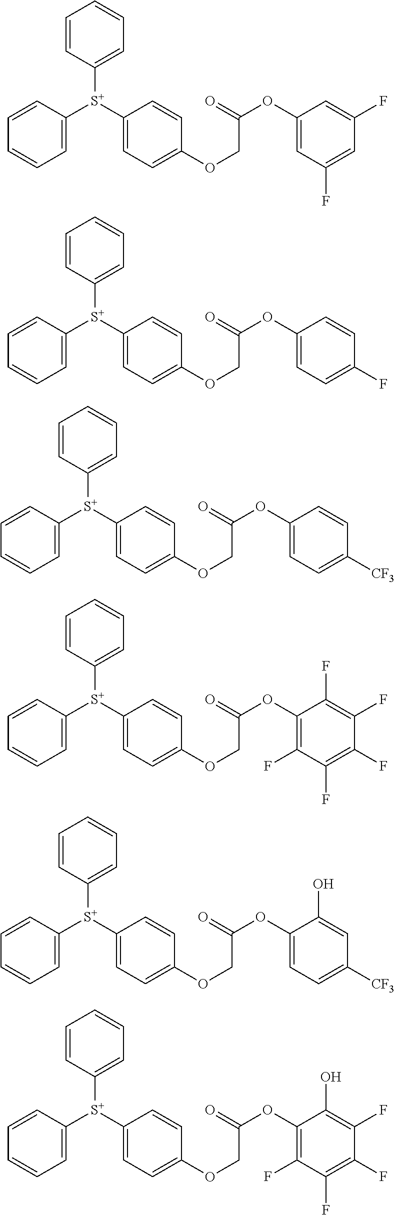

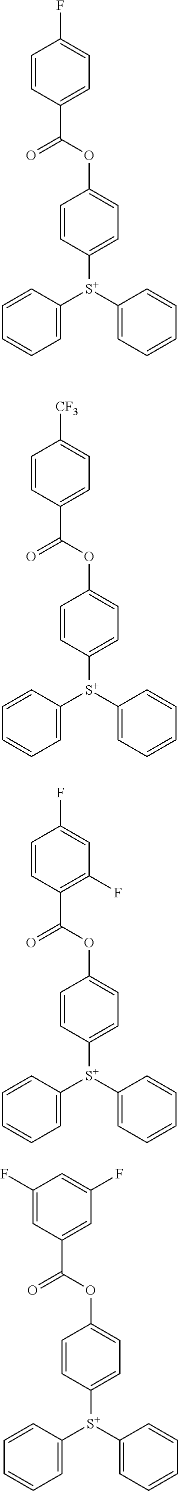

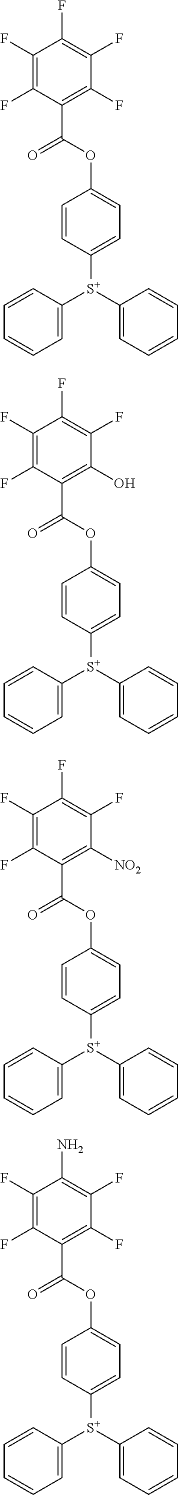

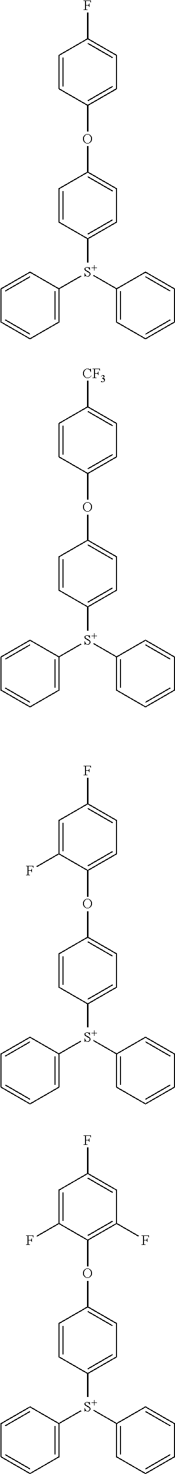

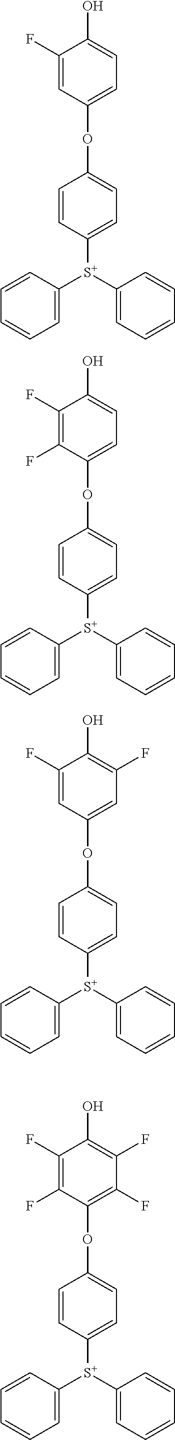

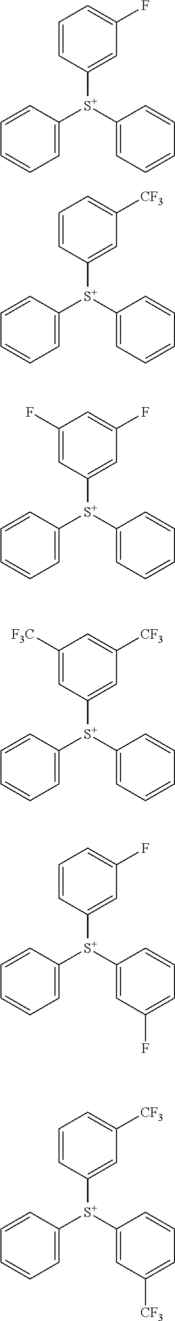

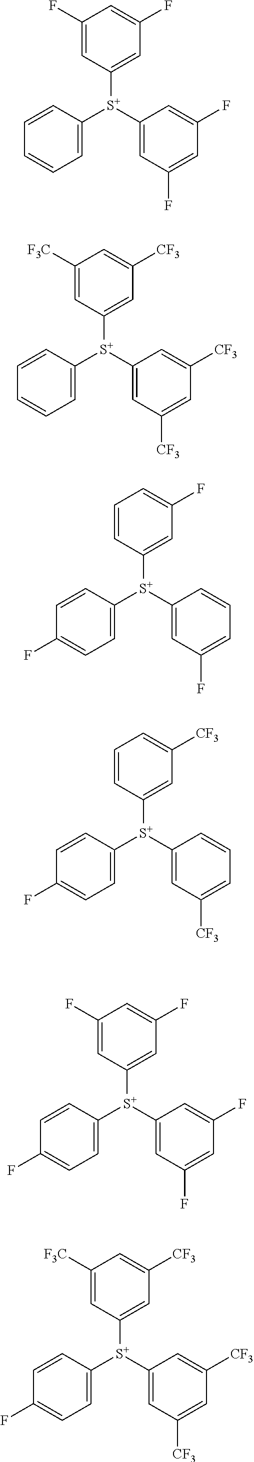

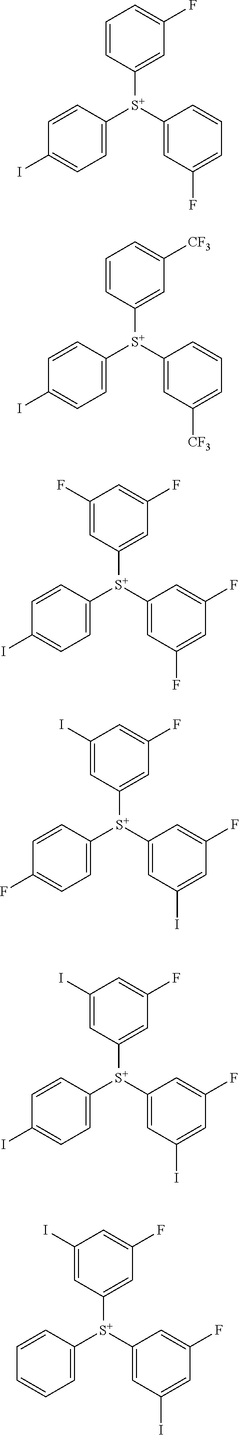

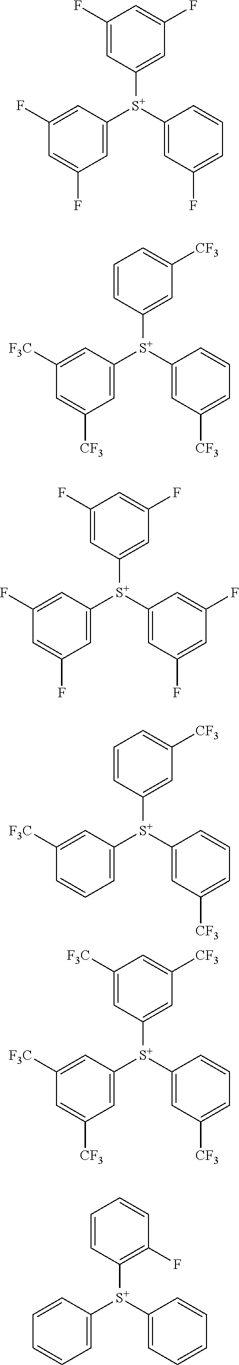

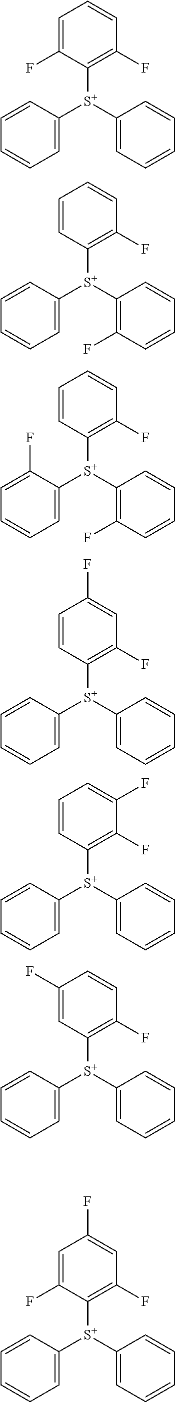

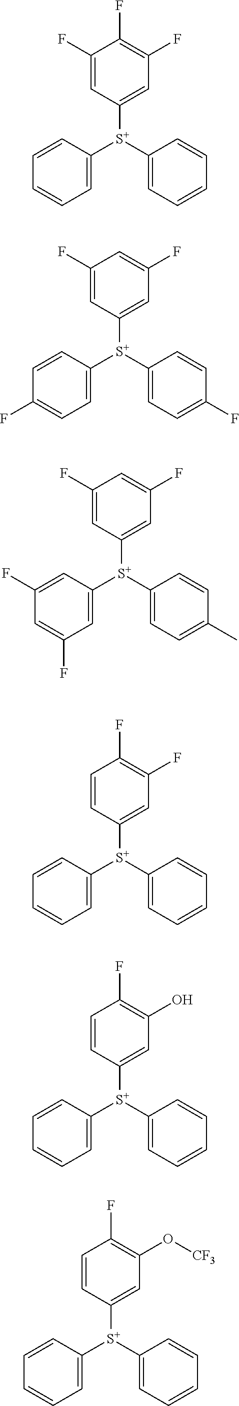

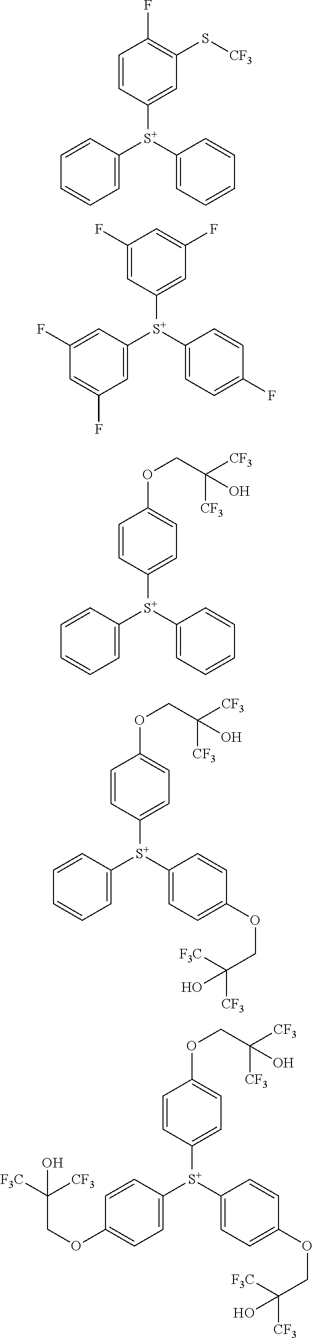

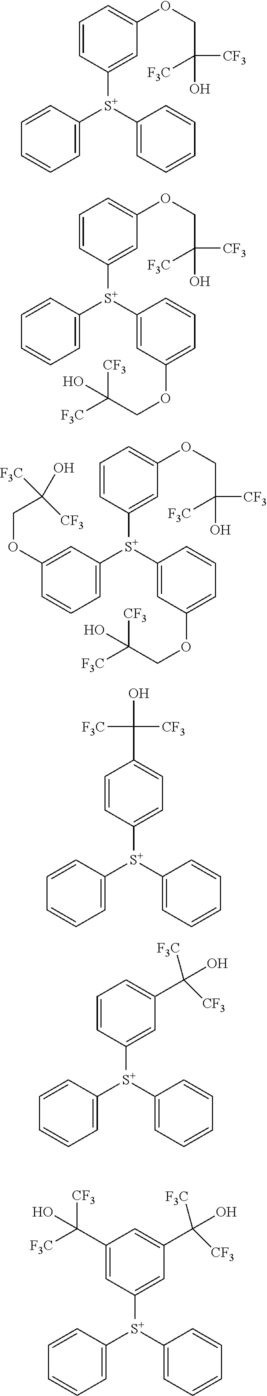

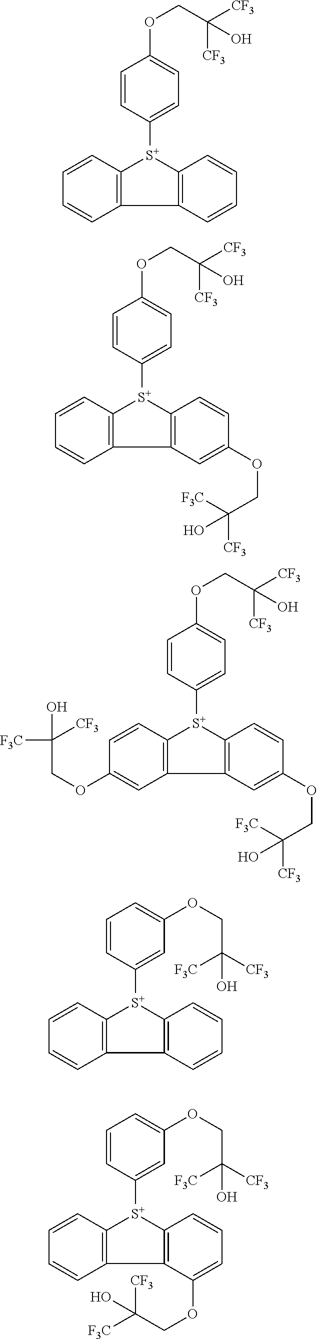

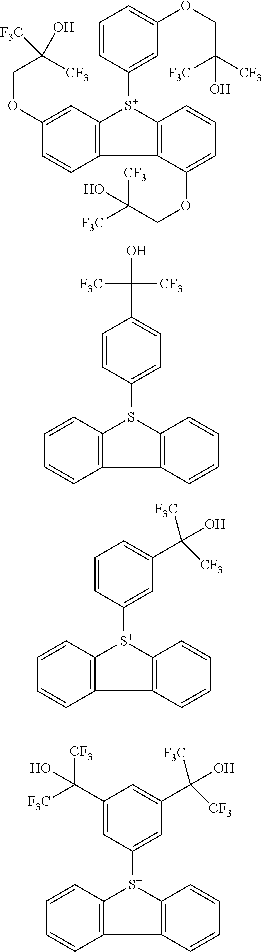

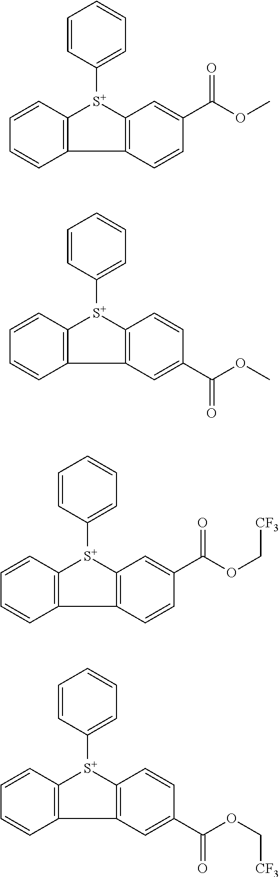

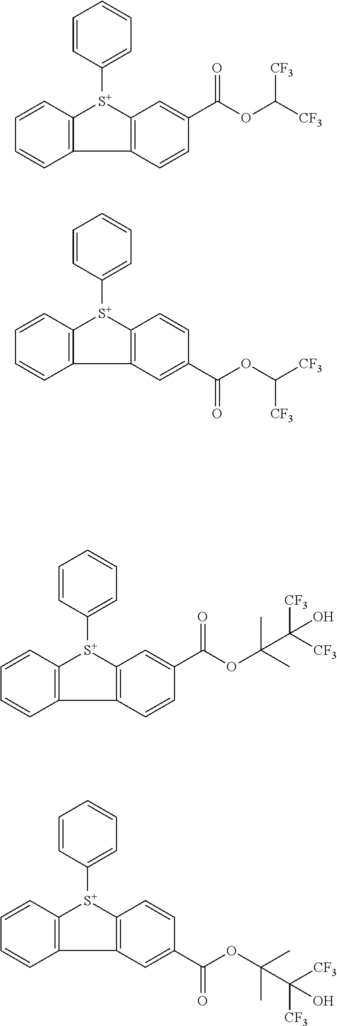

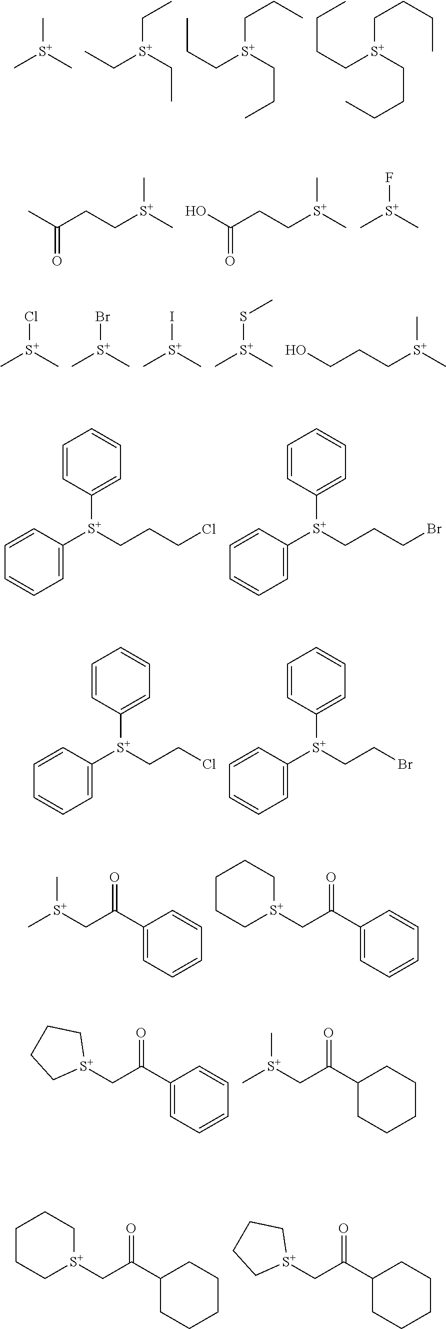

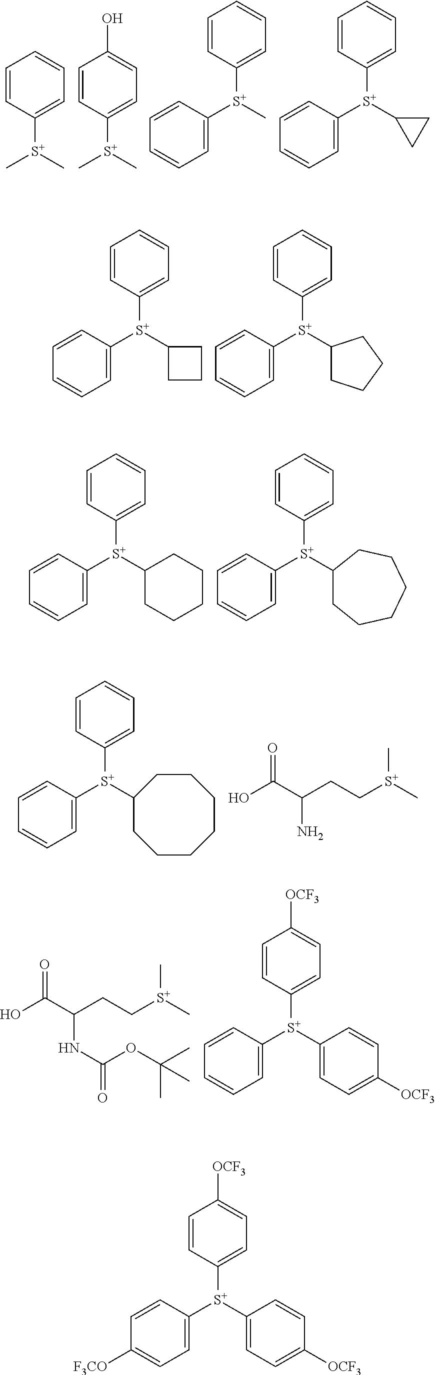

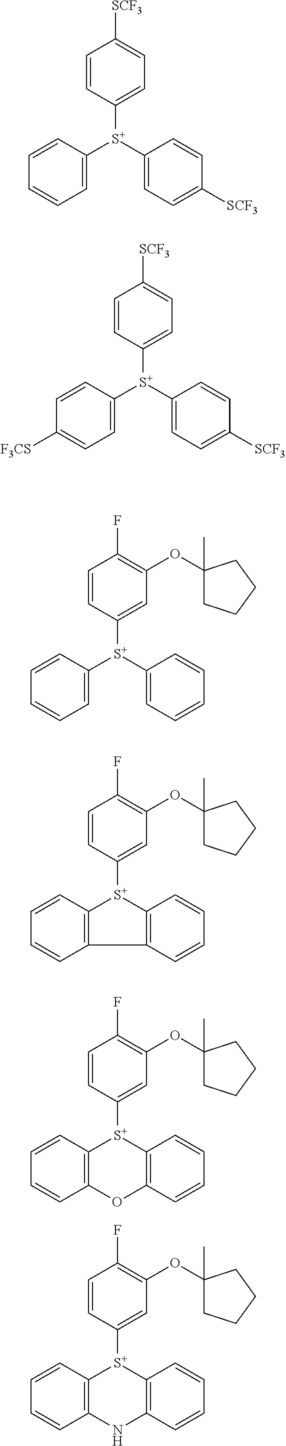

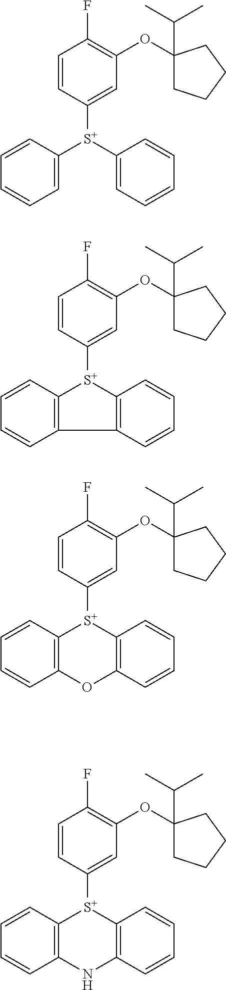

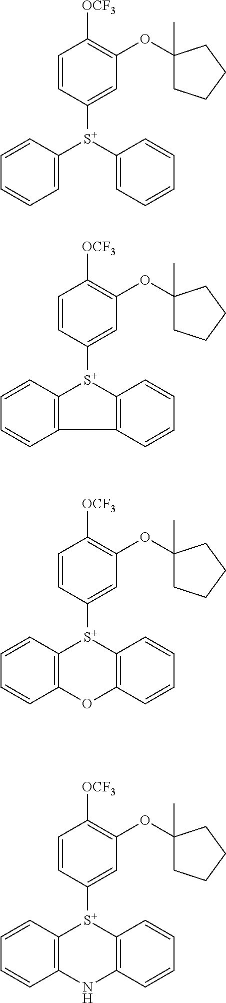

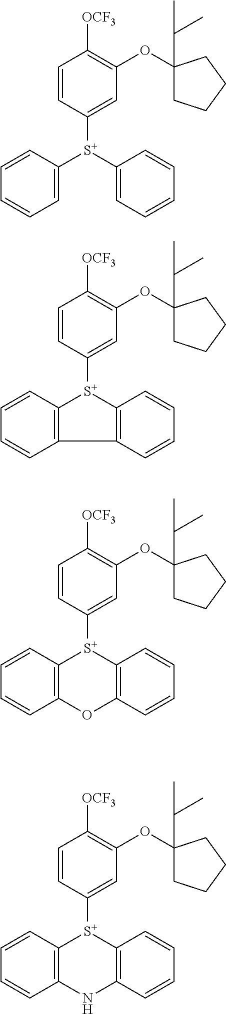

Specific examples of the iodonium cation represented by the general formula (5-2) include the following, but are not limited thereto.

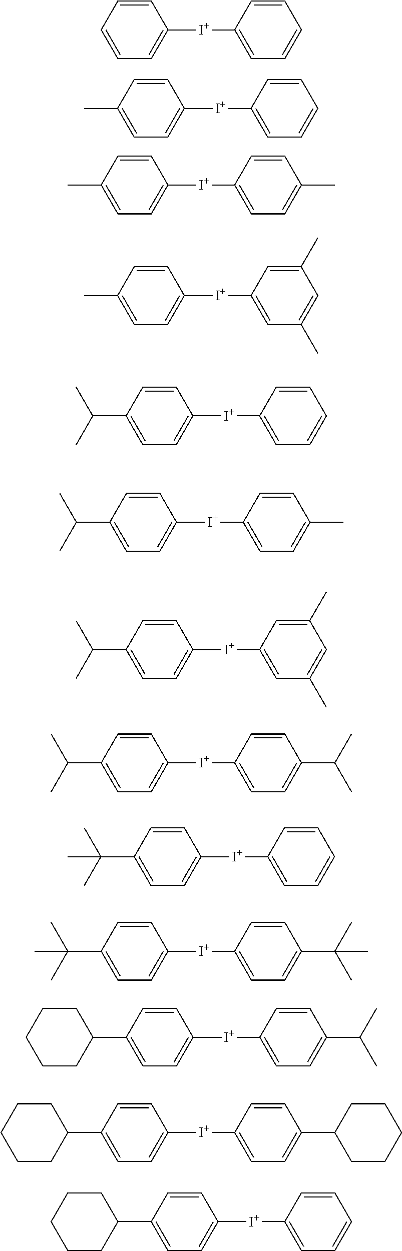

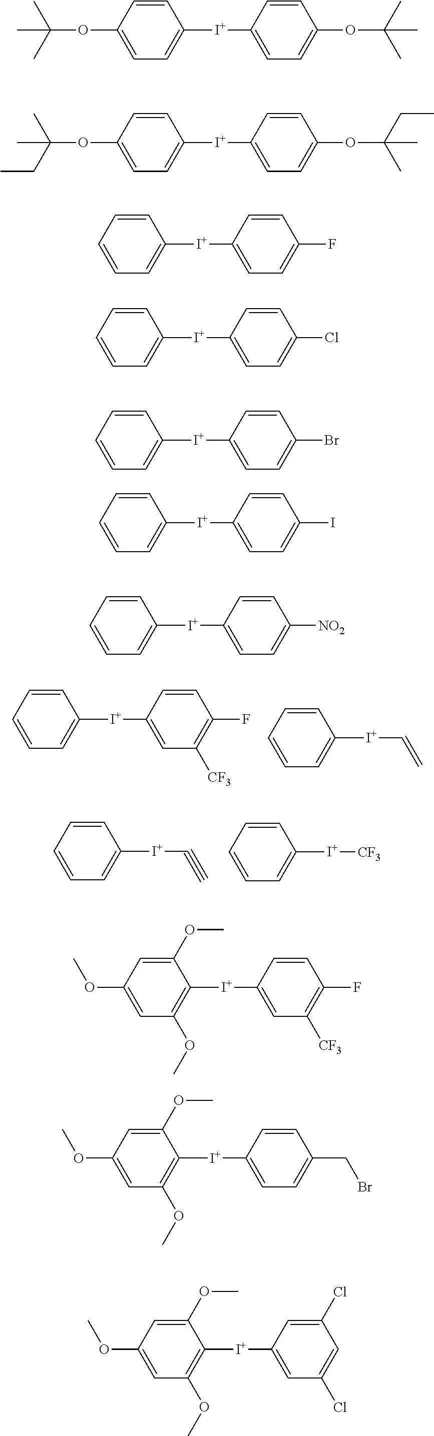

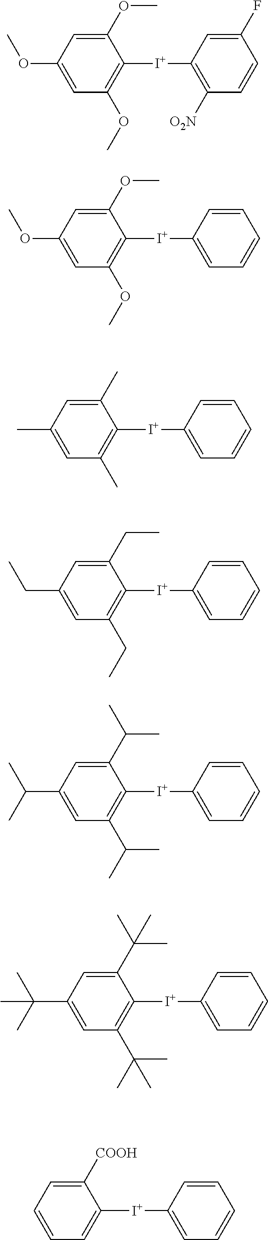

The onium salt compound contains, as an anion, a halide ion, a nitrate ion, a hydrogen sulfate ion, a hydrogen carbonate ion, a tetraphenylborate ion, or an anion represented by any of the following general formulae (5-3) to (5-9).

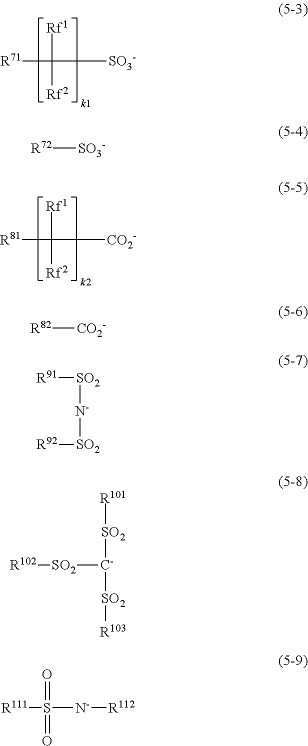

In the general formulae (5-3) and (5-5), “k1” and “k2” each independently represent an integer of 1 to 4. Rf¹ and Rf² each independently represent a hydrogen atom, a fluorine atom, or a fluorine-containing alkyl group having 1 to 6 carbon atoms, provided that not all of the Rf¹ and Rf² are hydrogen atoms at the same time.

In the general formula (5-3), R⁷¹ represents a hydrogen atom, a halogen atom, a hydroxy group, or a hydrocarbyl group having 1 to 50 carbon atoms and optionally containing a heteroatom.

In the general formula (5-4), R⁷² represents a hydrogen atom, a halogen atom, a hydroxy group, or a hydrocarbyl group having 1 to 50 carbon atoms and optionally containing a heteroatom. However, groups in which a hydrogen atom on the carbon atom in the α position and the β position of the sulfo group is substituted with a fluorine atom or a fluoroalkyl group are excluded.

In the general formula (5-5), R⁸¹ represents a hydrogen atom, a halogen atom, a hydroxy group, or a hydrocarbyl group having 1 to 50 carbon atoms and optionally containing a heteroatom.

In the general formula (5-6), R⁸² represents a hydrogen atom, a halogen atom, a hydroxy group, or a hydrocarbyl group having 1 to 50 carbon atoms and optionally containing a heteroatom. However, groups in which a hydrogen atom on the carbon atom in the α position and the β position of the carboxy group is substituted with a fluorine atom or a fluoroalkyl group are excluded.

In the general formula (5-7), R⁹¹ and R⁹² each independently represent a hydrocarbyl group having 1 to 50 carbon atoms and optionally containing a heteroatom.

In the general formula (5-8), R¹⁰¹ to R¹⁰³ each independently represent a hydrocarbyl group having 1 to 50 carbon atoms and optionally containing a heteroatom.

In the general formula (5-9), R¹¹¹ represents a fluorine atom or a fluorinated hydrocarbyl group having 1 to 10 carbon atoms, and the fluorinated hydrocarbyl group may contain a hydroxy group, an ether bond, or an ester bond. R¹¹² represents a hydrogen atom or a hydrocarbyl group having 1 to 20 carbon atoms, and the hydrocarbyl group may contain a hydroxy group, an ether bond, or an ester bond. Furthermore, R¹¹¹ and R¹¹² may be bonded to each other to form a ring together with the atoms bonded thereto.

As the anions of the onium salt compounds, a halide ion, a nitrate ion, and an anion represented by any of the general formulae (5-3) to (5-9) are preferable, and a halide ion, a nitrate ion, or an anion represented by the general formula (5-4), (5-6), or (5-8) is more preferable.

The hydrocarbyl group represented by R⁷¹, R⁷², R⁸¹, R⁸², R⁹¹, R⁹², R¹⁰¹, R¹⁰², and R¹⁰³ having 1 to 50 carbon atoms may be saturated or unsaturated, and may be linear, branched, or cyclic. Specific examples thereof include: alkyl groups having 1 to 50 carbon atoms, such as a methyl group, an ethyl group, a propyl group, an isopropyl group, an n-butyl group, a sec-butyl group, a tert-butyl group, a tert-pentyl group, an n-pentyl group, an n-hexyl group, an n-octyl group, a 2-ethylhexyl group, an n-nonyl group, and an n-decyl group; cyclic saturated hydrocarbyl groups having 3 to 50 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; alkenyl groups having 2 to 50 carbon atoms, such as a vinyl group, a 1-propenyl group, a 2-propenyl group, a butenyl group, and a hexenyl group; cyclic unsaturated hydrocarbyl groups having 3 to 50 carbon atoms, such as a cyclohexenyl group; aryl groups having 6 to 50 carbon atoms, such as a phenyl group, a naphthyl group, and an anthracenyl group; and groups which are combinations of these groups. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— constituting the hydrocarbyl group may be substituted with a group containing a heteroatom such as an oxygen atom, a sulfur atom, or a nitrogen atom. The resulting hydrocarbyl group may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc.

The fluorinated hydrocarbyl group represented by R¹¹¹ having 1 to 10 carbon atoms is a group in which part or all of the hydrogen atoms of a hydrocarbyl group having 1 to 10 carbon atoms are substituted with a fluorine atom. The hydrocarbyl group having 1 to 10 carbon atoms may be saturated or unsaturated, and may be linear, branched, or cyclic. Specific examples thereof include groups having 1 to 10 carbon atoms out of the groups given as examples of the hydrocarbyl group represented by R⁷¹, R⁷², R⁸¹, R⁸², R⁹¹, R⁹², R¹⁰¹, R¹⁰², and R¹⁰³ having 1 to 50 carbon atoms.

The hydrocarbyl group represented by R¹¹² having 1 to 20 carbon atoms may be saturated or unsaturated, and may be linear, branched, or cyclic. Specific examples thereof include groups having 1 to 20 carbon atoms out of the groups given as examples of the hydrocarbyl group represented by R⁷¹, R⁷², R⁸¹, R⁸², R⁹¹, R⁹², R¹⁰¹, R¹⁰², and R¹⁰³ having 1 to 50 carbon atoms.

The anion represented by any of the general formulae (5-3) to (5-9) may contain a polymerizable functional group in its structure, and may have a hydrocarbyl group having 2 to 50 carbon atoms and optionally containing a heteroatom. Specific examples thereof include the following (A-1 to A-57), but are not limited thereto.

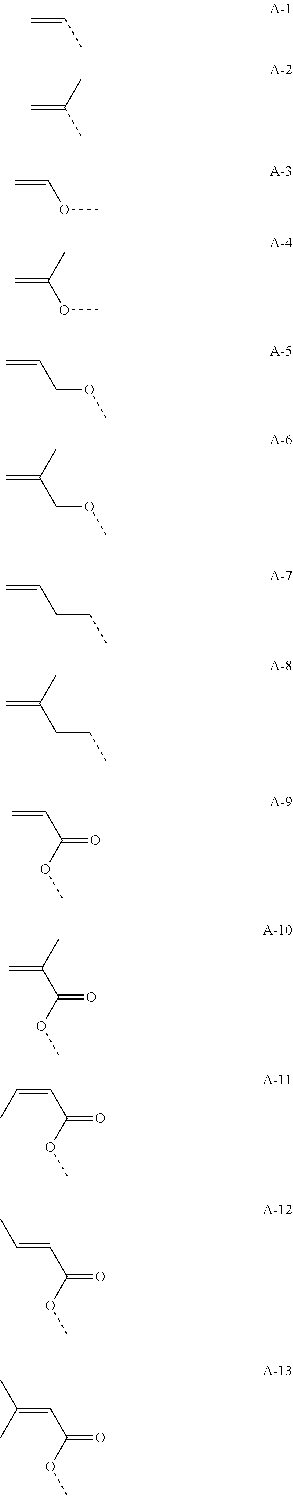

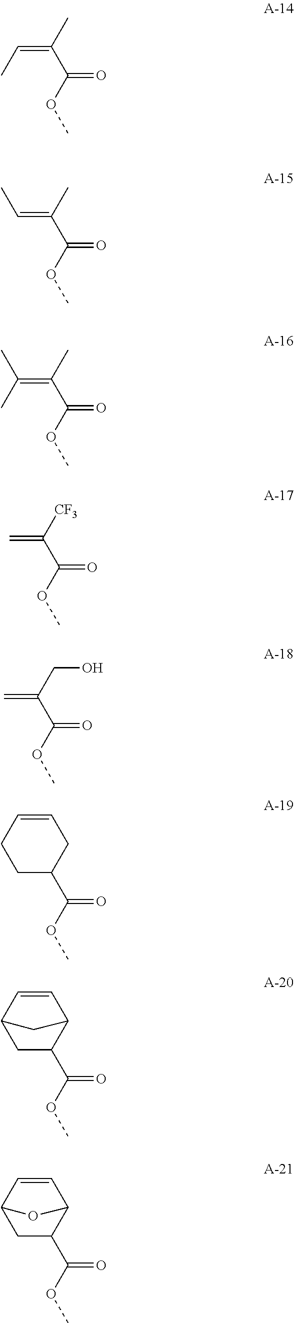

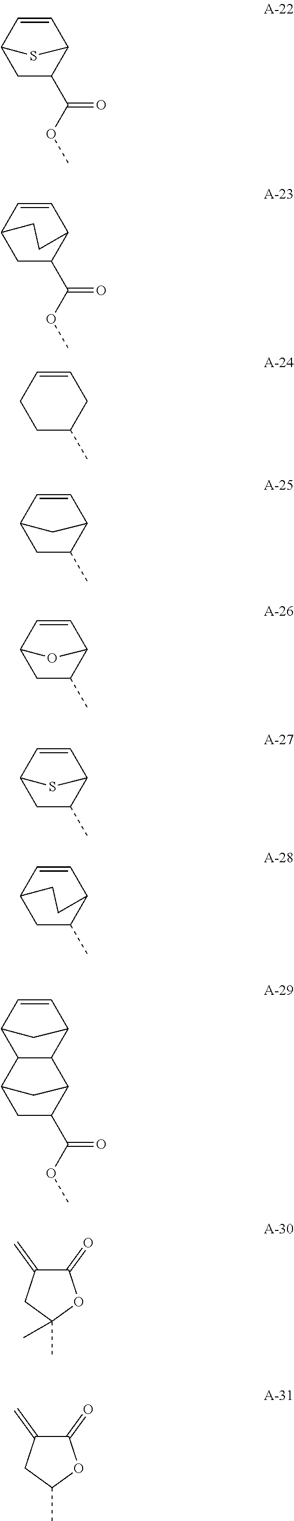

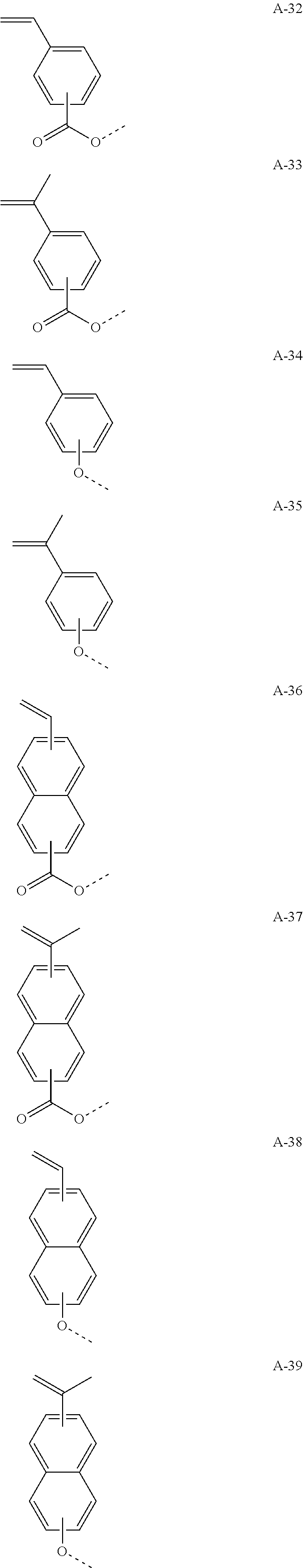

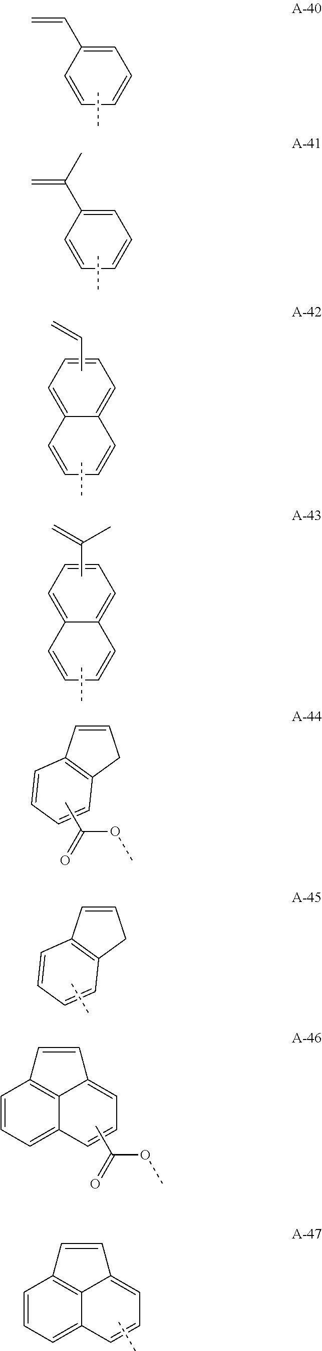

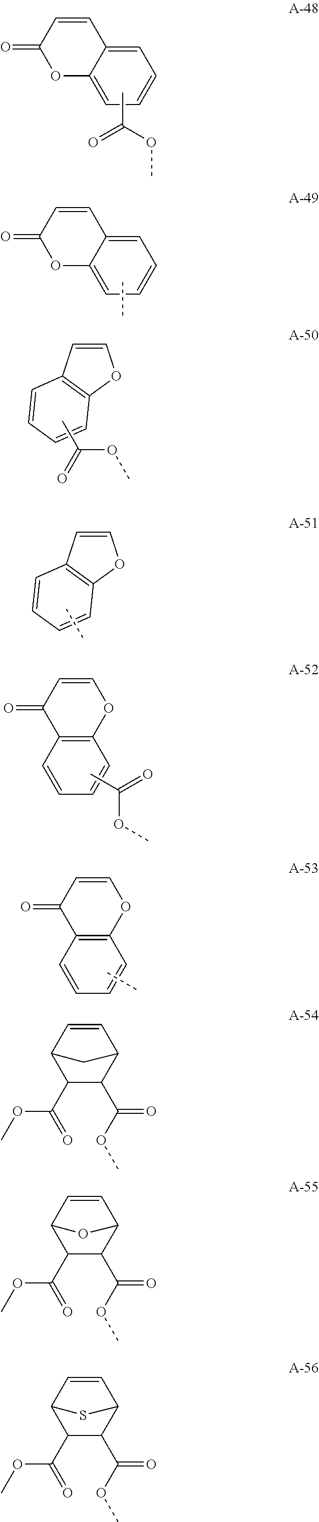

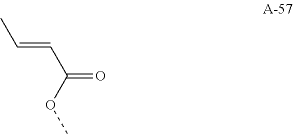

Specific examples of the anion represented by the general formula (5-3) include the following, but are not limited thereto. Note that, in the following formulae, Ac represents an acetyl group and Rf¹ is as defined above.

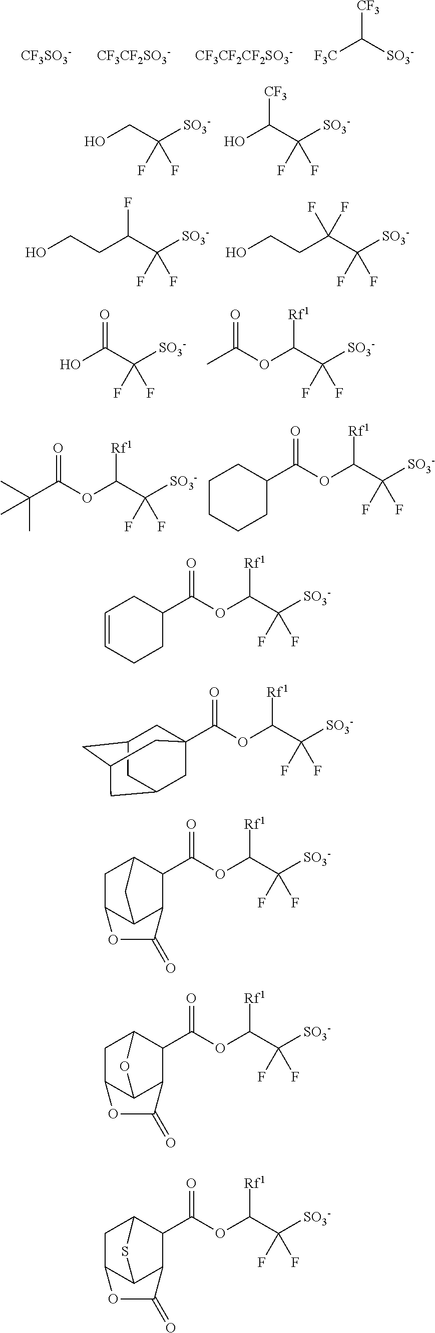

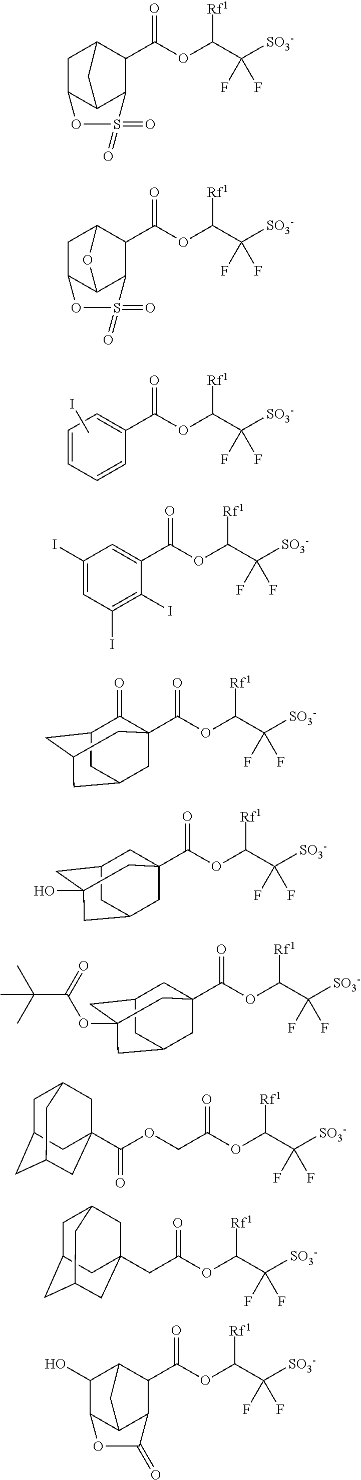

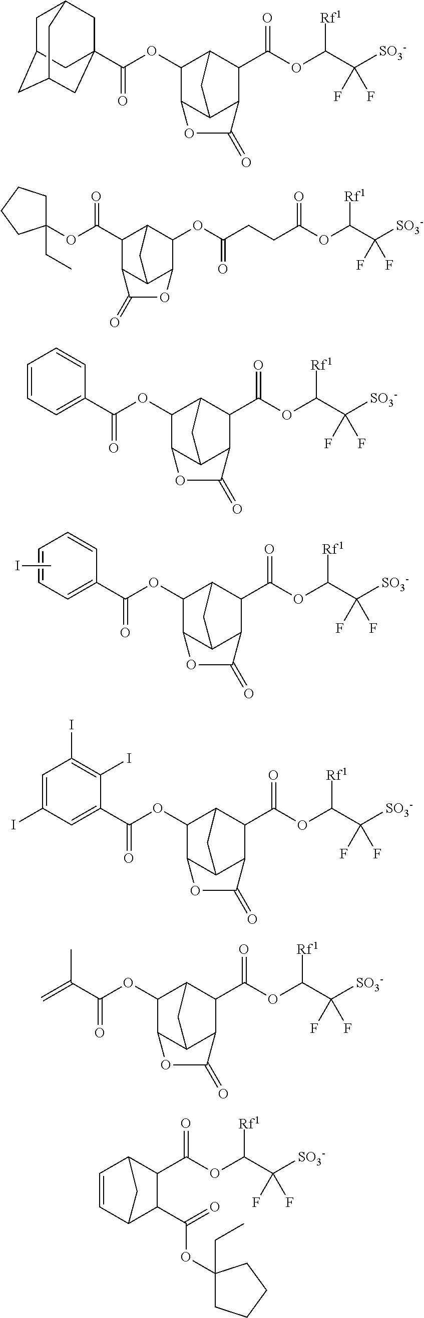

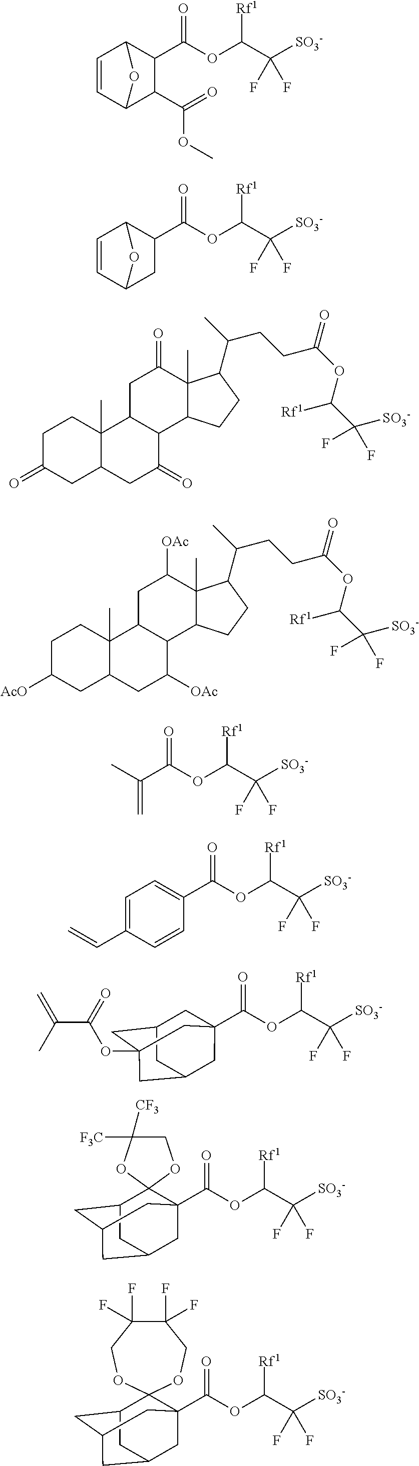

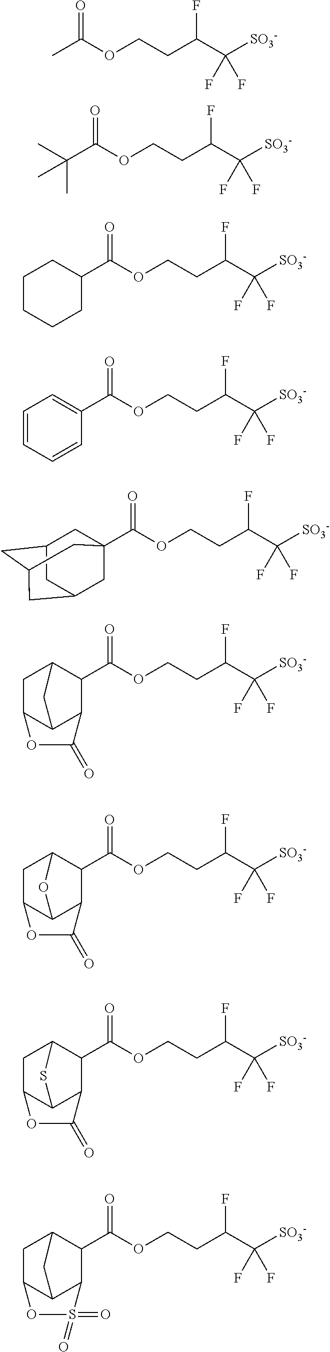

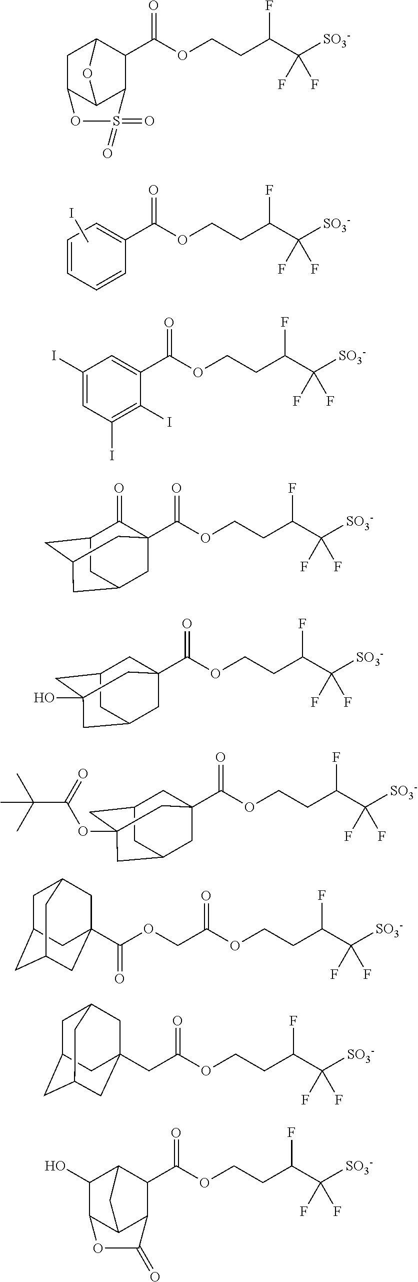

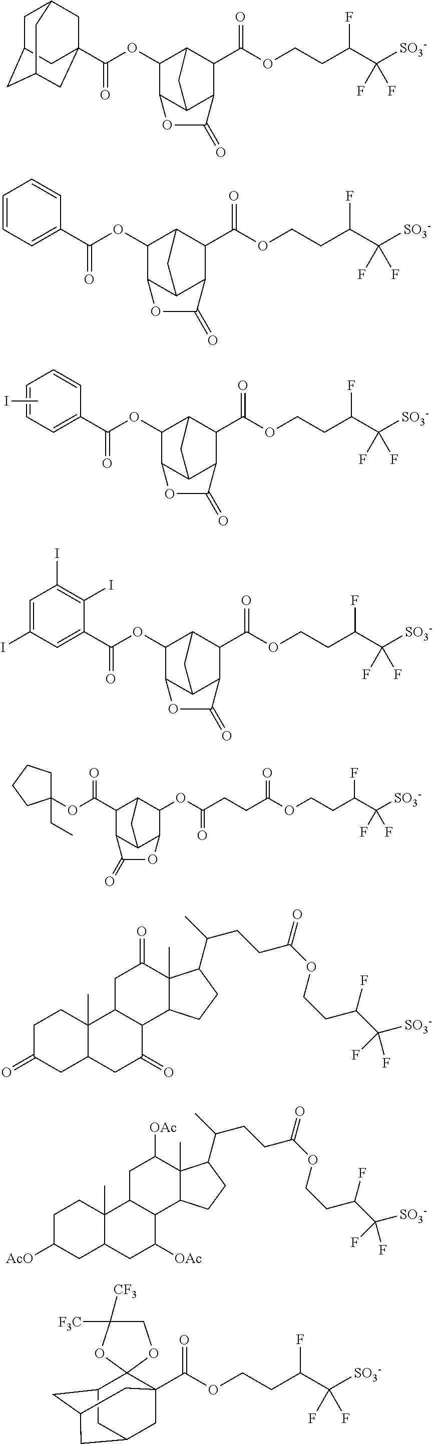

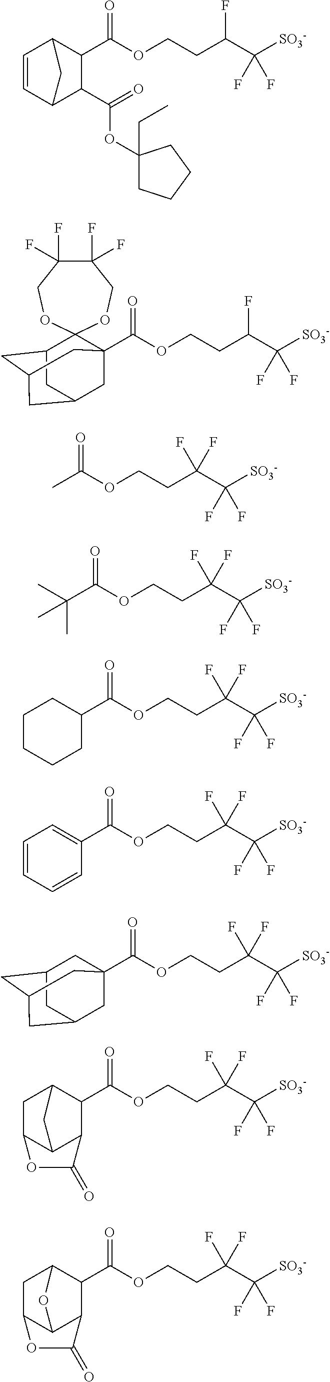

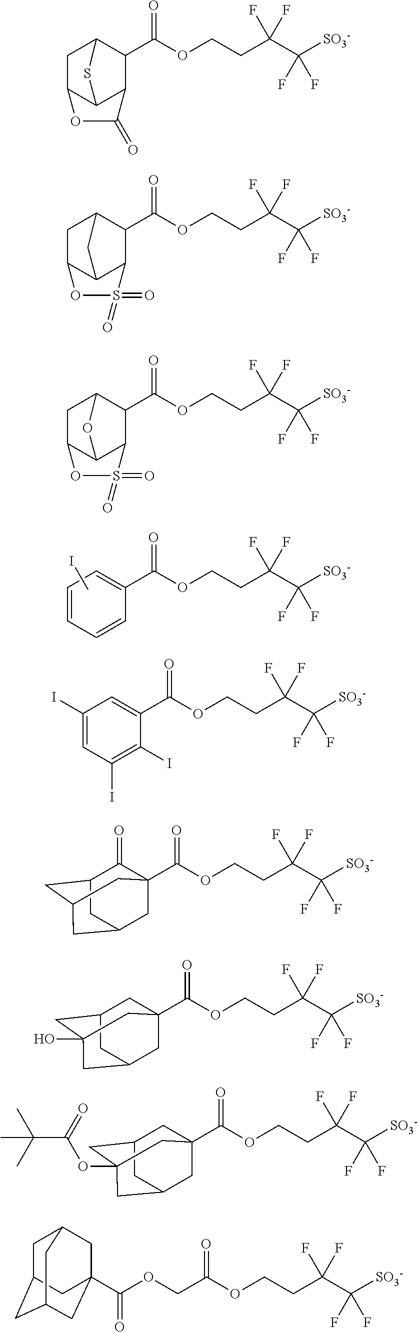

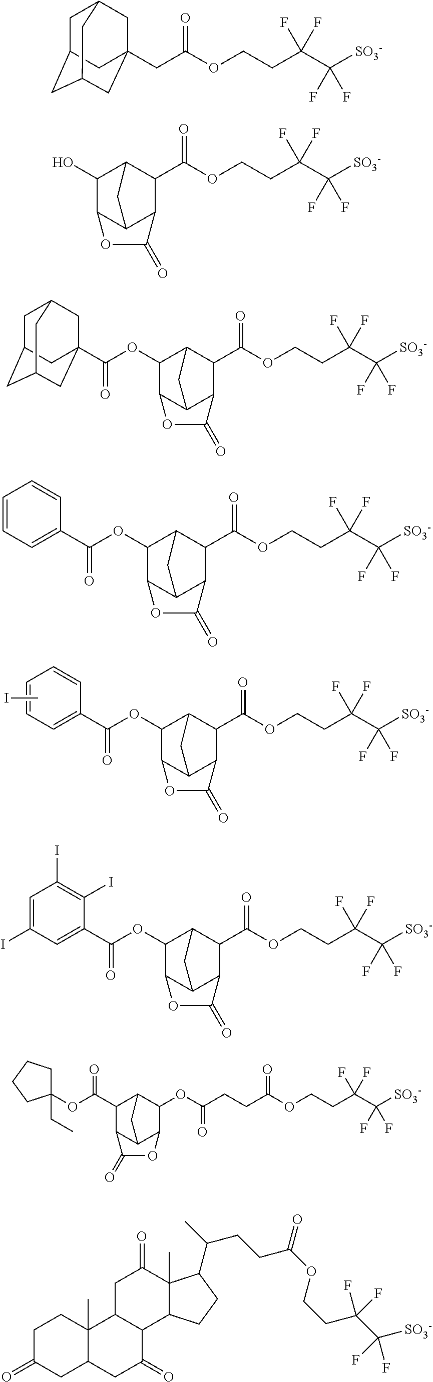

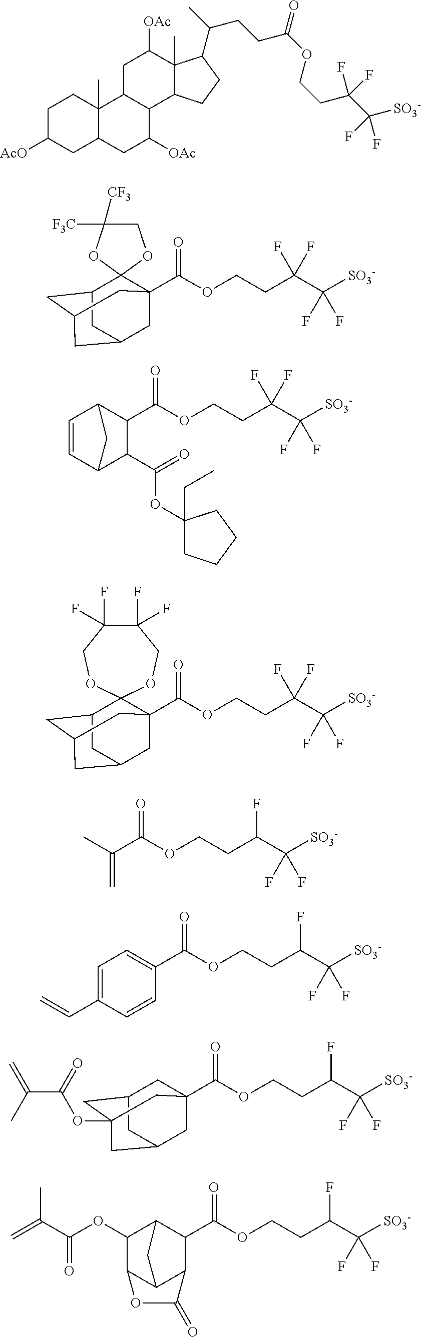

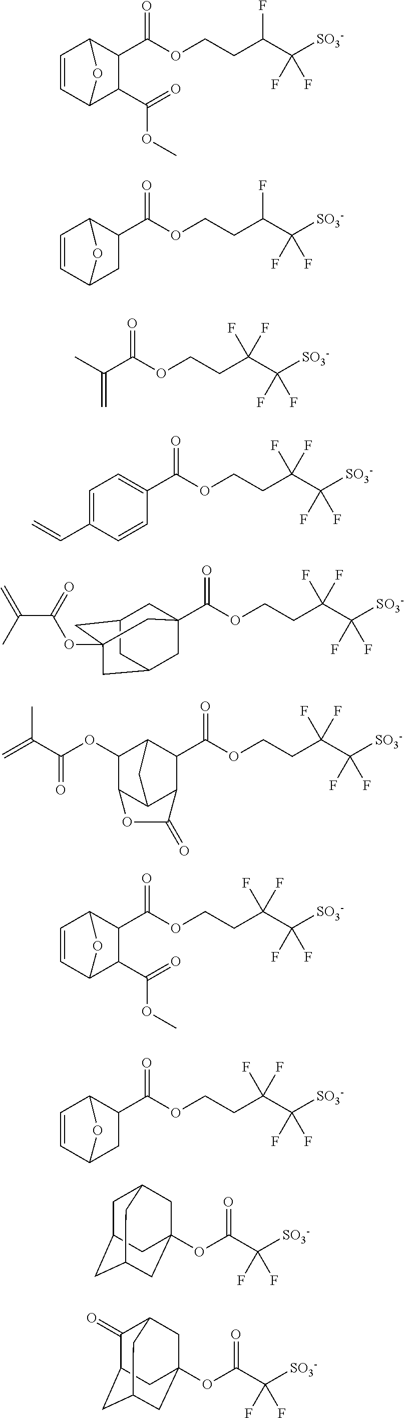

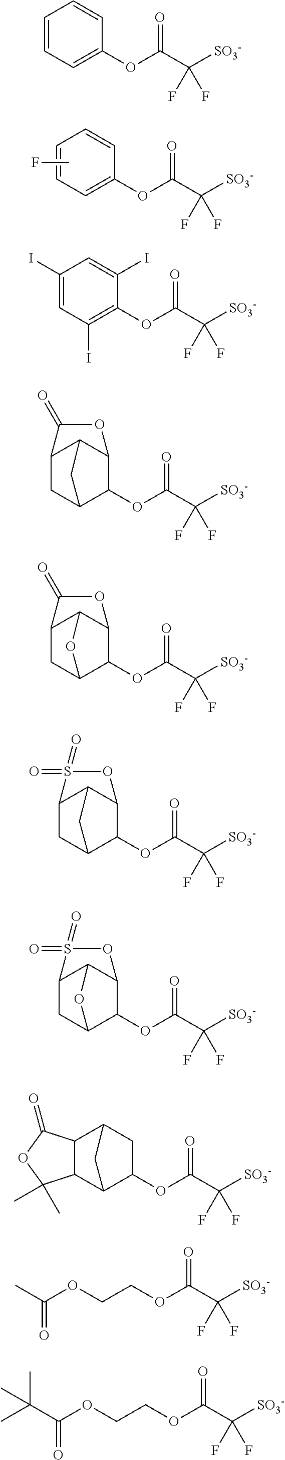

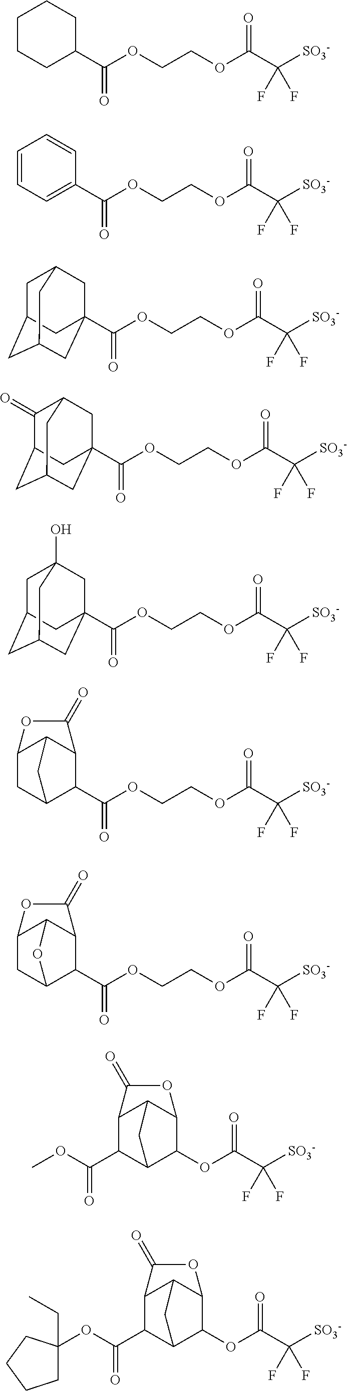

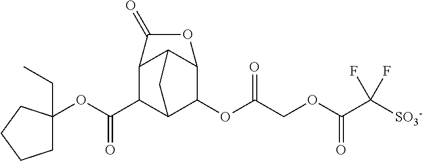

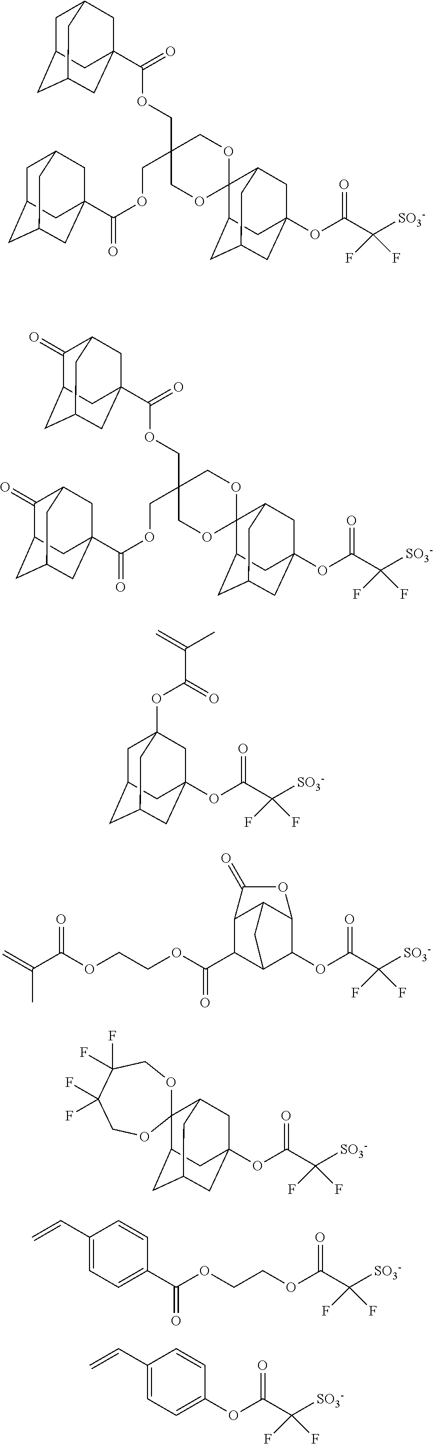

Specific examples of the anion represented by the general formula (5-4) include the following, but are not limited thereto.

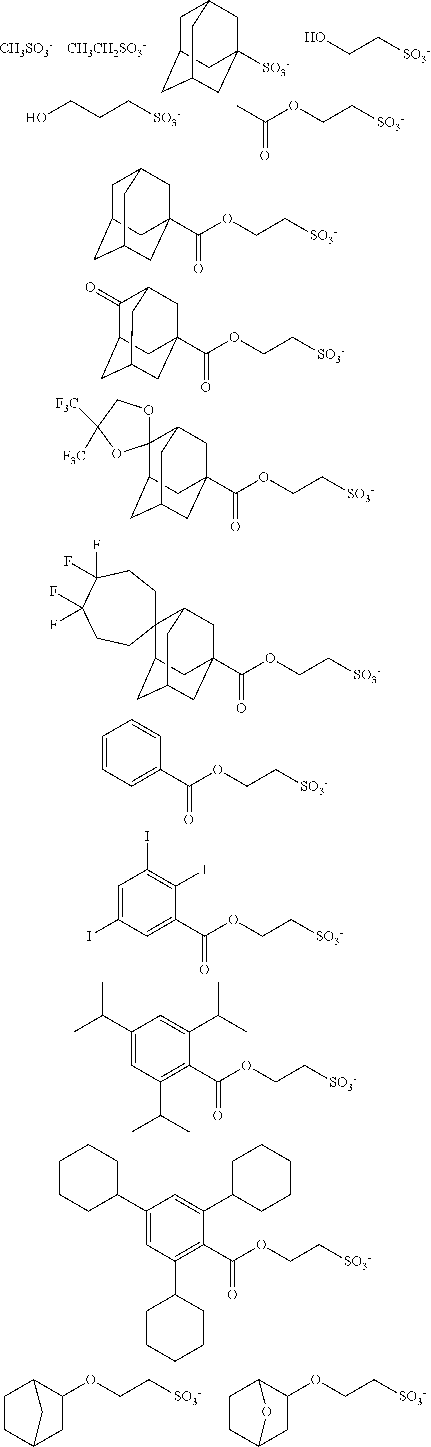

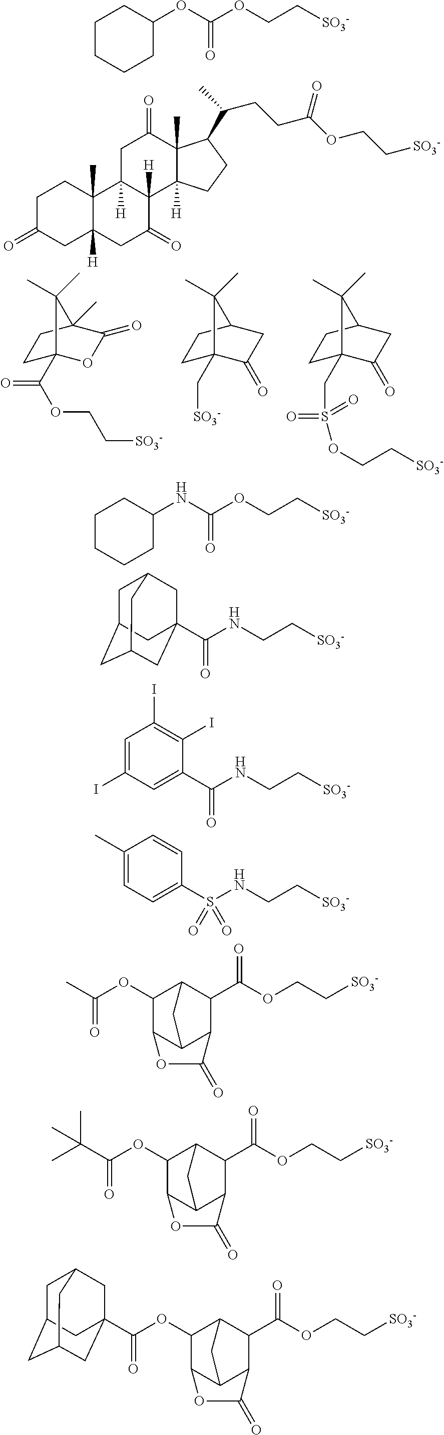

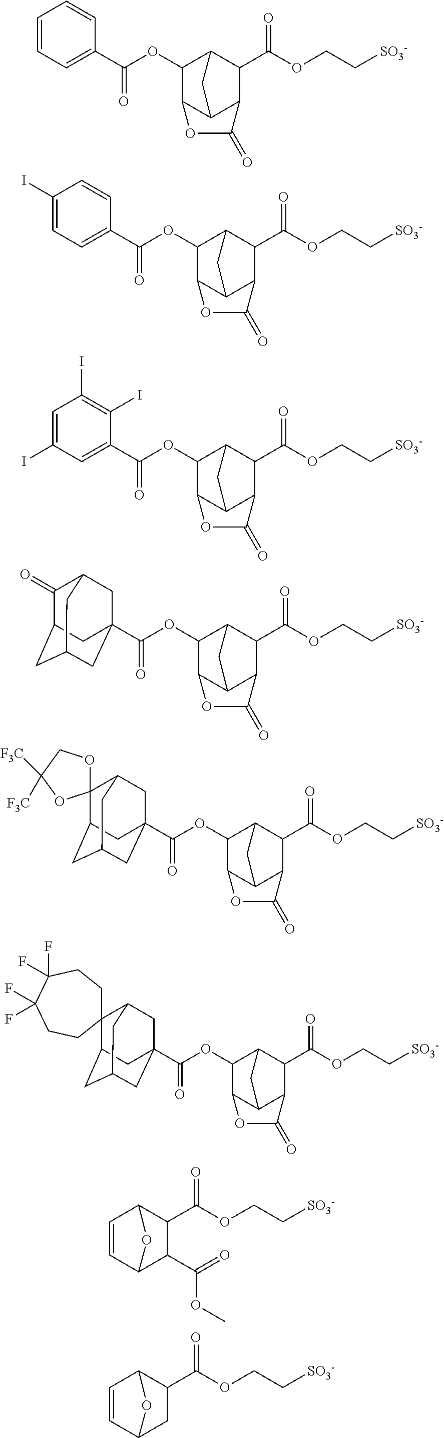

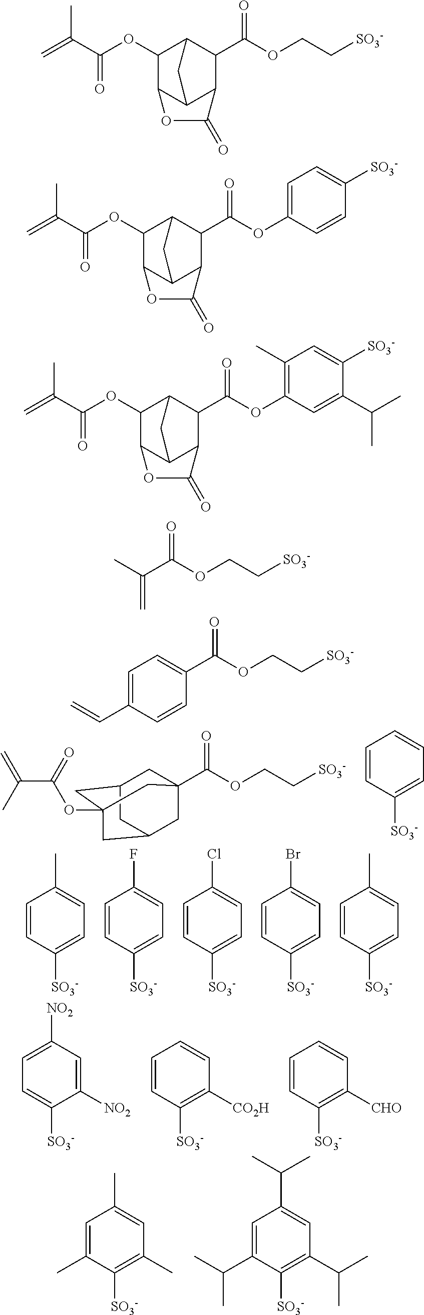

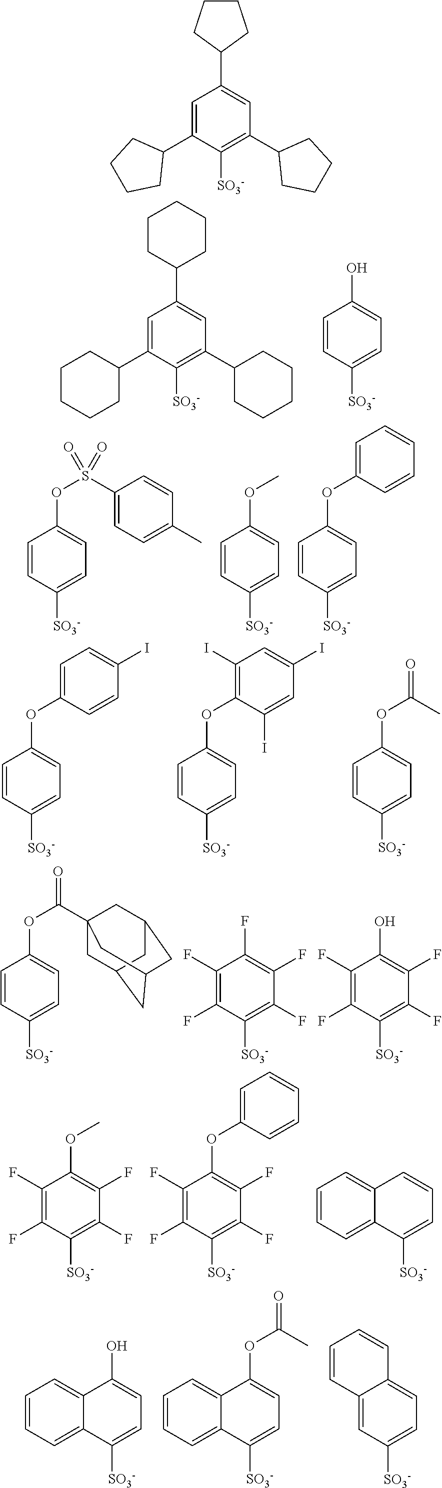

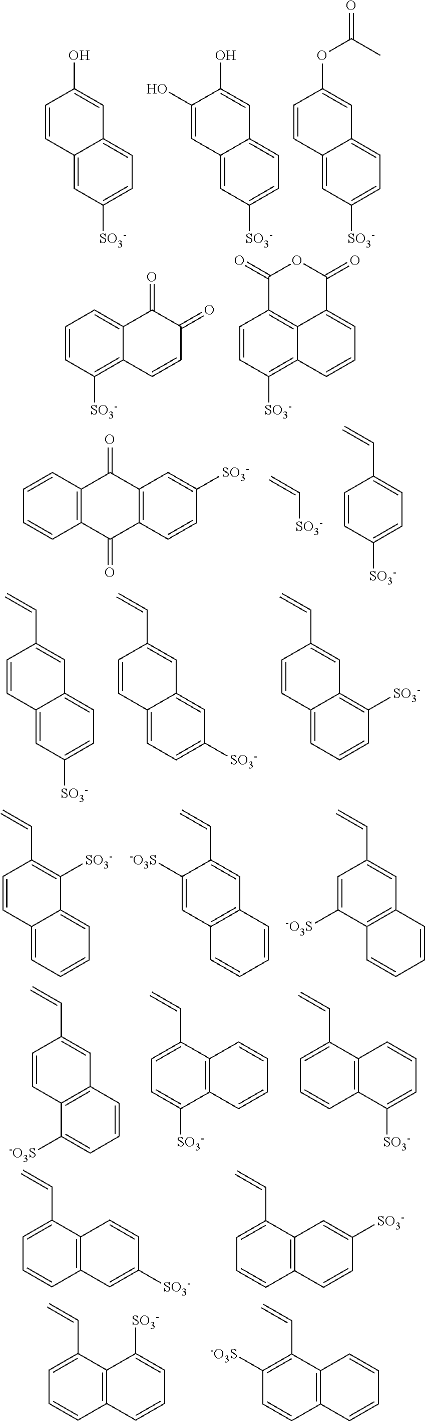

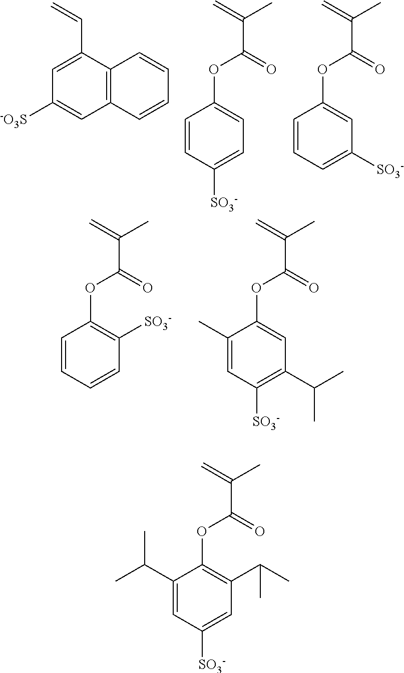

Specific examples of the anion represented by the general formula (5-5) include the following, but are not limited thereto.

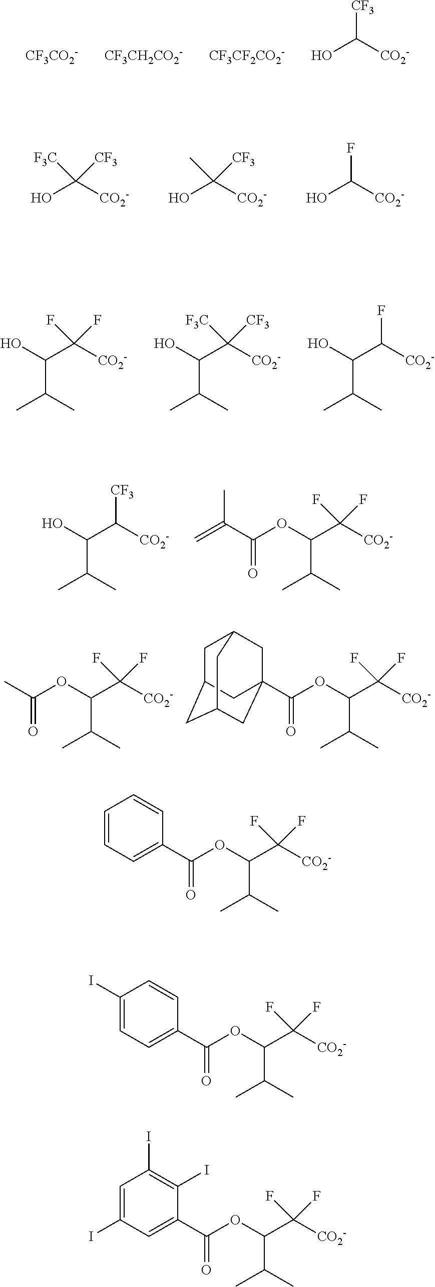

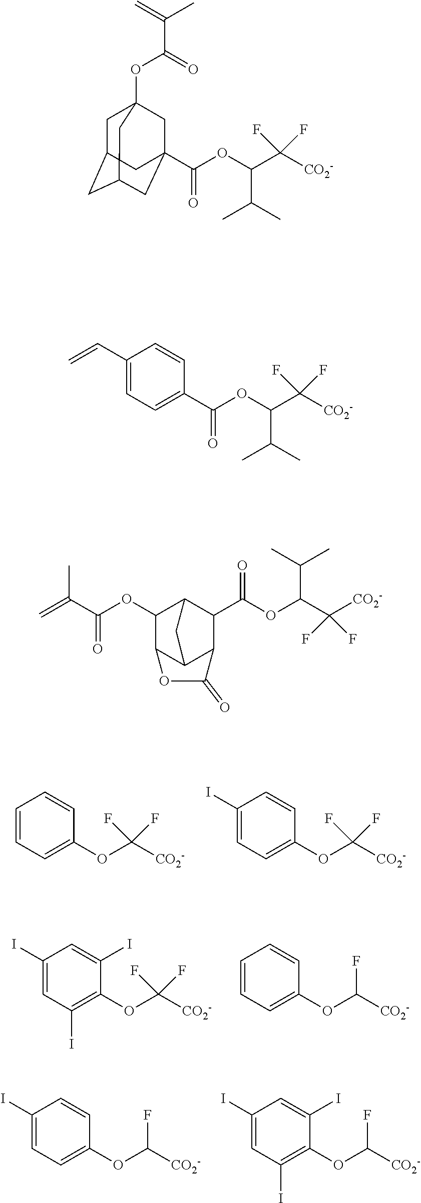

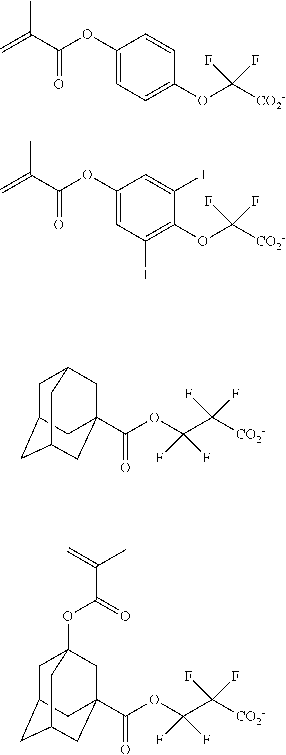

Specific examples of the anion represented by the general formula (5-6) include the following, but are not limited thereto.

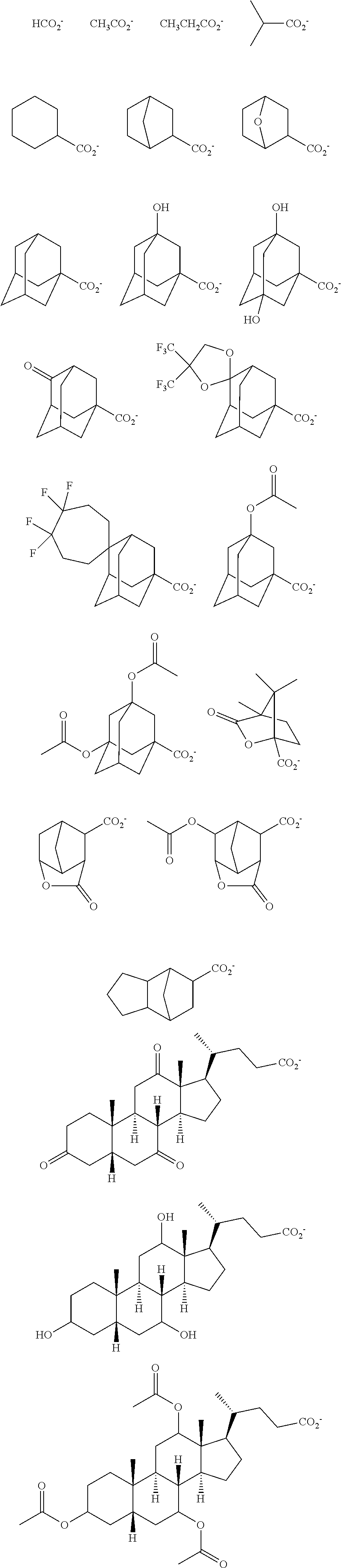

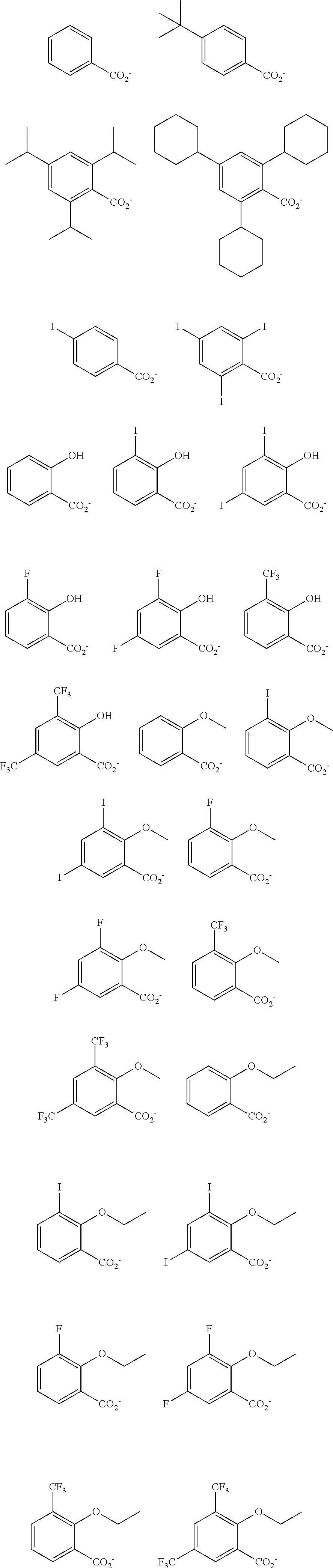

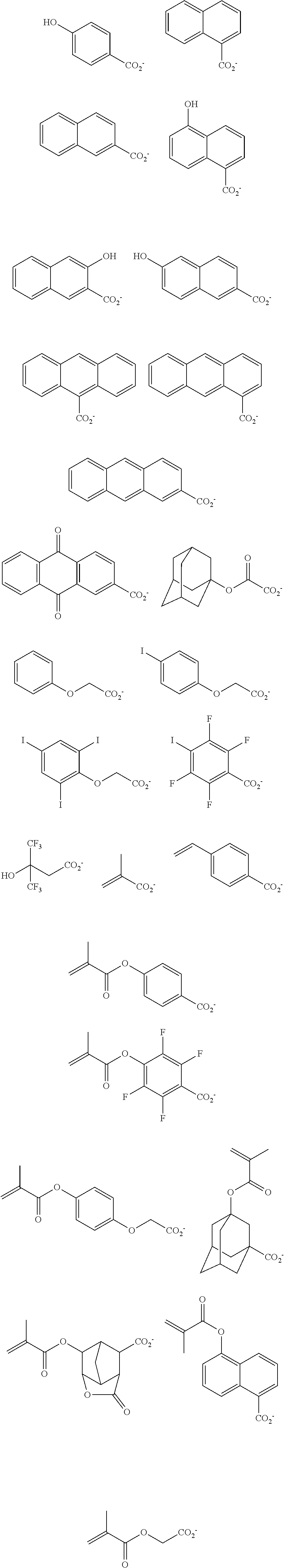

Specific examples of the anion represented by the general formula (5-7) include the following, but are not limited thereto.

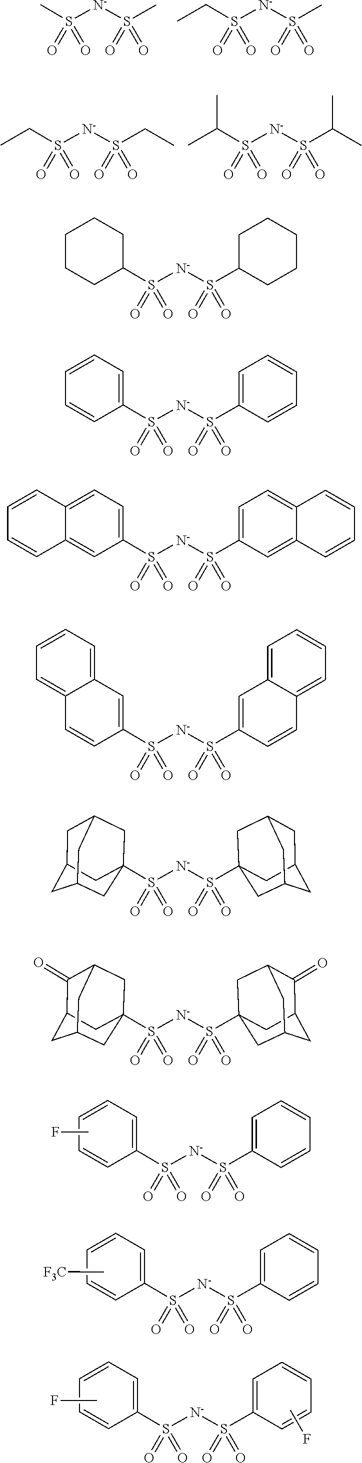

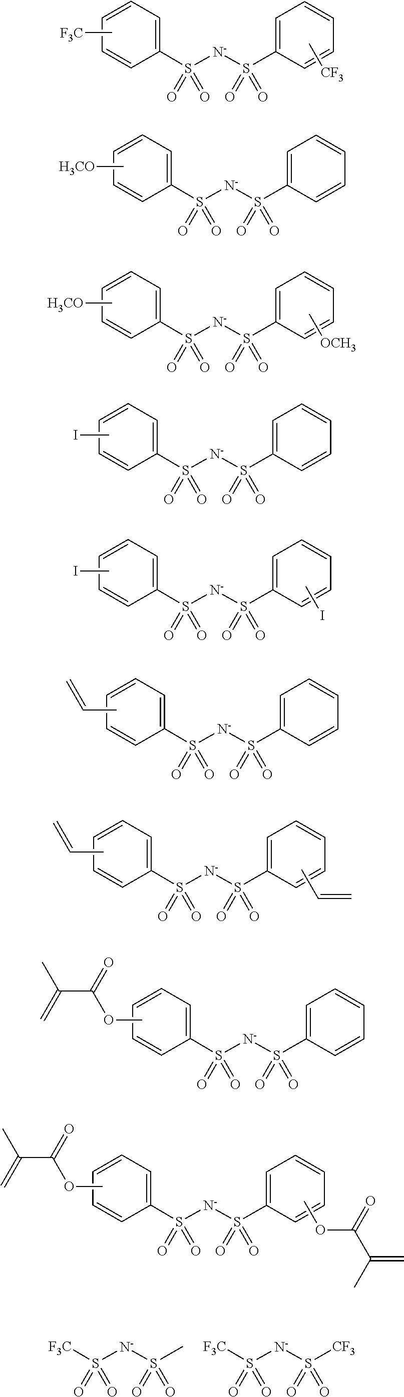

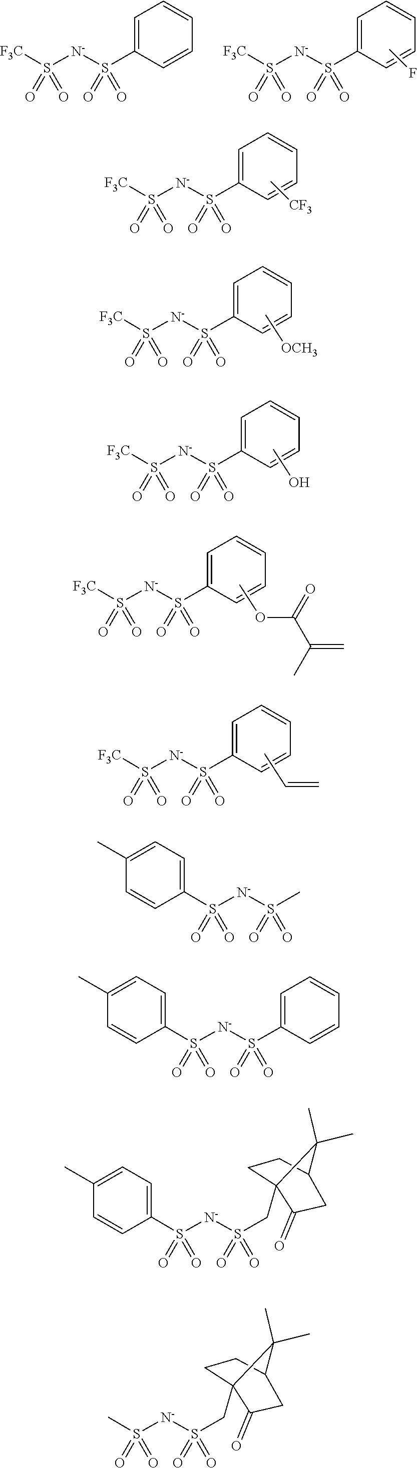

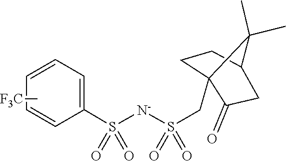

Specific examples of the anion represented by the general formula (5-8) include the following, but are not limited thereto.

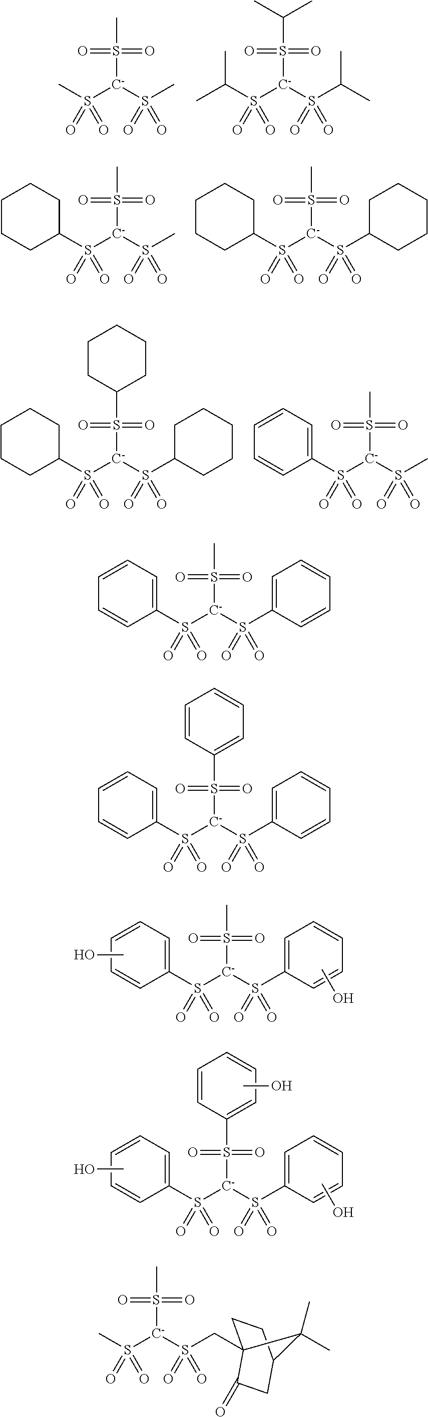

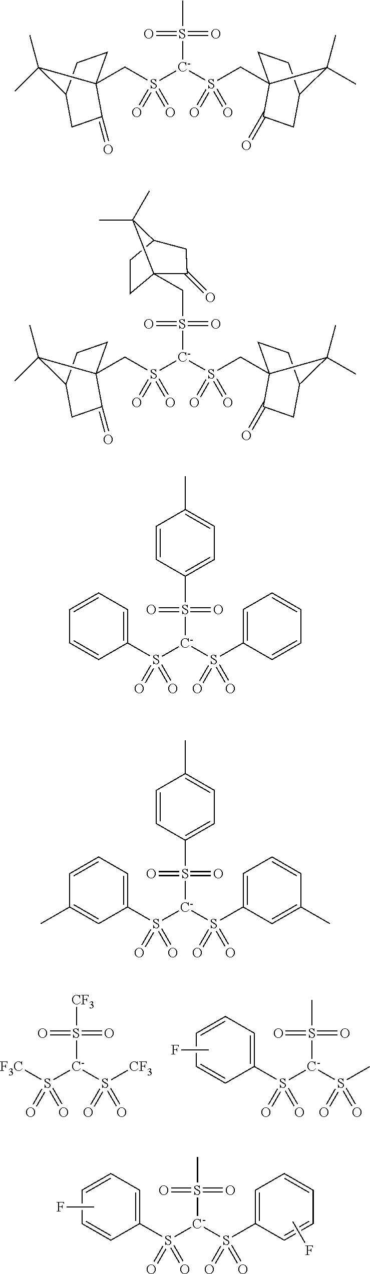

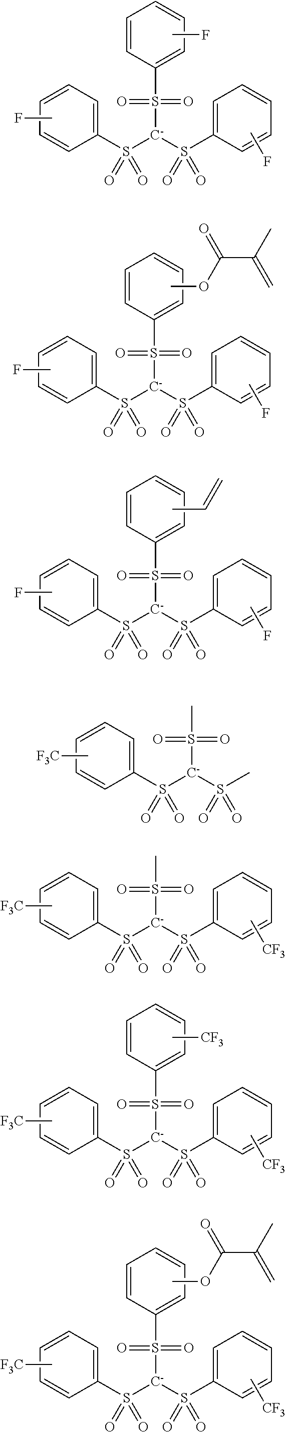

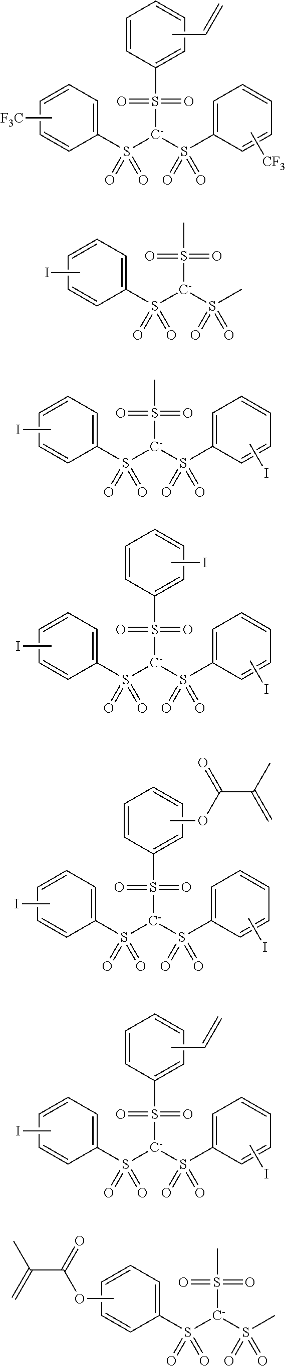

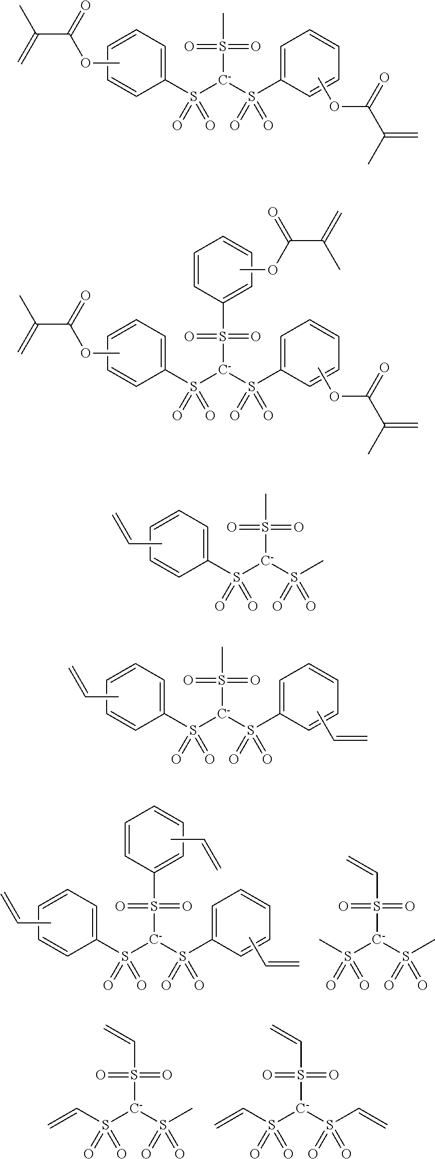

Specific examples of the anion represented by the general formula (5-9) include the following, but are not limited thereto.

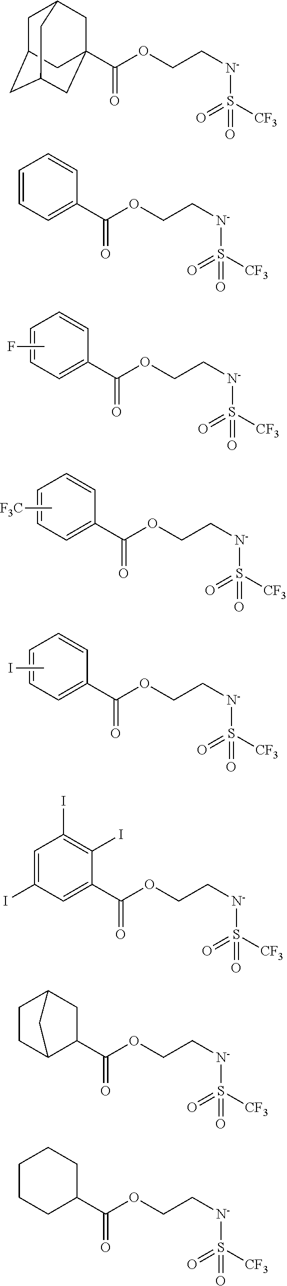

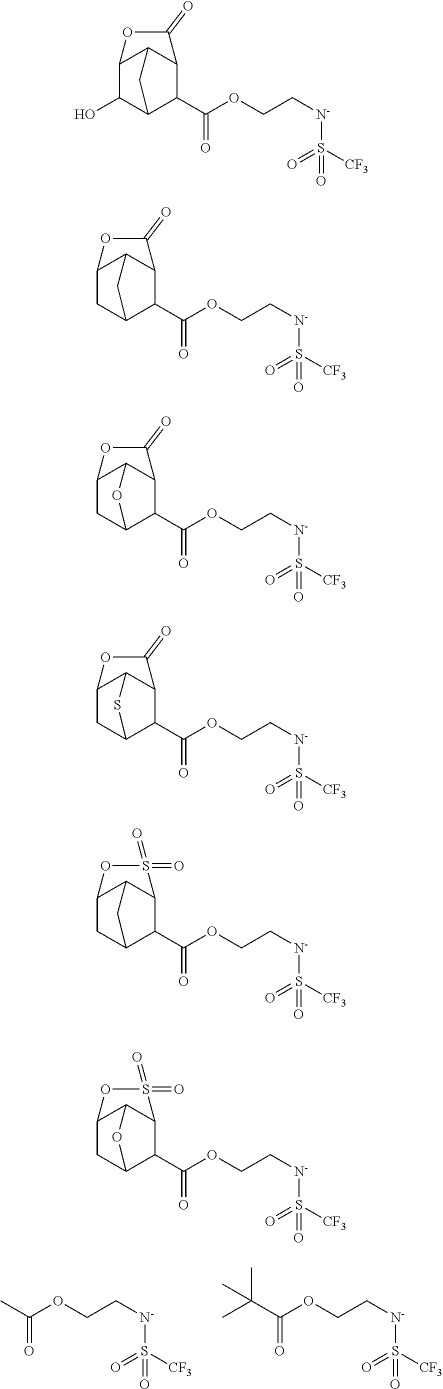

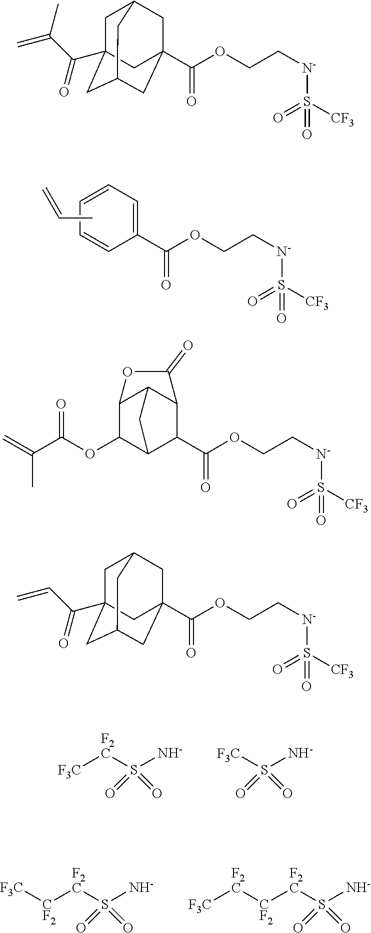

Specific examples of the onium salts include any combination of the above-described anions and cations.

One kind of the photo-acid generators may be used, or two or more kinds thereof may be used in combination. When two or more photo-acid generators are used in combination, it is preferable to use photo-acid generators that generate acids having different acidities. The acid generated in exposed portions of the resist is quenched by a photo-acid generator that generates an acid having a low acidity and is prevented from diffusing to unexposed portions, and thus, it is possible to suppress diffusion and form a high-resolution pattern.

In the resist composition used in the present invention, the content ratio of the hypervalent iodine compound to the photo-acid generator is preferably “hypervalent iodine compound”:“photo-acid generator”=1:1000 to 1000:1, more preferably 1:500 to 500:1 in molar ratio.

When a substituent that has a high molecular weight and is bulky has been introduced into the onium salt, the onium salt has a high excluded volume and can highly suppress the diffusion of the generated acid, and therefore, is suitable when forming a fine pattern.

When the onium salt has an element, such as a fluorine atom or an iodine atom, that has a high effect of absorbing EUV light, the generated amount of secondary electrons increases and the decomposition of cations is promoted, and therefore, the onium salt is suitable for fine patterning with high sensitivity.

### [Organotitanium Compound]

In the inventive patterning process, a resist pattern is formed using a resist film obtained from a resist composition containing the above-described hypervalent iodine compound, carboxylic acid compound, and solvent, then a pattern-reversal film is formed by applying and baking a material (hereinafter, referred to as a material for forming a reversal film) containing an organotitanium compound and a solvent, and then a reverse pattern is formed by performing an etching treatment. As the organotitanium compound used in this event, it is preferable to use one represented by the following general formula (13).

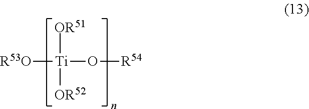

In the formula, R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

In the general formula (13), R⁵¹, R⁵², R⁵³, and R⁵⁴ are identical to or different from each other, and each represent a monovalent organic group having 1 to 30 carbon atoms. Incidentally, R⁵¹ and R⁵² may be bonded to each other to form a ring structure. “n” represents a real number of 1 or more. Specific examples of R⁵¹, R⁵², R⁵³, and R⁵⁴ include: alkyl groups having 1 to 30 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 30 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, and an adamantyl group; alkenyl groups having 2 to 30 carbon atoms, such as a vinyl group and an allyl group; aryl groups having 6 to 30 carbon atoms, such as a phenyl group and a naphthyl group; and groups which are combinations of these groups. Furthermore, part or all of the hydrogen atoms of the organic group may be substituted with a group containing a heteroatom, such as an oxygen atom, a sulfur atom, a nitrogen atom, or a halogen atom, and part of the —CH₂— of the organic group may be substituted with a group containing a heteroatom such as an oxygen atom, a sulfur atom, or a nitrogen atom. The resulting organic group may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc.

In the general formula (13), “n” represents a real number of 1 or more. Here, “n” indicates the average value of the number of repeating units. “n” is preferably 2 to 10, more preferably 2 to 8. If “n” is too large, the coating property of the material for forming a reversal film is degraded, and it is difficult to fill the spaces in the resist pattern.

Specific examples where “n” is 1, that is, specific examples of titanium monomers include titanium methoxide, titanium ethoxide, titanium propoxide, titanium butoxide, titanium amyloxide, titanium hexyloxide, titanium cyclopentoxide, titanium cyclohexyloxide, titanium allyloxide, titanium phenoxide, titanium methoxyethoxide, titanium ethoxyethoxide, titanium dipropoxy bisethyl acetoacetate, titanium dibutoxy bisethyl acetoacetate, titanium dipropoxy bis-2,4-pentanedionate, and titanium dibutoxy bis-2,4-pentanedionate.

When a titanium oligomer, where “n” is 2 or more, is to be synthesized, the method is not particularly limited. For example, the titanium oligomer is synthesized by adding a mixed solution of water and a water-soluble solvent to the titanium monomer and performing hydrolysis.

By synthesizing a tetraalkoxy titanium oligomer and then allowing it to react with a diol compound, it is also possible to synthesize a titanium oligomer in which the R⁵¹ and R⁵² in the general formula (13) are bonded to each other to form a ring structure. Specific examples of such R⁵¹ and R⁵² include the following structures.

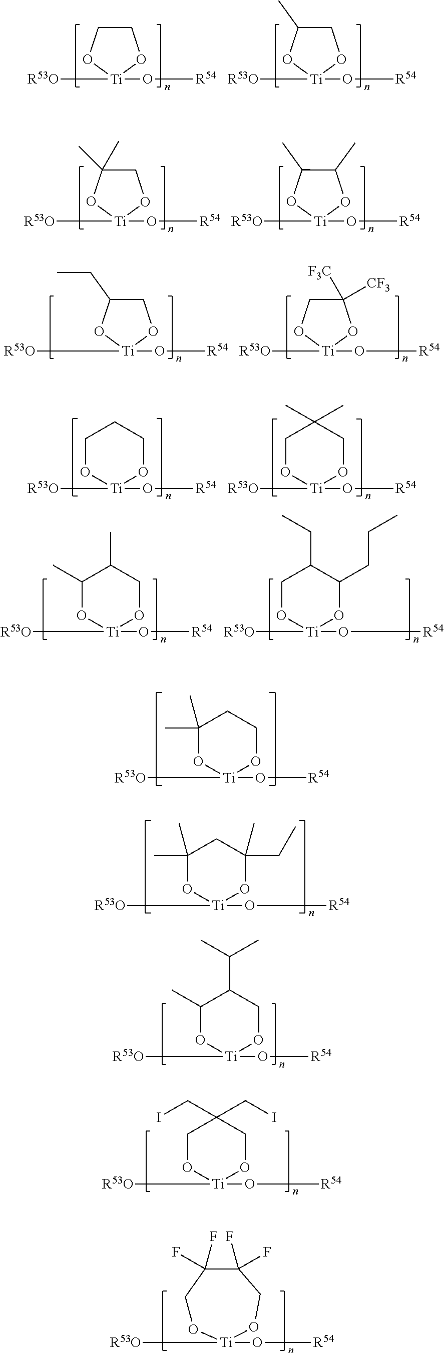

The organotitanium compound used in the present invention is used as a solution in a solvent. The solvent may be any solvent as long as it can dissolve the organotitanium compound without decomposition, but an organic solvent is preferable. Specific examples include: ketones, such as cyclohexanone, methyl isobutyl ketone, and methyl-2-n-pentyl ketone; alcohols, such as 3-methoxybutanol, 3-methyl-3-methoxybutanol, 1-methoxy-2-propanol, 1-ethoxy-2-propanol, and diacetone alcohol; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones, such as γ-butyrolactone; and mixed solvents thereof. Incidentally, the concentration of the organotitanium compound in the solution can be adjusted appropriately according to the purpose, and is, for example, 0.1 mass % to 50 mass %, preferably 1 mass % to 30 mass %.

### [Patterning Process]

The present invention is a patterning process including the steps of:
(i) forming a resist pattern on a support by using a resist film obtained from a resist composition containing a hypervalent iodine compound, a carboxy-group-containing compound, and a solvent;
(ii) forming a pattern-reversal film on the support having the formed resist pattern by applying a material containing an organotitanium compound and a solvent; and
(iii) removing the resist pattern by etching to form a reverse pattern.

Furthermore, a resist underlayer film is preferably formed between the support and the resist film.

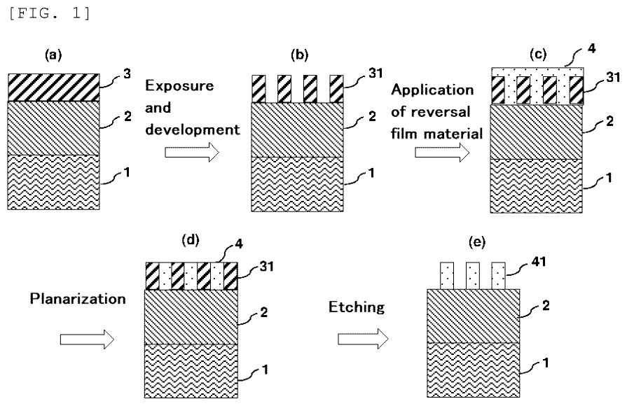

The inventive patterning process will be described in detail with reference to FIG. 1.

In FIG. 1 (a), a resist composition containing a hypervalent iodine compound, a carboxy-group-containing compound, and a solvent is applied onto a substrate 1 to be processed having a resist underlayer film 2 formed, and through a drying process performed by heating or the like, a resist film 3 having a predetermined film thickness is formed. In this event, the resist underlayer film 2 is not particularly limited as long as it does not degrade resist performance and has a sufficient selectivity relative to the pattern-reversal film in the etching process described later, and, for example, may be an organic underlayer film or a silicon-containing film. Depending on the purpose, it is also possible to perform a process in which the resist underlayer film 2 is not provided, and the resist film 3 is formed directly on the substrate 1 to be processed.

After forming the resist film 3 in FIG. 1 (a), exposure by irradiation with radiation is performed via a mask having a predetermined pattern. The resist composition is applied onto the resist underlayer film 2 by an appropriate coating process, such as spin coating, roll coating, flow coating, dip coating, spray coating, or doctor coating, so that the thickness of the coating film is 0.01 to 2 μm. The resultant is prebaked on a hot plate preferably at 60 to 200° C. for 10 seconds to 30 minutes, more preferably 80 to 180° C. for 30 seconds to 20 minutes. Thus, a resist film 3 is formed.

Subsequently, the resist film 3 is exposed by using a high-energy beam. Examples of the high-energy beam include ultraviolet ray, deep ultraviolet ray, electron beam (EB), extreme ultraviolet ray (EUV), X-ray, soft X-ray, excimer laser beam, γ-ray, and synchrotron radiation. When ultraviolet ray, deep ultraviolet ray, EUV, X-ray, soft X-ray, excimer laser beam, γ-ray, synchrotron radiation, or the like is employed as the high-energy beam, the irradiation is performed directly or while using a mask for forming a target pattern at an exposure dose of preferably about 1 to 300 mJ/cm², more preferably about 10 to 200 mJ/cm². When an EB is employed as the high-energy beam, the writing is performed directly or while using a mask for forming a target pattern at an exposure dose of preferably about 0.1 to 8,000 μC/cm², more preferably about 0.5 to 5,000 μC/cm². Note that the resist composition used in the present invention is particularly suitable for fine patterning with an EB or EUV, among the high-energy beams.

After the exposure, PEB is performed as necessary. In this event, the PEB is preferably performed after the exposure on a hot plate or in an oven under the conditions of 30 to 200° C. for 10 seconds to 30 minutes, more preferably 60 to 120° C. for 30 seconds to 20 minutes.

After that, by performing a development treatment, a resist pattern 31 is formed as in FIG. 1 (b). The type and method of the development is not particularly limited as long as the resist pattern 31 can be formed, and either dry or wet development may be performed. In the case of wet development, alkaline development or organic solvent development are possible, and organic solvent development is preferable. Examples of organic solvents for development include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, isopropyl alcohol, n-butanol, n-pentanol, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, phenylmethyl acetate, phenylethyl acetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, diacetone alcohol, and 4-methyl-2-pentanol. One kind of these developers may be used, or two or more kinds thereof may be used in mixture. Furthermore, after the development, rinsing may be performed as necessary. The rinsing liquid is preferably a solvent that is miscible with the developer but does not dissolve the resist pattern 31. As such a solvent, it is preferable to use an alcohol having 3 to 10 carbon atoms, an ether compound having 8 to 12 carbon atoms, an alkane, alkene, alkyne, and aromatic solvent, each having 6 to 12 carbon atoms. Water may also be used instead of an organic solvent as the rinsing liquid.

Subsequently, a material for forming a reversal film is applied so as to fill the spaces in the resist pattern 31. After the application, the material for forming a reversal film is cured by heat treatment or the like, and a pattern-reversal film 4 is formed as in FIG. 1 (c). Methods for applying the material for forming a reversal film are not particularly limited, and known means, such as a spinner, a coater, or a dispenser, can be used. The application can be performed in such a manner that a pattern-reversal film 4 having a desired film thickness can be formed. In this event, the difference between the film thickness of the pattern-reversal film 4 and the height of the resist pattern 31 is preferably 1 to 20 nm, more preferably 1 to 10 nm, in view of the resist pattern exposure process performed afterwards.

After the application, it is preferable to perform a baking treatment at 80 to 250° C. for the purpose of drying the coating film (volatilizing the organic solvent) etc.

After that, planarizing is performed so as to expose the upper surface of the resist pattern 31. Examples of techniques for planarizing include an etch-back method and a CMP method (FIG. 1 (d)). As a gas used for etching back, a halogen-based gas is preferable. Examples of halogen-based gases include tetrachloromethane (CCl₄) gas, hydrogen chloride (HCl) gas, hydrogen bromide (HBr) gas, boron trichloride (BCl₃) gas, and hydrocarbon gases in which part or all of the hydrogen atoms are substituted with a halogen atom, such as a fluorine atom and a chlorine atom, and specific examples include carbon-fluoride-based gas and carbon-chloride-based gas. Examples of carbon-fluoride-based gas include CF-based gases, such as tetrafluoromethane (CF₄) gas, and CHF-based gases, such as trifluoromethane (CHF₃) gas.

One kind of these etching gases may be used, or two or more kinds thereof may be used in mixture. Furthermore, nitrogen gas, a rare gas (argon gas etc.), etc. may be mixed with the etching gas.

Subsequently, by performing a dry etching treatment, the resist pattern 31 is removed, and a reverse pattern 41 is formed as in FIG. 1 (e). The type of gas selected for the dry etching is appropriately selected in view of etching selectivity relative to the resist pattern 31 and the resist underlayer film 2, and examples include oxygen (O₂) gas, sulfur dioxide gas, carbon monoxide gas, carbon dioxide gas, and the above-described halogen-based gases. One kind of these etching gases may be used, or two or more kinds thereof may be used in mixture. Furthermore, nitrogen gas, a rare gas (argon gas etc.), etc. may be mixed with the etching gas. In particular, oxygen plasma etching (dry etching using a plasma obtained from O₂ gas) is preferable.

Such patterning processes using a reversal material have been reported in the past. For example, JP2008-287176A discloses a reversal material containing a polysiloxane-containing resin composition and patterning process using the composition. In this report, a chemically amplified resist composition for ArF and KrF is applied as a resist material. That is, a mechanism is used where a polymer containing an acid-labile group and a photo-acid generator are essential components and polarity conversion in exposed portions is performed by an acid-catalyzed reaction.

On the other hand, the resist composition applied in the inventive patterning process is, as described above, a non-chemically amplified material containing a hypervalent iodine compound, a carboxylic acid compound, and a solvent. Therefore, it is possible to realize a resolution that cannot be achieved with a conventional chemically amplified resist, especially for the purpose of forming a fine pattern by using EUV light.

Meanwhile, a resist composition containing a hypervalent iodine compound has a problem that etching resistance is insufficient. Accordingly, by using a material for forming a reversal film excellent in etching resistance to reverse the pattern, it is possible to obtain an upper layer pattern that functions favorably as an etching mask.

Furthermore, a characteristic of the present invention is that an organotitanium compound is used as a material for forming a reversal film. An organotitanium compound can be easily processed into a form suitable as a coating material (e. g. an oligomer), and flowability can be adjusted to allow fine patterns to be filled. Furthermore, condensation and curing reactions can be performed at a lower temperature than in the case of a silicon compound, and therefore, a reversal film can be formed without damaging the resist pattern. In addition, a titanium-containing reversal film thus formed has better etching resistance compared to polymer resists formed from organic compounds or silicon-containing materials.

That is, by the formation of a reverse pattern by using the above-described resist composition and the above-described material for forming a reversal film, the inventive patterning process can achieve the resolution of a fine pattern and etching resistance at the same time, which was impossible to accomplish with conventional materials and patterning processes. Thus, the inventive patterning process has an extremely high value.

### EXAMPLES

Hereinafter, the present invention will be specifically described with reference to Synthesis Examples, Preparation Examples, Comparative Preparation Examples, Examples, and Comparative Example. However, the present invention is not limited to the following Examples.

### [1] Synthesis of Polymers

For the synthesis of polymers P-1 to P-3, the monomers a-1 to a-3, b-1, and b-2 shown below were used.

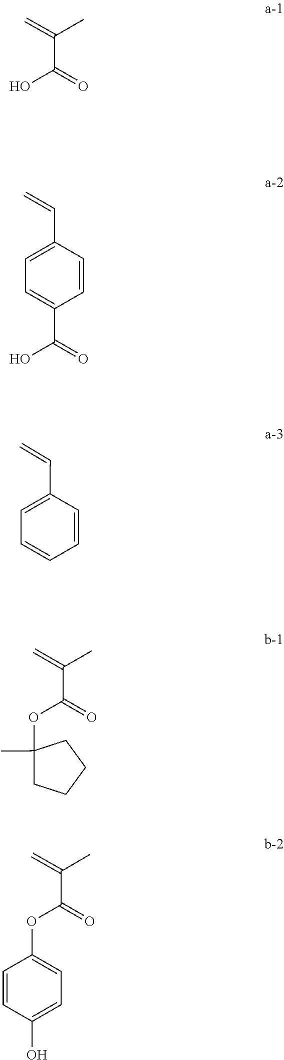

### [Synthesis Example 1-1] Synthesis of Polymer P-1

Under a nitrogen atmosphere, the monomer a-1 (56 g), the monomer a-3 (36 g), 5.4 g of V-601 (manufactured by FUJIFILM Wako Pure Chemical Corporation), and 180 g of MEK were added into a flask to prepare a monomer-polymerization initiator solution. Into another flask with a nitrogen atmosphere, 55 g of MEK was added and heated to 80° C. with stirring, and then the monomer-polymerization initiator solution was added dropwise over 4 hours. After the dropwise addition, the polymerization liquid was further stirred for 2 hours with maintaining the temperature at 80° C., and then cooled to room temperature. The obtained polymerization liquid was added dropwise to 4,000 g of vigorously stirred hexane, and the precipitated polymer was filtered. The obtained polymer was washed twice with hexane (1,200 g), and then dried in vacuo at 50° C. for 20 hours to obtain a white powder polymer P-1 (90 g, 98% yield). The polymer P-1 had Mw of 8,000 and Mw/Mn of 1.42. Note that the Mw is a polystyrene-converted measurement value obtained by GPC using THF as an eluent.

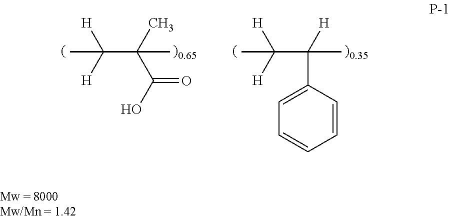

### [Synthesis Examples 1-2 and 1-3] Synthesis of Polymers P-2 and P-3

The polymers shown in Table 1 below were synthesized in the same manner as in Synthesis Example 1-1 except that the kinds and blending ratios of the monomers were changed.

TABLE 1

| | | Introduction | | Introduction | | |
|---|---|---|---|---|---|---|
| | Unit | rate | Unit | rate | | |
| Polymer | 1 | (mol %) | 2 | (mol %) | Mw | Mw/Mn |
| P-1 | a-1 | 65 | a-3 | 35 | 8000 | 1.42 |
| P-2 | a-2 | 65 | a-3 | 35 | 8000 | 1.44 |
| P-3 | b-1 | 60 | b-2 | 40 | 8500 | 1.45 |

### [2] Preparation of Resist Compositions

### Preparation Examples 1-1 to 1-10 and Comparative Preparation Example 1-1

A hypervalent iodine compound and a carboxy-group-containing compound were dissolved in a solvent containing 0.01 mass % of a surfactant (PF-636, manufactured by OMNOVA Solutions Inc.) in the constitution shown below in Table 2, and the obtained solution was filtered with a 0.2-μm Teflon (registered trademark) filter to prepare a resist composition (R-01 to R-10). Meanwhile, a polymer, a photo-acid generator, and a sensitivity modifier were dissolved in a solvent containing 0.01 mass % of a surfactant (PF-636, manufactured by OMNOVA Solutions Inc.) in the constitution shown below in Table 3, and the obtained solution was filtered with a 0.2-μm Teflon (registered trademark) filter to prepare a comparative resist composition (CR-01).

TABLE 2

| | | | Carboxy- | | | | |
|---|---|---|---|---|---|---|---|
| | | Hypervalent | group- | | | | |
| | | iodine | containing | | | | |
| | | compound | compound | Solvent 1 | | Solvent 2 | |
| | Resist | (parts by | (parts by | (parts by | | (parts by | |
| | composition | mass) | mass) | mass) | | mass) | |
| Preparation | R-01 | I-1 (10) | P-1(9) | PGMEA | (800) | AcOH | (200) |
| Example 1-1 | | | | | | | |
| Preparation | R-02 | I-2 (19) | P-1(9) | PGMEA | (800) | AcOH | (200) |
| Example 1-2 | | | | | | | |
| Preparation | R-03 | I-3 (10) | P-2(12) | PGMEA | (800) | AcOH | (200) |
| Example 1-3 | | | | | | | |
| Preparation | R-04 | I-4 (19) | P-2(12) | PGMEA | (800) | AcOH | (200) |
| Example 1-4 | | | | | | | |
| Preparation | R-05 | I-5 (10) | m-1(7) | PGMEA | (800) | AcOH | (200) |
| Example 1-5 | | | | | | | |
| Preparation | R-06 | I-6 (19) | m-1(7) | PGMEA | (800) | AcOH | (200) |
| Example 1-6 | | | | | | | |
| Preparation | R-07 | I-7 (10) | P-1(9) | PGMEA | (800) | AcOH | (200) |
| Example 1-7 | | | | | | | |
| Preparation | R-08 | I-8 (19) | P-1(9) | PGMEA | (800) | AcOH | (200) |
| Example 1-8 | | | | | | | |
| Preparation | R-09 | I-9 (10) | P-2(12) | PGMEA | (800) | AcOH | (200) |
| Example 1-9 | | | | | | | |
| Preparation | R-10 | I-10 (19) | P-2(12) | PGMEA | (800) | AcOH | (200) |
| Example 1-10 | | | | | | | |

TABLE 3

| | | | Photo-acid | Sensitivity | | |
|---|---|---|---|---|---|---|
| | Comparative | Polymer | generator | modifier | Solvent 1 | Solvent 2 |
| | resist | (parts by | (parts by | (parts by | (parts by | (parts by |
| | composition | mass) | mass) | mass) | mass) | mass) |
| Comparative | CR-01 | P-3 | PAG-1 | Q-1 (6) | PGMEA | GBL (210) |
| Preparation | | (80) | (19) | | (1890) | |
| Example 1-1 | | | | | | |

In Tables 2 and 3, hypervalent iodine compounds I-1 to I-10, carboxy-group-containing compound m-1, photo-acid generator PAG-1, sensitivity modifier Q-1, and solvents are as follows.

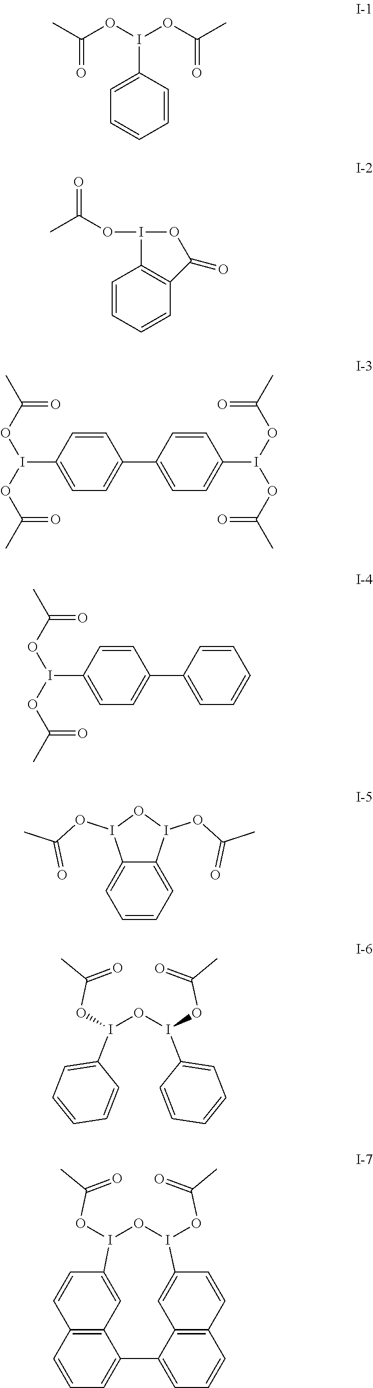

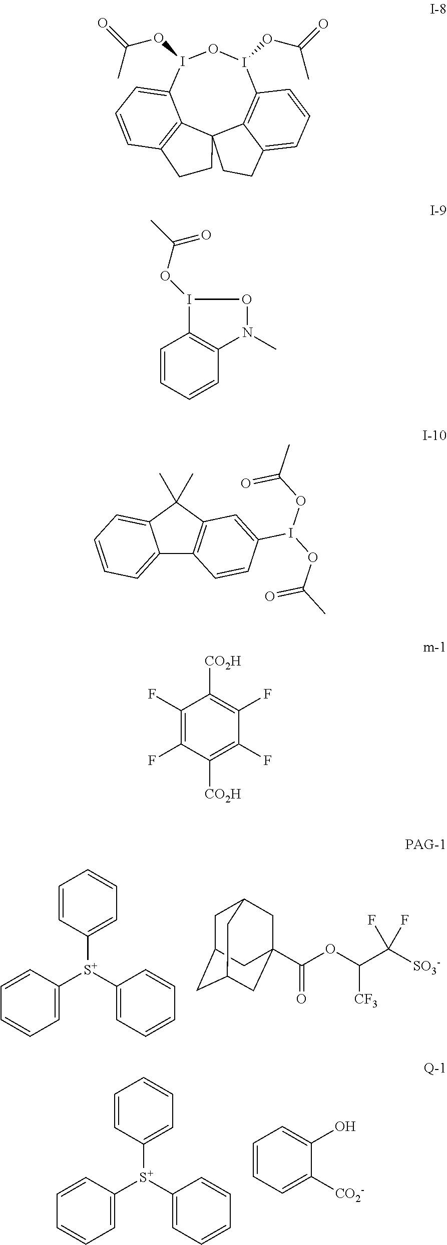

### Solvents:

PGMEA (propylene glycol monomethyl ether acetate)
AcOH (acetic acid)
GBL (γ-butyrolactone)

### [3] Synthesis of Organotitanium Compounds

### Synthesis Example 2-1

To a mixture of 28.4 g of titanium tetraisopropoxide and 50 g of isopropyl alcohol (IPA), a mixture of 0.9 g of pure water and 50 g of IPA was added dropwise, and reflux was performed for 30 minutes. Then, the IPA in the system was distilled off under reduced pressure to obtain 17.8 g of organotitanium compound A1.

### Synthesis Example 2-2

To a mixture of 34.0 g of titanium tetrabutoxide and 50 g of n-butyl alcohol, a mixture of 0.9 g of pure water and 50 g of n-butyl alcohol was added dropwise, and reflux was performed for 30 minutes. Then, the n-butyl alcohol in the system was distilled off under reduced pressure to obtain 20.4 g of organotitanium compound A2.

### Synthesis Example 2-3

A mixture of organotitanium compound A1 (9.1 g) obtained in Synthesis Example 2-1 and 1,2-propanediol (15.2 g) was refluxed for 2 hours. After that, 50 g of propylene glycol monomethyl ether acetate (PGMEA) was added thereto, and then concentration under reduced pressure was performed to obtain 6.9 g of a concentrated residue as organotitanium compound A3.

### Synthesis Example 2-4

A mixture of organotitanium compound A2 (10.5 g) obtained in Synthesis Example 2-2 and 2,4-dimethyl-2,4-pentanediol (26.4 g) was refluxed for 2 hours. After that, 60 g of propylene glycol monomethyl ether acetate (PGMEA) was added thereto, and then concentration under reduced pressure was performed to obtain 7.9 g of a concentrated residue as organotitanium compound A4.

The structures of organotitanium compounds A1 to A4 are shown below.

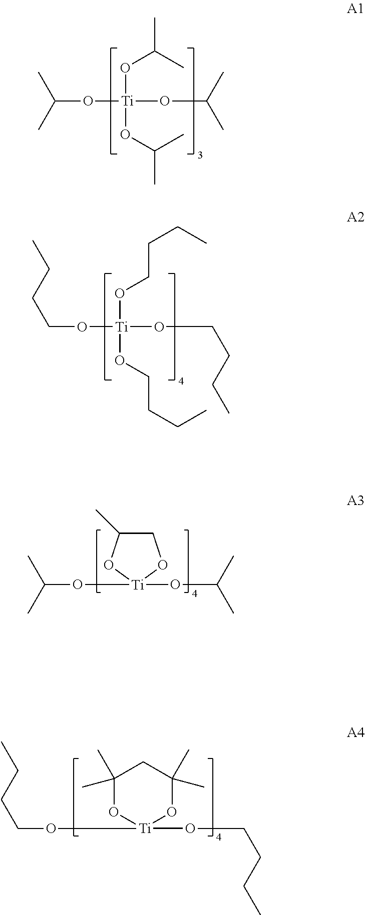

### [4] Preparation of Materials for Forming Organotitanium-Containing Reversal Film

3 mass % solutions of each of organotitanium compounds A1 to A4, obtained in Synthesis Examples 2-1 to 2-4, in 2-heptanone were formed and filtered through a 0.1-μm filter made of a fluorinated resin to prepare respective materials for forming an organotitanium-containing reversal film as IR-1 to IR-4.

### [5] Filling Property Evaluation (Examples 1-1 to 1-10 and Comparative Example 1-1)

Spin-on carbon ODL-301 (carbon content of 88 mass %) manufactured by Shin-Etsu Chemical Co., Ltd. was applied onto a silicon substrate and baked at 350° C. for 60 seconds to form a resist underlayer film with a film thickness of 100 nm. A resist composition (R-01 to R-10) or a comparative resist composition (CR-01) was applied thereto by using a spinner, subjected to a prebake (PAB) treatment at 130° C. for 60 seconds, and dried to form a resist film having a film thickness of 25 nm.

Subsequently, writing was performed on the resist film by using ELS-F125, manufactured by ELIONIX INC. Subsequently, a PEB treatment was performed at 90° C. for 60 seconds. Furthermore, the resist films formed from R-01, R-02, and R-05 to R-08 were developed with butyl acetate for 30 seconds, and the resist films formed from R-03, R-04, R-09, R-10, and CR-01 were developed with a 2.38 mass % aqueous solution of tetramethylammonium hydroxide (TMAH) for 30 seconds.

As a result, a line-and-space resist pattern (L/S pattern) having a line width of 20 nm and a pitch of 40 nm was formed on the resist film. Incidentally, the L/S patterns obtained from the resist films formed from R-01, R-02, R-05 to R-08, and CR-01 were positive patterns, where exposed portions were removed by the development, and the L/S patterns obtained from the resist films formed from R-03, R-04, R-09, and R-10 were negative patterns, where unexposed portions were removed by the development.

On the resist film having the formed L/S pattern, each of the materials IR-1 to IR-4 for forming an organotitanium-containing reversal film was applied by using a spinner at a rotational rate of 1500 rpm, baked under conditions of 250° C. and 60 seconds, and dried to form a pattern-reversal film having a film thickness of about 30 nm. The cross section of the obtained pattern-reversal film was observed with an SEM (scanning electron microscope). As a result, it was confirmed that, in the cases of Examples 1-1 to 1-10, where a film of each of IR-1 to IR-4 was formed on the resist patterns formed from the resist compositions (R-01 to R-10), the cross sections had no gaps and were homogeneous, and the space portions of the L/S patterns were filled with each material for forming an organotitanium-containing reversal film without gaps. Meanwhile, in the case of Comparative Example 1-1, where a film of each of IR-1 to IR-4 was formed on the resist patterns formed from the comparative resist composition (CR-01), in the cross section, each material for forming an organotitanium-containing reversal film had mixed with the resist pattern, and it was not possible to find the boundary between the resist pattern and the material for forming an organotitanium-containing reversal film.

### [6] Reverse Pattern Formation Evaluation (Reversal of L/S Pattern) (Examples 2-1 to 2-10 and Comparative Example 2-1)

Spin-on carbon ODL-301 (carbon content of 88 mass %) manufactured by Shin-Etsu Chemical Co., Ltd. was applied onto a silicon substrate and baked at 350° C. for 60 seconds to form a resist underlayer film with a film thickness of 100 nm. A resist composition (R-01 to R-10) or a comparative resist composition (CR-01) was applied thereto by spin-coating and subjected to a prebake (PAB) treatment on a hot plate at 130° C. for 60 seconds to produce a resist film having a film thickness of 25 nm. The resist film was exposed using an EUV scanner NXE3400 (NA 0.33, σ 0.9, 90° dipole illumination), manufactured by ASML Holding N.V., to form a 40-nm 1:1 line-and-space (L/S) pattern, and then a PEB treatment was performed on a hot plate at 90° C. for 60 seconds. Then, the resist films formed from R-01, R-02, and R-05 to R-08 were developed with butyl acetate for 30 seconds, and the resist films formed from R-03, R-04, R-09, R-10, and CR-01 were developed with a 2.38 mass % aqueous solution of tetramethylammonium hydroxide (TMAH) for 30 seconds.

On the resist film having the formed L/S pattern, each of the materials IR-1 to IR-4 for forming an organotitanium-containing reversal film was applied by using a spinner at a rotational rate of 1500 rpm, baked under conditions of 150° C. and 60 seconds, and dried to form a pattern-reversal film having a film thickness of about 30 nm.

The substrate having the formed pattern-reversal film was subjected to an etching treatment (pressure, 4 Pa; Upper RF=500 W, Lower RF=1,800 W; temperature, 20° C.; treatment time, 2 seconds in each case) with a mixed gas of CF₄ gas, Ar gas, and N₂ gas (flow rate ratio: CF₄/Ar/N₂=9/57/34) by using a plasma etching apparatus (manufactured by Tokyo Electron Ltd., apparatus name, Telius) to planarize the film surface.

The substrate after the etching treatment was subjected to an oxygen plasma etching treatment (pressure, 0.67 Pa; Upper RF=750 W, Lower RF=150 W; temperature, 0° C.; treatment time, 15 seconds) with a mixed gas of O₂ gas and N₂ gas (flow rate ratio: O₂/N₂=46/54) by using a plasma etching apparatus (manufactured by Tokyo Electron Ltd., apparatus name, Telius). The cross section of the substrate after the etching treatment was observed by SEM.

As a result, it was confirmed that, in the cases of Examples 2-1 to 2-10, where the resist compositions (R-01 to R-10) were used, a pattern was formed, where the line pattern of the L/S pattern and the resist underlayer film underneath were removed, and a space pattern having a space width of 20 nm and a height of about 100 nm was arranged at regular intervals on the substrate. Furthermore, the pattern had high rectangularity in the cross section of the top portion (pattern-reversal film portion) of the line, and had a favorable profile. On the other hand, in the case of Comparative Example 2-1, where the comparative resist composition (CR-01) was used, a reverse pattern had not been formed on the substrate.

Meanwhile, regarding the L/S patterns formed using R-01 to R-10 and CR-01, in a case where the oxygen plasma etching treatment was performed without using the material for forming an organotitanium-containing reversal film, the remaining resist was unable to withstand the etching treatment process, and the resist underlayer film regions required to remain were also partly removed.

As clearly seen from the above results, according to the inventive patterning process, the material for forming an organotitanium-containing reversal film used has favorable filling property, and makes it possible favorably to fill even fine resist patterns. Furthermore, it was found that the pattern-reversal film formed using the material for forming a reversal film had a high etching selectivity relative to the resist film and the resist underlayer film underneath, and the profile of the reverse pattern formed by removing the resist pattern by etching was also excellent.

The present description includes the following embodiments.
[1]: A patterning process comprising the steps of:
   (i) forming a resist pattern on a support by using a resist film obtained from a resist composition containing a hypervalent iodine compound, a carboxy-group-containing compound, and a solvent;
   (ii) forming a pattern-reversal film on the support having the formed resist pattern by applying a material containing an organotitanium compound and a solvent; and
   (iii) removing the resist pattern by etching to form a reverse pattern.
[2]: The patterning process according to [1], wherein, as the hypervalent iodine compound, at least one compound selected from hypervalent iodine compounds represented by the following general formulae (1) to (10) is used,

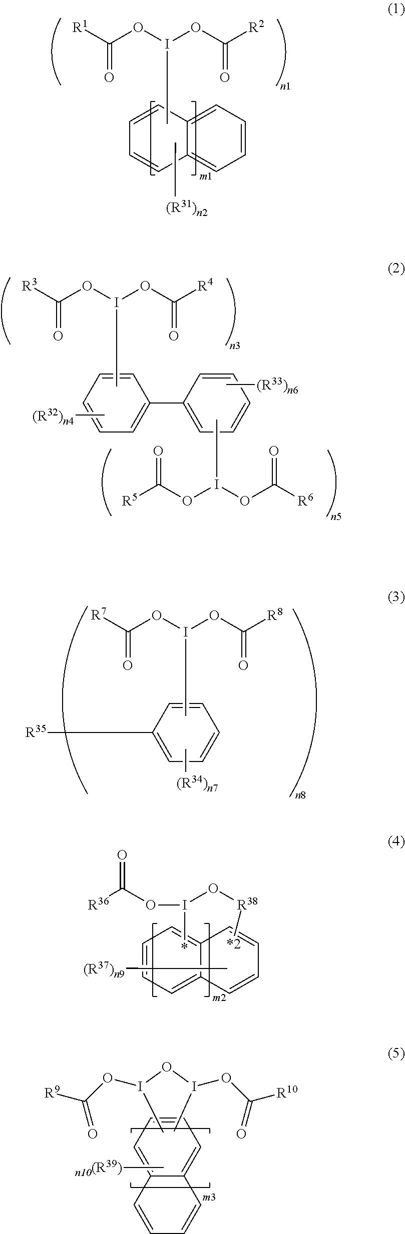

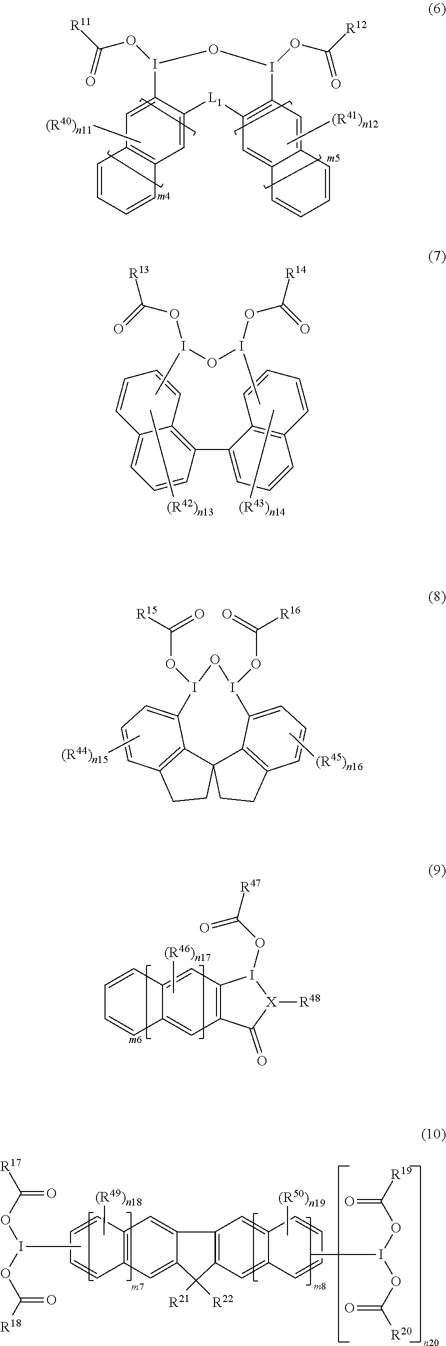

wherein “m1” represents an integer of 0 to 2, when “m1” is 0, “n1” representing an integer of 1 to 3, “n2” representing an integer of 0 to 5, and 1≤n1+n2≤6 being satisfied, when “m1” is 1, “n1” representing an integer of 1 to 3, “n2” representing an integer of 0 to 7, and 1≤n1+n2≤8 being satisfied, and when “m1” is 2, “n1” representing an integer of 1 to 3, “n2” representing an integer of 0 to 9, and 1≤n1+n2≤10 being satisfied;
“n3” represents 1 or 2, “n4” represents an integer of 0 to 4, and 1≤n3+n4≤5 is satisfied, and “n5” represents 1 or 2, “n6” represents an integer of 0 to 4, and 1≤n5+n6≤5 is satisfied;
“n7” represents an integer of 0 to 4, and “n8” represents an integer of 1 to 4;
“m2” represents an integer of 0 to 2, when “m2” is 0, “n9” representing an integer of 0 to 4, when “m2” is 1, “n9” representing an integer of 0 to 6, and when “m2” is 2, “n9” representing an integer of 0 to 8;
“m3” represents an integer of 0 to 2, when “m3” is 0, “n10” representing an integer of 0 to 4, when “m3” is 1, “n10” representing an integer of 0 to 6, and when “m3” is 2, “n10” representing an integer of 0 to 8;
“m4” represents 0 or 1, when “m4” is 0, “n11” representing an integer of 0 to 4 and when “m4” is 1, “n11” representing an integer of 0 to 6;
“m5” represents 0 or 1, when “m5” is 0, “n12” representing an integer of 0 to 4 and when “m5” is 1, “n12” representing an integer of 0 to 6;
“n13” and “n14” each represent an integer of 0 to 6;
“n15” and “n16” each represent an integer of 0 to 3;
“m6” represents an integer of 0 to 2, when “m6” is 0, “n17” representing an integer of 0 to 4, when “m6” is 1, “n17” representing an integer of 0 to 6, and when “m6” is 2, “n17” representing an integer of 0 to 8;
“m7” represents an integer of 0 to 2, when “m7” is 0, “n18” representing an integer of 0 to 3, when “m7” is 1, “n18” representing an integer of 0 to 5, and when “m7” is 2, “n18” representing an integer of 0 to 7;
“m8” represents an integer of 0 to 2, when “m8” is 0, “n19” representing an integer of 0 to 3 and “n20” representing 0 or 1, when “m8” is 1, “n19” representing an integer of 0 to 5 and “n20” representing 0 or 1, and when “m8” is 2, “n19” representing an integer of 0 to 7 and “n20” representing 0 or 1;
R¹ to R²² each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, R¹⁹ and R²⁰, or R²¹ and R²² may be bonded to each other to form a ring together with the carbon atoms bonded thereto and any atoms between the carbon atoms;
R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³²s are identical to or different from each other and the R³²s may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with the carbon atoms of the aromatic ring bonded thereto, when “n10” is 2 or more, the R³⁹s are identical to or different from each other and the R³⁹s may be bonded to each other to form a ring together with the carbon atoms of the aromatic ring bonded thereto, when “n11” is 2 or more, the R⁴⁰s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴²s are identical to or different from each other and the R⁴²s may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with the carbon atoms of the aromatic ring bonded thereto, and when “n19” is 2 or more, the R⁵⁰s are identical to or different from each other and the R⁵⁰s may be bonded to each other to form a ring together with the carbon atoms of the aromatic ring bonded thereto;
R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, wherein part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms;
R³⁶ represents a halogen atom or a hydrocarbyl group having 1 to 10 carbon atoms and optionally containing a heteroatom;
R³⁸ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
L₁ represents absence of a bond, a single bond, —O—, —S—, —NH—, or —CH₂—;
R⁴⁷ represents a halogen atom or a hydrocarbyl group having 1 to 10 carbon atoms and optionally containing a heteroatom;
X represents a nitrogen atom or a sulfur atom, when X is a nitrogen atom, X may have R⁴⁸; and
R⁴⁸ represents a hydrogen atom, a halogen atom, or a hydrocarbyl group or ester each having 1 to 20 carbon atoms and optionally containing a heteroatom.
[3]: The patterning process according to [1] or [2], wherein, as the carboxy-group-containing compound, a carboxy-group-containing polymer including a repeating unit represented by the following general formula (11) or a carboxylic acid compound represented by the following general formula (12) is used,

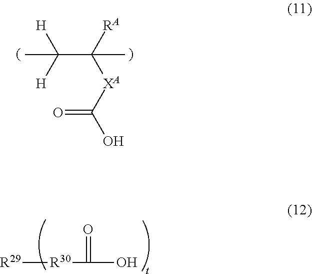

wherein R^{A} represents a hydrogen atom, a halogen atom, a methyl group, or a trifluoromethyl group;
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring, and “*” represents an attachment point to the carbon atom of the main chain;
“t” represents an integer of 1 to 4;
R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, wherein part or all of hydrogen atoms of the t-valent hydrocarbon group or the t-valent heterocyclic group may be substituted with a group containing a heteroatom, and part of —CH₂— of the t-valent hydrocarbon group may be substituted with a group containing a heteroatom; and
R³⁰ represents a single bond or a hydrocarbylene group having 1 to 10 carbon atoms, wherein part or all of hydrogen atoms of the hydrocarbylene group may be substituted with a group containing a heteroatom, part of —CH₂— of the hydrocarbylene group may be substituted with a group containing a heteroatom, and when “t” is 2 to 4, the R³⁰s are identical to or different from each other.
[4]: The patterning process according to any one of [1] to [3], wherein a resist underlayer film is formed between the support and the resist film.
[5]: The patterning process according to any one of [1] to [4], wherein, as the organotitanium compound, a compound represented by the following general formula (13) is used,

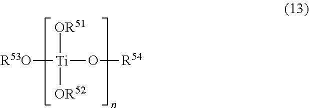

wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A patterning process comprising the steps of:
(i) forming a resist pattern on a support by using a resist film obtained from a resist composition containing a hypervalent iodine compound, a carboxy-group-containing compound, and a solvent;
(ii) forming a pattern-reversal film on the support having the formed resist pattern by applying a material containing an organotitanium compound and a solvent; and
(iii) removing the resist pattern by etching to form a reverse pattern.

2. The patterning process according to claim 1, wherein, as the hypervalent iodine compound, at least one compound selected from hypervalent iodine compounds represented by the following general formulae (1) to (10) is used, 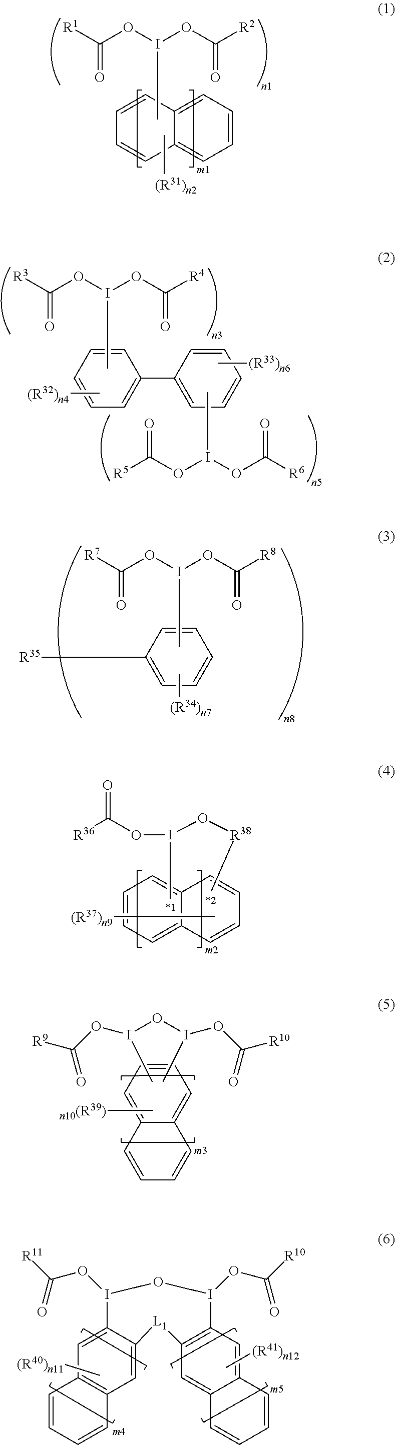 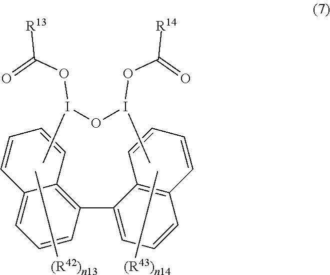 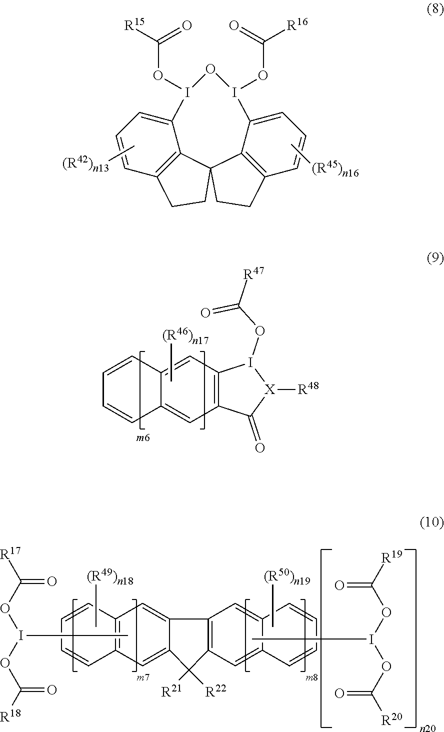
wherein “m1” represents an integer of 0 to 2, when “m1” is 0, “n1” representing an integer of 1 to 3, “n2” representing an integer of 0 to 5, and 1≤n1+n2≤6 being satisfied, when “m1” is 1, “n1” representing an integer of 1 to 3, “n2” representing an integer of 0 to 7, and 1≤n1+n2≤8 being satisfied, and when “m1” is 2, “n1” representing an integer of 1 to 3, “n2” representing an integer of 0 to 9, and 1≤n1+n2≤10 being satisfied;
“n3” represents 1 or 2, “n4” represents an integer of 0 to 4, and 1≤n3+n4≤5 is satisfied, and “n5” represents 1 or 2, “n6” represents an integer of 0 to 4, and 1≤n5+n6≤5 is satisfied;
“n7” represents an integer of 0 to 4, and “n8” represents an integer of 1 to 4;
“m2” represents an integer of 0 to 2, when “m2” is 0, “n9” representing an integer of 0 to 4, when “m2” is 1, “n9” representing an integer of 0 to 6, and when “m2” is 2, “n9” representing an integer of 0 to 8;
“m3” represents an integer of 0 to 2, when “m3” is 0, “n10” representing an integer of 0 to 4, when “m3” is 1, “n10” representing an integer of 0 to 6, and when “m3” is 2, “n10” representing an integer of 0 to 8;
“m4” represents 0 or 1, when “m4” is 0, “n11” representing an integer of 0 to 4 and when “m4” is 1, “n11” representing an integer of 0 to 6;
“m5” represents 0 or 1, when “m5” is 0, “n12” representing an integer of 0 to 4 and when “m5” is 1, “n12” representing an integer of 0 to 6;
“n13” and “n14” each represent an integer of 0 to 6;
“n15” and “n16” each represent an integer of 0 to 3;
“m6” represents an integer of 0 to 2, when “m6” is 0, “n17” representing an integer of 0 to 4, when “m6” is 1, “n17” representing an integer of 0 to 6, and when “m6” is 2, “n17” representing an integer of 0 to 8;
“m7” represents an integer of 0 to 2, when “m7” is 0, “n18” representing an integer of 0 to 3, when “m7” is 1, “n18” representing an integer of 0 to 5, and when “m7” is 2, “n18” representing an integer of 0 to 7;
“m8” represents an integer of 0 to 2, when “m8” is 0, “n19” representing an integer of 0 to 3 and “n20” representing 0 or 1, when “m8” is 1, “n19” representing an integer of 0 to 5 and “n20” representing 0 or 1, and when “m8” is 2, “n19” representing an integer of 0 to 7 and “n20” representing 0 or 1;
R¹ to R²² each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, R¹⁹ and R²⁰, or R²¹ and R²² may be bonded to each other to form a ring together with the carbon atoms bonded thereto and any atoms between the carbon atoms;
R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³²s are identical to or different from each other and the R³²s may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with the carbon atoms of the aromatic ring bonded thereto, when “n10” is 2 or more, the R³⁹s are identical to or different from each other and the R³⁹s may be bonded to each other to form a ring together with the carbon atoms of the aromatic ring bonded thereto, when “n11” is 2 or more, the R⁴⁰s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴²s are identical to or different from each other and the R⁴²s may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with the carbon atoms of the aromatic ring bonded thereto, and when “n19” is 2 or more, the R⁵⁰s are identical to or different from each other and the R⁵⁰s may be bonded to each other to form a ring together with the carbon atoms of the aromatic ring bonded thereto;
R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, wherein part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms;
R³⁶ represents a halogen atom or a hydrocarbyl group having 1 to 10 carbon atoms and optionally containing a heteroatom;
R³⁸ represents a carbonyl group or a hydrocarbylene group having 1 to 10 carbon atoms and optionally containing a heteroatom;
“*1” and “*2” each represent an attachment point to a carbon atom of the aromatic ring in the formula, provided that “*1” and “*2” are bonded to adjacent carbon atoms of the aromatic ring;
L₁ represents absence of a bond, a single bond, —O—, —S—, —NH—, or —CH₂—;
R⁴⁷ represents a halogen atom or a hydrocarbyl group having 1 to 10 carbon atoms and optionally containing a heteroatom;
X represents a nitrogen atom or a sulfur atom, when X is a nitrogen atom, X may have R⁴⁸; and
R⁴⁸ represents a hydrogen atom, a halogen atom, or a hydrocarbyl group or ester each having 1 to 20 carbon atoms and optionally containing a heteroatom.

3. The patterning process according to claim 1, wherein, as the carboxy-group-containing compound, a carboxy-group-containing polymer including a repeating unit represented by the following general formula (11) or a carboxylic acid compound represented by the following general formula (12) is used, 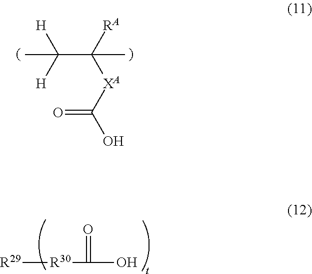
wherein R^{A} represents a hydrogen atom, a halogen atom, a methyl group, or a trifluoromethyl group;
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring, and “*” represents an attachment point to the carbon atom of the main chain;
“t” represents an integer of 1 to 4;
R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, wherein part or all of hydrogen atoms of the t-valent hydrocarbon group or the t-valent heterocyclic group may be substituted with a group containing a heteroatom, and part of —CH₂— of the t-valent hydrocarbon group may be substituted with a group containing a heteroatom; and
R³⁰ represents a single bond or a hydrocarbylene group having 1 to 10 carbon atoms, wherein part or all of hydrogen atoms of the hydrocarbylene group may be substituted with a group containing a heteroatom, part of —CH₂— of the hydrocarbylene group may be substituted with a group containing a heteroatom, and when “t” is 2 to 4, the R³⁰s are identical to or different from each other.

4. The patterning process according to claim 2, wherein, as the carboxy-group-containing compound, a carboxy-group-containing polymer including a repeating unit represented by the following general formula (11) or a carboxylic acid compound represented by the following general formula (12) is used, 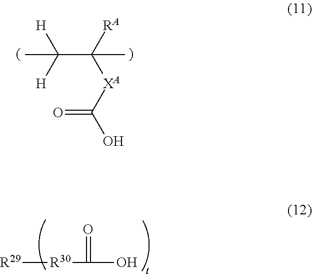
wherein R^{A} represents a hydrogen atom, a halogen atom, a methyl group, or a trifluoromethyl group;
X^{A} represents a single bond, a phenylene group, a naphthylene group, or *—C(═O)—O—X^{A1}—, X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring, and “*” represents an attachment point to the carbon atom of the main chain;
“t” represents an integer of 1 to 4;
R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, wherein part or all of hydrogen atoms of the t-valent hydrocarbon group or the t-valent heterocyclic group may be substituted with a group containing a heteroatom, and part of —CH₂— of the t-valent hydrocarbon group may be substituted with a group containing a heteroatom; and
R³⁰ represents a single bond or a hydrocarbylene group having 1 to 10 carbon atoms, wherein part or all of hydrogen atoms of the hydrocarbylene group may be substituted with a group containing a heteroatom, part of —CH₂— of the hydrocarbylene group may be substituted with a group containing a heteroatom, and when “t” is 2 to 4, the R³⁰s are identical to or different from each other.

5. The patterning process according to claim 1, wherein a resist underlayer film is formed between the support and the resist film.

6. The patterning process according to claim 2, wherein a resist underlayer film is formed between the support and the resist film.

7. The patterning process according to claim 3, wherein a resist underlayer film is formed between the support and the resist film.

8. The patterning process according to claim 4, wherein a resist underlayer film is formed between the support and the resist film.

9. The patterning process according to claim 1, wherein, as the organotitanium compound, a compound represented by the following general formula (13) is used, 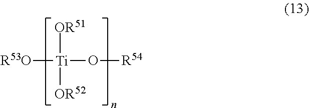
wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

10. The patterning process according to claim 2, wherein, as the organotitanium compound, a compound represented by the following general formula (13) is used, 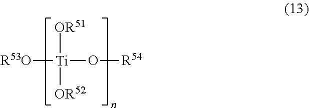
wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

11. The patterning process according to claim 3, wherein, as the organotitanium compound, a compound represented by the following general formula (13) is used, 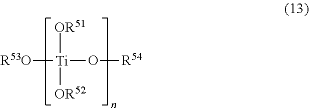
wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

12. The patterning process according to claim 4, wherein, as the organotitanium compound, a compound represented by the following general formula (13) is used, 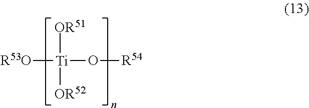
wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

13. The patterning process according to claim 5, wherein, as the organotitanium compound, a compound represented by the following general formula (13) is used, 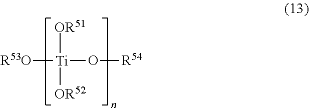
wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

14. The patterning process according to claim 6, wherein, as the organotitanium compound, a compound represented by the following general formula (13) is used, 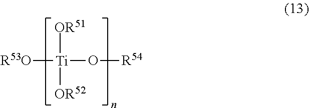
wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

15. The patterning process according to claim 7, wherein, as the organotitanium compound, a compound represented by the following general formula (13) is used, 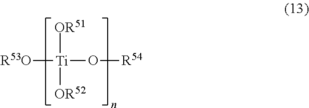
wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.

16. The patterning process according to claim 8, wherein, as the organotitanium compound, a compound represented by the following general formula (13) is used, 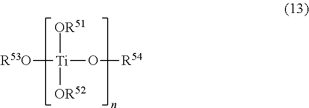
wherein R⁵¹, R⁵², R⁵³, and R⁵⁴ are identical to or different from each other, and each represent a monovalent organic group having 1 to 30 carbon atoms, R⁵¹ and R⁵² may be bonded to each other to form a ring structure, and “n” represents a real number of 1 or more.
